(19) United States
(12) Patent Application Publication
(10) Pub. No.: US 2024/0357933 A1
(43) Pub. Date: Oct. 24, 2024

(54) ORGANIC ELECTRIC ELEMENT COMPRISING A PLURALITY OF EMISSION-AUXILIARY LAYERS AND ELECTRONIC DEVICE COMPRISING IT

(71) Applicant: DUK SAN NEOLUX CO., LTD., Chungcheongnam-do (KR)

(72) Inventors: BUM SUNG LEE, Chungcheongnam-do (KR); HYUN JI OH, Chungcheongnam-do (KR); SOUNG YUN MUN, Chungcheongnam-do (KR); SUN HEE LEE, Chungcheongnam-do (KR); WON SAM KIM, Chungcheongnam-do (KR); GUANG MING LI, Chungcheongnam-do (KR); MIN JI JO, Chungcheongnam-do (KR)

(21) Appl. No.: 18/646,897

(22) Filed: Apr. 26, 2024

Related U.S. Application Data
(62) Division of application No. 17/773,732, filed on May 2, 2022.

(30) Foreign Application Priority Data
Nov. 1, 2019 (KR) 10-2019-0138801
Oct. 23, 2020 (KR) 10-2020-0138278

(51) Int. Cl. H10K 85/60; H10K 50/11; H10K 50/13; H10K 101/30; H10K 101/40; H10K 102/00

(52) U.S. Cl. CPC H10K 85/6576; H10K 85/657; H10K 85/6572; H10K 85/6574; H10K 50/11; H10K 50/13; H10K 2101/30; H10K 2101/40; H10K 2102/351

(57) ABSTRACT

An organic electric element includes a first electrode, a second electrode, and an organic material layer between the first electrode and the second electrode. The organic material layer includes a light-emitting layer, a hole transport layer between the first electrode and the light-emitting layer, and a plurality of emission-auxiliary layers between the light-emitting layer and the hole transport layer. The plurality of emission-auxiliary layers include a first emission-auxiliary layer adjacent to the hole transport layer and a second emission-auxiliary layer adjacent to the light-emitting layer. Each of the first emission-auxiliary layer and the second emission-auxiliary layer is independently formed of one type of a compound without additional doping. The first emission-auxiliary layer includes a compound represented by Formula 1 or Formula 2, and the second emission-auxiliary layer includes a compound represented by Formula A-4-1 or Formula A-4-2.

### CROSS-REFERENCE TO RELATED APPLICATION AND CLAIM OF PRIORITY

This application is a divisional application of application Ser. No. 17/773,732, filed on May 2, 2022, which is a National Stage entry from International Application No. PCT/KR 2020/014745, filed on Oct. 27, 2020, which claims priority to the benefit of Korean Patent Application Nos. 10-2019-0138801 filed on Nov. 1, 2019, and 10-2020-0138278 filed on Oct. 23, 2020 in the Korean Intellectual Property Office, the entire contents of which are incorporated herein by reference.

### BACKGROUND

### 1. Technical Field

The present invention relates to an organic electric device comprising a plurality of emission-auxiliary layers and an electronic device including the same, and more particularly, to an organic electric element comprising a plurality of emission-auxiliary layers having the highest occupied molecular orbital (HOMO) energy level lower than that of a hole transport layer and higher than that of a light-emitting layer, and an electronic device including the same.

### 2. Background Art

In general, an organic light emitting phenomenon refers to a phenomenon in which electric energy is converted into light energy of an organic material. An organic electric element utilizing the organic light emitting phenomenon usually has a structure including an anode, a cathode, and an organic material layer interposed therebetween. In many cases, the organic material layer has a multi-layered structure having respectively different materials in order to improve efficiency and stability of an organic electric element, and for example, may include a hole injection layer, a hole transport layer, a light-emitting layer, an electron transport layer, an electron injection layer, or the like.

In general, an electron is transferred from an electron transport layer to a light-emitting layer and a hole is transferred from a hole transport layer to the light-emitting layer, as a result, an exciton is formed by the recombination of the electron and hole.

However, the material used for the hole transport layer has a low HOMO value and therefore has a low T1 value. As a result, the exciton generated in the light-emitting layer is transferred to the hole transport layer, resulting in a charge unbalance in the light-emitting layer and there is a problem in that light is emitted at the interface of the hole transport layer.

Therefore, in order to solve the problem of light emission from a hole transport layer, an organic electric element that has a plurality of hole transport layers or an emission-auxiliary layer formed between a hole transport layer and a light-emitting layer has been proposed.

Korean Patent Publication Nos. 10-2014-0001581 and 10-2015-0023174 disclose an organic electric element including a hole transport layer of a multilayer structure. Such organic electric elements are intended to improve hole injection characteristics by doping a p-type doping material in a hole transport layer having one type of hole transporting material or by mixing a hole injection material with high conductivity to reduce the driving voltage of the element.

However, in this method, although the driving voltage of the device is reduced, the lifetime of the device is reduced and the hole transporting material is easily degraded by electrons injected into the device since a high-conductivity hole-transporting material is used and charge is injected excessively. As a result, light emission occurs near the interface between a hole transport layer and a light-emitting layer, and non-emission quenching increases, so that the efficiency and lifespan of the device are still deteriorated.

### SUMMARY

Therefore, the present invention is to solve the problems of the prior art, an object of the present invention is to provide an organic electric element having the improved luminous efficiency and lifetime by forming a plurality of emission-auxiliary layers having a predetermined thickness between a hole transport layer and a light-emitting layer, and by appropriately adjusting the HOMO energy level of the emission-auxiliary layers in consideration of the HOMO energy level of the adjacent organic material layer without using a p-type doping material when forming a plurality of emission-auxiliary layers, and an electronic device including the same.

In one aspect of the present invention, the present invention provides an organic electric element comprising a plurality of emission-auxiliary layers having a predetermined thickness, wherein the plurality of emission-auxiliary layers have the HOMO energy level lower than the HOMO energy level of a hole transport layer and higher than the HOMO energy level of a light-emitting layer.

In another aspect of the present invention, the present invention provides an electronic device comprising the organic electric element.

According to the present invention, even if each of emission-auxiliary layers is formed using only a single material without using a p-type doping material, it is possible to provide an organic electric element having the improved stability, luminous efficiency and lifetime without non-luminous quenching, and an electronic device including the same by forming a plurality of emission-auxiliary layers having a predetermined thickness between a hole transport layer and a light-emitting layer and by adjusting the energy level so that the HOMO energy level of the emission-auxiliary layers are lower than the HOMO energy level of a hole transport layer and higher than the HOMO energy level of a light-emitting layer.

### BRIEF DESCRIPTION OF THE DRAWINGS

FIG. 1 is a schematic configuration diagram of an organic electric device according to an embodiment of the present invention.

FIG. 2 is a schematic configuration diagram of an organic material layer showing the energy level of an organic electric device according to an embodiment of the present invention.

### DETAILED DESCRIPTION

Hereinafter, the present invention will be described with reference to the accompanying drawings.

In the reference numbers assigned to the components of each drawing, it should be noted that the same elements will be designated by the same reference numerals although they are shown in different drawings. In addition, in the following description of the present invention, a detailed description of known functions and configurations incorporated herein will be omitted when it may make the subject matter of the present invention rather unclear.

In describing the components of the present invention, terms such as first, second, A, B, (a), (b) or the like may be used. Each of these terminologies is not used for defining an essence, order or sequence of a corresponding component but used merely to distinguish the corresponding component from other component(s). It will be understood that the expression “one component is “connected,” “coupled” or “joined” to another component” comprises the case where a third component may be “connected,” “coupled,” and “joined” between the first and second components as well as the case where the first component may be directly connected, coupled or joined to the second component.

In addition, it will be understood that when an element such as a layer, film, region or substrate is referred to as being “on” or “over” another element, it can be directly on the other element or intervening elements may also be present. In contrast, when an element is referred to as being “directly on” another element, there are no intervening elements present.

Unless otherwise stated, the term “aryl group” and “arylene group” as used herein has, but not limited to, 6 to 60 carbon atoms. The aryl group or arylene group in the present invention may comprise a monocyclic ring, ring assemblies, a fused polycyclic system, spiro compounds and the like. In addition, unless otherwise stated, a fluorenyl group may be comprised in an aryl group and a fluorenylene group may be comprised in an arylene group.

As used herein, the term “fluorenyl group” refers to a substituted or unsubstituted fluorenyl group, “fluorenylene group” refers to a substituted or unsubstituted fluorenyl group. The fluorenyl group or fluorenylene group used in the present invention comprises a spiro compound formed by combining R and R′ with each other in the following structure, and also comprises compound formed by linking adjacent R″ s to each other. “Substituted fluorenyl group”, “substituted fluorenylene group” means that at least one of R, R′, R″ in the following structure is a substituent other than hydrogen, and R″ may be 1 to 8 in the following formula. In the present specification, regardless of the valence, a fluorenyl group, a fluorenylene group, a fluorenetriyl group, and the like may all be referred to as a fluorene group.

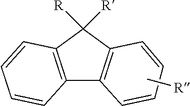

The term “spiro compound” as used herein has a spiro union which means union having one atom as the only common member of two rings. The common atom is designated as ‘spiro atom’. The compounds are defined as ‘monospiro-’, ‘dispiro-’ or ‘trispiro-’ depending on the number of spiro atoms in one compound.

The term “heterocyclic group” used in the specification comprises a non-aromatic ring as well as an aromatic ring like “heteroaryl group” or “heteroarylene group”. Unless otherwise stated, the term “heterocyclic group” means, but not limited to, a ring containing one or more heteroatoms and having 2 to 60 carbon atoms. Unless otherwise stated, the term “heteroatom” as used herein represents N, O, S, P or Si and the heterocyclic group means a monocyclic, ring assemblies, fused polycyclic system or spiro compound containing a heteroatom. In addition, heterocyclic group comprises the compound comprising the heteroatom group such as SO₂, P═O and the like instead of carbon forming a ring like the following compound.

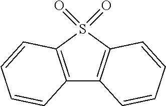 [SMILES: O=S1(=O)c2ccccc2-c2ccccc21]

The term “aliphatic ring group” as used herein refers to a cyclic hydrocarbon except for aromatic hydrocarbons, and comprises a monocyclic ring, ring assemblies, a fused polycyclic system, spiro compounds, and the like, and unless otherwise specified, it means a ring of 3 to 60 carbon atoms, but not limited thereto. For example, a fused ring formed by benzene being an aromatic ring with cyclohexane being a non-aromatic ring corresponds to aliphatic ring group.

In this specification, a ‘group name’ corresponding to an aryl group, an arylene group, a heterocyclic group, and the like exemplified for each symbol and its substituent may be written in the name of functional group reflecting the valence, and may also be described as the name of a parent compound. For example, in the case of phenanthrene which is a kind of aryl group, it may be described by distinguishing valence such as ‘phenanthryl (group)’ when it is ‘monovalent group’, and as ‘phenanthrylene (group)’ when it is ‘divalent group’, and it may also be described as a parent compound name, ‘phenanthrene’, regardless of its valence. Similarly, in the case of pyrimidine, it may be described as ‘pyrimidine’ regardless of its valence, and it may also be described as the name of corresponding functional group such as pyrimidinyl (group) when it is ‘monovalent group’, and as ‘pyrimidylene (group)’ when it is ‘divalent group’.

In addition, in the present specification, the numbers and alphabets indicating a position may be omitted when describing a compound name or a substituent name, For example, pyrido[4,3-d]pyrimidine, benzopuro[2,3-d] pyrimidine and 9,9-dimethyl-9H-fluorene can be described as pyridopyrimidine, benzofurropyrimidine and dimethylfluorene, respectively. Therefore, both benzo[g]quinoxaline and benzo[f]quinoxaline can be described as benzoquinoxaline.

In addition, unless otherwise expressed, where any formula of the present invention is represented by the following formula, the substituent according to the index may be defined as follows.

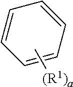

In the above formula, when a is an integer of zero, the substituent R¹ is absent, that is, hydrogen atoms are bonded to all the carbon constituting the benzene ring. Here, chemical formulas or compounds may be written without explicitly describing the hydrogen. In addition, one substituent R¹ is bonded to any carbon of the carbons forming the benzene ring when “a” is an integer of 1, when “a” is an integer of 2 or 3, substituents R¹s may be bonded to the carbon of the benzene ring, for example, as followings and, when “a” is an integer of 4 to 6, substituents R¹s are bonded to the carbon of the benzene ring in a similar manner. Further, when “a” is an integer of 2 or more, R¹s may be the same or different from each other.

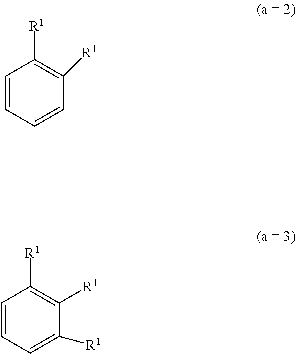

In addition, unless otherwise specified in the present specification, when referring to a condensed/fused ring, the number in the ‘number-condensed/fused ring’ indicates the number of condensed/fused rings. For example, a form in which three rings are condensed/fused with each other, such as anthracene, phenanthrene, and benzoquinazoline, may be represented by a 3-condensed/fused ring.

In addition, unless otherwise described herein, in the case of expressing a ring in the form of a ‘number-membered’ such as a 5-membered ring or a 6-membered ring, the number in the ‘number-membered’ represents the number of atoms forming the ring. For example, thiophene or furan may correspond to a 5-membered ring, and benzene or pyridine may correspond to a 6-membered ring.

In addition, unless otherwise specified in the present specification, the ring formed by bonding between adjacent groups may be selected from the group consisting of a C₆-C₆₀ aromatic ring group, a fluorenyl group, a C₂-C₆₀ heterocyclic group containing at least one heteroatom selected from the group consisting of O, N, S, Si, and P, and a C₃-C₆₀ aliphatic ring.

Unless otherwise stated, the term “between adjacent groups”, for example, in case of the following Formulas, comprises not only “between R₁ and R₂”, “between R₂ and R₃”, “between R₃ and R₄”, “between R₅ and R₆”, but also “between R₇ and R₈” sharing one carbon, and may comprise “between substituents” attached to atom (carbon or nitrogen) consisting different ring, such as “between R₁ and R₇”, “between R₁ and R₈”, or “between R₄ and R₈” and the like. That is, where there are substituents bonded to adjacent elements constituting the same ring, the substituents may be correspond “adjacent groups”, and even if there are no adjacent substituents on the same ring, substituents attached to the neighboring ring may correspond to “adjacent groups”.

In the following Formula, when the substituents bonded to the same carbon, such as R₇ and R₈, are linked to each other to form a ring, a compound containing a spiro-moiety may be formed.

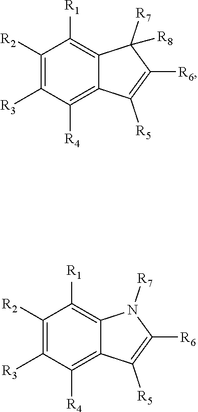

In addition, in the present specification, the expression ‘neighboring groups may be linked to each other to form a ring’ is used in the same sense as ‘neighboring groups are linked selectively to each other to form a ring’, and a case where at least one pair of neighboring groups may be bonded to each other to form a ring.

In addition, unless otherwise specified in the present specification, an aryl group, an arylene group, a fluorenyl group, a fluorenylene group, a heterocyclic group, an aliphatic ring group, an alkyl group, an alkenyl group, an alkynyl group, an alkoxy group, an aryloxy group, and a ring formed by linking neighboring groups to each other may be each optionally substituted with one or more substituents selected from the group consisting of deuterium, halogen, a silane group unsubstituted or substituted with a C₁-C₂₀ alkyl group or a C₆-C₂₀ aryl group, a phosphine oxide group unsubstituted or substituted with a C₁-C₂₀ alkyl group or a C₆-C₂₀ aryl group, a siloxane group, a cyano group, a nitro group, a C₁-C₂₀ alkylthio group, a C₁-C₂₀ alkoxy group, a C₆-C₂₀ aryloxy group, a C₆-C₂₀ arylthio, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, and a C₃-C₂₀ aliphatic ring group.

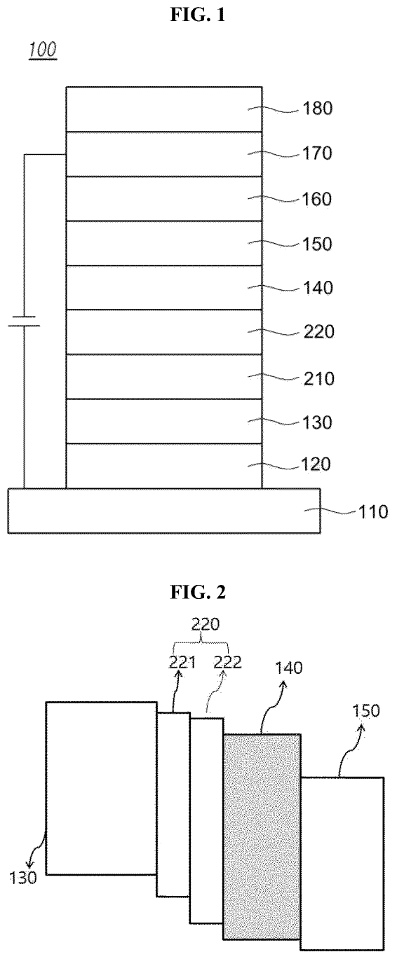

The FIG. 1 illustrates an example of an organic electroluminescent element according to an embodiment of the present invention.

Referring to the FIG. 1, an organic electric element 100 according to an embodiment of the present invention includes a first electrode 110 formed on a substrate (not shown), a second electrode 170, and an organic material layer formed between the first electrode 110 and the second electrode 170.

The first electrode 110 may be an anode (positive electrode), and the second electrode 170 may be a cathode (negative electrode). In the case of an inverted organic electric element, the first electrode may be a cathode, and the second electrode may be an anode.

The organic material layer may be comprised a hole injection layer 120, a hole transport layer 130, a light-emitting layer 140, an electron transport layer 150, and an electron injection layer 160, and an emission-auxiliary layer 220 is formed between a hole transport layer 130 and a light-emitting layer 140. In addition, a buffer layer 210 may be further formed between a hole transport layer 130 and an emission-auxiliary layer 220.

Specifically, a hole injection layer 120, a hole transport layer 130, a buffer layer 210, an emission-auxiliary layer 220, a light-emitting layer 140, an electron transport layer 150, and an electron injection layer 160 are formed on the first electrode 110 in sequence.

Preferably, a layer for improving the luminous efficiency 180 may be formed on one side of sides of the first electrode 110 or one side of sides of the second electrode 170, wherein the one side is not facing the organic material layer. If a layer for improving the luminous efficiency 180 is formed, the luminous efficiency of an organic electric element can be improved.

For example, the light efficiency improving layer 180 may be formed on the second electrode 170, as a result, in the case of a top emission organic light emitting diode, the optical energy loss due to Surface Plasmon Polarizations (SPPs) at the second electrode 170 may be reduced and in the case of a bottom emission organic light emitting diode, the light efficiency improving layer 180 may serve as a buffer for the second electrode 170.

Although not shown in FIG. 1, an electron transport-auxiliary layer may be further formed between the light-emitting layer 140 and the electron transport layer 150.

An emission-auxiliary layer 220 according to the present invention will be described in more detail with reference to FIG. 2.

FIG. 2 is a schematic configuration diagram of an organic material layer showing the energy level of an organic electric device according to an embodiment of the present invention.

Referring to FIG. 2, an organic material layer according to an embodiment of the present invention comprises a plurality of emission-auxiliary layers, and FIG. 2 shows an organic material layer including two emission-auxiliary layers. The plurality of emission-auxiliary layers 220 comprise a first emission-auxiliary layer 221 adjacent to the hole transport layer 130 and a second emission-auxiliary layer 222 adjacent to the light-emitting layer 140.

Preferably, the HOMO energy level of the emission-auxiliary layer 220 is lower than the HOMO energy level of the hole transport layer 130 and higher than the HOMO energy level of the light-emitting layer 140, and the HOMO energy level of the first emission-auxiliary layer 221 is higher than the HOMO energy level of the second emission-auxiliary layer 222.

Since the HOMO value has a negative value, ‘lower HOMO energy level’ means a larger absolute value. Therefore, the absolute value of the HOMO energy level of the emission-auxiliary layer 220 according to the present invention is larger than the absolute value of the HOMO energy level of the hole transport layer 130 and smaller than the absolute value of the HOMO energy level of the light-emitting layer 140, and it is preferable that the absolute value of the HOMO energy level of the first emission-auxiliary layer 221 is smaller than the absolute value of the HOMO energy level of the second emission-auxiliary layer 222.

Preferably, the first emission-auxiliary layer 221 is formed of one type of compound without additional doping and has a thickness of 200 to 400 Å, and the second emission-auxiliary layer 222 is also formed of one type of compound without additional doping. and a thickness of 50 to 200 Å, and the total thickness of the emission-auxiliary layers is 300 to 400 Å. Here, ‘additional doping’ may mean doping with a p-doping material.

Like this, even if each of the emission-auxiliary layers 220 of the present invention is formed of only one type of compound without additional doping with a p-doping material, by forming the emission-auxiliary layer having a predetermined thickness and the appropriate HOMO energy level in relation to the adjacent organic material layer, the lifespan and efficiency of an organic electric element can be improved.

Preferably, the HOMO energy level of the first emission-auxiliary layer 221 is 0.01 to 0.5 eV higher than the HOMO energy level of the second auxiliary layer 222, and the HOMO energy levels of the first emission-auxiliary layer 221 and the second emission-auxiliary layer 222 are respectively 5.50 to 5.69 eV based on absolute values. That is, it is preferable that the HOMO energy level of the first light emission auxiliary layer 221 and the second light emission auxiliary layer 222 has a value of −5.69 eV or more and −5.50 eV or less, respectively, and the HOMO energy level of the first emission-auxiliary layer 221 is higher than the HOMO energy level of the second auxiliary layer 222.

Preferably, a light-emitting layer according to the present invention is a red light-emitting layer or a green light-emitting layer.

According to another embodiment of the present invention, the organic material layer may be formed in a plurality of stacks, wherein the stacks comprise a hole transport layer, an emission-auxiliary layer, a light-emitting layer, and an electron transport layer.

In general, an organic light emitting element can be divided into a single light emitting element (Single OLED) and a multilayer light emitting element (Tandem OLED) according to the number of light emitting units. A multilayer light emitting element (Tandem OLED) is an OLED element composed of two or more light emitting units (stack), and it is easier to improve the driving voltage and efficiency compared to the conventional single OLED.

Specifically, the organic electric element according to an embodiment of the present invention may include a first electrode, a first stack formed on the first electrode, a second stack formed on the first stack, and a second electrode. Here, the stack may correspond to an organic material layer, and a layer for improving light efficiency may be further formed on one side of both sides of the first electrode and/or the second electrode, wherein the one side is not facing with the organic material layer.

Each of the first and the second stacks is an organic material layer comprising a hole injection layer, a hole transport layer, a light-emitting layer and an electron transport layer, and the first and the second stacks may be formed in the same or different stacked structures.

At least one of the first stack and the second stack includes a plurality of light emitting-auxiliary layers according to the present invention. That is, a plurality of light emitting-auxiliary layers according to the present invention are comprised between the hole transport layer and the light-emitting layer, and these light emitting-auxiliary layers may be included in the first stack and/or the second stack.

In addition, a charge generation layer (CGL) may be formed between the first stack and the second stack. The charge generation layer CGL may include a first charge generation layer and a second charge generation layer. The charge generating layer (CGL) is formed between the light-emitting layer of the first stack and the light-emitting layer of the second stack to increase current efficiency generated in each light-emitting layer and smoothly distribute charges.

Two or more stacks of the organic material layer may be formed. For example, in a case where three stacks are formed, a charge generating layer (CGL) and a third stack may be additionally stacked on the second stack.

Like this, when a plurality of light-emitting layers are formed by the multilayer stack structure method, it is possible to manufacture an organic electroluminescent element that emits white light by the mixing effect of the light emitted from each light-emitting layer, as well as to emit light of various colors.

The organic layer with a smaller number of layers according to the present invention may be manufactured by a solution process or a solvent process such as a spin coating process, a nozzle printing process, an inkjet printing process, a slot coating process, a dip coating process, a roll-to-roll process, doctor blading process, a screen printing process, or a thermal transfer method using various polymer materials rather than a deposition method. Since the organic material layer according to the present invention may be formed in various ways, the scope of protection of the present invention is not limited by a method of forming the organic material layer.

The organic electric element according to an embodiment of the present invention may be of a top emission type, a bottom emission type, or a dual emission type depending on the material used.

In addition, the organic electric element according to an embodiment of the present invention may be selected from the group consisting of an organic electroluminescent element, an organic solar cell, an organic photo conductor, an organic transistor, an element for monochromatic illumination and an element for quantum dot display.

Another embodiment of the present invention provides an electronic device including a display device which includes the above described organic electric element, and a control unit for controlling the display device. Here, the electronic device may be a wired/wireless communication terminal which is currently used or will be used in the future, and covers all kinds of electronic devices including a mobile communication terminal such as a cellular phone, a personal digital assistant (PDA), an electronic dictionary, a point-to-multipoint (PMP), a remote controller, a navigation unit, a game player, various kinds of TVs, and various kinds of computers.

According to the present invention, the HOMO energy level of the emission-auxiliary layer 220 is lower than the HOMO energy level of the hole transport layer 130 and higher than the HOMO energy level of the light-emitting layer 140.

Preferably, a plurality of emission-auxiliary layers according to the present invention comprise a first emission-auxiliary layer adjacent to a hole transport layer and a second emission-auxiliary layer adjacent to a light-emitting layer, wherein the first emission-auxiliary layer and the second emission-auxiliary layer comprise compound represented by the following Formula 1 or Formula 2.

Here, the first emission-auxiliary layer and the second emission-auxiliary layer are preferably formed of different compounds. That is, even if both the first emission-auxiliary layer and the second emission-auxiliary layer are formed of the compound represented by the following Formula 1 or both are formed of the compound represented by the following Formula 2, each of the emission-auxiliary layers is preferably formed of a different compound.

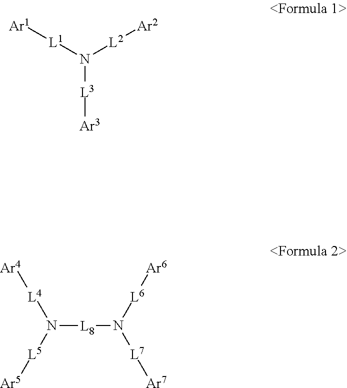

In Formulas 1 and 2, each of symbols may be defined as follows.

Ar¹ to Ar⁷ are each independently selected from the group consisting of a C₆-C₆₀ aryl group, a fluorenyl group, a C₂-C₆₀ heterocyclic group comprising at least one heteroatom selected from the group consisting of O, N, S, Si and P, and a C₃-C₆₀ aliphatic ring, Ar⁴ and Ar⁵ may be linked to each other to form a ring, and Ar⁶ and Ar⁷ may be linked to each other to form a ring. When Ar⁴ and Ar⁵ are linked to each other or Ar⁶ and Ar⁷ are linked to each other to form a ring, a heterocycle including N may be formed together with N in the backbone to which they are directly or indirectly linked.

When Ar¹ to Ar⁷ are each an aryl group, the aryl group may be preferably a C₆-C₃₀ aryl group, more preferably a C₆-C₁₈ aryl group, for example, phenyl, biphenyl, naphthyl, terphenyl, phenanthrene, anthracene, triphenylene, pyrene, chrysene, and the like.

When Ar¹ to Ar⁷ are each a heterocyclic group, the heterocyclic group may be preferably a C₂-C₃₀ heterocyclic group, more preferably a C₂-C₂₆ heterocyclic group, for example, pyridine, pyrimidine, pyrazine, pyridazine, triazine, furan, thiophene, pyrrole, silole, indene, indole, phenyl-indole, benzoindole, phenyl-benzoindole, benzofuran, benzothiophene, benzoimidazole, benzothiazole, benzoxazole, benzosilole, dibenzofuran, dibenzothiophene, carbazole, quinoline, isoquinoline, benzoquinoline, quinoxaline, quinazoline, phenanthroline, benzonaphthothiophene, benzonaphthofuran, phenylcarbazole, benzocarbazole, phenyl-benzocarbazole, naphthyl-benzocarbazole, dibenzocarbazole, indolocarbazole, benzofuropyridine, benzothienopyridine, and the like.

When Ar¹ to Ar⁷ are each an aliphatic ring, the aliphatic ring may be preferably a C₃-C₂₀ aliphatic ring, more preferably a C₆-C₁₆ aliphatic ring, for example, cyclohexane, fluoranthene, or the like.

When Ar¹ to Ar⁷ are each a fluorenyl group, the fluorenyl group may be 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, and the like.

L¹ to L⁷ are each independently selected from the group consisting of a single bond, a C₆-C₆₀ arylene group, a fluorenylene group, a C₃-C₆₀ aliphatic ring, and a C₂-C₆₀ heterocyclic group comprising at least one heteroatom selected from the group consisting of O, N, S, Si and P.

Where L¹ to L⁷ are each an arylene group, the arylene group may be preferably a C₆-C₃₀ arylene group, more preferably a C₆-C₁₈ arylene group, for example, phenylene, biphenyl, naphthalene, terphenyl, pyrene, phenanthrene and the like.

Where L¹ to L⁷ are each a heterocyclic group, the heterocyclic group may be preferably a C₂-C₃₀ heterocyclic group, more preferably a C₂-C₂₂ heterocyclic group, for example, carbazole, phenylcarbazole, naphthylcarbazole, dibenzothiophene, dibenzofuran, benzonaphthothiophene, benzonaphthofuran and the like.

Where L¹ to L⁷ are each a fluorenylene group, the fluorenylene group may be 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, and the like.

L⁸ is selected from the group consisting of a C₆-C₆₀ arylene group, a fluorenylene group, a C₃-C₆₀ aliphatic ring, and a C₂-C₆₀ heterocyclic group comprising at least one heteroatom selected from the group consisting of O, N, S, Si and P.

Where L⁸ is an arylene group, the arylene group may be preferably a C₆-C₃₀ arylene group, more preferably a C₆-C₁₈ arylene group, for example, phenylene, biphenyl, naphthalene, terphenyl, anthracene, phenanthrene, pyrene, and the like.

Where L⁸ is a heterocyclic group, the heterocyclic group may be preferably a C₂-C₃₀ heterocyclic group, more preferably a C₂-C₁₈ heterocyclic group, for example, dibenzothiophene, dibenzofuran, benzonaphthofuran, benzonaphthothiophene, carbazole, phenylcarbazole, and the like.

Where L⁸ is a fluorenylene group, the fluorenylene group may be 9,9-dimethyl-9H-fluorene, 9,9-diphenyl-9H-fluorene, 9,9′-spirobifluorene, spiro[benzo[b]fluorene-11,9′-fluorene], benzo[b]fluorene, 11,11-diphenyl-11H-benzo[b]fluorene, 9-(naphthalen-2-yl)9-phenyl-9H-fluorene, and the like.

The aryl group, arylene group, fluorenyl group, fluorenylene group, heterocyclic group, aliphatic ring group, the ring formed by linking Ar⁴ and Ar⁵ to each other and the ring formed by linking Ar⁶ and Ar⁷ to each other may be each optionally substituted with one or more substituents selected from the group consisting of deuterium, halogen, a silane group unsubstituted or substituted with a C₁-C₂₀ alkyl group or a C₆-C₂₀ aryl group, a siloxane group, a cyano group, a nitro group, a C₁-C₂₀ alkylthio group, a C₁-C₂₀ alkoxy group, a C₆-C₂₀ aryloxy group, a C₆-C₂₀ arylthio, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}).

L¹ is selected from the group consisting of a single bond, a C₆-C₂₀ arylene group, a fluorenylene group, a C₃-C₂₀ aliphatic ring, and a C₂-C₂₀ heterocyclic group comprising at least one heteroatom selected from the group consisting of O, N, S, Si and P.

Rₐ and R_{b} are each independently selected from the group consisting of a C₆-C₂₀ aryl group, a fluorenyl group, a C₃-C₂₀ aliphatic ring, and a C₂-C₂₀ heterocyclic group comprising at least one heteroatom selected from the group consisting of O, N, S, Si and P.

Formula 1 may be represented by Formula A-1 or Formula A-2.

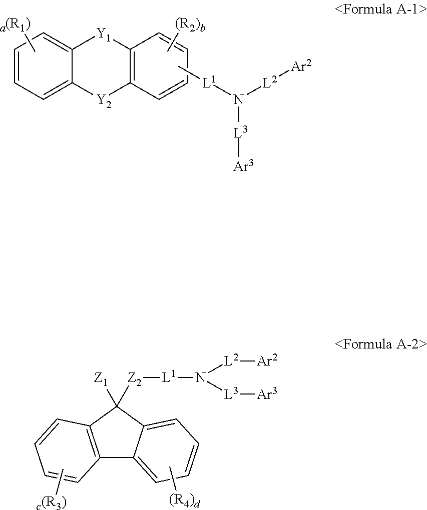

In Formulas A-1 and A-2, each of symbols may be defined as follows.

L¹ to L³, Ar², Ar³ are the same as defined for Formula 1.

Y₁ and Y₂ are each a single bond, O, S or C(R₅)(R₆), and a case where both Y₁ and Y₂ are a single bond is excluded.

R₁ to R₆ and Z₁ are each independently selected from the group consisting of deuterium, halogen, a silane group unsubstituted or substituted with a C₁-C₂₀ alkyl group or a C₆-C₂₀ aryl group, a siloxane group, a cyano group, a nitro group, a C₁-C₂₀ alkylthio group, a C₁-C₂₀ alkoxy group, a C₆-C₂₀ aryloxy group, a C₆-C₂₀ arylthio, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and adjacent groups may be linked to each other to form a ring, and Z₁ and Z₂ may be linked to each other to form a ring.

Z₂ is selected from the group consisting of a C₆-C₂₀ arylene group, a fluorenylene group, a C₂-C₂₀ heterocyclic group containing at least one heteroatom of O, N, S, Si, and P, and a C₃-C₂₀ aliphatic ring group.

a, c and d are each an integer of 0 to 4, b is an integer of 0 to 3, and when each of these is an integer of 2 or more, a plurality of R₁ are the same or different from each other, a plurality of R₂ are the same or different from each other, a plurality of R₃ are the same or different from each other, and a plurality of R₄ are the same or different from each other,

The aryl group, arylene group, fluorenyl group, fluorenylene group, heterocyclic group, aliphatic ring group, alkyl group, alkenyl group, alkynyl group, alkoxy group, aryloxy group, the ring formed by linking adjacent groups to each other, the ring formed by linking R₅ and R₆ to each other, and the ring formed by linking Z₁ and Z₂ to each other may be each optionally substituted with one or more substituents selected from the group consisting of deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and L′, Rₐ and R_{b} are the same as defined for Formula 1.

Formula A-1 may be represented by one of Formulas A-3 to A-6.

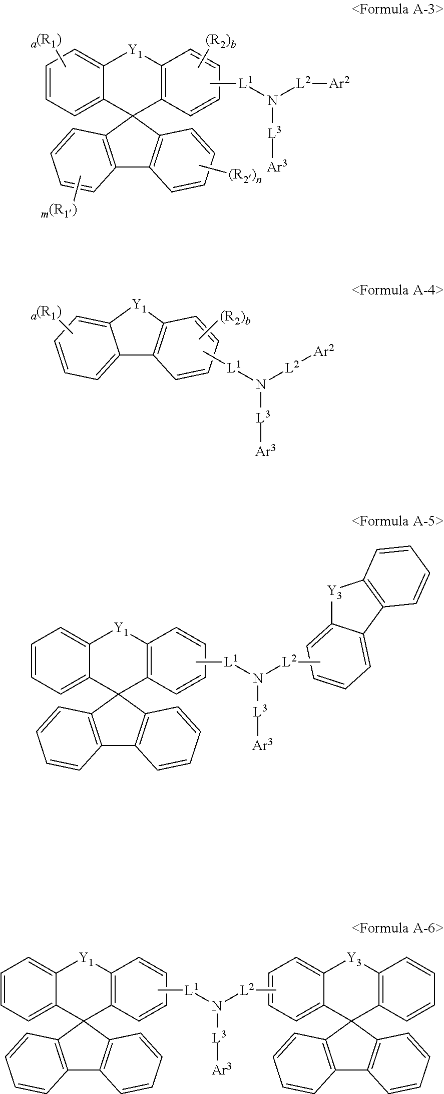

In Formulas A-3 to A-6, each of symbols may be defined as follows.

L¹ to L³, Ar², Ar³, R₁, R₂, a, b, Y₁ are the same as defined for Formula A-1, and Y₃ is defined the same as Y₁.

R_{1′} and R₂ are each independently selected from the group consisting of deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and L′, Rₐ and R_{b} are the same as defined for Formula 1.

m is an integer of 0 to 4, n is an integer of 0 to 3, and when each of these is an integer of 2 or more, a plurality of R_{1′} are the same or different from each other, and a plurality of R_{2′} are the same or different from each other.

In the Formulae described in the specification, since a substituent such as L¹, L², Ar², Ar³, R₁ to R₄, etc. is depicted by drawing that substituent attached to a bond that extends into the center of a ring, it means that the substituent may be attached to any of the ring atoms as is allowed by normal bonding rules according to IUPAC standard.

For example, the substituent L¹ in Formula A-4 may be attached to any of the 1, 2, 3, and 4 ring positions. That is, Formula A-4 may be Formula A-4-1 to A-4-4 as follows:

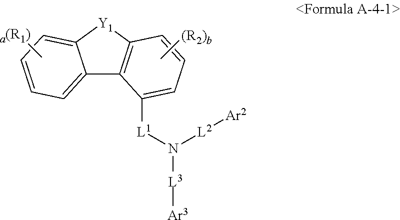

(L¹ attached to the 1 ring position)

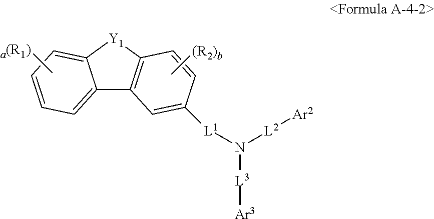

(L¹ is attached to the 2 ring position)

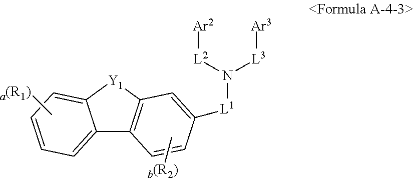

(L¹ is attached to the 4 ring position)

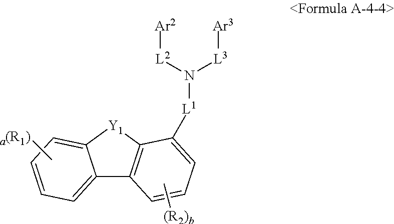

Formula 2 may be represented by Formula B-1.

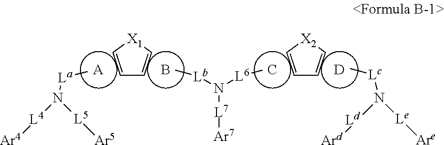

In Formula B-1, each of symbols may be defined as follows.

L⁴ to L⁷, Ar⁴, Ar⁵, Ar⁷ are the same as defined for Formula 2.

A ring, B ring, C ring and D ring are each independently selected from the group consisting of a C₆-C₂₀ aromatic ring group, a fluorene group, a C₂-C₂₀ heterocyclic group containing at least one heteroatom of O, N, S, Si and P, and a C₃-C₂₀ aliphatic ring, and each of these may be substituted with one or more R.

X₁ and X₂ are each independently O, S, N(Ar) or C(R₇)(R₈).

L^{a} to L^{e} are each independently selected from the group consisting of a single bond, a C₆-C₂₀ arylene group, a fluorenylene group, a C₂-C₂₀ heterocyclic group comprising at least one heteroatom selected from the group consisting of O, N, S, Si and P, and a C₃-C₂₀ aliphatic ring.

Ar^{d}, Ar^{e} and Ar are each independently selected from the group consisting of a C₆-C₂₀ aryl group, a fluorenyl group, a C₂-C₂₀ heterocyclic group comprising at least one heteroatom selected from the group consisting of O, N, S, Si and P, a C₃-C₂₀ aliphatic ring.

R, R₇ and R₈ are each independently selected from the group consisting of hydrogen, deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, and a C₃-C₂₀ aliphatic ring group, and R₇ and R₈ may be linked to each other to form a ring.

The aryl group, arylene group, fluorenyl group, fluorenylene group, heterocyclic group, aliphatic ring group, alkyl group, alkenyl group, alkynyl group, alkoxy group, aryloxy group, the ring formed by linking R₇ and R₈ to each other may be each optionally substituted with one or more substituents selected from the group consisting of deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and L′, Rₐ and R_{b} are the same as defined for Formula 2.

Formula B-1 may be represented by one of Formulas B-2 to B-6.

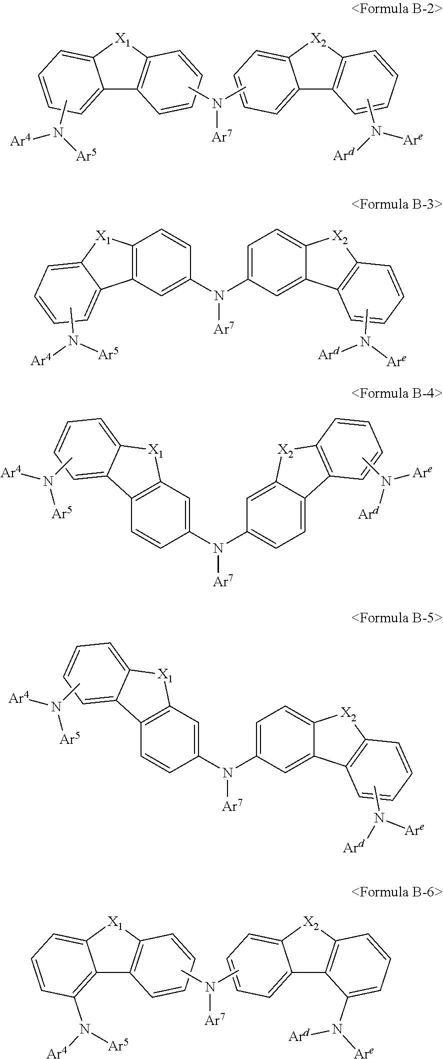

In Formulas B-2 to B-6, Ar⁴, Ar⁵, Ar⁷, Ar^{d}, Ar^{e}, X₁, X₂ are the same as defined for Formula B-1.

Preferably, at least one of Ar¹ to Ar⁷, and L⁸ may be represented by Formula 3 when the first emission-auxiliary layer is comprised of the compound represented by Formula 1 or Formula 2.

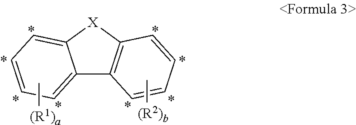

In Formula 3, each of symbols may be defined as follows.

* indicates a bonding position. X is N, N-(L^{a}-Ar^{a}), O, S or C(R′)(R″).

In a case where Ar¹ to Ar³ of Formula 1 are each Formula 3, L¹ to L³ are each bonded to the carbon represented by * in Formula 3 when X is N-(L^{a}-Ar^{a}), O, S or C(R′)(R″), and L¹ to L³ are each bonded to X when X is N.

In a case where Ar⁴ to Ar⁷ of Formula 2 are each Formula 3, L⁴ to L⁷ are each bonded to the carbon represented by * in Formula 3 when X is N-(L^{a}-Ar^{a}), O, S or C(R′)(R″), and L⁴ to L⁷ are each bonded to X when X is N.

In a case where L⁸ of Formula 2 is Formula 3, both Ns in the skeleton are each bonded to the carbon represented by * in Formula 3 when X is N-(L^{a}-Ar^{a}), O, S or C(R′)(R″), and one of both Ns in the backbone is bonded to X, and the other is bonded to the carbon represented by * in Formula 3 when X is N.

R¹, R², R′ and R″ are each independently selected from the group consisting of hydrogen, deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), adjacent groups may be linked to each other to form a ring, and R′ and R″ may be linked to each other to form a ring, and L′, Rₐ and R_{b} are the same as defined in the above.

a and b are each an integer of 0 to 4, and when each of these is an integer of 2 or more, a plurality of R′ are the same or different from each other, and a plurality of R² are the same or different from each other.

L^{a} is selected from the group consisting of a single bond, a C₆-C₂₀ arylene group, a fluorenylene group, a C₂-C₂₀ heterocyclic group comprising at least one heteroatom selected from the group consisting of O, N, S, Si and P, and a C₃-C₂₀ aliphatic ring.

Ar^{a} is selected from the group consisting of a C₆-C₂₀ aryl group, a fluorenyl group, a C₂-C₂₀ heterocyclic group comprising at least one heteroatom selected from the group consisting of O, N, S, Si and P, and a C₃-C₂₀ aliphatic ring.

Preferably, Ar¹ to Ar⁷ may be each a C₆-C₂₄ aryl group and L⁸ may be a C₆-C₂₄ arylene group when the second emission-auxiliary layer is comprised of the compound represented by Formula 1 or Formula 2.

In addition, preferably, at least one of Ar¹ to Ar⁷ and L⁸ may be a dibenzofuran when the second emission-auxiliary layer is comprised of the compound represented by Formula 1 or Formula 2.

The first emission-auxiliary layer and the second emission-auxiliary layer may be formed of different compound, and the first emission-auxiliary layer may comprise the compound represented by Formula A-1.

Specifically, the compound represented by formula 1 may be one of the following compounds, but there is no limitation thereto.

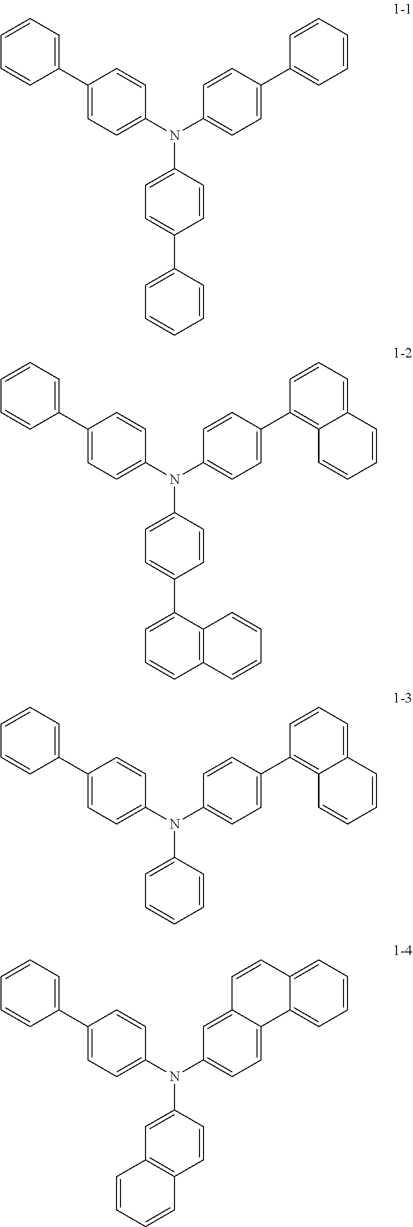 [SMILES: c1ccc(-c2ccc(N(c3ccc(-c4ccccc4)cc3)c3ccc(-c4ccccc4)cc3)cc2)cc1 ; c1ccc(-c2ccc(N(c3ccc(-c4cccc5ccccc45)cc3)c3ccc(-c4cccc5ccccc45)cc3)cc2)cc1 ; c1ccc(-c2ccc(N(c3ccccc3)c3ccc(-c4cccc5ccccc45)cc3)cc2)cc1 ; c1ccc(-c2ccc(N(c3ccc4ccccc4c3)c3ccc4c(ccc5ccccc54)c3)cc2)cc1]

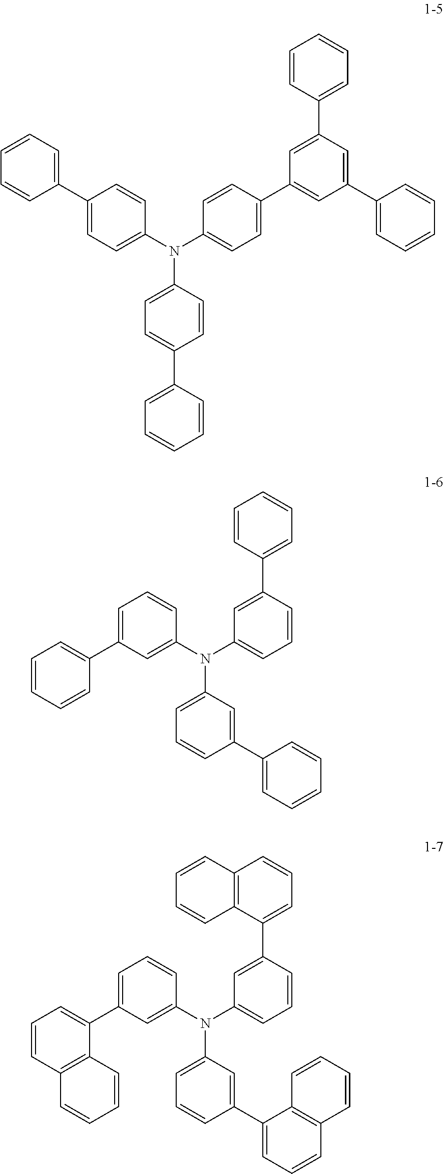 [SMILES: c1ccc(-c2ccc(N(c3ccc(-c4ccccc4)cc3)c3ccc(-c4cc(-c5ccccc5)cc(-c5ccccc5)c4)cc3)cc2)cc1 ; c1ccc(-c2cccc(N(c3cccc(-c4ccccc4)c3)c3cccc(-c4ccccc4)c3)c2)cc1 ; c1cc(-c2cccc3ccccc23)cc(N(c2cccc(-c3cccc4ccccc34)c2)c2cccc(-c3cccc4ccccc34)c2)c1]

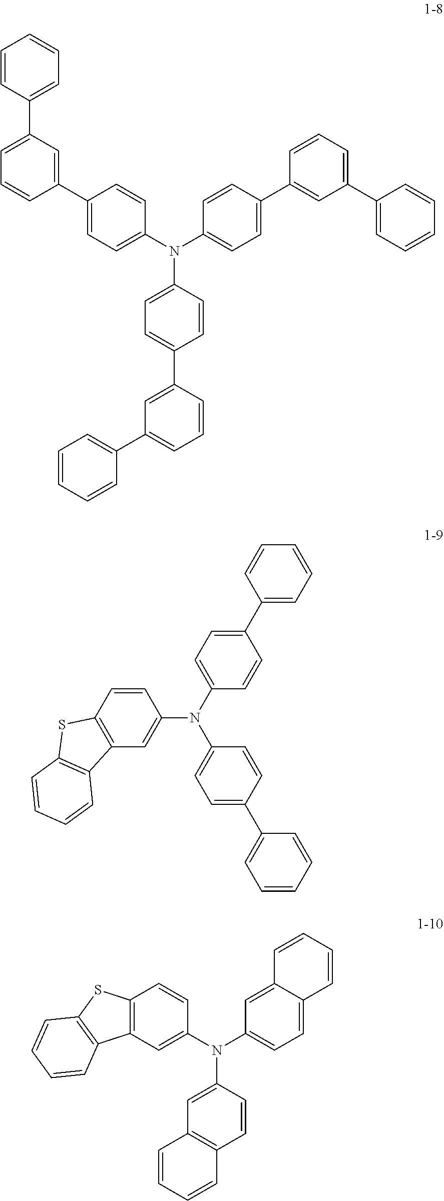

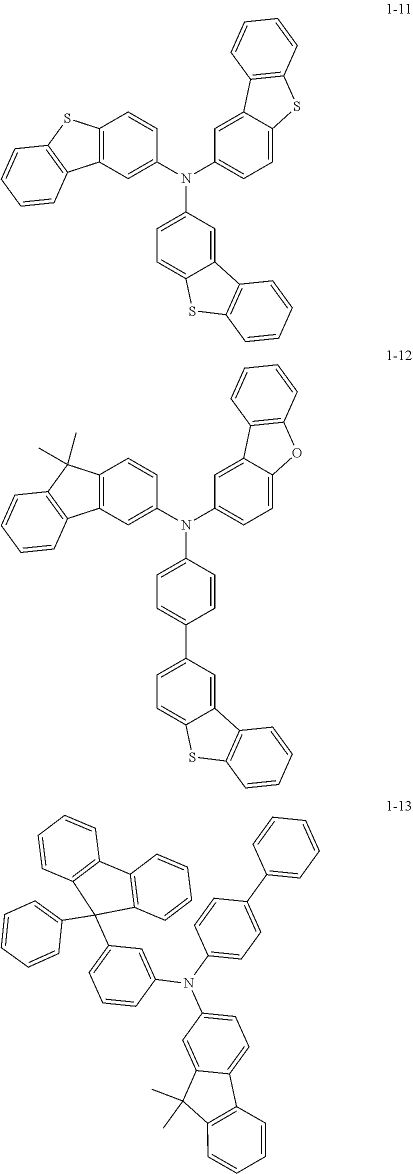

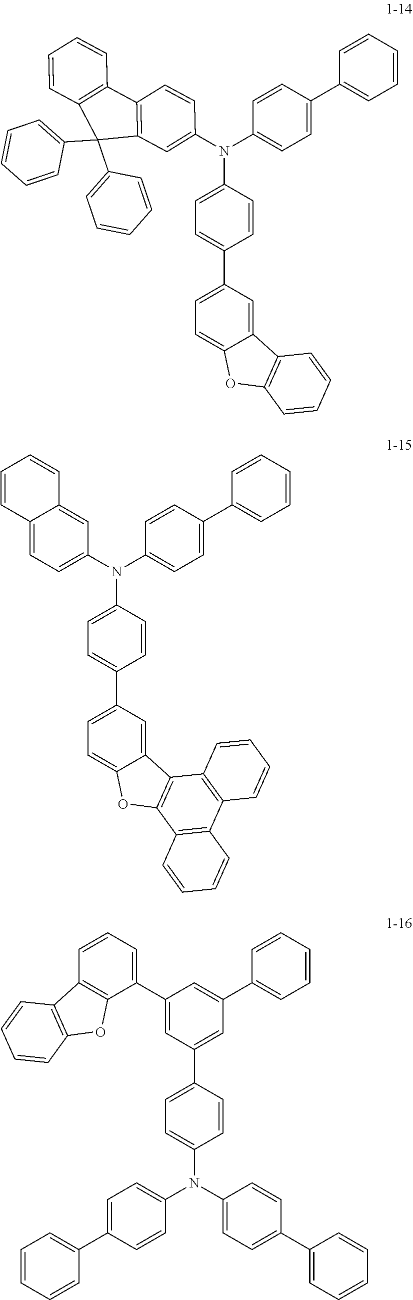 [SMILES: c1ccc(-c2ccc(N(c3ccc(-c4ccc5oc6ccccc6c5c4)cc3)c3ccc4c(c3)C(c3ccccc3)(c3ccccc3)c3ccccc3-4)cc2)cc1 ; c1ccc(-c2ccc(N(c3ccc(-c4ccc5oc6c7ccccc7c7ccccc7c6c5c4)cc3)c3ccc4ccccc4c3)cc2)cc1 ; c1ccc(-c2ccc(N(c3ccc(-c4ccccc4)cc3)c3ccc(-c4cc(-c5ccccc5)cc(-c5cccc6c5oc5ccccc56)c4)cc3)cc2)cc1]

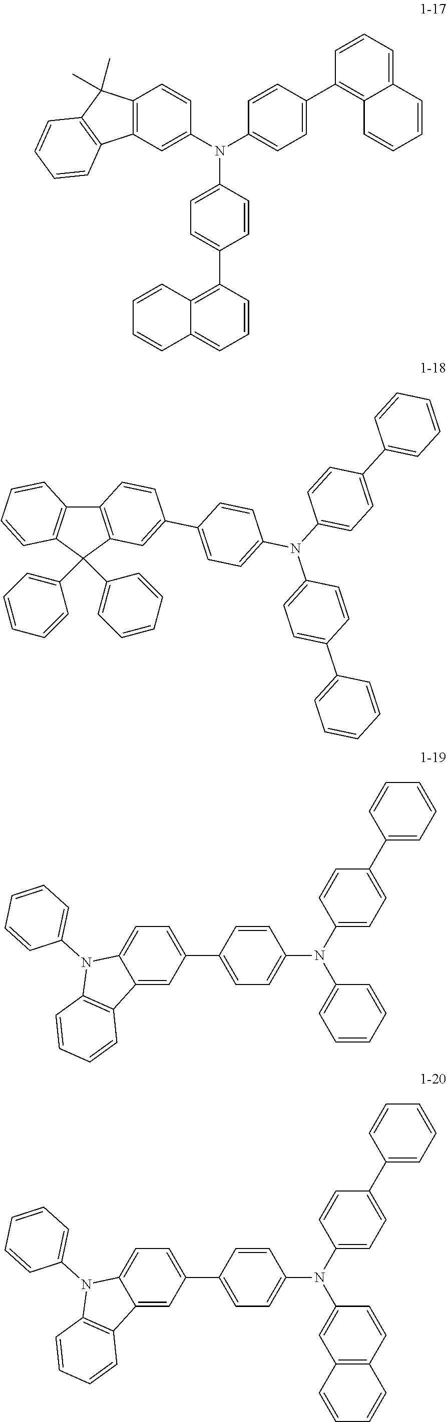 [SMILES: CC1(C)c2ccccc2-c2cc(N(c3ccc(-c4cccc5ccccc45)cc3)c3ccc(-c4cccc5ccccc45)cc3)ccc21 ; c1ccc(-c2ccc(N(c3ccc(-c4ccccc4)cc3)c3ccc(-c4ccc5c(c4)C(c4ccccc4)(c4ccccc4)c4ccccc4-5)cc3)cc2)cc1 ; c1ccc(-c2ccc(N(c3ccccc3)c3ccc(-c4ccc5c(c4)c4ccccc4n5-c4ccccc4)cc3)cc2)cc1 ; c1ccc(-c2ccc(N(c3ccc(-c4ccc5c(c4)c4ccccc4n5-c4ccccc4)cc3)c3ccc4ccccc4c3)cc2)cc1]

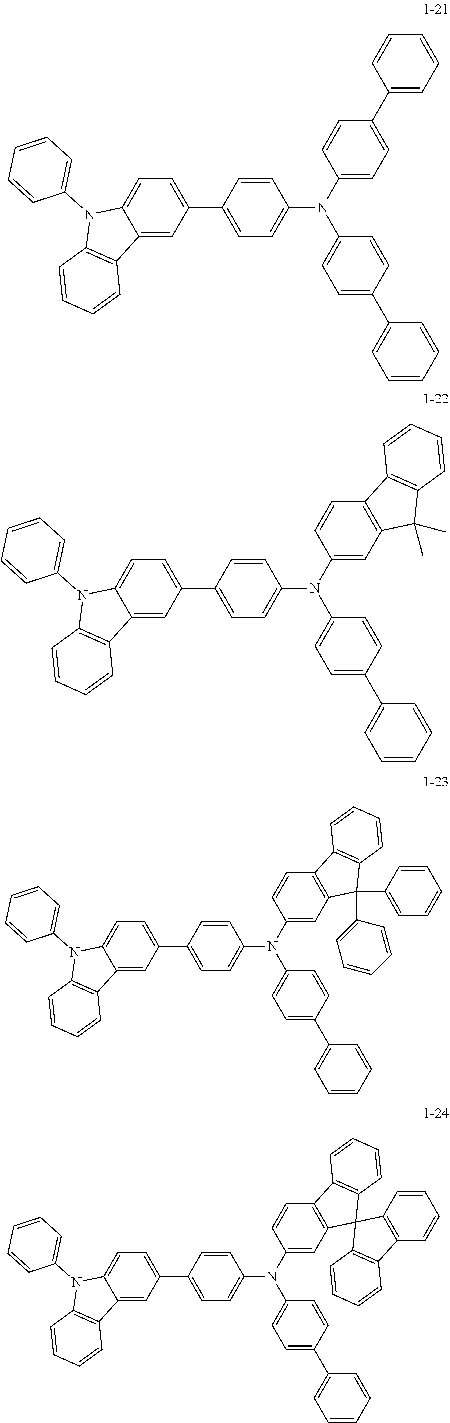 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

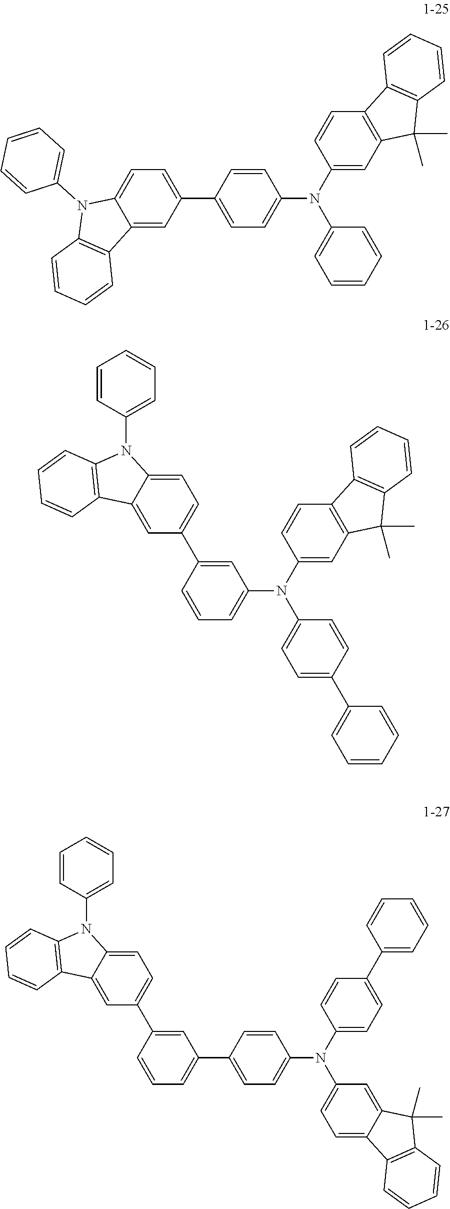 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccccc4)cc3)c3cccc(-c4ccc5c(c4)c4ccccc4n5-c4ccccc4)c3)cc21 ; CC1(C)c2ccccc2-c2ccc(N(c3ccc(-c4ccccc4)cc3)c3ccc(-c4cccc(-c5ccc6c(c5)c5ccccc5n6-c5ccccc5)c4)cc3)cc21]

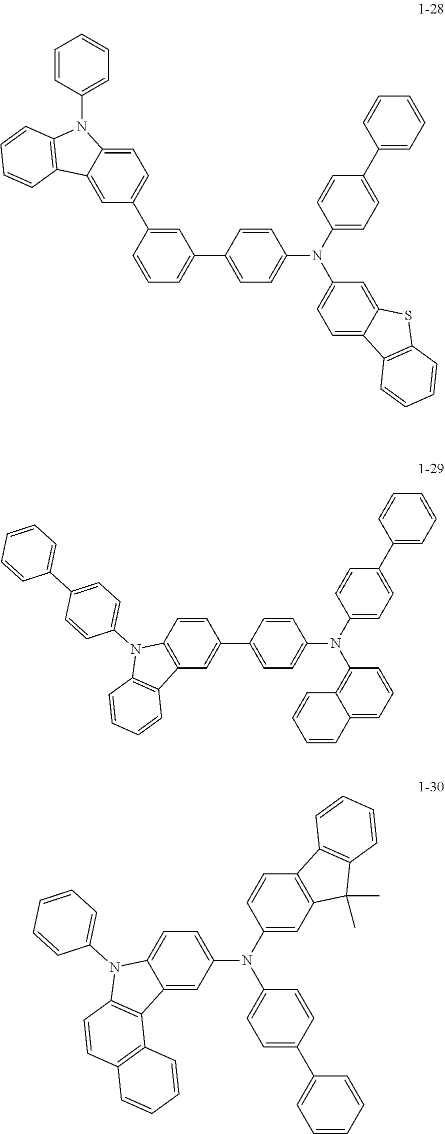 [SMILES: c1ccc(-c2ccc(N(c3ccc(-c4cccc(-c5ccc6c(c5)c5ccccc5n6-c5ccccc5)c4)cc3)c3ccc4c(c3)sc3ccccc34)cc2)cc1 ; c1ccc(-c2ccc(N(c3ccc(-c4ccc5c(c4)c4ccccc4n5-c4ccc(-c5ccccc5)cc4)cc3)c3cccc4ccccc34)cc2)cc1 ; CC1(C)c2ccccc2-c2ccc(N(c3ccc(-c4ccccc4)cc3)c3ccc4c(c3)c3c5ccccc5ccc3n4-c3ccccc3)cc21]

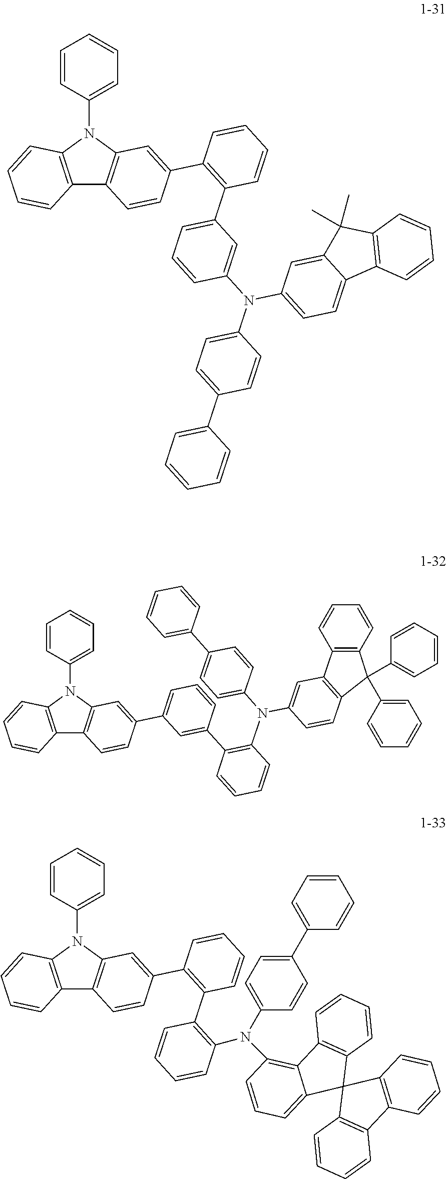 [SMILES: CC1(C)c2ccccc2-c2ccc(N(c3ccc(-c4ccccc4)cc3)c3cccc(-c4ccccc4-c4ccc5c6ccccc6n(-c6ccccc6)c5c4)c3)cc21 ; c1ccc(-c2ccc(N(c3ccc4c(c3)-c3ccccc3C4(c3ccccc3)c3ccccc3)c3ccccc3-c3cccc(-c4ccc5c6ccccc6n(-c6ccccc6)c5c4)c3)cc2)cc1 ; c1ccc(-c2ccc(N(c3ccccc3-c3ccccc3-c3ccc4c5ccccc5n(-c5ccccc5)c4c3)c3cccc4c3-c3ccccc3C43c4ccccc4-c4ccccc43)cc2)cc1]

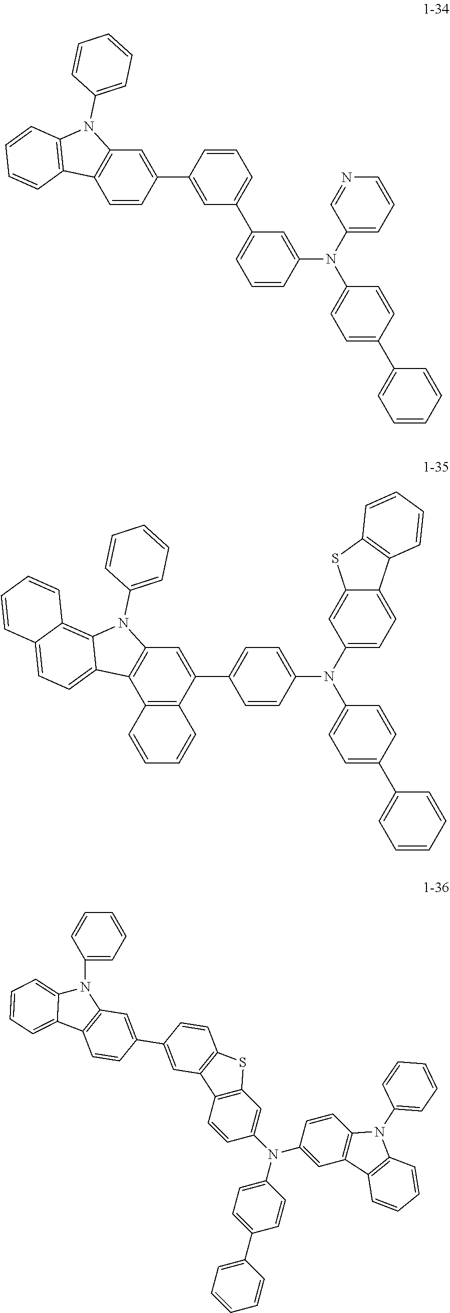 [SMILES: c1ccc(-c2ccc(N(c3cccnc3)c3cccc(-c4cccc(-c5ccc6c7ccccc7n(-c7ccccc7)c6c5)c4)c3)cc2)cc1 ; c1ccc(-c2ccc(N(c3ccc(-c4cc5c(c6ccccc46)c4ccc6ccccc6c4n5-c4ccccc4)cc3)c3ccc4c(c3)sc3ccccc34)cc2)cc1 ; c1ccc(-c2ccc(N(c3ccc4c(c3)sc3ccc(-c5ccc6c7ccccc7n(-c7ccccc7)c6c5)cc34)c3ccc4c(c3)c3ccccc3n4-c3ccccc3)cc2)cc1]

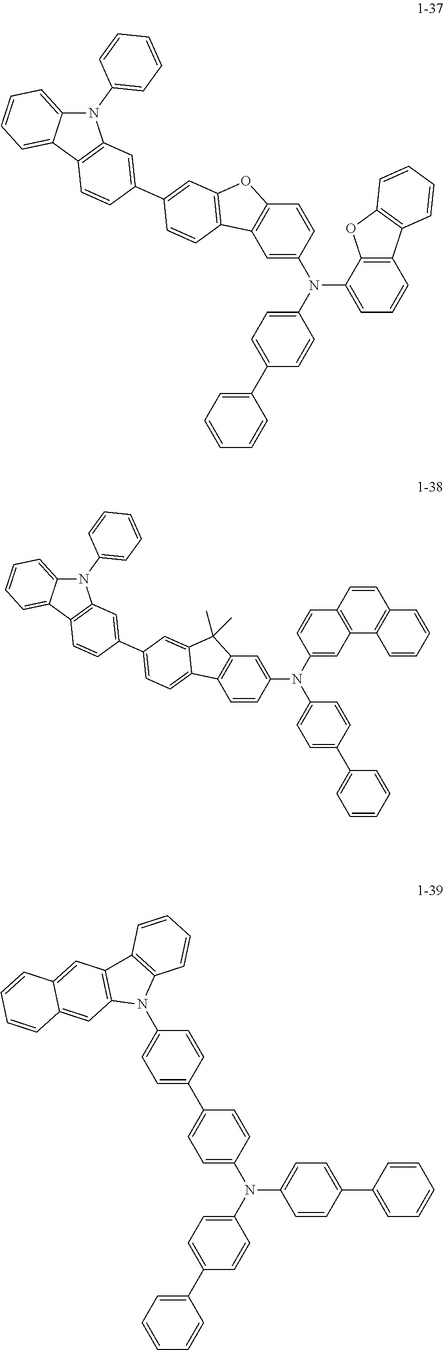 [SMILES: c1ccc(-c2ccc(N(c3ccc4oc5cc(-c6ccc7c8ccccc8n(-c8ccccc8)c7c6)ccc5c4c3)c3cccc4c3oc3ccccc34)cc2)cc1 ; CC1(C)c2cc(-c3ccc4c5ccccc5n(-c5ccccc5)c4c3)ccc2-c2ccc(N(c3ccc(-c4ccccc4)cc3)c3ccc4ccc5ccccc5c4c3)cc21 ; c1ccc(-c2ccc(N(c3ccc(-c4ccccc4)cc3)c3ccc(-c4ccc(-n5c6ccccc6c6cc7ccccc7cc65)cc4)cc3)cc2)cc1]

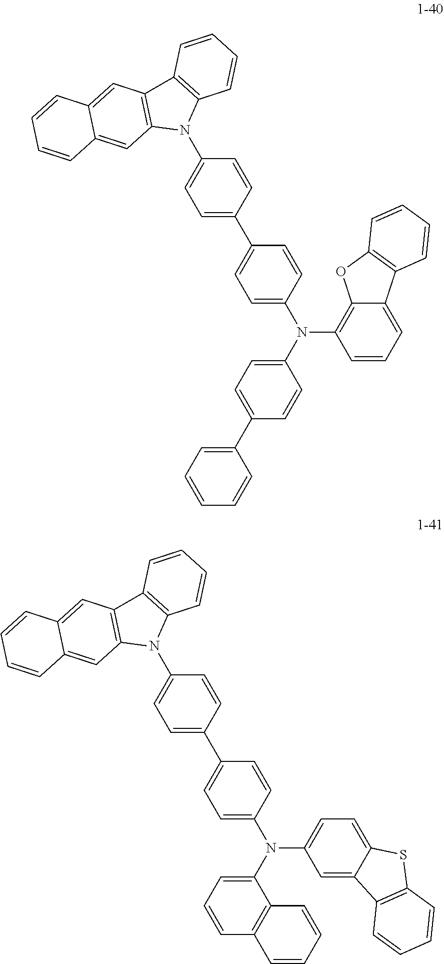 [SMILES: c1ccc(-c2ccc(N(c3ccc(-c4ccc(-n5c6ccccc6c6cc7ccccc7cc65)cc4)cc3)c3cccc4c3oc3ccccc34)cc2)cc1 ; c1ccc2cc3c(cc2c1)c1ccccc1n3-c1ccc(-c2ccc(N(c3ccc4sc5ccccc5c4c3)c3cccc4ccccc34)cc2)cc1]

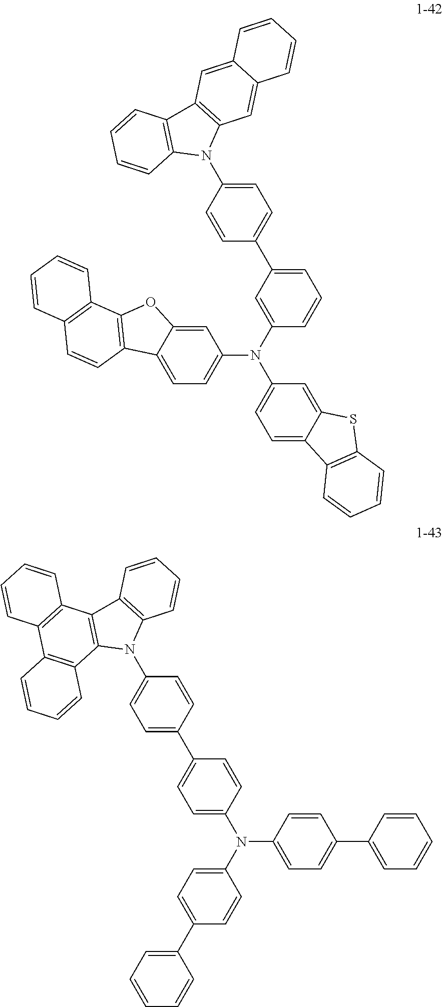 [SMILES: c1cc(-c2ccc(-n3c4ccccc4c4cc5ccccc5cc43)cc2)cc(N(c2ccc3c(c2)oc2c4ccccc4ccc32)c2ccc3c(c2)sc2ccccc23)c1 ; c1ccc(-c2ccc(N(c3ccc(-c4ccccc4)cc3)c3ccc(-c4ccc(-n5c6ccccc6c6c7ccccc7c7ccccc7c65)cc4)cc3)cc2)cc1]

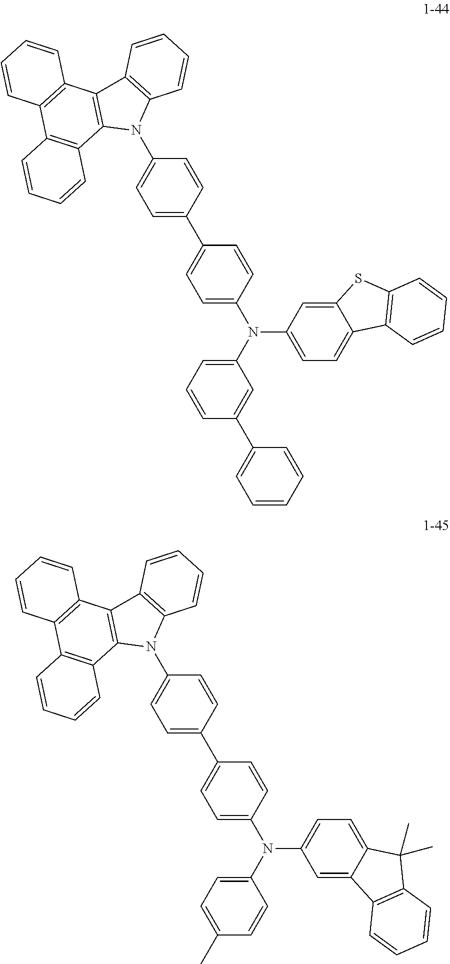 [SMILES: c1ccc(-c2cccc(N(c3ccc(-c4ccc(-n5c6ccccc6c6c7ccccc7c7ccccc7c65)cc4)cc3)c3ccc4c(c3)sc3ccccc34)c2)cc1 ; Cc1ccc(N(c2ccc(-c3ccc(-n4c5ccccc5c5c6ccccc6c6ccccc6c54)cc3)cc2)c2ccc3c(c2)-c2ccccc2C3(C)C)cc1]

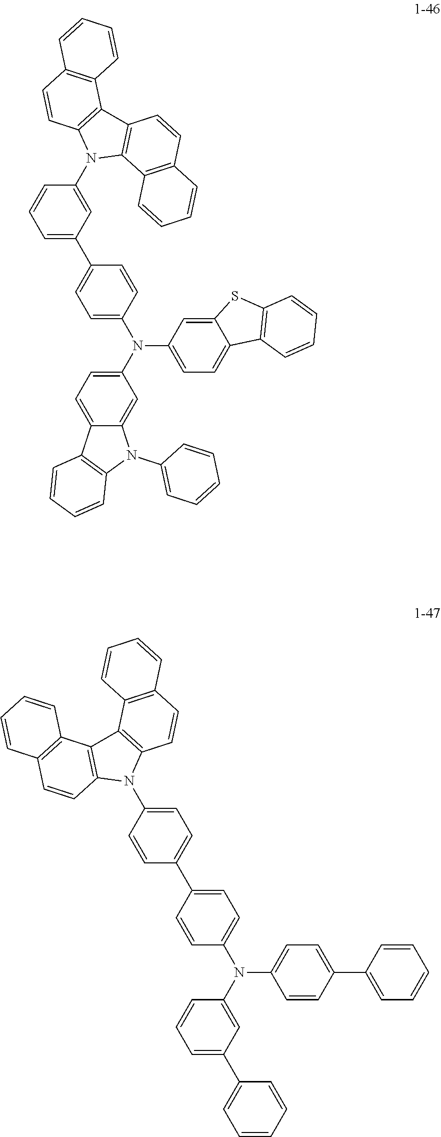 [SMILES: c1ccc(-n2c3ccccc3c3ccc(N(c4ccc(-c5cccc(-n6c7ccc8ccccc8c7c7ccc8ccccc8c76)c5)cc4)c4ccc5c(c4)sc4ccccc45)cc32)cc1 ; c1ccc(-c2ccc(N(c3ccc(-c4ccc(-n5c6ccc7ccccc7c6c6c7ccccc7ccc65)cc4)cc3)c3cccc(-c4ccccc4)c3)cc2)cc1]

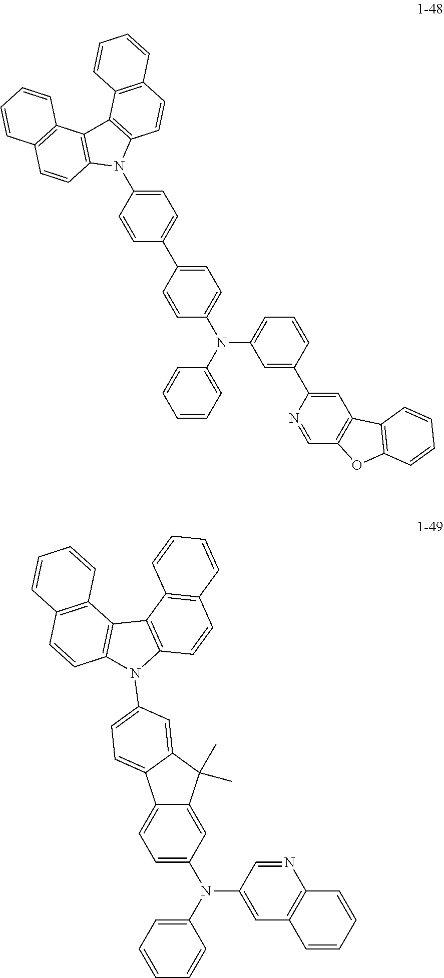 [SMILES: c1ccc(N(c2ccc(-c3ccc(-n4c5ccc6ccccc6c5c5c6ccccc6ccc54)cc3)cc2)c2cccc(-c3cc4c(cn3)oc3ccccc34)c2)cc1 ; CC1(C)c2cc(N(c3ccccc3)c3cnc4ccccc4c3)ccc2-c2ccc(-n3c4ccc5ccccc5c4c4c5ccccc5ccc43)cc21]

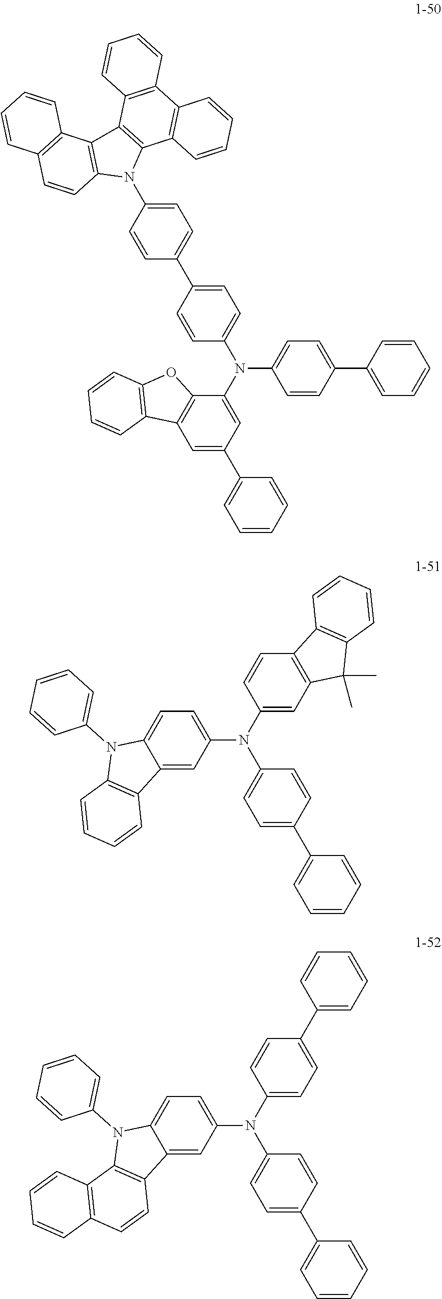

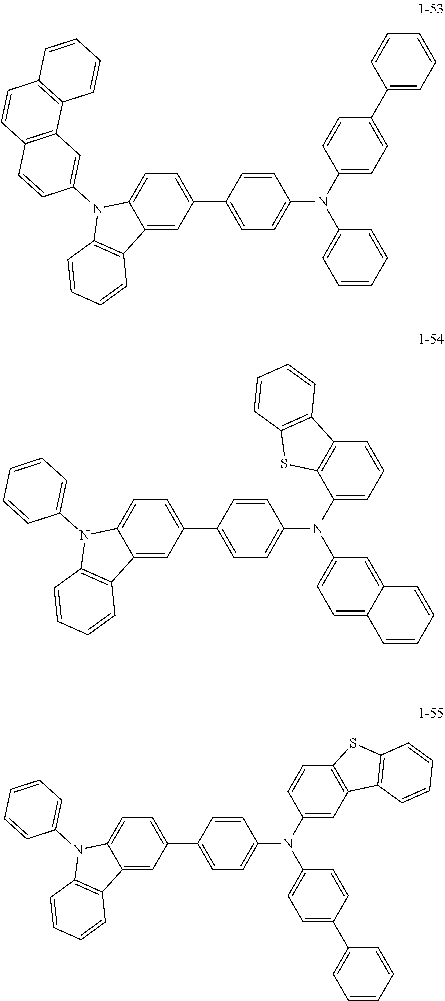 [SMILES: c1ccc(-c2ccc(N(c3ccccc3)c3ccc(-c4ccc5c(c4)c4ccccc4n5-c4ccc5ccc6ccccc6c5c4)cc3)cc2)cc1 ; c1ccc(-n2c3ccccc3c3cc(-c4ccc(N(c5ccc6ccccc6c5)c5cccc6c5sc5ccccc56)cc4)ccc32)cc1 ; c1ccc(-c2ccc(N(c3ccc(-c4ccc5c(c4)c4ccccc4n5-c4ccccc4)cc3)c3ccc4sc5ccccc5c4c3)cc2)cc1]

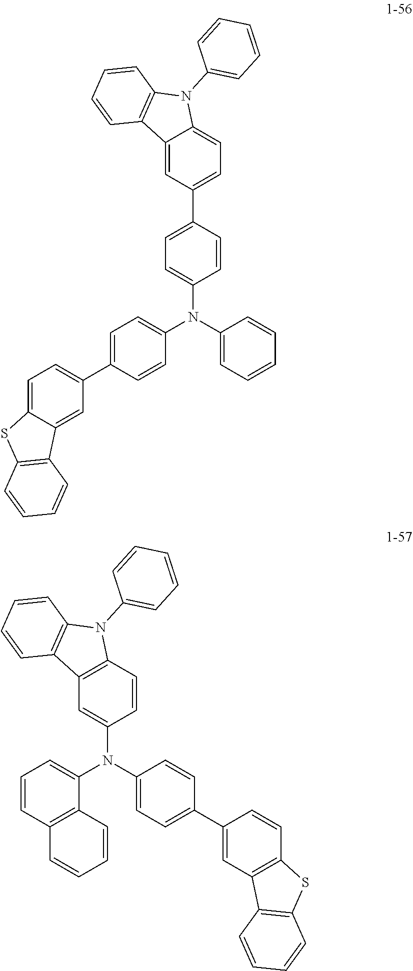 [SMILES: c1ccc(N(c2ccc(-c3ccc4sc5ccccc5c4c3)cc2)c2ccc(-c3ccc4c(c3)c3ccccc3n4-c3ccccc3)cc2)cc1 ; c1ccc(-n2c3ccccc3c3cc(N(c4ccc(-c5ccc6sc7ccccc7c6c5)cc4)c4cccc5ccccc45)ccc32)cc1]

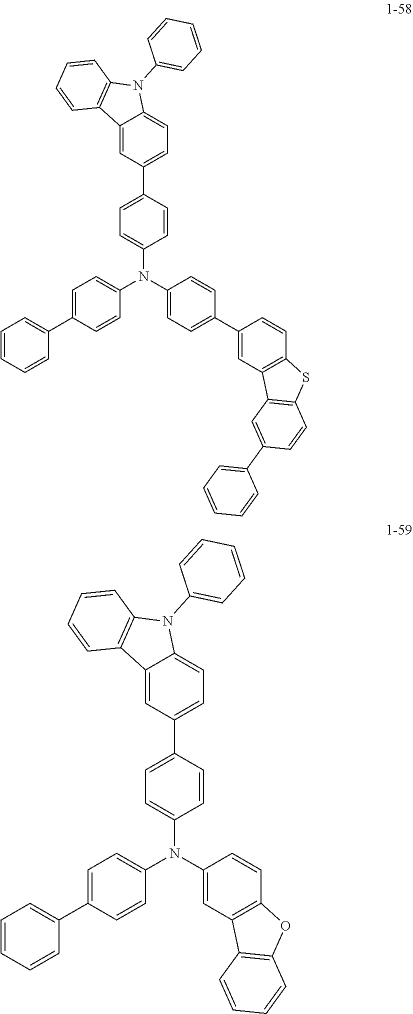

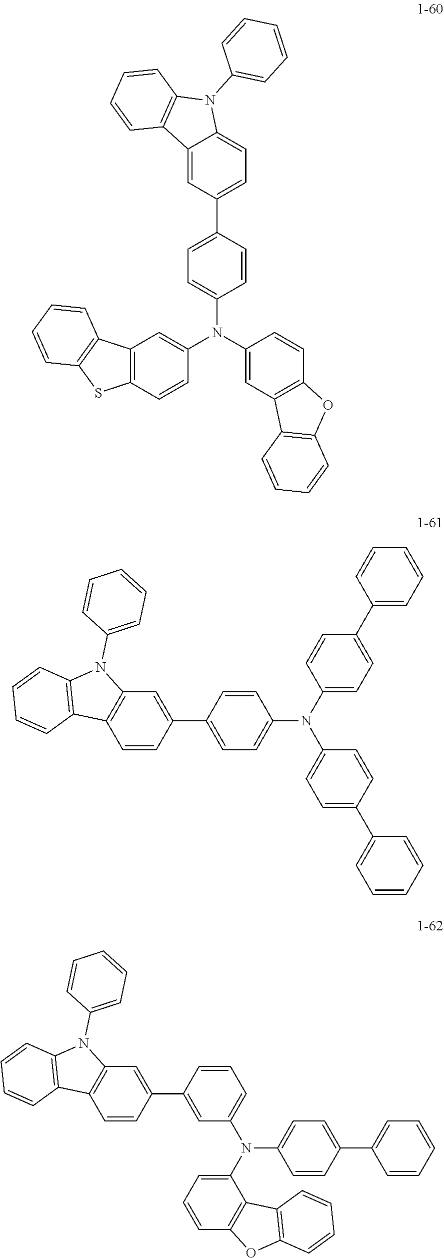 [SMILES: c1ccc(-n2c3ccccc3c3cc(-c4ccc(N(c5ccc6oc7ccccc7c6c5)c5ccc6sc7ccccc7c6c5)cc4)ccc32)cc1 ; c1ccc(-c2ccc(N(c3ccc(-c4ccccc4)cc3)c3ccc(-c4ccc5c6ccccc6n(-c6ccccc6)c5c4)cc3)cc2)cc1 ; c1ccc(-c2ccc(N(c3cccc(-c4ccc5c6ccccc6n(-c6ccccc6)c5c4)c3)c3cccc4oc5ccccc5c34)cc2)cc1]

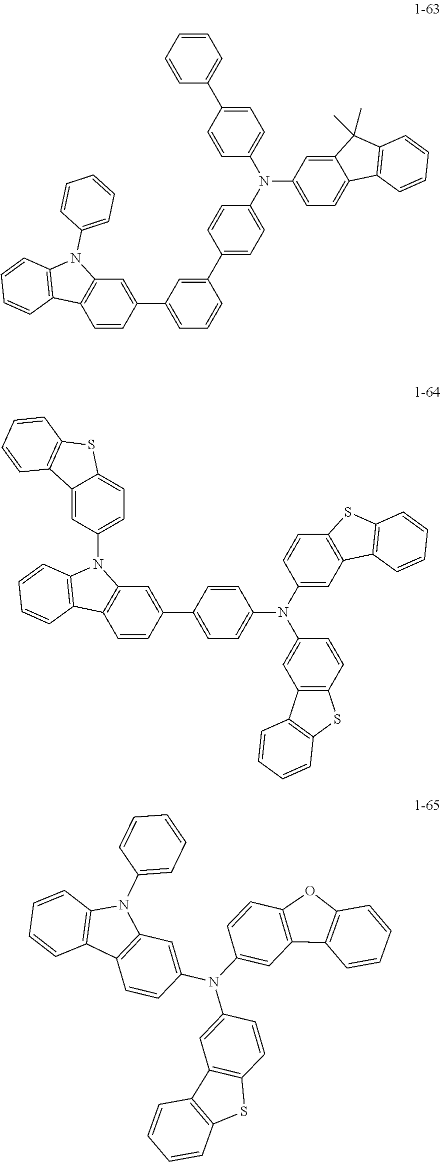 [SMILES: CC1(C)c2ccccc2-c2ccc(N(c3ccc(-c4ccccc4)cc3)c3ccc(-c4cccc(-c5ccc6c7ccccc7n(-c7ccccc7)c6c5)c4)cc3)cc21 ; c1ccc2c(c1)sc1ccc(N(c3ccc(-c4ccc5c6ccccc6n(-c6ccc7sc8ccccc8c7c6)c5c4)cc3)c3ccc4sc5ccccc5c4c3)cc12 ; c1ccc(-n2c3ccccc3c3ccc(N(c4ccc5oc6ccccc6c5c4)c4ccc5sc6ccccc6c5c4)cc32)cc1]

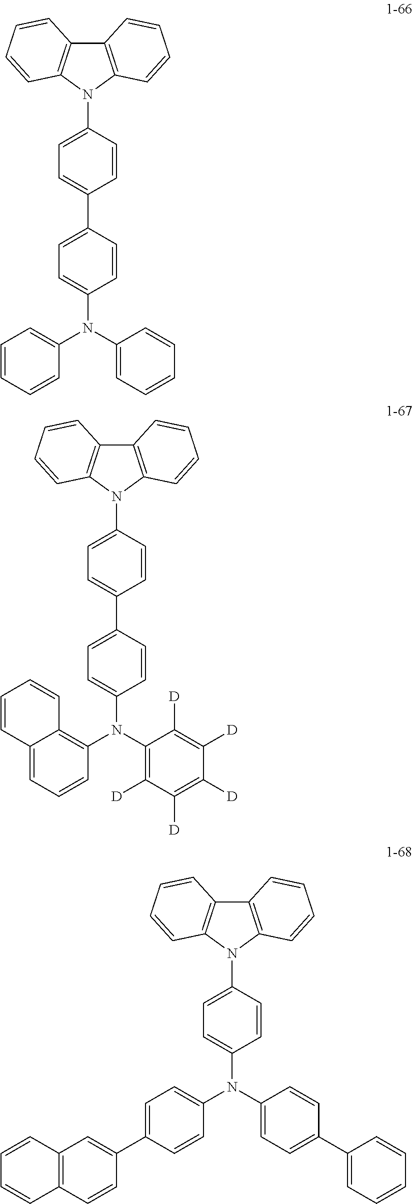

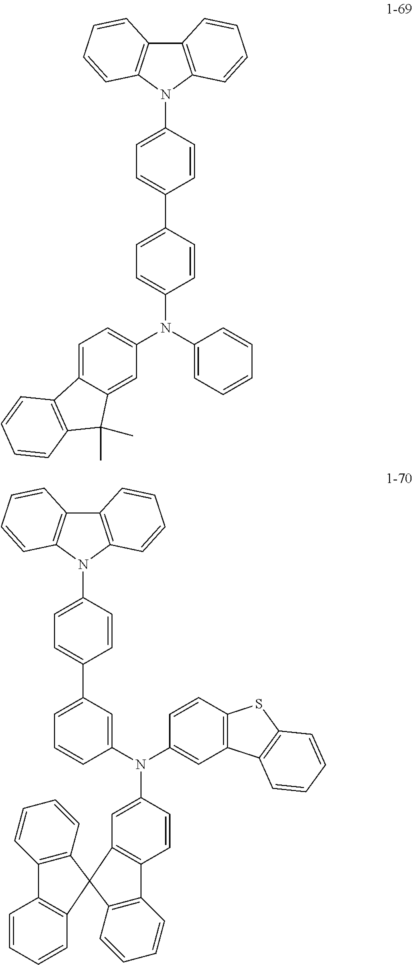

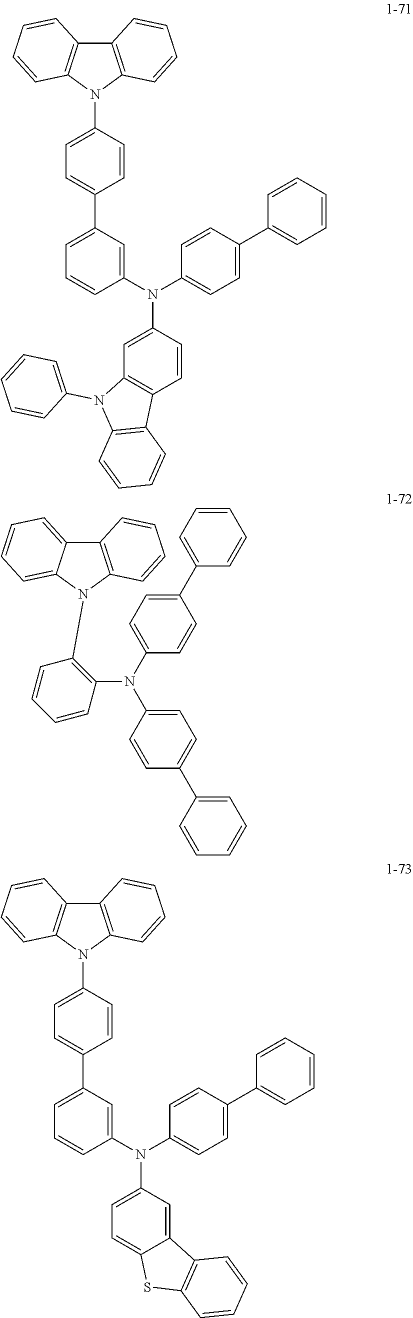

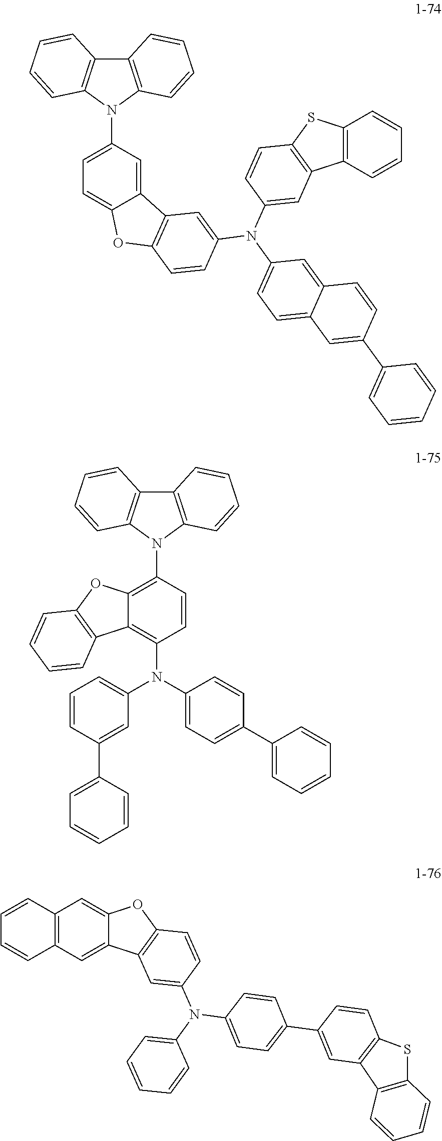 [SMILES: c1ccc(-c2ccc3cc(N(c4ccc5oc6ccc(-n7c8ccccc8c8ccccc87)cc6c5c4)c4ccc5sc6ccccc6c5c4)ccc3c2)cc1 ; c1ccc(-c2ccc(N(c3cccc(-c4ccccc4)c3)c3ccc(-n4c5ccccc5c5ccccc54)c4oc5ccccc5c34)cc2)cc1 ; c1ccc(N(c2ccc(-c3ccc4sc5ccccc5c4c3)cc2)c2ccc3oc4cc5ccccc5cc4c3c2)cc1]

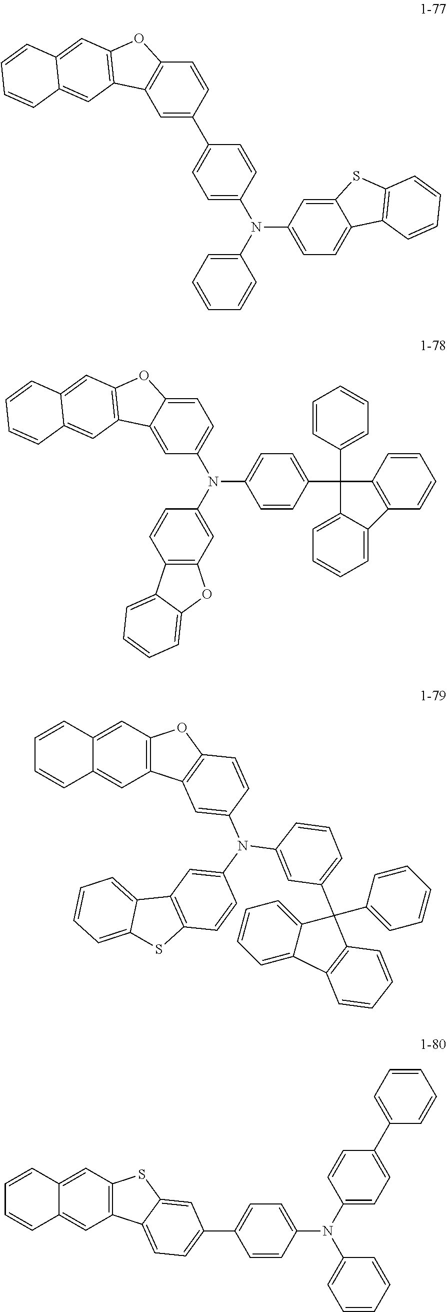 [SMILES: c1ccc(N(c2ccc(-c3ccc4oc5cc6ccccc6cc5c4c3)cc2)c2ccc3c(c2)sc2ccccc23)cc1 ; c1ccc(C2(c3ccc(N(c4ccc5c(c4)oc4ccccc45)c4ccc5oc6cc7ccccc7cc6c5c4)cc3)c3ccccc3-c3ccccc32)cc1 ; c1ccc(C2(c3cccc(N(c4ccc5oc6cc7ccccc7cc6c5c4)c4ccc5sc6ccccc6c5c4)c3)c3ccccc3-c3ccccc32)cc1 ; c1ccc(-c2ccc(N(c3ccccc3)c3ccc(-c4ccc5c(c4)sc4cc6ccccc6cc45)cc3)cc2)cc1]

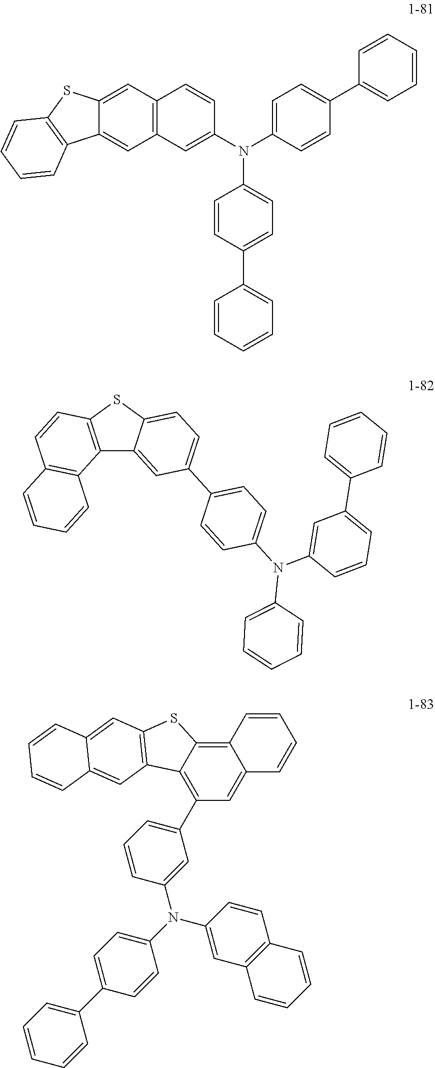

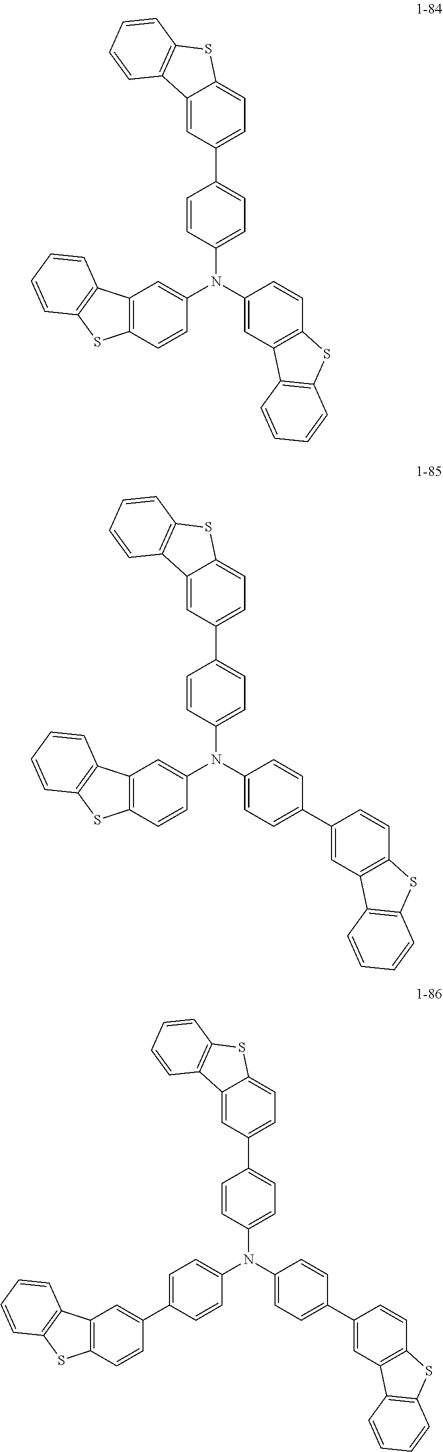 [SMILES: c1ccc2c(c1)sc1ccc(-c3ccc(N(c4ccc5sc6ccccc6c5c4)c4ccc5sc6ccccc6c5c4)cc3)cc12 ; c1ccc2c(c1)sc1ccc(-c3ccc(N(c4ccc(-c5ccc6sc7ccccc7c6c5)cc4)c4ccc5sc6ccccc6c5c4)cc3)cc12 ; c1ccc2c(c1)sc1ccc(-c3ccc(N(c4ccc(-c5ccc6sc7ccccc7c6c5)cc4)c4ccc(-c5ccc6sc7ccccc7c6c5)cc4)cc3)cc12]

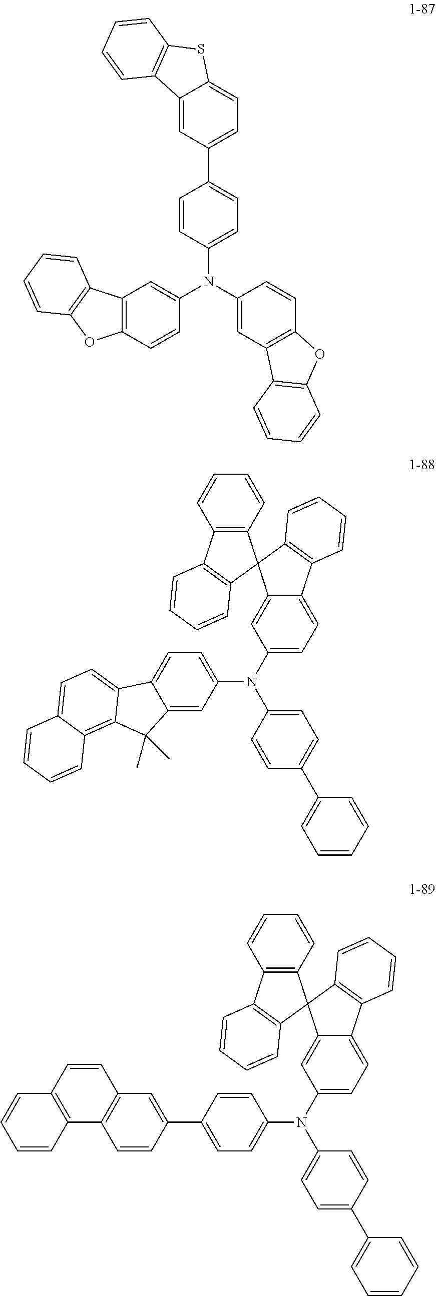

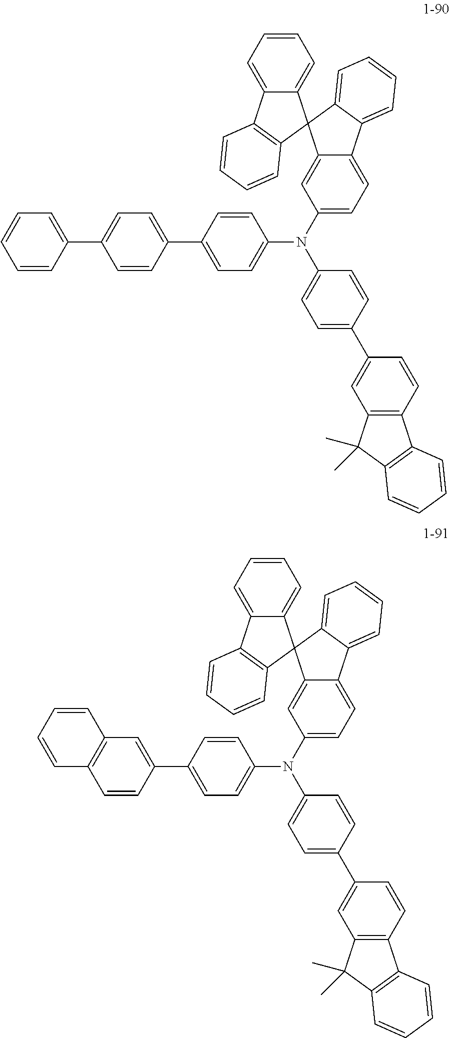 [SMILES: CC1(C)c2ccccc2-c2ccc(-c3ccc(N(c4ccc(-c5ccc(-c6ccccc6)cc5)cc4)c4ccc5c(c4)C4(c6ccccc6-c6ccccc64)c4ccccc4-5)cc3)cc21 ; CC1(C)c2ccccc2-c2ccc(-c3ccc(N(c4ccc(-c5ccc6ccccc6c5)cc4)c4ccc5c(c4)C4(c6ccccc6-c6ccccc64)c4ccccc4-5)cc3)cc21]

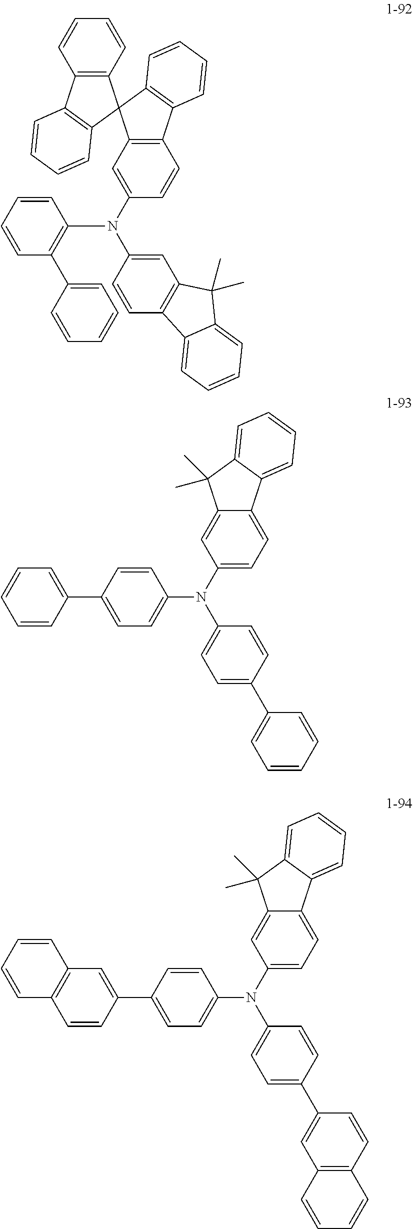

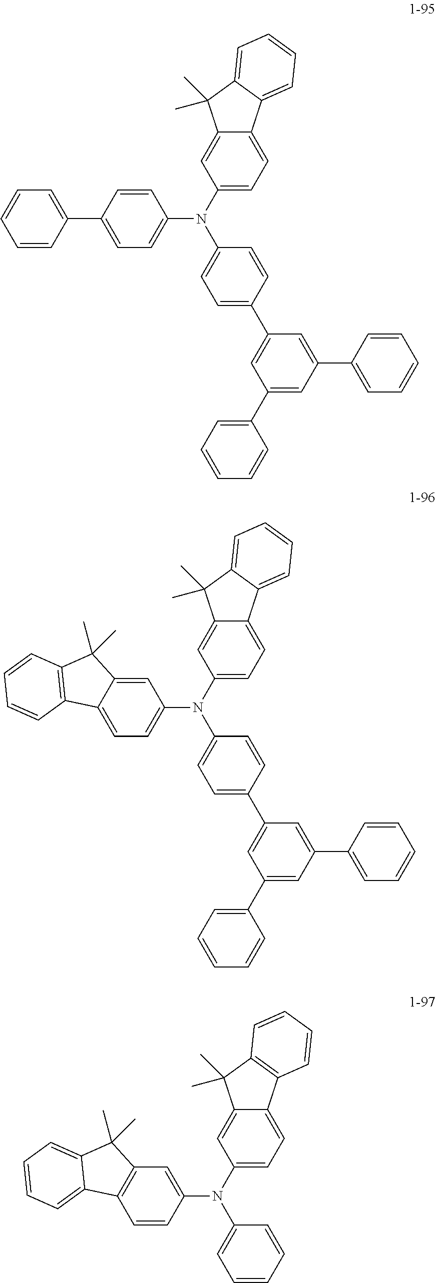

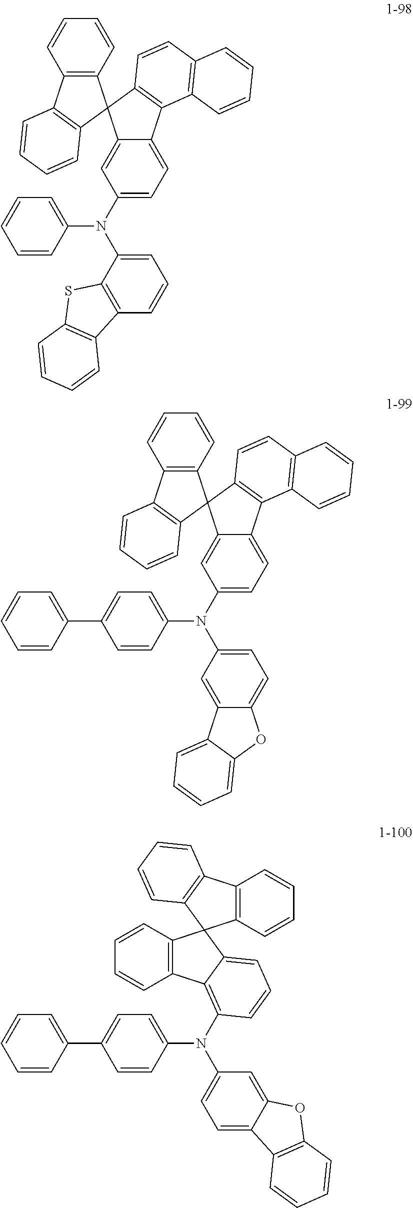

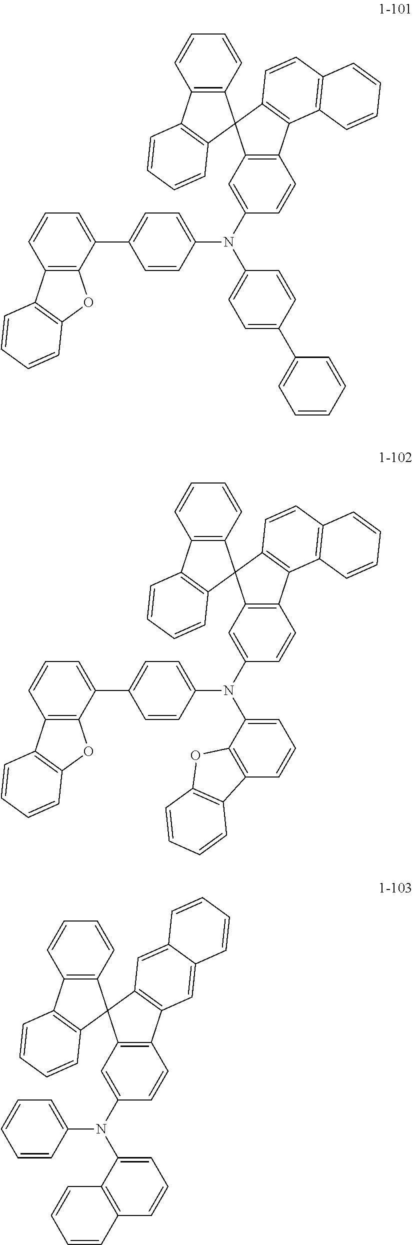

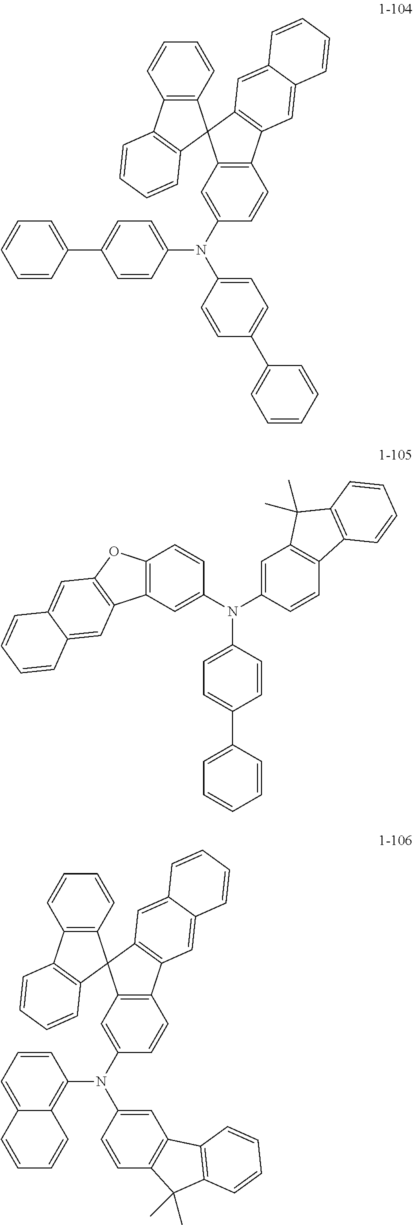 [SMILES: c1ccc(-c2ccc(N(c3ccc(-c4ccccc4)cc3)c3ccc4c(c3)C3(c5ccccc5-c5ccccc53)c3cc5ccccc5cc3-4)cc2)cc1 ; CC1(C)c2ccccc2-c2ccc(N(c3ccc(-c4ccccc4)cc3)c3ccc4oc5cc6ccccc6cc5c4c3)cc21 ; CC1(C)c2ccccc2-c2cc(N(c3ccc4c(c3)C3(c5ccccc5-c5ccccc53)c3cc5ccccc5cc3-4)c3cccc4ccccc34)ccc21]

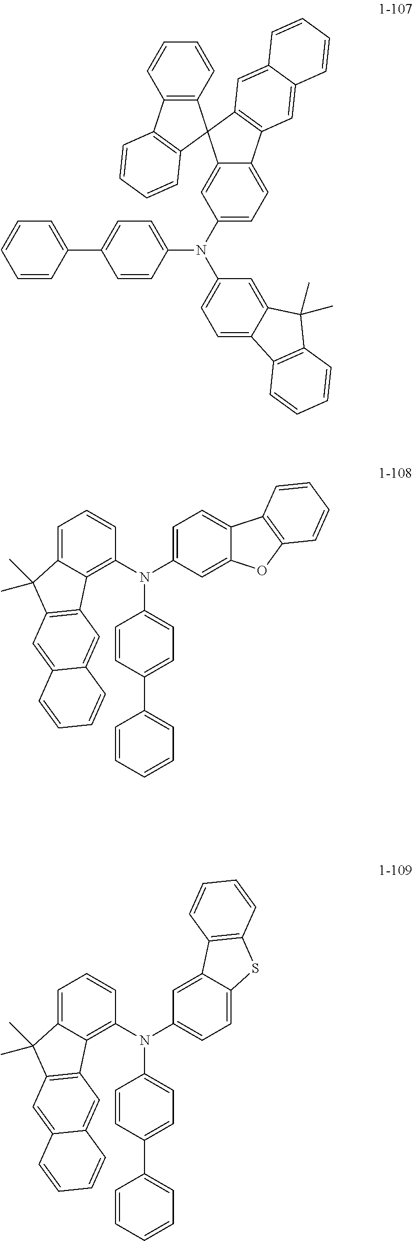

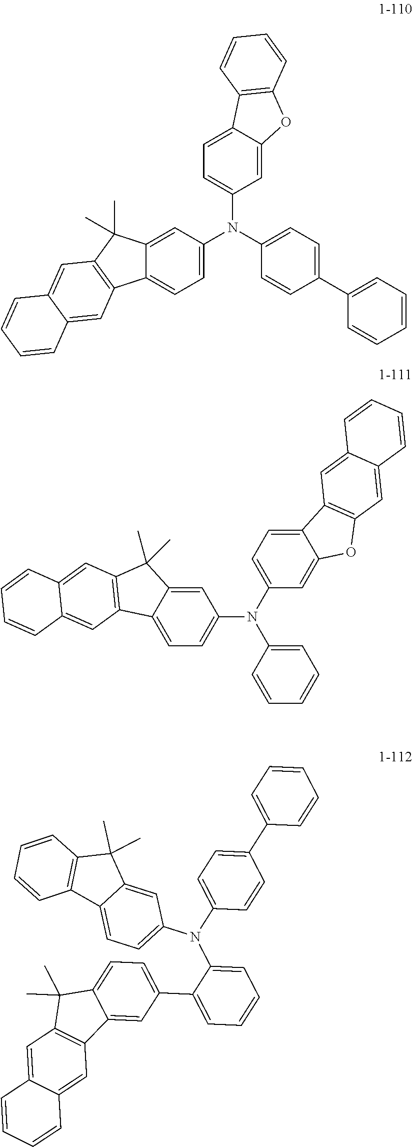 [SMILES: CC1(C)c2cc(N(c3ccc(-c4ccccc4)cc3)c3ccc4c(c3)oc3ccccc34)ccc2-c2cc3ccccc3cc21 ; CC1(C)c2cc(N(c3ccccc3)c3ccc4c(c3)oc3cc5ccccc5cc34)ccc2-c2cc3ccccc3cc21 ; CC1(C)c2ccccc2-c2ccc(N(c3ccc(-c4ccccc4)cc3)c3ccccc3-c3ccc4c(c3)-c3cc5ccccc5cc3C4(C)C)cc21]

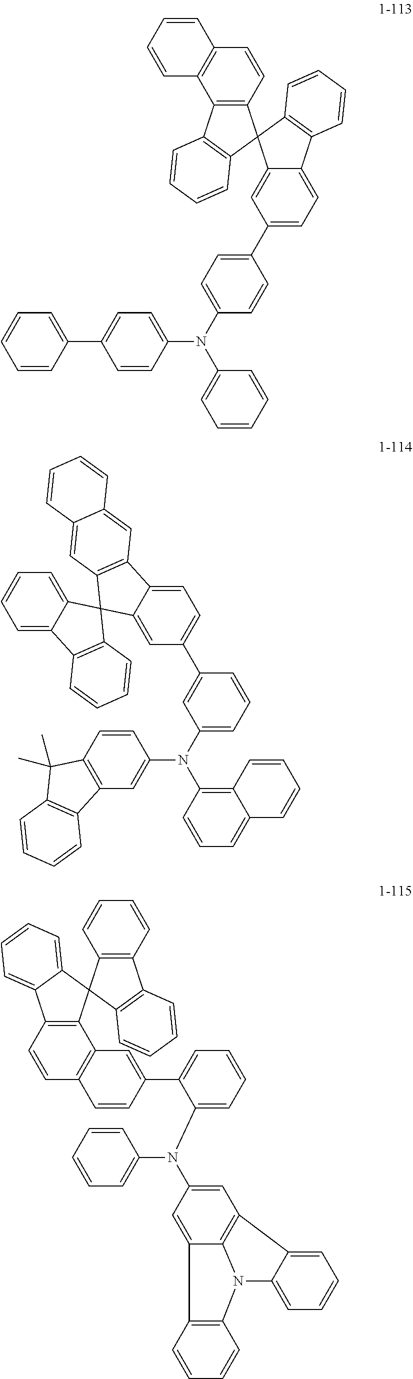 [SMILES: c1ccc(-c2ccc(N(c3ccccc3)c3ccc(-c4ccc5c(c4)C4(c6ccccc6-5)c5ccccc5-c5c4ccc4ccccc54)cc3)cc2)cc1 ; CC1(C)c2ccccc2-c2cc(N(c3cccc(-c4ccc5c(c4)C4(c6ccccc6-c6ccccc64)c4cc6ccccc6cc4-5)c3)c3cccc4ccccc34)ccc21 ; c1ccc(N(c2cc3c4ccccc4n4c5ccccc5c(c2)c34)c2ccccc2-c2ccc3ccc4c(c3c2)C2(c3ccccc3-c3ccccc32)c2ccccc2-4)cc1]

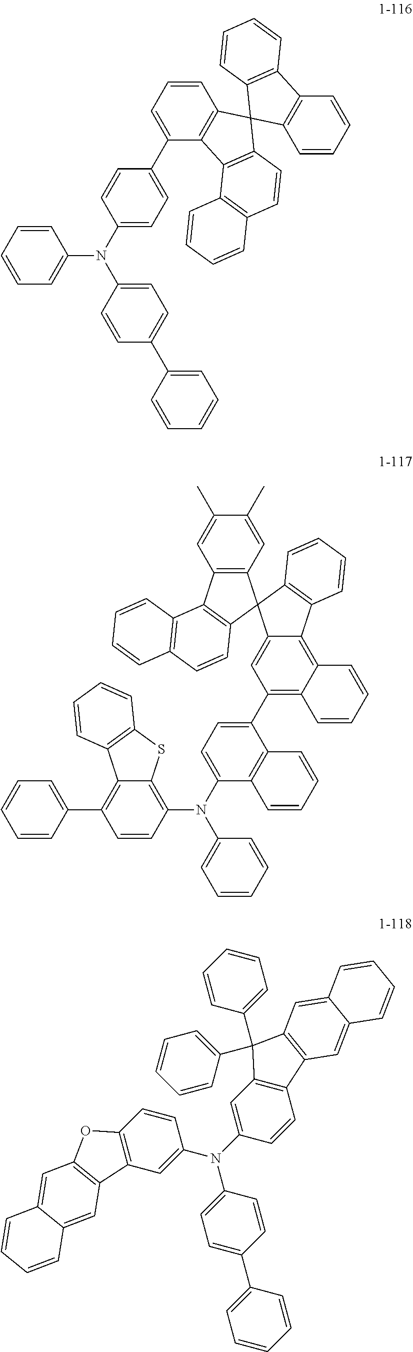 [SMILES: c1ccc(-c2ccc(N(c3ccccc3)c3ccc(-c4cccc5c4-c4c(ccc6ccccc46)C54c5ccccc5-c5ccccc54)cc3)cc2)cc1 ; Cc1cc2c(cc1C)C1(c3ccccc3-c3c1cc(-c1ccc(N(c4ccccc4)c4ccc(-c5ccccc5)c5c4sc4ccccc45)c4ccccc14)c1ccccc31)c1ccc3ccccc3c1-2 ; c1ccc(-c2ccc(N(c3ccc4c(c3)C(c3ccccc3)(c3ccccc3)c3cc5ccccc5cc3-4)c3ccc4oc5cc6ccccc6cc5c4c3)cc2)cc1]

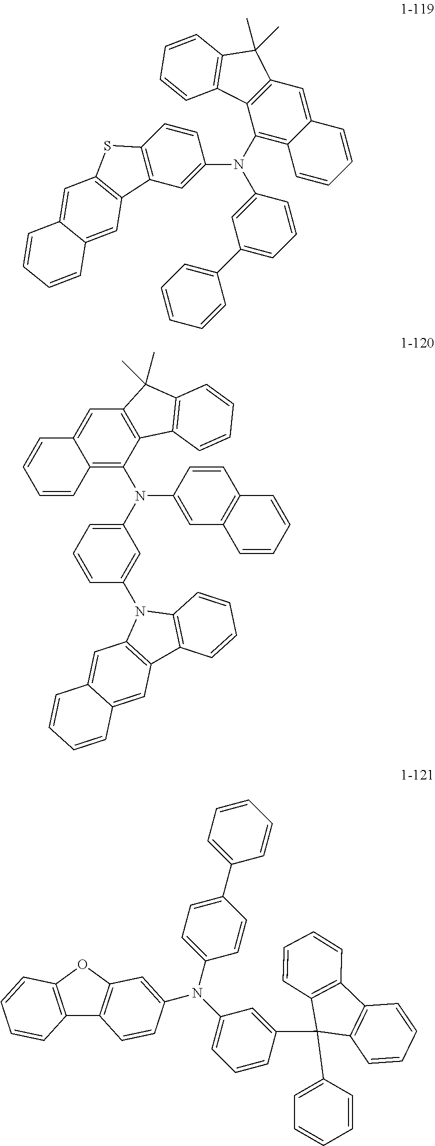

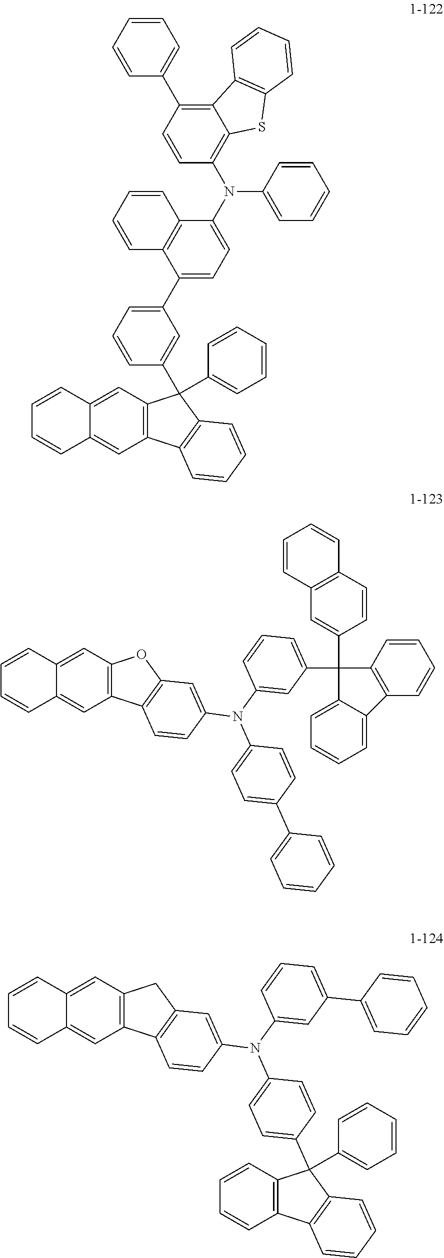 [SMILES: c1ccc(-c2ccc(N(c3ccccc3)c3ccc(-c4cccc(C5(c6ccccc6)c6ccccc6-c6cc7ccccc7cc65)c4)c4ccccc34)c3sc4ccccc4c23)cc1 ; c1ccc(-c2ccc(N(c3cccc(C4(c5ccc6ccccc6c5)c5ccccc5-c5ccccc54)c3)c3ccc4c(c3)oc3cc5ccccc5cc34)cc2)cc1 ; c1ccc(-c2cccc(N(c3ccc(C4(c5ccccc5)c5ccccc5-c5ccccc54)cc3)c3ccc4c(c3)Cc3cc5ccccc5cc3-4)c2)cc1]

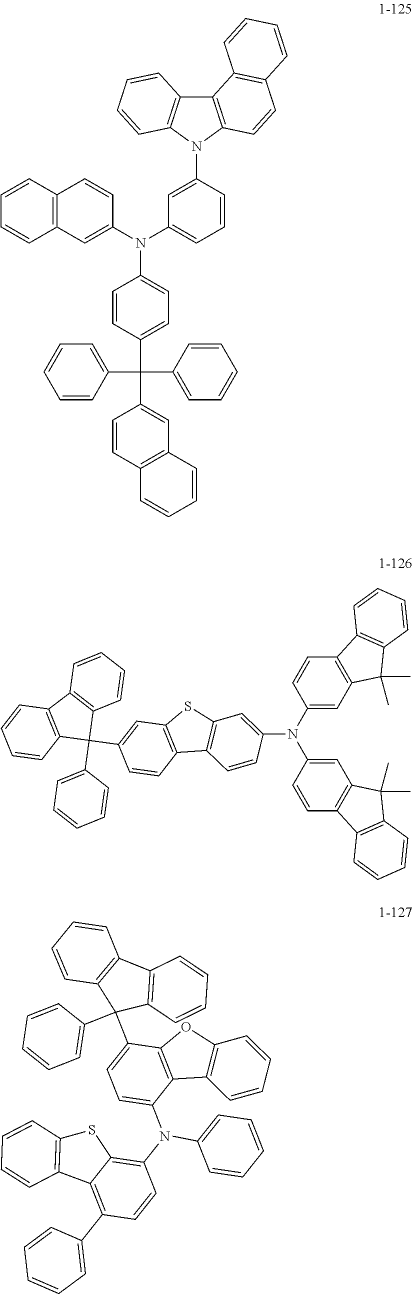 [SMILES: c1ccc(C(c2ccccc2)(c2ccc(N(c3cccc(-n4c5ccccc5c5c6ccccc6ccc54)c3)c3ccc4ccccc4c3)cc2)c2ccc3ccccc3c2)cc1 ; CC1(C)c2ccccc2-c2ccc(N(c3ccc4c(c3)C(C)(C)c3ccccc3-4)c3ccc4c(c3)sc3cc(C5(c6ccccc6)c6ccccc6-c6ccccc65)ccc34)cc21 ; c1ccc(-c2ccc(N(c3ccccc3)c3ccc(C4(c5ccccc5)c5ccccc5-c5ccccc54)c4oc5ccccc5c34)c3sc4ccccc4c23)cc1]

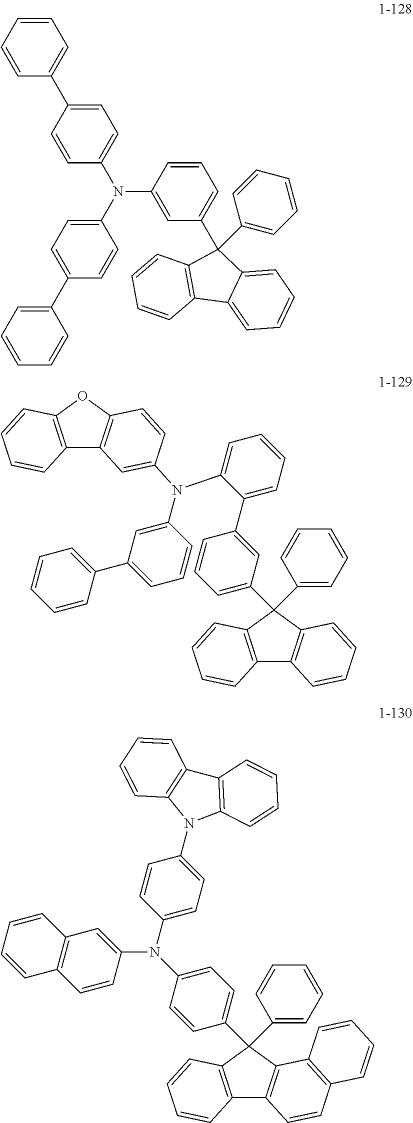

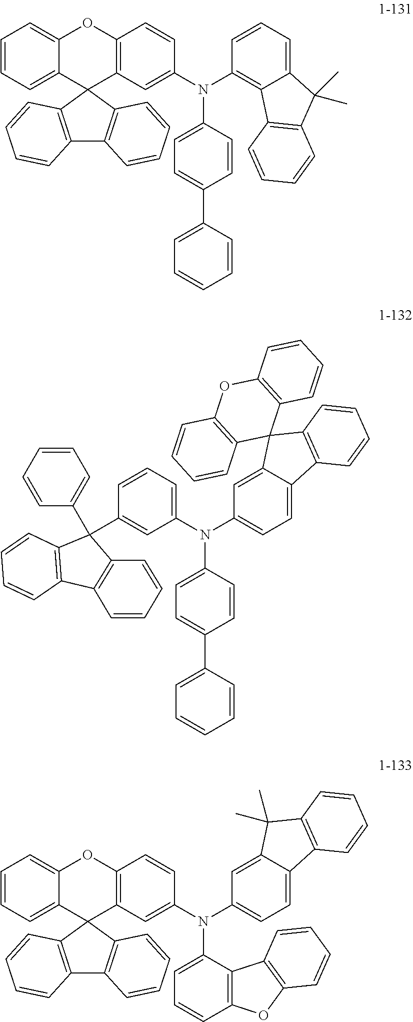 [SMILES: CC1(C)c2ccccc2-c2c(N(c3ccc(-c4ccccc4)cc3)c3ccc4c(c3)C3(c5ccccc5O4)c4ccccc4-c4ccccc43)cccc21 ; c1ccc(-c2ccc(N(c3cccc(C4(c5ccccc5)c5ccccc5-c5ccccc54)c3)c3ccc4c(c3)C3(c5ccccc5Oc5ccccc53)c3ccccc3-4)cc2)cc1 ; CC1(C)c2ccccc2-c2ccc(N(c3ccc4c(c3)C3(c5ccccc5O4)c4ccccc4-c4ccccc43)c3cccc4oc5ccccc5c34)cc21]

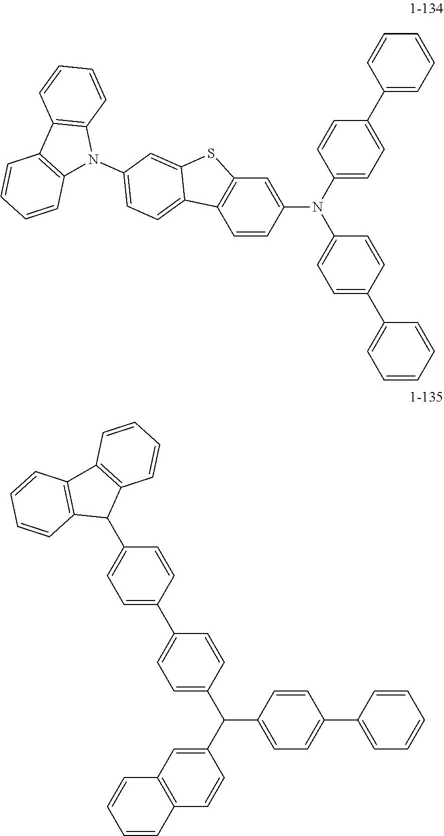

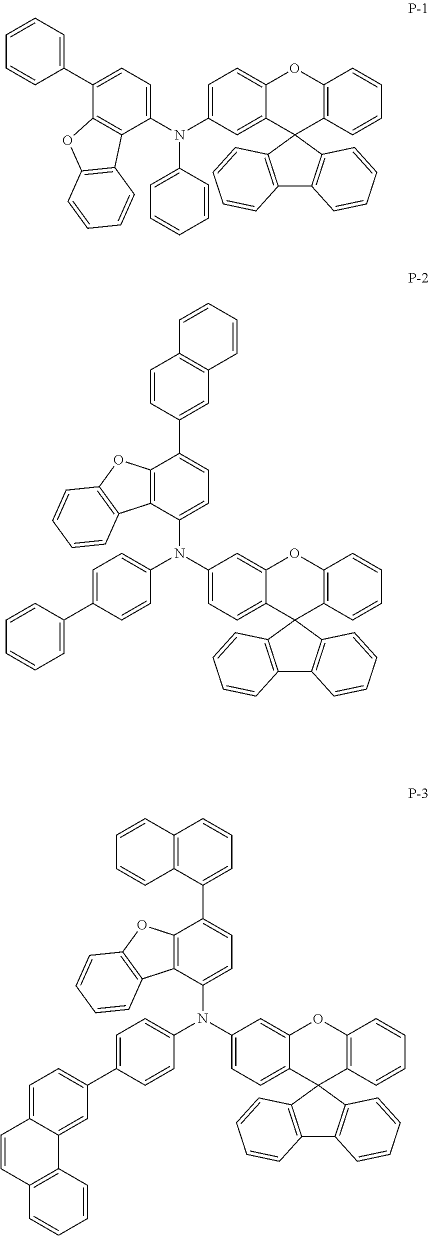 [SMILES: c1ccc(-c2ccc(N(c3ccccc3)c3ccc4c(c3)C3(c5ccccc5O4)c4ccccc4-c4ccccc43)c3c2oc2ccccc23)cc1 ; c1ccc(-c2ccc(N(c3ccc4c(c3)Oc3ccccc3C43c4ccccc4-c4ccccc43)c3ccc(-c4ccc5ccccc5c4)c4oc5ccccc5c34)cc2)cc1 ; c1ccc2c(c1)Oc1cc(N(c3ccc(-c4ccc5ccc6ccccc6c5c4)cc3)c3ccc(-c4cccc5ccccc45)c4oc5ccccc5c34)ccc1C21c2ccccc2-c2ccccc21]

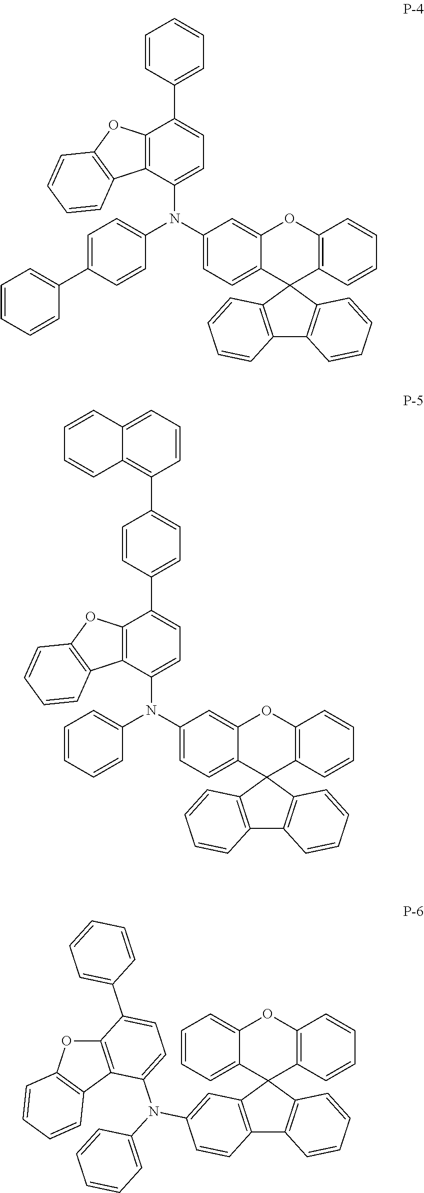 [SMILES: c1ccc(-c2ccc(N(c3ccc4c(c3)Oc3ccccc3C43c4ccccc4-c4ccccc43)c3ccc(-c4ccccc4)c4oc5ccccc5c34)cc2)cc1 ; c1ccc(N(c2ccc3c(c2)Oc2ccccc2C32c3ccccc3-c3ccccc32)c2ccc(-c3ccc(-c4cccc5ccccc45)cc3)c3oc4ccccc4c23)cc1 ; c1ccc(-c2ccc(N(c3ccccc3)c3ccc4c(c3)C3(c5ccccc5Oc5ccccc53)c3ccccc3-4)c3c2oc2ccccc23)cc1]

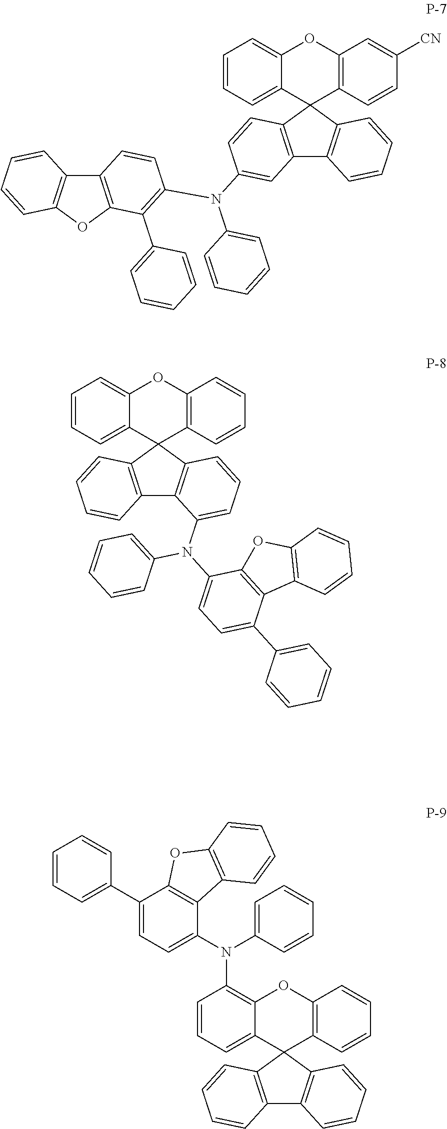 [SMILES: N#Cc1ccc2c(c1)Oc1ccccc1C21c2ccccc2-c2cc(N(c3ccccc3)c3ccc4c(oc5ccccc54)c3-c3ccccc3)ccc21 ; c1ccc(-c2ccc(N(c3ccccc3)c3cccc4c3-c3ccccc3C43c4ccccc4Oc4ccccc43)c3oc4ccccc4c23)cc1 ; c1ccc(-c2ccc(N(c3ccccc3)c3cccc4c3Oc3ccccc3C43c4ccccc4-c4ccccc43)c3c2oc2ccccc23)cc1]

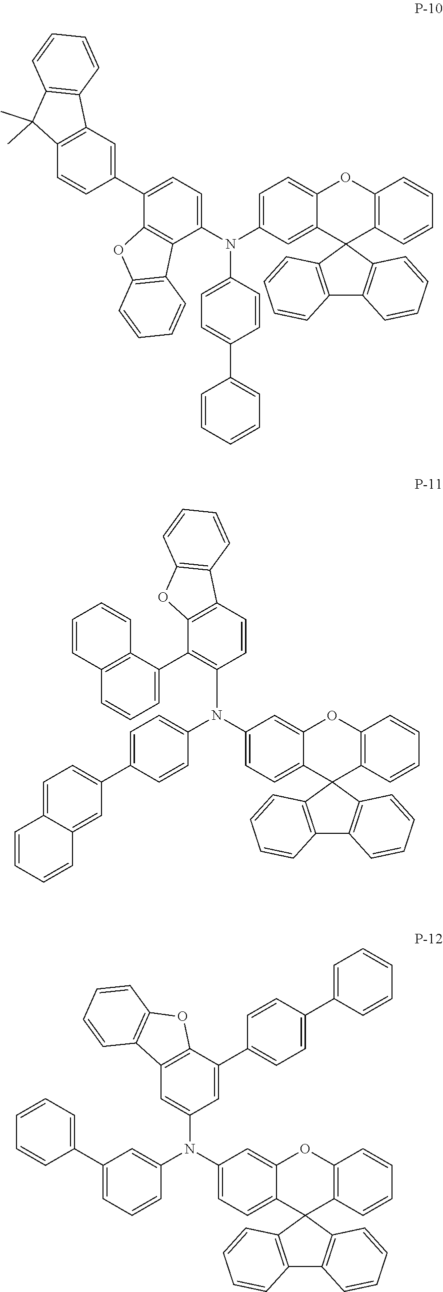 [SMILES: CC1(C)c2ccccc2-c2cc(-c3ccc(N(c4ccc(-c5ccccc5)cc4)c4ccc5c(c4)C4(c6ccccc6O5)c5ccccc5-c5ccccc54)c4c3oc3ccccc34)ccc21 ; c1ccc2c(c1)Oc1cc(N(c3ccc(-c4ccc5ccccc5c4)cc3)c3ccc4c(oc5ccccc54)c3-c3cccc4ccccc34)ccc1C21c2ccccc2-c2ccccc21 ; c1ccc(-c2ccc(-c3cc(N(c4cccc(-c5ccccc5)c4)c4ccc5c(c4)Oc4ccccc4C54c5ccccc5-c5ccccc54)cc4c3oc3ccccc34)cc2)cc1]

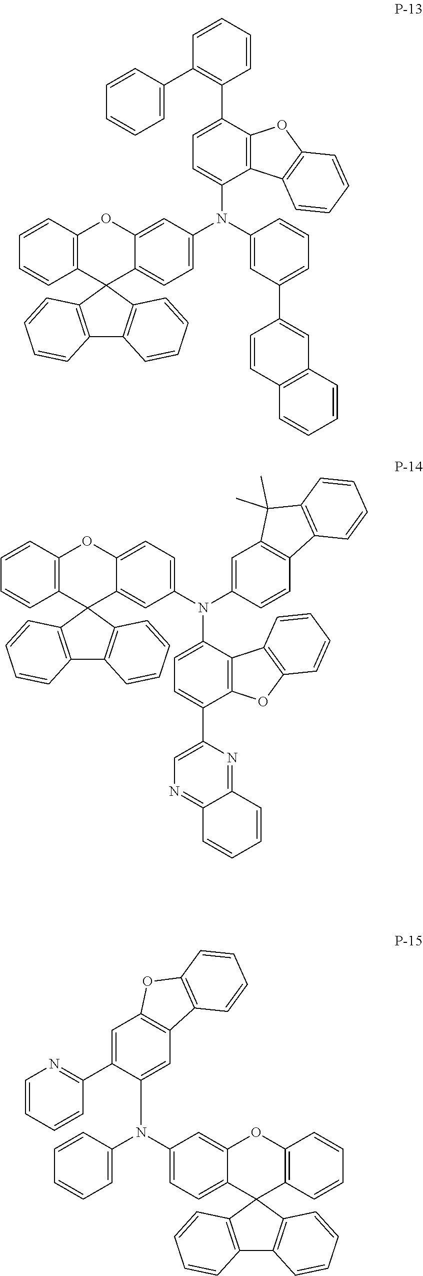

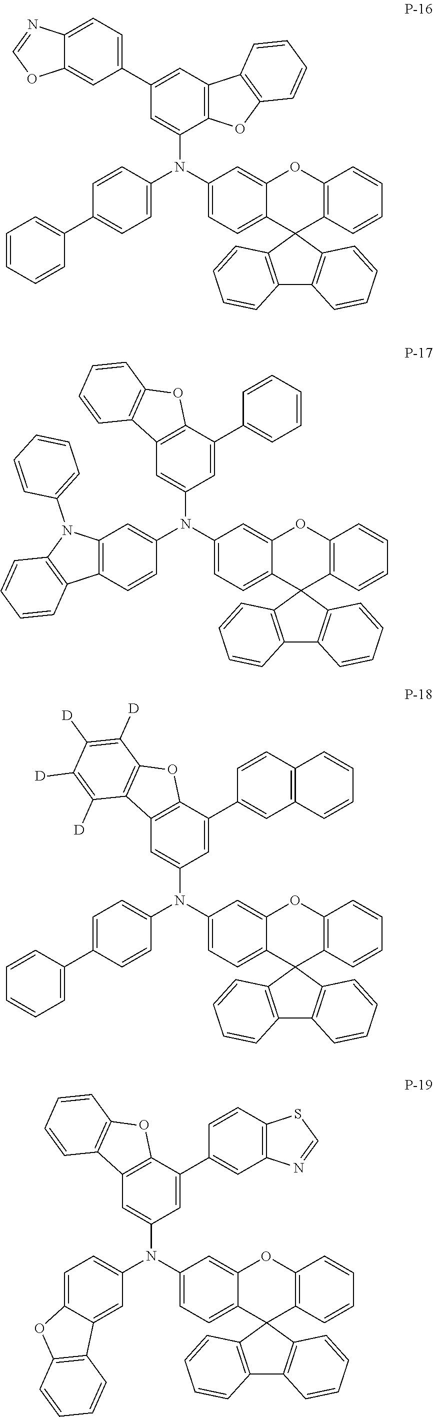 [SMILES: c1ccc(-c2ccc(N(c3ccc4c(c3)Oc3ccccc3C43c4ccccc4-c4ccccc43)c3cc(-c4ccc5ncoc5c4)cc4c3oc3ccccc34)cc2)cc1 ; c1ccc(-c2cc(N(c3ccc4c(c3)Oc3ccccc3C43c4ccccc4-c4ccccc43)c3ccc4c5ccccc5n(-c5ccccc5)c4c3)cc3c2oc2ccccc23)cc1 ; [2H]c1c([2H])c([2H])c2c(oc3c(-c4ccc5ccccc5c4)cc(N(c4ccc(-c5ccccc5)cc4)c4ccc5c(c4)Oc4ccccc4C54c5ccccc5-c5ccccc54)cc32)c1[2H] ; c1ccc2c(c1)Oc1cc(N(c3ccc4oc5ccccc5c4c3)c3cc(-c4ccc5scnc5c4)c4oc5ccccc5c4c3)ccc1C21c2ccccc2-c2ccccc21]

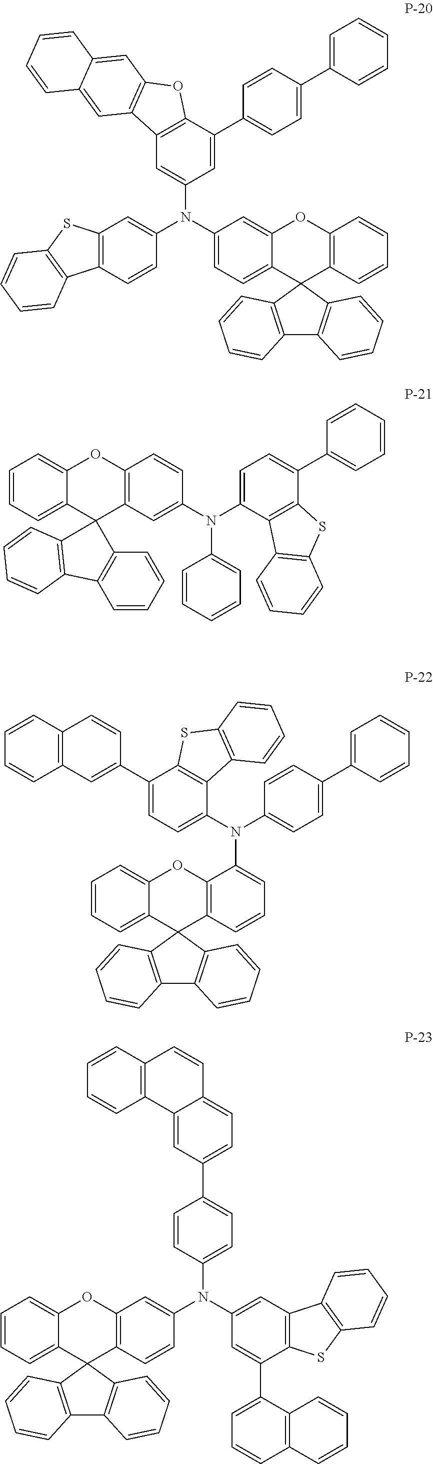

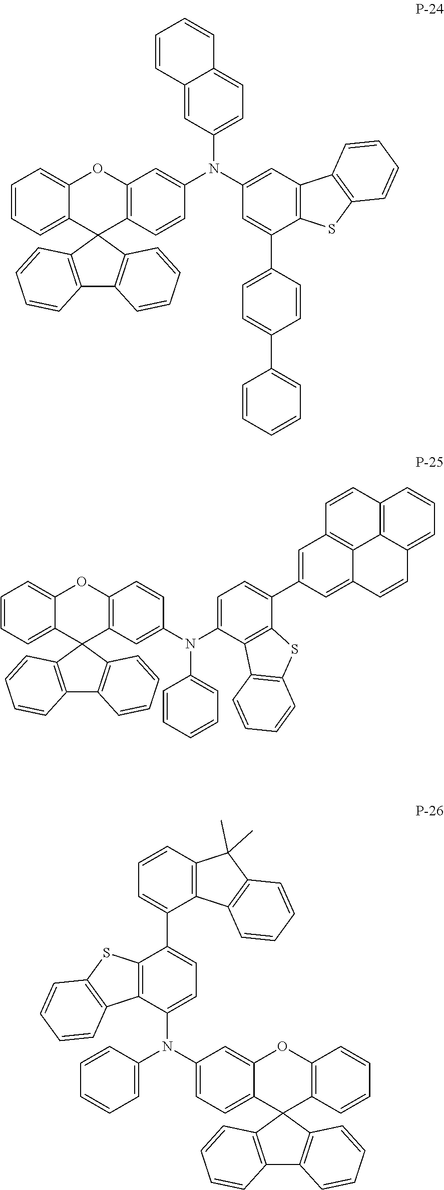 [SMILES: c1ccc(-c2ccc(-c3cc(N(c4ccc5c(c4)Oc4ccccc4C54c5ccccc5-c5ccccc54)c4ccc5ccccc5c4)cc4c3sc3ccccc34)cc2)cc1 ; c1ccc(N(c2ccc3c(c2)C2(c4ccccc4O3)c3ccccc3-c3ccccc32)c2ccc(-c3cc4ccc5cccc6ccc(c3)c4c56)c3sc4ccccc4c23)cc1 ; CC1(C)c2ccccc2-c2c(-c3ccc(N(c4ccccc4)c4ccc5c(c4)Oc4ccccc4C54c5ccccc5-c5ccccc54)c4c3sc3ccccc34)cccc21]

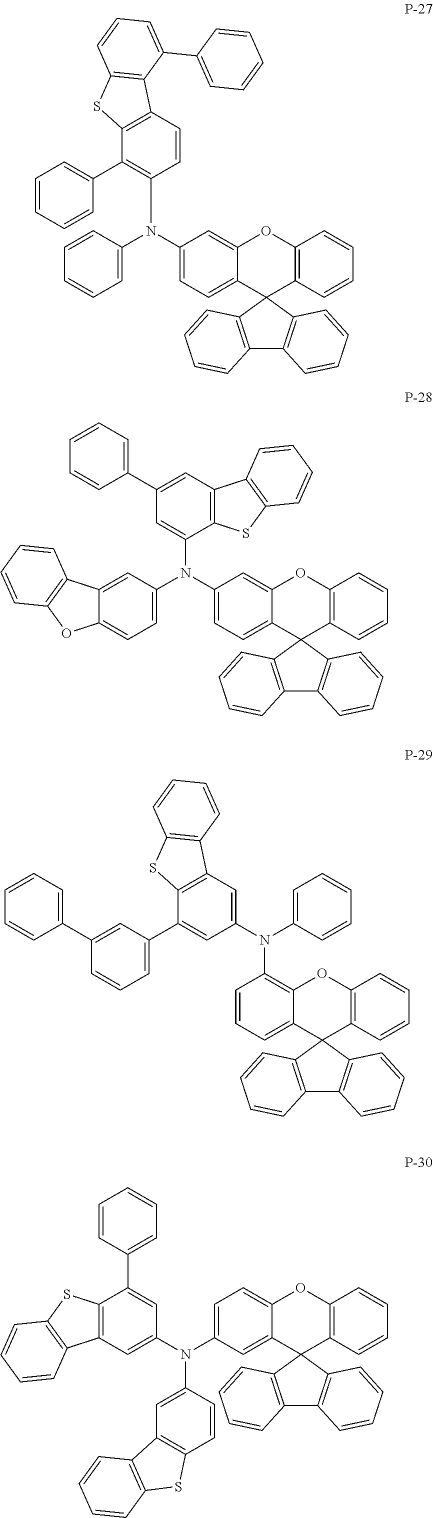 [SMILES: c1ccc(-c2c(N(c3ccccc3)c3ccc4c(c3)Oc3ccccc3C43c4ccccc4-c4ccccc43)ccc3c2sc2cccc(-c4ccccc4)c23)cc1 ; c1ccc(-c2cc(N(c3ccc4c(c3)Oc3ccccc3C43c4ccccc4-c4ccccc43)c3ccc4oc5ccccc5c4c3)c3sc4ccccc4c3c2)cc1 ; c1ccc(-c2cccc(-c3cc(N(c4ccccc4)c4cccc5c4Oc4ccccc4C54c5ccccc5-c5ccccc54)cc4c3sc3ccccc34)c2)cc1 ; c1ccc(-c2cc(N(c3ccc4c(c3)C3(c5ccccc5O4)c4ccccc4-c4ccccc43)c3ccc4sc5ccccc5c4c3)cc3c2sc2ccccc23)cc1]

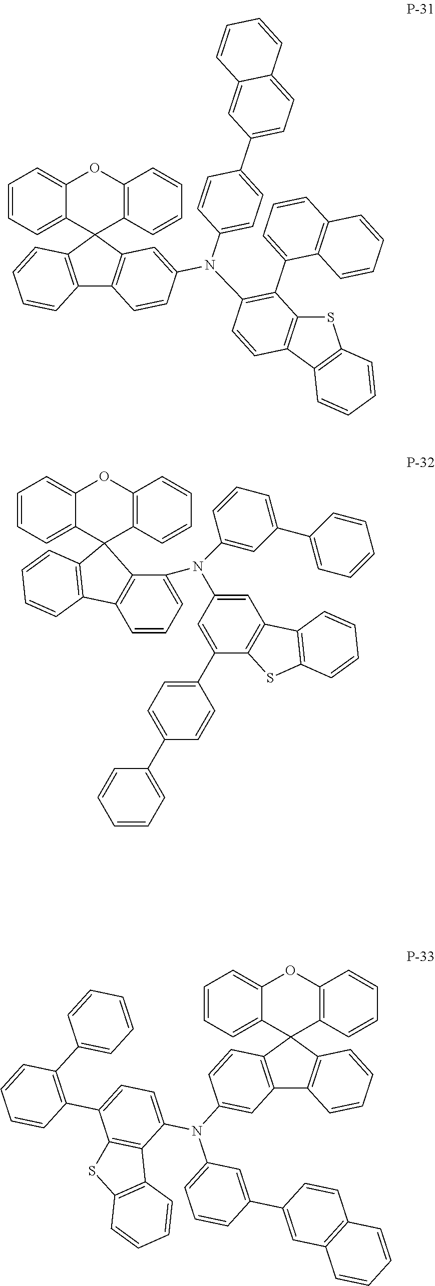 [SMILES: c1ccc2c(c1)Oc1ccccc1C21c2ccccc2-c2ccc(N(c3ccc(-c4ccc5ccccc5c4)cc3)c3ccc4c(sc5ccccc54)c3-c3cccc4ccccc34)cc21 ; c1ccc(-c2ccc(-c3cc(N(c4cccc(-c5ccccc5)c4)c4cccc5c4C4(c6ccccc6Oc6ccccc64)c4ccccc4-5)cc4c3sc3ccccc34)cc2)cc1 ; c1ccc(-c2ccccc2-c2ccc(N(c3cccc(-c4ccc5ccccc5c4)c3)c3ccc4c(c3)-c3ccccc3C43c4ccccc4Oc4ccccc43)c3c2sc2ccccc23)cc1]

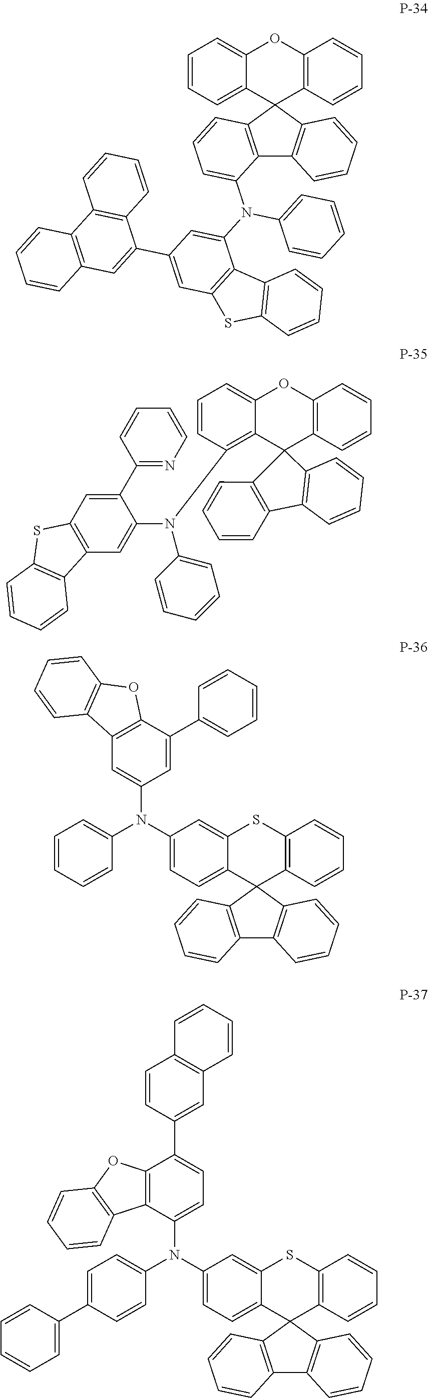

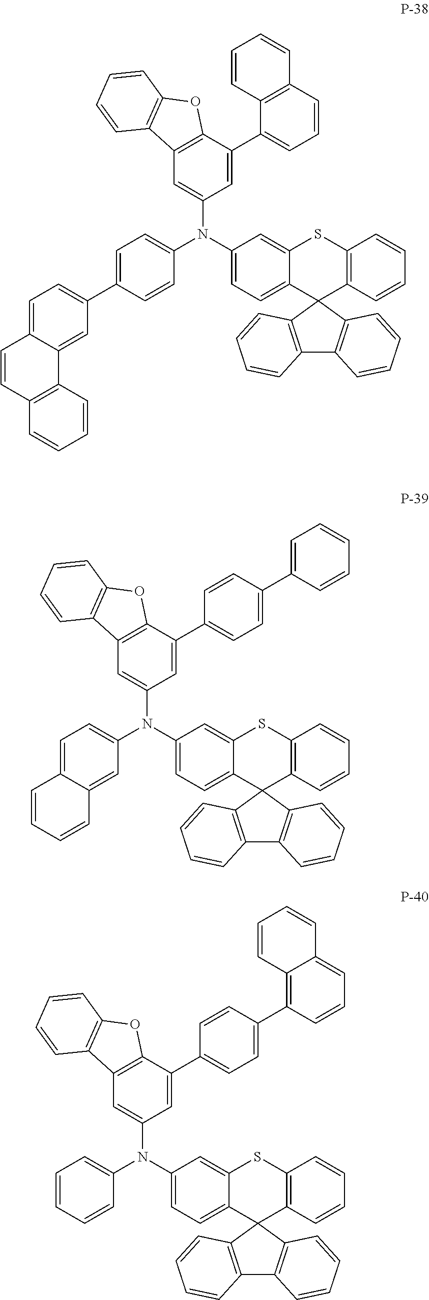

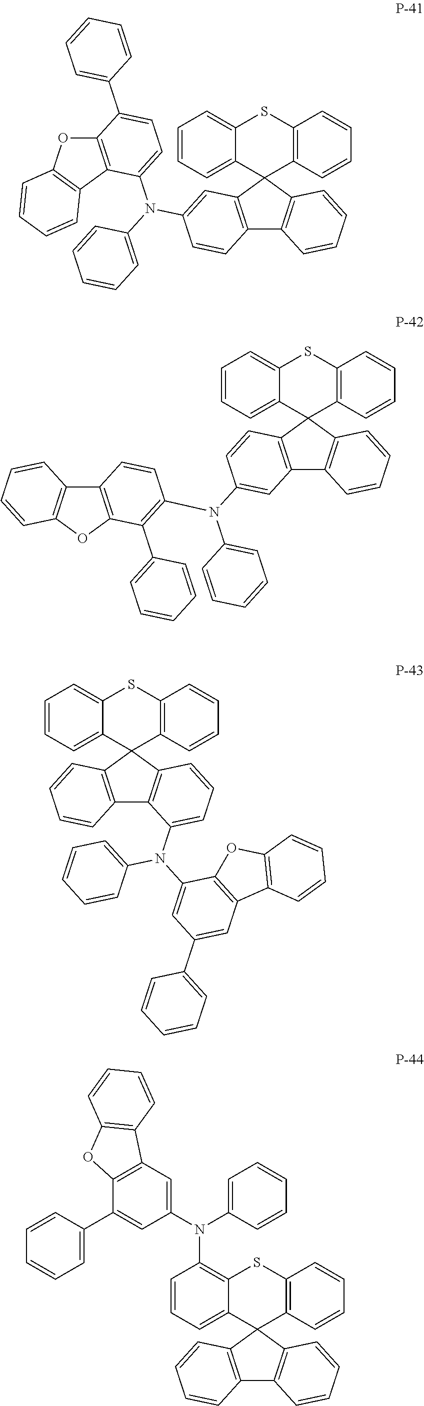

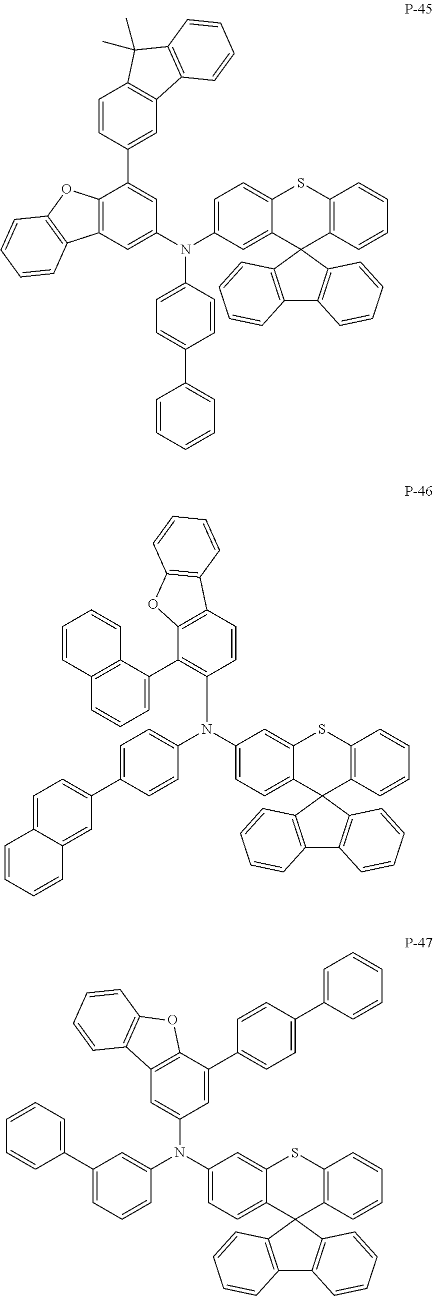 [SMILES: CC1(C)c2ccccc2-c2cc(-c3cc(N(c4ccc(-c5ccccc5)cc4)c4ccc5c(c4)C4(c6ccccc6S5)c5ccccc5-c5ccccc54)cc4c3oc3ccccc34)ccc21 ; c1ccc2c(c1)Sc1cc(N(c3ccc(-c4ccc5ccccc5c4)cc3)c3ccc4c(oc5ccccc54)c3-c3cccc4ccccc34)ccc1C21c2ccccc2-c2ccccc21 ; c1ccc(-c2ccc(-c3cc(N(c4cccc(-c5ccccc5)c4)c4ccc5c(c4)Sc4ccccc4C54c5ccccc5-c5ccccc54)cc4c3oc3ccccc34)cc2)cc1]

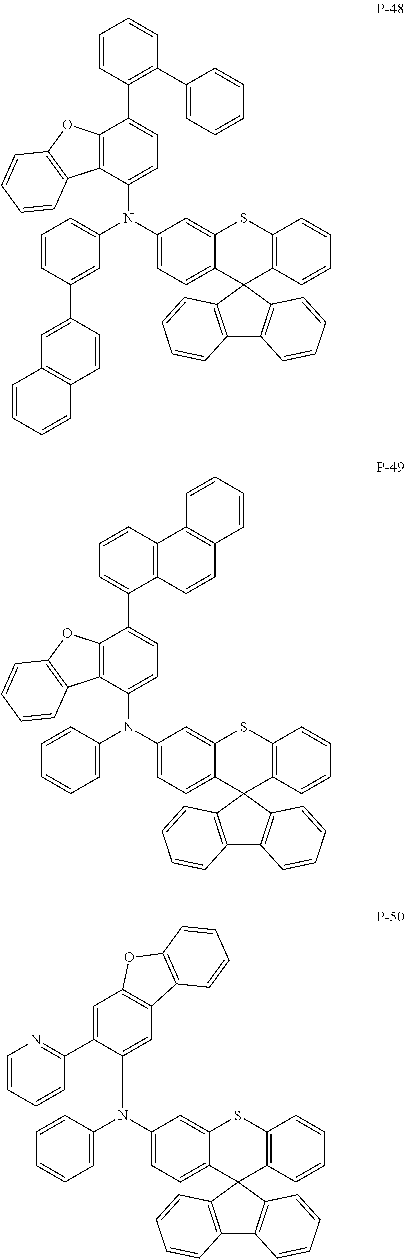 [SMILES: c1ccc(-c2ccccc2-c2ccc(N(c3cccc(-c4ccc5ccccc5c4)c3)c3ccc4c(c3)Sc3ccccc3C43c4ccccc4-c4ccccc43)c3c2oc2ccccc23)cc1 ; c1ccc(N(c2ccc3c(c2)Sc2ccccc2C32c3ccccc3-c3ccccc32)c2ccc(-c3cccc4c3ccc3ccccc34)c3oc4ccccc4c23)cc1 ; c1ccc(N(c2ccc3c(c2)Sc2ccccc2C32c3ccccc3-c3ccccc32)c2cc3c(cc2-c2ccccn2)oc2ccccc23)cc1]

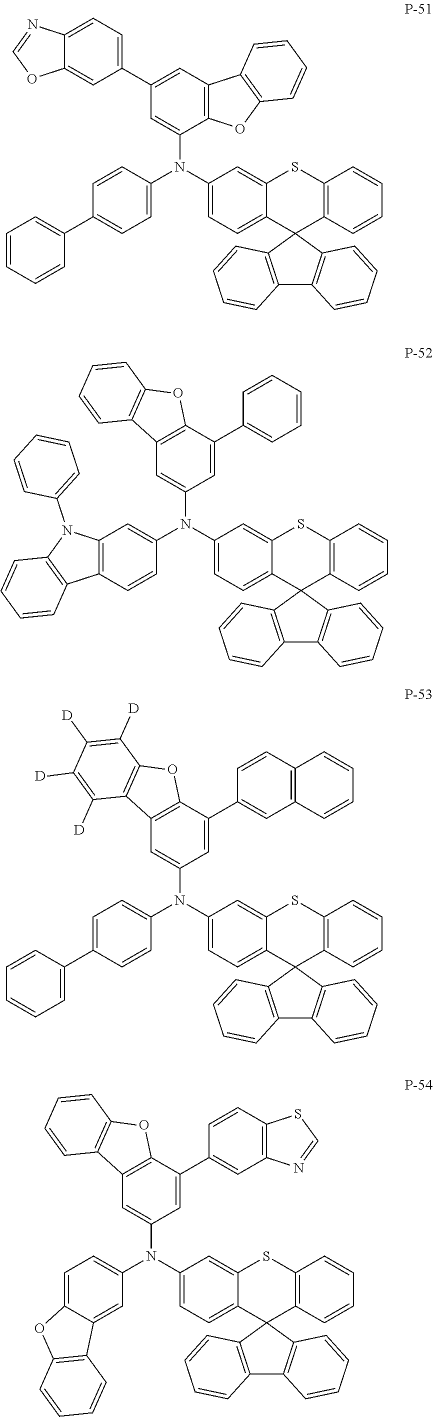 [SMILES: c1ccc(-c2ccc(N(c3ccc4c(c3)Sc3ccccc3C43c4ccccc4-c4ccccc43)c3cc(-c4ccc5ncoc5c4)cc4c3oc3ccccc34)cc2)cc1 ; c1ccc(-c2cc(N(c3ccc4c(c3)Sc3ccccc3C43c4ccccc4-c4ccccc43)c3ccc4c5ccccc5n(-c5ccccc5)c4c3)cc3c2oc2ccccc23)cc1 ; [2H]c1c([2H])c([2H])c2c(oc3c(-c4ccc5ccccc5c4)cc(N(c4ccc(-c5ccccc5)cc4)c4ccc5c(c4)Sc4ccccc4C54c5ccccc5-c5ccccc54)cc32)c1[2H] ; c1ccc2c(c1)Sc1cc(N(c3ccc4oc5ccccc5c4c3)c3cc(-c4ccc5scnc5c4)c4oc5ccccc5c4c3)ccc1C21c2ccccc2-c2ccccc21]

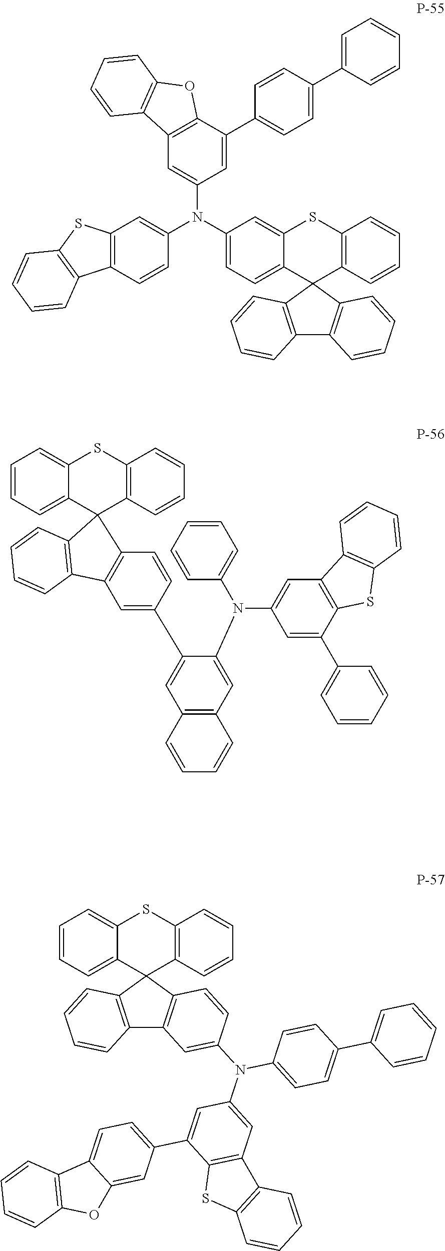 [SMILES: c1ccc(-c2ccc(-c3cc(N(c4ccc5c(c4)Sc4ccccc4C54c5ccccc5-c5ccccc54)c4ccc5c(c4)sc4ccccc45)cc4c3oc3ccccc34)cc2)cc1 ; c1ccc(-c2cc(N(c3ccccc3)c3cc4ccccc4cc3-c3ccc4c(c3)-c3ccccc3C43c4ccccc4Sc4ccccc43)cc3c2sc2ccccc23)cc1 ; c1ccc(-c2ccc(N(c3ccc4c(c3)-c3ccccc3C43c4ccccc4Sc4ccccc43)c3cc(-c4ccc5c(c4)oc4ccccc45)c4sc5ccccc5c4c3)cc2)cc1]

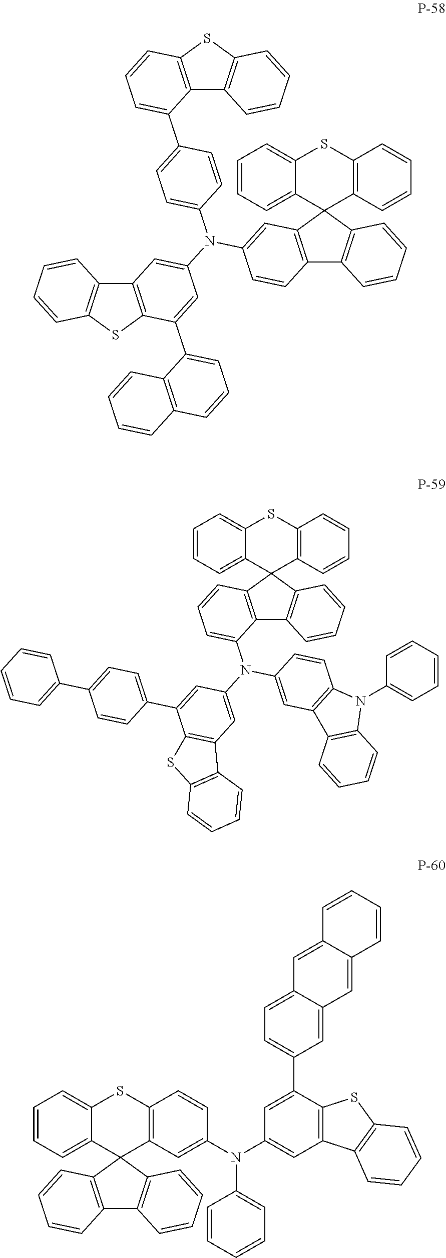 [SMILES: c1ccc2c(c1)Sc1ccccc1C21c2ccccc2-c2ccc(N(c3ccc(-c4cccc5sc6ccccc6c45)cc3)c3cc(-c4cccc5ccccc45)c4sc5ccccc5c4c3)cc21 ; c1ccc(-c2ccc(-c3cc(N(c4ccc5c(c4)c4ccccc4n5-c4ccccc4)c4cccc5c4-c4ccccc4C54c5ccccc5Sc5ccccc54)cc4c3sc3ccccc34)cc2)cc1 ; c1ccc(N(c2ccc3c(c2)C2(c4ccccc4S3)c3ccccc3-c3ccccc32)c2cc(-c3ccc4cc5ccccc5cc4c3)c3sc4ccccc4c3c2)cc1]

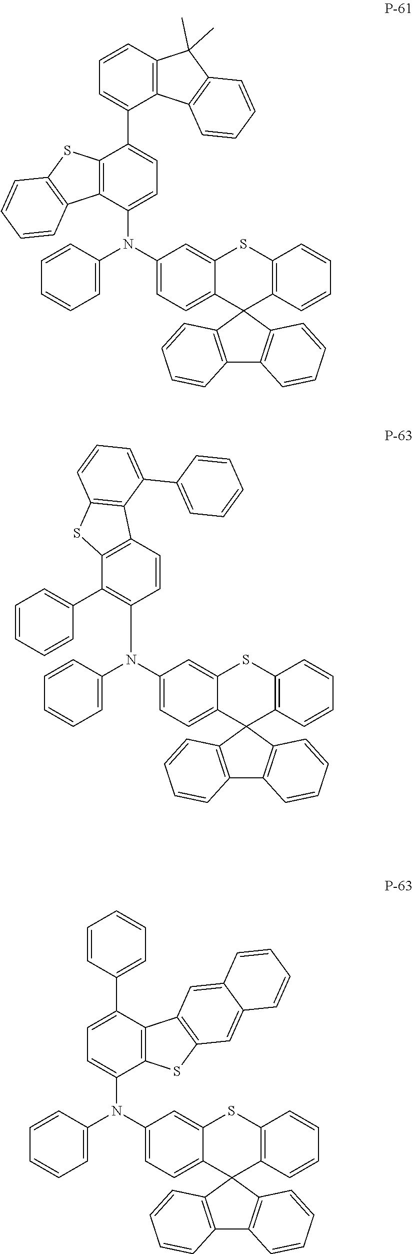 [SMILES: CC1(C)c2ccccc2-c2c(-c3ccc(N(c4ccccc4)c4ccc5c(c4)Sc4ccccc4C54c5ccccc5-c5ccccc54)c4c3sc3ccccc34)cccc21 ; c1ccc(-c2c(N(c3ccccc3)c3ccc4c(c3)Sc3ccccc3C43c4ccccc4-c4ccccc43)ccc3c2sc2cccc(-c4ccccc4)c23)cc1 ; c1ccc(-c2ccc(N(c3ccccc3)c3ccc4c(c3)Sc3ccccc3C43c4ccccc4-c4ccccc43)c3sc4cc5ccccc5cc4c23)cc1]

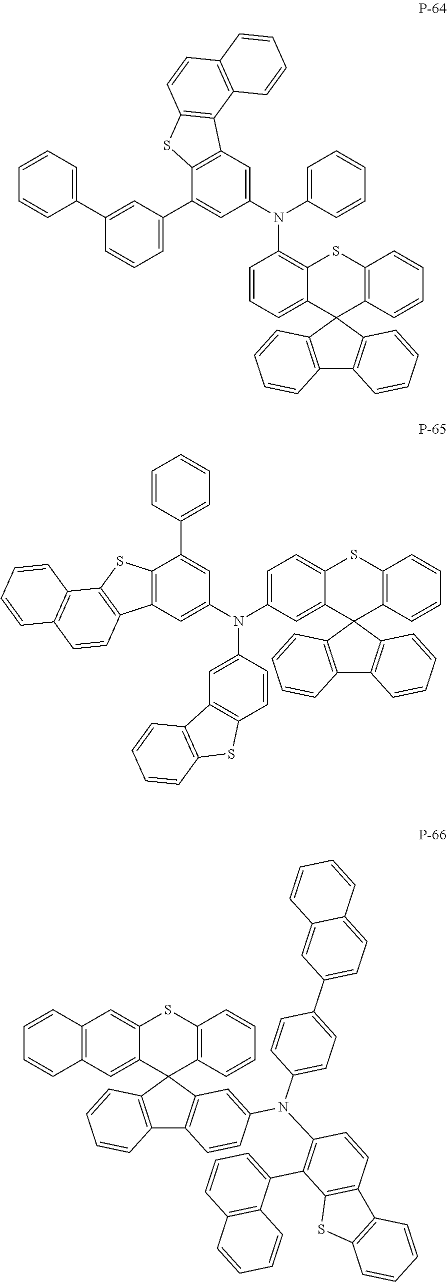 [SMILES: c1ccc(-c2cccc(-c3cc(N(c4ccccc4)c4cccc5c4Sc4ccccc4C54c5ccccc5-c5ccccc54)cc4c3sc3ccc5ccccc5c34)c2)cc1 ; c1ccc(-c2cc(N(c3ccc4c(c3)C3(c5ccccc5S4)c4ccccc4-c4ccccc43)c3ccc4sc5ccccc5c4c3)cc3c2sc2c4ccccc4ccc32)cc1 ; c1ccc2c(c1)Sc1cc3ccccc3cc1C21c2ccccc2-c2ccc(N(c3ccc(-c4ccc5ccccc5c4)cc3)c3ccc4c(sc5ccccc54)c3-c3cccc4ccccc34)cc21]

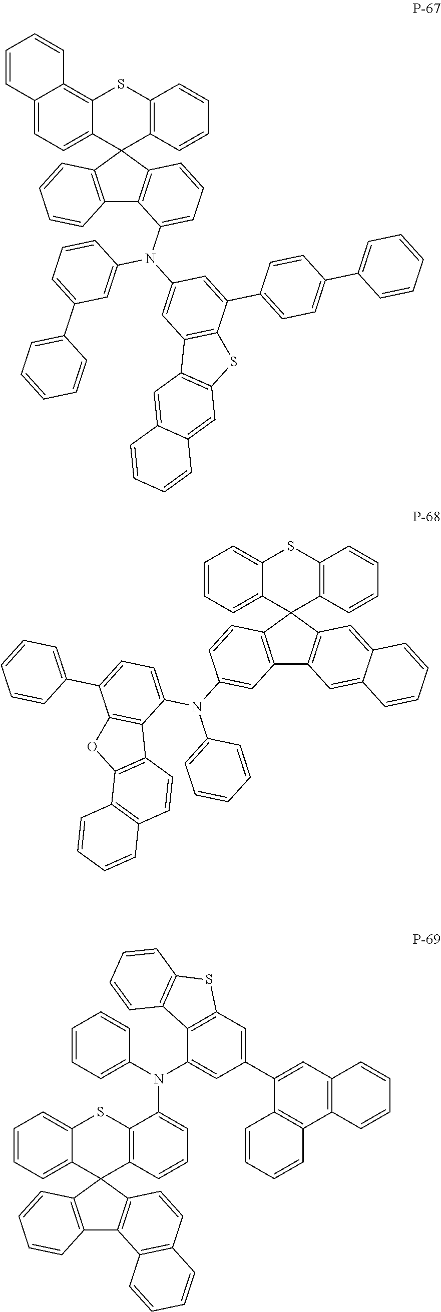 [SMILES: c1ccc(-c2ccc(-c3cc(N(c4cccc(-c5ccccc5)c4)c4cccc5c4-c4ccccc4C54c5ccccc5Sc5c4ccc4ccccc54)cc4c3sc3cc5ccccc5cc34)cc2)cc1 ; c1ccc(-c2ccc(N(c3ccccc3)c3ccc4c(c3)-c3cc5ccccc5cc3C43c4ccccc4Sc4ccccc43)c3c2oc2c4ccccc4ccc23)cc1 ; c1ccc(N(c2cccc3c2Sc2ccccc2C32c3ccccc3-c3c2ccc2ccccc32)c2cc(-c3cc4ccccc4c4ccccc34)cc3sc4ccccc4c23)cc1]

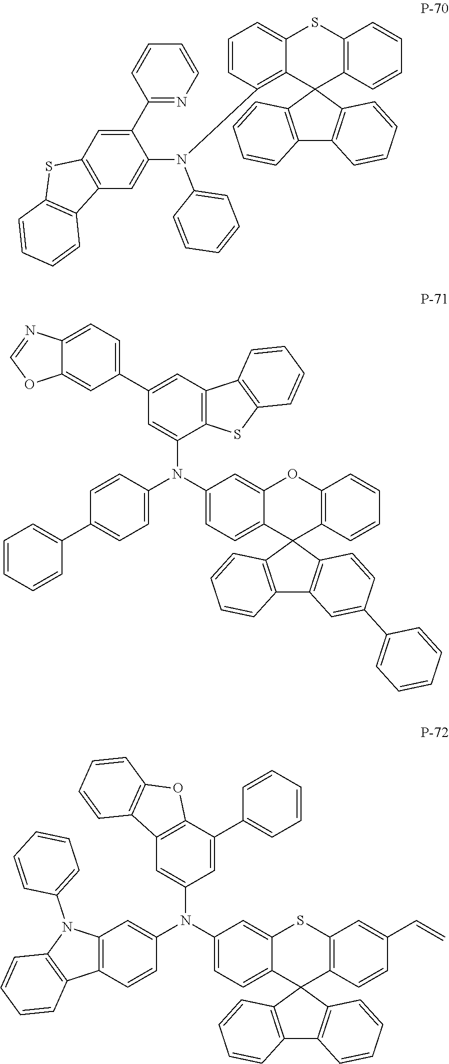 [SMILES: c1ccc(N(c2cc3c(cc2-c2ccccn2)sc2ccccc23)c2cccc3c2C2(c4ccccc4S3)c3ccccc3-c3ccccc32)cc1 ; c1ccc(-c2ccc(N(c3ccc4c(c3)Oc3ccccc3C43c4ccccc4-c4cc(-c5ccccc5)ccc43)c3cc(-c4ccc5ncoc5c4)cc4c3sc3ccccc34)cc2)cc1 ; C=Cc1ccc2c(c1)Sc1cc(N(c3cc(-c4ccccc4)c4oc5ccccc5c4c3)c3ccc4c5ccccc5n(-c5ccccc5)c4c3)ccc1C21c2ccccc2-c2ccccc21]

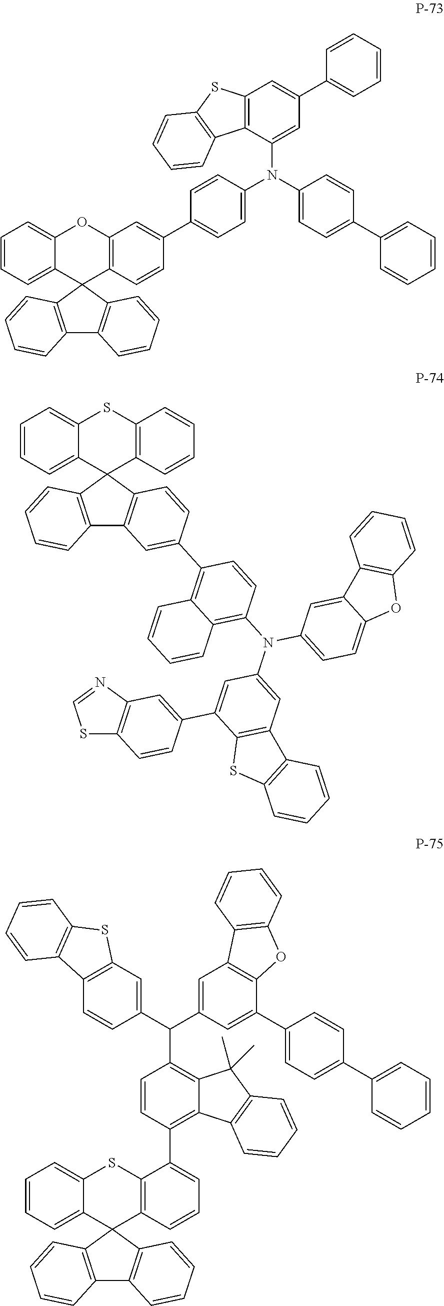 [SMILES: c1ccc(-c2ccc(N(c3ccc(-c4ccc5c(c4)Oc4ccccc4C54c5ccccc5-c5ccccc54)cc3)c3cc(-c4ccccc4)cc4sc5ccccc5c34)cc2)cc1 ; c1ccc2c(c1)Sc1ccccc1C21c2ccccc2-c2cc(-c3ccc(N(c4ccc5oc6ccccc6c5c4)c4cc(-c5ccc6scnc6c5)c5sc6ccccc6c5c4)c4ccccc34)ccc21 ; CC1(C)c2ccccc2-c2c(-c3cccc4c3Sc3ccccc3C43c4ccccc4-c4ccccc43)ccc(C(c3ccc4c(c3)sc3ccccc34)c3cc(-c4ccc(-c5ccccc5)cc4)c4oc5ccccc5c4c3)c21]

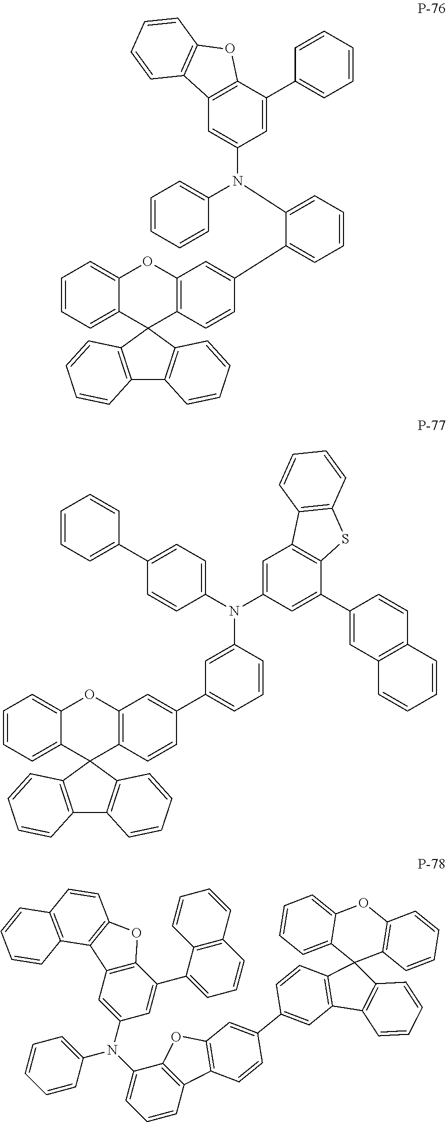 [SMILES: c1ccc(-c2cc(N(c3ccccc3)c3ccccc3-c3ccc4c(c3)Oc3ccccc3C43c4ccccc4-c4ccccc43)cc3c2oc2ccccc23)cc1 ; c1ccc(-c2ccc(N(c3cccc(-c4ccc5c(c4)Oc4ccccc4C54c5ccccc5-c5ccccc54)c3)c3cc(-c4ccc5ccccc5c4)c4sc5ccccc5c4c3)cc2)cc1 ; c1ccc(N(c2cc(-c3cccc4ccccc34)c3oc4ccc5ccccc5c4c3c2)c2cccc3c2oc2cc(-c4ccc5c(c4)-c4ccccc4C54c5ccccc5Oc5ccccc54)ccc23)cc1]

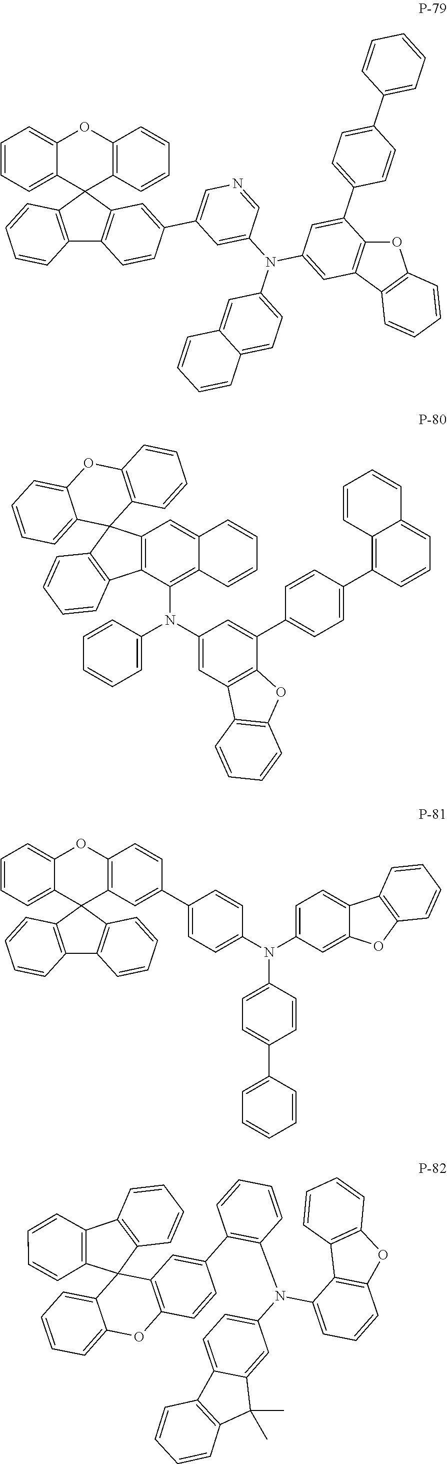 [SMILES: c1ccc(-c2ccc(-c3cc(N(c4cncc(-c5ccc6c(c5)C5(c7ccccc7Oc7ccccc75)c5ccccc5-6)c4)c4ccc5ccccc5c4)cc4c3oc3ccccc34)cc2)cc1 ; c1ccc(N(c2cc(-c3ccc(-c4cccc5ccccc45)cc3)c3oc4ccccc4c3c2)c2c3c(cc4ccccc24)C2(c4ccccc4Oc4ccccc42)c2ccccc2-3)cc1 ; c1ccc(-c2ccc(N(c3ccc(-c4ccc5c(c4)C4(c6ccccc6O5)c5ccccc5-c5ccccc54)cc3)c3ccc4c(c3)oc3ccccc34)cc2)cc1 ; CC1(C)c2ccccc2-c2ccc(N(c3ccccc3-c3ccc4c(c3)C3(c5ccccc5O4)c4ccccc4-c4ccccc43)c3cccc4oc5ccccc5c34)cc21]

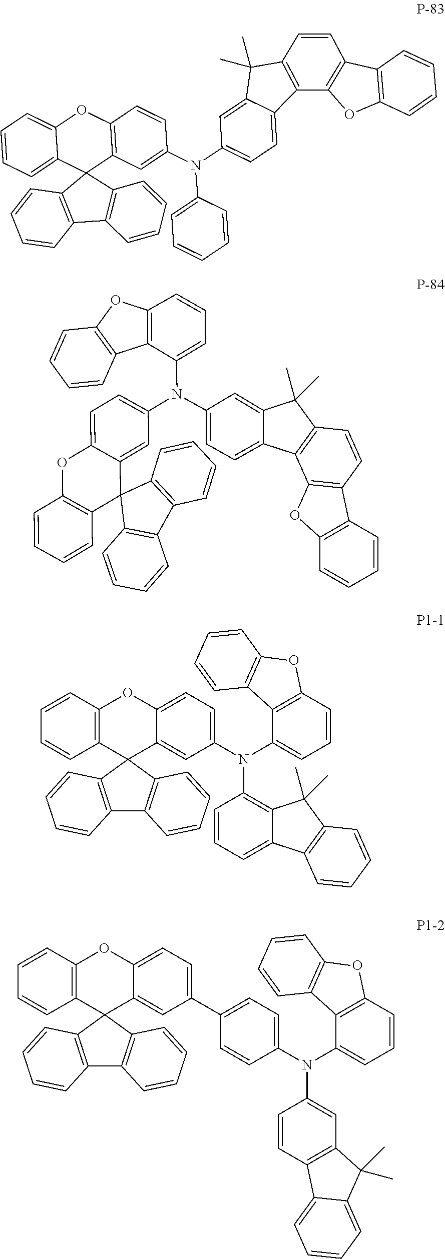

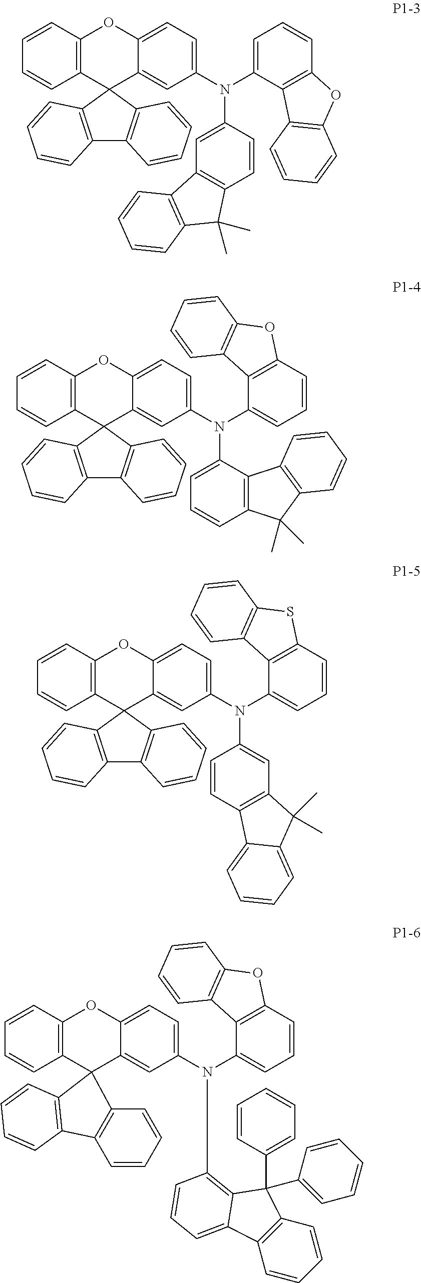

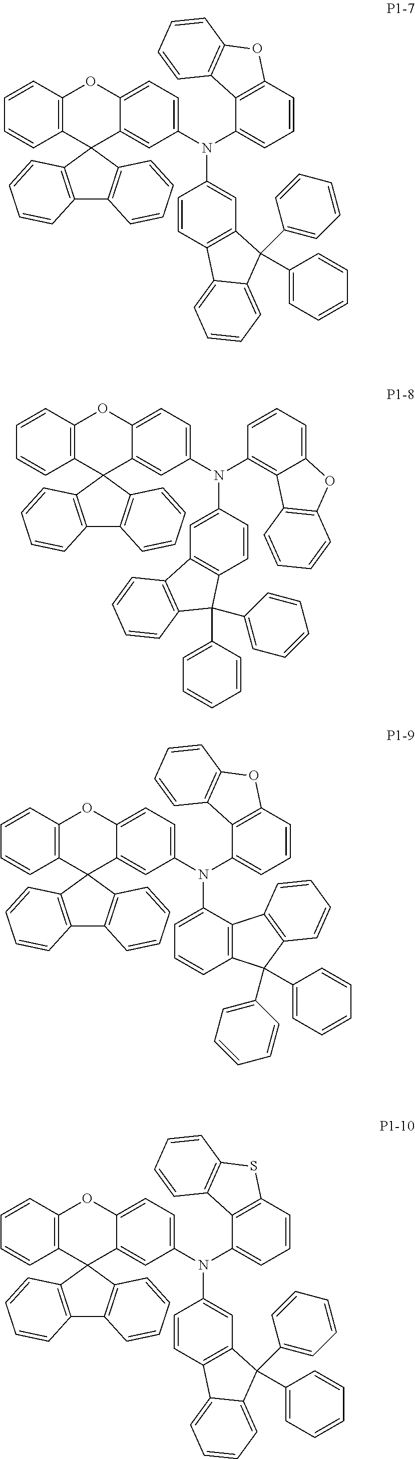

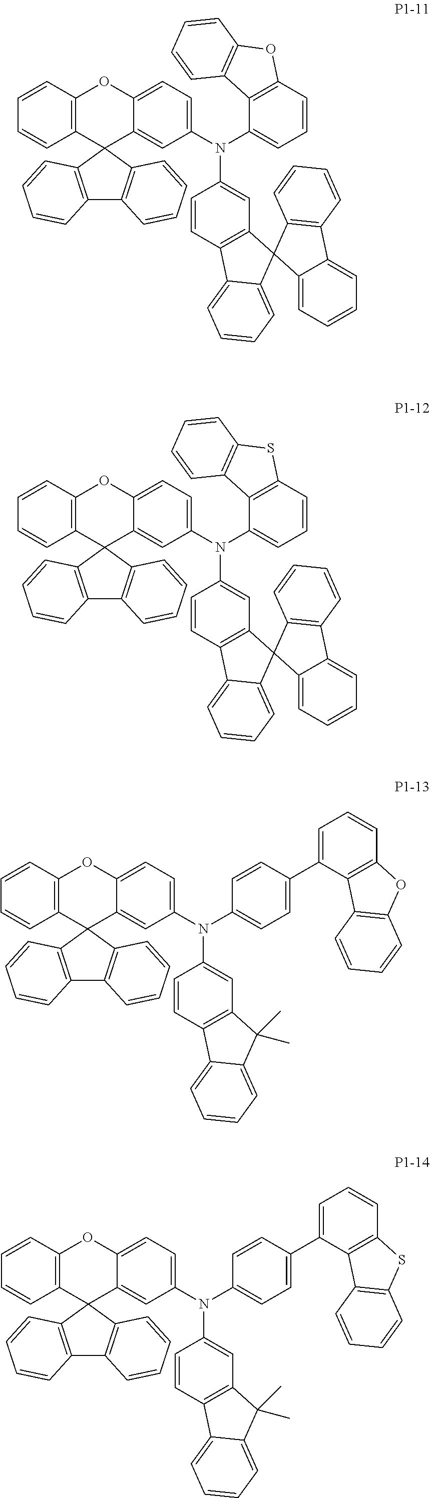 [SMILES: c1ccc2c(c1)Oc1ccc(N(c3ccc4c(c3)C3(c5ccccc5-c5ccccc53)c3ccccc3-4)c3cccc4oc5ccccc5c34)cc1C21c2ccccc2-c2ccccc21 ; c1ccc2c(c1)Oc1ccc(N(c3ccc4c(c3)C3(c5ccccc5-c5ccccc53)c3ccccc3-4)c3cccc4sc5ccccc5c34)cc1C21c2ccccc2-c2ccccc21 ; CC1(C)c2ccccc2-c2ccc(N(c3ccc(-c4cccc5oc6ccccc6c45)cc3)c3ccc4c(c3)C3(c5ccccc5O4)c4ccccc4-c4ccccc43)cc21 ; CC1(C)c2ccccc2-c2ccc(N(c3ccc(-c4cccc5sc6ccccc6c45)cc3)c3ccc4c(c3)C3(c5ccccc5O4)c4ccccc4-c4ccccc43)cc21]

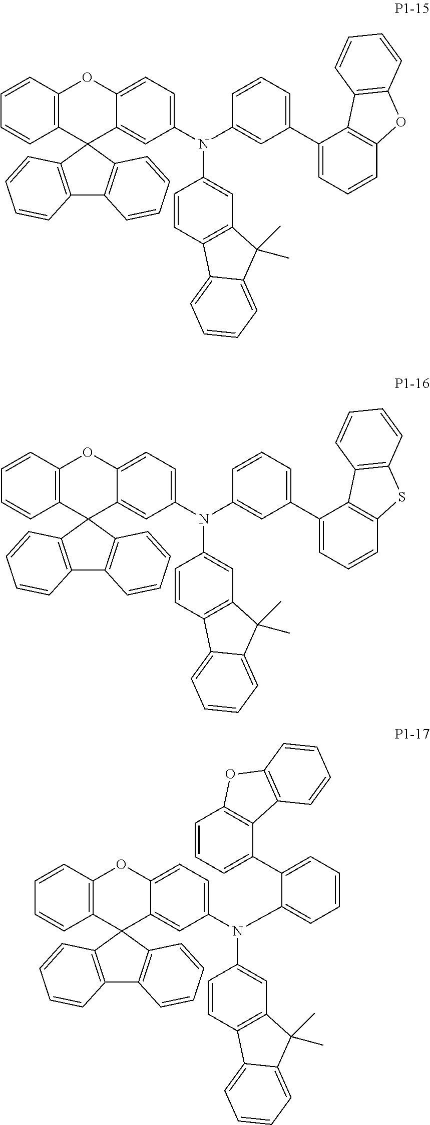 [SMILES: CC1(C)c2ccccc2-c2ccc(N(c3cccc(-c4cccc5oc6ccccc6c45)c3)c3ccc4c(c3)C3(c5ccccc5O4)c4ccccc4-c4ccccc43)cc21 ; CC1(C)c2ccccc2-c2ccc(N(c3cccc(-c4cccc5sc6ccccc6c45)c3)c3ccc4c(c3)C3(c5ccccc5O4)c4ccccc4-c4ccccc43)cc21 ; CC1(C)c2ccccc2-c2ccc(N(c3ccc4c(c3)C3(c5ccccc5O4)c4ccccc4-c4ccccc43)c3ccccc3-c3cccc4oc5ccccc5c34)cc21]

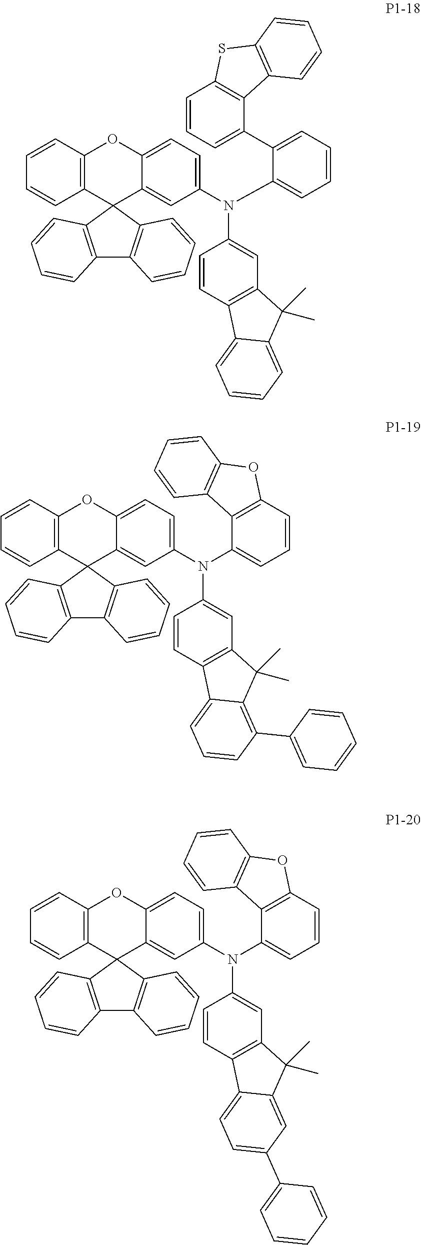 [SMILES: CC1(C)c2ccccc2-c2ccc(N(c3ccc4c(c3)C3(c5ccccc5O4)c4ccccc4-c4ccccc43)c3ccccc3-c3cccc4sc5ccccc5c34)cc21 ; CC1(C)c2cc(N(c3ccc4c(c3)C3(c5ccccc5O4)c4ccccc4-c4ccccc43)c3cccc4oc5ccccc5c34)ccc2-c2cccc(-c3ccccc3)c21 ; CC1(C)c2cc(-c3ccccc3)ccc2-c2ccc(N(c3ccc4c(c3)C3(c5ccccc5O4)c4ccccc4-c4ccccc43)c3cccc4oc5ccccc5c34)cc21]

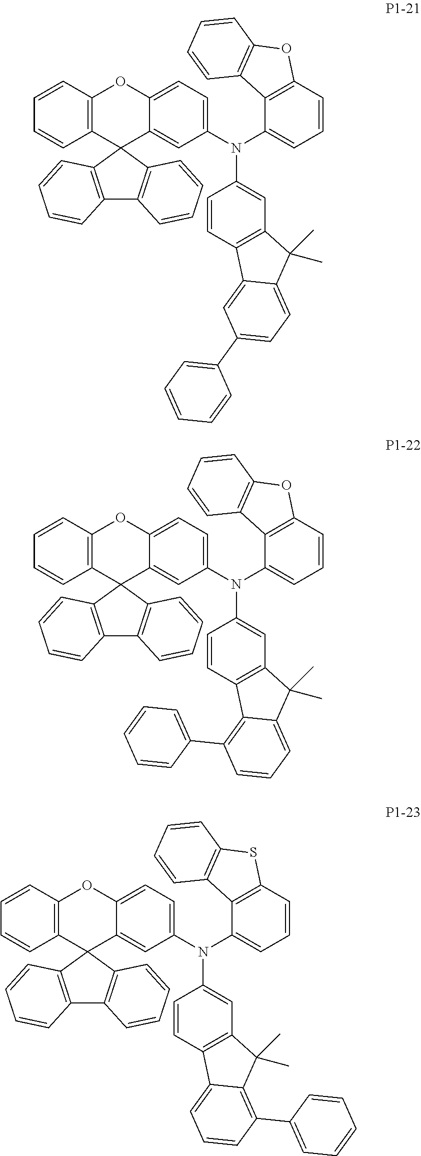

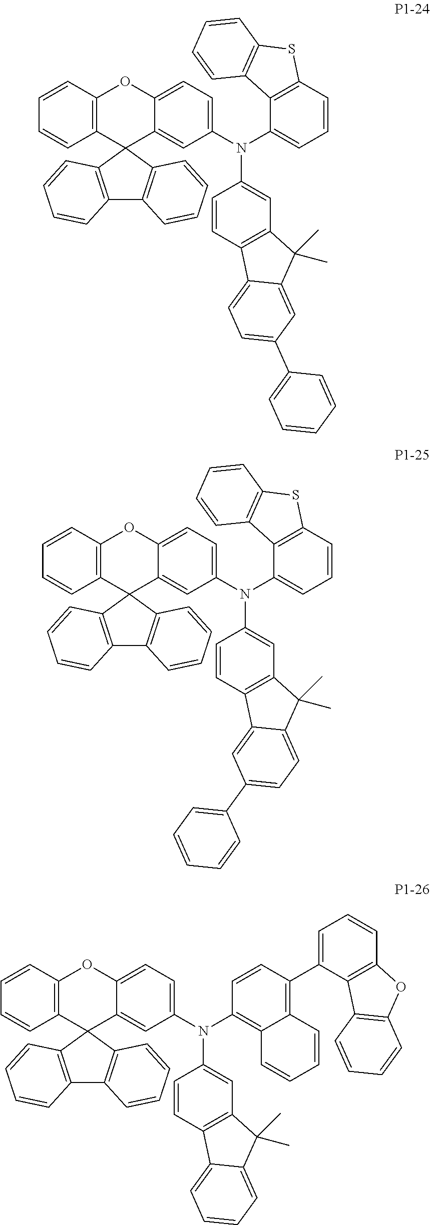 [SMILES: CC1(C)c2cc(-c3ccccc3)ccc2-c2ccc(N(c3ccc4c(c3)C3(c5ccccc5O4)c4ccccc4-c4ccccc43)c3cccc4sc5ccccc5c34)cc21 ; CC1(C)c2ccc(-c3ccccc3)cc2-c2ccc(N(c3ccc4c(c3)C3(c5ccccc5O4)c4ccccc4-c4ccccc43)c3cccc4sc5ccccc5c34)cc21 ; CC1(C)c2ccccc2-c2ccc(N(c3ccc4c(c3)C3(c5ccccc5O4)c4ccccc4-c4ccccc43)c3ccc(-c4cccc5oc6ccccc6c45)c4ccccc34)cc21]

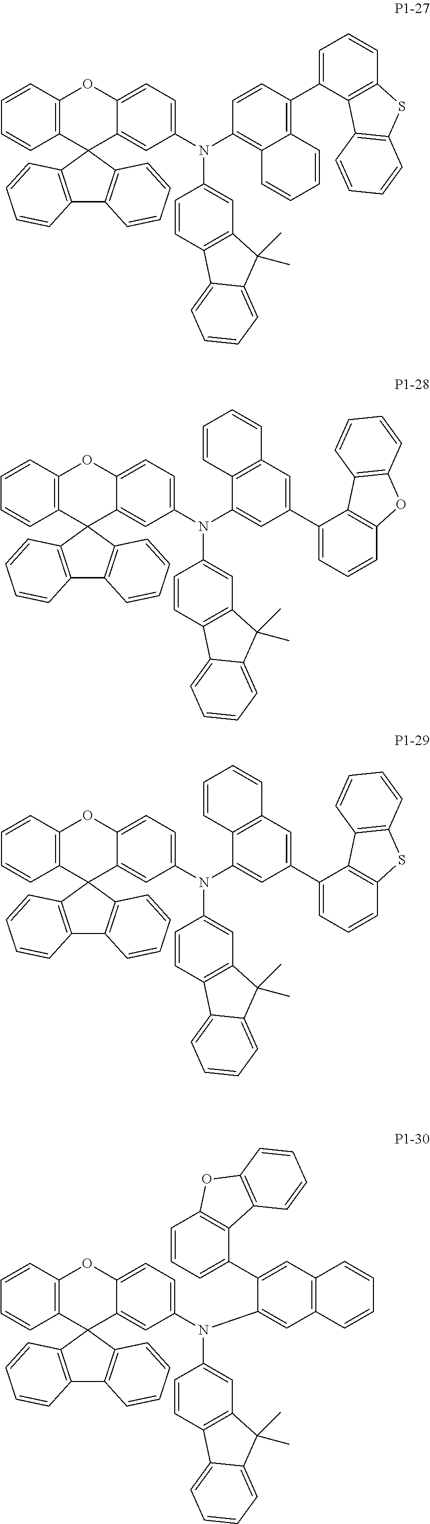

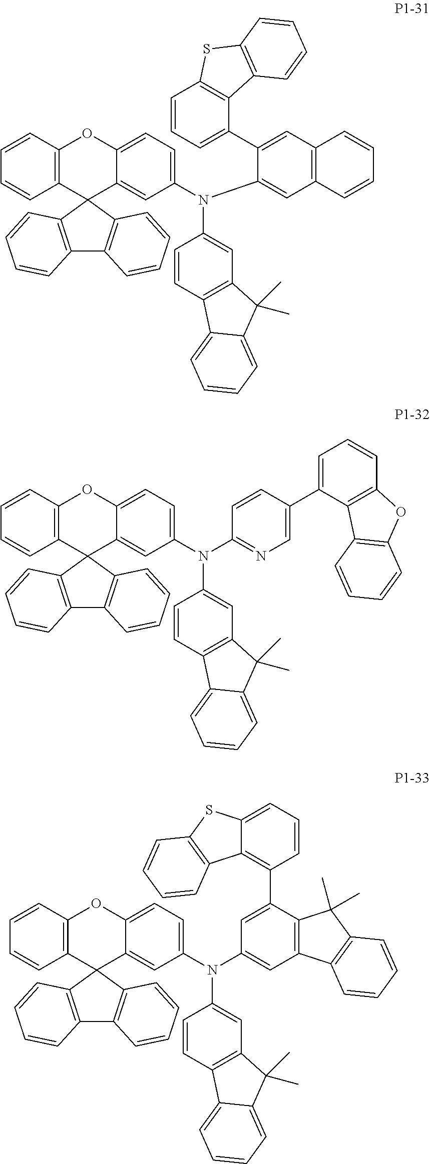 [SMILES: CC1(C)c2ccccc2-c2ccc(N(c3ccc4c(c3)C3(c5ccccc5O4)c4ccccc4-c4ccccc43)c3cc4ccccc4cc3-c3cccc4sc5ccccc5c34)cc21 ; CC1(C)c2ccccc2-c2ccc(N(c3ccc4c(c3)C3(c5ccccc5O4)c4ccccc4-c4ccccc43)c3ccc(-c4cccc5oc6ccccc6c45)cn3)cc21 ; CC1(C)c2ccccc2-c2ccc(N(c3cc4c(c(-c5cccc6sc7ccccc7c56)c3)C(C)(C)c3ccccc3-4)c3ccc4c(c3)C3(c5ccccc5O4)c4ccccc4-c4ccccc43)cc21]

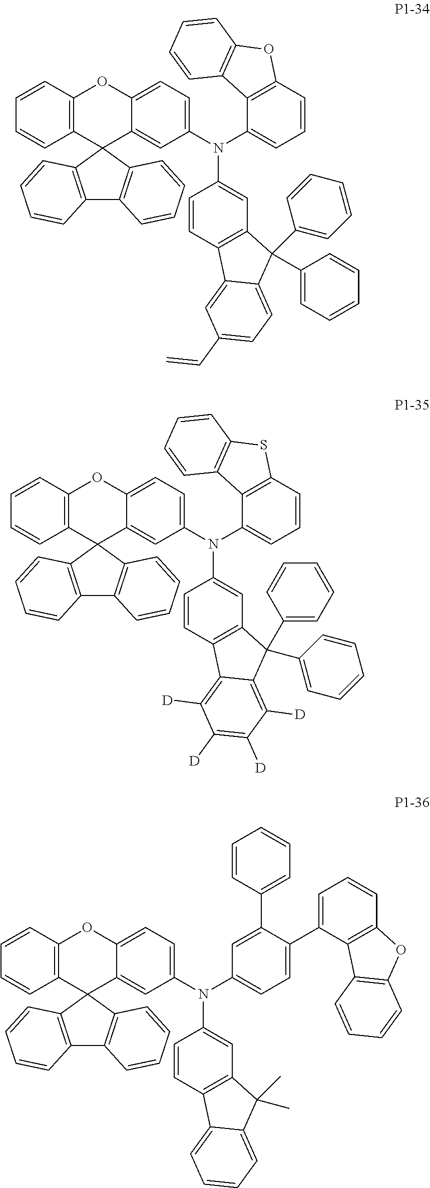 [SMILES: C=Cc1ccc2c(c1)-c1ccc(N(c3ccc4c(c3)C3(c5ccccc5O4)c4ccccc4-c4ccccc43)c3cccc4oc5ccccc5c34)cc1C2(c1ccccc1)c1ccccc1 ; [2H]c1c([2H])c([2H])c2c(c1[2H])-c1ccc(N(c3ccc4c(c3)C3(c5ccccc5O4)c4ccccc4-c4ccccc43)c3cccc4sc5ccccc5c34)cc1C2(c1ccccc1)c1ccccc1 ; CC1(C)c2ccccc2-c2ccc(N(c3ccc(-c4cccc5oc6ccccc6c45)c(-c4ccccc4)c3)c3ccc4c(c3)C3(c5ccccc5O4)c4ccccc4-c4ccccc43)cc21]

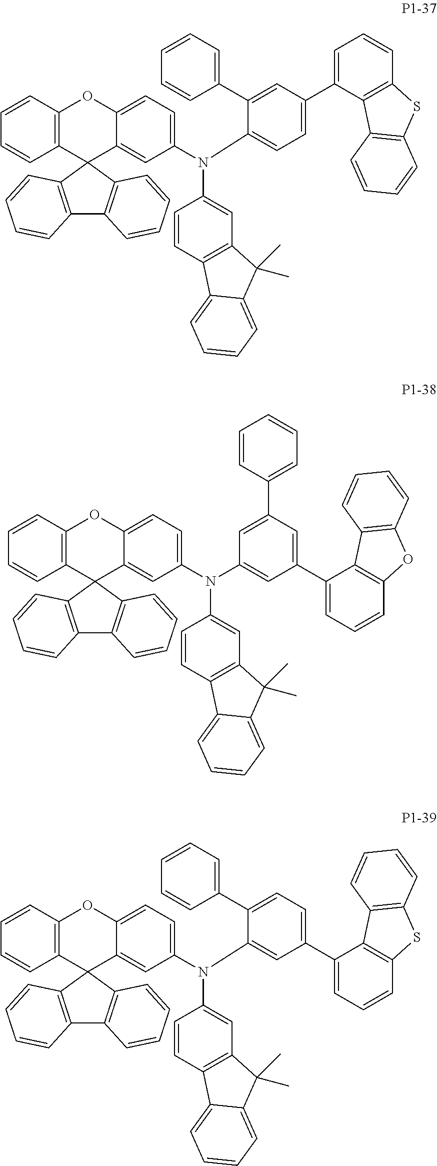 [SMILES: CC1(C)c2ccccc2-c2ccc(N(c3ccc4c(c3)C3(c5ccccc5O4)c4ccccc4-c4ccccc43)c3ccc(-c4cccc5sc6ccccc6c45)cc3-c3ccccc3)cc21 ; CC1(C)c2ccccc2-c2ccc(N(c3cc(-c4ccccc4)cc(-c4cccc5oc6ccccc6c45)c3)c3ccc4c(c3)C3(c5ccccc5O4)c4ccccc4-c4ccccc43)cc21 ; CC1(C)c2ccccc2-c2ccc(N(c3ccc4c(c3)C3(c5ccccc5O4)c4ccccc4-c4ccccc43)c3cc(-c4cccc5sc6ccccc6c45)ccc3-c3ccccc3)cc21]

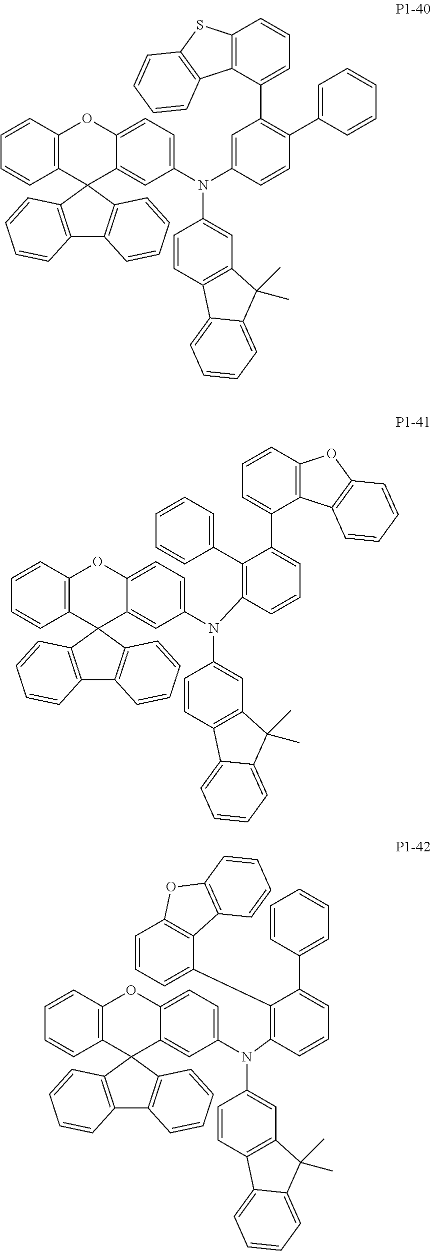

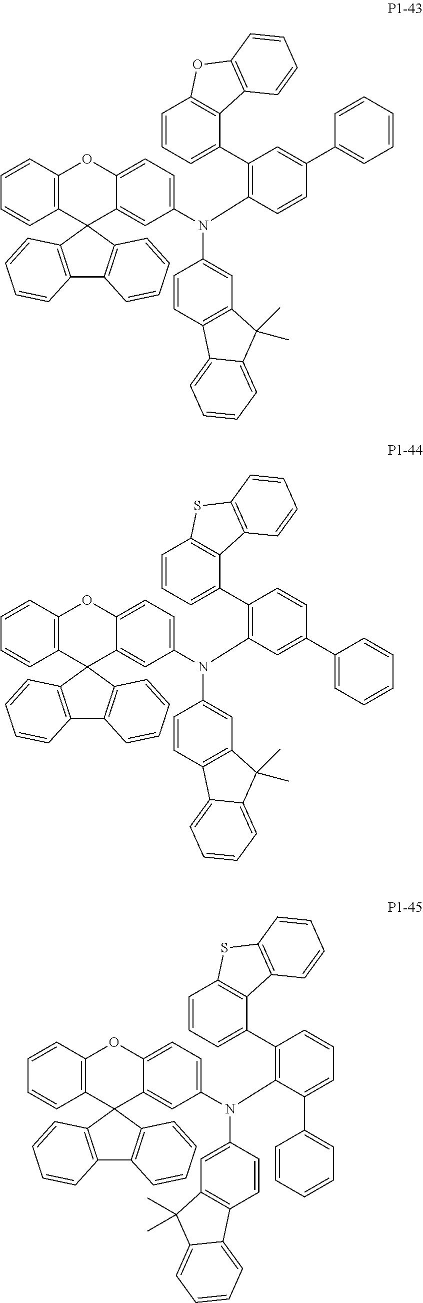 [SMILES: CC1(C)c2ccccc2-c2ccc(N(c3ccc4c(c3)C3(c5ccccc5O4)c4ccccc4-c4ccccc43)c3ccc(-c4ccccc4)cc3-c3cccc4oc5ccccc5c34)cc21 ; CC1(C)c2ccccc2-c2ccc(N(c3ccc4c(c3)C3(c5ccccc5O4)c4ccccc4-c4ccccc43)c3cc(-c4ccccc4)ccc3-c3cccc4sc5ccccc5c34)cc21 ; CC1(C)c2ccccc2-c2ccc(N(c3ccc4c(c3)C3(c5ccccc5O4)c4ccccc4-c4ccccc43)c3c(-c4ccccc4)cccc3-c3cccc4sc5ccccc5c34)cc21]

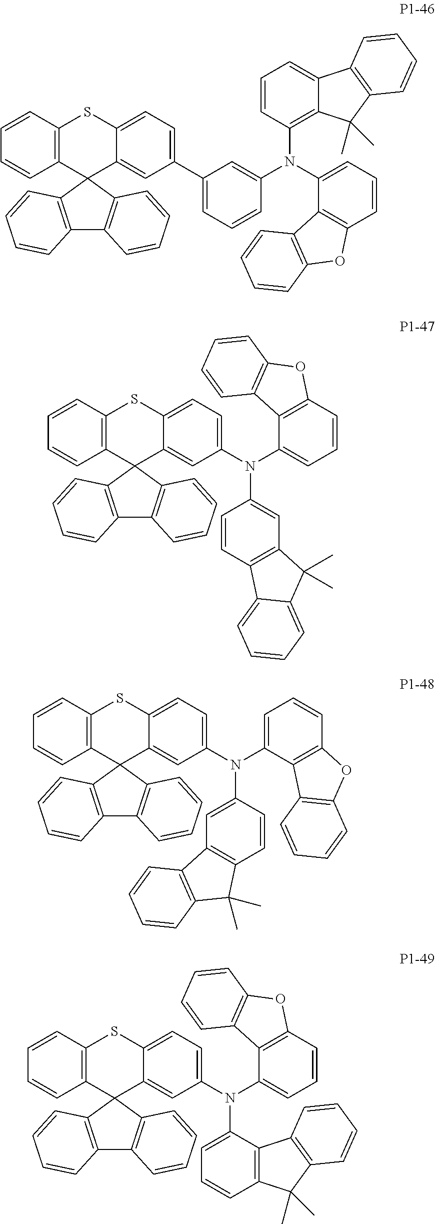

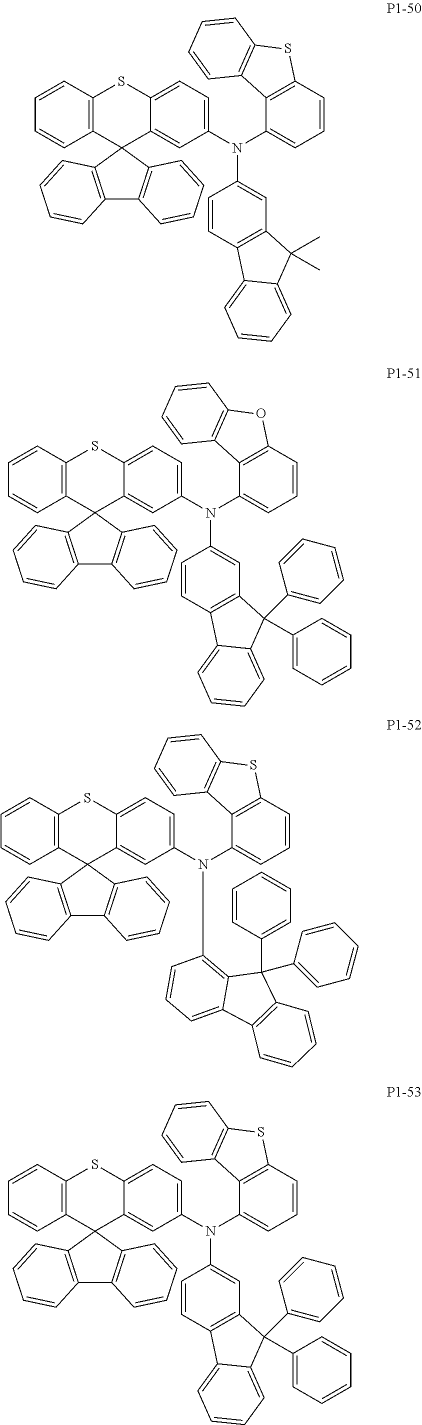

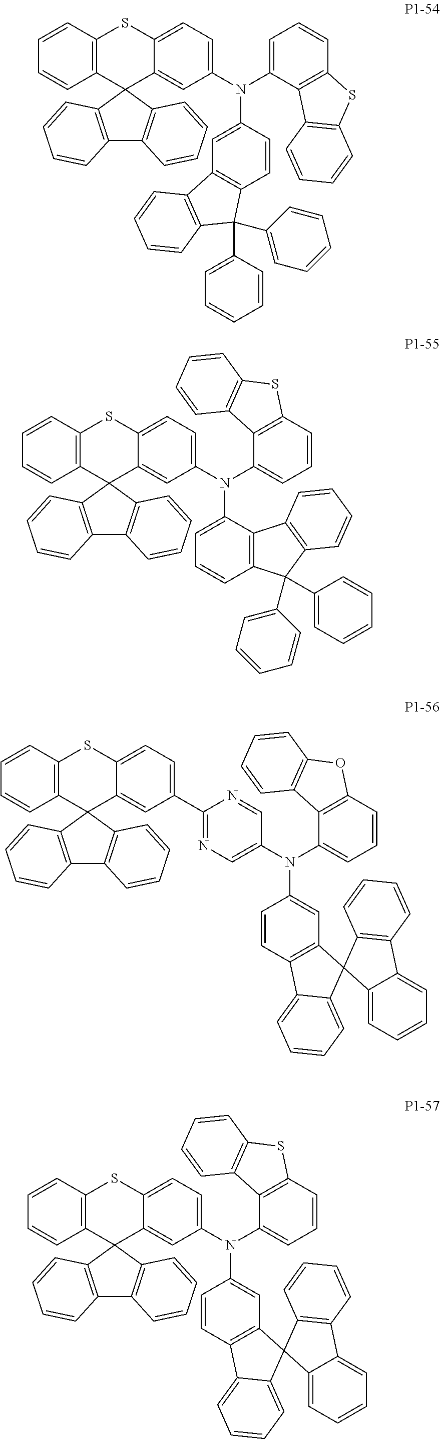

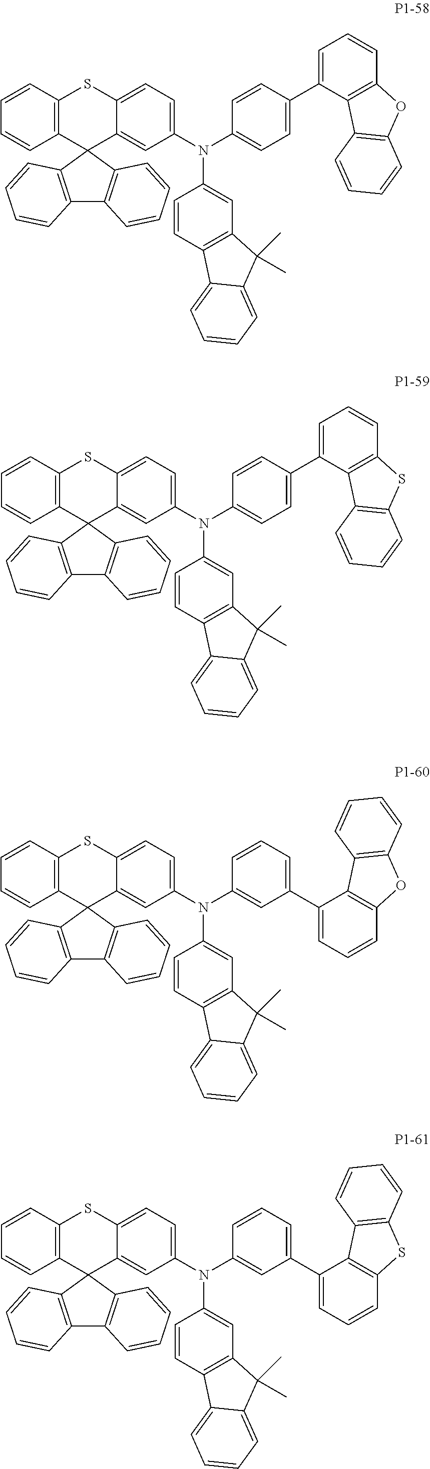 [SMILES: CC1(C)c2ccccc2-c2ccc(N(c3ccc(-c4cccc5oc6ccccc6c45)cc3)c3ccc4c(c3)C3(c5ccccc5S4)c4ccccc4-c4ccccc43)cc21 ; CC1(C)c2ccccc2-c2ccc(N(c3ccc(-c4cccc5sc6ccccc6c45)cc3)c3ccc4c(c3)C3(c5ccccc5S4)c4ccccc4-c4ccccc43)cc21 ; CC1(C)c2ccccc2-c2ccc(N(c3cccc(-c4cccc5oc6ccccc6c45)c3)c3ccc4c(c3)C3(c5ccccc5S4)c4ccccc4-c4ccccc43)cc21 ; CC1(C)c2ccccc2-c2ccc(N(c3cccc(-c4cccc5sc6ccccc6c45)c3)c3ccc4c(c3)C3(c5ccccc5S4)c4ccccc4-c4ccccc43)cc21]

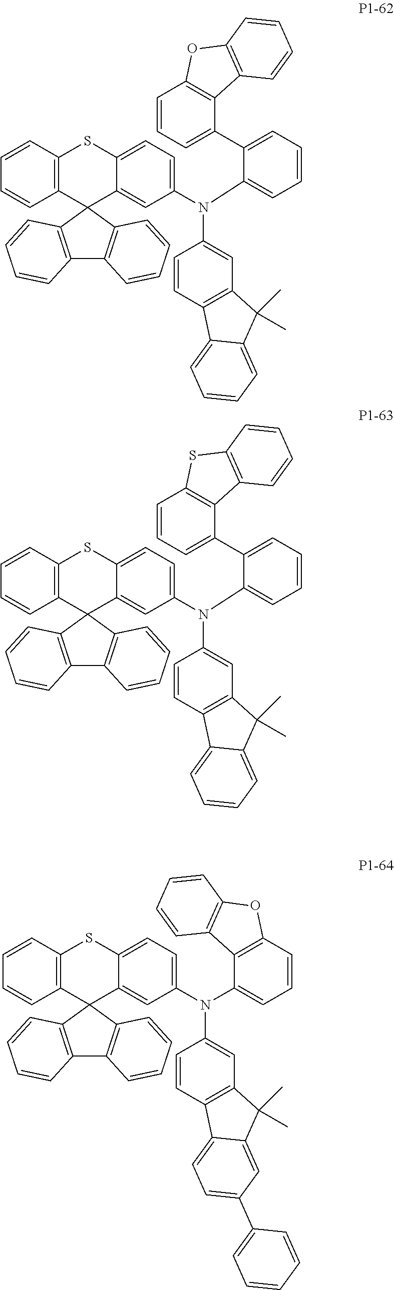

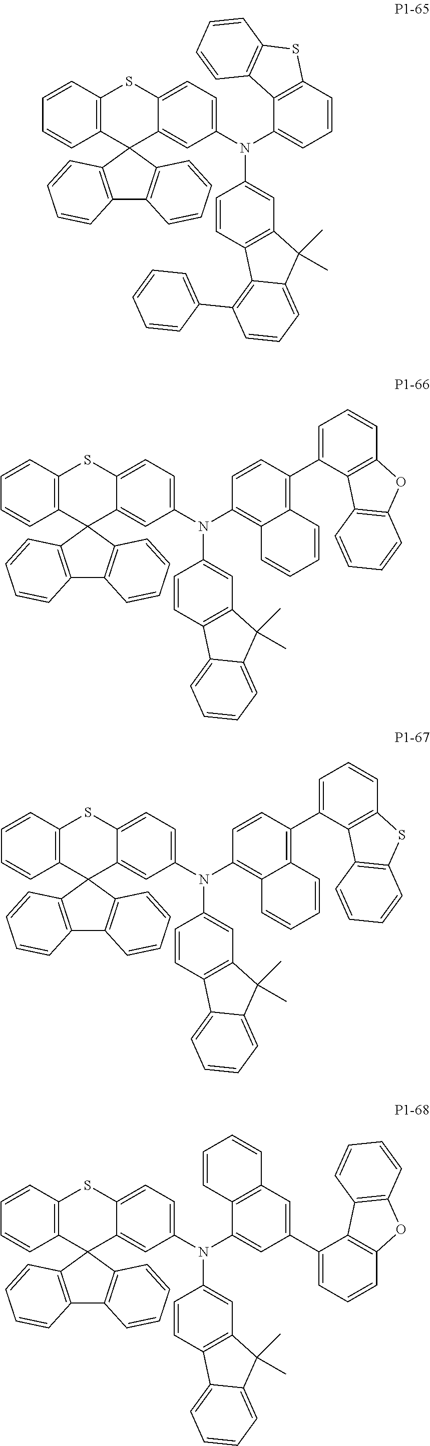 [SMILES: CC1(C)c2cc(N(c3ccc4c(c3)C3(c5ccccc5S4)c4ccccc4-c4ccccc43)c3cccc4sc5ccccc5c34)ccc2-c2c(-c3ccccc3)cccc21 ; CC1(C)c2ccccc2-c2ccc(N(c3ccc4c(c3)C3(c5ccccc5S4)c4ccccc4-c4ccccc43)c3ccc(-c4cccc5oc6ccccc6c45)c4ccccc34)cc21 ; CC1(C)c2ccccc2-c2ccc(N(c3ccc4c(c3)C3(c5ccccc5S4)c4ccccc4-c4ccccc43)c3ccc(-c4cccc5sc6ccccc6c45)c4ccccc34)cc21 ; CC1(C)c2ccccc2-c2ccc(N(c3ccc4c(c3)C3(c5ccccc5S4)c4ccccc4-c4ccccc43)c3cc(-c4cccc5oc6ccccc6c45)cc4ccccc34)cc21]

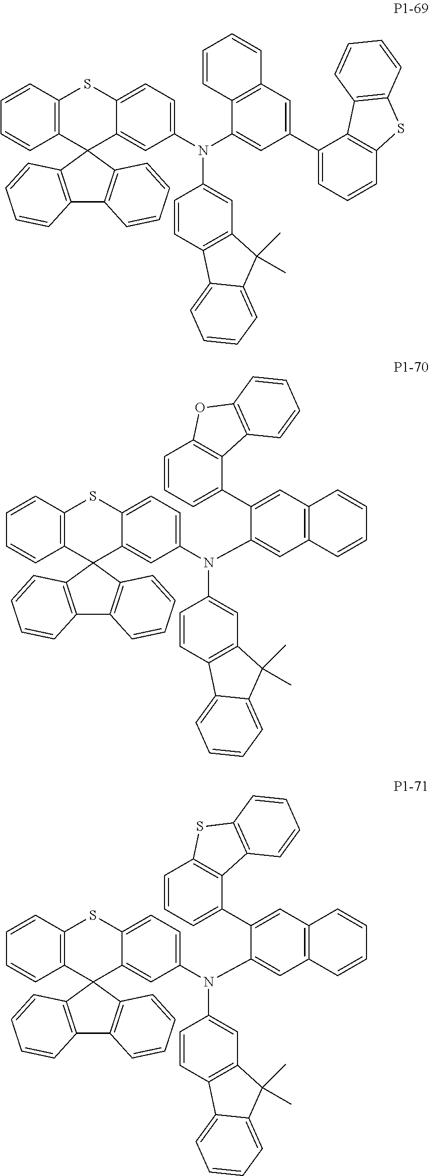

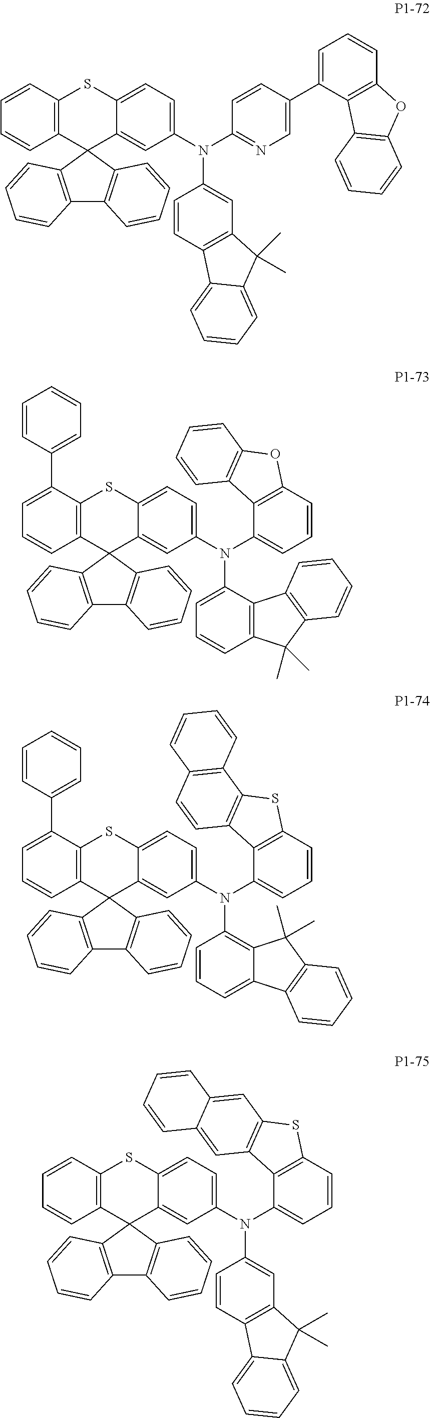 [SMILES: CC1(C)c2ccccc2-c2ccc(N(c3ccc4c(c3)C3(c5ccccc5S4)c4ccccc4-c4ccccc43)c3ccc(-c4cccc5oc6ccccc6c45)cn3)cc21 ; CC1(C)c2ccccc2-c2c(N(c3ccc4c(c3)C3(c5ccccc5-c5ccccc53)c3cccc(-c5ccccc5)c3S4)c3cccc4oc5ccccc5c34)cccc21 ; CC1(C)c2ccccc2-c2cccc(N(c3ccc4c(c3)C3(c5ccccc5-c5ccccc53)c3cccc(-c5ccccc5)c3S4)c3cccc4sc5c6ccccc6ccc5c34)c21 ; CC1(C)c2ccccc2-c2ccc(N(c3ccc4c(c3)C3(c5ccccc5S4)c4ccccc4-c4ccccc43)c3cccc4sc5cc6ccccc6cc5c34)cc21]

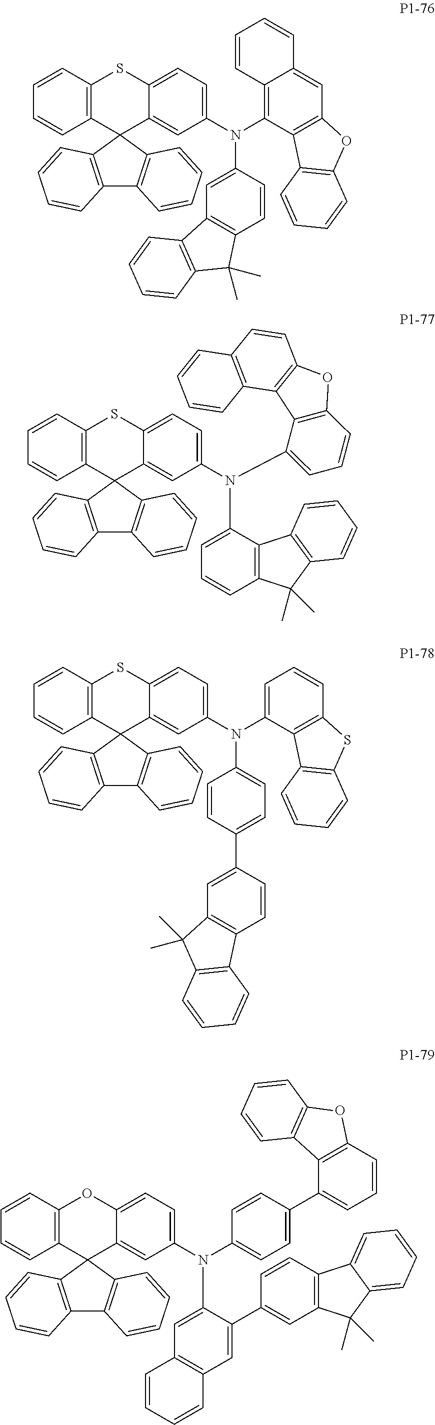

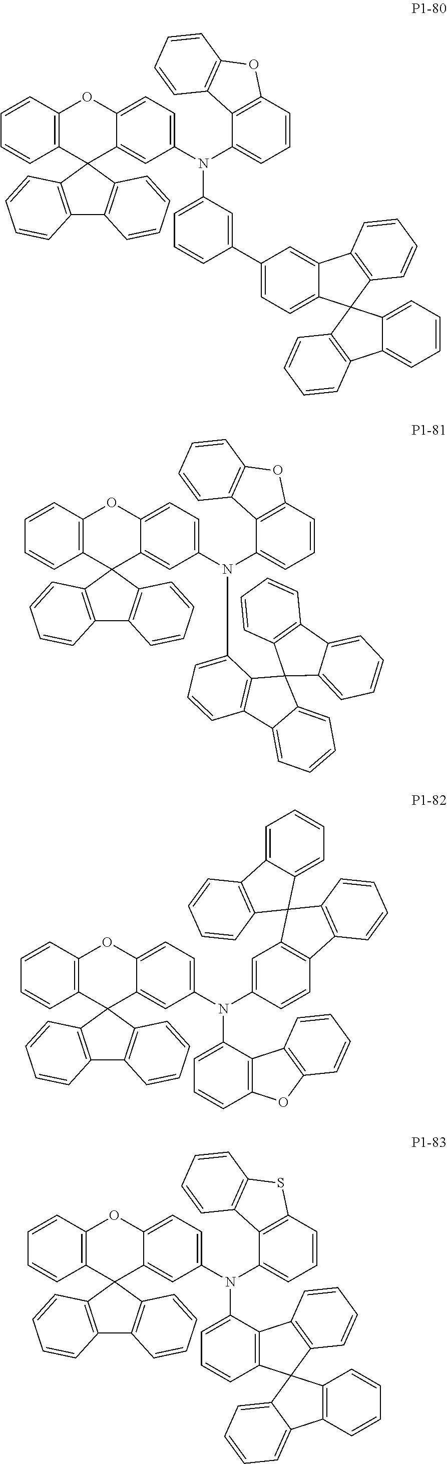

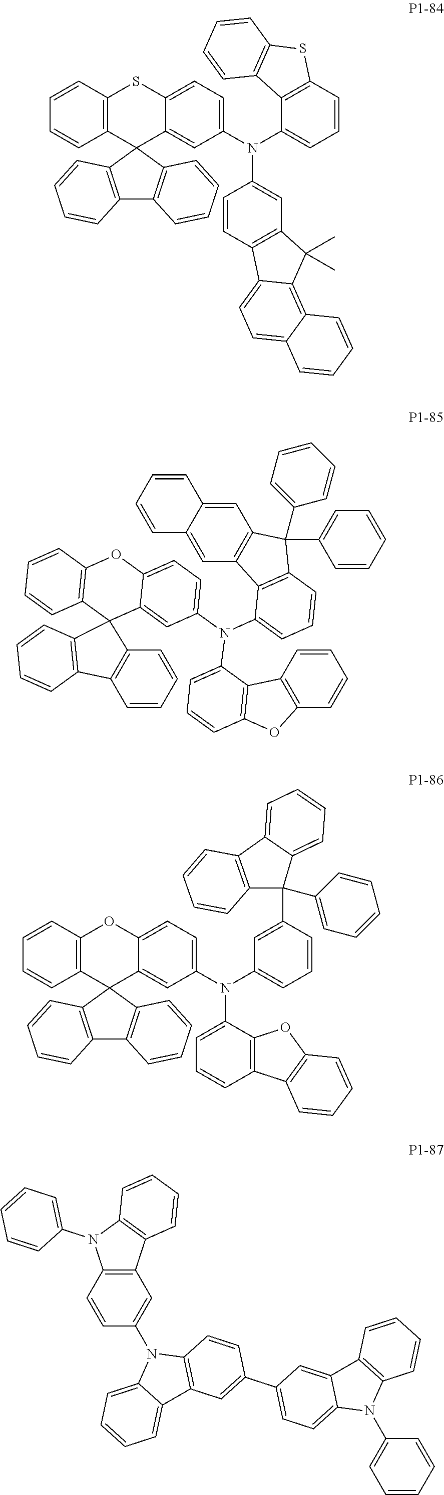 [SMILES: CC1(C)c2cc(N(c3ccc4c(c3)C3(c5ccccc5S4)c4ccccc4-c4ccccc43)c3cccc4sc5ccccc5c34)ccc2-c2ccc3ccccc3c21 ; c1ccc(C2(c3ccccc3)c3cc4ccccc4cc3-c3c(N(c4ccc5c(c4)C4(c6ccccc6O5)c5ccccc5-c5ccccc54)c4cccc5oc6ccccc6c45)cccc32)cc1 ; c1ccc(C2(c3cccc(N(c4ccc5c(c4)C4(c6ccccc6O5)c5ccccc5-c5ccccc54)c4cccc5c4oc4ccccc45)c3)c3ccccc3-c3ccccc32)cc1 ; c1ccc(-n2c3ccccc3c3cc(-c4ccc5c(c4)c4ccccc4n5-c4ccc5c(c4)c4ccccc4n5-c4ccccc4)ccc32)cc1]

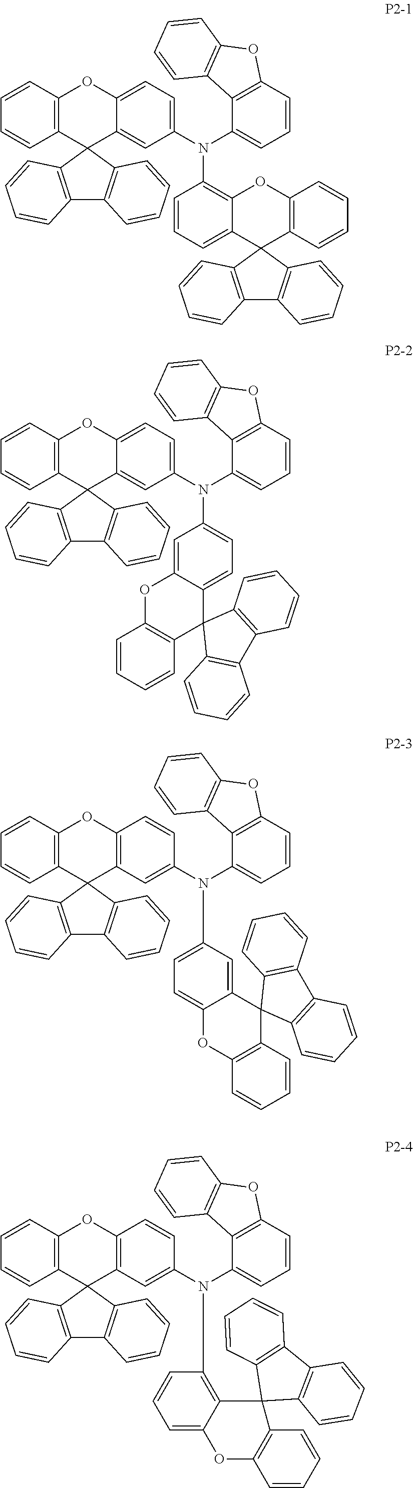

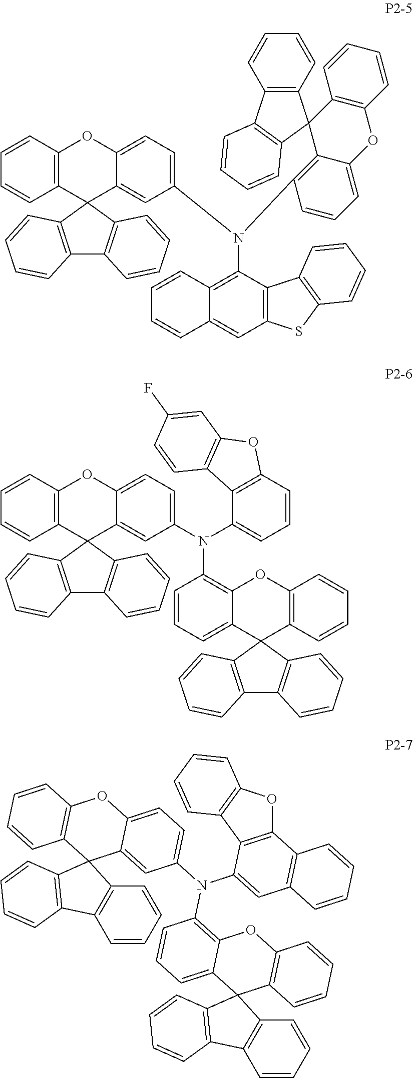

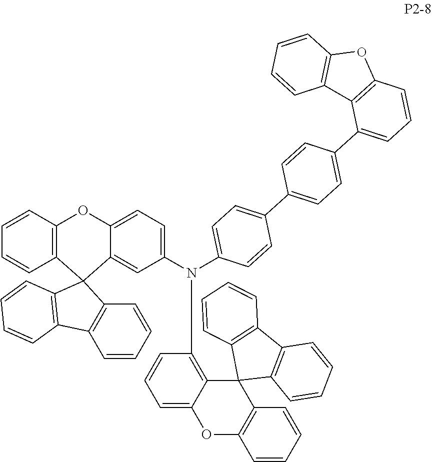 [SMILES: c1ccc2c(c1)Oc1ccc(N(c3ccc(-c4ccc(-c5cccc6oc7ccccc7c56)cc4)cc3)c3cccc4c3C3(c5ccccc5O4)c4ccccc4-c4ccccc43)cc1C21c2ccccc2-c2ccccc21]

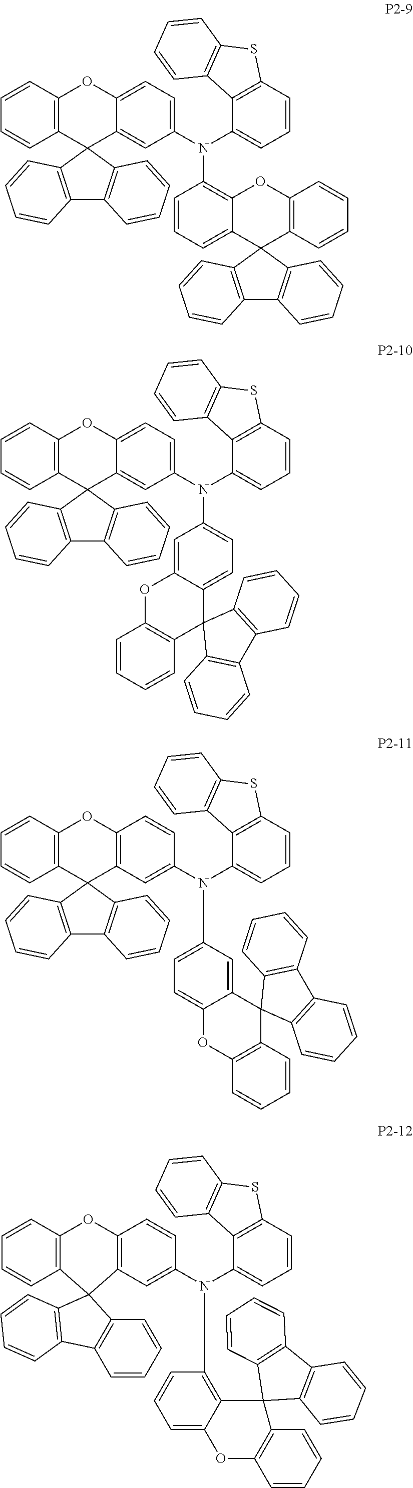

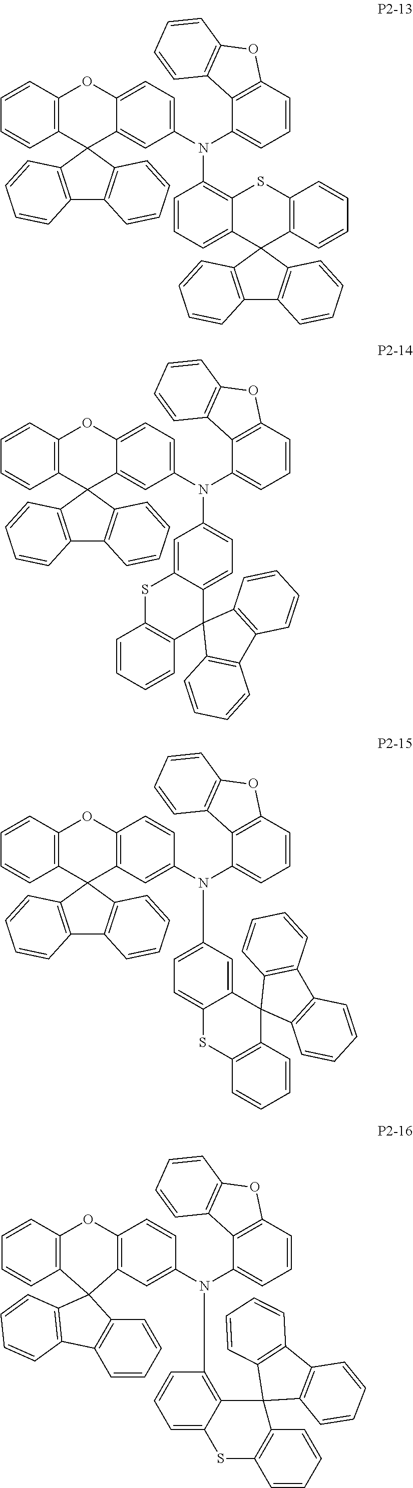

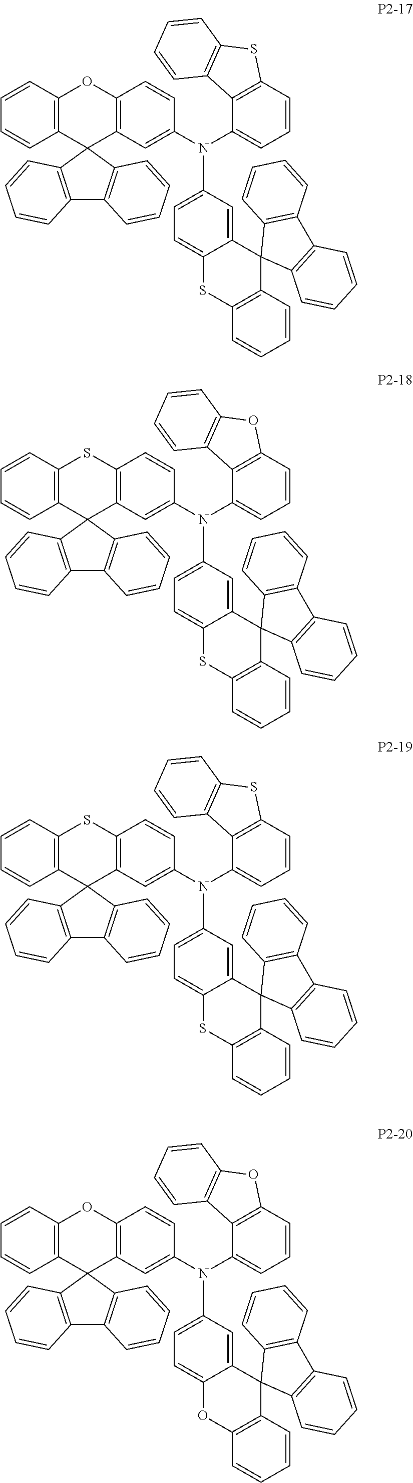 [SMILES: c1ccc2c(c1)Oc1ccc(N(c3ccc4c(c3)C3(c5ccccc5S4)c4ccccc4-c4ccccc43)c3cccc4sc5ccccc5c34)cc1C21c2ccccc2-c2ccccc21 ; c1ccc2c(c1)Sc1ccc(N(c3ccc4c(c3)C3(c5ccccc5S4)c4ccccc4-c4ccccc43)c3cccc4oc5ccccc5c34)cc1C21c2ccccc2-c2ccccc21 ; c1ccc2c(c1)Sc1ccc(N(c3ccc4c(c3)C3(c5ccccc5S4)c4ccccc4-c4ccccc43)c3cccc4sc5ccccc5c34)cc1C21c2ccccc2-c2ccccc21 ; c1ccc2c(c1)Oc1ccc(N(c3ccc4c(c3)C3(c5ccccc5O4)c4ccccc4-c4ccccc43)c3cccc4oc5ccccc5c34)cc1C21c2ccccc2-c2ccccc21]

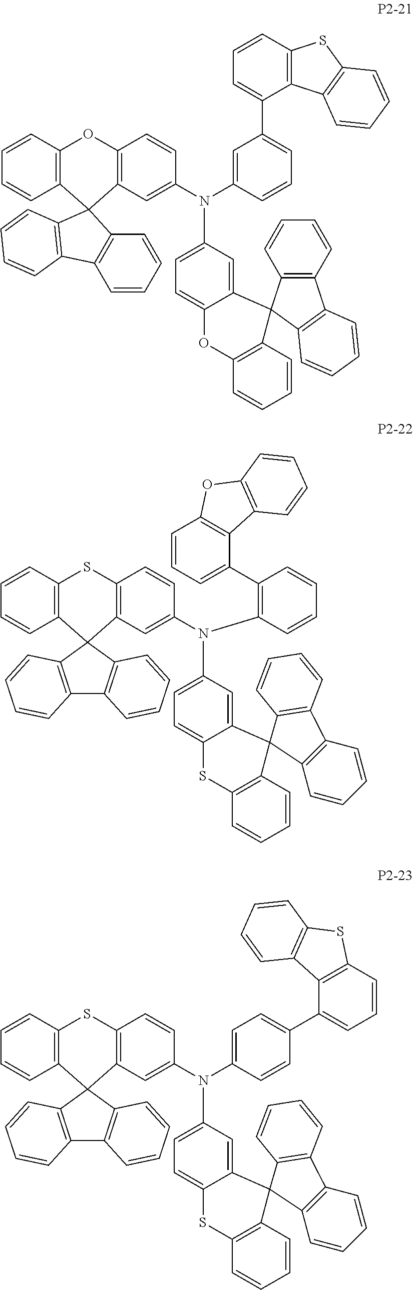

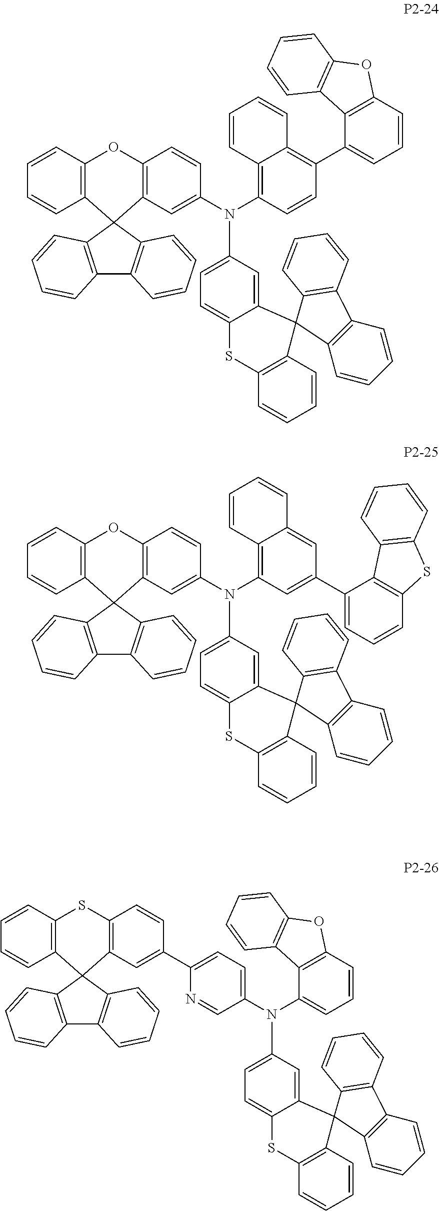 [SMILES: c1ccc2c(c1)Oc1ccc(N(c3ccc4c(c3)C3(c5ccccc5S4)c4ccccc4-c4ccccc43)c3ccc(-c4cccc5oc6ccccc6c45)c4ccccc34)cc1C21c2ccccc2-c2ccccc21 ; c1ccc2c(c1)Oc1ccc(N(c3ccc4c(c3)C3(c5ccccc5S4)c4ccccc4-c4ccccc43)c3cc(-c4cccc5sc6ccccc6c45)cc4ccccc34)cc1C21c2ccccc2-c2ccccc21 ; c1ccc2c(c1)Sc1ccc(-c3ccc(N(c4ccc5c(c4)C4(c6ccccc6S5)c5ccccc5-c5ccccc54)c4cccc5oc6ccccc6c45)cn3)cc1C21c2ccccc2-c2ccccc21]

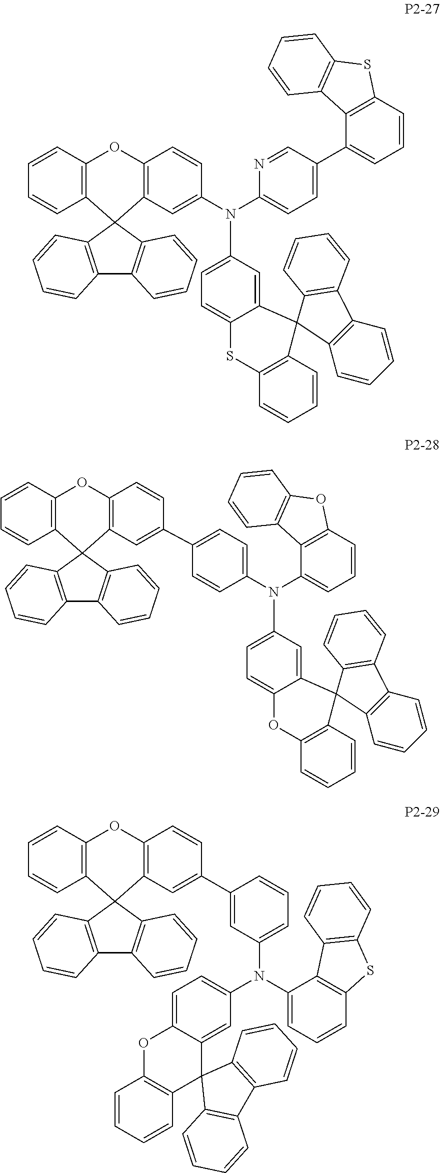 [SMILES: c1ccc2c(c1)Oc1ccc(N(c3ccc4c(c3)C3(c5ccccc5S4)c4ccccc4-c4ccccc43)c3ccc(-c4cccc5sc6ccccc6c45)cn3)cc1C21c2ccccc2-c2ccccc21 ; c1ccc2c(c1)Oc1ccc(-c3ccc(N(c4ccc5c(c4)C4(c6ccccc6O5)c5ccccc5-c5ccccc54)c4cccc5oc6ccccc6c45)cc3)cc1C21c2ccccc2-c2ccccc21 ; c1cc(-c2ccc3c(c2)C2(c4ccccc4O3)c3ccccc3-c3ccccc32)cc(N(c2ccc3c(c2)C2(c4ccccc4O3)c3ccccc3-c3ccccc32)c2cccc3sc4ccccc4c23)c1]

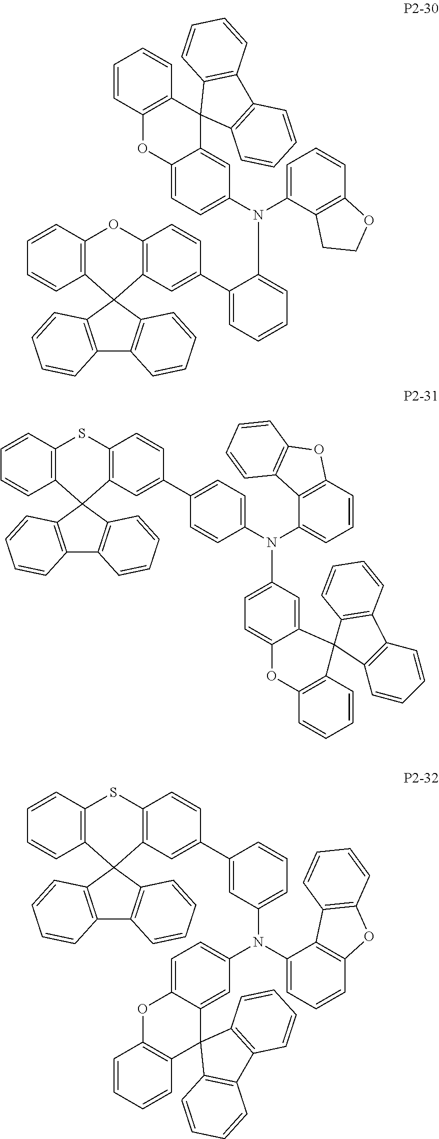 [SMILES: c1ccc2c(c1)Oc1ccc(-c3ccccc3N(c3ccc4c(c3)C3(c5ccccc5O4)c4ccccc4-c4ccccc43)c3cccc4c3CCO4)cc1C21c2ccccc2-c2ccccc21 ; c1ccc2c(c1)Oc1ccc(N(c3ccc(-c4ccc5c(c4)C4(c6ccccc6S5)c5ccccc5-c5ccccc54)cc3)c3cccc4oc5ccccc5c34)cc1C21c2ccccc2-c2ccccc21 ; c1cc(-c2ccc3c(c2)C2(c4ccccc4S3)c3ccccc3-c3ccccc32)cc(N(c2ccc3c(c2)C2(c4ccccc4O3)c3ccccc3-c3ccccc32)c2cccc3oc4ccccc4c23)c1]

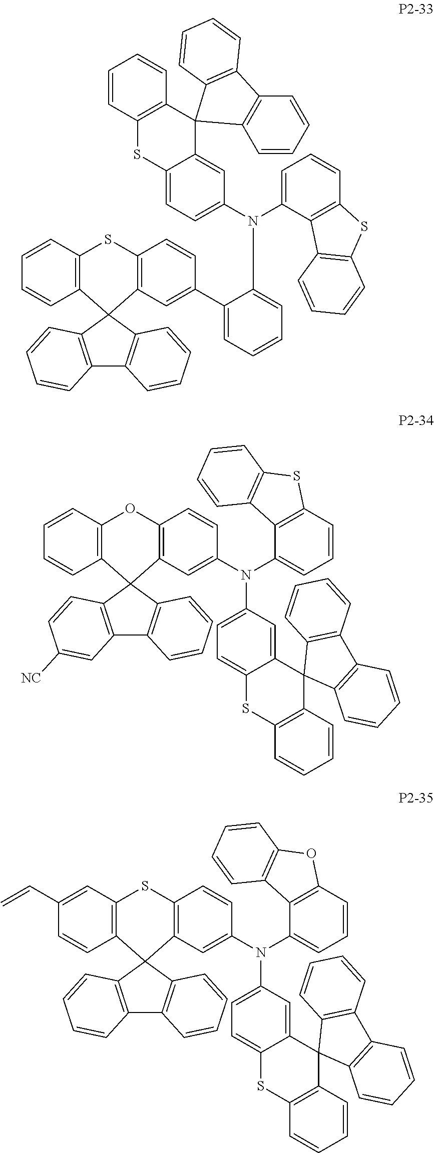 [SMILES: c1ccc2c(c1)Sc1ccc(-c3ccccc3N(c3ccc4c(c3)C3(c5ccccc5S4)c4ccccc4-c4ccccc43)c3cccc4sc5ccccc5c34)cc1C21c2ccccc2-c2ccccc21 ; N#Cc1ccc2c(c1)-c1ccccc1C21c2ccccc2Oc2ccc(N(c3ccc4c(c3)C3(c5ccccc5S4)c4ccccc4-c4ccccc43)c3cccc4sc5ccccc5c34)cc21 ; C=Cc1ccc2c(c1)Sc1ccc(N(c3ccc4c(c3)C3(c5ccccc5S4)c4ccccc4-c4ccccc43)c3cccc4oc5ccccc5c34)cc1C21c2ccccc2-c2ccccc21]

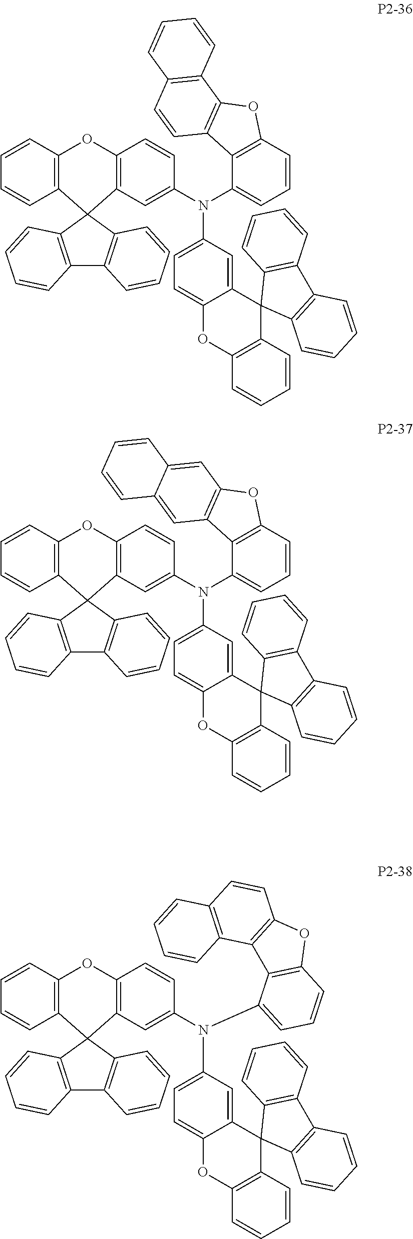 [SMILES: c1ccc2c(c1)Oc1ccc(N(c3ccc4c(c3)C3(c5ccccc5O4)c4ccccc4-c4ccccc43)c3cccc4oc5c6ccccc6ccc5c34)cc1C21c2ccccc2-c2ccccc21 ; c1ccc2c(c1)Oc1ccc(N(c3ccc4c(c3)C3(c5ccccc5O4)c4ccccc4-c4ccccc43)c3cccc4oc5cc6ccccc6cc5c34)cc1C21c2ccccc2-c2ccccc21 ; c1ccc2c(c1)Oc1ccc(N(c3ccc4c(c3)C3(c5ccccc5O4)c4ccccc4-c4ccccc43)c3cccc4oc5ccc6ccccc6c5c34)cc1C21c2ccccc2-c2ccccc21]

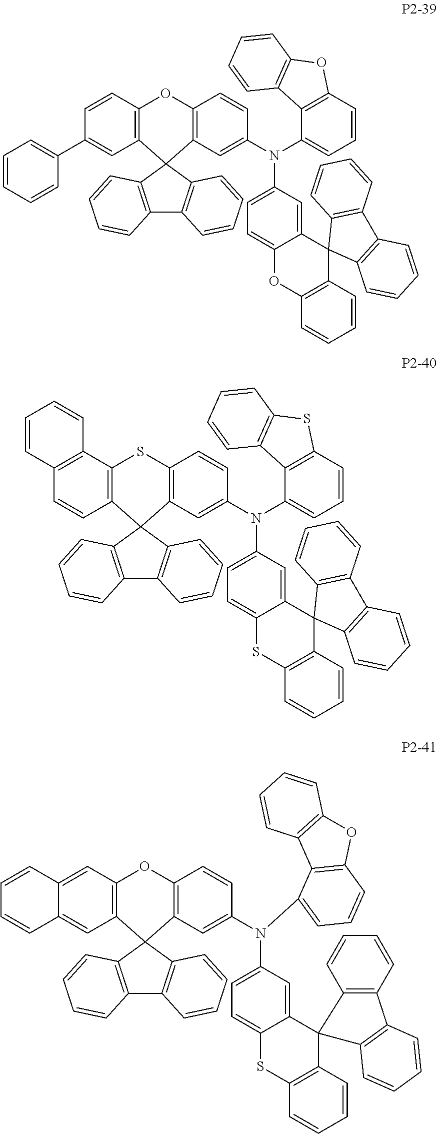 [SMILES: c1ccc(-c2ccc3c(c2)C2(c4cc(N(c5ccc6c(c5)C5(c7ccccc7O6)c6ccccc6-c6ccccc65)c5cccc6oc7ccccc7c56)ccc4O3)c3ccccc3-c3ccccc32)cc1 ; c1ccc2c(c1)Sc1ccc(N(c3ccc4c(c3)C3(c5ccccc5-c5ccccc53)c3ccc5ccccc5c3S4)c3cccc4sc5ccccc5c34)cc1C21c2ccccc2-c2ccccc21 ; c1ccc2c(c1)Sc1ccc(N(c3ccc4c(c3)C3(c5cc6ccccc6cc5O4)c4ccccc4-c4ccccc43)c3cccc4oc5ccccc5c34)cc1C21c2ccccc2-c2ccccc21]

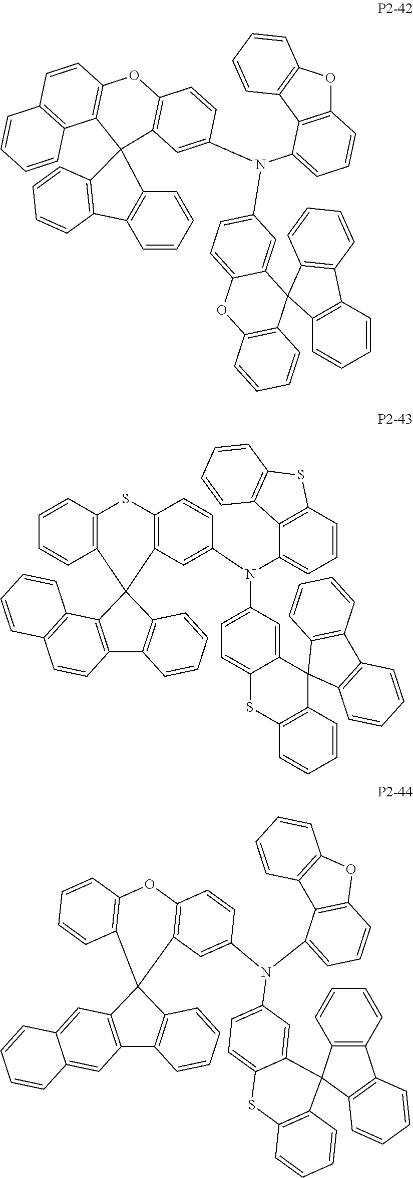 [SMILES: c1ccc2c(c1)Oc1ccc(N(c3ccc4c(c3)C3(c5ccccc5-c5ccccc53)c3c(ccc5ccccc35)O4)c3cccc4oc5ccccc5c34)cc1C21c2ccccc2-c2ccccc21 ; c1ccc2c(c1)Sc1ccc(N(c3ccc4c(c3)C3(c5ccccc5S4)c4ccccc4-c4ccc5ccccc5c43)c3cccc4sc5ccccc5c34)cc1C21c2ccccc2-c2ccccc21 ; c1ccc2c(c1)Oc1ccc(N(c3ccc4c(c3)C3(c5ccccc5S4)c4ccccc4-c4ccccc43)c3cccc4oc5ccccc5c34)cc1C21c2ccccc2-c2cc3ccccc3cc21]

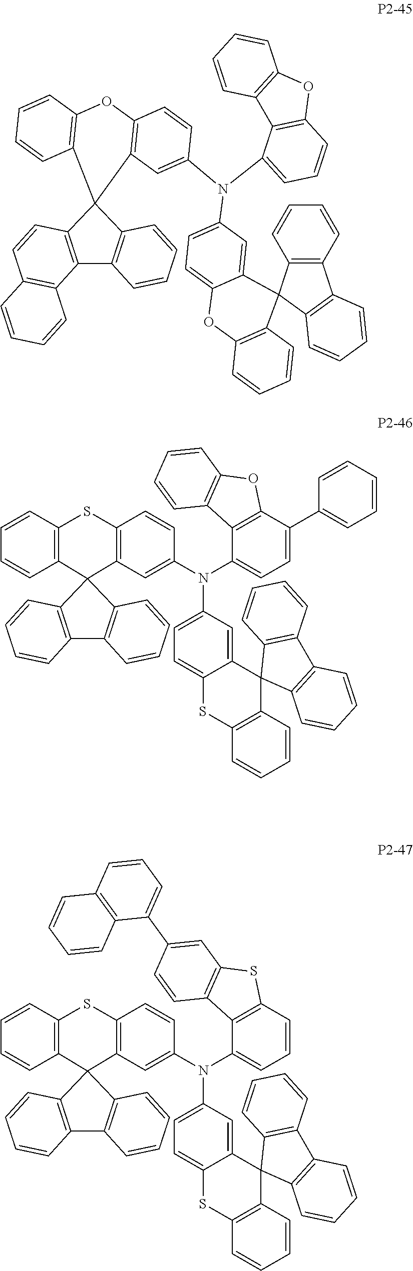 [SMILES: c1ccc2c(c1)Oc1ccc(N(c3ccc4c(c3)C3(c5ccccc5O4)c4ccccc4-c4c3ccc3ccccc43)c3cccc4oc5ccccc5c34)cc1C21c2ccccc2-c2ccccc21 ; c1ccc(-c2ccc(N(c3ccc4c(c3)C3(c5ccccc5S4)c4ccccc4-c4ccccc43)c3ccc4c(c3)C3(c5ccccc5S4)c4ccccc4-c4ccccc43)c3c2oc2ccccc23)cc1 ; c1ccc2c(c1)Sc1ccc(N(c3ccc4c(c3)C3(c5ccccc5S4)c4ccccc4-c4ccccc43)c3cccc4sc5cc(-c6cccc7ccccc67)ccc5c34)cc1C21c2ccccc2-c2ccccc21]

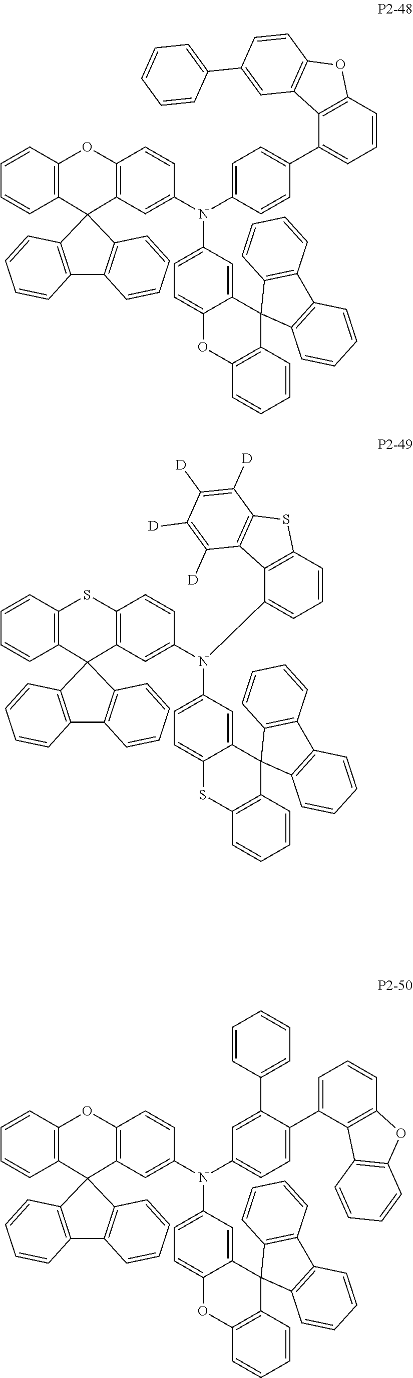

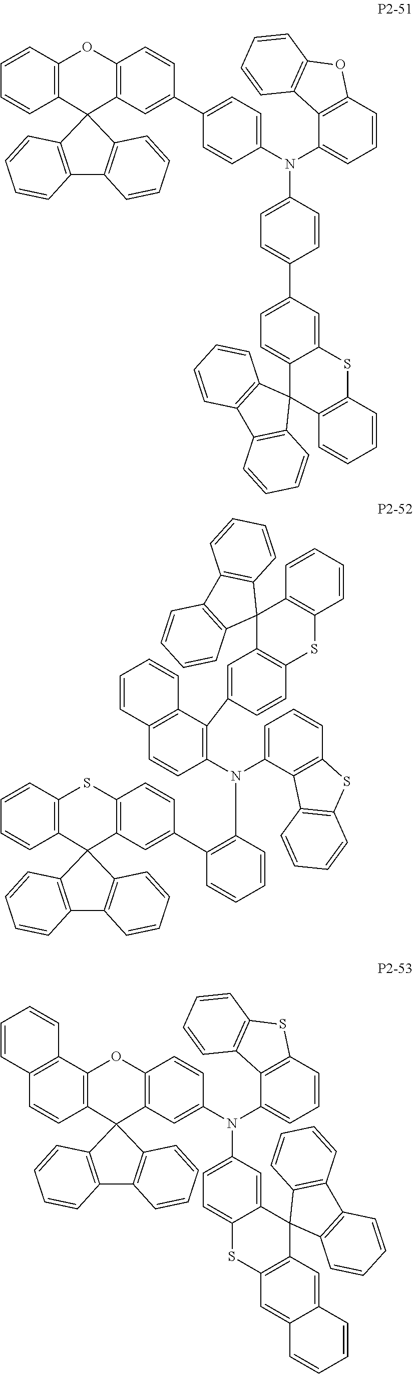

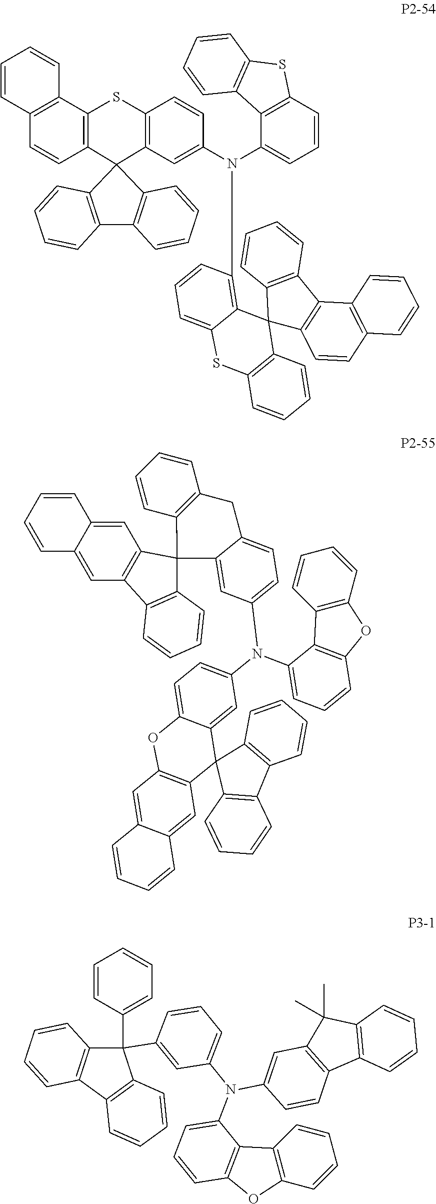 [SMILES: c1ccc2c(c1)Sc1cccc(N(c3ccc4c(c3)C3(c5ccccc5-c5ccccc53)c3ccc5ccccc5c3S4)c3cccc4sc5ccccc5c34)c1C21c2ccccc2-c2c1ccc1ccccc21 ; c1ccc2c(c1)Cc1ccc(N(c3ccc4c(c3)C3(c5cc6ccccc6cc5O4)c4ccccc4-c4ccccc43)c3cccc4oc5ccccc5c34)cc1C21c2ccccc2-c2cc3ccccc3cc21 ; CC1(C)c2ccccc2-c2ccc(N(c3cccc(C4(c5ccccc5)c5ccccc5-c5ccccc54)c3)c3cccc4oc5ccccc5c34)cc21]

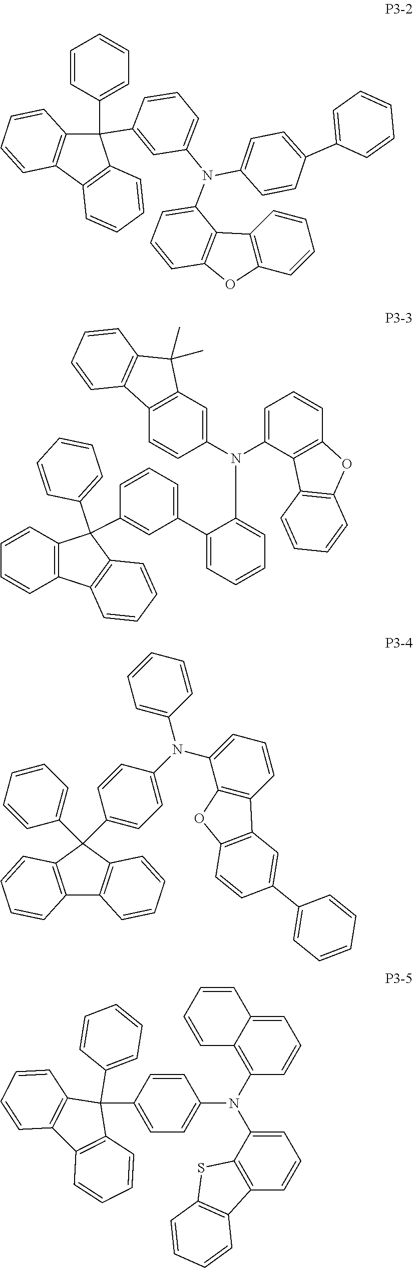

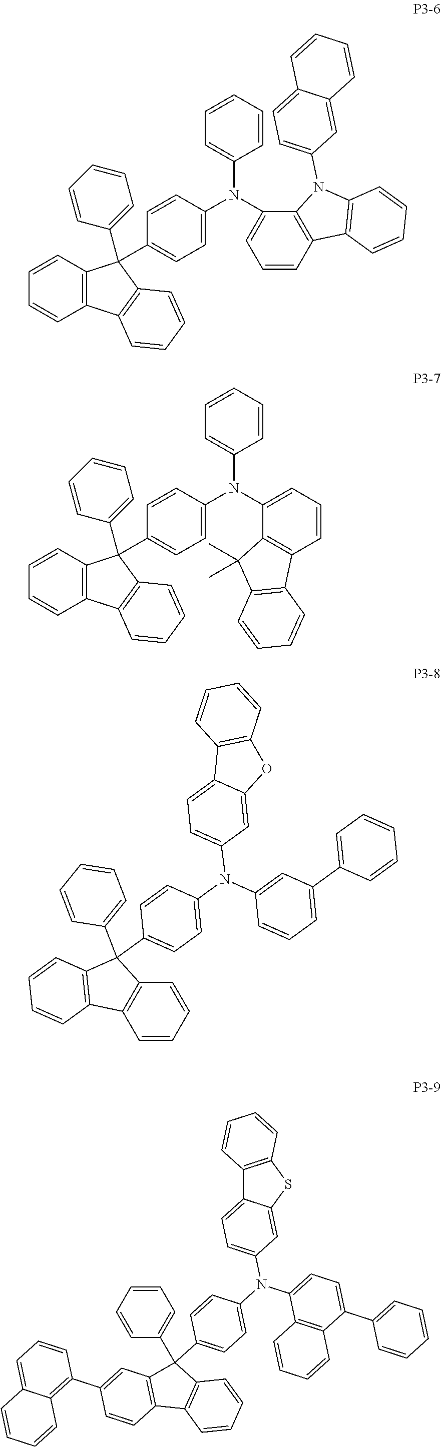

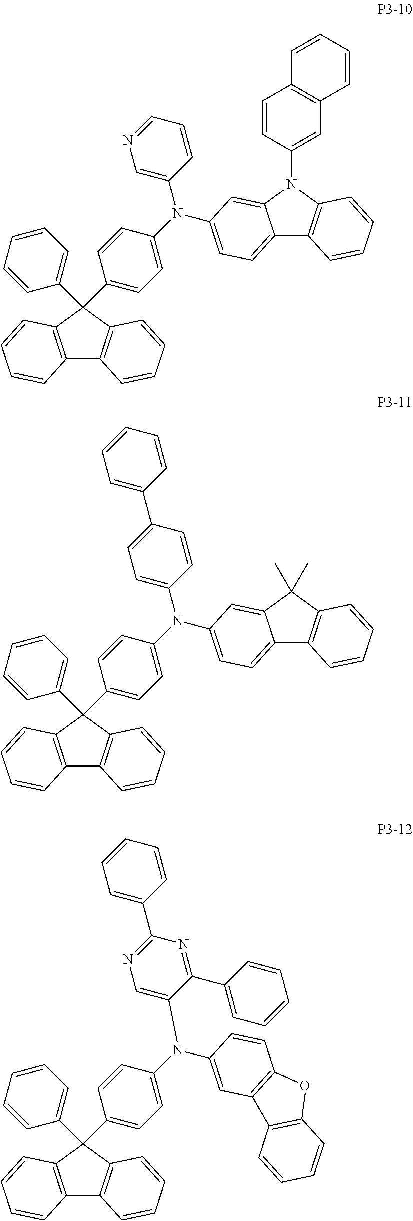

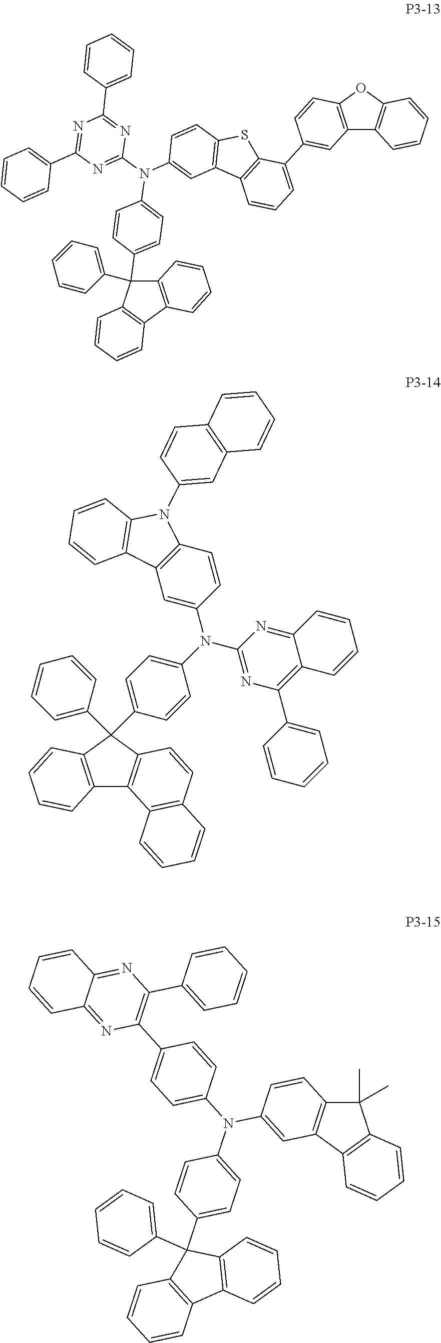 [SMILES: c1ccc(-c2nc(-c3ccccc3)nc(N(c3ccc(C4(c5ccccc5)c5ccccc5-c5ccccc54)cc3)c3ccc4sc5c(-c6ccc7oc8ccccc8c7c6)cccc5c4c3)n2)cc1 ; c1ccc(-c2nc(N(c3ccc(C4(c5ccccc5)c5ccccc5-c5c4ccc4ccccc54)cc3)c3ccc4c(c3)c3ccccc3n4-c3ccc4ccccc4c3)nc3ccccc23)cc1 ; CC1(C)c2ccccc2-c2cc(N(c3ccc(-c4nc5ccccc5nc4-c4ccccc4)cc3)c3ccc(C4(c5ccccc5)c5ccccc5-c5ccccc54)cc3)ccc21]

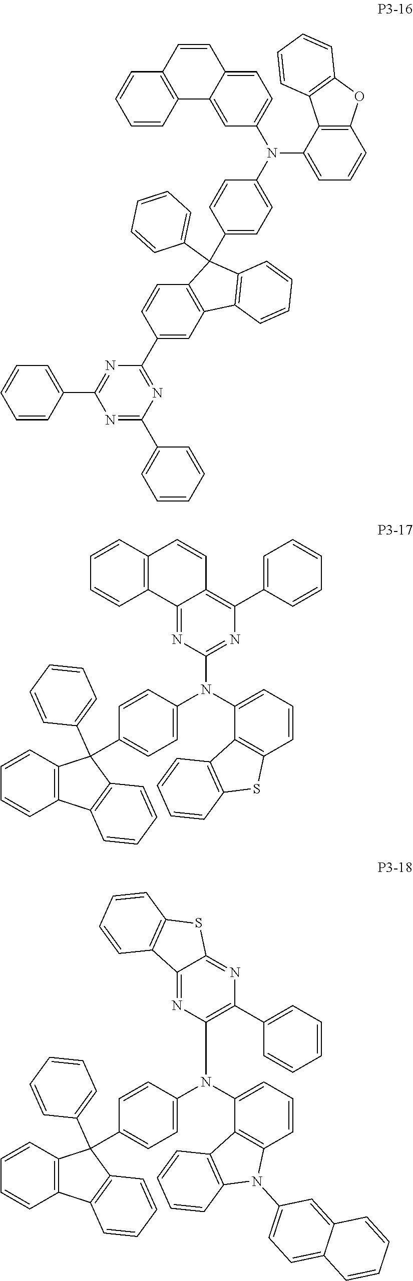

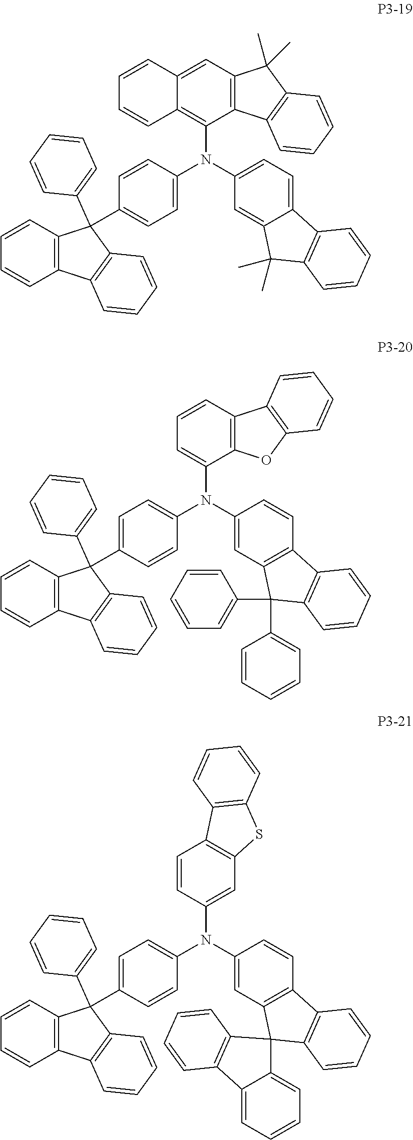 [SMILES: CC1(C)c2ccccc2-c2ccc(N(c3ccc(C4(c5ccccc5)c5ccccc5-c5ccccc54)cc3)c3c4c(cc5ccccc35)C(C)(C)c3ccccc3-4)cc21 ; c1ccc(C2(c3ccc(N(c4ccc5c(c4)C(c4ccccc4)(c4ccccc4)c4ccccc4-5)c4cccc5c4oc4ccccc45)cc3)c3ccccc3-c3ccccc32)cc1 ; c1ccc(C2(c3ccc(N(c4ccc5c(c4)C4(c6ccccc6-c6ccccc64)c4ccccc4-5)c4ccc5c(c4)sc4ccccc45)cc3)c3ccccc3-c3ccccc32)cc1]

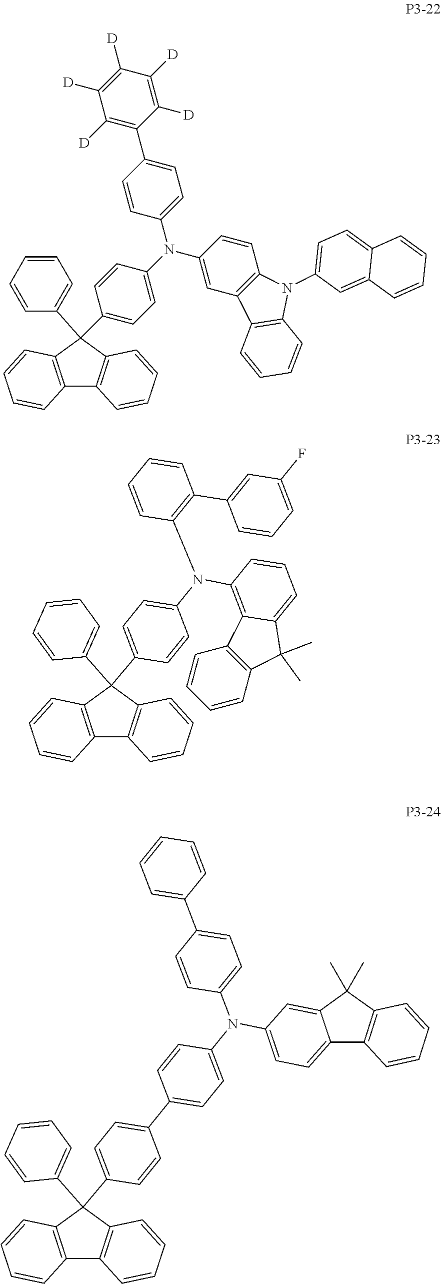 [SMILES: [2H]c1c([2H])c([2H])c(-c2ccc(N(c3ccc(C4(c5ccccc5)c5ccccc5-c5ccccc54)cc3)c3ccc4c(c3)c3ccccc3n4-c3ccc4ccccc4c3)cc2)c([2H])c1[2H] ; CC1(C)c2ccccc2-c2c(N(c3ccc(C4(c5ccccc5)c5ccccc5-c5ccccc54)cc3)c3ccccc3-c3cccc(F)c3)cccc21 ; CC1(C)c2ccccc2-c2ccc(N(c3ccc(-c4ccccc4)cc3)c3ccc(-c4ccc(C5(c6ccccc6)c6ccccc6-c6ccccc65)cc4)cc3)cc21]

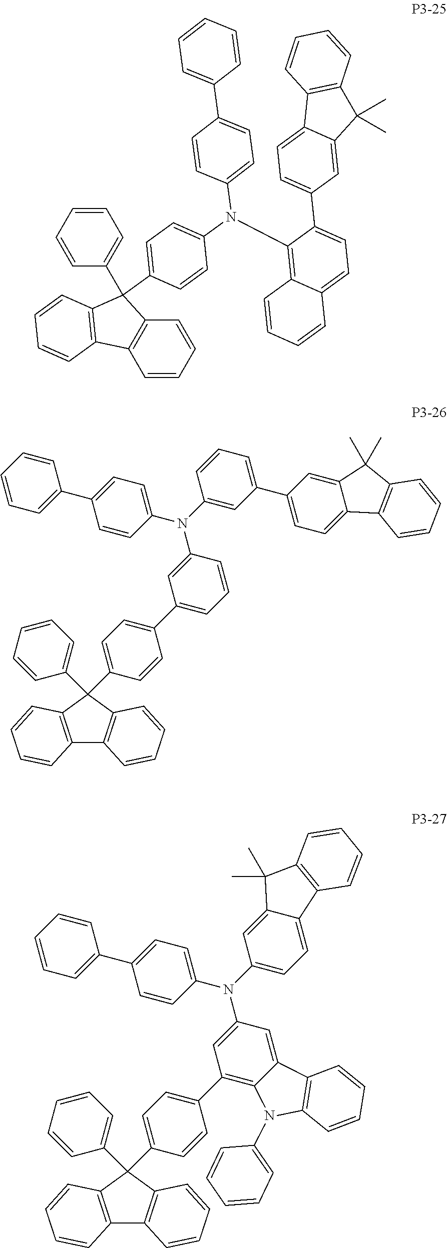 [SMILES: CC1(C)c2ccccc2-c2ccc(-c3ccc4ccccc4c3N(c3ccc(-c4ccccc4)cc3)c3ccc(C4(c5ccccc5)c5ccccc5-c5ccccc54)cc3)cc21 ; CC1(C)c2ccccc2-c2ccc(-c3cccc(N(c4ccc(-c5ccccc5)cc4)c4cccc(-c5ccc(C6(c7ccccc7)c7ccccc7-c7ccccc76)cc5)c4)c3)cc21 ; CC1(C)c2ccccc2-c2ccc(N(c3ccc(-c4ccccc4)cc3)c3cc(-c4ccc(C5(c6ccccc6)c6ccccc6-c6ccccc65)cc4)c4c(c3)c3ccccc3n4-c3ccccc3)cc21]

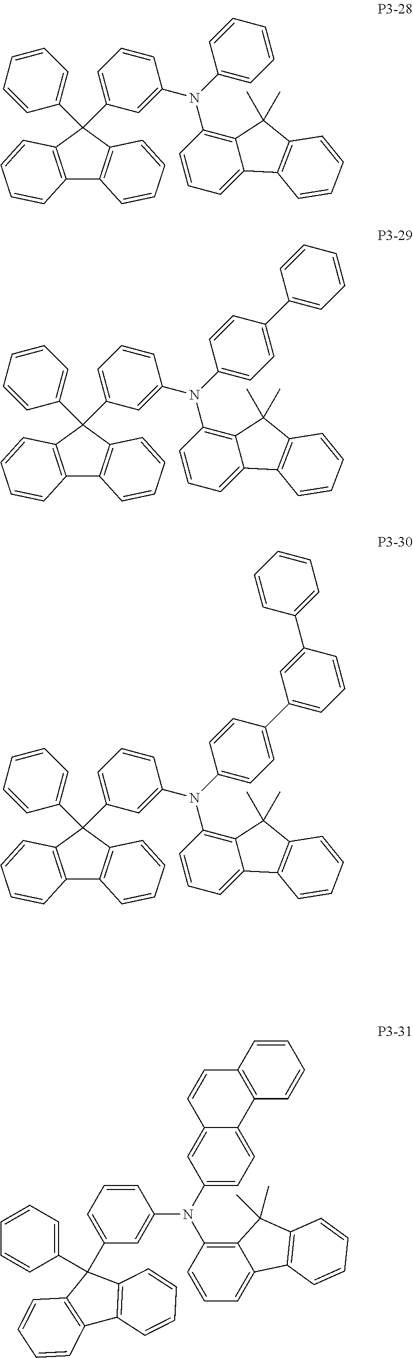 [SMILES: CC1(C)c2ccccc2-c2cccc(N(c3ccccc3)c3cccc(C4(c5ccccc5)c5ccccc5-c5ccccc54)c3)c21 ; CC1(C)c2ccccc2-c2cccc(N(c3ccc(-c4ccccc4)cc3)c3cccc(C4(c5ccccc5)c5ccccc5-c5ccccc54)c3)c21 ; CC1(C)c2ccccc2-c2cccc(N(c3ccc(-c4cccc(-c5ccccc5)c4)cc3)c3cccc(C4(c5ccccc5)c5ccccc5-c5ccccc54)c3)c21 ; CC1(C)c2ccccc2-c2cccc(N(c3cccc(C4(c5ccccc5)c5ccccc5-c5ccccc54)c3)c3ccc4c(ccc5ccccc54)c3)c21]

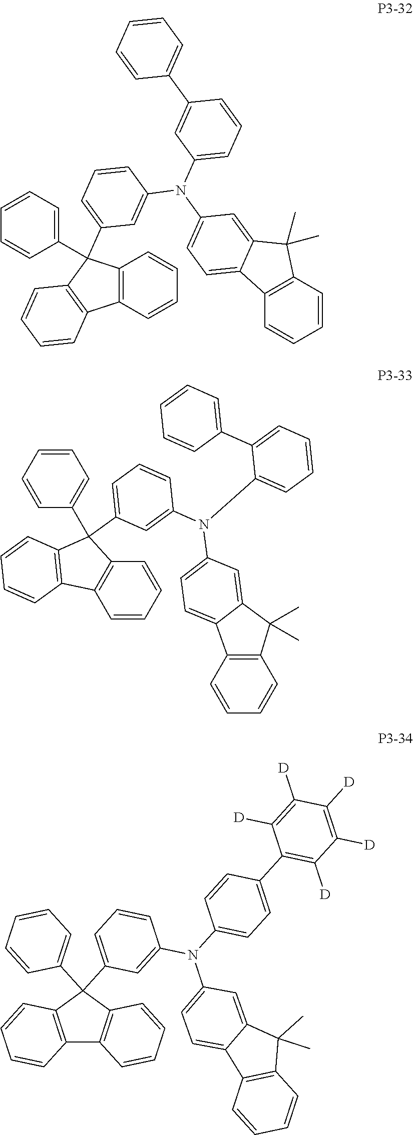 [SMILES: CC1(C)c2ccccc2-c2ccc(N(c3cccc(-c4ccccc4)c3)c3cccc(C4(c5ccccc5)c5ccccc5-c5ccccc54)c3)cc21 ; CC1(C)c2ccccc2-c2ccc(N(c3cccc(C4(c5ccccc5)c5ccccc5-c5ccccc54)c3)c3ccccc3-c3ccccc3)cc21 ; [2H]c1c([2H])c([2H])c(-c2ccc(N(c3cccc(C4(c5ccccc5)c5ccccc5-c5ccccc54)c3)c3ccc4c(c3)C(C)(C)c3ccccc3-4)cc2)c([2H])c1[2H]]

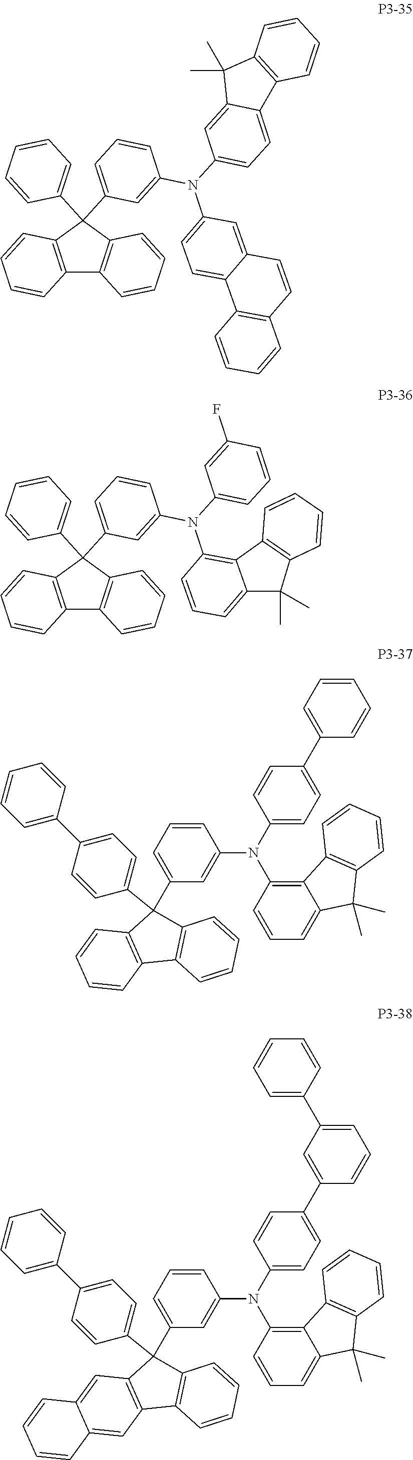

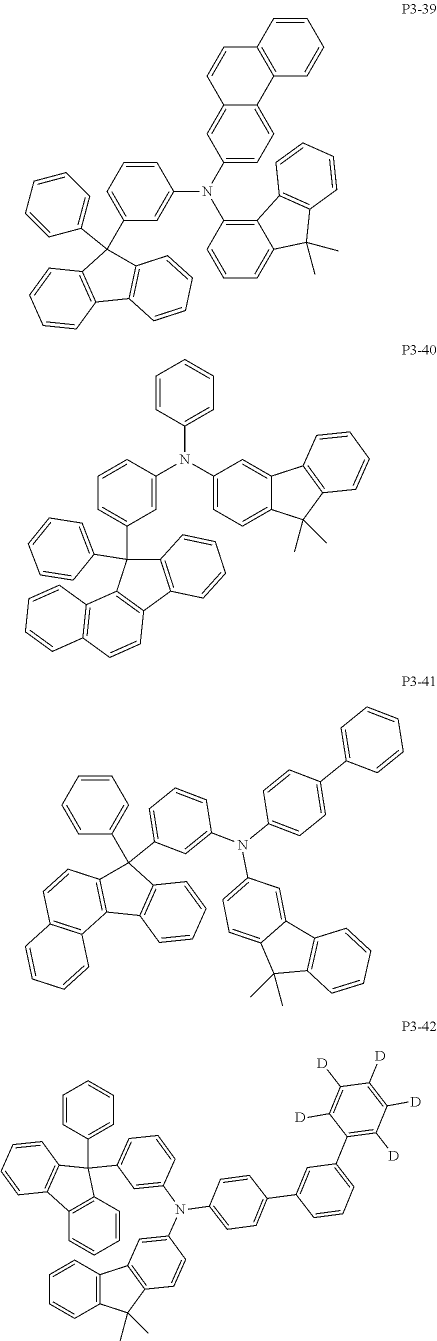 [SMILES: CC1(C)c2ccccc2-c2c(N(c3cccc(C4(c5ccccc5)c5ccccc5-c5ccccc54)c3)c3ccc4c(ccc5ccccc54)c3)cccc21 ; CC1(C)c2ccccc2-c2cc(N(c3ccccc3)c3cccc(C4(c5ccccc5)c5ccccc5-c5ccc6ccccc6c54)c3)ccc21 ; CC1(C)c2ccccc2-c2cc(N(c3ccc(-c4ccccc4)cc3)c3cccc(C4(c5ccccc5)c5ccccc5-c5c4ccc4ccccc54)c3)ccc21 ; [2H]c1c([2H])c([2H])c(-c2cccc(-c3ccc(N(c4cccc(C5(c6ccccc6)c6ccccc6-c6ccccc65)c4)c4ccc5c(c4)-c4ccccc4C5(C)C)cc3)c2)c([2H])c1[2H]]

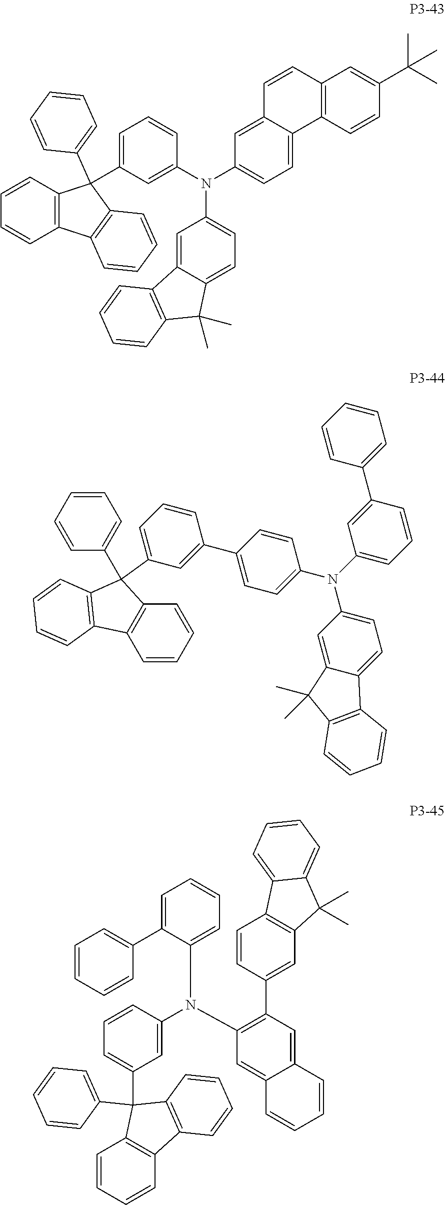 [SMILES: CC(C)(C)c1ccc2c(ccc3cc(N(c4cccc(C5(c6ccccc6)c6ccccc6-c6ccccc65)c4)c4ccc5c(c4)-c4ccccc4C5(C)C)ccc32)c1 ; CC1(C)c2ccccc2-c2ccc(N(c3ccc(-c4cccc(C5(c6ccccc6)c6ccccc6-c6ccccc65)c4)cc3)c3cccc(-c4ccccc4)c3)cc21 ; CC1(C)c2ccccc2-c2ccc(-c3cc4ccccc4cc3N(c3cccc(C4(c5ccccc5)c5ccccc5-c5ccccc54)c3)c3ccccc3-c3ccccc3)cc21]

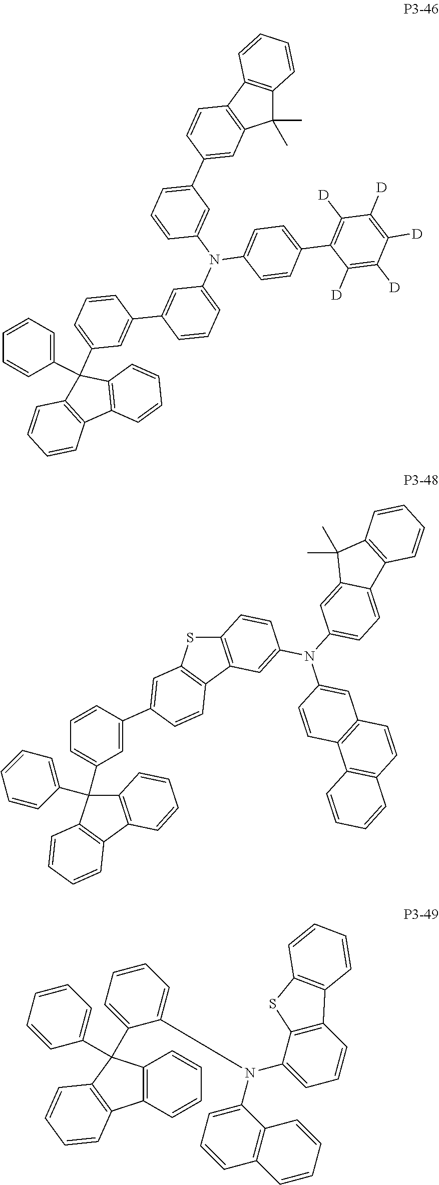 [SMILES: [2H]c1c([2H])c([2H])c(-c2ccc(N(c3cccc(-c4cccc(C5(c6ccccc6)c6ccccc6-c6ccccc65)c4)c3)c3cccc(-c4ccc5c(c4)C(C)(C)c4ccccc4-5)c3)cc2)c([2H])c1[2H] ; CC1(C)c2ccccc2-c2ccc(N(c3ccc4c(ccc5ccccc54)c3)c3ccc4sc5cc(-c6cccc(C7(c8ccccc8)c8ccccc8-c8ccccc87)c6)ccc5c4c3)cc21 ; c1ccc(C2(c3ccccc3N(c3cccc4ccccc34)c3cccc4c3sc3ccccc34)c3ccccc3-c3ccccc32)cc1]

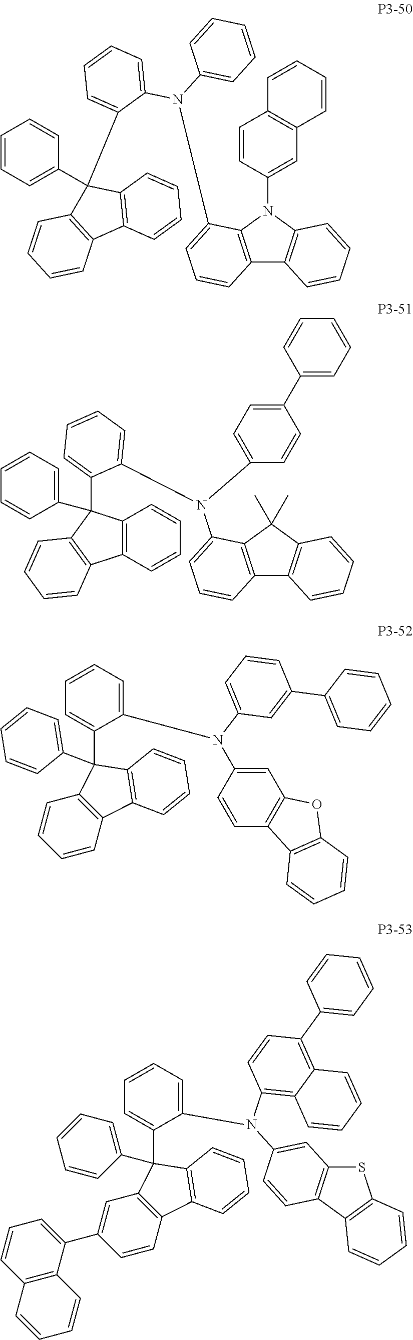

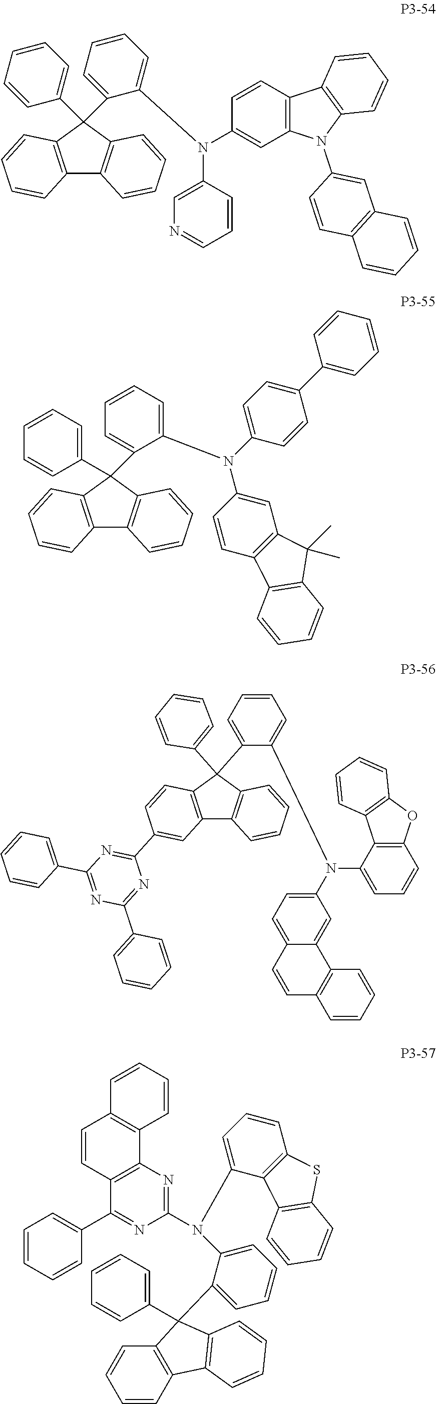 [SMILES: c1ccc(C2(c3ccccc3N(c3cccnc3)c3ccc4c5ccccc5n(-c5ccc6ccccc6c5)c4c3)c3ccccc3-c3ccccc32)cc1 ; CC1(C)c2ccccc2-c2ccc(N(c3ccc(-c4ccccc4)cc3)c3ccccc3C3(c4ccccc4)c4ccccc4-c4ccccc43)cc21 ; c1ccc(-c2nc(-c3ccccc3)nc(-c3ccc4c(c3)-c3ccccc3C4(c3ccccc3)c3ccccc3N(c3ccc4ccc5ccccc5c4c3)c3cccc4oc5ccccc5c34)n2)cc1 ; c1ccc(-c2nc(N(c3ccccc3C3(c4ccccc4)c4ccccc4-c4ccccc43)c3cccc4sc5ccccc5c34)nc3c2ccc2ccccc23)cc1]

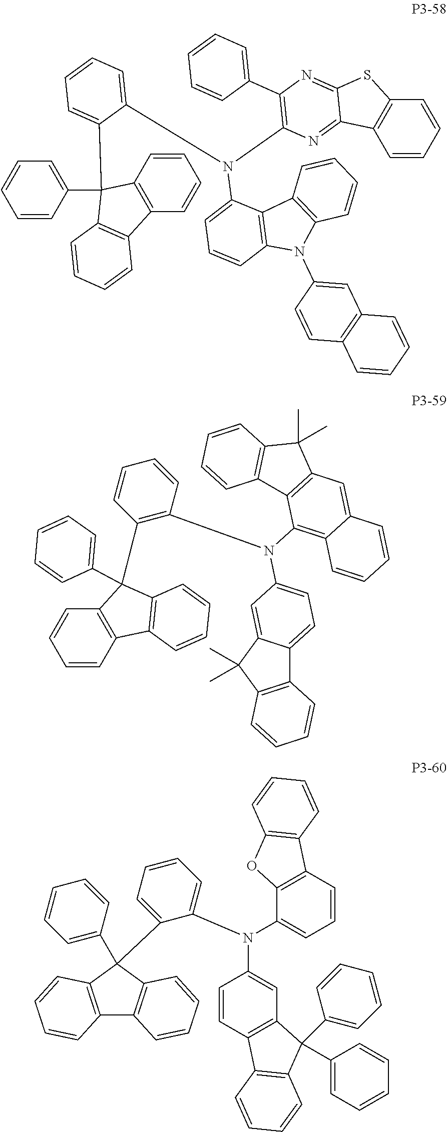

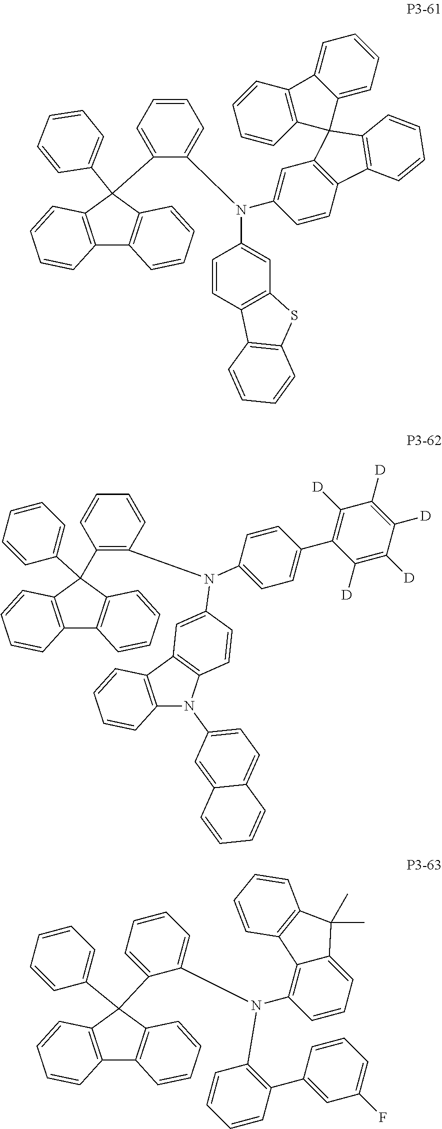

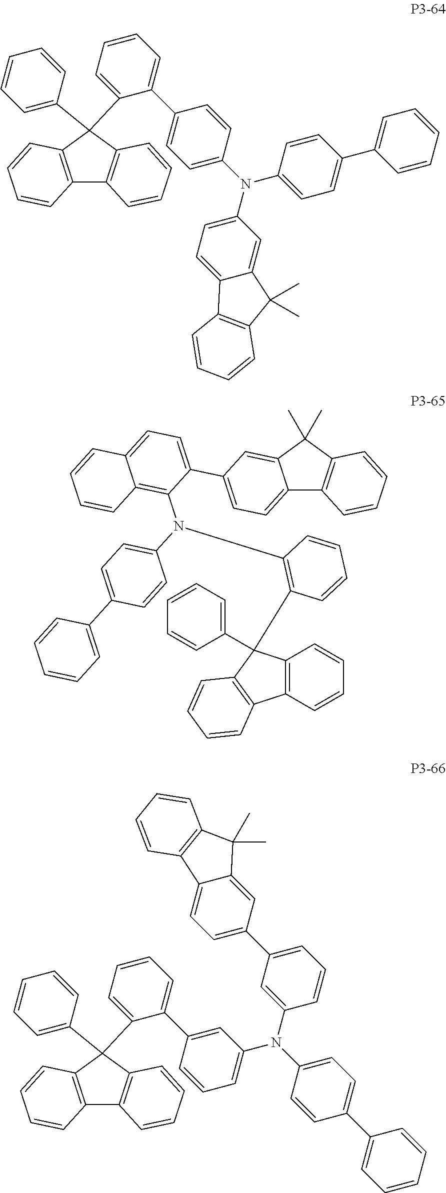 [SMILES: CC1(C)c2ccccc2-c2ccc(N(c3ccc(-c4ccccc4)cc3)c3ccc(-c4ccccc4C4(c5ccccc5)c5ccccc5-c5ccccc54)cc3)cc21 ; CC1(C)c2ccccc2-c2ccc(-c3ccc4ccccc4c3N(c3ccc(-c4ccccc4)cc3)c3ccccc3C3(c4ccccc4)c4ccccc4-c4ccccc43)cc21 ; CC1(C)c2ccccc2-c2ccc(-c3cccc(N(c4ccc(-c5ccccc5)cc4)c4cccc(-c5ccccc5C5(c6ccccc6)c6ccccc6-c6ccccc65)c4)c3)cc21]

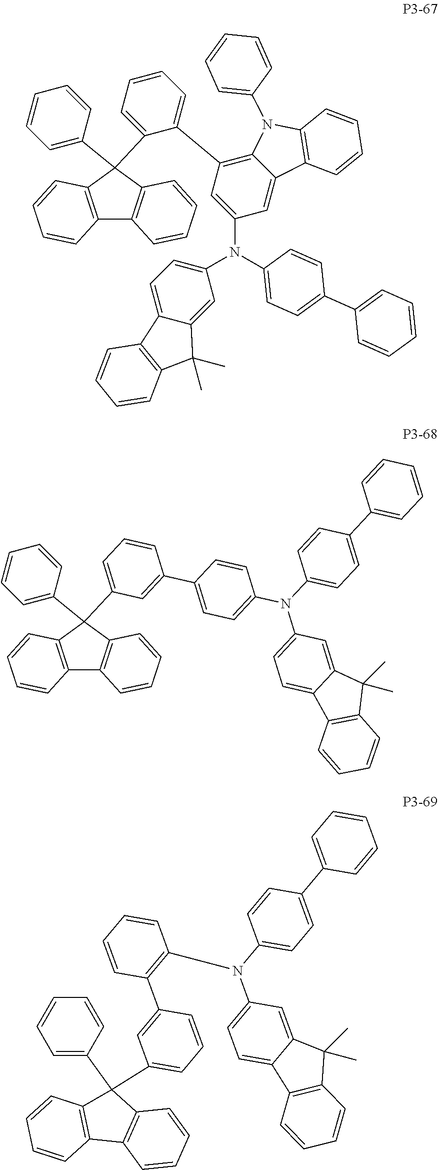

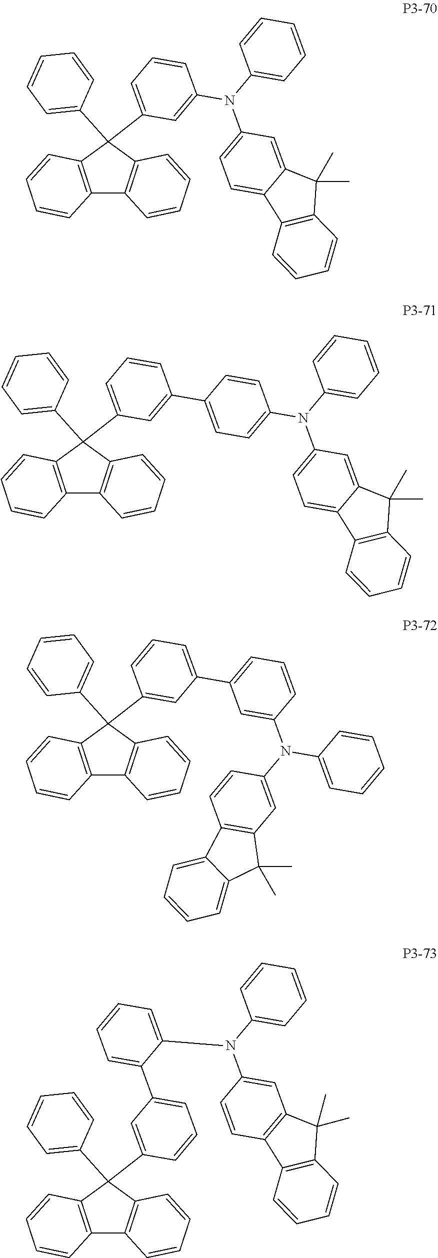 [SMILES: CC1(C)c2ccccc2-c2ccc(N(c3ccccc3)c3cccc(C4(c5ccccc5)c5ccccc5-c5ccccc54)c3)cc21 ; CC1(C)c2ccccc2-c2ccc(N(c3ccccc3)c3ccc(-c4cccc(C5(c6ccccc6)c6ccccc6-c6ccccc65)c4)cc3)cc21 ; CC1(C)c2ccccc2-c2ccc(N(c3ccccc3)c3cccc(-c4cccc(C5(c6ccccc6)c6ccccc6-c6ccccc65)c4)c3)cc21 ; CC1(C)c2ccccc2-c2ccc(N(c3ccccc3)c3ccccc3-c3cccc(C4(c5ccccc5)c5ccccc5-c5ccccc54)c3)cc21]

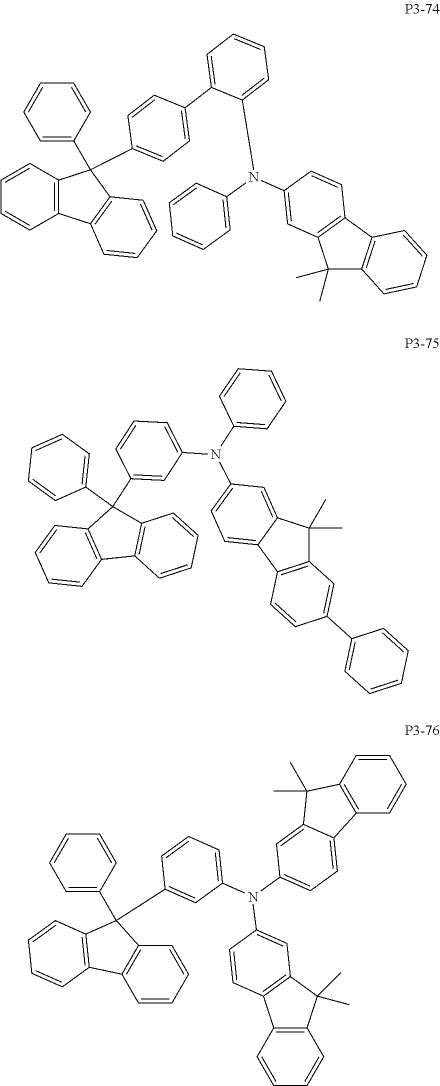 [SMILES: CC1(C)c2ccccc2-c2ccc(N(c3ccccc3)c3ccccc3-c3ccc(C4(c5ccccc5)c5ccccc5-c5ccccc54)cc3)cc21 ; CC1(C)c2cc(-c3ccccc3)ccc2-c2ccc(N(c3ccccc3)c3cccc(C4(c5ccccc5)c5ccccc5-c5ccccc54)c3)cc21 ; CC1(C)c2ccccc2-c2ccc(N(c3cccc(C4(c5ccccc5)c5ccccc5-c5ccccc54)c3)c3ccc4c(c3)C(C)(C)c3ccccc3-4)cc21]

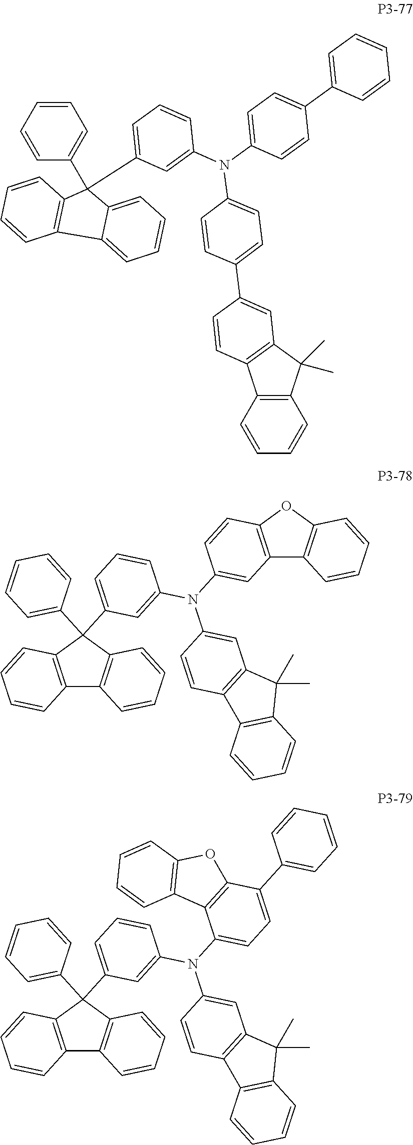

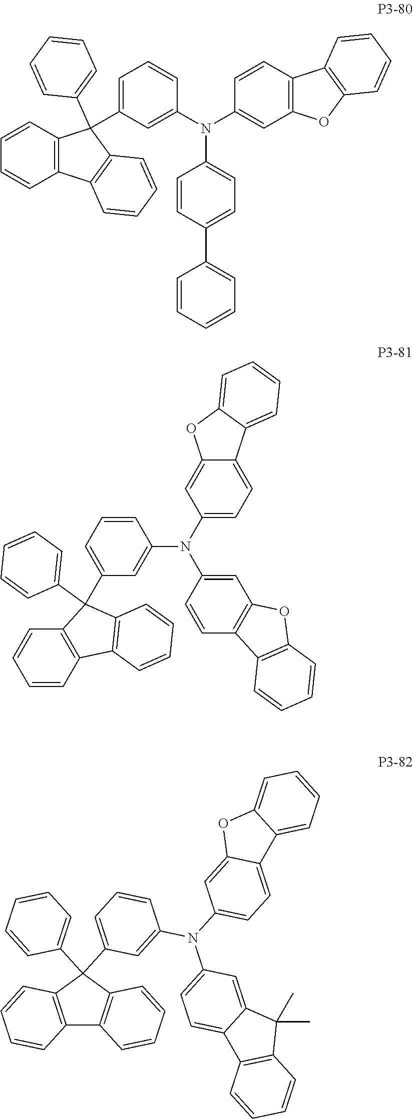 [SMILES: c1ccc(-c2ccc(N(c3cccc(C4(c5ccccc5)c5ccccc5-c5ccccc54)c3)c3ccc4c(c3)oc3ccccc34)cc2)cc1 ; c1ccc(C2(c3cccc(N(c4ccc5c(c4)oc4ccccc45)c4ccc5c(c4)oc4ccccc45)c3)c3ccccc3-c3ccccc32)cc1 ; CC1(C)c2ccccc2-c2ccc(N(c3cccc(C4(c5ccccc5)c5ccccc5-c5ccccc54)c3)c3ccc4c(c3)oc3ccccc34)cc21]

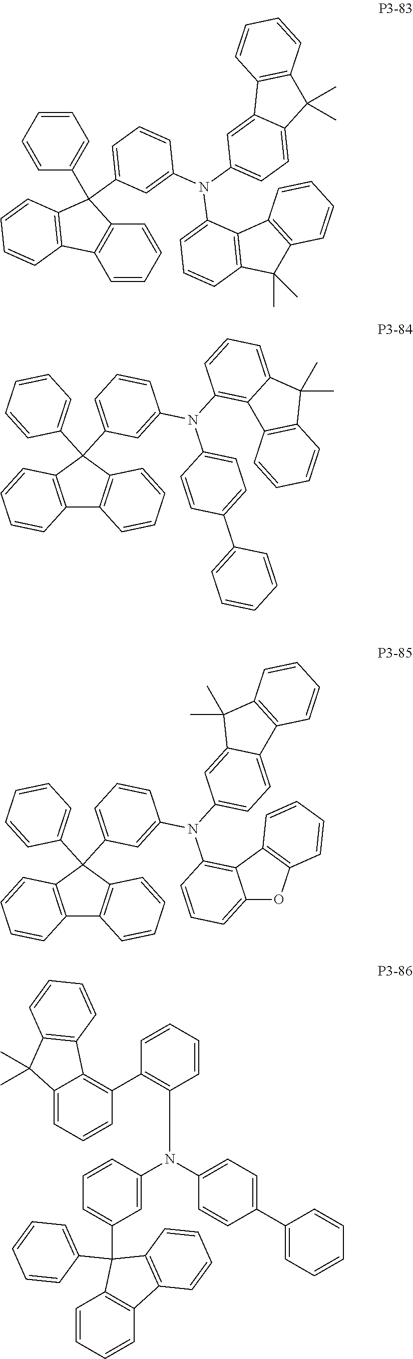

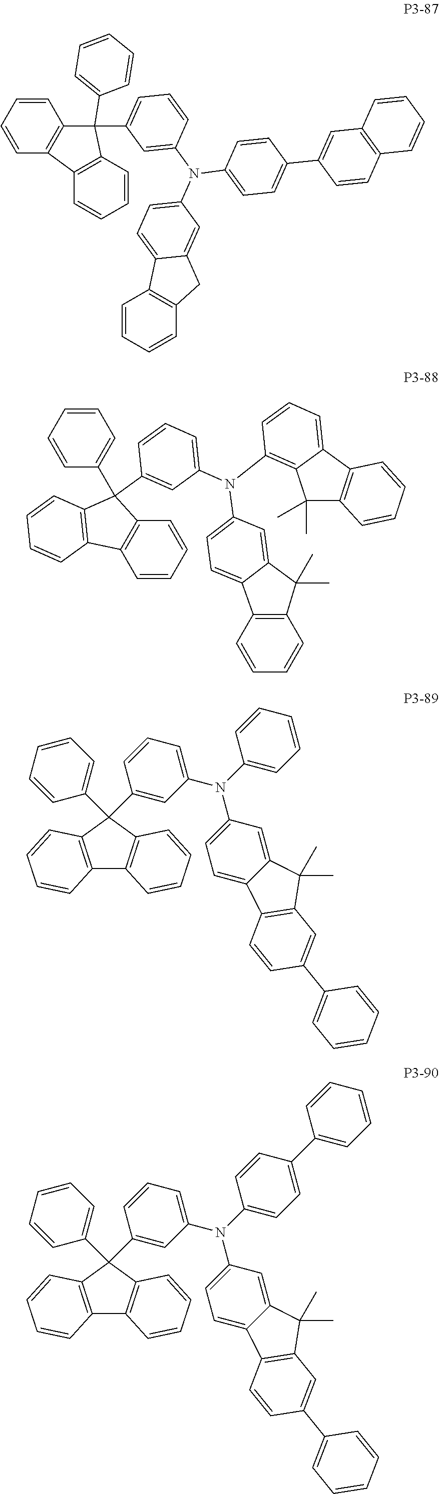

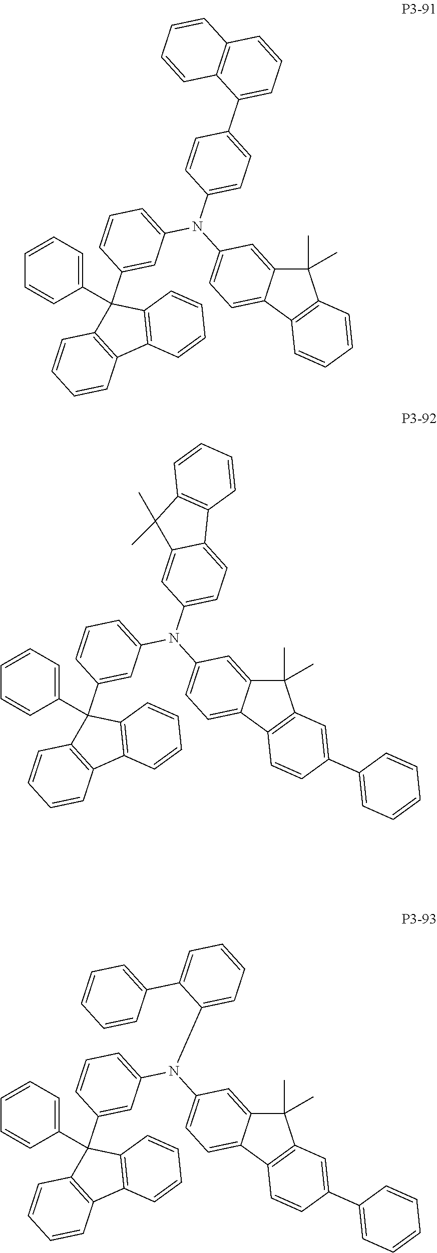 [SMILES: CC1(C)c2ccccc2-c2ccc(N(c3ccc(-c4cccc5ccccc45)cc3)c3cccc(C4(c5ccccc5)c5ccccc5-c5ccccc54)c3)cc21 ; CC1(C)c2ccccc2-c2ccc(N(c3cccc(C4(c5ccccc5)c5ccccc5-c5ccccc54)c3)c3ccc4c(c3)C(C)(C)c3cc(-c5ccccc5)ccc3-4)cc21 ; CC1(C)c2cc(-c3ccccc3)ccc2-c2ccc(N(c3cccc(C4(c5ccccc5)c5ccccc5-c5ccccc54)c3)c3ccccc3-c3ccccc3)cc21]

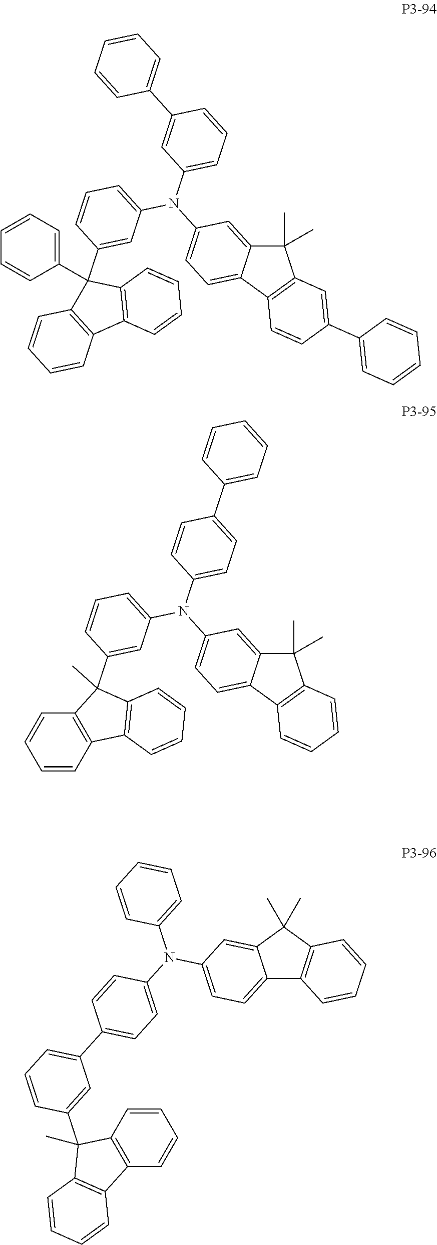 [SMILES: CC1(C)c2cc(-c3ccccc3)ccc2-c2ccc(N(c3cccc(-c4ccccc4)c3)c3cccc(C4(c5ccccc5)c5ccccc5-c5ccccc54)c3)cc21 ; CC1(C)c2ccccc2-c2ccc(N(c3ccc(-c4ccccc4)cc3)c3cccc(C4(C)c5ccccc5-c5ccccc54)c3)cc21 ; CC1(C)c2ccccc2-c2ccc(N(c3ccccc3)c3ccc(-c4cccc(C5(C)c6ccccc6-c6ccccc65)c4)cc3)cc21]

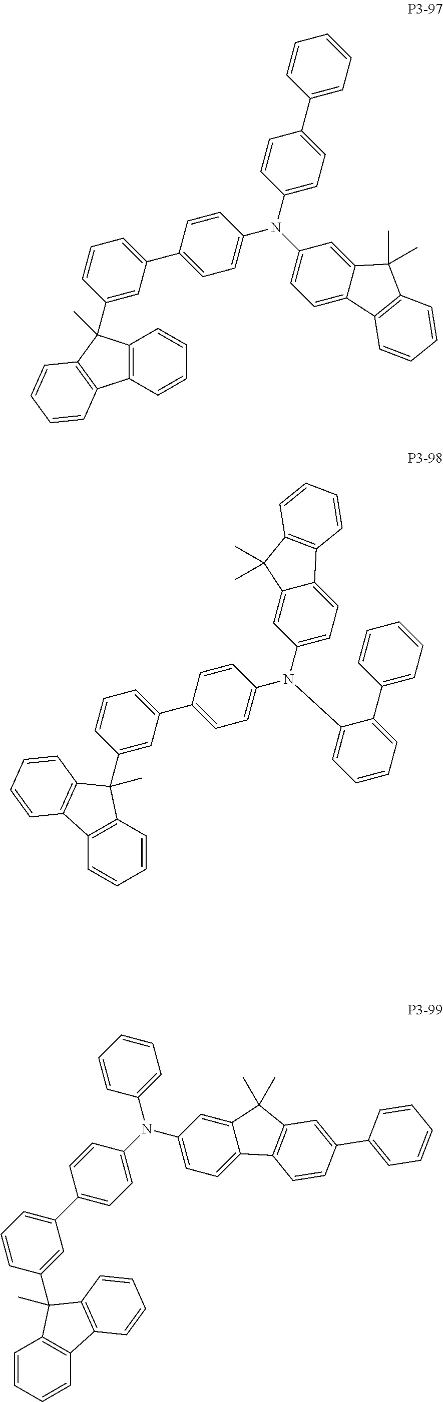 [SMILES: CC1(C)c2ccccc2-c2ccc(N(c3ccc(-c4ccccc4)cc3)c3ccc(-c4cccc(C5(C)c6ccccc6-c6ccccc65)c4)cc3)cc21 ; CC1(C)c2ccccc2-c2ccc(N(c3ccc(-c4cccc(C5(C)c6ccccc6-c6ccccc65)c4)cc3)c3ccccc3-c3ccccc3)cc21 ; CC1(C)c2cc(-c3ccccc3)ccc2-c2ccc(N(c3ccccc3)c3ccc(-c4cccc(C5(C)c6ccccc6-c6ccccc65)c4)cc3)cc21]

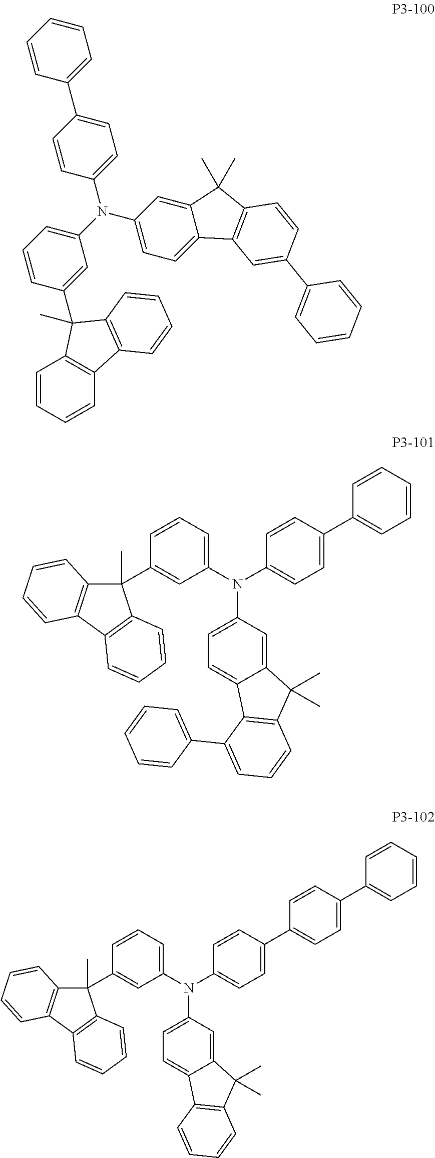 [SMILES: CC1(C)c2ccc(-c3ccccc3)cc2-c2ccc(N(c3ccc(-c4ccccc4)cc3)c3cccc(C4(C)c5ccccc5-c5ccccc54)c3)cc21 ; CC1(C)c2cc(N(c3ccc(-c4ccccc4)cc3)c3cccc(C4(C)c5ccccc5-c5ccccc54)c3)ccc2-c2c(-c3ccccc3)cccc21 ; CC1(C)c2ccccc2-c2ccc(N(c3ccc(-c4ccc(-c5ccccc5)cc4)cc3)c3cccc(C4(C)c5ccccc5-c5ccccc54)c3)cc21]

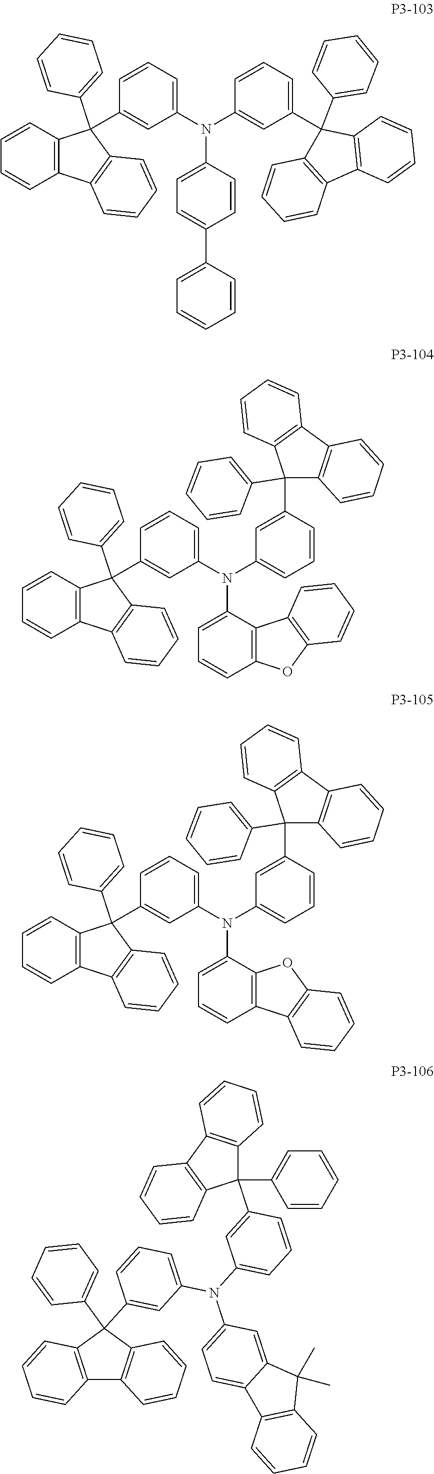 [SMILES: c1ccc(-c2ccc(N(c3cccc(C4(c5ccccc5)c5ccccc5-c5ccccc54)c3)c3cccc(C4(c5ccccc5)c5ccccc5-c5ccccc54)c3)cc2)cc1 ; c1ccc(C2(c3cccc(N(c4cccc(C5(c6ccccc6)c6ccccc6-c6ccccc65)c4)c4cccc5oc6ccccc6c45)c3)c3ccccc3-c3ccccc32)cc1 ; c1ccc(C2(c3cccc(N(c4cccc(C5(c6ccccc6)c6ccccc6-c6ccccc65)c4)c4cccc5c4oc4ccccc45)c3)c3ccccc3-c3ccccc32)cc1 ; CC1(C)c2ccccc2-c2ccc(N(c3cccc(C4(c5ccccc5)c5ccccc5-c5ccccc54)c3)c3cccc(C4(c5ccccc5)c5ccccc5-c5ccccc54)c3)cc21]

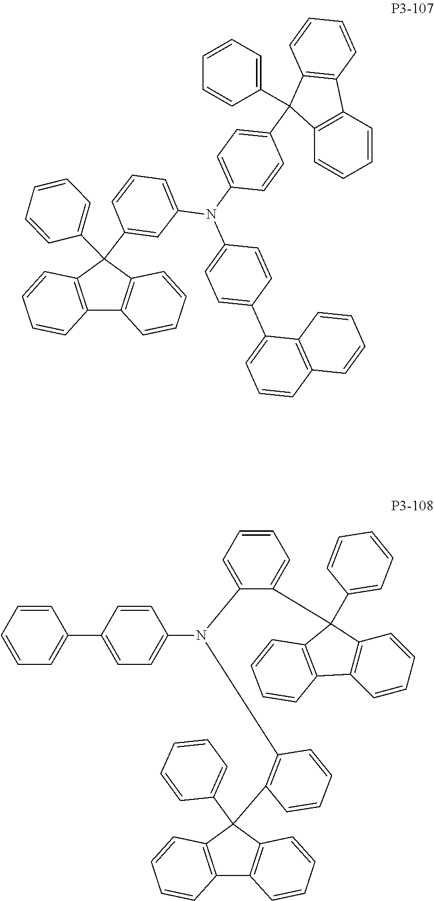 [SMILES: c1ccc(C2(c3ccc(N(c4ccc(-c5cccc6ccccc56)cc4)c4cccc(C5(c6ccccc6)c6ccccc6-c6ccccc65)c4)cc3)c3ccccc3-c3ccccc32)cc1 ; c1ccc(-c2ccc(N(c3ccccc3C3(c4ccccc4)c4ccccc4-c4ccccc43)c3ccccc3C3(c4ccccc4)c4ccccc4-c4ccccc43)cc2)cc1]

Specifically, the compound represented by formula 2 may be one of the following compounds, but there is no limitation thereto.

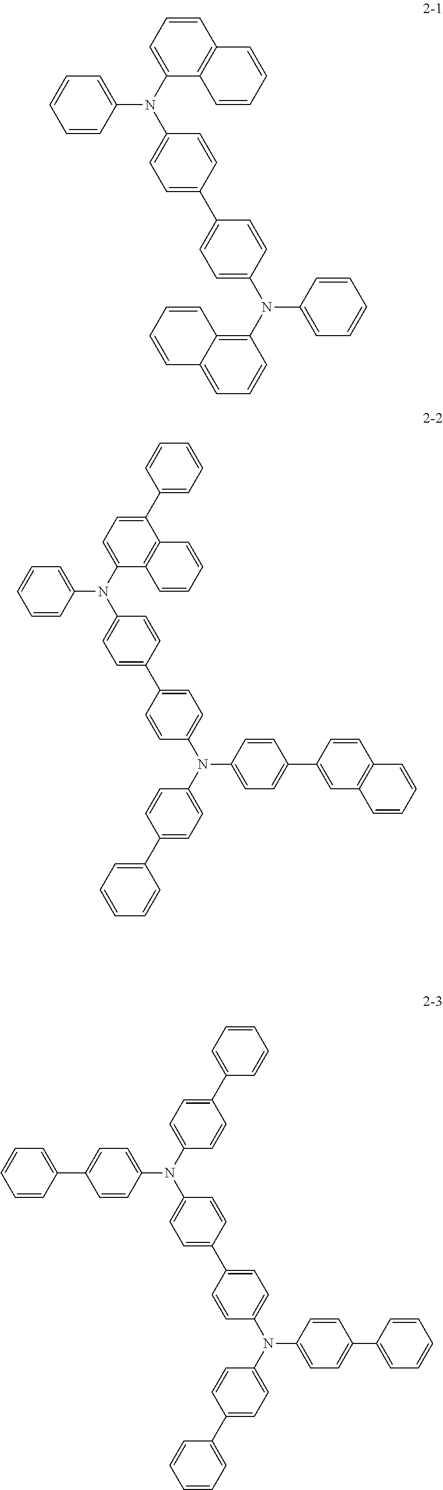 [SMILES: c1ccc(N(c2ccc(-c3ccc(N(c4ccccc4)c4cccc5ccccc45)cc3)cc2)c2cccc3ccccc23)cc1 ; c1ccc(-c2ccc(N(c3ccc(-c4ccc(N(c5ccccc5)c5ccc(-c6ccccc6)c6ccccc56)cc4)cc3)c3ccc(-c4ccc5ccccc5c4)cc3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1]

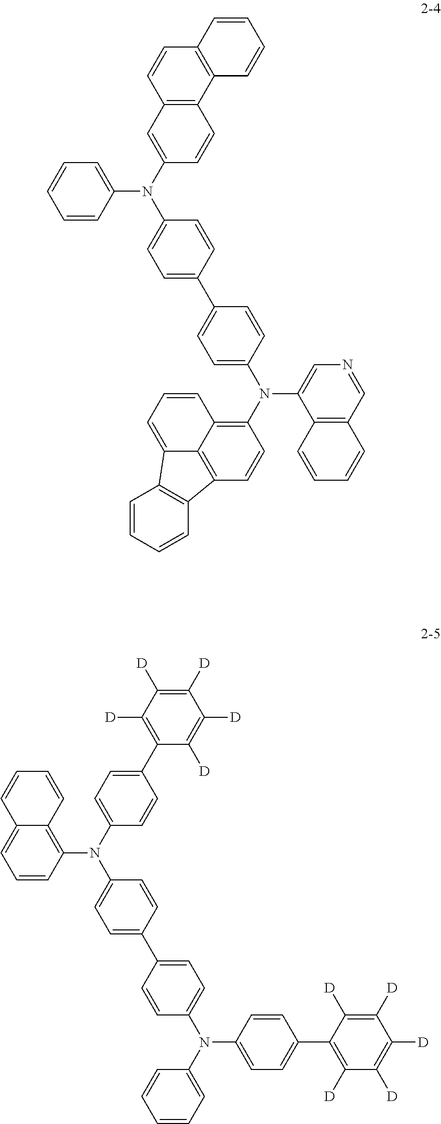 [SMILES: c1ccc(N(c2ccc(-c3ccc(N(c4cncc5ccccc45)c4ccc5c6c(cccc46)-c4ccccc4-5)cc3)cc2)c2ccc3c(ccc4ccccc43)c2)cc1 ; [2H]c1c([2H])c([2H])c(-c2ccc(N(c3ccccc3)c3ccc(-c4ccc(N(c5ccc(-c6c([2H])c([2H])c([2H])c([2H])c6[2H])cc5)c5cccc6ccccc56)cc4)cc3)cc2)c([2H])c1[2H]]

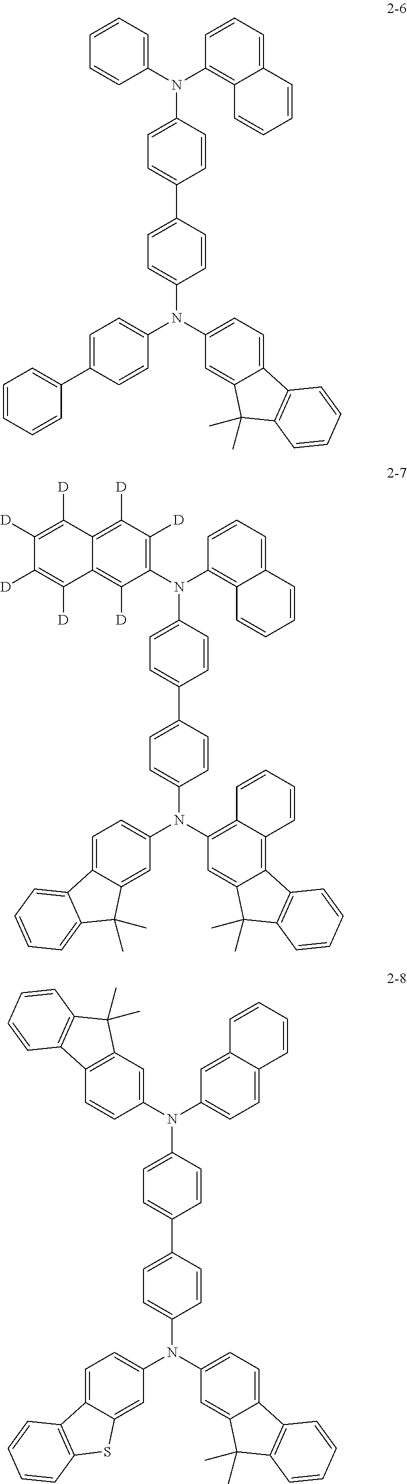

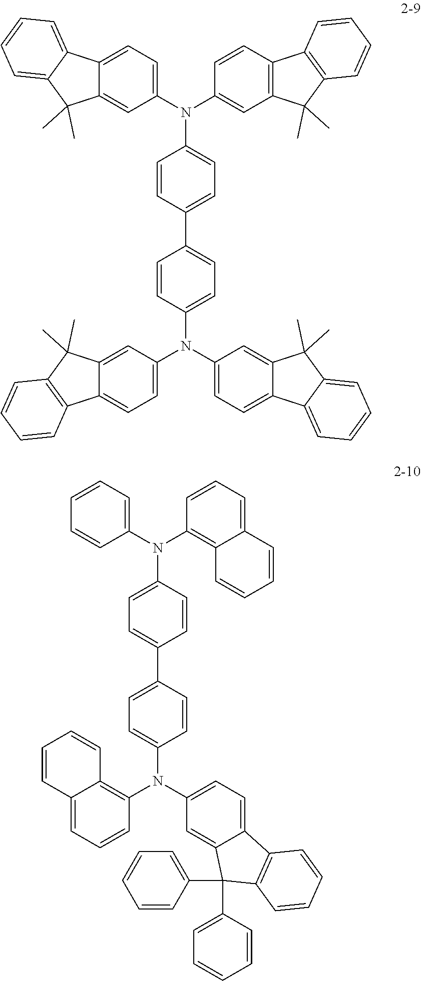 [SMILES: CC1(C)c2ccccc2-c2ccc(N(c3ccc(-c4ccc(N(c5ccc6c(c5)C(C)(C)c5ccccc5-6)c5ccc6c(c5)C(C)(C)c5ccccc5-6)cc4)cc3)c3ccc4c(c3)C(C)(C)c3ccccc3-4)cc21 ; c1ccc(N(c2ccc(-c3ccc(N(c4ccc5c(c4)C(c4ccccc4)(c4ccccc4)c4ccccc4-5)c4cccc5ccccc45)cc3)cc2)c2cccc3ccccc23)cc1]

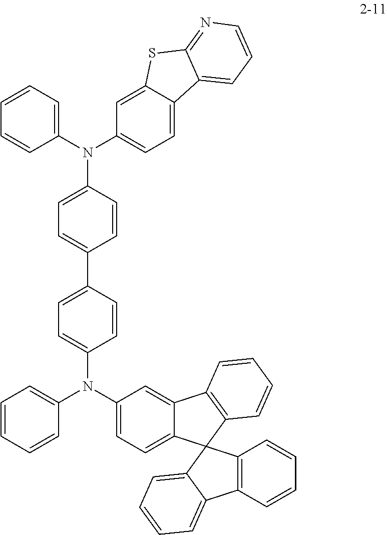 [SMILES: c1ccc(N(c2ccc(-c3ccc(N(c4ccccc4)c4ccc5c(c4)sc4ncccc45)cc3)cc2)c2ccc3c(c2)-c2ccccc2C32c3ccccc3-c3ccccc32)cc1]

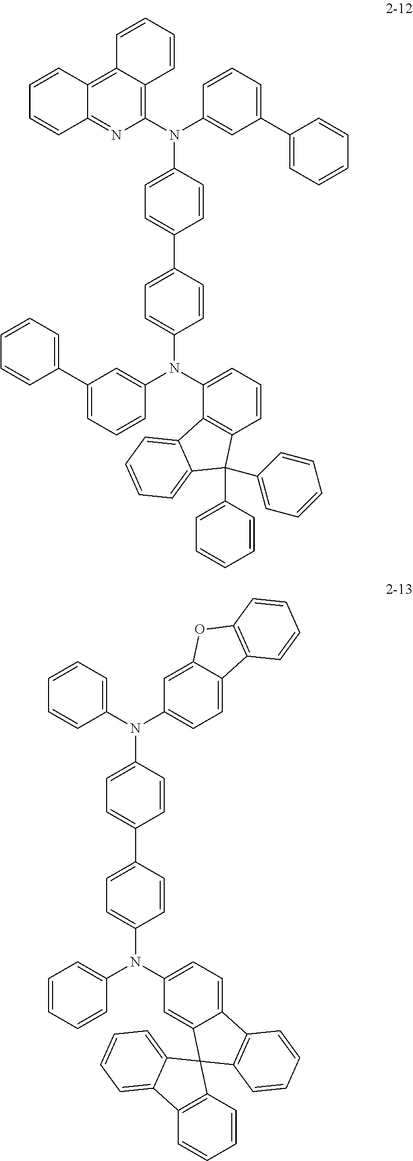

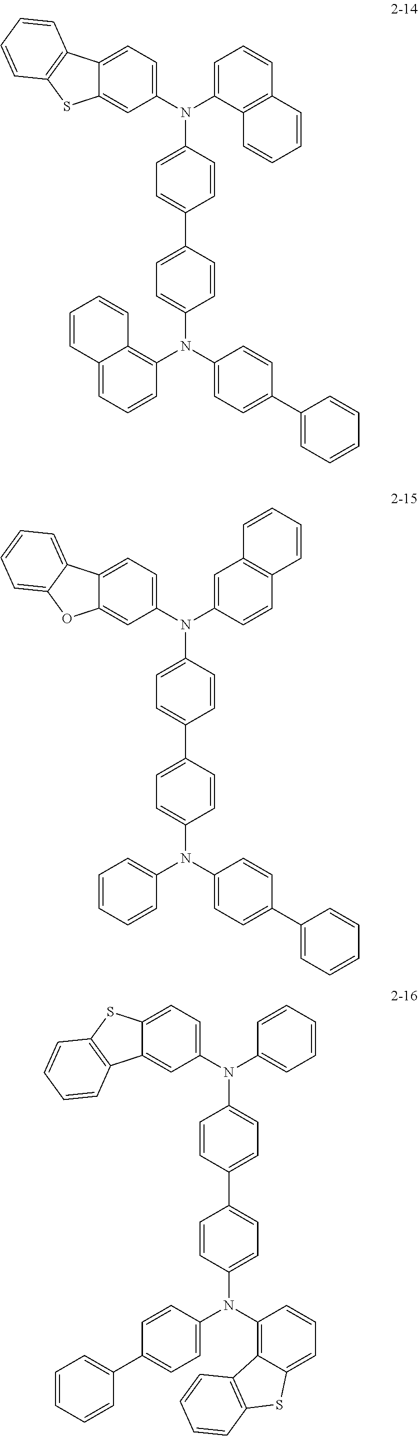 [SMILES: c1ccc(-c2ccc(N(c3ccc(-c4ccc(N(c5ccc6c(c5)sc5ccccc56)c5cccc6ccccc56)cc4)cc3)c3cccc4ccccc34)cc2)cc1 ; c1ccc(-c2ccc(N(c3ccccc3)c3ccc(-c4ccc(N(c5ccc6ccccc6c5)c5ccc6c(c5)oc5ccccc56)cc4)cc3)cc2)cc1 ; c1ccc(-c2ccc(N(c3ccc(-c4ccc(N(c5ccccc5)c5ccc6sc7ccccc7c6c5)cc4)cc3)c3cccc4sc5ccccc5c34)cc2)cc1]

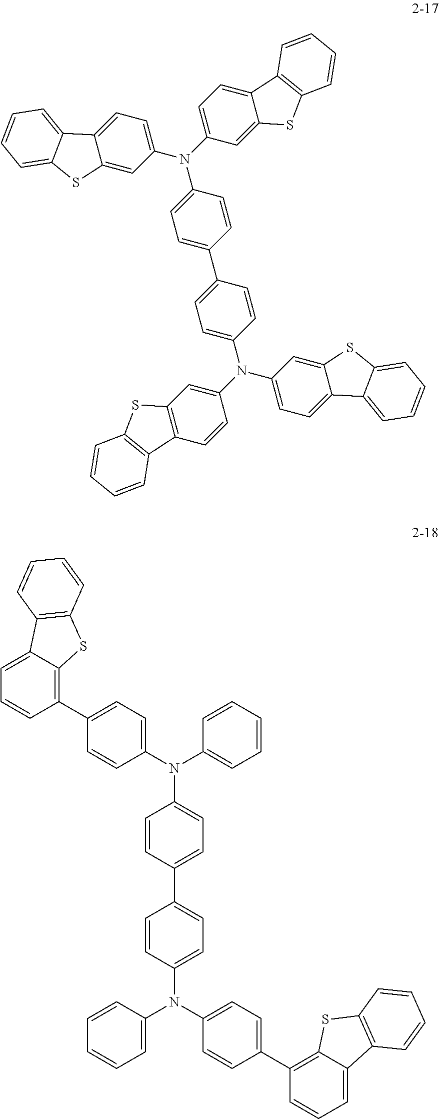 [SMILES: c1ccc2c(c1)sc1cc(N(c3ccc(-c4ccc(N(c5ccc6c(c5)sc5ccccc56)c5ccc6c(c5)sc5ccccc56)cc4)cc3)c3ccc4c(c3)sc3ccccc34)ccc12 ; c1ccc(N(c2ccc(-c3ccc(N(c4ccccc4)c4ccc(-c5cccc6c5sc5ccccc56)cc4)cc3)cc2)c2ccc(-c3cccc4c3sc3ccccc34)cc2)cc1]

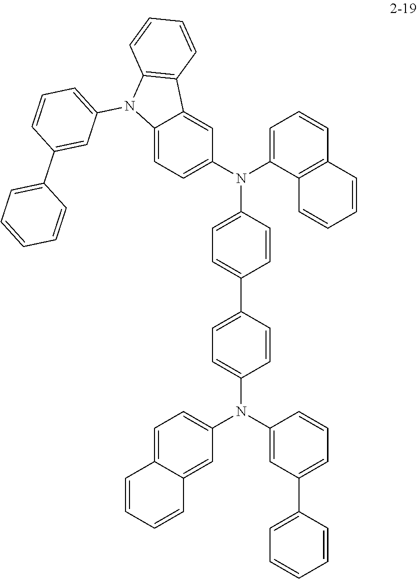 [SMILES: c1ccc(-c2cccc(N(c3ccc(-c4ccc(N(c5ccc6c(c5)c5ccccc5n6-c5cccc(-c6ccccc6)c5)c5cccc6ccccc56)cc4)cc3)c3ccc4ccccc4c3)c2)cc1]

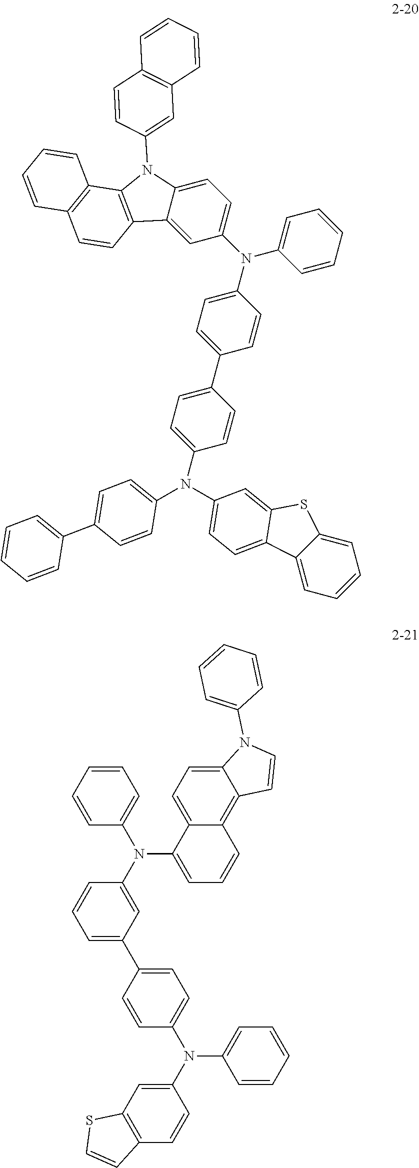 [SMILES: c1ccc(-c2ccc(N(c3ccc(-c4ccc(N(c5ccccc5)c5ccc6c(c5)c5ccc7ccccc7c5n6-c5ccc6ccccc6c5)cc4)cc3)c3ccc4c(c3)sc3ccccc34)cc2)cc1 ; c1ccc(N(c2ccc(-c3cccc(N(c4ccccc4)c4cccc5c4ccc4c5ccn4-c4ccccc4)c3)cc2)c2ccc3ccsc3c2)cc1]

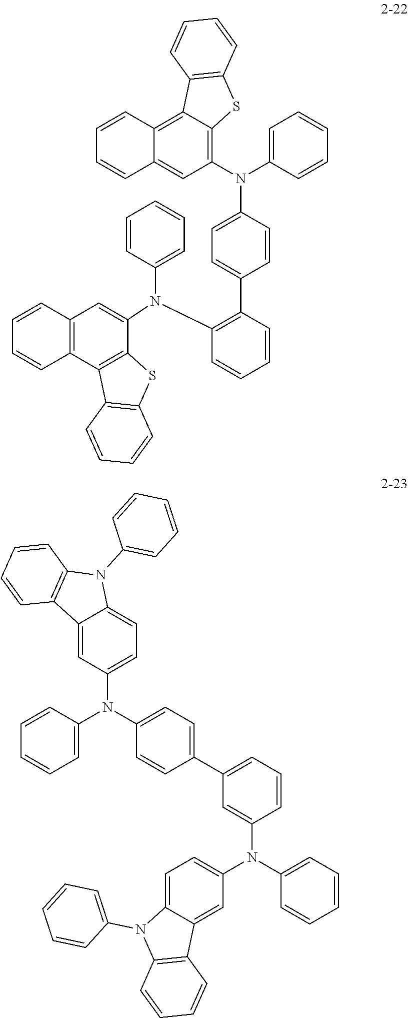

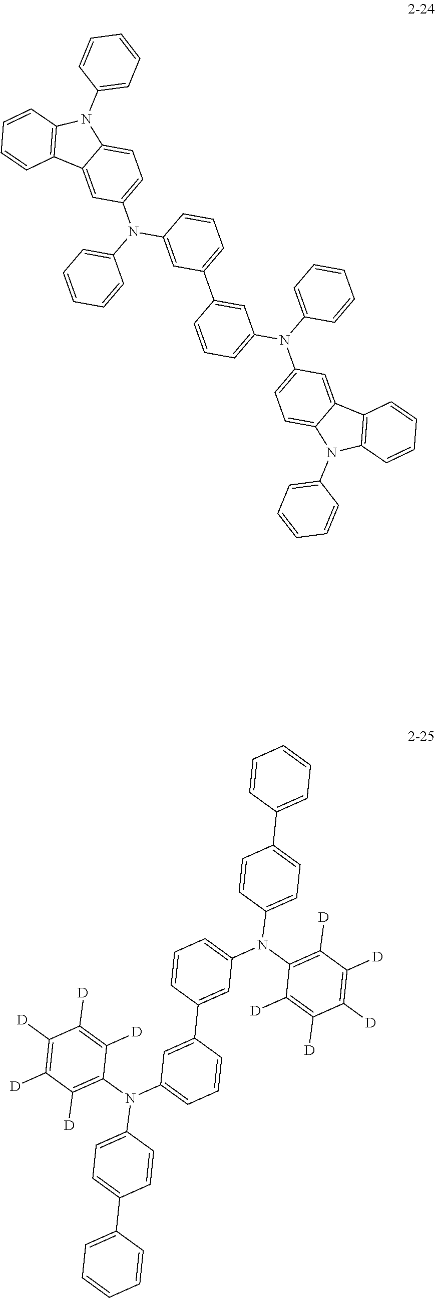 [SMILES: c1ccc(N(c2cccc(-c3cccc(N(c4ccccc4)c4ccc5c(c4)c4ccccc4n5-c4ccccc4)c3)c2)c2ccc3c(c2)c2ccccc2n3-c2ccccc2)cc1 ; [2H]c1c([2H])c([2H])c(N(c2ccc(-c3ccccc3)cc2)c2cccc(-c3cccc(N(c4ccc(-c5ccccc5)cc4)c4c([2H])c([2H])c([2H])c([2H])c4[2H])c3)c2)c([2H])c1[2H]]

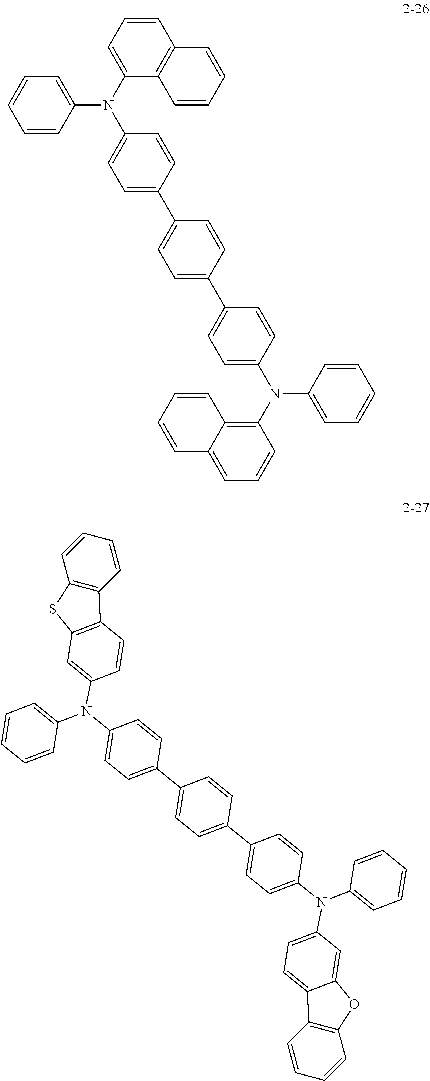 [SMILES: c1ccc(N(c2ccc(-c3ccc(-c4ccc(N(c5ccccc5)c5cccc6ccccc56)cc4)cc3)cc2)c2cccc3ccccc23)cc1 ; c1ccc(N(c2ccc(-c3ccc(-c4ccc(N(c5ccccc5)c5ccc6c(c5)sc5ccccc56)cc4)cc3)cc2)c2ccc3c(c2)oc2ccccc23)cc1]

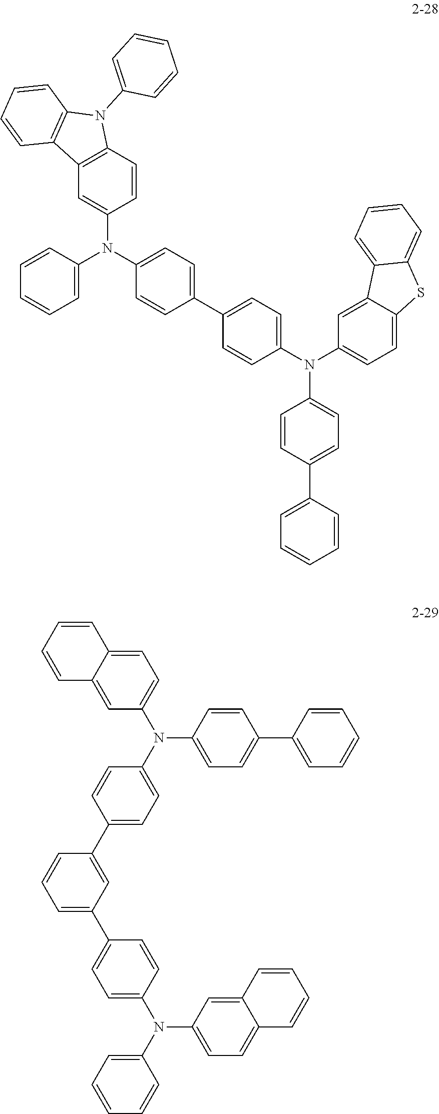 [SMILES: c1ccc(-c2ccc(N(c3ccc(-c4ccc(N(c5ccccc5)c5ccc6c(c5)c5ccccc5n6-c5ccccc5)cc4)cc3)c3ccc4sc5ccccc5c4c3)cc2)cc1 ; c1ccc(-c2ccc(N(c3ccc(-c4cccc(-c5ccc(N(c6ccccc6)c6ccc7ccccc7c6)cc5)c4)cc3)c3ccc4ccccc4c3)cc2)cc1]

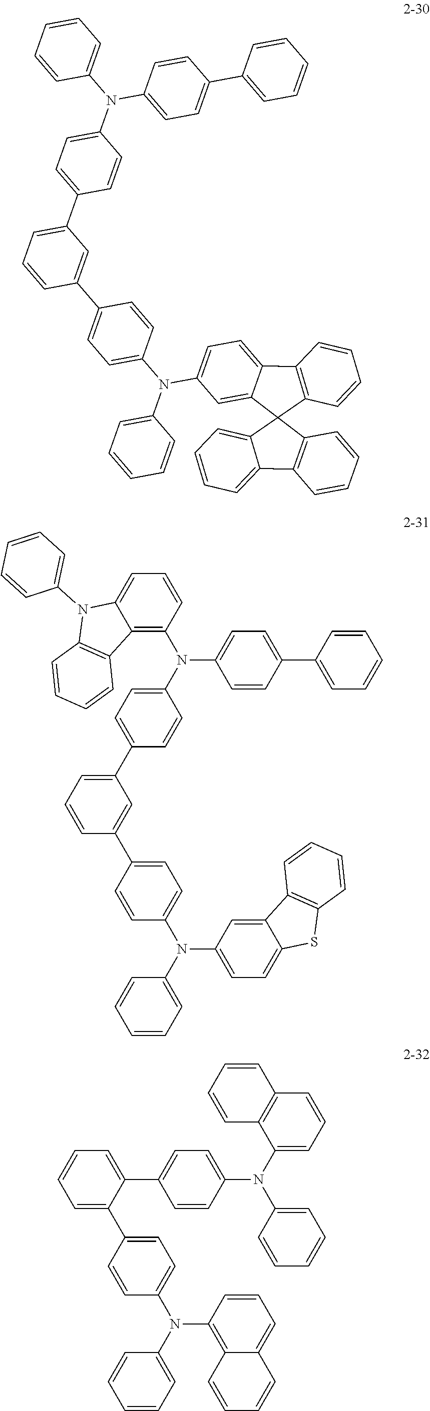 [SMILES: c1ccc(-c2ccc(N(c3ccccc3)c3ccc(-c4cccc(-c5ccc(N(c6ccccc6)c6ccc7c(c6)C6(c8ccccc8-c8ccccc86)c6ccccc6-7)cc5)c4)cc3)cc2)cc1 ; c1ccc(-c2ccc(N(c3ccc(-c4cccc(-c5ccc(N(c6ccccc6)c6ccc7sc8ccccc8c7c6)cc5)c4)cc3)c3cccc4c3c3ccccc3n4-c3ccccc3)cc2)cc1 ; c1ccc(N(c2ccc(-c3ccccc3-c3ccc(N(c4ccccc4)c4cccc5ccccc45)cc3)cc2)c2cccc3ccccc23)cc1]

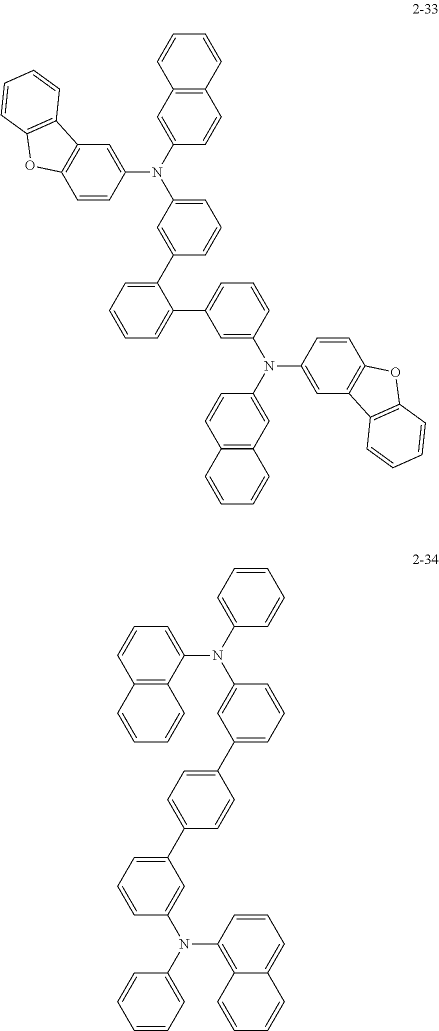 [SMILES: c1cc(-c2ccccc2-c2cccc(N(c3ccc4ccccc4c3)c3ccc4oc5ccccc5c4c3)c2)cc(N(c2ccc3ccccc3c2)c2ccc3oc4ccccc4c3c2)c1 ; c1ccc(N(c2cccc(-c3ccc(-c4cccc(N(c5ccccc5)c5cccc6ccccc56)c4)cc3)c2)c2cccc3ccccc23)cc1]

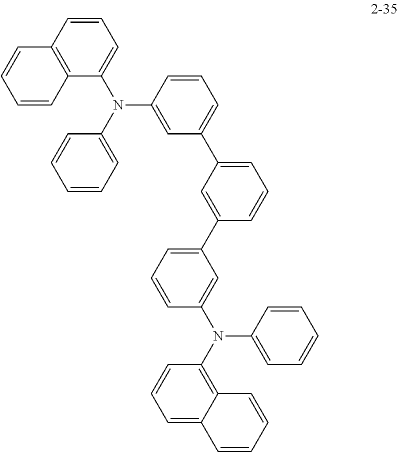 [SMILES: c1ccc(N(c2cccc(-c3cccc(-c4cccc(N(c5ccccc5)c5cccc6ccccc56)c4)c3)c2)c2cccc3ccccc23)cc1]

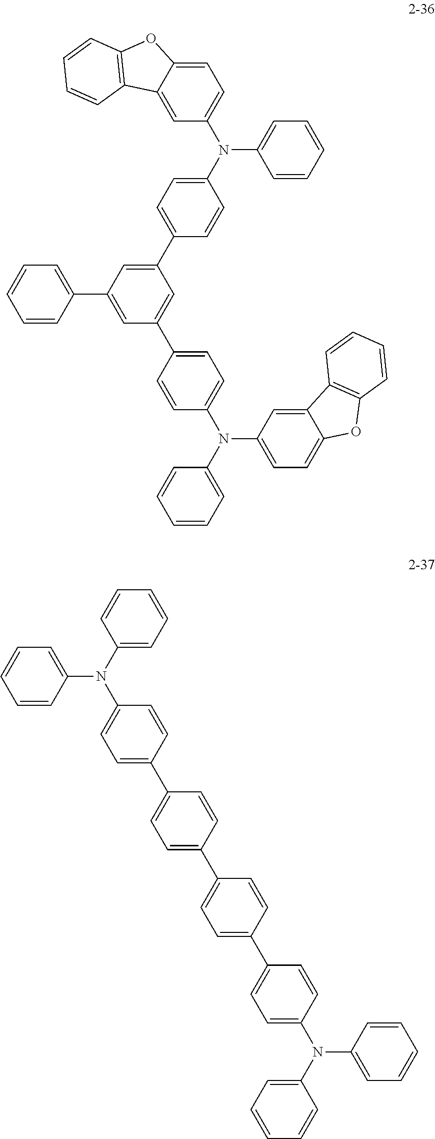 [SMILES: c1ccc(-c2cc(-c3ccc(N(c4ccccc4)c4ccc5oc6ccccc6c5c4)cc3)cc(-c3ccc(N(c4ccccc4)c4ccc5oc6ccccc6c5c4)cc3)c2)cc1 ; c1ccc(N(c2ccccc2)c2ccc(-c3ccc(-c4ccc(-c5ccc(N(c6ccccc6)c6ccccc6)cc5)cc4)cc3)cc2)cc1]

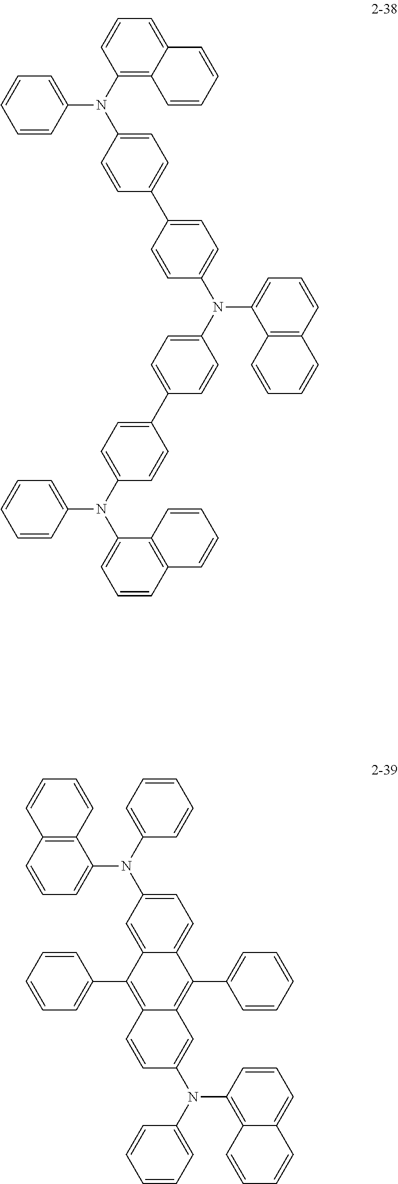 [SMILES: c1ccc(N(c2ccc(-c3ccc(N(c4ccc(-c5ccc(N(c6ccccc6)c6cccc7ccccc67)cc5)cc4)c4cccc5ccccc45)cc3)cc2)c2cccc3ccccc23)cc1 ; c1ccc(-c2c3ccc(N(c4ccccc4)c4cccc5ccccc45)cc3c(-c3ccccc3)c3ccc(N(c4ccccc4)c4cccc5ccccc45)cc23)cc1]

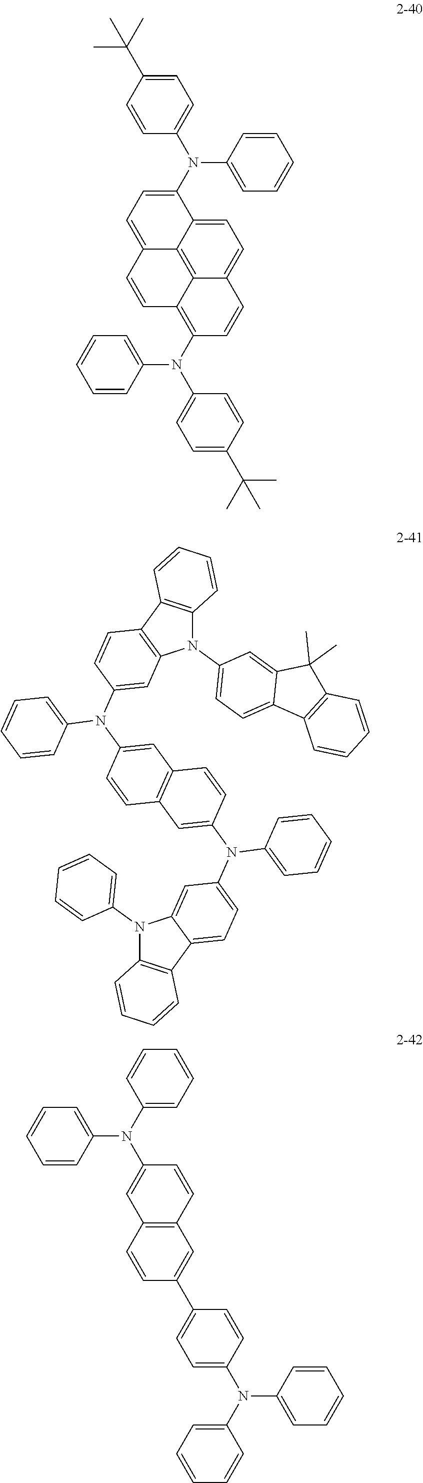

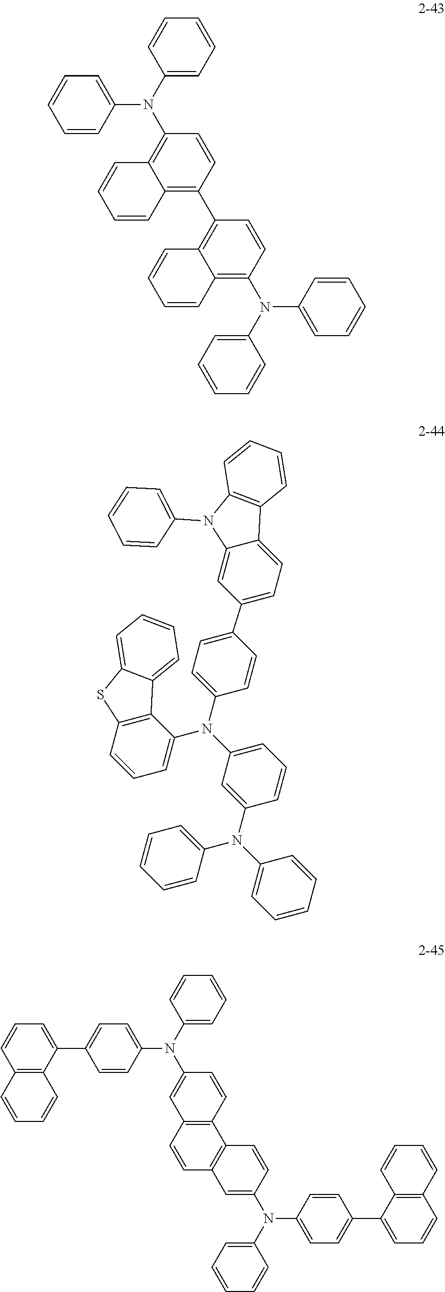 [SMILES: c1ccc(N(c2ccccc2)c2ccc(-c3ccc(N(c4ccccc4)c4ccccc4)c4ccccc34)c3ccccc23)cc1 ; c1ccc(N(c2ccccc2)c2cccc(N(c3ccc(-c4ccc5c6ccccc6n(-c6ccccc6)c5c4)cc3)c3cccc4sc5ccccc5c34)c2)cc1 ; c1ccc(N(c2ccc(-c3cccc4ccccc34)cc2)c2ccc3c(ccc4cc(N(c5ccccc5)c5ccc(-c6cccc7ccccc67)cc5)ccc43)c2)cc1]

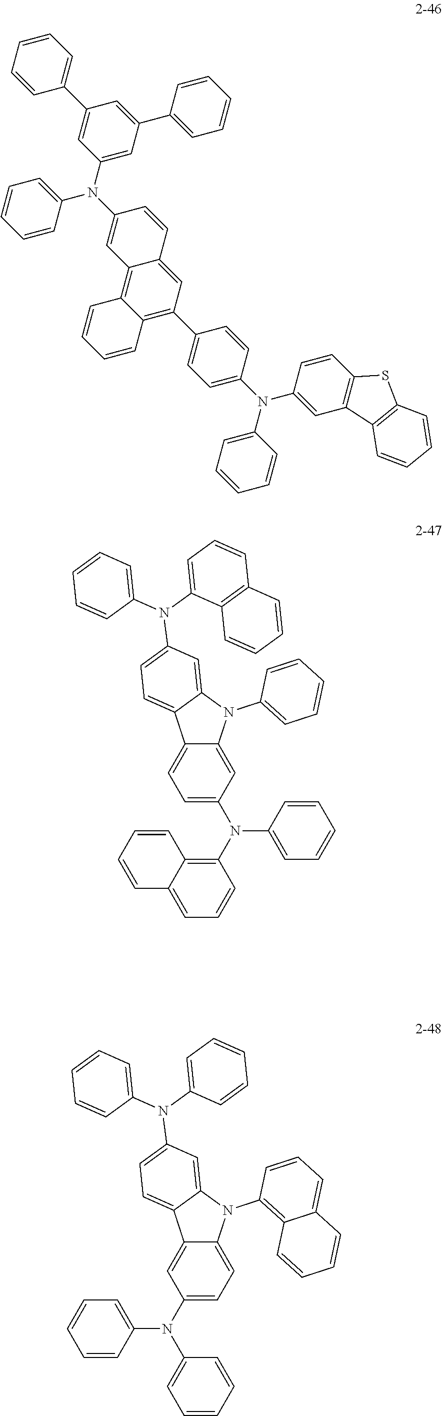 [SMILES: c1ccc(-c2cc(-c3ccccc3)cc(N(c3ccccc3)c3ccc4cc(-c5ccc(N(c6ccccc6)c6ccc7sc8ccccc8c7c6)cc5)c5ccccc5c4c3)c2)cc1 ; c1ccc(N(c2ccc3c4ccc(N(c5ccccc5)c5cccc6ccccc56)cc4n(-c4ccccc4)c3c2)c2cccc3ccccc23)cc1 ; c1ccc(N(c2ccccc2)c2ccc3c(c2)c2ccc(N(c4ccccc4)c4ccccc4)cc2n3-c2cccc3ccccc23)cc1]

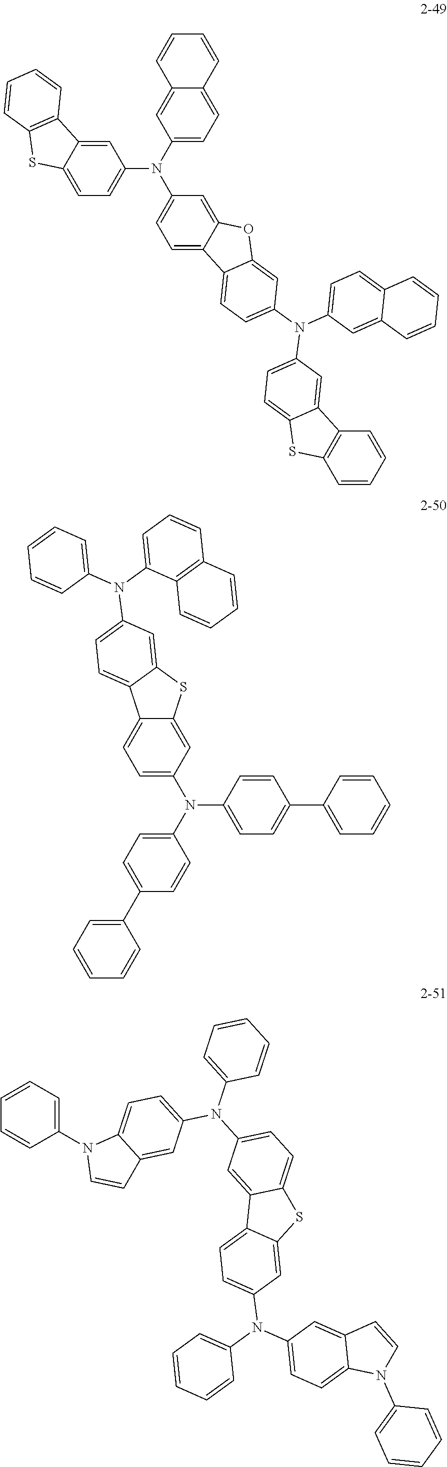 [SMILES: c1ccc2cc(N(c3ccc4c(c3)oc3cc(N(c5ccc6ccccc6c5)c5ccc6sc7ccccc7c6c5)ccc34)c3ccc4sc5ccccc5c4c3)ccc2c1 ; c1ccc(-c2ccc(N(c3ccc(-c4ccccc4)cc3)c3ccc4c(c3)sc3cc(N(c5ccccc5)c5cccc6ccccc56)ccc34)cc2)cc1 ; c1ccc(N(c2ccc3c(ccn3-c3ccccc3)c2)c2ccc3c(c2)sc2ccc(N(c4ccccc4)c4ccc5c(ccn5-c5ccccc5)c4)cc23)cc1]

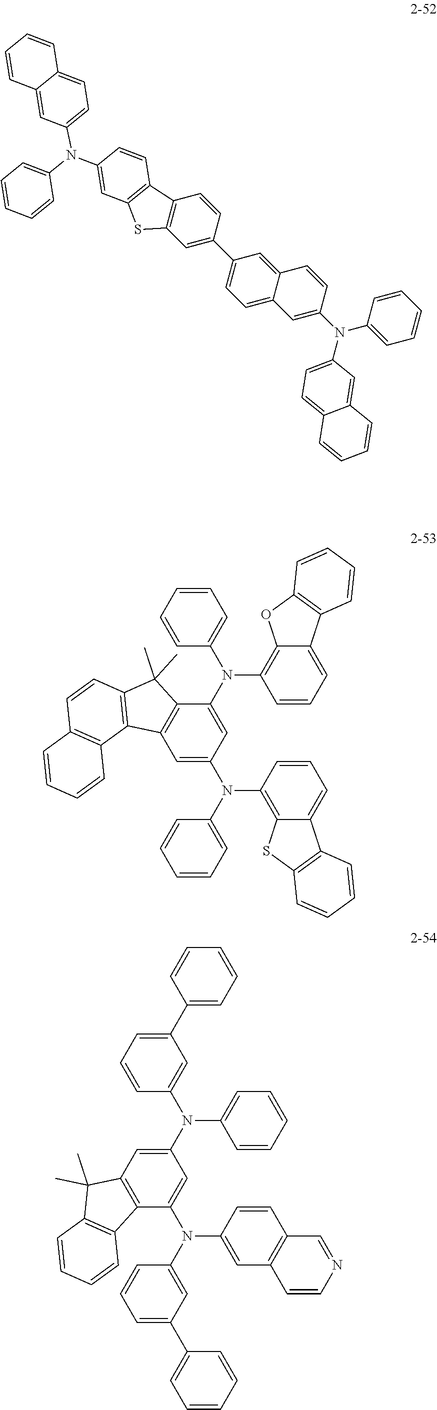 [SMILES: c1ccc(N(c2ccc3ccccc3c2)c2ccc3cc(-c4ccc5c(c4)sc4cc(N(c6ccccc6)c6ccc7ccccc7c6)ccc45)ccc3c2)cc1 ; CC1(C)c2ccc3ccccc3c2-c2cc(N(c3ccccc3)c3cccc4c3sc3ccccc34)cc(N(c3ccccc3)c3cccc4c3oc3ccccc34)c21 ; CC1(C)c2ccccc2-c2c(N(c3cccc(-c4ccccc4)c3)c3ccc4cnccc4c3)cc(N(c3ccccc3)c3cccc(-c4ccccc4)c3)cc21]

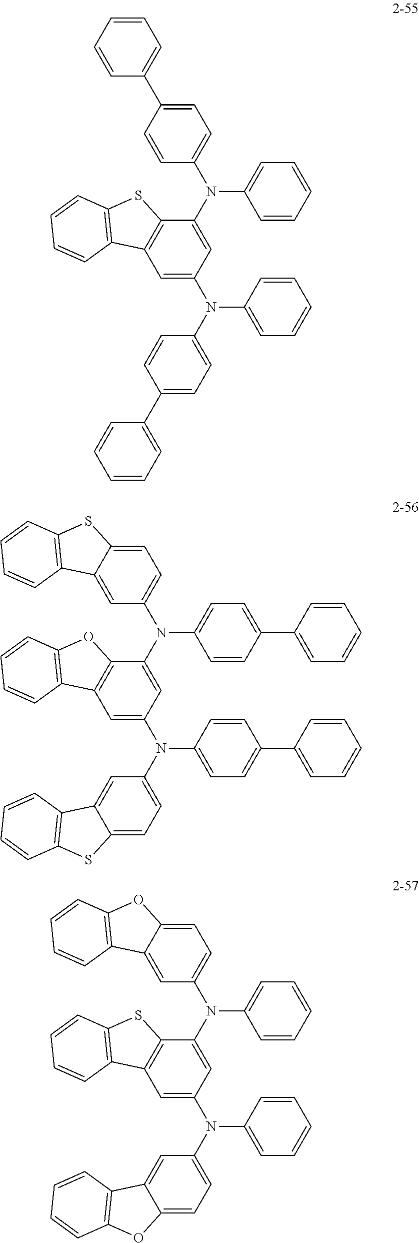

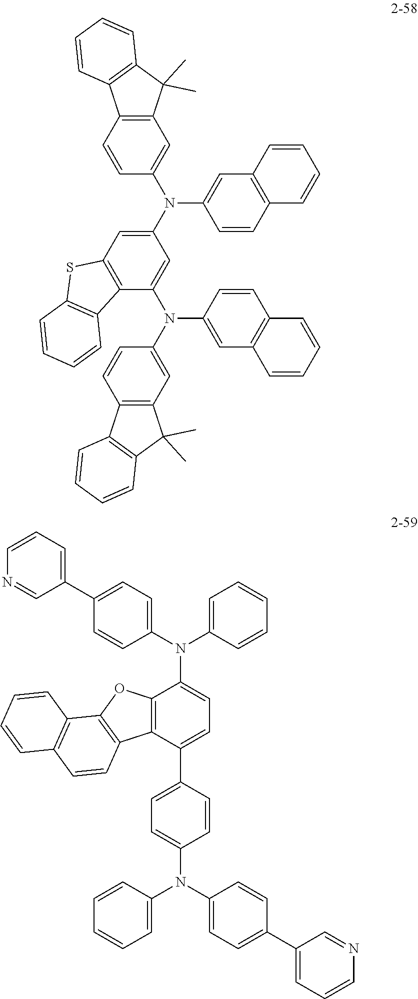 [SMILES: CC1(C)c2ccccc2-c2ccc(N(c3ccc4ccccc4c3)c3cc(N(c4ccc5c(c4)C(C)(C)c4ccccc4-5)c4ccc5ccccc5c4)c4c(c3)sc3ccccc34)cc21 ; c1ccc(N(c2ccc(-c3cccnc3)cc2)c2ccc(-c3ccc(N(c4ccccc4)c4ccc(-c5cccnc5)cc4)c4oc5c6ccccc6ccc5c34)cc2)cc1]

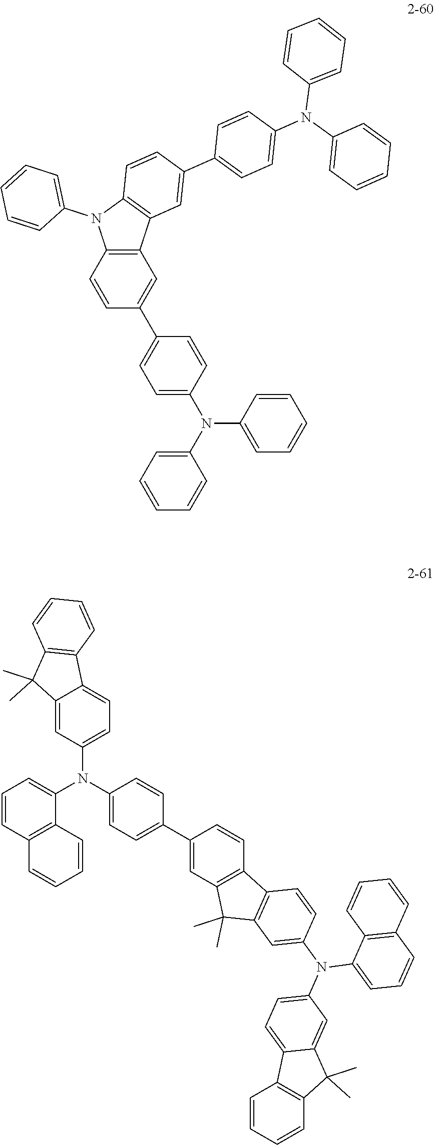 [SMILES: c1ccc(N(c2ccccc2)c2ccc(-c3ccc4c(c3)c3cc(-c5ccc(N(c6ccccc6)c6ccccc6)cc5)ccc3n4-c3ccccc3)cc2)cc1 ; CC1(C)c2ccccc2-c2ccc(N(c3ccc(-c4ccc5c(c4)C(C)(C)c4cc(N(c6ccc7c(c6)C(C)(C)c6ccccc6-7)c6cccc7ccccc67)ccc4-5)cc3)c3cccc4ccccc34)cc21]

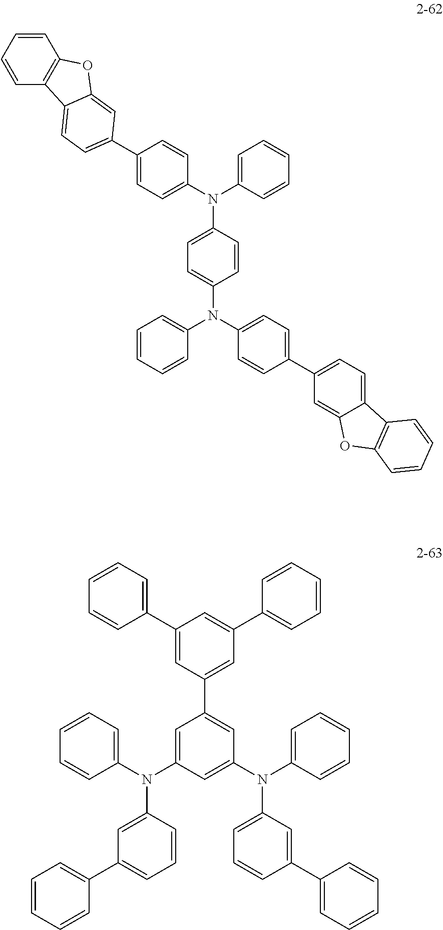 [SMILES: c1ccc(N(c2ccc(-c3ccc4c(c3)oc3ccccc34)cc2)c2ccc(N(c3ccccc3)c3ccc(-c4ccc5c(c4)oc4ccccc45)cc3)cc2)cc1 ; c1ccc(-c2cc(-c3ccccc3)cc(-c3cc(N(c4ccccc4)c4cccc(-c5ccccc5)c4)cc(N(c4ccccc4)c4cccc(-c5ccccc5)c4)c3)c2)cc1]

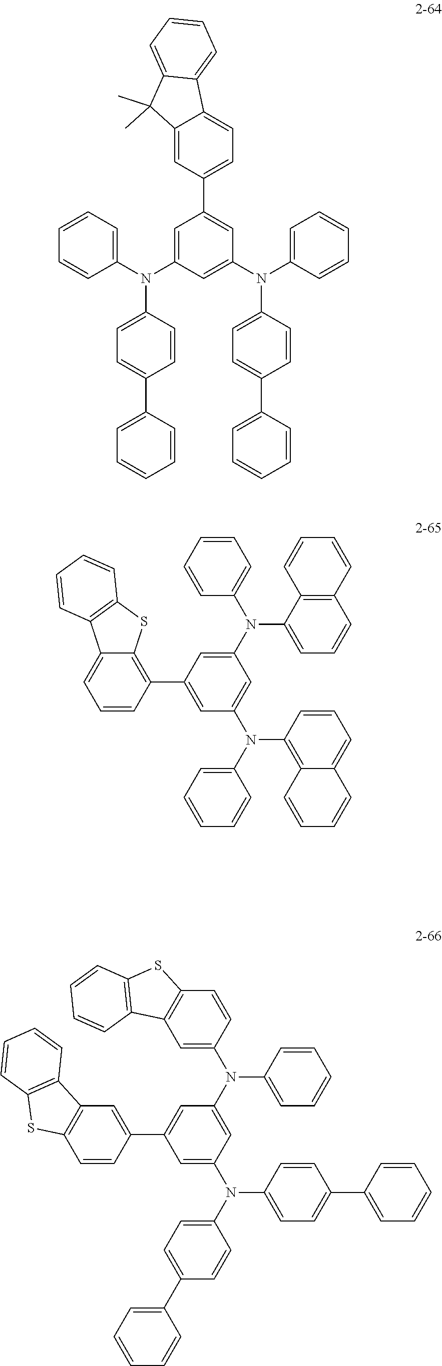 [SMILES: CC1(C)c2ccccc2-c2ccc(-c3cc(N(c4ccccc4)c4ccc(-c5ccccc5)cc4)cc(N(c4ccccc4)c4ccc(-c5ccccc5)cc4)c3)cc21 ; c1ccc(N(c2cc(-c3cccc4c3sc3ccccc34)cc(N(c3ccccc3)c3cccc4ccccc34)c2)c2cccc3ccccc23)cc1 ; c1ccc(-c2ccc(N(c3ccc(-c4ccccc4)cc3)c3cc(-c4ccc5sc6ccccc6c5c4)cc(N(c4ccccc4)c4ccc5sc6ccccc6c5c4)c3)cc2)cc1]

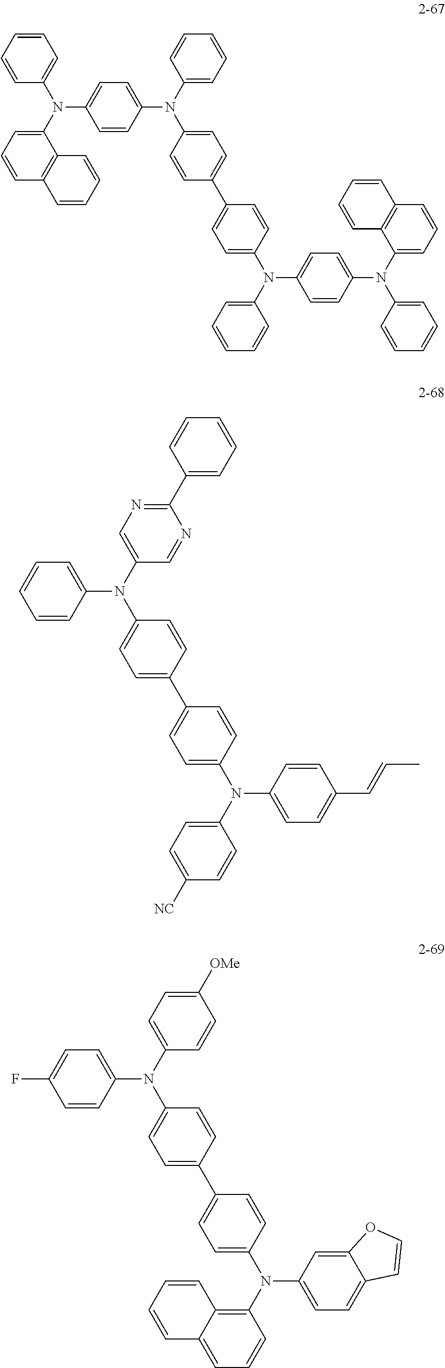 [SMILES: c1ccc(N(c2ccc(-c3ccc(N(c4ccccc4)c4ccc(N(c5ccccc5)c5cccc6ccccc56)cc4)cc3)cc2)c2ccc(N(c3ccccc3)c3cccc4ccccc34)cc2)cc1 ; C/C=C/c1ccc(N(c2ccc(C#N)cc2)c2ccc(-c3ccc(N(c4ccccc4)c4cnc(-c5ccccc5)nc4)cc3)cc2)cc1 ; COc1ccc(N(c2ccc(F)cc2)c2ccc(-c3ccc(N(c4ccc5ccoc5c4)c4cccc5ccccc45)cc3)cc2)cc1]

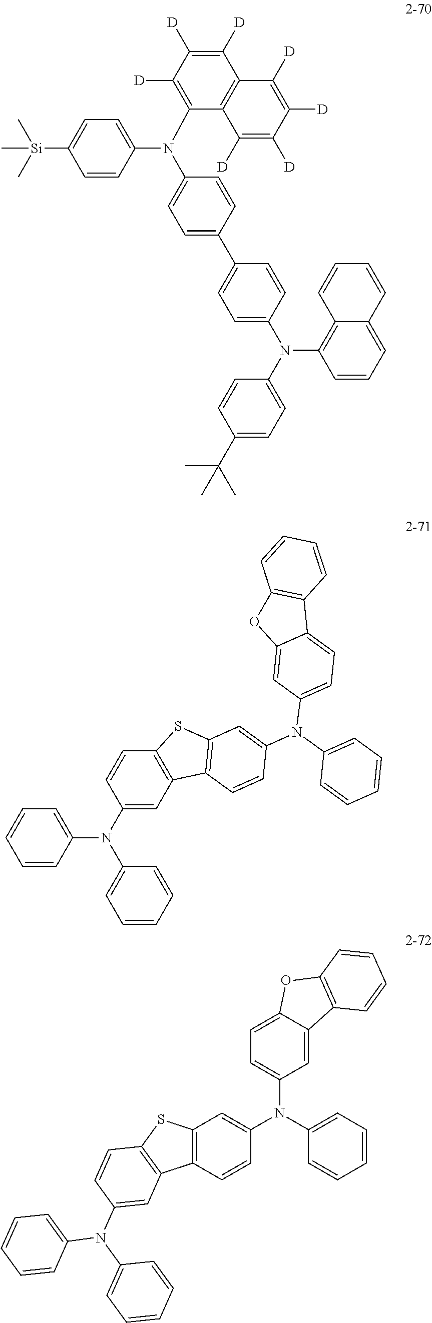 [SMILES: [2H]c1c([2H])c([2H])c2c(N(c3ccc(-c4ccc(N(c5ccc(C(C)(C)C)cc5)c5cccc6ccccc56)cc4)cc3)c3ccc([Si](C)(C)C)cc3)c([2H])c([2H])c([2H])c2c1[2H] ; c1ccc(N(c2ccc3c(c2)oc2ccccc23)c2ccc3c(c2)sc2ccc(N(c4ccccc4)c4ccccc4)cc23)cc1 ; c1ccc(N(c2ccc3c(c2)sc2ccc(N(c4ccccc4)c4ccccc4)cc23)c2ccc3oc4ccccc4c3c2)cc1]

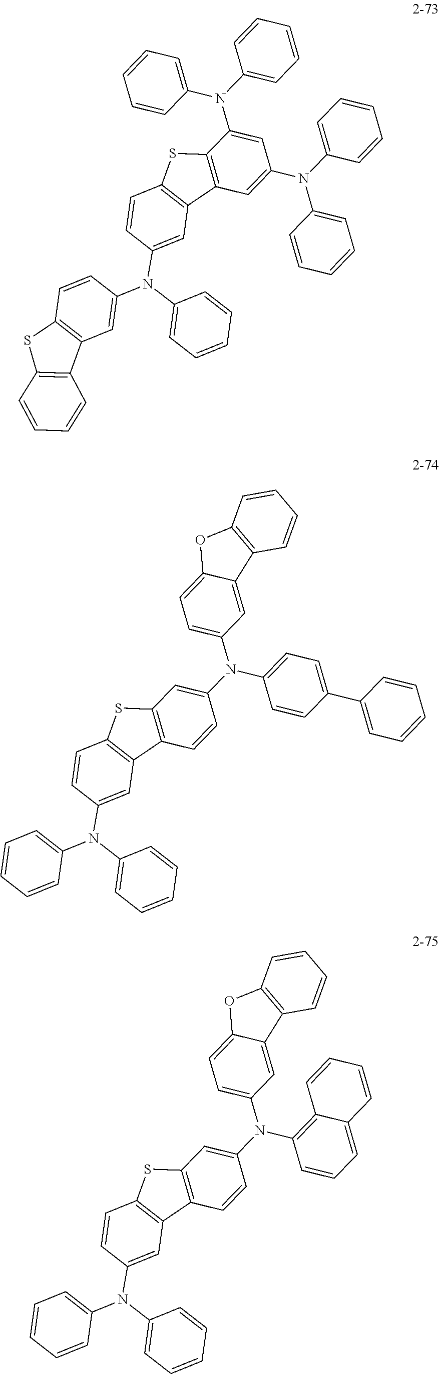 [SMILES: c1ccc(N(c2ccc3sc4ccccc4c3c2)c2ccc3sc4c(N(c5ccccc5)c5ccccc5)cc(N(c5ccccc5)c5ccccc5)cc4c3c2)cc1 ; c1ccc(-c2ccc(N(c3ccc4c(c3)sc3ccc(N(c5ccccc5)c5ccccc5)cc34)c3ccc4oc5ccccc5c4c3)cc2)cc1 ; c1ccc(N(c2ccccc2)c2ccc3sc4cc(N(c5ccc6oc7ccccc7c6c5)c5cccc6ccccc56)ccc4c3c2)cc1]

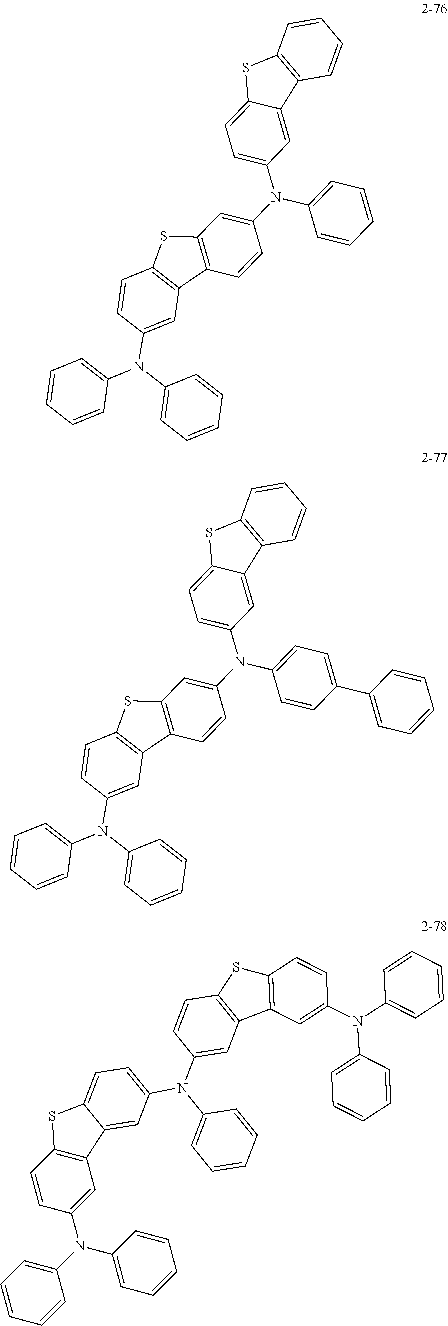 [SMILES: c1ccc(N(c2ccc3c(c2)sc2ccc(N(c4ccccc4)c4ccccc4)cc23)c2ccc3sc4ccccc4c3c2)cc1 ; c1ccc(-c2ccc(N(c3ccc4c(c3)sc3ccc(N(c5ccccc5)c5ccccc5)cc34)c3ccc4sc5ccccc5c4c3)cc2)cc1 ; c1ccc(N(c2ccccc2)c2ccc3sc4ccc(N(c5ccccc5)c5ccc6sc7ccc(N(c8ccccc8)c8ccccc8)cc7c6c5)cc4c3c2)cc1]

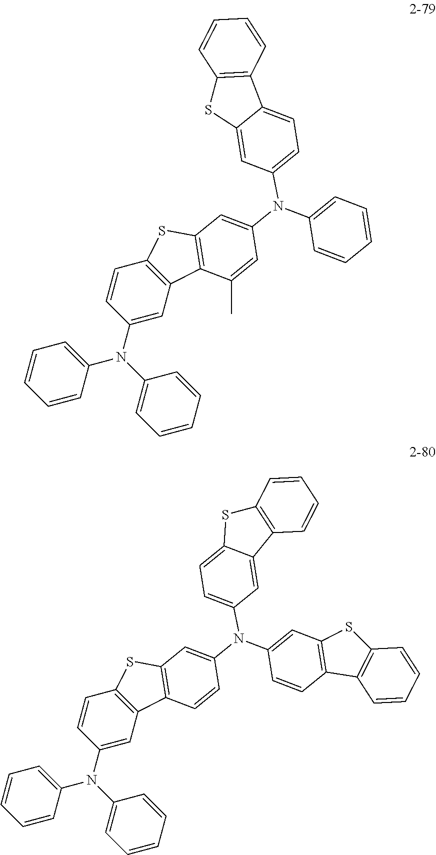 [SMILES: Cc1cc(N(c2ccccc2)c2ccc3c(c2)sc2ccccc23)cc2sc3ccc(N(c4ccccc4)c4ccccc4)cc3c12 ; c1ccc(N(c2ccccc2)c2ccc3sc4cc(N(c5ccc6c(c5)sc5ccccc56)c5ccc6sc7ccccc7c6c5)ccc4c3c2)cc1]

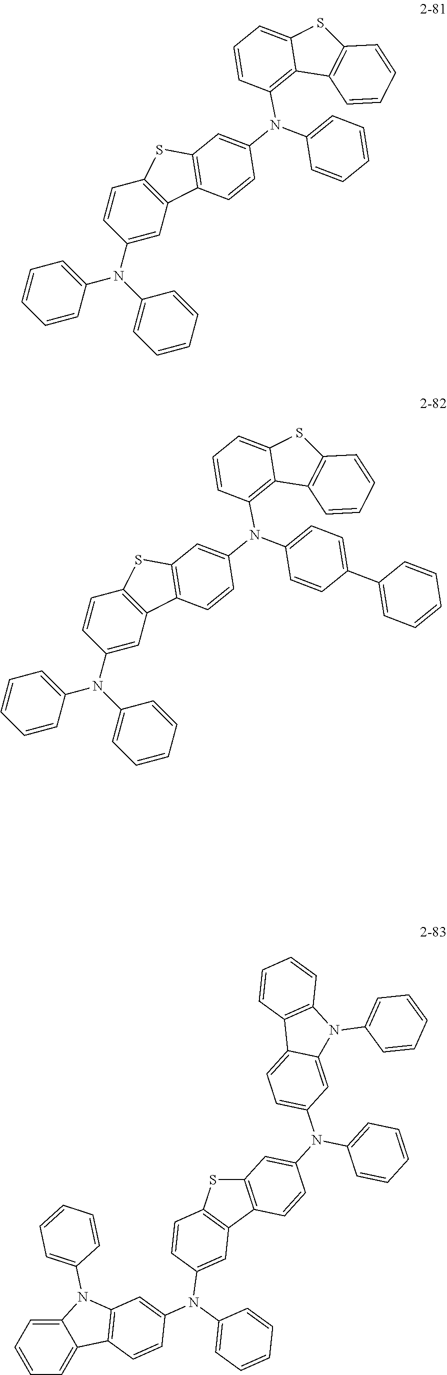 [SMILES: c1ccc(N(c2ccccc2)c2ccc3sc4cc(N(c5ccccc5)c5cccc6sc7ccccc7c56)ccc4c3c2)cc1 ; c1ccc(-c2ccc(N(c3ccc4c(c3)sc3ccc(N(c5ccccc5)c5ccccc5)cc34)c3cccc4sc5ccccc5c34)cc2)cc1 ; c1ccc(N(c2ccc3c(c2)sc2ccc(N(c4ccccc4)c4ccc5c6ccccc6n(-c6ccccc6)c5c4)cc23)c2ccc3c4ccccc4n(-c4ccccc4)c3c2)cc1]

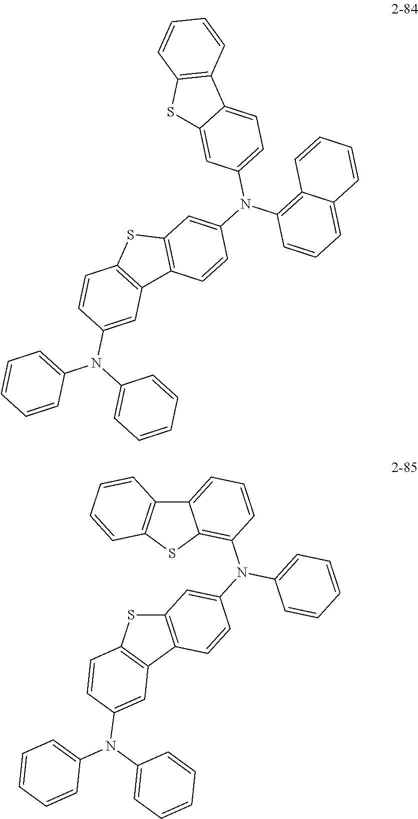

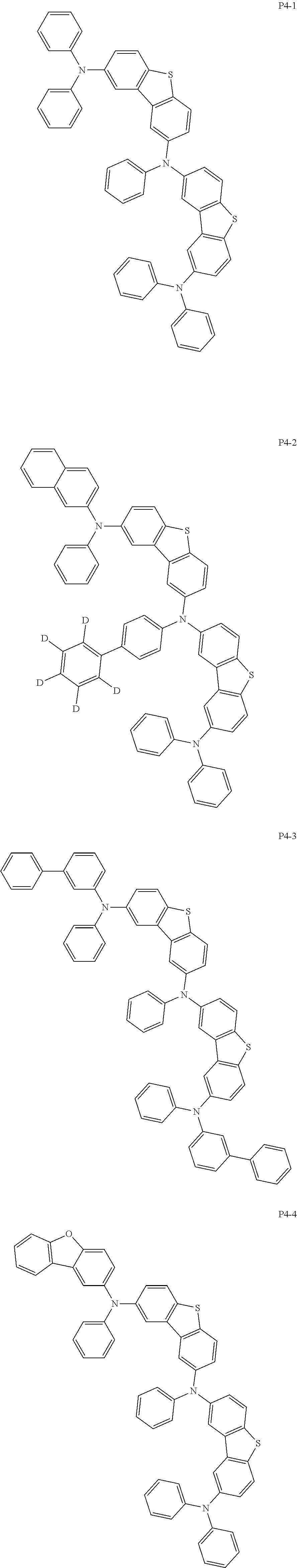 [SMILES: c1ccc(N(c2ccccc2)c2ccc3sc4ccc(N(c5ccccc5)c5ccc6sc7ccc(N(c8ccccc8)c8ccccc8)cc7c6c5)cc4c3c2)cc1 ; [2H]c1c([2H])c([2H])c(-c2ccc(N(c3ccc4sc5ccc(N(c6ccccc6)c6ccccc6)cc5c4c3)c3ccc4sc5ccc(N(c6ccccc6)c6ccc7ccccc7c6)cc5c4c3)cc2)c([2H])c1[2H] ; c1ccc(-c2cccc(N(c3ccccc3)c3ccc4sc5ccc(N(c6ccccc6)c6ccc7sc8ccc(N(c9ccccc9)c9cccc(-c%10ccccc%10)c9)cc8c7c6)cc5c4c3)c2)cc1 ; c1ccc(N(c2ccccc2)c2ccc3sc4ccc(N(c5ccccc5)c5ccc6sc7ccc(N(c8ccccc8)c8ccc9oc%10ccccc%10c9c8)cc7c6c5)cc4c3c2)cc1]

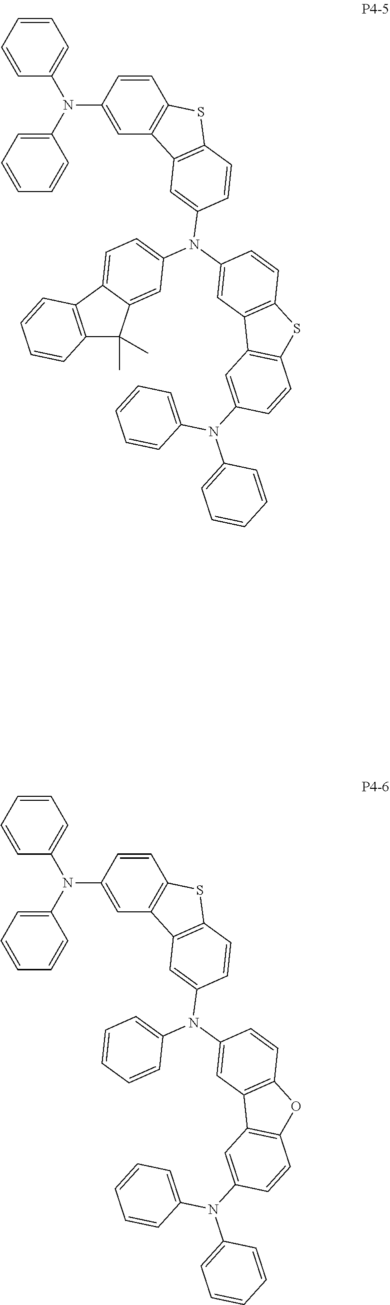 [SMILES: CC1(C)c2ccccc2-c2ccc(N(c3ccc4sc5ccc(N(c6ccccc6)c6ccccc6)cc5c4c3)c3ccc4sc5ccc(N(c6ccccc6)c6ccccc6)cc5c4c3)cc21 ; c1ccc(N(c2ccccc2)c2ccc3oc4ccc(N(c5ccccc5)c5ccc6sc7ccc(N(c8ccccc8)c8ccccc8)cc7c6c5)cc4c3c2)cc1]

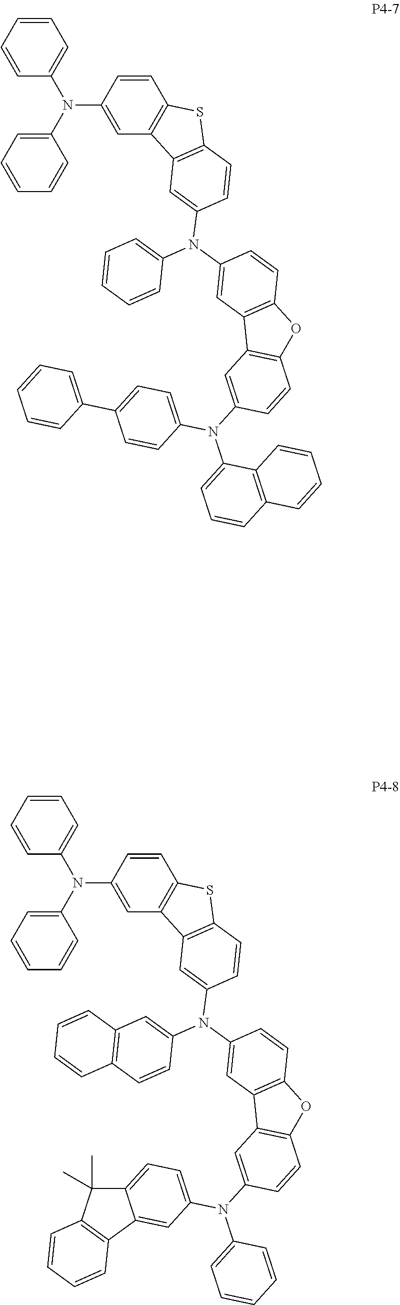 [SMILES: c1ccc(-c2ccc(N(c3ccc4oc5ccc(N(c6ccccc6)c6ccc7sc8ccc(N(c9ccccc9)c9ccccc9)cc8c7c6)cc5c4c3)c3cccc4ccccc34)cc2)cc1 ; CC1(C)c2ccccc2-c2cc(N(c3ccccc3)c3ccc4oc5ccc(N(c6ccc7ccccc7c6)c6ccc7sc8ccc(N(c9ccccc9)c9ccccc9)cc8c7c6)cc5c4c3)ccc21]

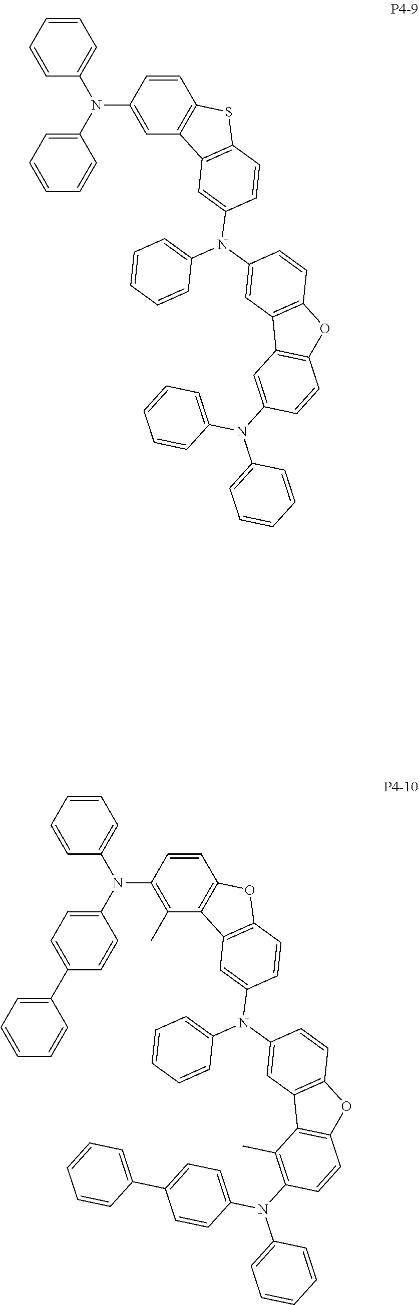 [SMILES: c1ccc(N(c2ccccc2)c2ccc3oc4ccc(N(c5ccccc5)c5ccc6sc7ccc(N(c8ccccc8)c8ccccc8)cc7c6c5)cc4c3c2)cc1 ; Cc1c(N(c2ccccc2)c2ccc(-c3ccccc3)cc2)ccc2oc3ccc(N(c4ccccc4)c4ccc5oc6ccc(N(c7ccccc7)c7ccc(-c8ccccc8)cc7)c(C)c6c5c4)cc3c12]

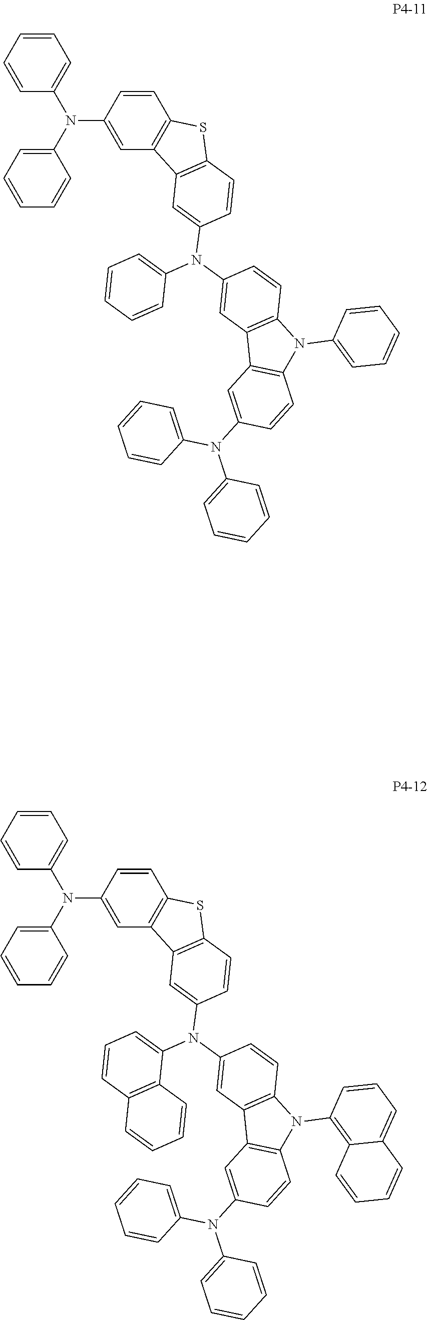 [SMILES: c1ccc(N(c2ccccc2)c2ccc3sc4ccc(N(c5ccccc5)c5ccc6c(c5)c5cc(N(c7ccccc7)c7ccccc7)ccc5n6-c5ccccc5)cc4c3c2)cc1 ; c1ccc(N(c2ccccc2)c2ccc3sc4ccc(N(c5ccc6c(c5)c5cc(N(c7ccccc7)c7ccccc7)ccc5n6-c5cccc6ccccc56)c5cccc6ccccc56)cc4c3c2)cc1]

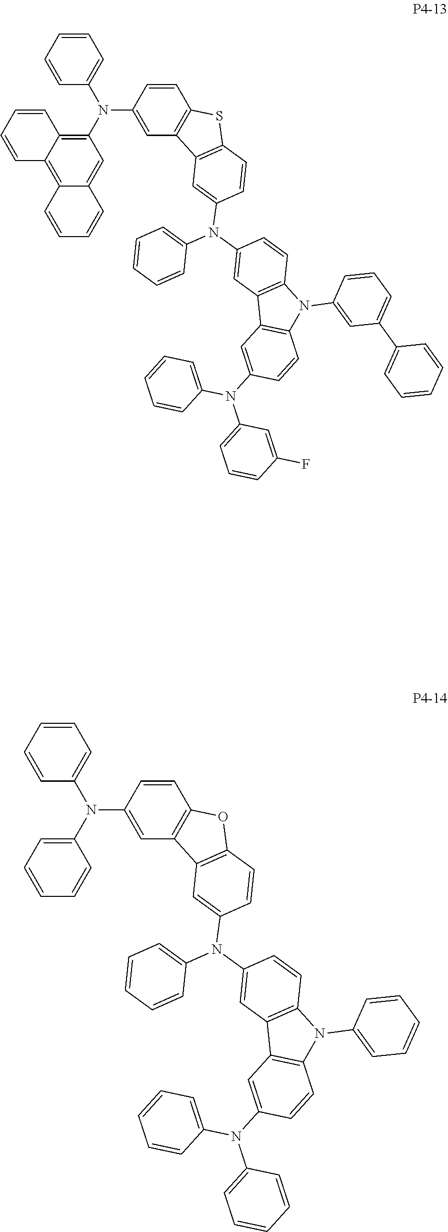 [SMILES: Fc1cccc(N(c2ccccc2)c2ccc3c(c2)c2cc(N(c4ccccc4)c4ccc5sc6ccc(N(c7ccccc7)c7cc8ccccc8c8ccccc78)cc6c5c4)ccc2n3-c2cccc(-c3ccccc3)c2)c1 ; c1ccc(N(c2ccccc2)c2ccc3oc4ccc(N(c5ccccc5)c5ccc6c(c5)c5cc(N(c7ccccc7)c7ccccc7)ccc5n6-c5ccccc5)cc4c3c2)cc1]

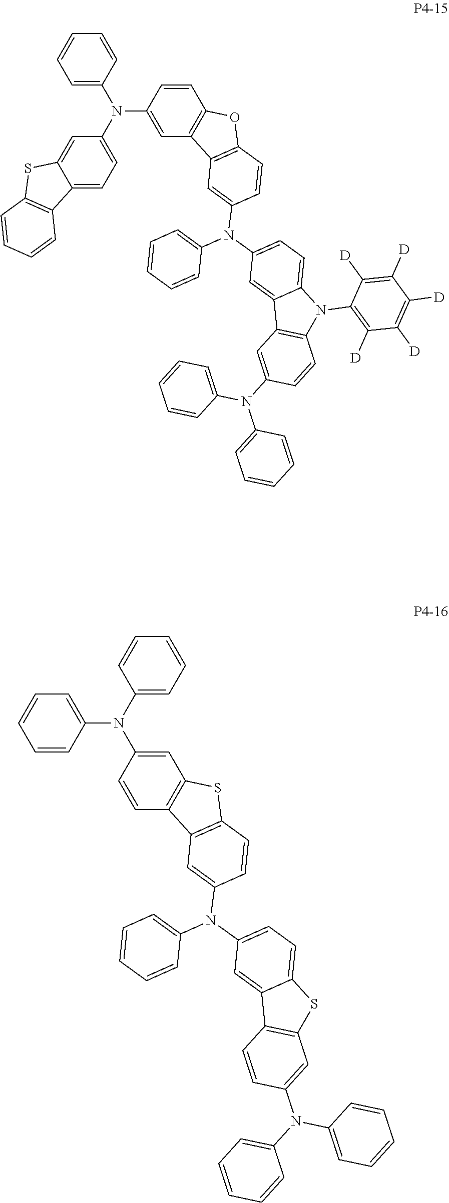 [SMILES: [2H]c1c([2H])c([2H])c(-n2c3ccc(N(c4ccccc4)c4ccccc4)cc3c3cc(N(c4ccccc4)c4ccc5oc6ccc(N(c7ccccc7)c7ccc8c(c7)sc7ccccc78)cc6c5c4)ccc32)c([2H])c1[2H] ; c1ccc(N(c2ccccc2)c2ccc3c(c2)sc2ccc(N(c4ccccc4)c4ccc5sc6cc(N(c7ccccc7)c7ccccc7)ccc6c5c4)cc23)cc1]

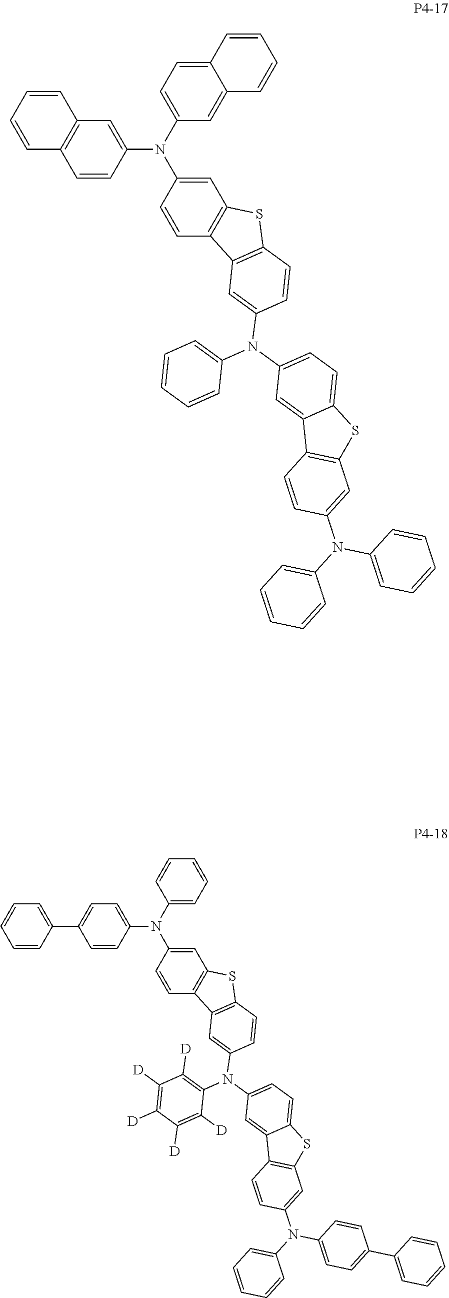 [SMILES: c1ccc(N(c2ccccc2)c2ccc3c(c2)sc2ccc(N(c4ccccc4)c4ccc5sc6cc(N(c7ccc8ccccc8c7)c7ccc8ccccc8c7)ccc6c5c4)cc23)cc1 ; [2H]c1c([2H])c([2H])c(N(c2ccc3sc4cc(N(c5ccccc5)c5ccc(-c6ccccc6)cc5)ccc4c3c2)c2ccc3sc4cc(N(c5ccccc5)c5ccc(-c6ccccc6)cc5)ccc4c3c2)c([2H])c1[2H]]

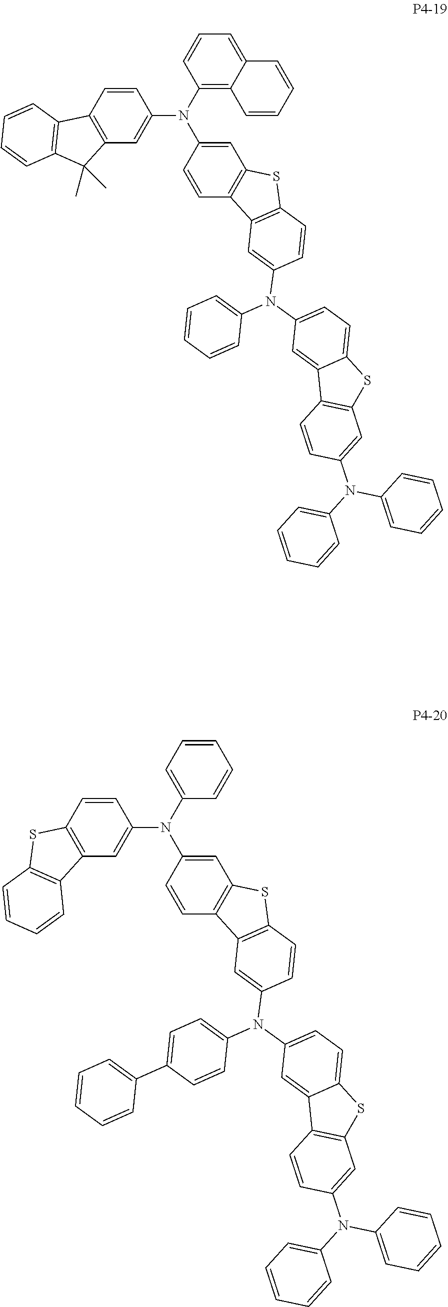 [SMILES: CC1(C)c2ccccc2-c2ccc(N(c3ccc4c(c3)sc3ccc(N(c5ccccc5)c5ccc6sc7cc(N(c8ccccc8)c8ccccc8)ccc7c6c5)cc34)c3cccc4ccccc34)cc21 ; c1ccc(-c2ccc(N(c3ccc4sc5cc(N(c6ccccc6)c6ccccc6)ccc5c4c3)c3ccc4sc5cc(N(c6ccccc6)c6ccc7sc8ccccc8c7c6)ccc5c4c3)cc2)cc1]

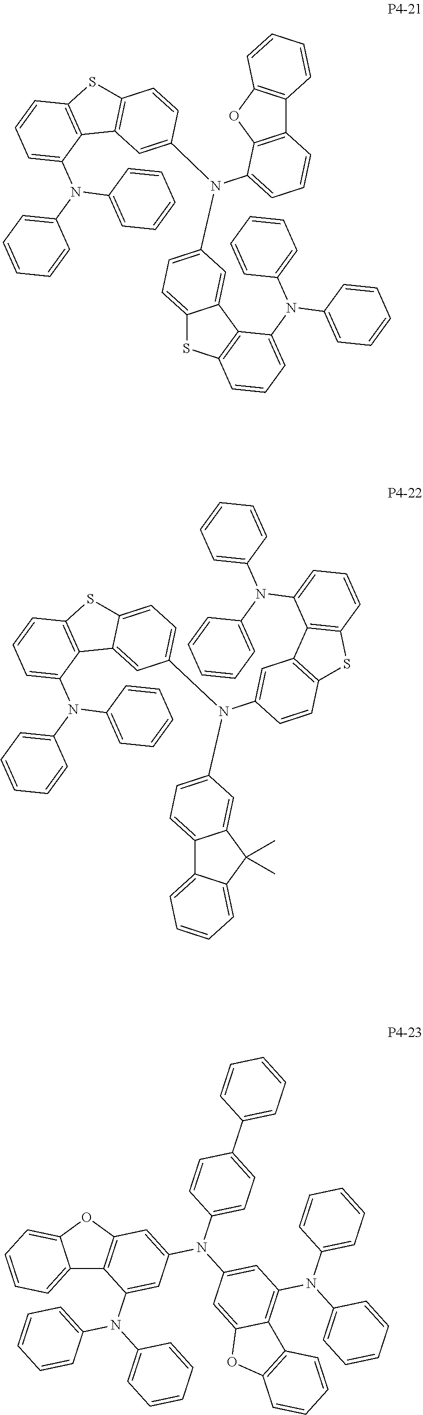 [SMILES: c1ccc(N(c2ccccc2)c2cccc3sc4ccc(N(c5ccc6sc7cccc(N(c8ccccc8)c8ccccc8)c7c6c5)c5cccc6c5oc5ccccc56)cc4c23)cc1 ; CC1(C)c2ccccc2-c2ccc(N(c3ccc4sc5cccc(N(c6ccccc6)c6ccccc6)c5c4c3)c3ccc4sc5cccc(N(c6ccccc6)c6ccccc6)c5c4c3)cc21 ; c1ccc(-c2ccc(N(c3cc(N(c4ccccc4)c4ccccc4)c4c(c3)oc3ccccc34)c3cc(N(c4ccccc4)c4ccccc4)c4c(c3)oc3ccccc34)cc2)cc1]

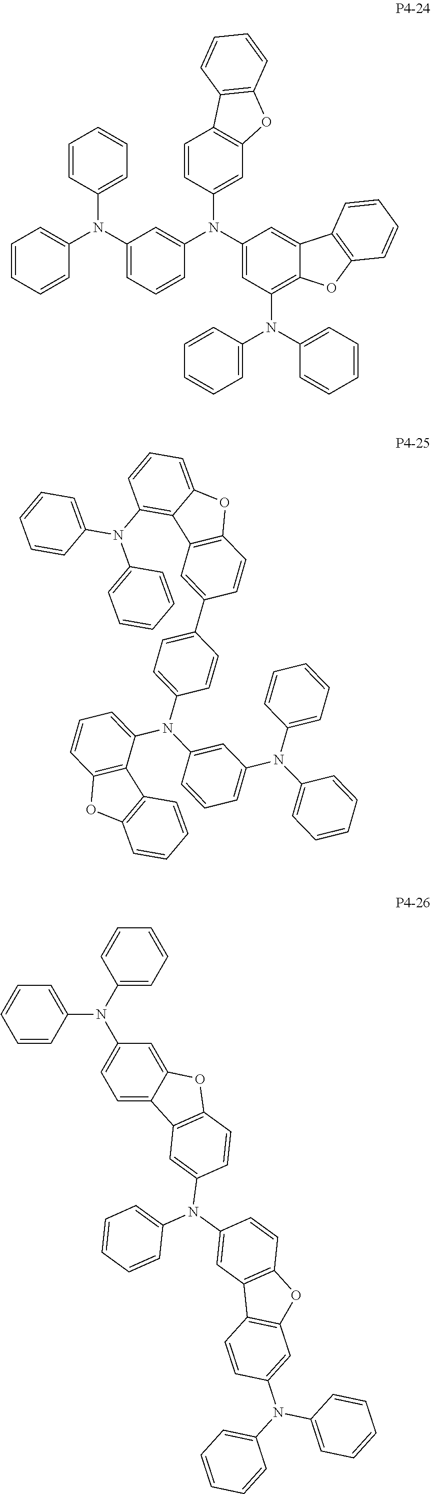 [SMILES: c1ccc(N(c2ccccc2)c2cccc(N(c3ccc4c(c3)oc3ccccc34)c3cc(N(c4ccccc4)c4ccccc4)c4oc5ccccc5c4c3)c2)cc1 ; c1ccc(N(c2ccccc2)c2cccc(N(c3ccc(-c4ccc5oc6cccc(N(c7ccccc7)c7ccccc7)c6c5c4)cc3)c3cccc4oc5ccccc5c34)c2)cc1 ; c1ccc(N(c2ccccc2)c2ccc3c(c2)oc2ccc(N(c4ccccc4)c4ccc5oc6cc(N(c7ccccc7)c7ccccc7)ccc6c5c4)cc23)cc1]

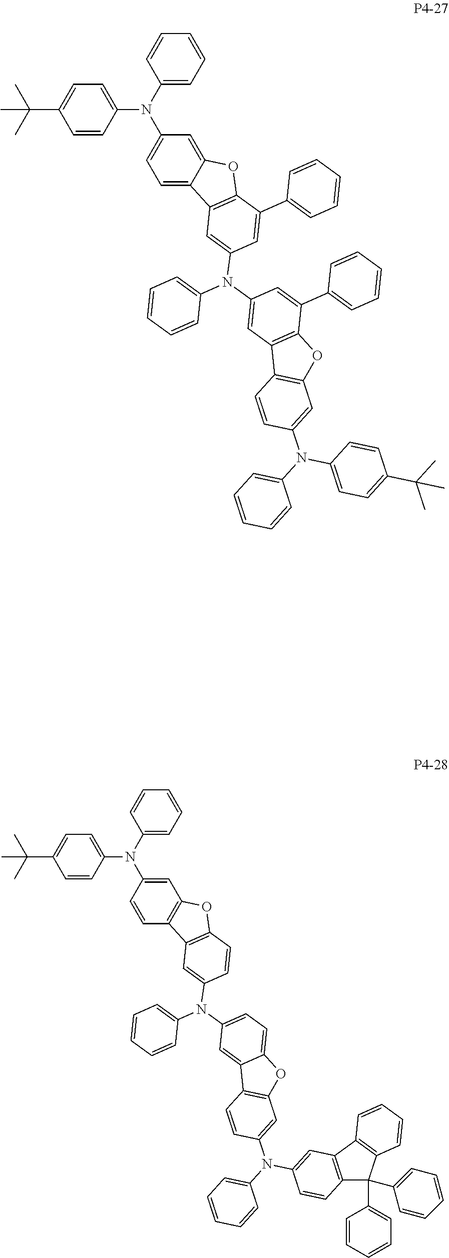

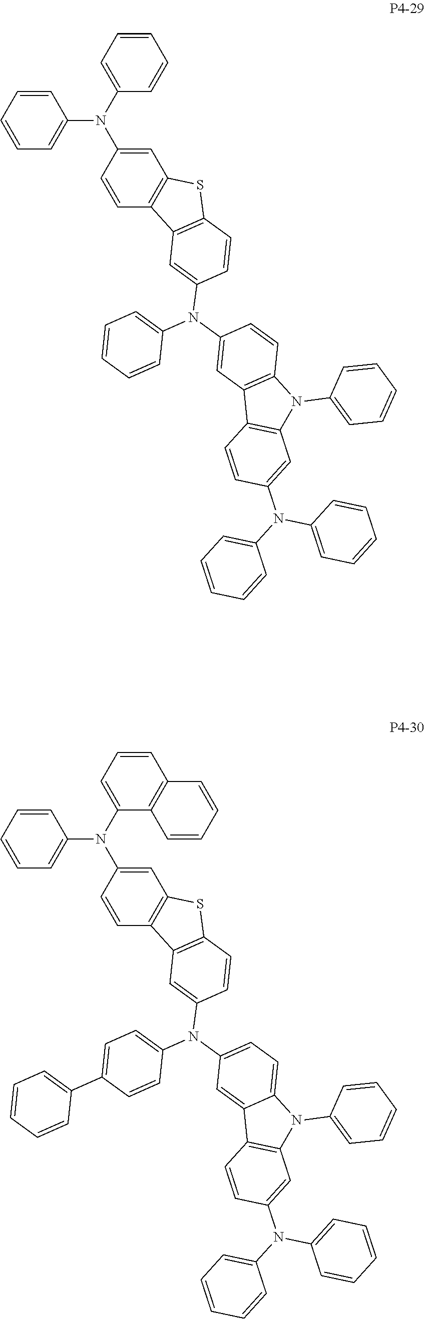 [SMILES: c1ccc(N(c2ccccc2)c2ccc3c(c2)sc2ccc(N(c4ccccc4)c4ccc5c(c4)c4ccc(N(c6ccccc6)c6ccccc6)cc4n5-c4ccccc4)cc23)cc1 ; c1ccc(-c2ccc(N(c3ccc4sc5cc(N(c6ccccc6)c6cccc7ccccc67)ccc5c4c3)c3ccc4c(c3)c3ccc(N(c5ccccc5)c5ccccc5)cc3n4-c3ccccc3)cc2)cc1]

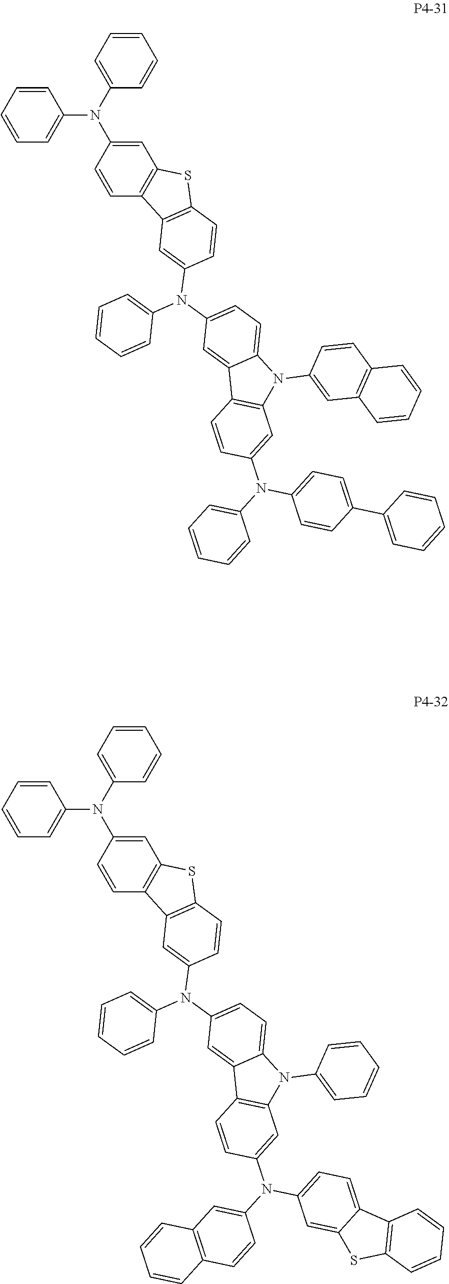 [SMILES: c1ccc(-c2ccc(N(c3ccccc3)c3ccc4c5cc(N(c6ccccc6)c6ccc7sc8cc(N(c9ccccc9)c9ccccc9)ccc8c7c6)ccc5n(-c5ccc6ccccc6c5)c4c3)cc2)cc1 ; c1ccc(N(c2ccccc2)c2ccc3c(c2)sc2ccc(N(c4ccccc4)c4ccc5c(c4)c4ccc(N(c6ccc7ccccc7c6)c6ccc7c(c6)sc6ccccc67)cc4n5-c4ccccc4)cc23)cc1]

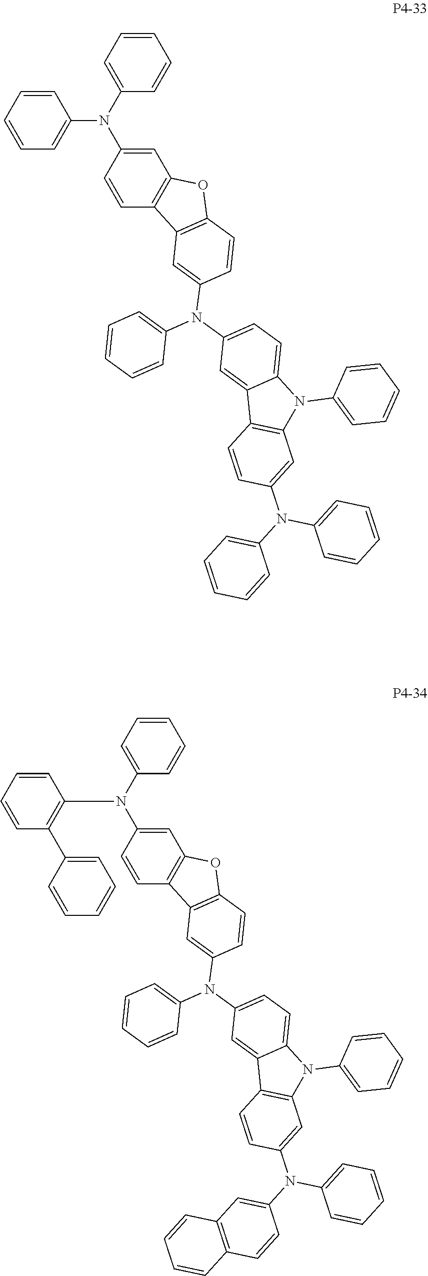 [SMILES: c1ccc(N(c2ccccc2)c2ccc3c(c2)oc2ccc(N(c4ccccc4)c4ccc5c(c4)c4ccc(N(c6ccccc6)c6ccccc6)cc4n5-c4ccccc4)cc23)cc1 ; c1ccc(-c2ccccc2N(c2ccccc2)c2ccc3c(c2)oc2ccc(N(c4ccccc4)c4ccc5c(c4)c4ccc(N(c6ccccc6)c6ccc7ccccc7c6)cc4n5-c4ccccc4)cc23)cc1]

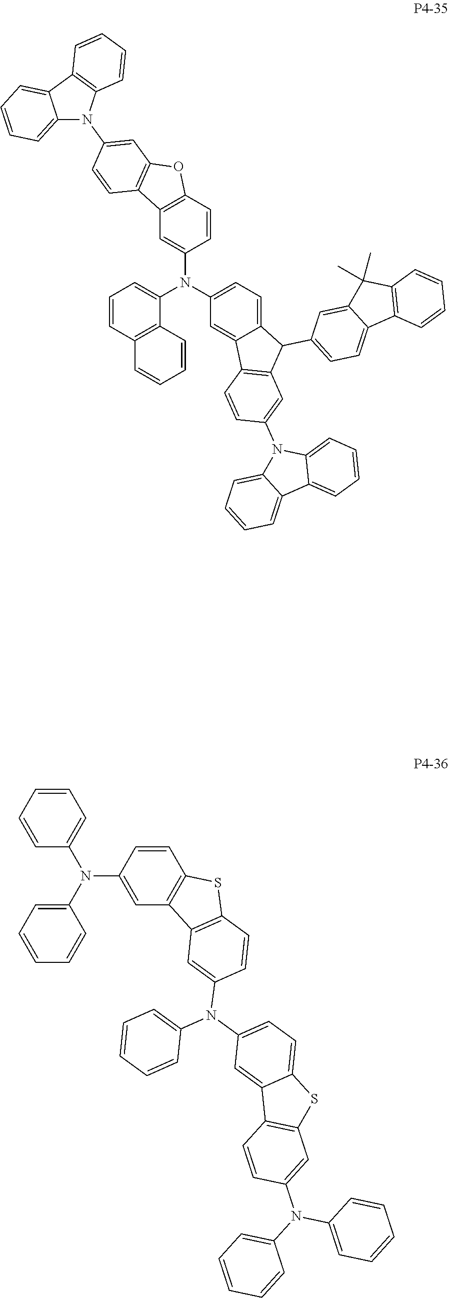 [SMILES: CC1(C)c2ccccc2-c2ccc(C3c4ccc(N(c5ccc6oc7cc(-n8c9ccccc9c9ccccc98)ccc7c6c5)c5cccc6ccccc56)cc4-c4ccc(-n5c6ccccc6c6ccccc65)cc43)cc21 ; c1ccc(N(c2ccccc2)c2ccc3c(c2)sc2ccc(N(c4ccccc4)c4ccc5sc6ccc(N(c7ccccc7)c7ccccc7)cc6c5c4)cc23)cc1]

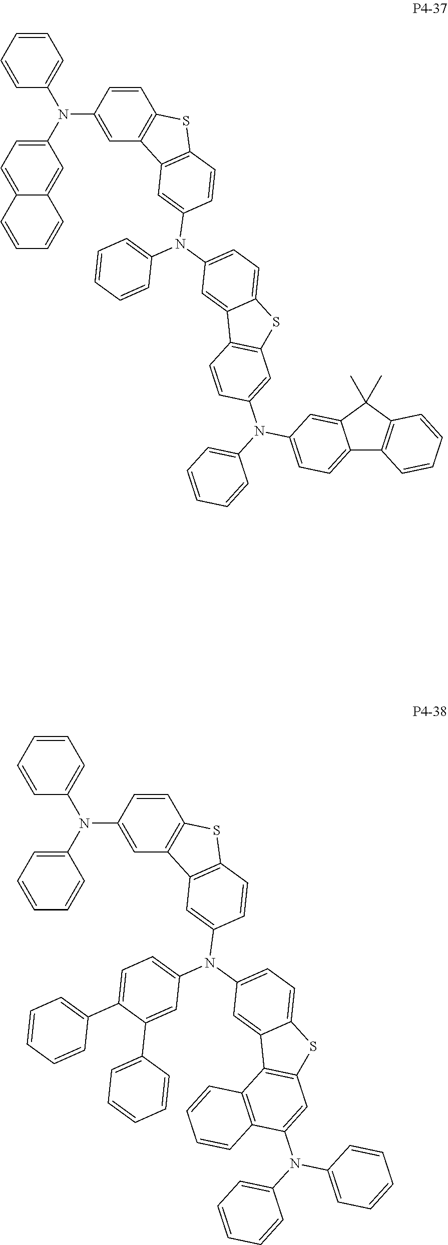 [SMILES: CC1(C)c2ccccc2-c2ccc(N(c3ccccc3)c3ccc4c(c3)sc3ccc(N(c5ccccc5)c5ccc6sc7ccc(N(c8ccccc8)c8ccc9ccccc9c8)cc7c6c5)cc34)cc21 ; c1ccc(-c2ccc(N(c3ccc4sc5ccc(N(c6ccccc6)c6ccccc6)cc5c4c3)c3ccc4sc5cc(N(c6ccccc6)c6ccccc6)c6ccccc6c5c4c3)cc2-c2ccccc2)cc1]

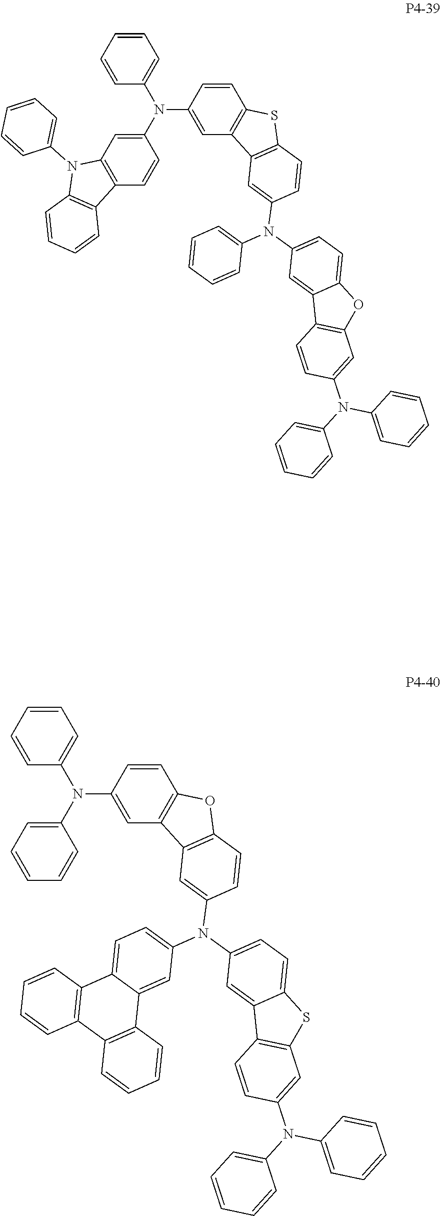 [SMILES: c1ccc(N(c2ccccc2)c2ccc3c(c2)oc2ccc(N(c4ccccc4)c4ccc5sc6ccc(N(c7ccccc7)c7ccc8c9ccccc9n(-c9ccccc9)c8c7)cc6c5c4)cc23)cc1 ; c1ccc(N(c2ccccc2)c2ccc3c(c2)sc2ccc(N(c4ccc5oc6ccc(N(c7ccccc7)c7ccccc7)cc6c5c4)c4ccc5c6ccccc6c6ccccc6c5c4)cc23)cc1]

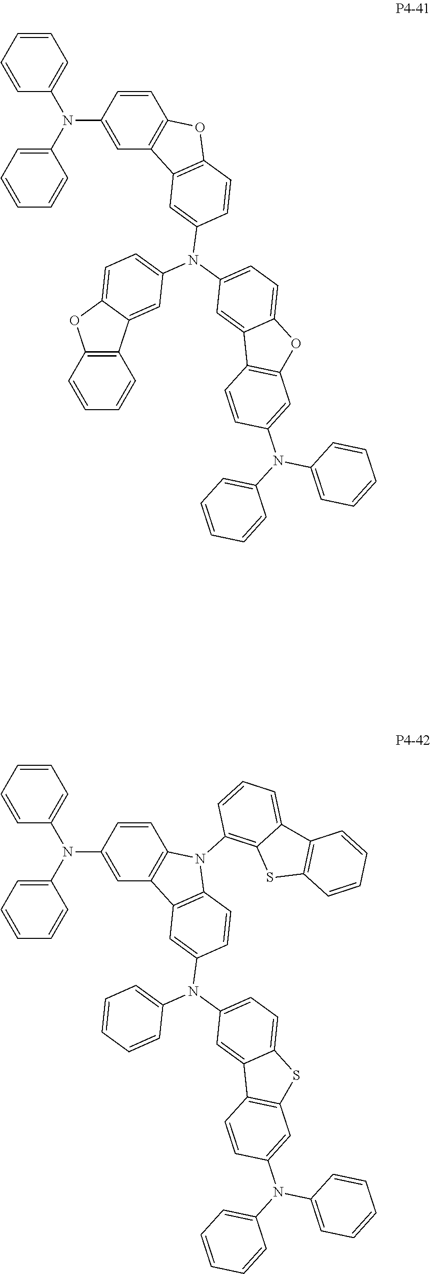 [SMILES: c1ccc(N(c2ccccc2)c2ccc3c(c2)oc2ccc(N(c4ccc5oc6ccccc6c5c4)c4ccc5oc6ccc(N(c7ccccc7)c7ccccc7)cc6c5c4)cc23)cc1 ; c1ccc(N(c2ccccc2)c2ccc3c(c2)sc2ccc(N(c4ccccc4)c4ccc5c(c4)c4cc(N(c6ccccc6)c6ccccc6)ccc4n5-c4cccc5c4sc4ccccc45)cc23)cc1]

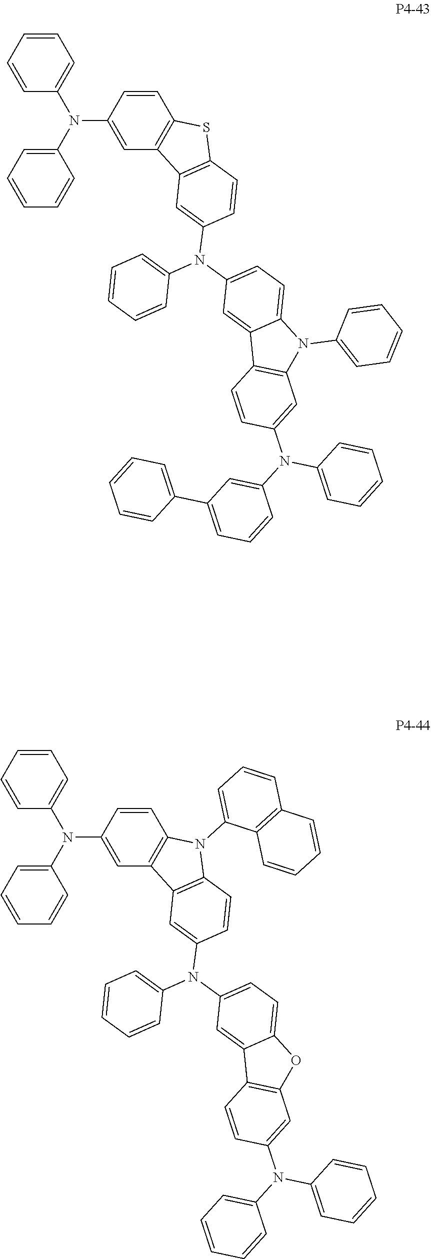 [SMILES: c1ccc(-c2cccc(N(c3ccccc3)c3ccc4c5cc(N(c6ccccc6)c6ccc7sc8ccc(N(c9ccccc9)c9ccccc9)cc8c7c6)ccc5n(-c5ccccc5)c4c3)c2)cc1 ; c1ccc(N(c2ccccc2)c2ccc3c(c2)oc2ccc(N(c4ccccc4)c4ccc5c(c4)c4cc(N(c6ccccc6)c6ccccc6)ccc4n5-c4cccc5ccccc45)cc23)cc1]

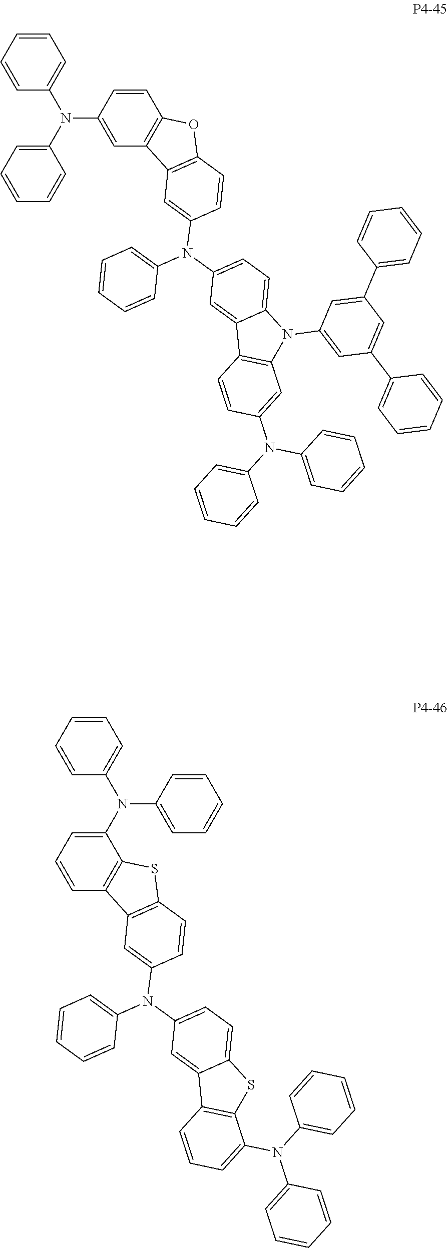 [SMILES: c1ccc(-c2cc(-c3ccccc3)cc(-n3c4ccc(N(c5ccccc5)c5ccc6oc7ccc(N(c8ccccc8)c8ccccc8)cc7c6c5)cc4c4ccc(N(c5ccccc5)c5ccccc5)cc43)c2)cc1 ; c1ccc(N(c2ccc3sc4c(N(c5ccccc5)c5ccccc5)cccc4c3c2)c2ccc3sc4c(N(c5ccccc5)c5ccccc5)cccc4c3c2)cc1]

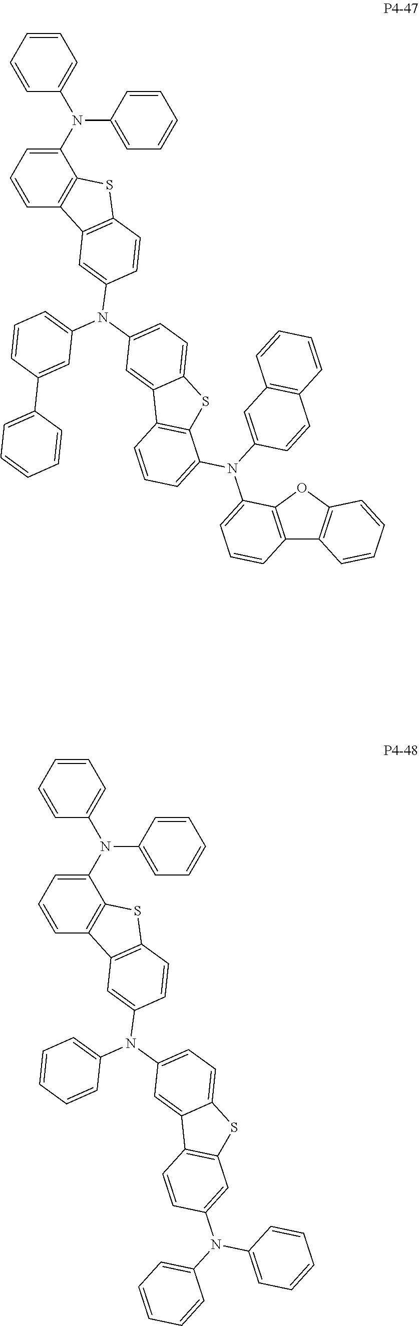 [SMILES: c1ccc(-c2cccc(N(c3ccc4sc5c(N(c6ccccc6)c6ccccc6)cccc5c4c3)c3ccc4sc5c(N(c6ccc7ccccc7c6)c6cccc7c6oc6ccccc67)cccc5c4c3)c2)cc1 ; c1ccc(N(c2ccccc2)c2ccc3c(c2)sc2ccc(N(c4ccccc4)c4ccc5sc6c(N(c7ccccc7)c7ccccc7)cccc6c5c4)cc23)cc1]

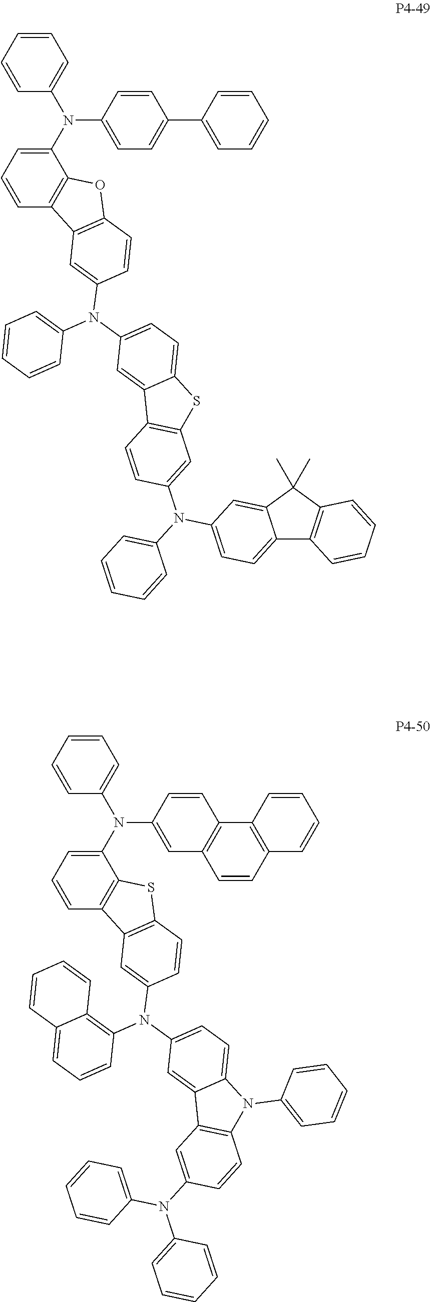 [SMILES: CC1(C)c2ccccc2-c2ccc(N(c3ccccc3)c3ccc4c(c3)sc3ccc(N(c5ccccc5)c5ccc6oc7c(N(c8ccccc8)c8ccc(-c9ccccc9)cc8)cccc7c6c5)cc34)cc21 ; c1ccc(N(c2ccccc2)c2ccc3c(c2)c2cc(N(c4ccc5sc6c(N(c7ccccc7)c7ccc8c(ccc9ccccc98)c7)cccc6c5c4)c4cccc5ccccc45)ccc2n3-c2ccccc2)cc1]

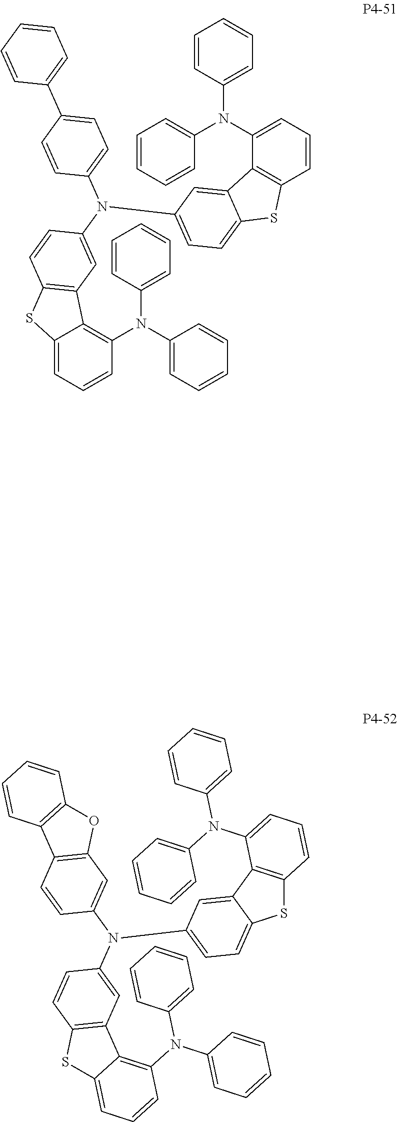 [SMILES: c1ccc(-c2ccc(N(c3ccc4sc5cccc(N(c6ccccc6)c6ccccc6)c5c4c3)c3ccc4sc5cccc(N(c6ccccc6)c6ccccc6)c5c4c3)cc2)cc1 ; c1ccc(N(c2ccccc2)c2cccc3sc4ccc(N(c5ccc6c(c5)oc5ccccc56)c5ccc6sc7cccc(N(c8ccccc8)c8ccccc8)c7c6c5)cc4c23)cc1]

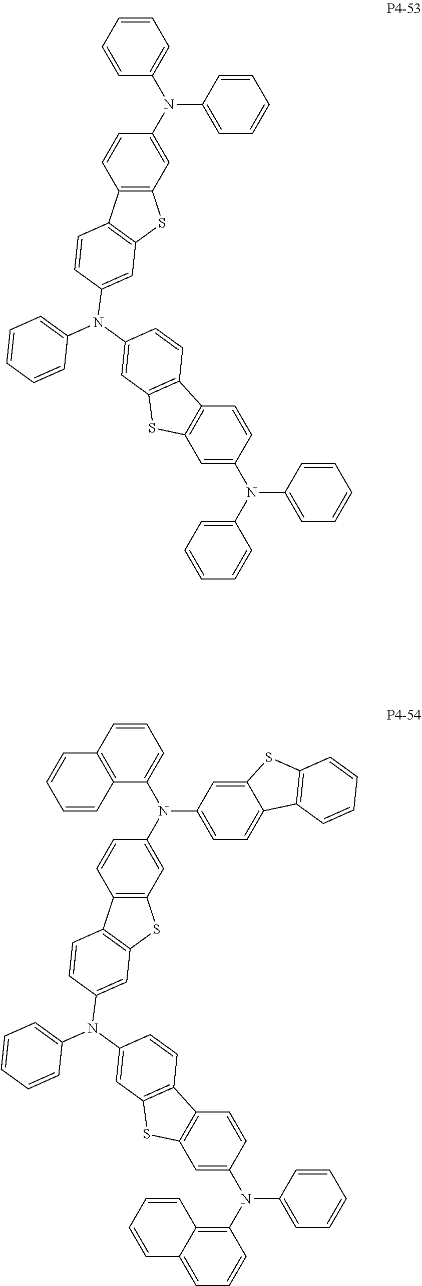 [SMILES: c1ccc(N(c2ccccc2)c2ccc3c(c2)sc2cc(N(c4ccccc4)c4ccc5c(c4)sc4cc(N(c6ccccc6)c6ccccc6)ccc45)ccc23)cc1 ; c1ccc(N(c2ccc3c(c2)sc2cc(N(c4ccccc4)c4cccc5ccccc45)ccc23)c2ccc3c(c2)sc2cc(N(c4ccc5c(c4)sc4ccccc45)c4cccc5ccccc45)ccc23)cc1]

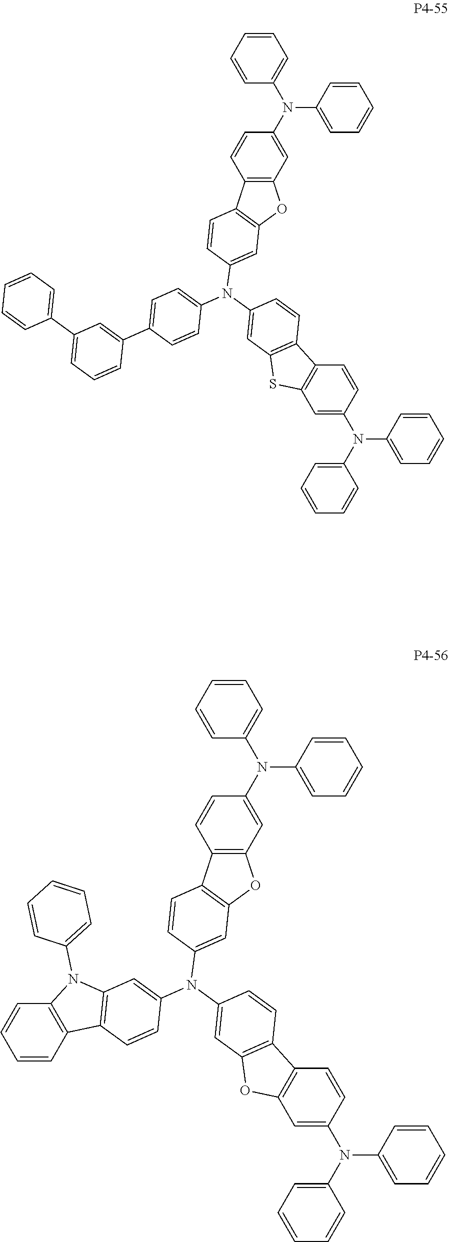 [SMILES: c1ccc(-c2cccc(-c3ccc(N(c4ccc5c(c4)oc4cc(N(c6ccccc6)c6ccccc6)ccc45)c4ccc5c(c4)sc4cc(N(c6ccccc6)c6ccccc6)ccc45)cc3)c2)cc1 ; c1ccc(N(c2ccccc2)c2ccc3c(c2)oc2cc(N(c4ccc5c(c4)oc4cc(N(c6ccccc6)c6ccccc6)ccc45)c4ccc5c6ccccc6n(-c6ccccc6)c5c4)ccc23)cc1]

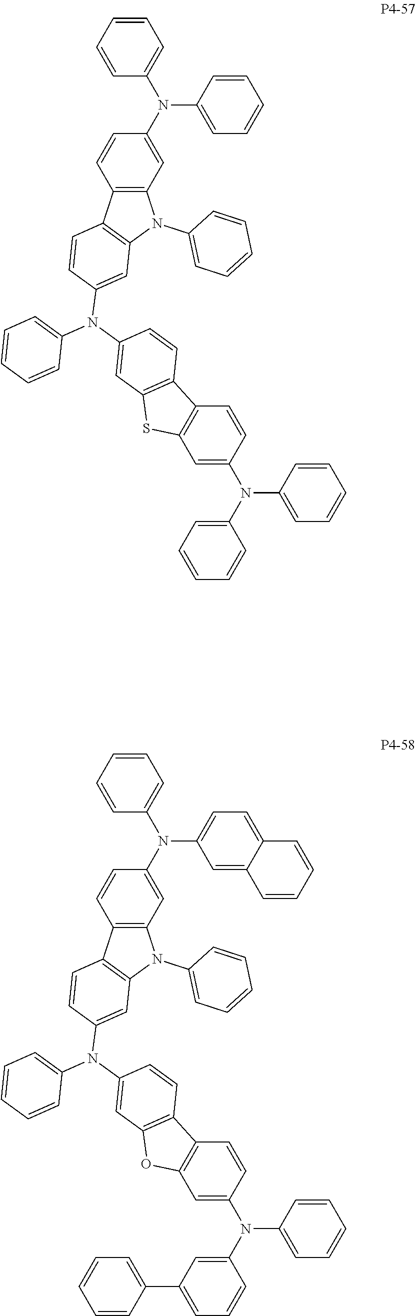 [SMILES: c1ccc(N(c2ccccc2)c2ccc3c(c2)sc2cc(N(c4ccccc4)c4ccc5c6ccc(N(c7ccccc7)c7ccccc7)cc6n(-c6ccccc6)c5c4)ccc23)cc1 ; c1ccc(-c2cccc(N(c3ccccc3)c3ccc4c(c3)oc3cc(N(c5ccccc5)c5ccc6c7ccc(N(c8ccccc8)c8ccc9ccccc9c8)cc7n(-c7ccccc7)c6c5)ccc34)c2)cc1]

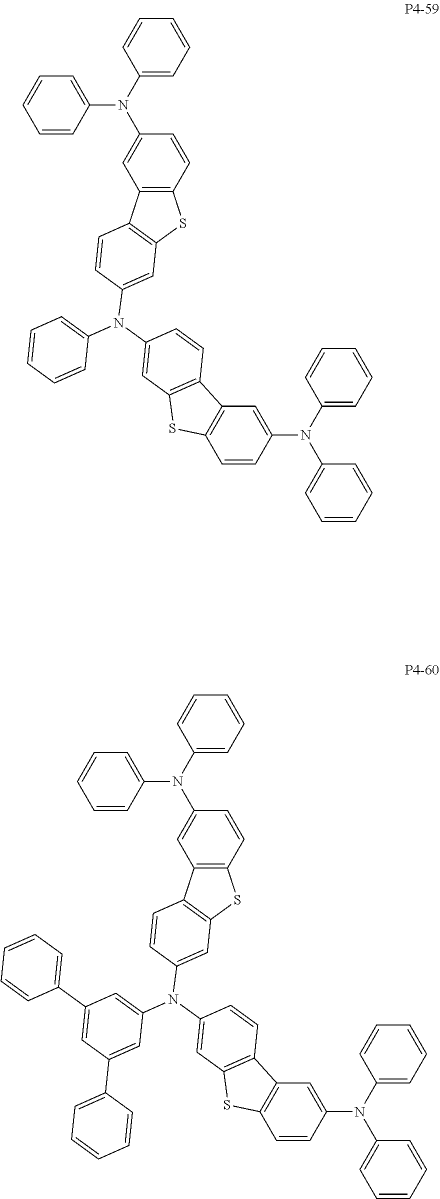 [SMILES: c1ccc(N(c2ccc3c(c2)sc2ccc(N(c4ccccc4)c4ccccc4)cc23)c2ccc3c(c2)sc2ccc(N(c4ccccc4)c4ccccc4)cc23)cc1 ; c1ccc(-c2cc(-c3ccccc3)cc(N(c3ccc4c(c3)sc3ccc(N(c5ccccc5)c5ccccc5)cc34)c3ccc4c(c3)sc3ccc(N(c5ccccc5)c5ccccc5)cc34)c2)cc1]

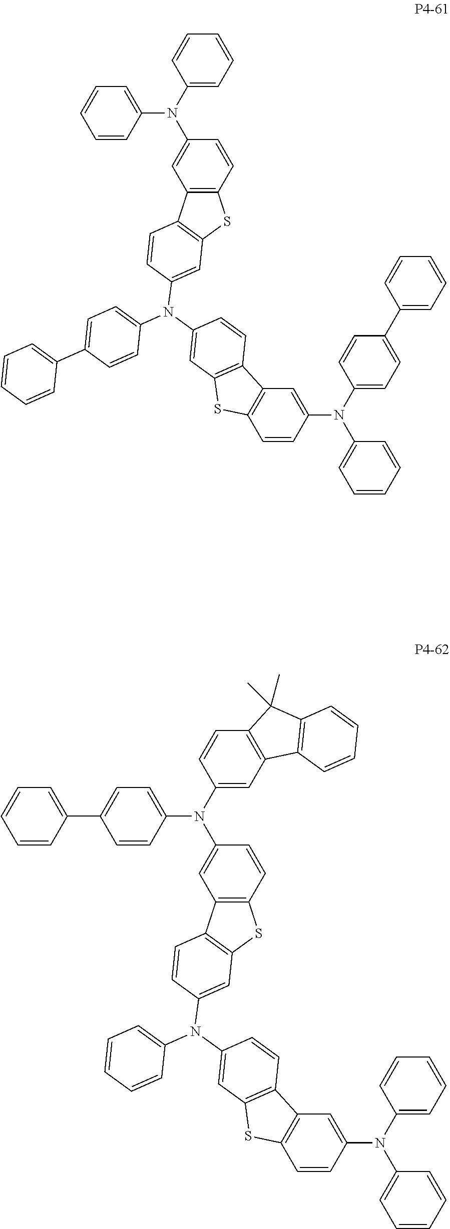 [SMILES: c1ccc(-c2ccc(N(c3ccc4c(c3)sc3ccc(N(c5ccccc5)c5ccccc5)cc34)c3ccc4c(c3)sc3ccc(N(c5ccccc5)c5ccc(-c6ccccc6)cc5)cc34)cc2)cc1 ; CC1(C)c2ccccc2-c2cc(N(c3ccc(-c4ccccc4)cc3)c3ccc4sc5cc(N(c6ccccc6)c6ccc7c(c6)sc6ccc(N(c8ccccc8)c8ccccc8)cc67)ccc5c4c3)ccc21]

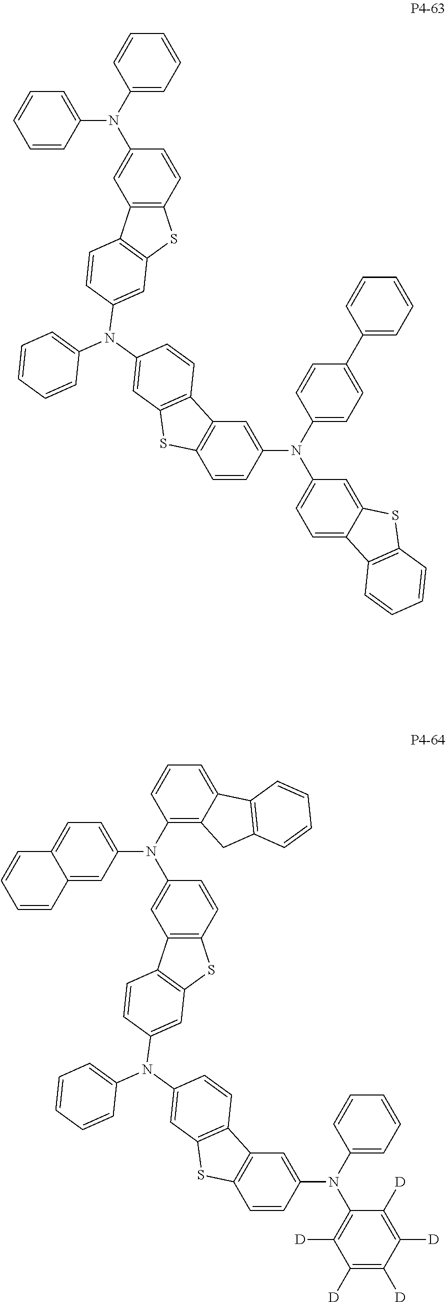 [SMILES: c1ccc(-c2ccc(N(c3ccc4c(c3)sc3ccccc34)c3ccc4sc5cc(N(c6ccccc6)c6ccc7c(c6)sc6ccc(N(c8ccccc8)c8ccccc8)cc67)ccc5c4c3)cc2)cc1 ; [2H]c1c([2H])c([2H])c(N(c2ccccc2)c2ccc3sc4cc(N(c5ccccc5)c5ccc6c(c5)sc5ccc(N(c7ccc8ccccc8c7)c7cccc8c7Cc7ccccc7-8)cc56)ccc4c3c2)c([2H])c1[2H]]

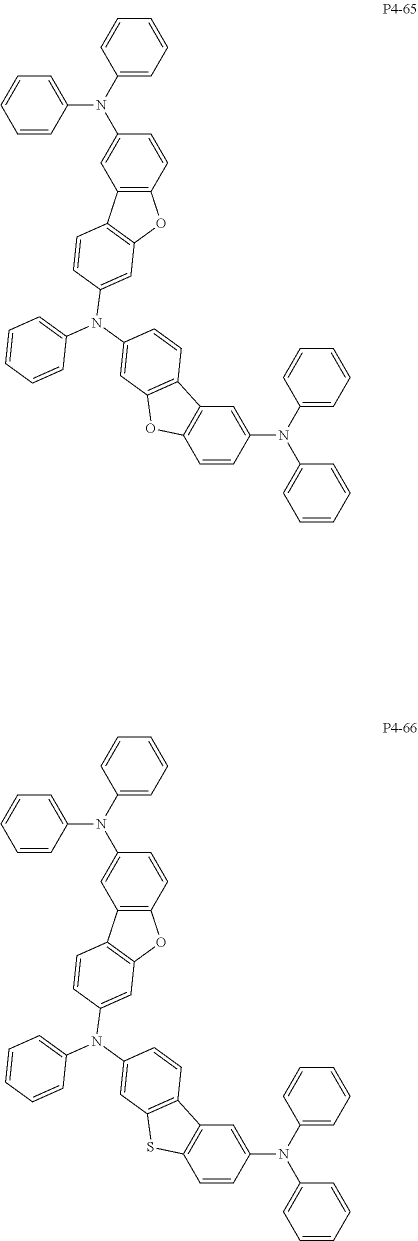 [SMILES: c1ccc(N(c2ccc3c(c2)oc2ccc(N(c4ccccc4)c4ccccc4)cc23)c2ccc3c(c2)oc2ccc(N(c4ccccc4)c4ccccc4)cc23)cc1 ; c1ccc(N(c2ccc3c(c2)oc2ccc(N(c4ccccc4)c4ccccc4)cc23)c2ccc3c(c2)sc2ccc(N(c4ccccc4)c4ccccc4)cc23)cc1]

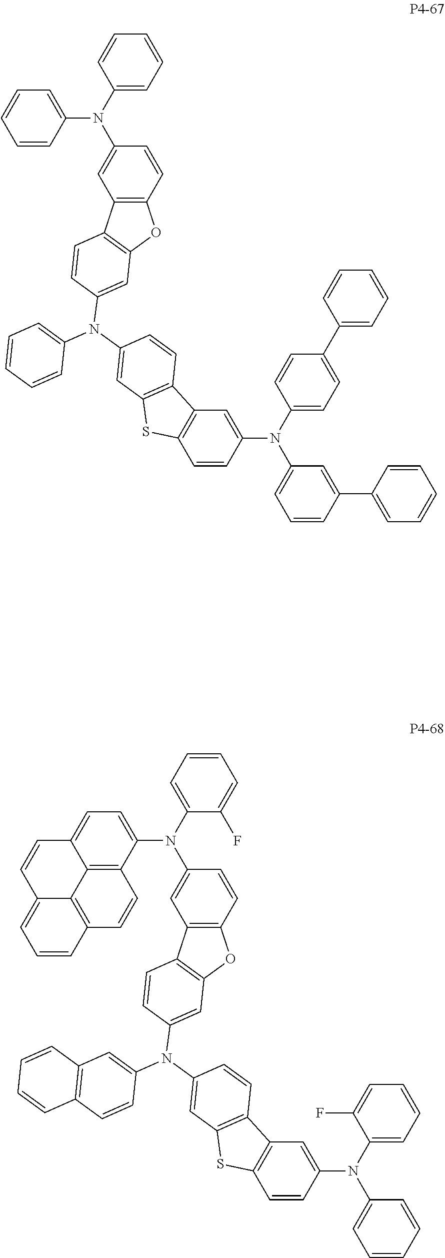 [SMILES: c1ccc(-c2ccc(N(c3cccc(-c4ccccc4)c3)c3ccc4sc5cc(N(c6ccccc6)c6ccc7c(c6)oc6ccc(N(c8ccccc8)c8ccccc8)cc67)ccc5c4c3)cc2)cc1 ; Fc1ccccc1N(c1ccccc1)c1ccc2sc3cc(N(c4ccc5ccccc5c4)c4ccc5c(c4)oc4ccc(N(c6ccccc6F)c6ccc7ccc8cccc9ccc6c7c89)cc45)ccc3c2c1]

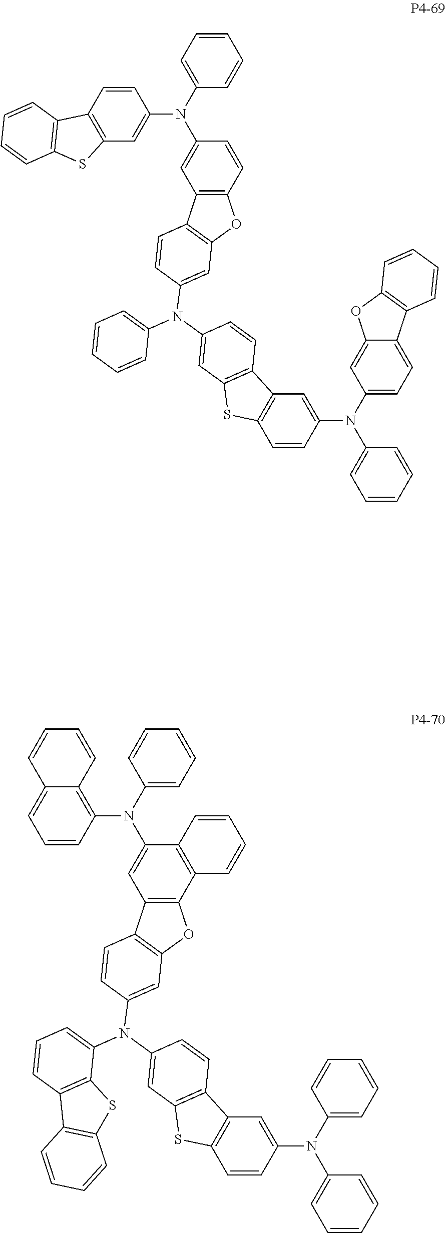 [SMILES: c1ccc(N(c2ccc3c(c2)oc2ccc(N(c4ccccc4)c4ccc5c(c4)sc4ccccc45)cc23)c2ccc3c(c2)sc2ccc(N(c4ccccc4)c4ccc5c(c4)oc4ccccc45)cc23)cc1 ; c1ccc(N(c2ccccc2)c2ccc3sc4cc(N(c5ccc6c(c5)oc5c7ccccc7c(N(c7ccccc7)c7cccc8ccccc78)cc65)c5cccc6c5sc5ccccc56)ccc4c3c2)cc1]

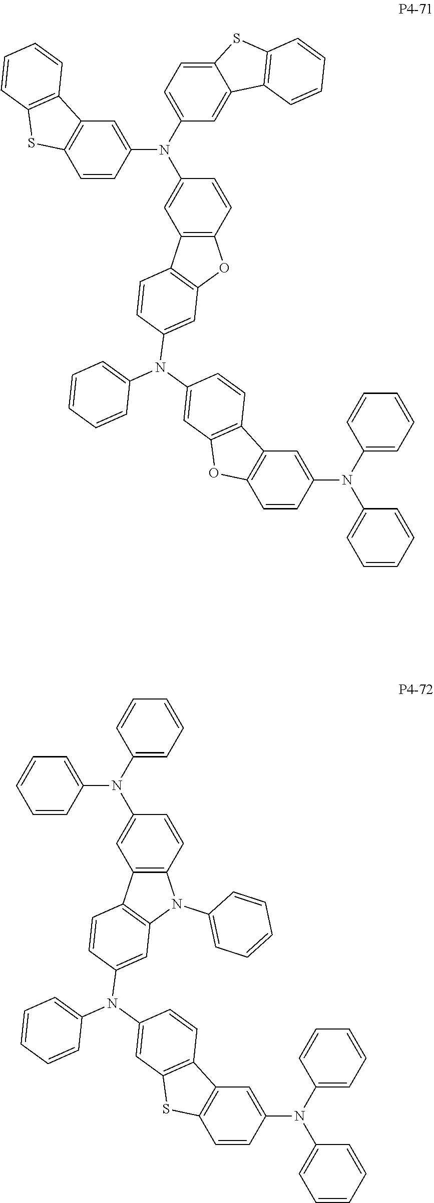 [SMILES: c1ccc(N(c2ccc3c(c2)oc2ccc(N(c4ccccc4)c4ccccc4)cc23)c2ccc3c(c2)oc2ccc(N(c4ccc5sc6ccccc6c5c4)c4ccc5sc6ccccc6c5c4)cc23)cc1 ; c1ccc(N(c2ccccc2)c2ccc3sc4cc(N(c5ccccc5)c5ccc6c7cc(N(c8ccccc8)c8ccccc8)ccc7n(-c7ccccc7)c6c5)ccc4c3c2)cc1]

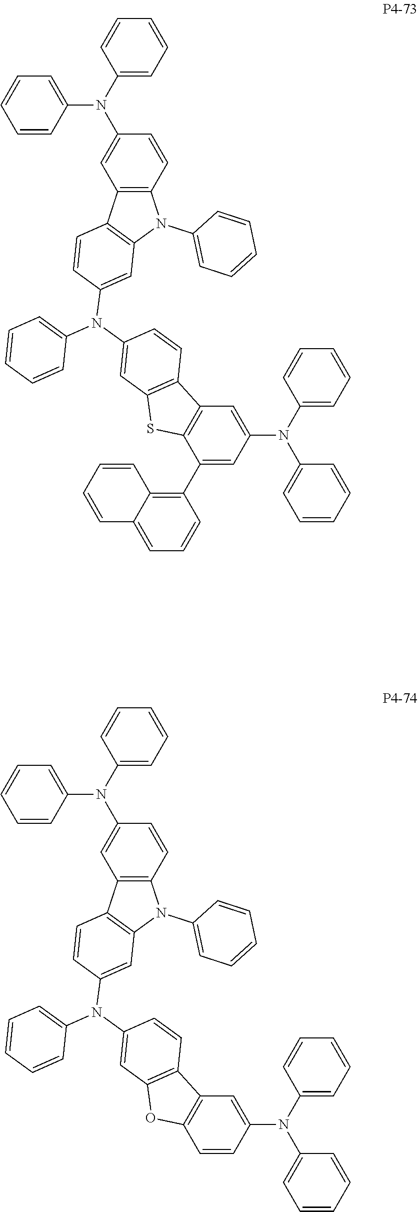 [SMILES: c1ccc(N(c2ccccc2)c2cc(-c3cccc4ccccc34)c3sc4cc(N(c5ccccc5)c5ccc6c7cc(N(c8ccccc8)c8ccccc8)ccc7n(-c7ccccc7)c6c5)ccc4c3c2)cc1 ; c1ccc(N(c2ccccc2)c2ccc3oc4cc(N(c5ccccc5)c5ccc6c7cc(N(c8ccccc8)c8ccccc8)ccc7n(-c7ccccc7)c6c5)ccc4c3c2)cc1]

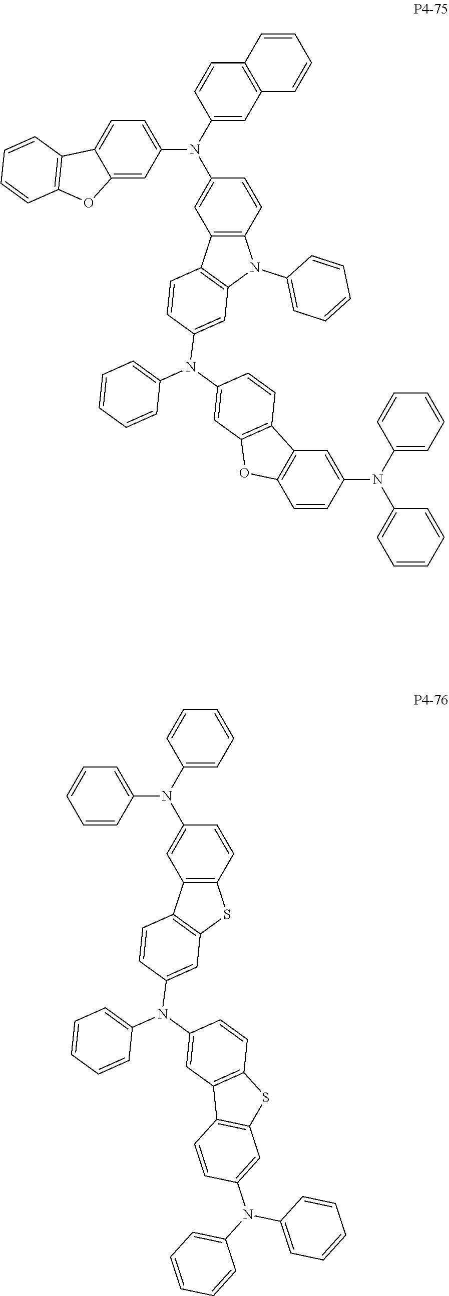 [SMILES: c1ccc(N(c2ccccc2)c2ccc3oc4cc(N(c5ccccc5)c5ccc6c7cc(N(c8ccc9ccccc9c8)c8ccc9c(c8)oc8ccccc89)ccc7n(-c7ccccc7)c6c5)ccc4c3c2)cc1 ; c1ccc(N(c2ccccc2)c2ccc3c(c2)sc2ccc(N(c4ccccc4)c4ccc5c(c4)sc4ccc(N(c6ccccc6)c6ccccc6)cc45)cc23)cc1]

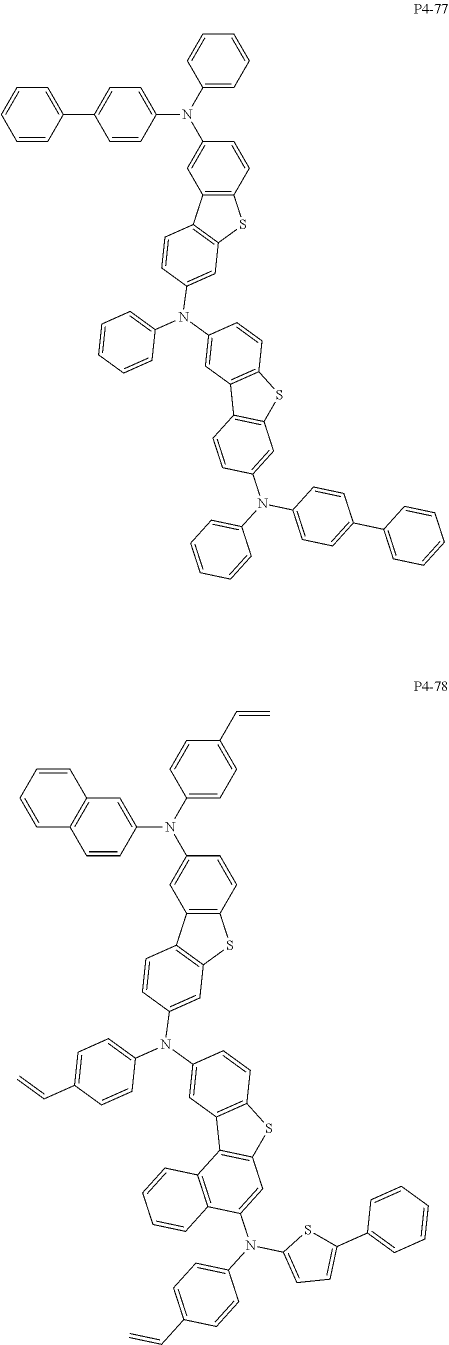 [SMILES: c1ccc(-c2ccc(N(c3ccccc3)c3ccc4c(c3)sc3ccc(N(c5ccccc5)c5ccc6c(c5)sc5ccc(N(c7ccccc7)c7ccc(-c8ccccc8)cc7)cc56)cc34)cc2)cc1 ; C=Cc1ccc(N(c2ccc3ccccc3c2)c2ccc3sc4cc(N(c5ccc(C=C)cc5)c5ccc6sc7cc(N(c8ccc(C=C)cc8)c8ccc(-c9ccccc9)s8)c8ccccc8c7c6c5)ccc4c3c2)cc1]

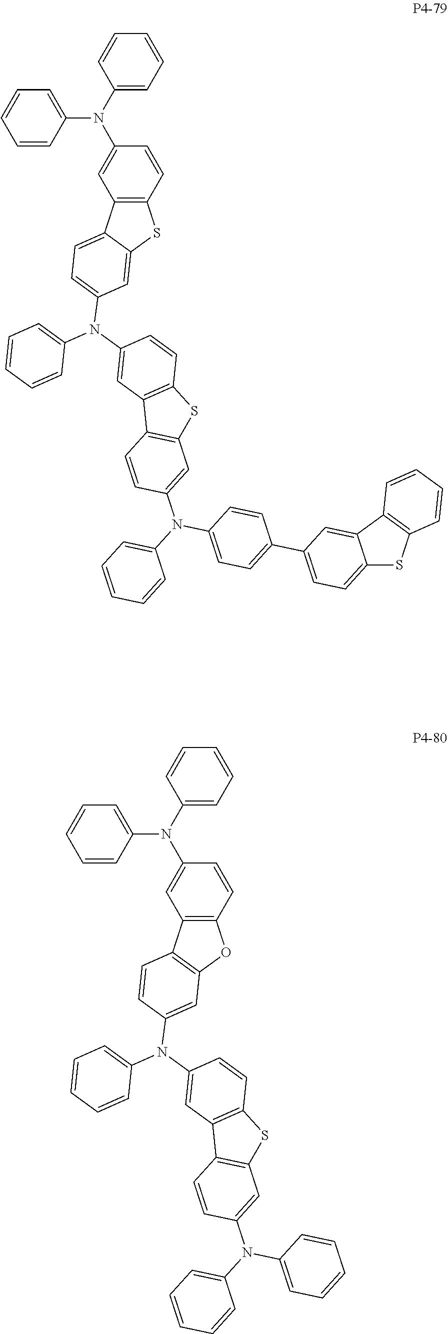 [SMILES: c1ccc(N(c2ccc(-c3ccc4sc5ccccc5c4c3)cc2)c2ccc3c(c2)sc2ccc(N(c4ccccc4)c4ccc5c(c4)sc4ccc(N(c6ccccc6)c6ccccc6)cc45)cc23)cc1 ; c1ccc(N(c2ccccc2)c2ccc3c(c2)sc2ccc(N(c4ccccc4)c4ccc5c(c4)oc4ccc(N(c6ccccc6)c6ccccc6)cc45)cc23)cc1]

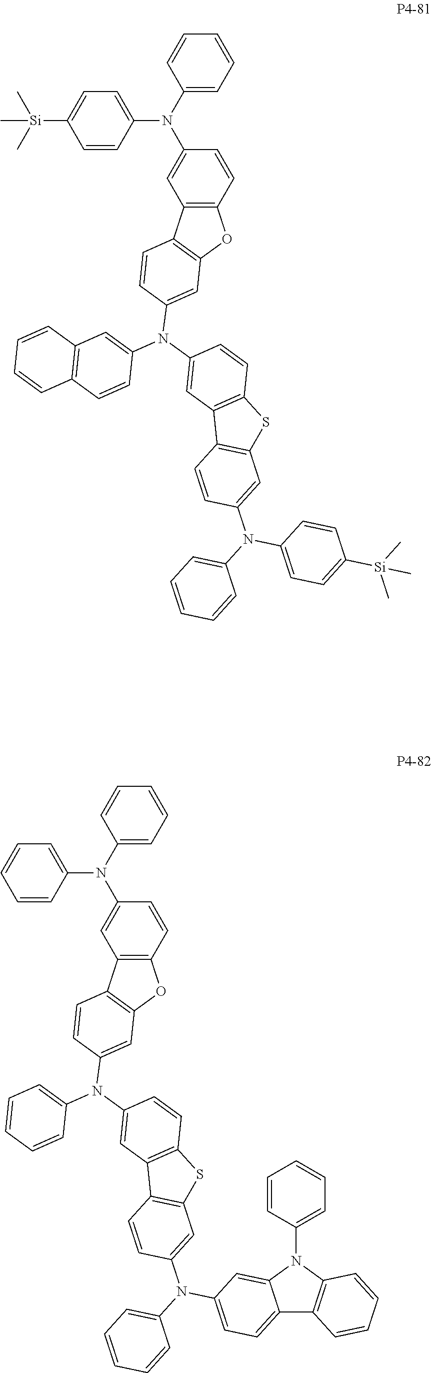

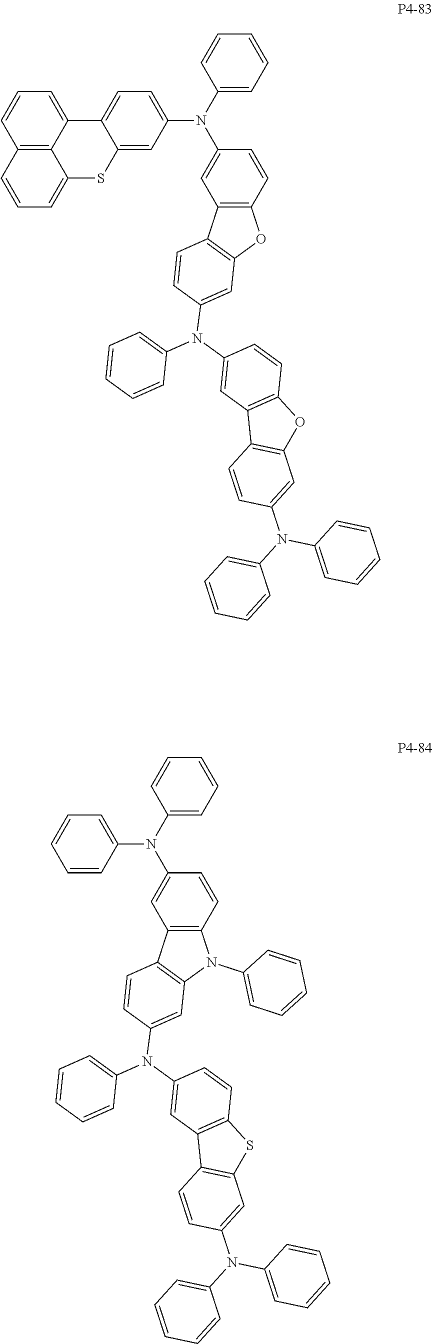 [SMILES: c1ccc(N(c2ccccc2)c2ccc3c(c2)oc2ccc(N(c4ccccc4)c4ccc5c(c4)oc4ccc(N(c6ccccc6)c6ccc7c(c6)Sc6cccc8cccc-7c68)cc45)cc23)cc1 ; c1ccc(N(c2ccccc2)c2ccc3c(c2)sc2ccc(N(c4ccccc4)c4ccc5c6cc(N(c7ccccc7)c7ccccc7)ccc6n(-c6ccccc6)c5c4)cc23)cc1]

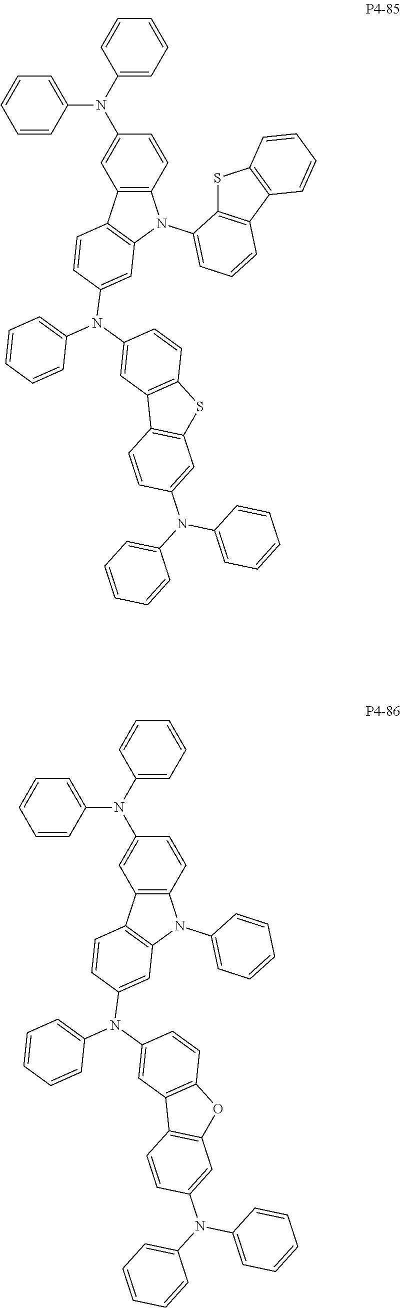 [SMILES: c1ccc(N(c2ccccc2)c2ccc3c(c2)sc2ccc(N(c4ccccc4)c4ccc5c6cc(N(c7ccccc7)c7ccccc7)ccc6n(-c6cccc7c6sc6ccccc67)c5c4)cc23)cc1 ; c1ccc(N(c2ccccc2)c2ccc3c(c2)oc2ccc(N(c4ccccc4)c4ccc5c6cc(N(c7ccccc7)c7ccccc7)ccc6n(-c6ccccc6)c5c4)cc23)cc1]

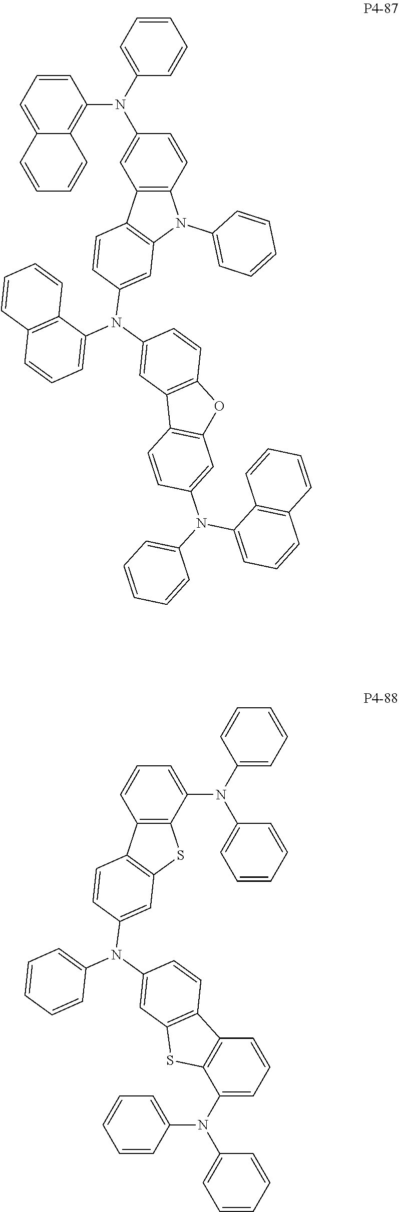 [SMILES: c1ccc(N(c2ccc3c(c2)oc2ccc(N(c4ccc5c6cc(N(c7ccccc7)c7cccc8ccccc78)ccc6n(-c6ccccc6)c5c4)c4cccc5ccccc45)cc23)c2cccc3ccccc23)cc1 ; c1ccc(N(c2ccc3c(c2)sc2c(N(c4ccccc4)c4ccccc4)cccc23)c2ccc3c(c2)sc2c(N(c4ccccc4)c4ccccc4)cccc23)cc1]

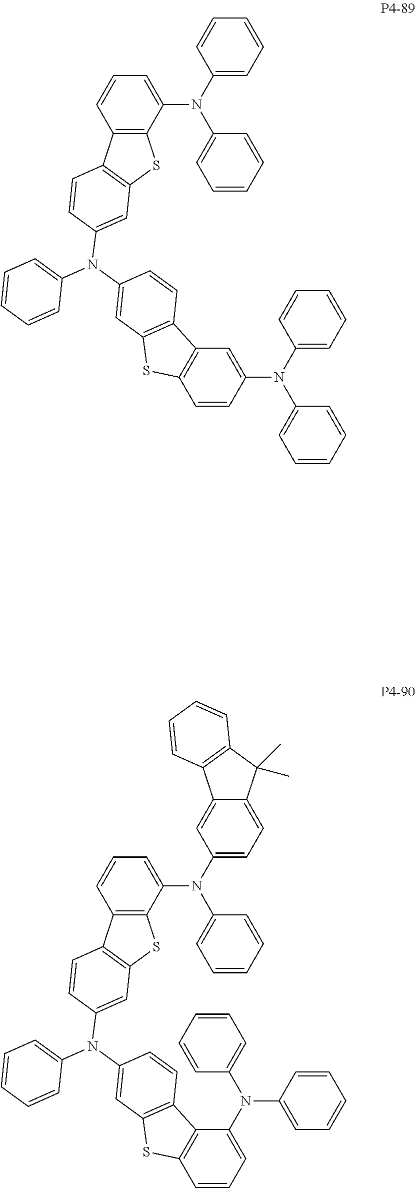 [SMILES: c1ccc(N(c2ccc3c(c2)sc2ccc(N(c4ccccc4)c4ccccc4)cc23)c2ccc3c(c2)sc2c(N(c4ccccc4)c4ccccc4)cccc23)cc1 ; CC1(C)c2ccccc2-c2cc(N(c3ccccc3)c3cccc4c3sc3cc(N(c5ccccc5)c5ccc6c(c5)sc5cccc(N(c7ccccc7)c7ccccc7)c56)ccc34)ccc21]

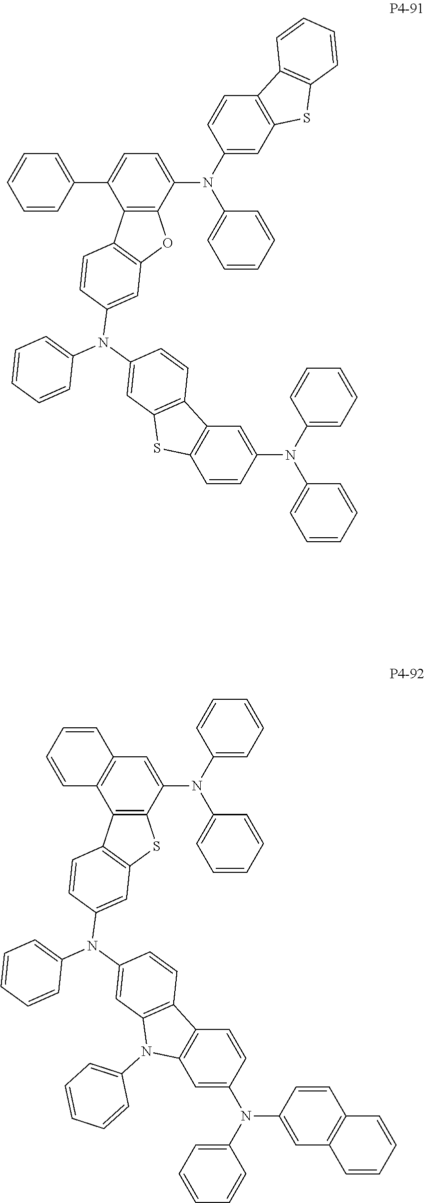 [SMILES: c1ccc(-c2ccc(N(c3ccccc3)c3ccc4c(c3)sc3ccccc34)c3oc4cc(N(c5ccccc5)c5ccc6c(c5)sc5ccc(N(c7ccccc7)c7ccccc7)cc56)ccc4c23)cc1 ; c1ccc(N(c2ccc3ccccc3c2)c2ccc3c4ccc(N(c5ccccc5)c5ccc6c(c5)sc5c(N(c7ccccc7)c7ccccc7)cc7ccccc7c56)cc4n(-c4ccccc4)c3c2)cc1]

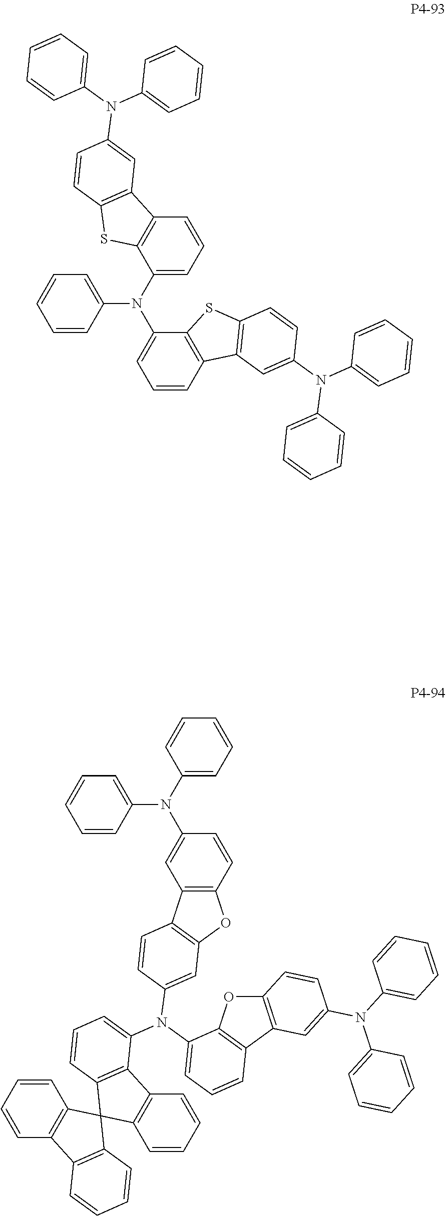 [SMILES: c1ccc(N(c2ccccc2)c2ccc3sc4c(N(c5ccccc5)c5cccc6c5sc5ccc(N(c7ccccc7)c7ccccc7)cc56)cccc4c3c2)cc1 ; c1ccc(N(c2ccccc2)c2ccc3oc4cc(N(c5cccc6c5-c5ccccc5C65c6ccccc6-c6ccccc65)c5cccc6c5oc5ccc(N(c7ccccc7)c7ccccc7)cc56)ccc4c3c2)cc1]

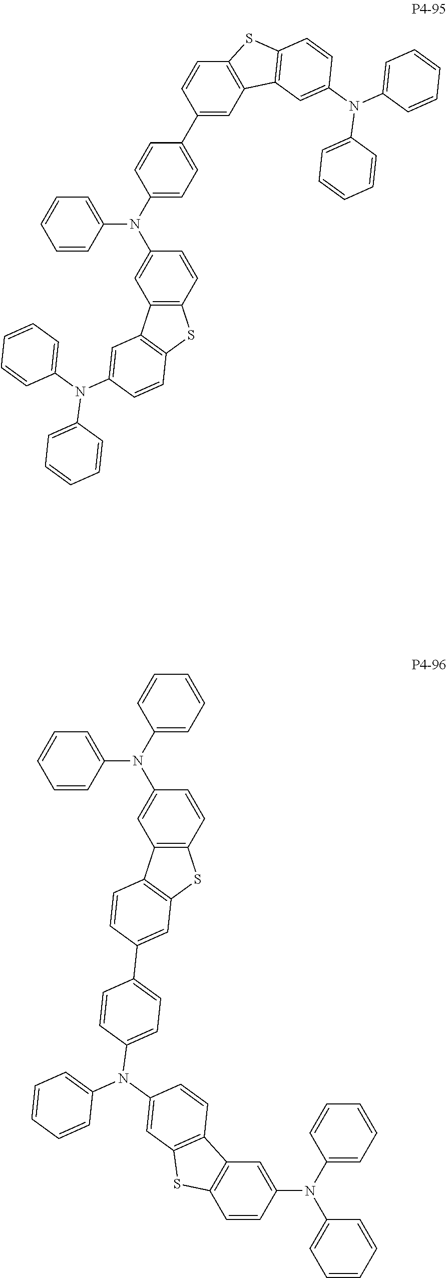 [SMILES: c1ccc(N(c2ccccc2)c2ccc3sc4ccc(-c5ccc(N(c6ccccc6)c6ccc7sc8ccc(N(c9ccccc9)c9ccccc9)cc8c7c6)cc5)cc4c3c2)cc1 ; c1ccc(N(c2ccc(-c3ccc4c(c3)sc3ccc(N(c5ccccc5)c5ccccc5)cc34)cc2)c2ccc3c(c2)sc2ccc(N(c4ccccc4)c4ccccc4)cc23)cc1]

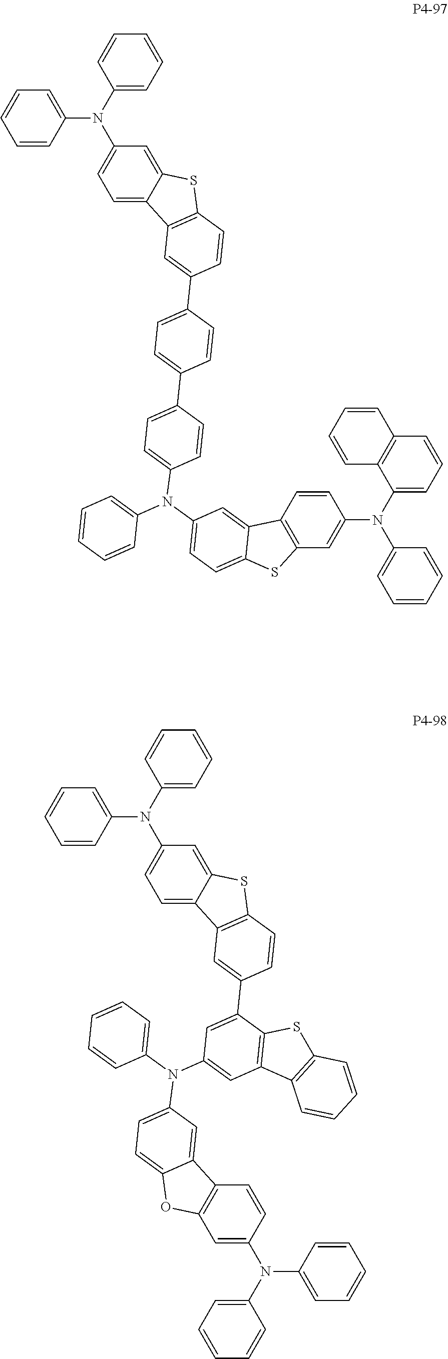 [SMILES: c1ccc(N(c2ccccc2)c2ccc3c(c2)sc2ccc(-c4ccc(-c5ccc(N(c6ccccc6)c6ccc7sc8cc(N(c9ccccc9)c9cccc%10ccccc9%10)ccc8c7c6)cc5)cc4)cc23)cc1 ; c1ccc(N(c2ccccc2)c2ccc3c(c2)oc2ccc(N(c4ccccc4)c4cc(-c5ccc6sc7cc(N(c8ccccc8)c8ccccc8)ccc7c6c5)c5sc6ccccc6c5c4)cc23)cc1]

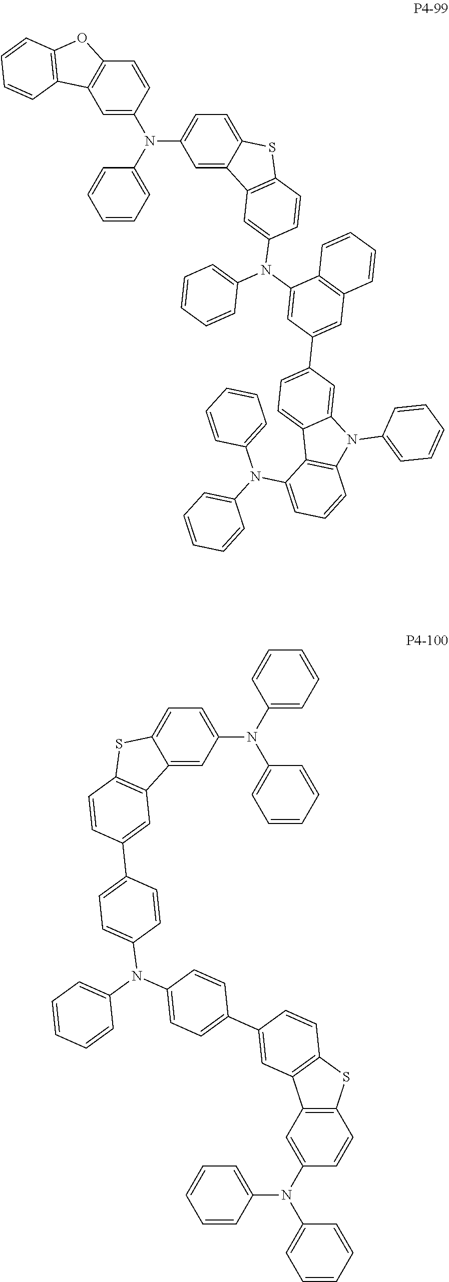 [SMILES: c1ccc(N(c2ccc3oc4ccccc4c3c2)c2ccc3sc4ccc(N(c5ccccc5)c5cc(-c6ccc7c8c(N(c9ccccc9)c9ccccc9)cccc8n(-c8ccccc8)c7c6)cc6ccccc56)cc4c3c2)cc1 ; c1ccc(N(c2ccc(-c3ccc4sc5ccc(N(c6ccccc6)c6ccccc6)cc5c4c3)cc2)c2ccc(-c3ccc4sc5ccc(N(c6ccccc6)c6ccccc6)cc5c4c3)cc2)cc1]

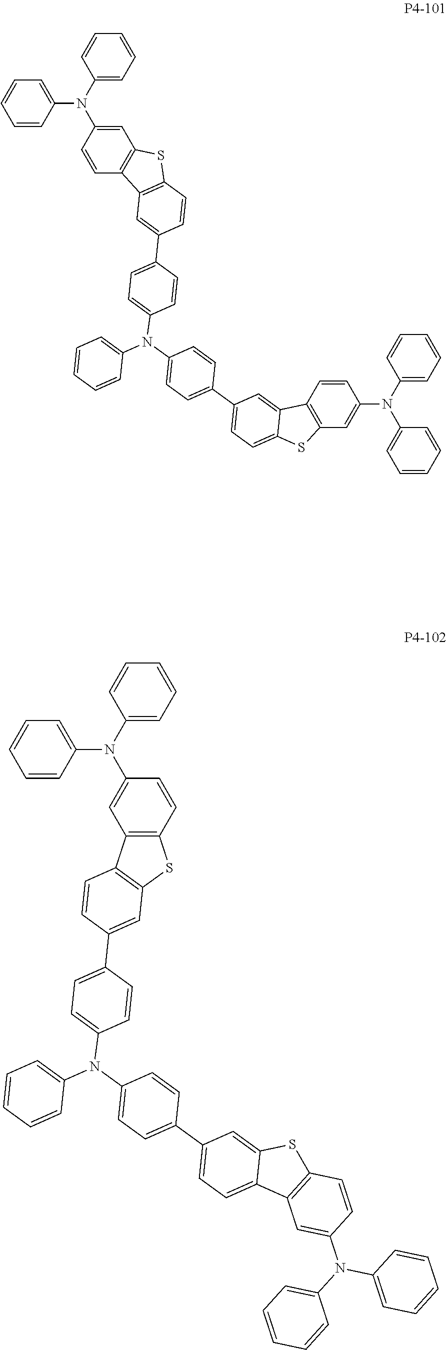 [SMILES: c1ccc(N(c2ccc(-c3ccc4sc5cc(N(c6ccccc6)c6ccccc6)ccc5c4c3)cc2)c2ccc(-c3ccc4sc5cc(N(c6ccccc6)c6ccccc6)ccc5c4c3)cc2)cc1 ; c1ccc(N(c2ccc(-c3ccc4c(c3)sc3ccc(N(c5ccccc5)c5ccccc5)cc34)cc2)c2ccc(-c3ccc4c(c3)sc3ccc(N(c5ccccc5)c5ccccc5)cc34)cc2)cc1]

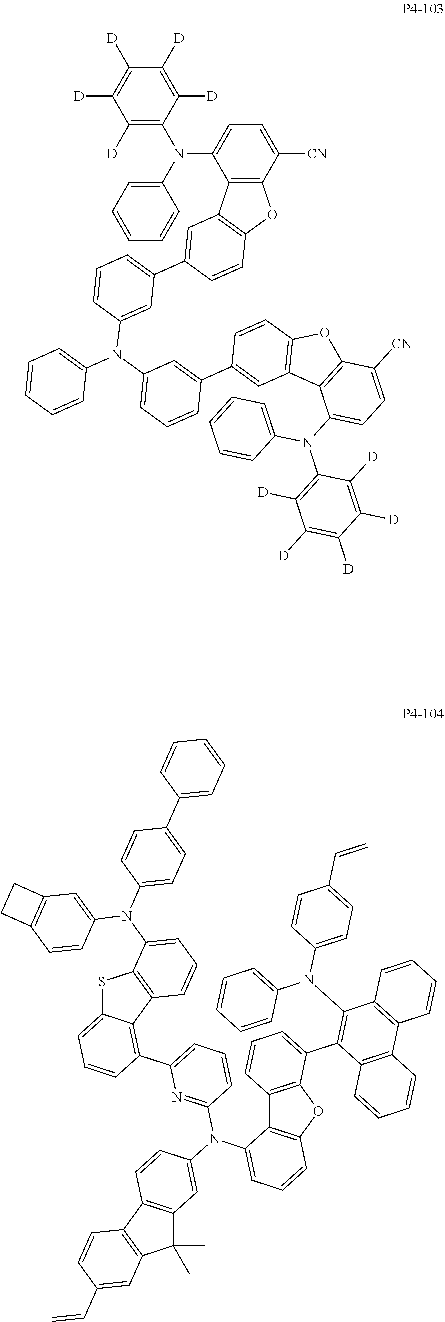 [SMILES: [2H]c1c([2H])c([2H])c(N(c2ccccc2)c2ccc(C#N)c3oc4ccc(-c5cccc(N(c6ccccc6)c6cccc(-c7ccc8oc9c(C#N)ccc(N(c%10ccccc%10)c%10c([2H])c([2H])c([2H])c([2H])c%10[2H])c9c8c7)c6)c5)cc4c23)c([2H])c1[2H] ; C=Cc1ccc(N(c2ccccc2)c2c(-c3cccc4c3oc3cccc(N(c5ccc6c(c5)C(C)(C)c5cc(C=C)ccc5-6)c5cccc(-c6cccc7sc8c(N(c9ccc(-c%10ccccc%10)cc9)c9ccc%10c(c9)CC%10)cccc8c67)n5)c34)c3ccccc3c3ccccc23)cc1]

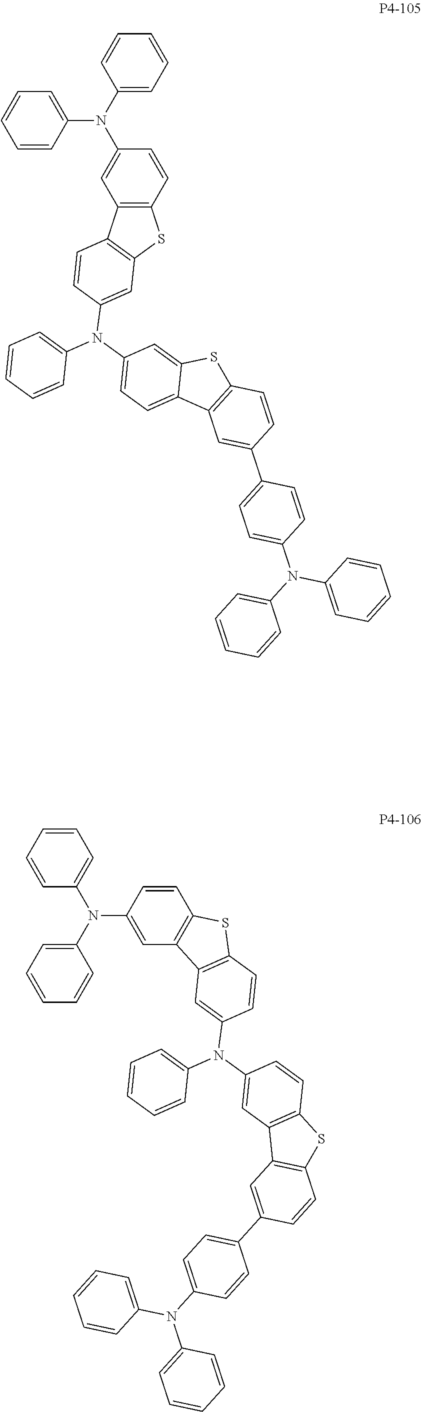 [SMILES: c1ccc(N(c2ccccc2)c2ccc(-c3ccc4sc5cc(N(c6ccccc6)c6ccc7c(c6)sc6ccc(N(c8ccccc8)c8ccccc8)cc67)ccc5c4c3)cc2)cc1 ; c1ccc(N(c2ccccc2)c2ccc(-c3ccc4sc5ccc(N(c6ccccc6)c6ccc7sc8ccc(N(c9ccccc9)c9ccccc9)cc8c7c6)cc5c4c3)cc2)cc1]

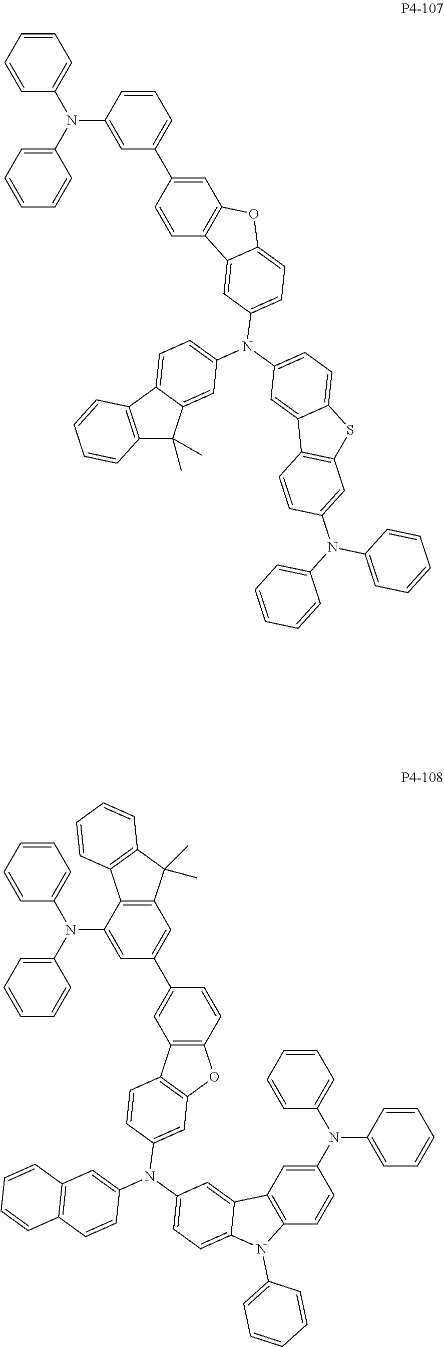 [SMILES: CC1(C)c2ccccc2-c2ccc(N(c3ccc4oc5cc(-c6cccc(N(c7ccccc7)c7ccccc7)c6)ccc5c4c3)c3ccc4sc5cc(N(c6ccccc6)c6ccccc6)ccc5c4c3)cc21 ; CC1(C)c2ccccc2-c2c(N(c3ccccc3)c3ccccc3)cc(-c3ccc4oc5cc(N(c6ccc7ccccc7c6)c6ccc7c(c6)c6cc(N(c8ccccc8)c8ccccc8)ccc6n7-c6ccccc6)ccc5c4c3)cc21]

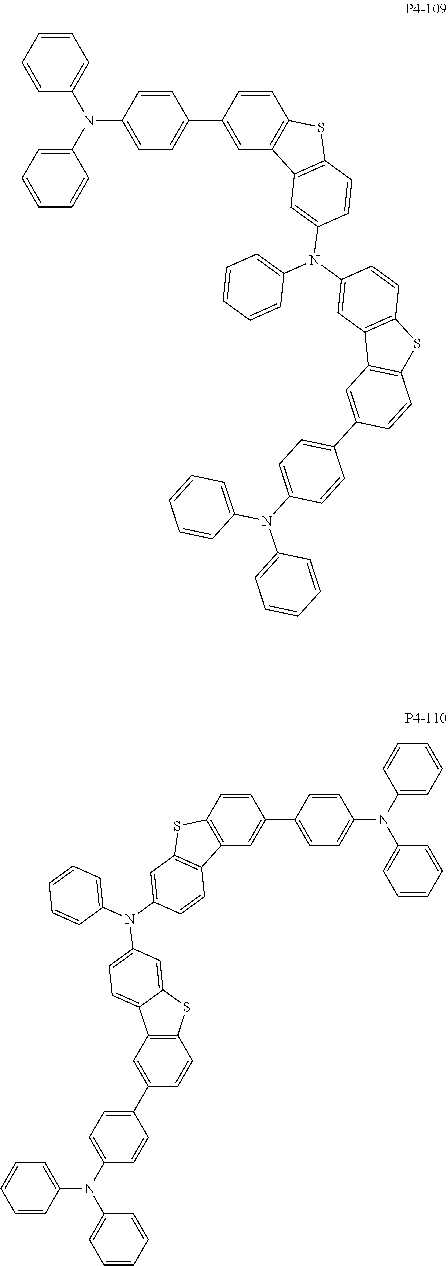 [SMILES: c1ccc(N(c2ccccc2)c2ccc(-c3ccc4sc5ccc(N(c6ccccc6)c6ccc7sc8ccc(-c9ccc(N(c%10ccccc%10)c%10ccccc%10)cc9)cc8c7c6)cc5c4c3)cc2)cc1 ; c1ccc(N(c2ccccc2)c2ccc(-c3ccc4sc5cc(N(c6ccccc6)c6ccc7c(c6)sc6ccc(-c8ccc(N(c9ccccc9)c9ccccc9)cc8)cc67)ccc5c4c3)cc2)cc1]

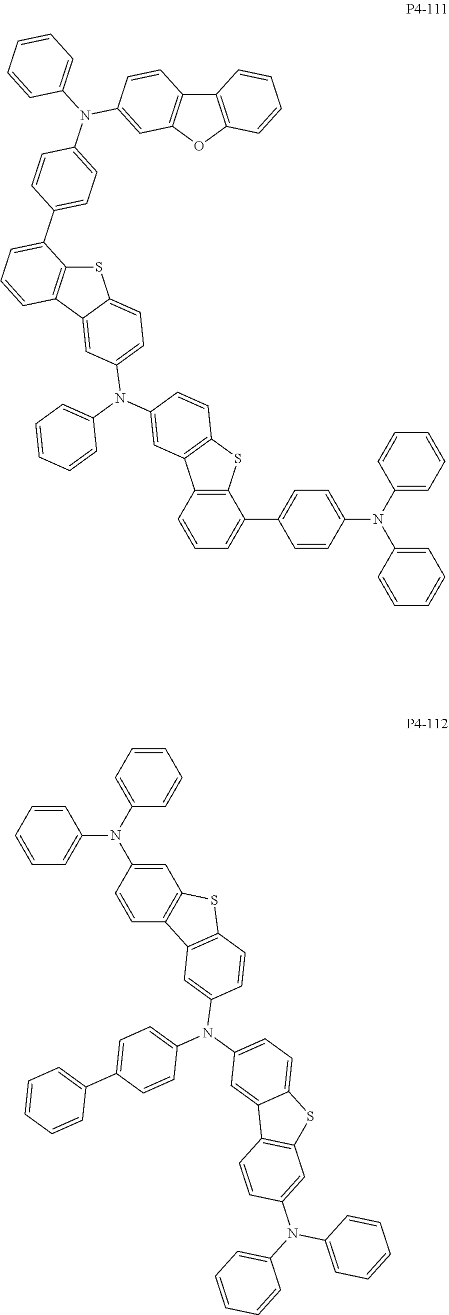 [SMILES: c1ccc(N(c2ccccc2)c2ccc(-c3cccc4c3sc3ccc(N(c5ccccc5)c5ccc6sc7c(-c8ccc(N(c9ccccc9)c9ccc%10c(c9)oc9ccccc9%10)cc8)cccc7c6c5)cc34)cc2)cc1 ; c1ccc(-c2ccc(N(c3ccc4sc5cc(N(c6ccccc6)c6ccccc6)ccc5c4c3)c3ccc4sc5cc(N(c6ccccc6)c6ccccc6)ccc5c4c3)cc2)cc1]

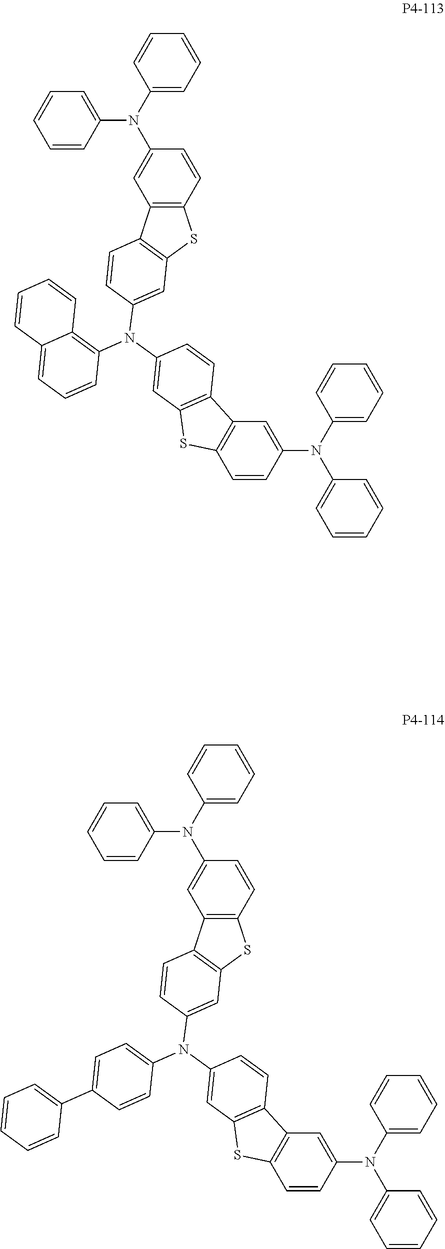 [SMILES: c1ccc(N(c2ccccc2)c2ccc3sc4cc(N(c5ccc6c(c5)sc5ccc(N(c7ccccc7)c7ccccc7)cc56)c5cccc6ccccc56)ccc4c3c2)cc1 ; c1ccc(-c2ccc(N(c3ccc4c(c3)sc3ccc(N(c5ccccc5)c5ccccc5)cc34)c3ccc4c(c3)sc3ccc(N(c5ccccc5)c5ccccc5)cc34)cc2)cc1]

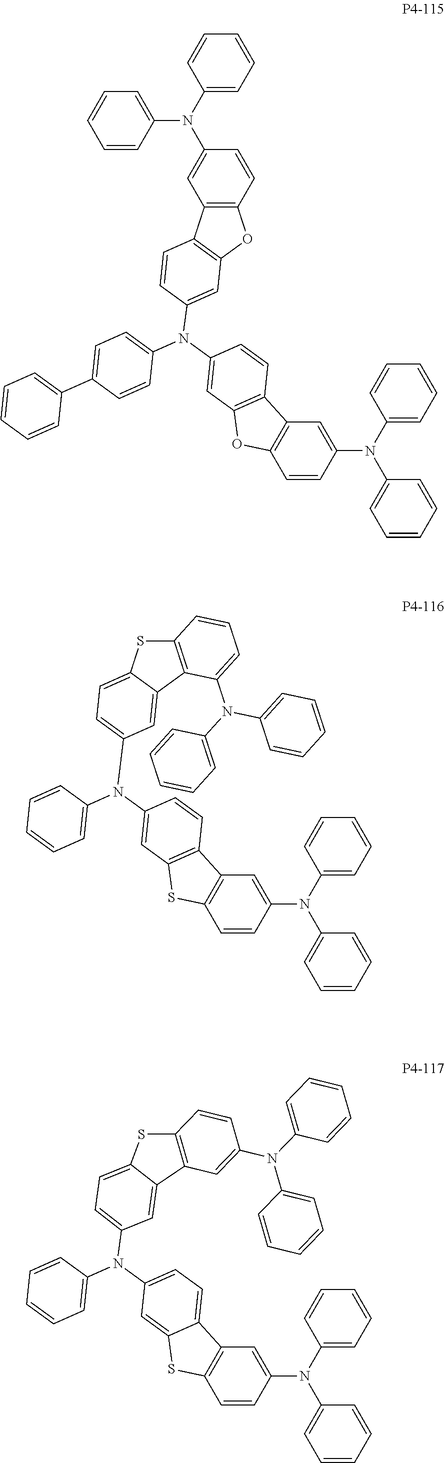 [SMILES: c1ccc(-c2ccc(N(c3ccc4c(c3)oc3ccc(N(c5ccccc5)c5ccccc5)cc34)c3ccc4c(c3)oc3ccc(N(c5ccccc5)c5ccccc5)cc34)cc2)cc1 ; c1ccc(N(c2ccccc2)c2ccc3sc4cc(N(c5ccccc5)c5ccc6sc7cccc(N(c8ccccc8)c8ccccc8)c7c6c5)ccc4c3c2)cc1 ; c1ccc(N(c2ccccc2)c2ccc3sc4cc(N(c5ccccc5)c5ccc6sc7ccc(N(c8ccccc8)c8ccccc8)cc7c6c5)ccc4c3c2)cc1]

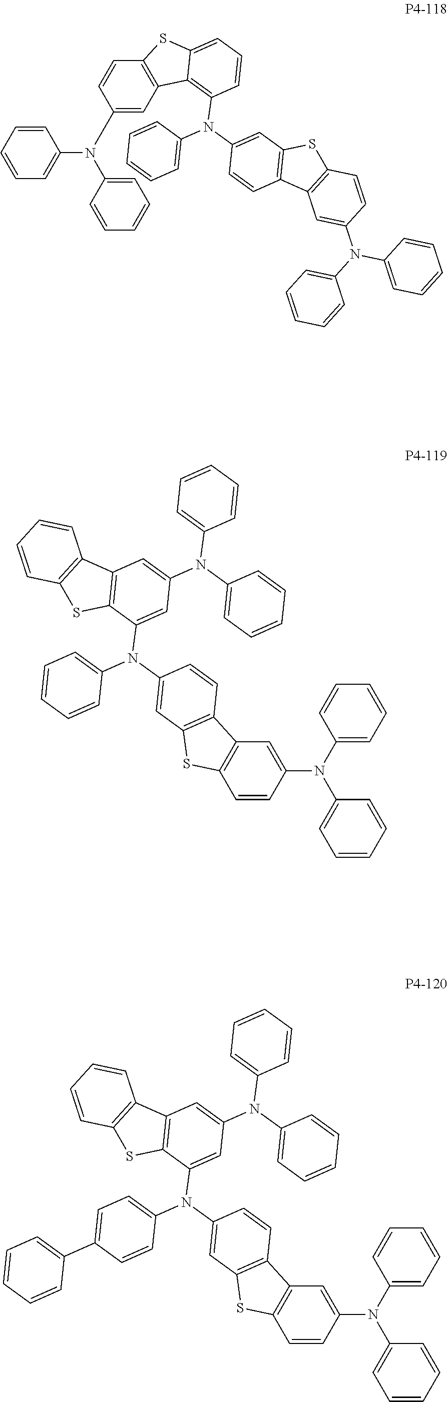 [SMILES: c1ccc(N(c2ccccc2)c2ccc3sc4cc(N(c5ccccc5)c5cccc6sc7ccc(N(c8ccccc8)c8ccccc8)cc7c56)ccc4c3c2)cc1 ; c1ccc(N(c2ccccc2)c2ccc3sc4cc(N(c5ccccc5)c5cc(N(c6ccccc6)c6ccccc6)cc6c5sc5ccccc56)ccc4c3c2)cc1 ; c1ccc(-c2ccc(N(c3ccc4c(c3)sc3ccc(N(c5ccccc5)c5ccccc5)cc34)c3cc(N(c4ccccc4)c4ccccc4)cc4c3sc3ccccc34)cc2)cc1]

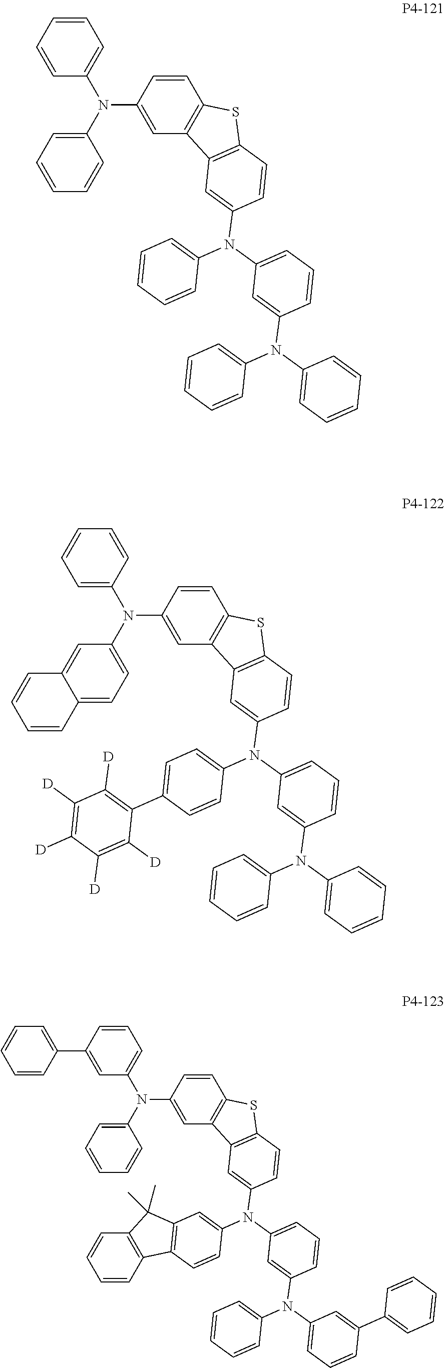 [SMILES: c1ccc(N(c2ccccc2)c2cccc(N(c3ccccc3)c3ccc4sc5ccc(N(c6ccccc6)c6ccccc6)cc5c4c3)c2)cc1 ; [2H]c1c([2H])c([2H])c(-c2ccc(N(c3cccc(N(c4ccccc4)c4ccccc4)c3)c3ccc4sc5ccc(N(c6ccccc6)c6ccc7ccccc7c6)cc5c4c3)cc2)c([2H])c1[2H] ; CC1(C)c2ccccc2-c2ccc(N(c3cccc(N(c4ccccc4)c4cccc(-c5ccccc5)c4)c3)c3ccc4sc5ccc(N(c6ccccc6)c6cccc(-c7ccccc7)c6)cc5c4c3)cc21]

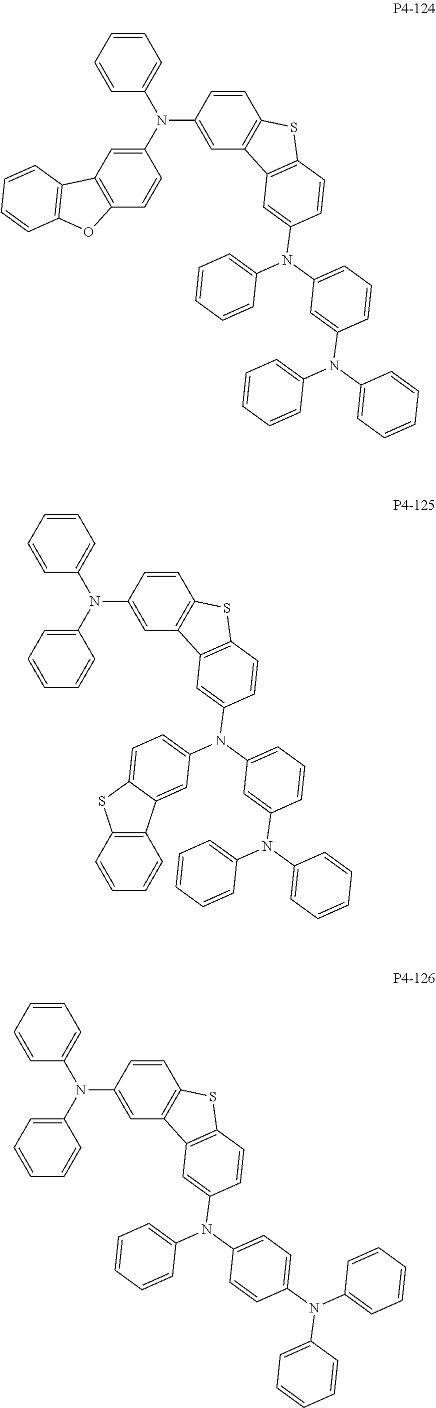 [SMILES: c1ccc(N(c2ccccc2)c2cccc(N(c3ccccc3)c3ccc4sc5ccc(N(c6ccccc6)c6ccc7oc8ccccc8c7c6)cc5c4c3)c2)cc1 ; c1ccc(N(c2ccccc2)c2cccc(N(c3ccc4sc5ccccc5c4c3)c3ccc4sc5ccc(N(c6ccccc6)c6ccccc6)cc5c4c3)c2)cc1 ; c1ccc(N(c2ccccc2)c2ccc(N(c3ccccc3)c3ccc4sc5ccc(N(c6ccccc6)c6ccccc6)cc5c4c3)cc2)cc1]

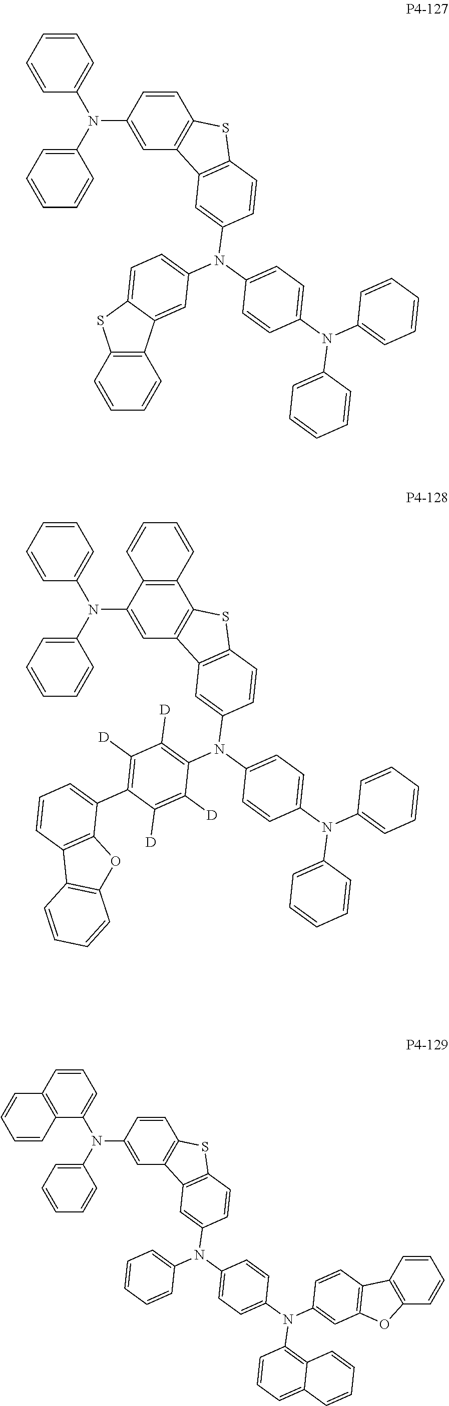 [SMILES: c1ccc(N(c2ccccc2)c2ccc(N(c3ccc4sc5ccccc5c4c3)c3ccc4sc5ccc(N(c6ccccc6)c6ccccc6)cc5c4c3)cc2)cc1 ; [2H]c1c([2H])c(N(c2ccc(N(c3ccccc3)c3ccccc3)cc2)c2ccc3sc4c5ccccc5c(N(c5ccccc5)c5ccccc5)cc4c3c2)c([2H])c([2H])c1-c1cccc2c1oc1ccccc12 ; c1ccc(N(c2ccc(N(c3ccc4c(c3)oc3ccccc34)c3cccc4ccccc34)cc2)c2ccc3sc4ccc(N(c5ccccc5)c5cccc6ccccc56)cc4c3c2)cc1]

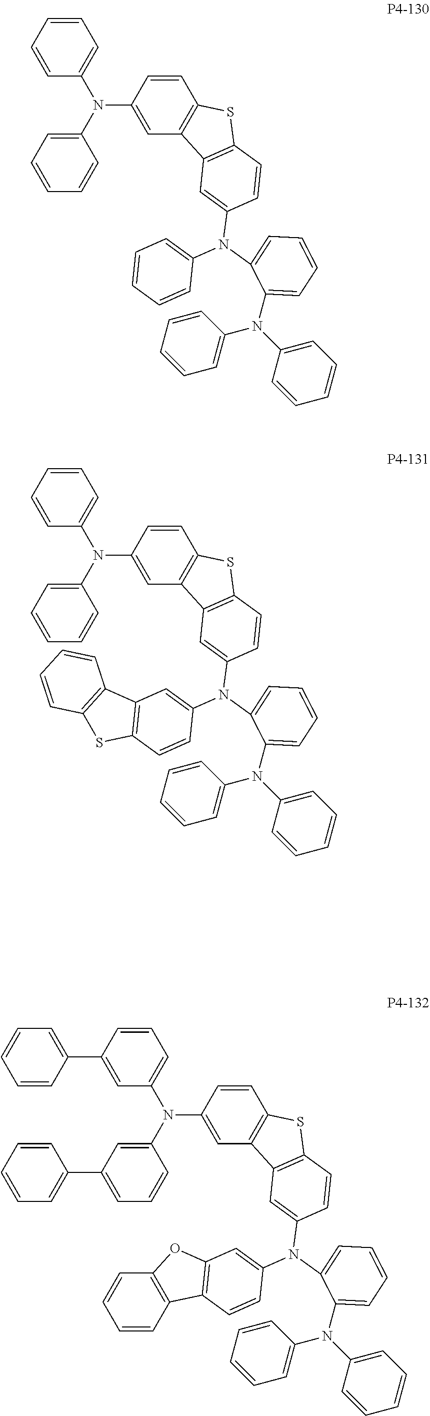 [SMILES: c1ccc(N(c2ccccc2)c2ccc3sc4ccc(N(c5ccccc5)c5ccccc5N(c5ccccc5)c5ccccc5)cc4c3c2)cc1 ; c1ccc(N(c2ccccc2)c2ccc3sc4ccc(N(c5ccc6sc7ccccc7c6c5)c5ccccc5N(c5ccccc5)c5ccccc5)cc4c3c2)cc1 ; c1ccc(-c2cccc(N(c3cccc(-c4ccccc4)c3)c3ccc4sc5ccc(N(c6ccc7c(c6)oc6ccccc67)c6ccccc6N(c6ccccc6)c6ccccc6)cc5c4c3)c2)cc1]

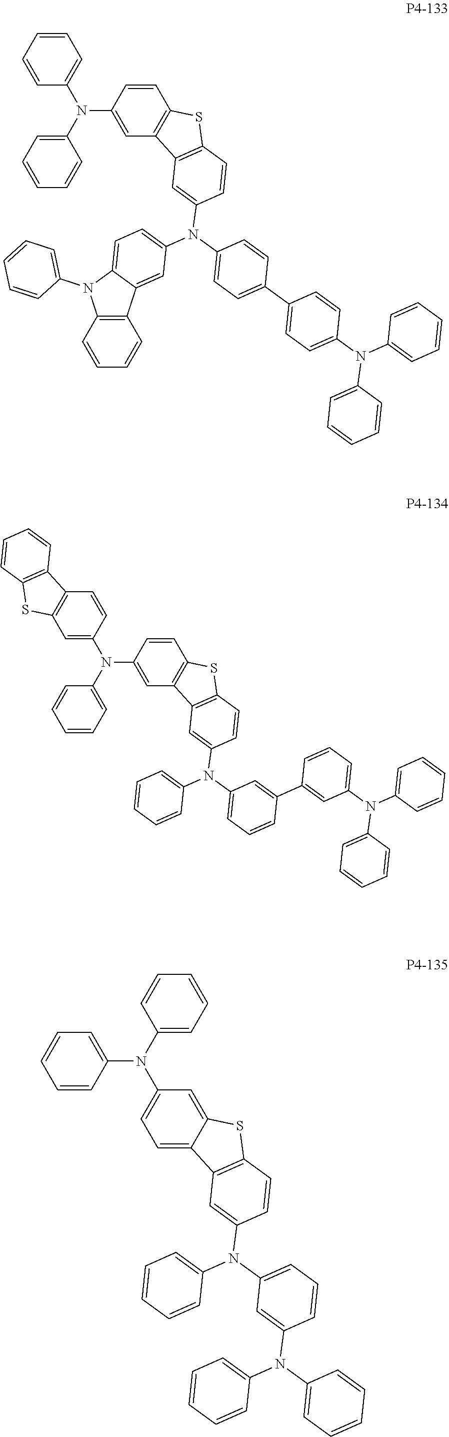 [SMILES: c1ccc(N(c2ccccc2)c2ccc(-c3ccc(N(c4ccc5sc6ccc(N(c7ccccc7)c7ccccc7)cc6c5c4)c4ccc5c(c4)c4ccccc4n5-c4ccccc4)cc3)cc2)cc1 ; c1ccc(N(c2ccccc2)c2cccc(-c3cccc(N(c4ccccc4)c4ccc5sc6ccc(N(c7ccccc7)c7ccc8c(c7)sc7ccccc78)cc6c5c4)c3)c2)cc1 ; c1ccc(N(c2ccccc2)c2cccc(N(c3ccccc3)c3ccc4sc5cc(N(c6ccccc6)c6ccccc6)ccc5c4c3)c2)cc1]

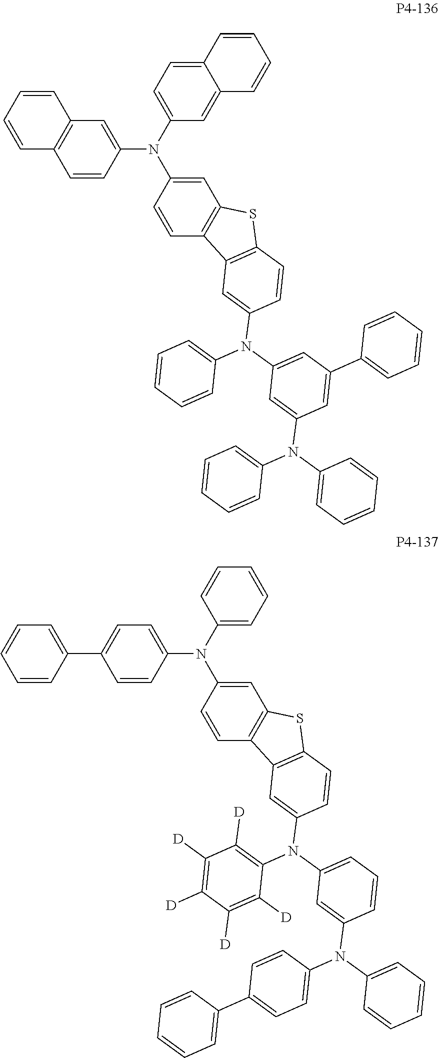 [SMILES: c1ccc(-c2cc(N(c3ccccc3)c3ccccc3)cc(N(c3ccccc3)c3ccc4sc5cc(N(c6ccc7ccccc7c6)c6ccc7ccccc7c6)ccc5c4c3)c2)cc1 ; [2H]c1c([2H])c([2H])c(N(c2cccc(N(c3ccccc3)c3ccc(-c4ccccc4)cc3)c2)c2ccc3sc4cc(N(c5ccccc5)c5ccc(-c6ccccc6)cc5)ccc4c3c2)c([2H])c1[2H]]

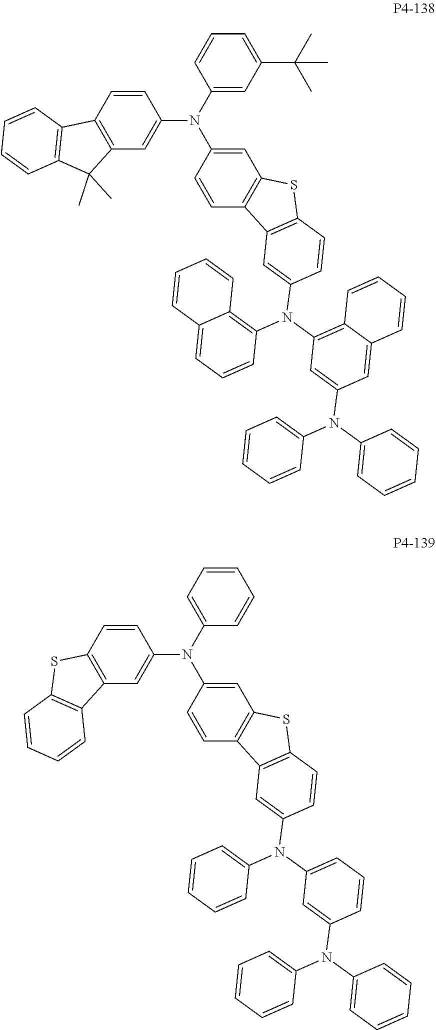 [SMILES: CC(C)(C)c1cccc(N(c2ccc3c(c2)C(C)(C)c2ccccc2-3)c2ccc3c(c2)sc2ccc(N(c4cccc5ccccc45)c4cc(N(c5ccccc5)c5ccccc5)cc5ccccc45)cc23)c1 ; c1ccc(N(c2ccccc2)c2cccc(N(c3ccccc3)c3ccc4sc5cc(N(c6ccccc6)c6ccc7sc8ccccc8c7c6)ccc5c4c3)c2)cc1]

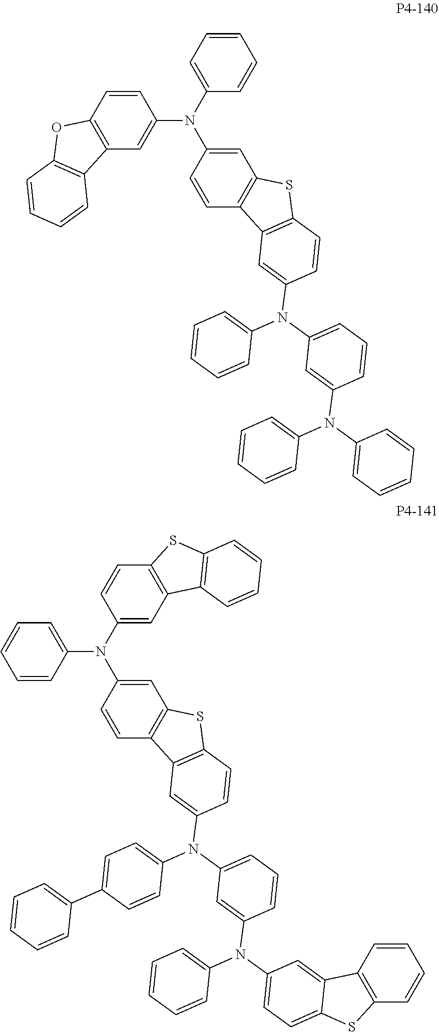 [SMILES: c1ccc(N(c2ccccc2)c2cccc(N(c3ccccc3)c3ccc4sc5cc(N(c6ccccc6)c6ccc7oc8ccccc8c7c6)ccc5c4c3)c2)cc1 ; c1ccc(-c2ccc(N(c3cccc(N(c4ccccc4)c4ccc5sc6ccccc6c5c4)c3)c3ccc4sc5cc(N(c6ccccc6)c6ccc7sc8ccccc8c7c6)ccc5c4c3)cc2)cc1]

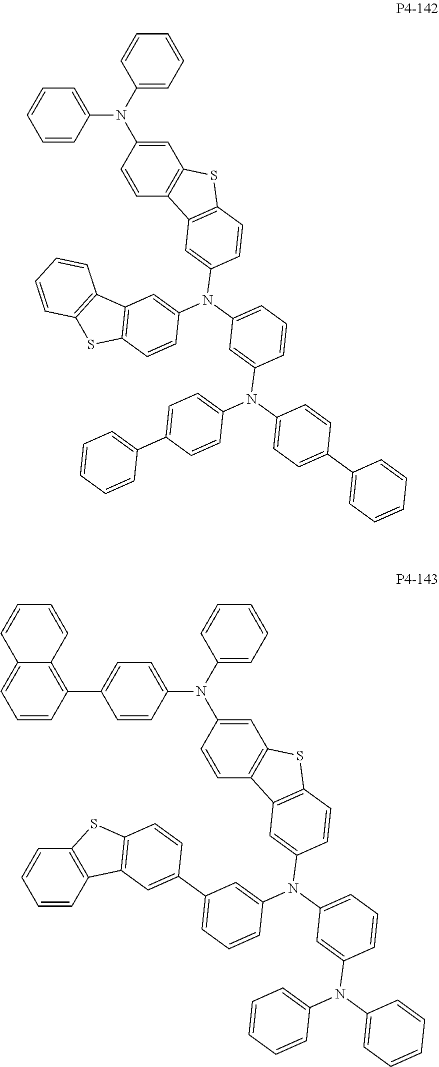 [SMILES: c1ccc(-c2ccc(N(c3ccc(-c4ccccc4)cc3)c3cccc(N(c4ccc5sc6ccccc6c5c4)c4ccc5sc6cc(N(c7ccccc7)c7ccccc7)ccc6c5c4)c3)cc2)cc1 ; c1ccc(N(c2ccccc2)c2cccc(N(c3cccc(-c4ccc5sc6ccccc6c5c4)c3)c3ccc4sc5cc(N(c6ccccc6)c6ccc(-c7cccc8ccccc78)cc6)ccc5c4c3)c2)cc1]

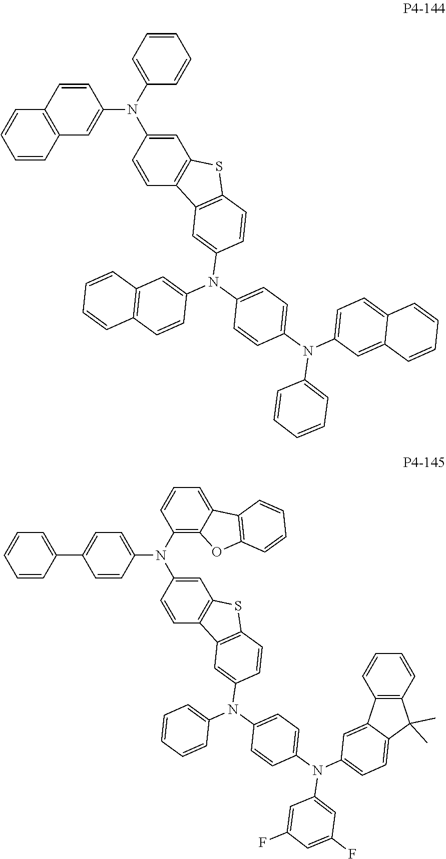 [SMILES: c1ccc(N(c2ccc(N(c3ccc4ccccc4c3)c3ccc4sc5cc(N(c6ccccc6)c6ccc7ccccc7c6)ccc5c4c3)cc2)c2ccc3ccccc3c2)cc1 ; CC1(C)c2ccccc2-c2cc(N(c3ccc(N(c4ccccc4)c4ccc5sc6cc(N(c7ccc(-c8ccccc8)cc7)c7cccc8c7oc7ccccc78)ccc6c5c4)cc3)c3cc(F)cc(F)c3)ccc21]

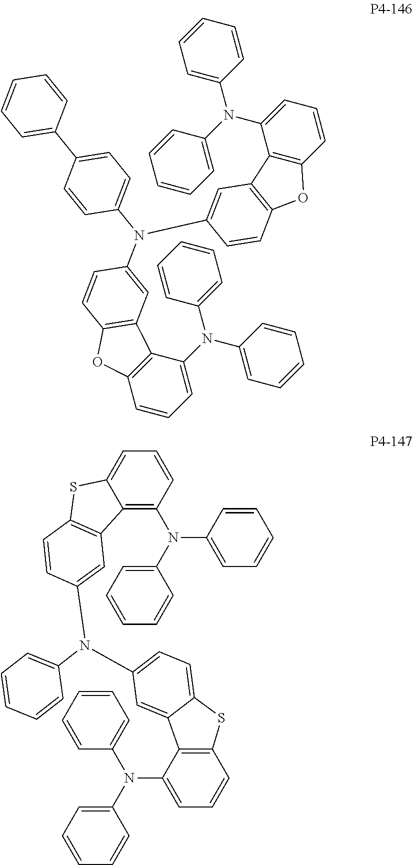

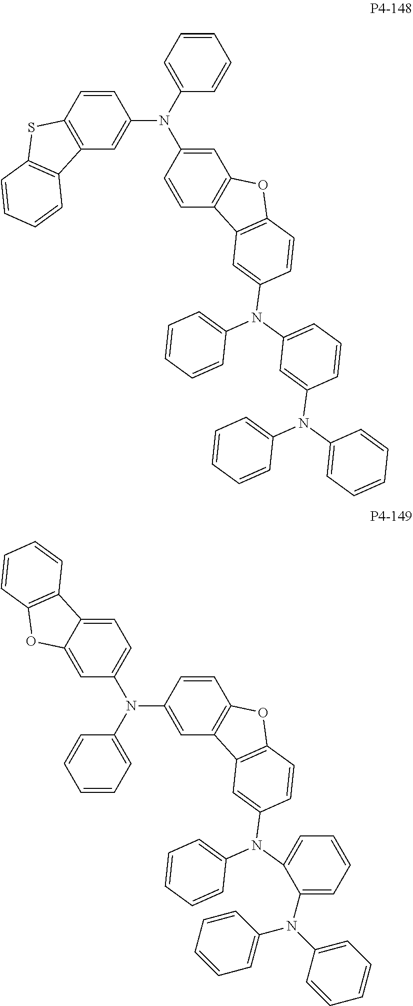 [SMILES: c1ccc(N(c2ccccc2)c2cccc(N(c3ccccc3)c3ccc4oc5cc(N(c6ccccc6)c6ccc7sc8ccccc8c7c6)ccc5c4c3)c2)cc1 ; c1ccc(N(c2ccc3c(c2)oc2ccccc23)c2ccc3oc4ccc(N(c5ccccc5)c5ccccc5N(c5ccccc5)c5ccccc5)cc4c3c2)cc1]

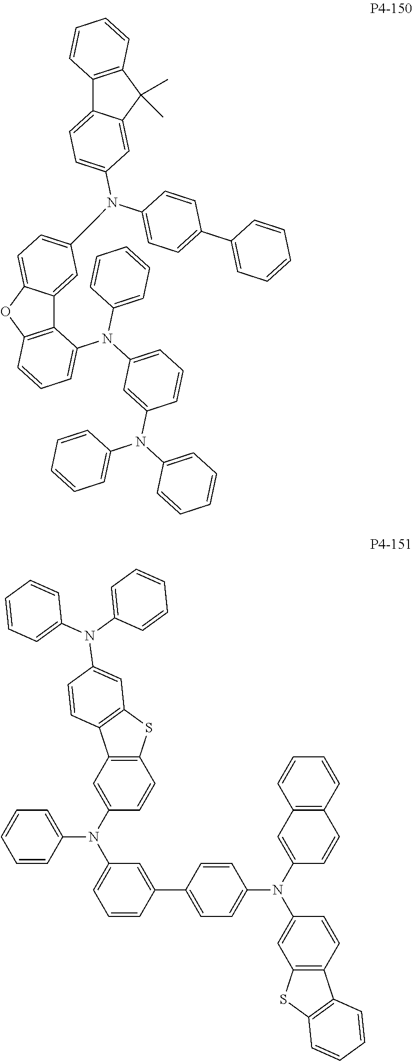 [SMILES: CC1(C)c2ccccc2-c2ccc(N(c3ccc(-c4ccccc4)cc3)c3ccc4oc5cccc(N(c6ccccc6)c6cccc(N(c7ccccc7)c7ccccc7)c6)c5c4c3)cc21 ; c1ccc(N(c2ccccc2)c2ccc3c(c2)sc2ccc(N(c4ccccc4)c4cccc(-c5ccc(N(c6ccc7ccccc7c6)c6ccc7c(c6)sc6ccccc67)cc5)c4)cc23)cc1]

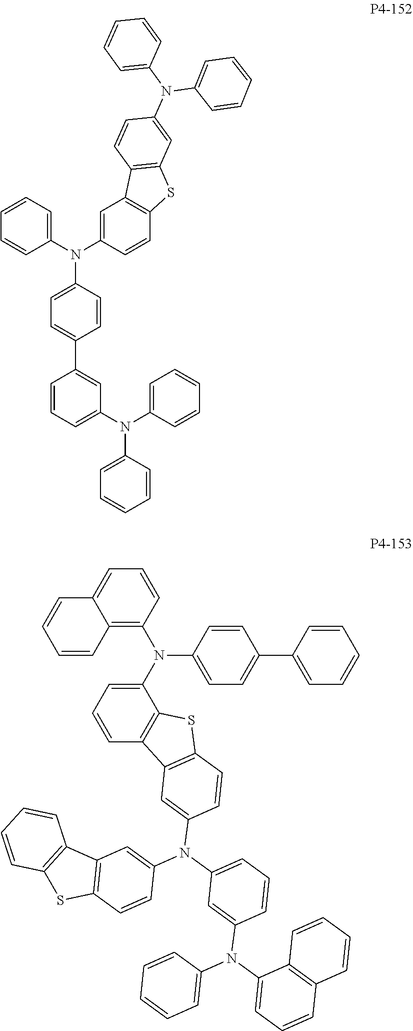 [SMILES: c1ccc(N(c2ccccc2)c2cccc(-c3ccc(N(c4ccccc4)c4ccc5sc6cc(N(c7ccccc7)c7ccccc7)ccc6c5c4)cc3)c2)cc1 ; c1ccc(-c2ccc(N(c3cccc4ccccc34)c3cccc4c3sc3ccc(N(c5cccc(N(c6ccccc6)c6cccc7ccccc67)c5)c5ccc6sc7ccccc7c6c5)cc34)cc2)cc1]

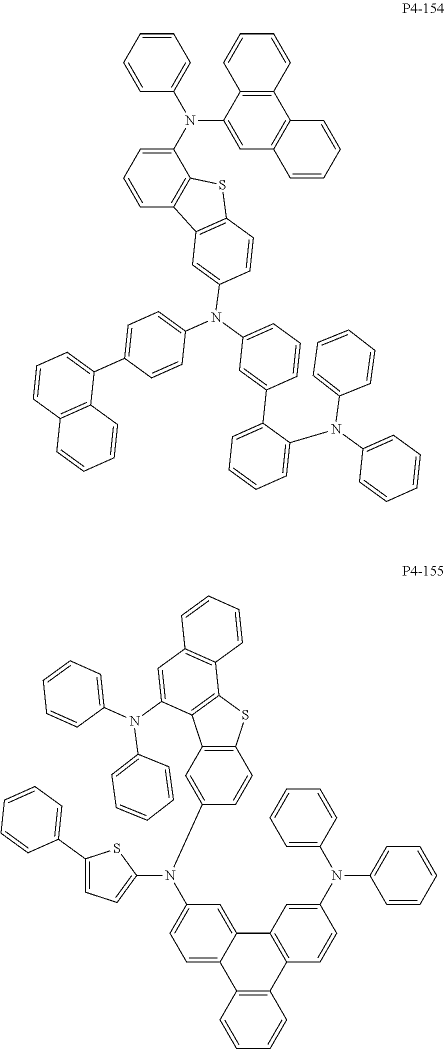 [SMILES: c1ccc(N(c2ccccc2)c2ccccc2-c2cccc(N(c3ccc(-c4cccc5ccccc45)cc3)c3ccc4sc5c(N(c6ccccc6)c6cc7ccccc7c7ccccc67)cccc5c4c3)c2)cc1 ; c1ccc(-c2ccc(N(c3ccc4c5ccccc5c5ccc(N(c6ccccc6)c6ccccc6)cc5c4c3)c3ccc4sc5c6ccccc6cc(N(c6ccccc6)c6ccccc6)c5c4c3)s2)cc1]

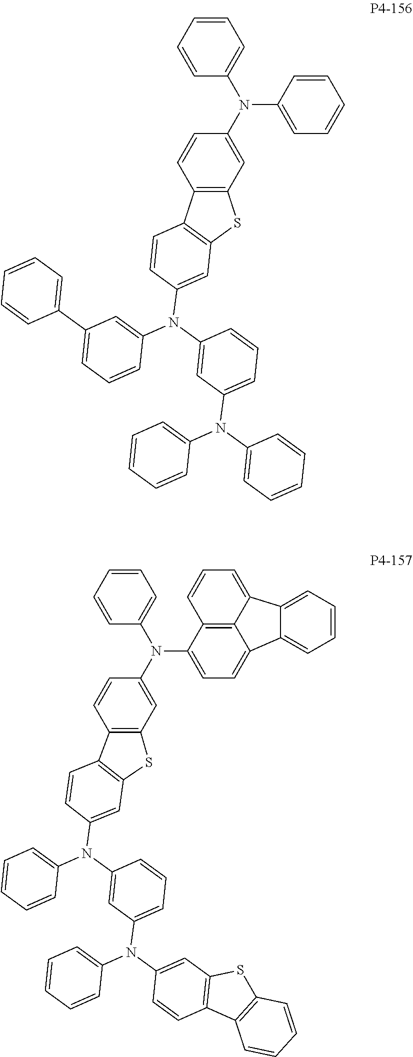 [SMILES: c1ccc(-c2cccc(N(c3cccc(N(c4ccccc4)c4ccccc4)c3)c3ccc4c(c3)sc3cc(N(c5ccccc5)c5ccccc5)ccc34)c2)cc1 ; c1ccc(N(c2cccc(N(c3ccccc3)c3ccc4c(c3)sc3cc(N(c5ccccc5)c5ccc6c7c(cccc57)-c5ccccc5-6)ccc34)c2)c2ccc3c(c2)sc2ccccc23)cc1]

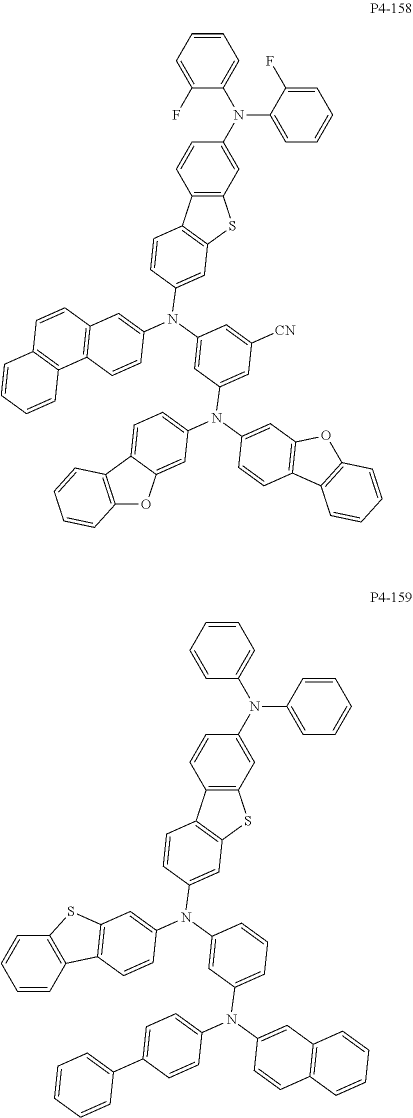 [SMILES: N#Cc1cc(N(c2ccc3c(c2)oc2ccccc23)c2ccc3c(c2)oc2ccccc23)cc(N(c2ccc3c(ccc4ccccc43)c2)c2ccc3c(c2)sc2cc(N(c4ccccc4F)c4ccccc4F)ccc23)c1 ; c1ccc(-c2ccc(N(c3cccc(N(c4ccc5c(c4)sc4ccccc45)c4ccc5c(c4)sc4cc(N(c6ccccc6)c6ccccc6)ccc45)c3)c3ccc4ccccc4c3)cc2)cc1]

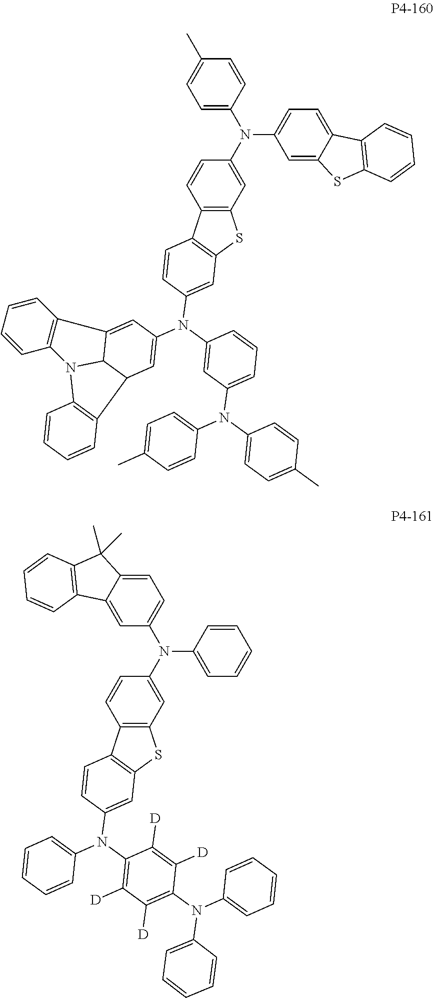 [SMILES: Cc1ccc(N(c2ccc(C)cc2)c2cccc(N(C3=CC4c5ccccc5N5c6ccccc6C(=C3)C45)c3ccc4c(c3)sc3cc(N(c5ccc(C)cc5)c5ccc6c(c5)sc5ccccc56)ccc34)c2)cc1 ; [2H]c1c([2H])c(N(c2ccccc2)c2ccc3c(c2)sc2cc(N(c4ccccc4)c4ccc5c(c4)-c4ccccc4C5(C)C)ccc23)c([2H])c([2H])c1N(c1ccccc1)c1ccccc1]

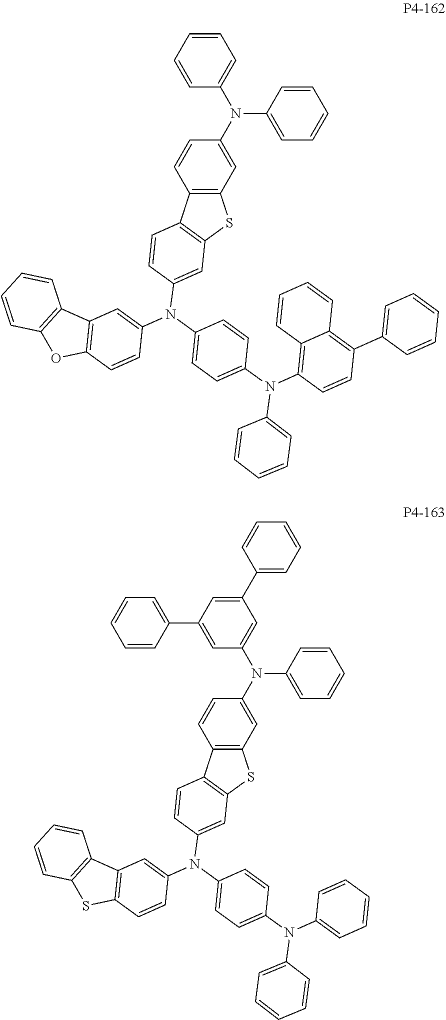 [SMILES: c1ccc(-c2ccc(N(c3ccccc3)c3ccc(N(c4ccc5c(c4)sc4cc(N(c6ccccc6)c6ccccc6)ccc45)c4ccc5oc6ccccc6c5c4)cc3)c3ccccc23)cc1 ; c1ccc(-c2cc(-c3ccccc3)cc(N(c3ccccc3)c3ccc4c(c3)sc3cc(N(c5ccc(N(c6ccccc6)c6ccccc6)cc5)c5ccc6sc7ccccc7c6c5)ccc34)c2)cc1]

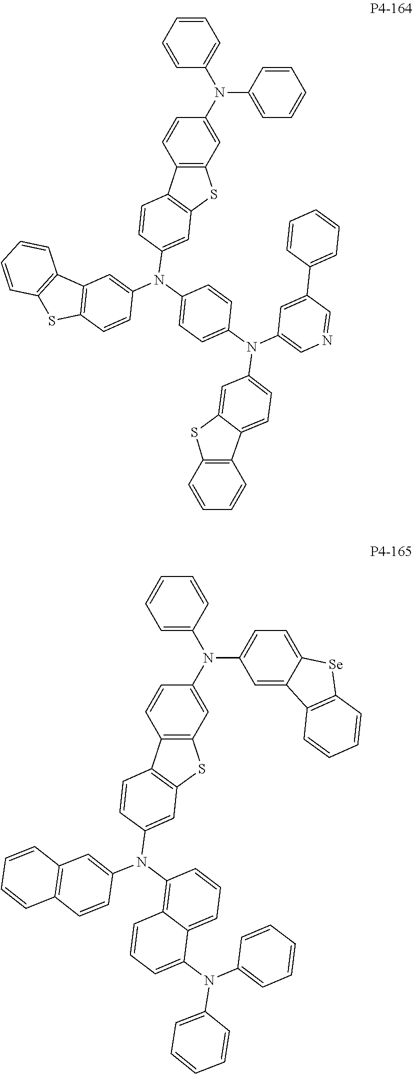 [SMILES: c1ccc(-c2cncc(N(c3ccc(N(c4ccc5c(c4)sc4cc(N(c6ccccc6)c6ccccc6)ccc45)c4ccc5sc6ccccc6c5c4)cc3)c3ccc4c(c3)sc3ccccc34)c2)cc1 ; c1ccc(N(c2ccc3c(c2)sc2cc(N(c4ccc5ccccc5c4)c4cccc5c(N(c6ccccc6)c6ccccc6)cccc45)ccc23)c2ccc3[se]c4ccccc4c3c2)cc1]

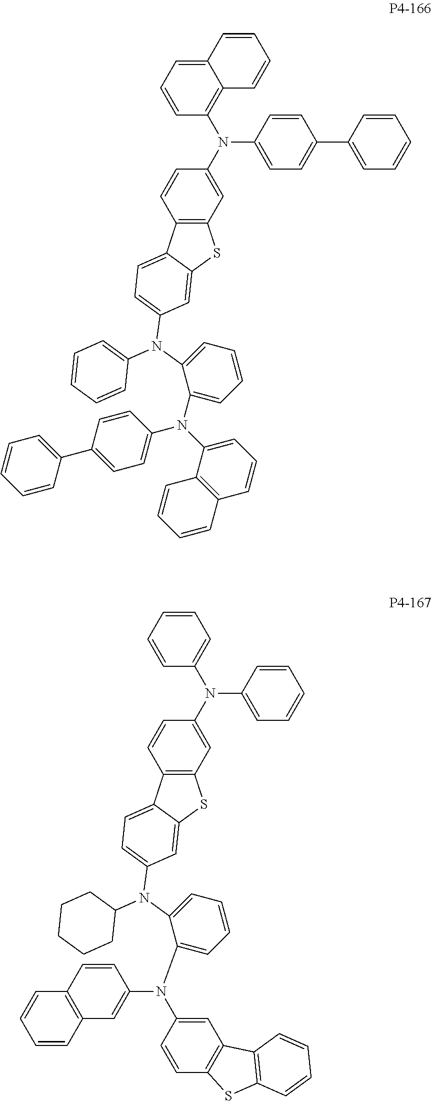 [SMILES: c1ccc(-c2ccc(N(c3ccc4c(c3)sc3cc(N(c5ccccc5)c5ccccc5N(c5ccc(-c6ccccc6)cc5)c5cccc6ccccc56)ccc34)c3cccc4ccccc34)cc2)cc1 ; c1ccc(N(c2ccccc2)c2ccc3c(c2)sc2cc(N(c4ccccc4N(c4ccc5ccccc5c4)c4ccc5sc6ccccc6c5c4)C4CCCCC4)ccc23)cc1]

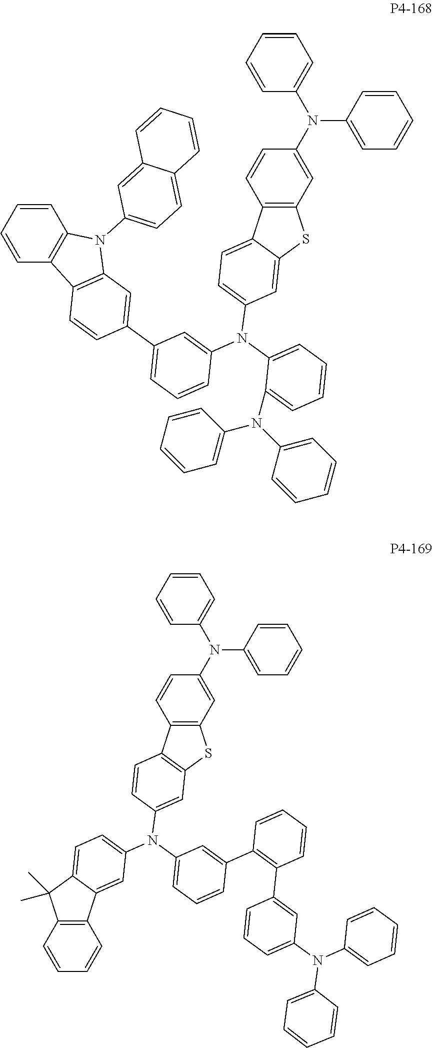 [SMILES: c1ccc(N(c2ccccc2)c2ccc3c(c2)sc2cc(N(c4cccc(-c5ccc6c7ccccc7n(-c7ccc8ccccc8c7)c6c5)c4)c4ccccc4N(c4ccccc4)c4ccccc4)ccc23)cc1 ; CC1(C)c2ccccc2-c2cc(N(c3cccc(-c4ccccc4-c4cccc(N(c5ccccc5)c5ccccc5)c4)c3)c3ccc4c(c3)sc3cc(N(c5ccccc5)c5ccccc5)ccc34)ccc21]

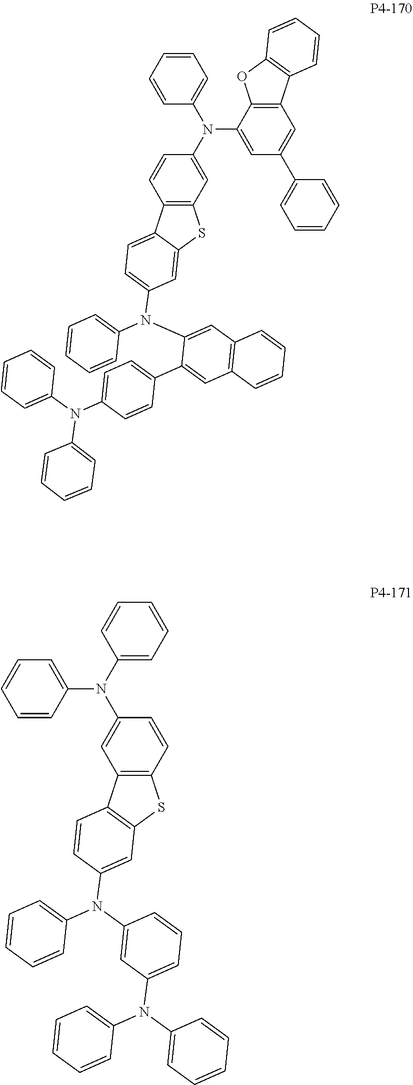 [SMILES: c1ccc(-c2cc(N(c3ccccc3)c3ccc4c(c3)sc3cc(N(c5ccccc5)c5cc6ccccc6cc5-c5ccc(N(c6ccccc6)c6ccccc6)cc5)ccc34)c3oc4ccccc4c3c2)cc1 ; c1ccc(N(c2ccccc2)c2cccc(N(c3ccccc3)c3ccc4c(c3)sc3ccc(N(c5ccccc5)c5ccccc5)cc34)c2)cc1]

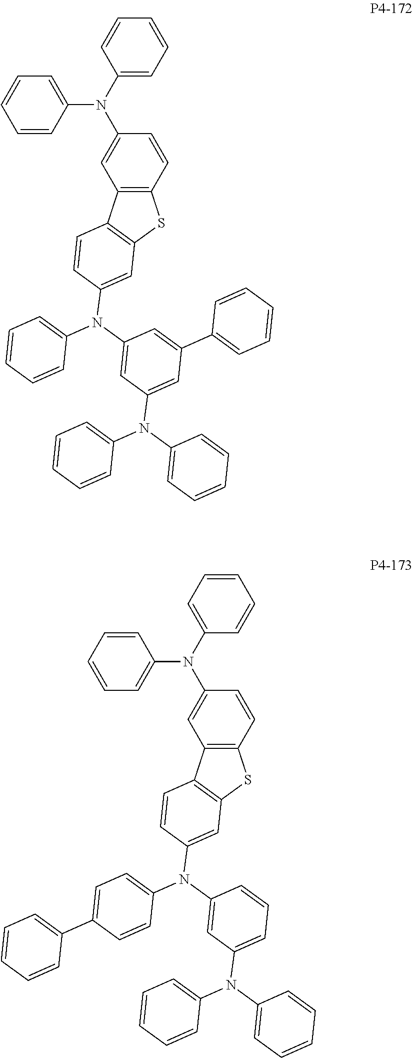 [SMILES: c1ccc(-c2cc(N(c3ccccc3)c3ccccc3)cc(N(c3ccccc3)c3ccc4c(c3)sc3ccc(N(c5ccccc5)c5ccccc5)cc34)c2)cc1 ; c1ccc(-c2ccc(N(c3cccc(N(c4ccccc4)c4ccccc4)c3)c3ccc4c(c3)sc3ccc(N(c5ccccc5)c5ccccc5)cc34)cc2)cc1]

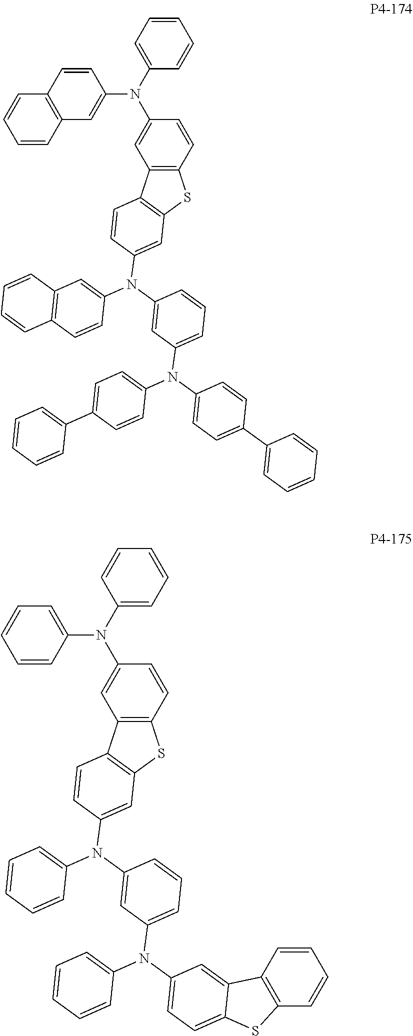 [SMILES: c1ccc(-c2ccc(N(c3ccc(-c4ccccc4)cc3)c3cccc(N(c4ccc5ccccc5c4)c4ccc5c(c4)sc4ccc(N(c6ccccc6)c6ccc7ccccc7c6)cc45)c3)cc2)cc1 ; c1ccc(N(c2cccc(N(c3ccccc3)c3ccc4sc5ccccc5c4c3)c2)c2ccc3c(c2)sc2ccc(N(c4ccccc4)c4ccccc4)cc23)cc1]

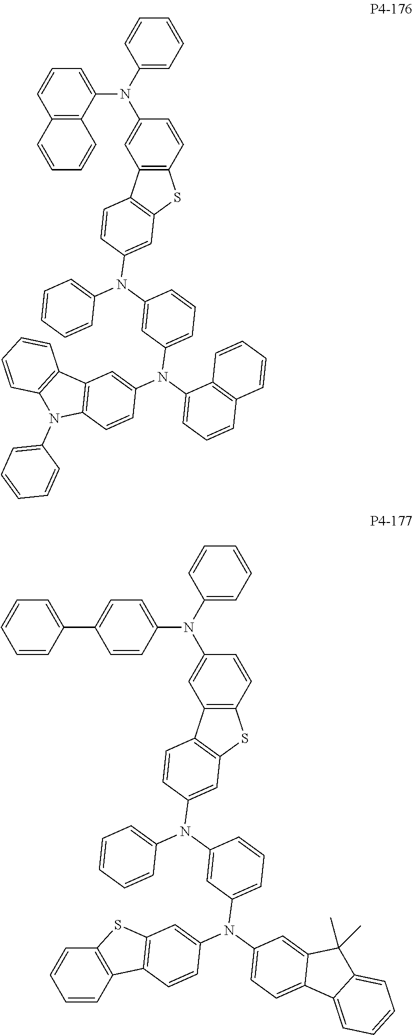 [SMILES: c1ccc(N(c2cccc(N(c3ccc4c(c3)c3ccccc3n4-c3ccccc3)c3cccc4ccccc34)c2)c2ccc3c(c2)sc2ccc(N(c4ccccc4)c4cccc5ccccc45)cc23)cc1 ; CC1(C)c2ccccc2-c2ccc(N(c3cccc(N(c4ccccc4)c4ccc5c(c4)sc4ccc(N(c6ccccc6)c6ccc(-c7ccccc7)cc6)cc45)c3)c3ccc4c(c3)sc3ccccc34)cc21]

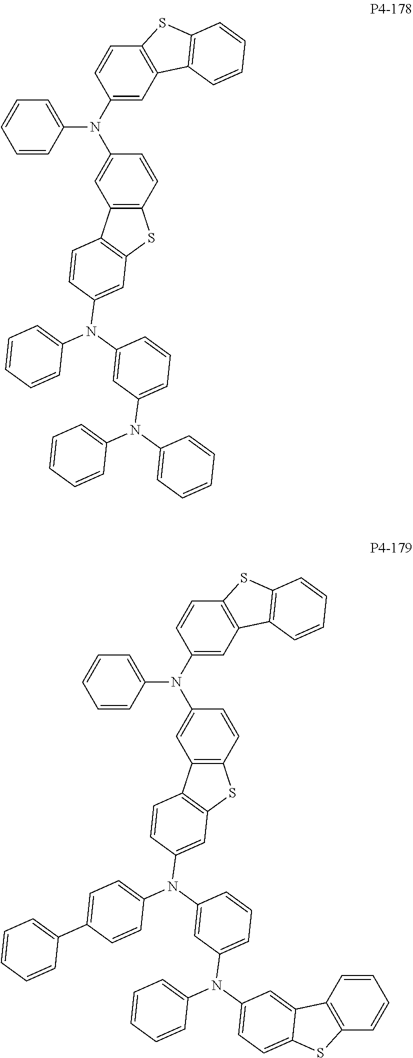 [SMILES: c1ccc(N(c2ccccc2)c2cccc(N(c3ccccc3)c3ccc4c(c3)sc3ccc(N(c5ccccc5)c5ccc6sc7ccccc7c6c5)cc34)c2)cc1 ; c1ccc(-c2ccc(N(c3cccc(N(c4ccccc4)c4ccc5sc6ccccc6c5c4)c3)c3ccc4c(c3)sc3ccc(N(c5ccccc5)c5ccc6sc7ccccc7c6c5)cc34)cc2)cc1]

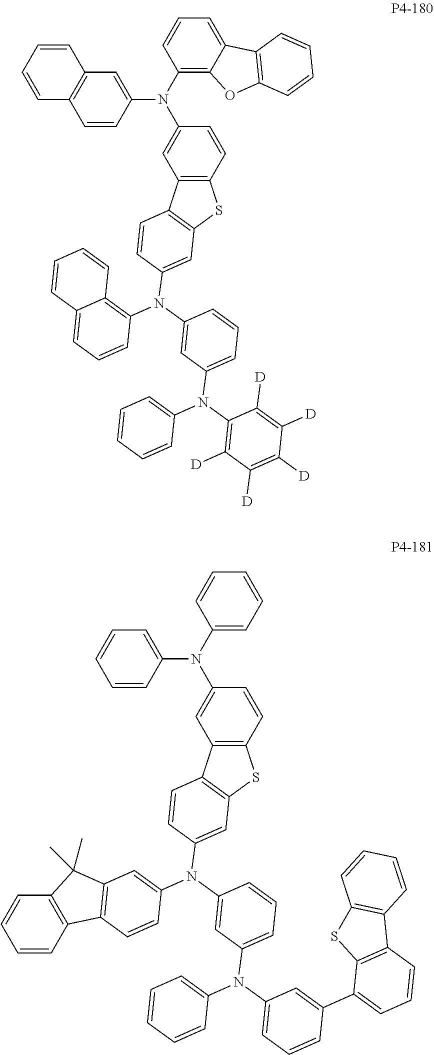 [SMILES: [2H]c1c([2H])c([2H])c(N(c2ccccc2)c2cccc(N(c3ccc4c(c3)sc3ccc(N(c5ccc6ccccc6c5)c5cccc6c5oc5ccccc56)cc34)c3cccc4ccccc34)c2)c([2H])c1[2H] ; CC1(C)c2ccccc2-c2ccc(N(c3cccc(N(c4ccccc4)c4cccc(-c5cccc6c5sc5ccccc56)c4)c3)c3ccc4c(c3)sc3ccc(N(c5ccccc5)c5ccccc5)cc34)cc21]

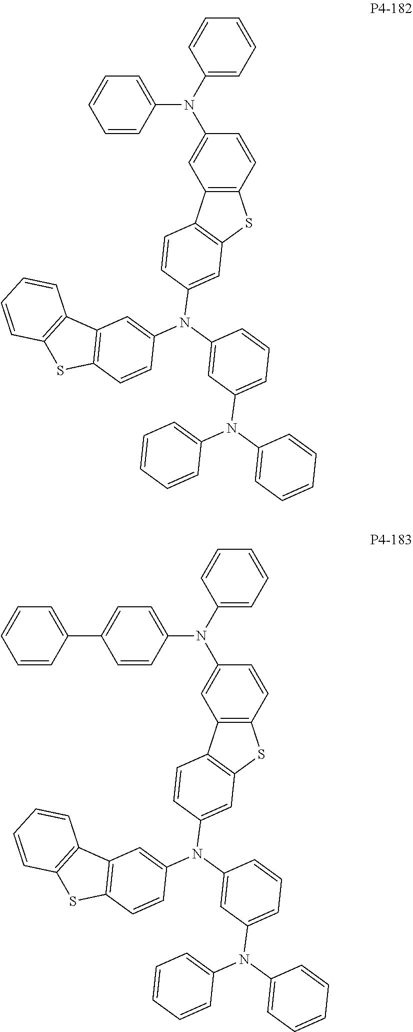 [SMILES: c1ccc(N(c2ccccc2)c2cccc(N(c3ccc4c(c3)sc3ccc(N(c5ccccc5)c5ccccc5)cc34)c3ccc4sc5ccccc5c4c3)c2)cc1 ; c1ccc(-c2ccc(N(c3ccccc3)c3ccc4sc5cc(N(c6cccc(N(c7ccccc7)c7ccccc7)c6)c6ccc7sc8ccccc8c7c6)ccc5c4c3)cc2)cc1]

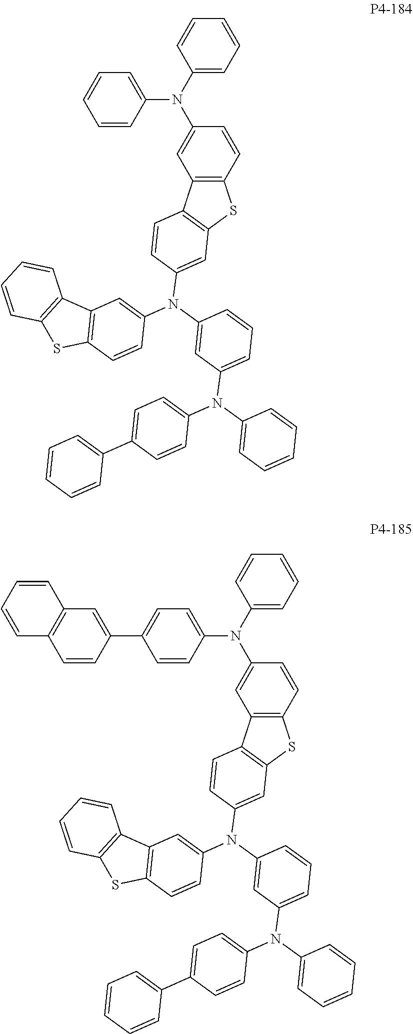 [SMILES: c1ccc(-c2ccc(N(c3ccccc3)c3cccc(N(c4ccc5c(c4)sc4ccc(N(c6ccccc6)c6ccccc6)cc45)c4ccc5sc6ccccc6c5c4)c3)cc2)cc1 ; c1ccc(-c2ccc(N(c3ccccc3)c3cccc(N(c4ccc5c(c4)sc4ccc(N(c6ccccc6)c6ccc(-c7ccc8ccccc8c7)cc6)cc45)c4ccc5sc6ccccc6c5c4)c3)cc2)cc1]

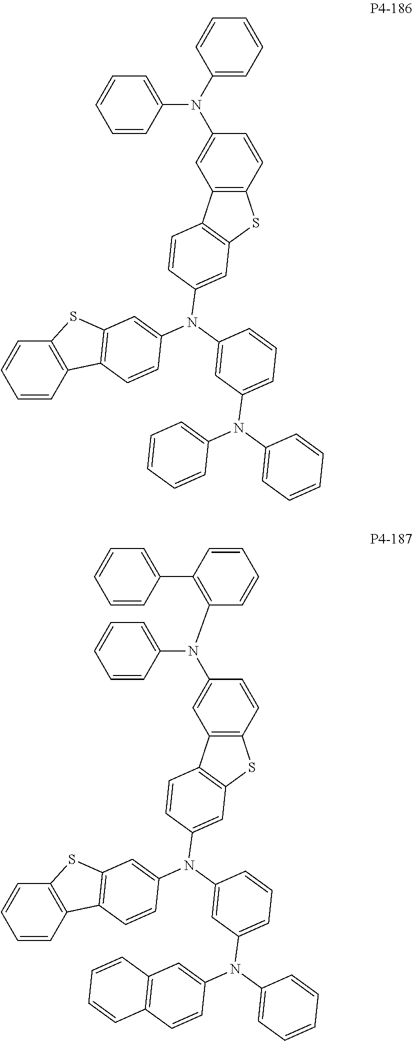 [SMILES: c1ccc(N(c2ccccc2)c2cccc(N(c3ccc4c(c3)sc3ccccc34)c3ccc4c(c3)sc3ccc(N(c5ccccc5)c5ccccc5)cc34)c2)cc1 ; c1ccc(-c2ccccc2N(c2ccccc2)c2ccc3sc4cc(N(c5cccc(N(c6ccccc6)c6ccc7ccccc7c6)c5)c5ccc6c(c5)sc5ccccc56)ccc4c3c2)cc1]

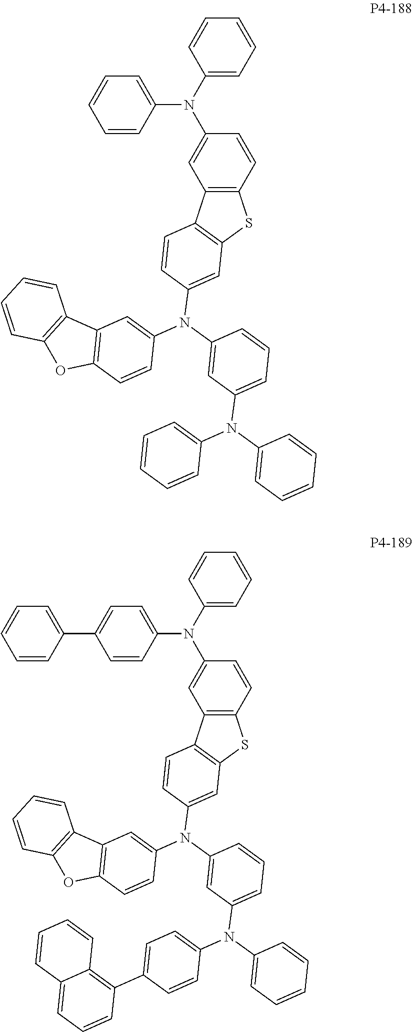 [SMILES: c1ccc(N(c2ccccc2)c2cccc(N(c3ccc4c(c3)sc3ccc(N(c5ccccc5)c5ccccc5)cc34)c3ccc4oc5ccccc5c4c3)c2)cc1 ; c1ccc(-c2ccc(N(c3ccccc3)c3ccc4sc5cc(N(c6cccc(N(c7ccccc7)c7ccc(-c8cccc9ccccc89)cc7)c6)c6ccc7oc8ccccc8c7c6)ccc5c4c3)cc2)cc1]

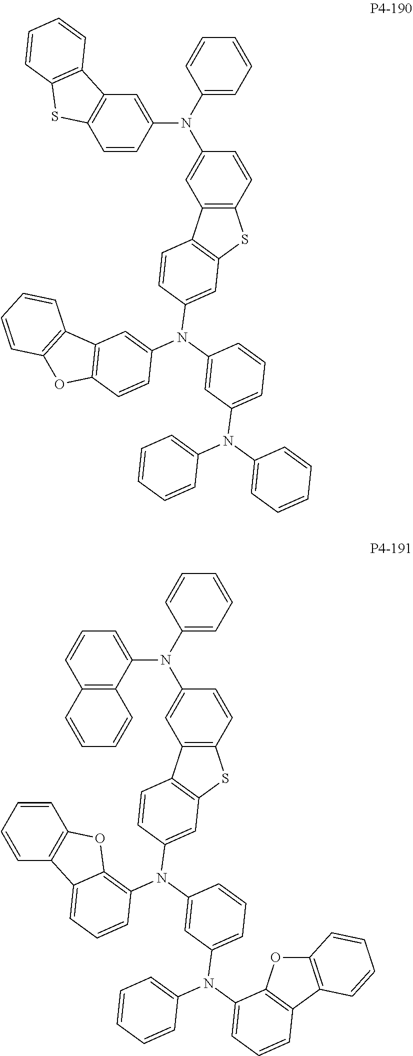 [SMILES: c1ccc(N(c2ccccc2)c2cccc(N(c3ccc4c(c3)sc3ccc(N(c5ccccc5)c5ccc6sc7ccccc7c6c5)cc34)c3ccc4oc5ccccc5c4c3)c2)cc1 ; c1ccc(N(c2ccc3sc4cc(N(c5cccc(N(c6ccccc6)c6cccc7c6oc6ccccc67)c5)c5cccc6c5oc5ccccc56)ccc4c3c2)c2cccc3ccccc23)cc1]

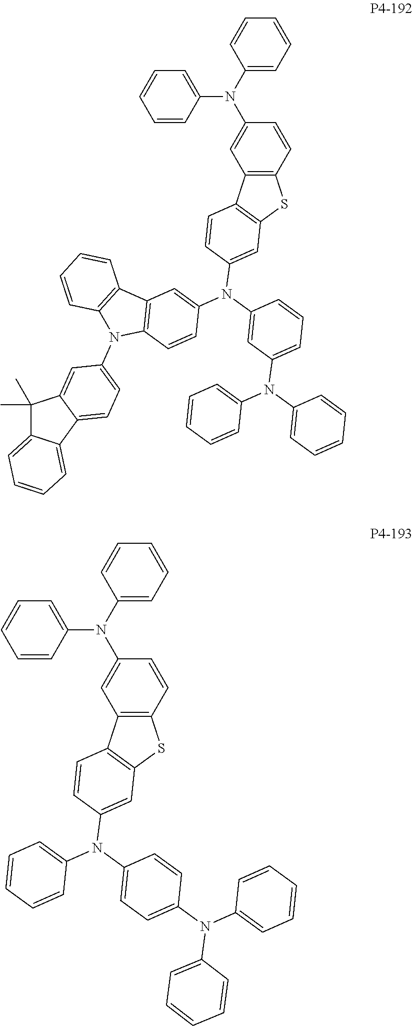 [SMILES: CC1(C)c2ccccc2-c2ccc(-n3c4ccccc4c4cc(N(c5cccc(N(c6ccccc6)c6ccccc6)c5)c5ccc6c(c5)sc5ccc(N(c7ccccc7)c7ccccc7)cc56)ccc43)cc21 ; c1ccc(N(c2ccccc2)c2ccc(N(c3ccccc3)c3ccc4c(c3)sc3ccc(N(c5ccccc5)c5ccccc5)cc34)cc2)cc1]

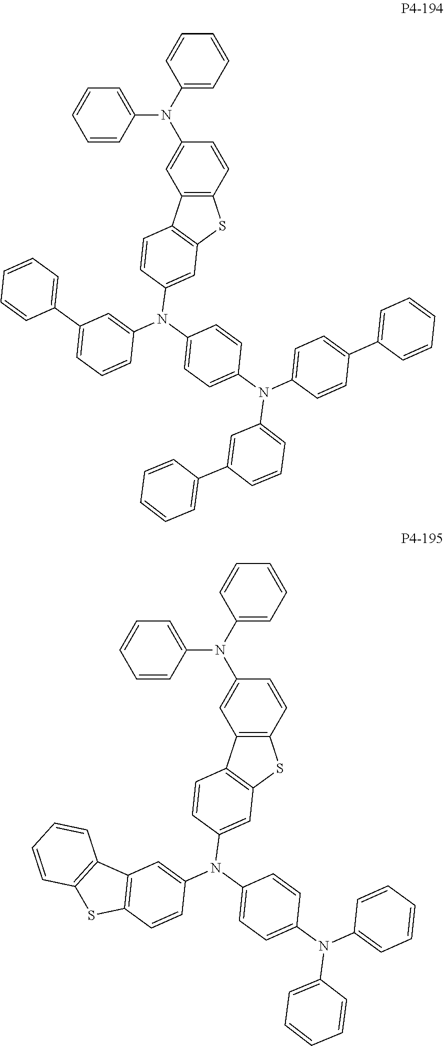 [SMILES: c1ccc(-c2ccc(N(c3ccc(N(c4cccc(-c5ccccc5)c4)c4ccc5c(c4)sc4ccc(N(c6ccccc6)c6ccccc6)cc45)cc3)c3cccc(-c4ccccc4)c3)cc2)cc1 ; c1ccc(N(c2ccccc2)c2ccc(N(c3ccc4c(c3)sc3ccc(N(c5ccccc5)c5ccccc5)cc34)c3ccc4sc5ccccc5c4c3)cc2)cc1]

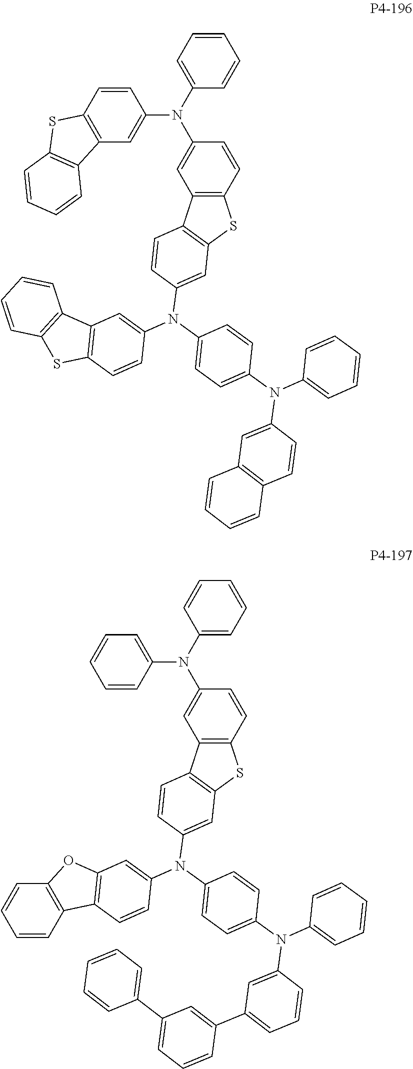 [SMILES: c1ccc(N(c2ccc(N(c3ccc4c(c3)sc3ccc(N(c5ccccc5)c5ccc6sc7ccccc7c6c5)cc34)c3ccc4sc5ccccc5c4c3)cc2)c2ccc3ccccc3c2)cc1 ; c1ccc(-c2cccc(-c3cccc(N(c4ccccc4)c4ccc(N(c5ccc6c(c5)oc5ccccc56)c5ccc6c(c5)sc5ccc(N(c7ccccc7)c7ccccc7)cc56)cc4)c3)c2)cc1]

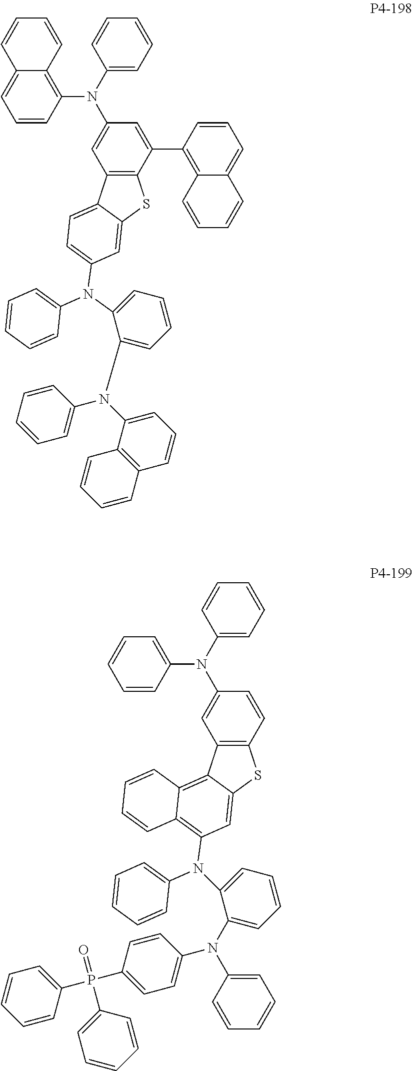 [SMILES: c1ccc(N(c2ccc3c(c2)sc2c(-c4cccc5ccccc45)cc(N(c4ccccc4)c4cccc5ccccc45)cc23)c2ccccc2N(c2ccccc2)c2cccc3ccccc23)cc1 ; O=P(c1ccccc1)(c1ccccc1)c1ccc(N(c2ccccc2)c2ccccc2N(c2ccccc2)c2cc3sc4ccc(N(c5ccccc5)c5ccccc5)cc4c3c3ccccc23)cc1]

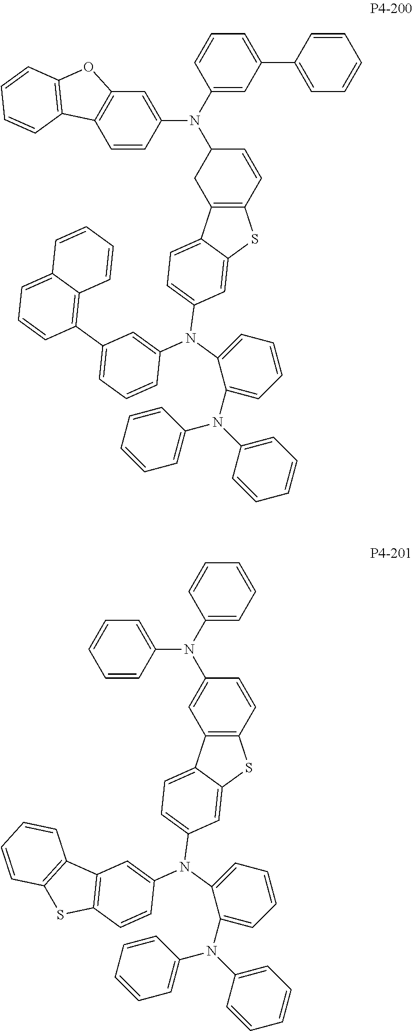 [SMILES: C1=CC(N(c2cccc(-c3ccccc3)c2)c2ccc3c(c2)oc2ccccc23)Cc2c1sc1cc(N(c3cccc(-c4cccc5ccccc45)c3)c3ccccc3N(c3ccccc3)c3ccccc3)ccc21 ; c1ccc(N(c2ccccc2)c2ccc3sc4cc(N(c5ccc6sc7ccccc7c6c5)c5ccccc5N(c5ccccc5)c5ccccc5)ccc4c3c2)cc1]

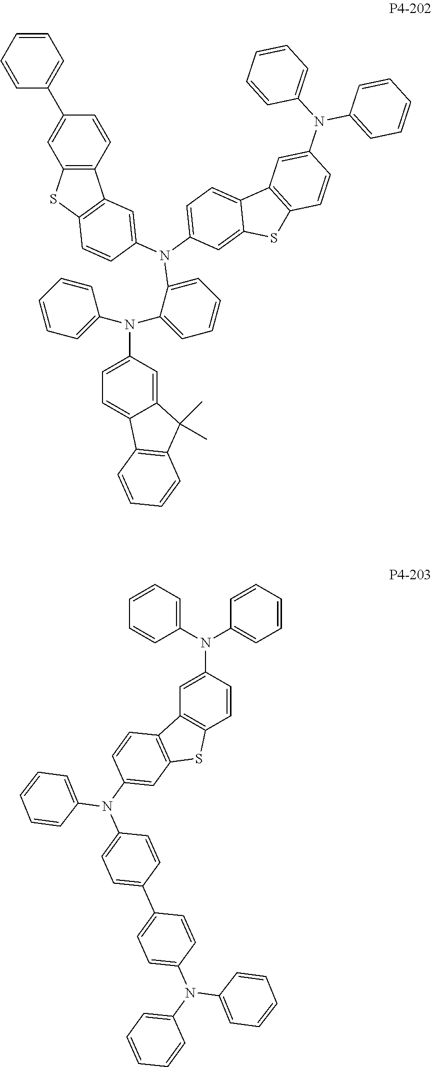 [SMILES: CC1(C)c2ccccc2-c2ccc(N(c3ccccc3)c3ccccc3N(c3ccc4c(c3)sc3ccc(N(c5ccccc5)c5ccccc5)cc34)c3ccc4sc5cc(-c6ccccc6)ccc5c4c3)cc21 ; c1ccc(N(c2ccccc2)c2ccc(-c3ccc(N(c4ccccc4)c4ccc5c(c4)sc4ccc(N(c6ccccc6)c6ccccc6)cc45)cc3)cc2)cc1]

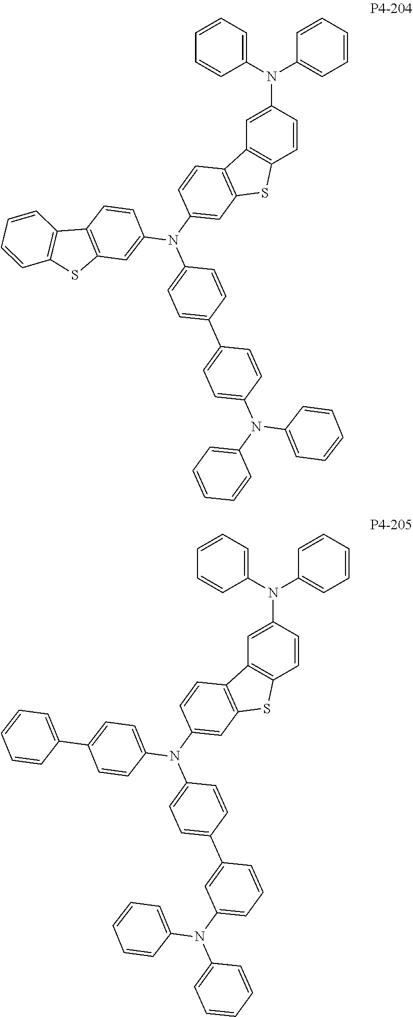

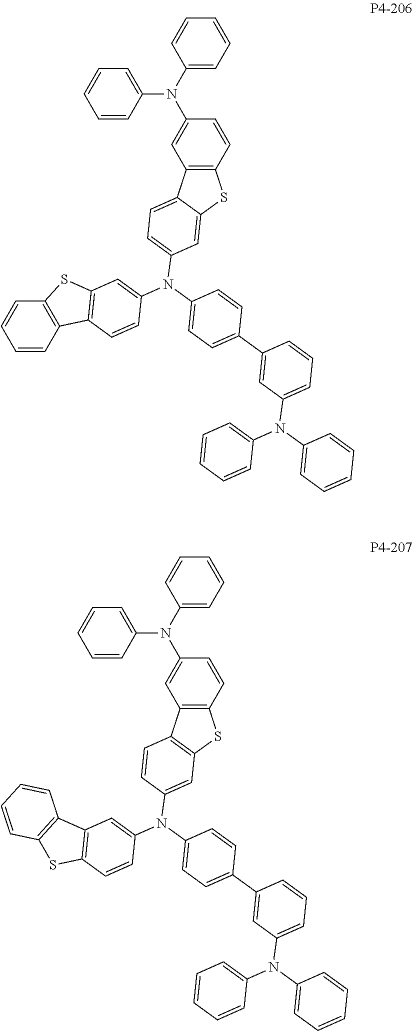 [SMILES: c1ccc(N(c2ccccc2)c2cccc(-c3ccc(N(c4ccc5c(c4)sc4ccccc45)c4ccc5c(c4)sc4ccc(N(c6ccccc6)c6ccccc6)cc45)cc3)c2)cc1 ; c1ccc(N(c2ccccc2)c2cccc(-c3ccc(N(c4ccc5c(c4)sc4ccc(N(c6ccccc6)c6ccccc6)cc45)c4ccc5sc6ccccc6c5c4)cc3)c2)cc1]

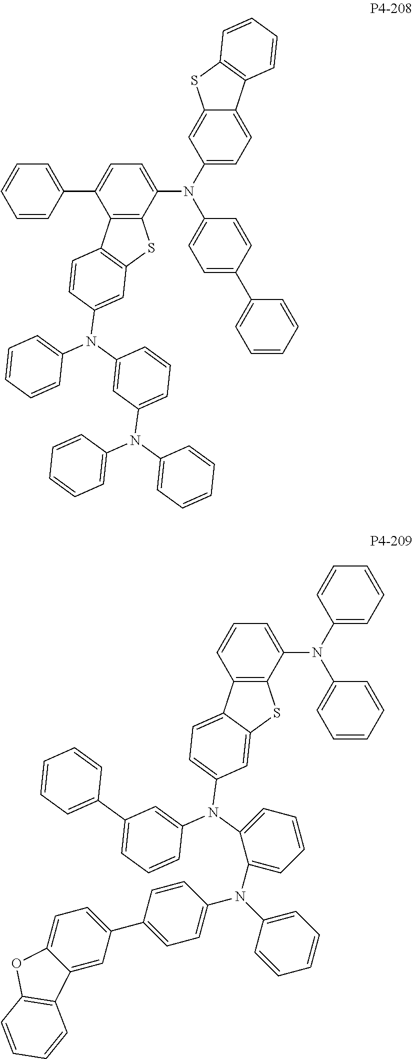 [SMILES: c1ccc(-c2ccc(N(c3ccc4c(c3)sc3ccccc34)c3ccc(-c4ccccc4)c4c3sc3cc(N(c5ccccc5)c5cccc(N(c6ccccc6)c6ccccc6)c5)ccc34)cc2)cc1 ; c1ccc(-c2cccc(N(c3ccc4c(c3)sc3c(N(c5ccccc5)c5ccccc5)cccc34)c3ccccc3N(c3ccccc3)c3ccc(-c4ccc5oc6ccccc6c5c4)cc3)c2)cc1]

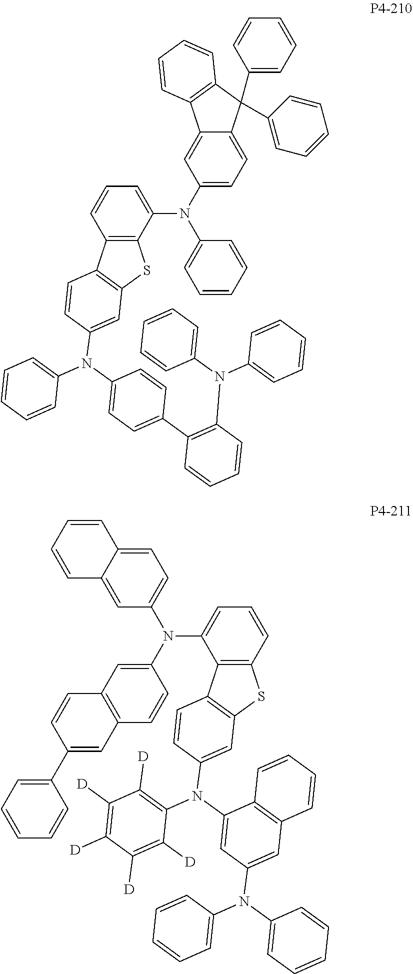 [SMILES: c1ccc(N(c2ccc(-c3ccccc3N(c3ccccc3)c3ccccc3)cc2)c2ccc3c(c2)sc2c(N(c4ccccc4)c4ccc5c(c4)-c4ccccc4C5(c4ccccc4)c4ccccc4)cccc23)cc1 ; [2H]c1c([2H])c([2H])c(N(c2ccc3c(c2)sc2cccc(N(c4ccc5ccccc5c4)c4ccc5cc(-c6ccccc6)ccc5c4)c23)c2cc(N(c3ccccc3)c3ccccc3)cc3ccccc23)c([2H])c1[2H]]

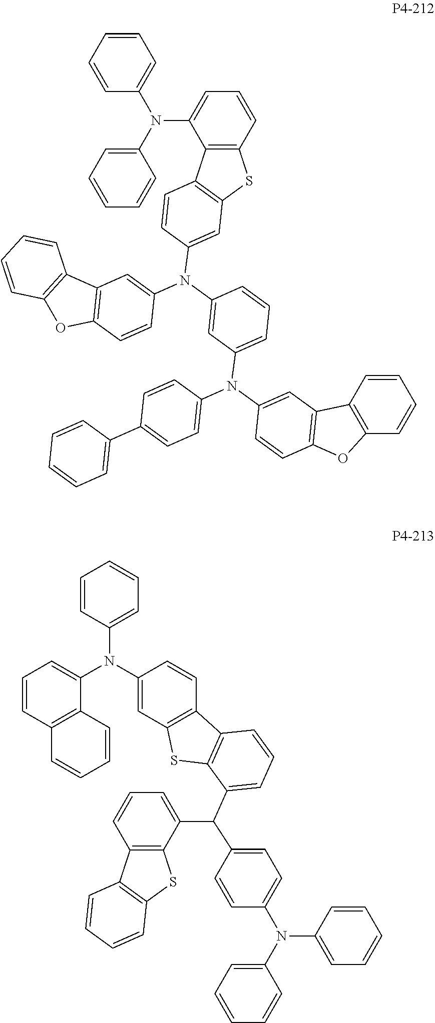 [SMILES: c1ccc(-c2ccc(N(c3cccc(N(c4ccc5c(c4)sc4cccc(N(c6ccccc6)c6ccccc6)c45)c4ccc5oc6ccccc6c5c4)c3)c3ccc4oc5ccccc5c4c3)cc2)cc1 ; c1ccc(N(c2ccccc2)c2ccc(C(c3cccc4c3sc3ccccc34)c3cccc4c3sc3cc(N(c5ccccc5)c5cccc6ccccc56)ccc34)cc2)cc1]

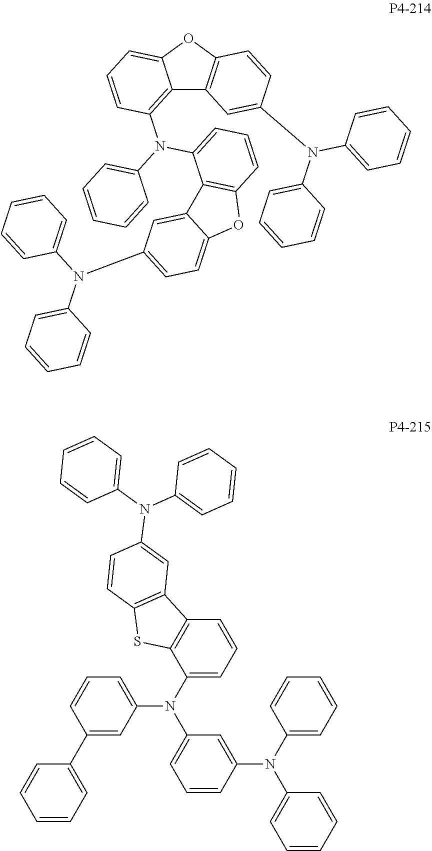 [SMILES: c1ccc(N(c2ccccc2)c2ccc3oc4cccc(N(c5ccccc5)c5cccc6oc7ccc(N(c8ccccc8)c8ccccc8)cc7c56)c4c3c2)cc1 ; c1ccc(-c2cccc(N(c3cccc(N(c4ccccc4)c4ccccc4)c3)c3cccc4c3sc3ccc(N(c5ccccc5)c5ccccc5)cc34)c2)cc1]

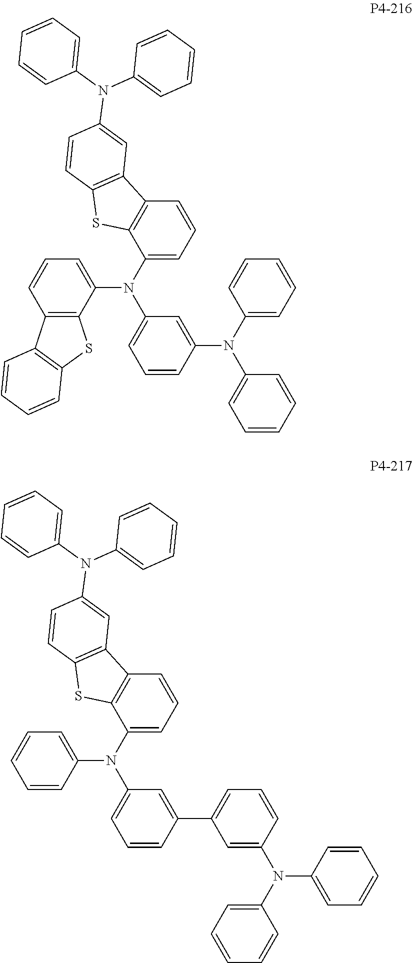 [SMILES: c1ccc(N(c2ccccc2)c2cccc(N(c3cccc4c3sc3ccccc34)c3cccc4c3sc3ccc(N(c5ccccc5)c5ccccc5)cc34)c2)cc1 ; c1ccc(N(c2ccccc2)c2cccc(-c3cccc(N(c4ccccc4)c4cccc5c4sc4ccc(N(c6ccccc6)c6ccccc6)cc45)c3)c2)cc1]

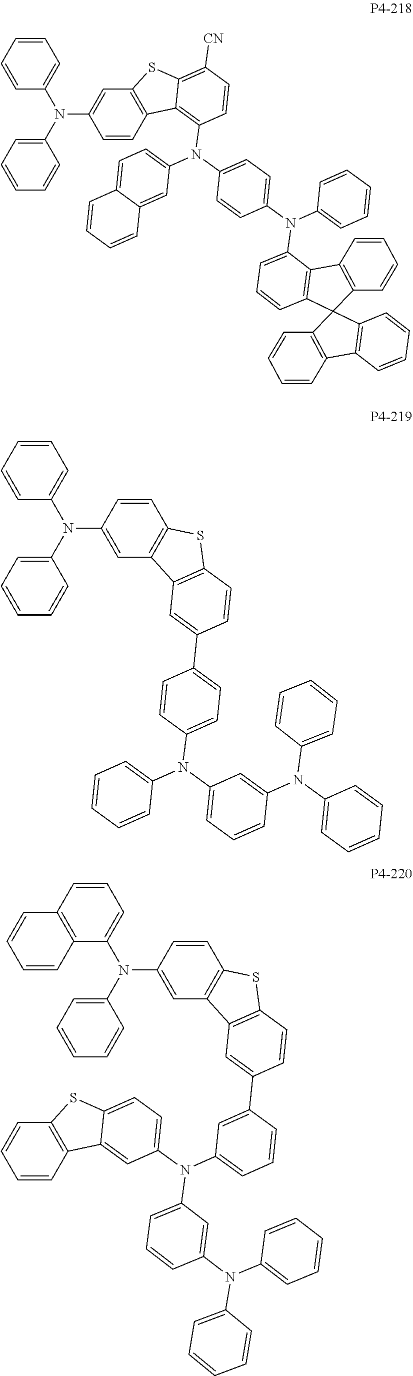 [SMILES: N#Cc1ccc(N(c2ccc(N(c3ccccc3)c3cccc4c3-c3ccccc3C43c4ccccc4-c4ccccc43)cc2)c2ccc3ccccc3c2)c2c1sc1cc(N(c3ccccc3)c3ccccc3)ccc12 ; c1ccc(N(c2ccccc2)c2cccc(N(c3ccccc3)c3ccc(-c4ccc5sc6ccc(N(c7ccccc7)c7ccccc7)cc6c5c4)cc3)c2)cc1 ; c1ccc(N(c2ccccc2)c2cccc(N(c3cccc(-c4ccc5sc6ccc(N(c7ccccc7)c7cccc8ccccc78)cc6c5c4)c3)c3ccc4sc5ccccc5c4c3)c2)cc1]

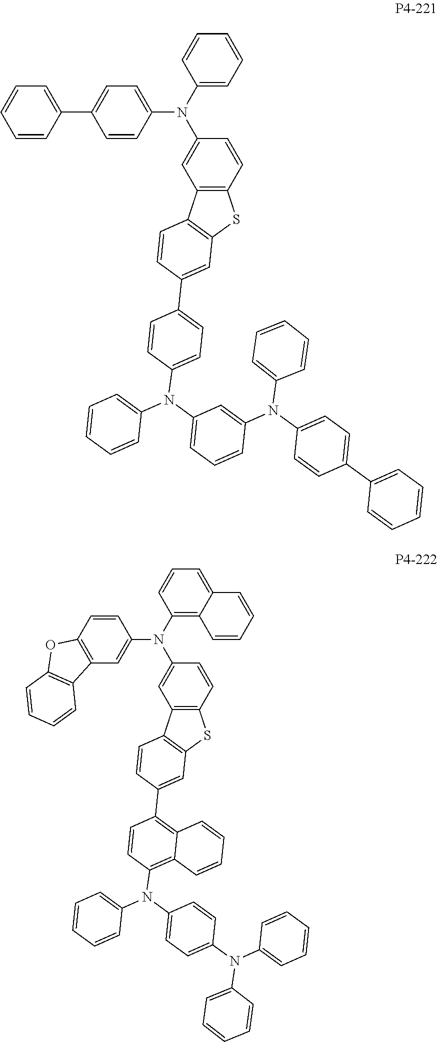 [SMILES: c1ccc(-c2ccc(N(c3ccccc3)c3cccc(N(c4ccccc4)c4ccc(-c5ccc6c(c5)sc5ccc(N(c7ccccc7)c7ccc(-c8ccccc8)cc7)cc56)cc4)c3)cc2)cc1 ; c1ccc(N(c2ccccc2)c2ccc(N(c3ccccc3)c3ccc(-c4ccc5c(c4)sc4ccc(N(c6ccc7oc8ccccc8c7c6)c6cccc7ccccc67)cc45)c4ccccc34)cc2)cc1]

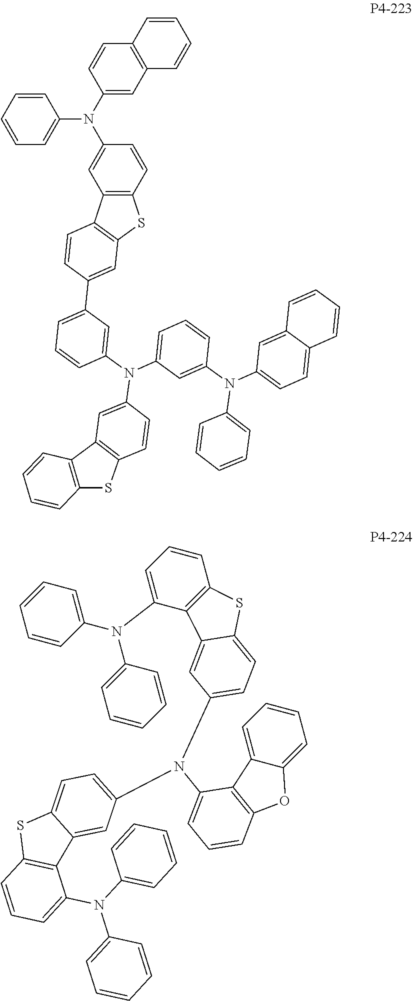 [SMILES: c1ccc(N(c2cccc(N(c3cccc(-c4ccc5c(c4)sc4ccc(N(c6ccccc6)c6ccc7ccccc7c6)cc45)c3)c3ccc4sc5ccccc5c4c3)c2)c2ccc3ccccc3c2)cc1 ; c1ccc(N(c2ccccc2)c2cccc3sc4ccc(N(c5ccc6sc7cccc(N(c8ccccc8)c8ccccc8)c7c6c5)c5cccc6oc7ccccc7c56)cc4c23)cc1]

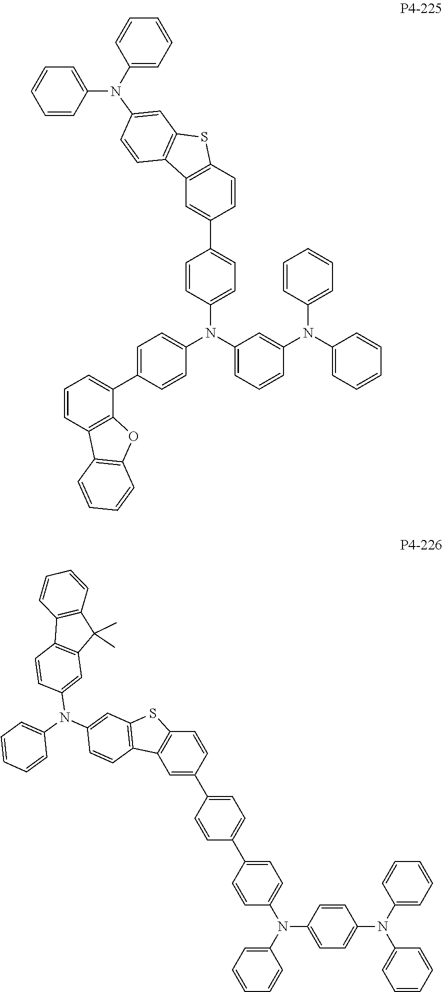 [SMILES: c1ccc(N(c2ccccc2)c2cccc(N(c3ccc(-c4ccc5sc6cc(N(c7ccccc7)c7ccccc7)ccc6c5c4)cc3)c3ccc(-c4cccc5c4oc4ccccc45)cc3)c2)cc1 ; CC1(C)c2ccccc2-c2ccc(N(c3ccccc3)c3ccc4c(c3)sc3ccc(-c5ccc(-c6ccc(N(c7ccccc7)c7ccc(N(c8ccccc8)c8ccccc8)cc7)cc6)cc5)cc34)cc21]

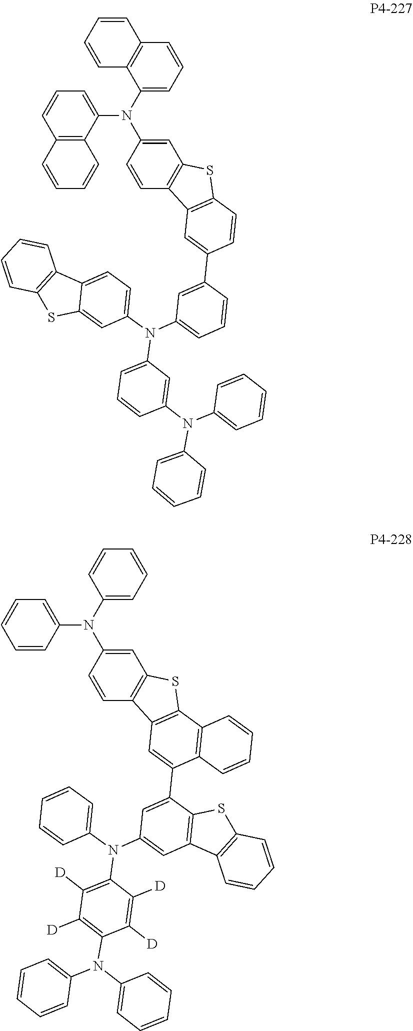 [SMILES: c1ccc(N(c2ccccc2)c2cccc(N(c3cccc(-c4ccc5sc6cc(N(c7cccc8ccccc78)c7cccc8ccccc78)ccc6c5c4)c3)c3ccc4c(c3)sc3ccccc34)c2)cc1 ; [2H]c1c([2H])c(N(c2ccccc2)c2cc(-c3cc4c5ccc(N(c6ccccc6)c6ccccc6)cc5sc4c4ccccc34)c3sc4ccccc4c3c2)c([2H])c([2H])c1N(c1ccccc1)c1ccccc1]

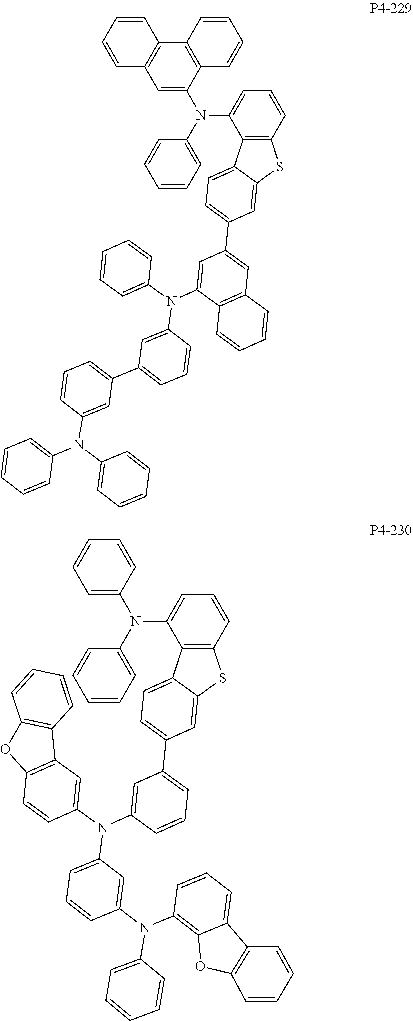

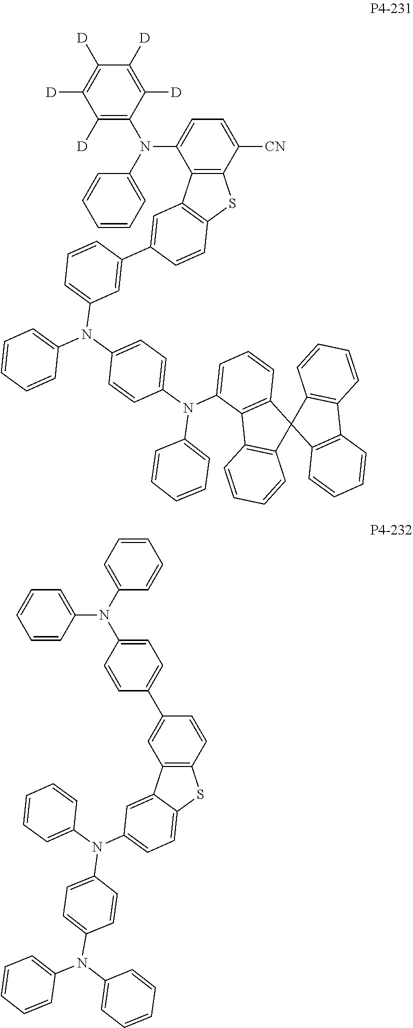 [SMILES: [2H]c1c([2H])c([2H])c(N(c2ccccc2)c2ccc(C#N)c3sc4ccc(-c5cccc(N(c6ccccc6)c6ccc(N(c7ccccc7)c7cccc8c7-c7ccccc7C87c8ccccc8-c8ccccc87)cc6)c5)cc4c23)c([2H])c1[2H] ; c1ccc(N(c2ccccc2)c2ccc(-c3ccc4sc5ccc(N(c6ccccc6)c6ccc(N(c7ccccc7)c7ccccc7)cc6)cc5c4c3)cc2)cc1]

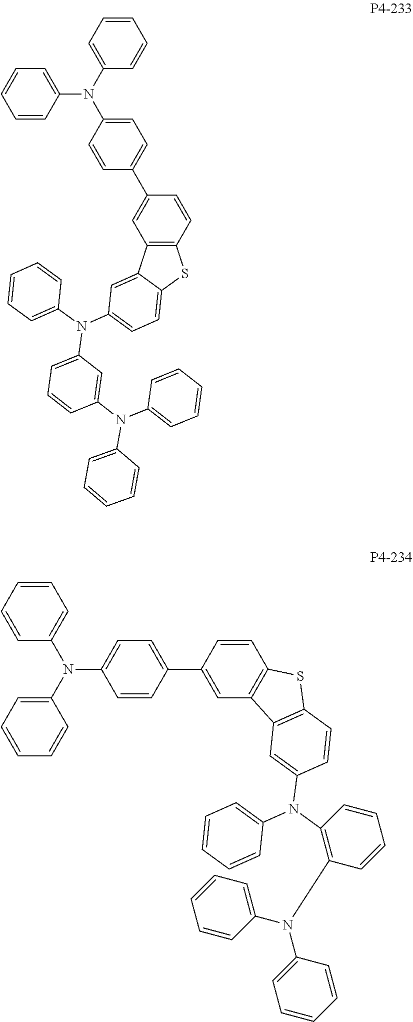 [SMILES: c1ccc(N(c2ccccc2)c2ccc(-c3ccc4sc5ccc(N(c6ccccc6)c6cccc(N(c7ccccc7)c7ccccc7)c6)cc5c4c3)cc2)cc1 ; c1ccc(N(c2ccccc2)c2ccc(-c3ccc4sc5ccc(N(c6ccccc6)c6ccccc6N(c6ccccc6)c6ccccc6)cc5c4c3)cc2)cc1]

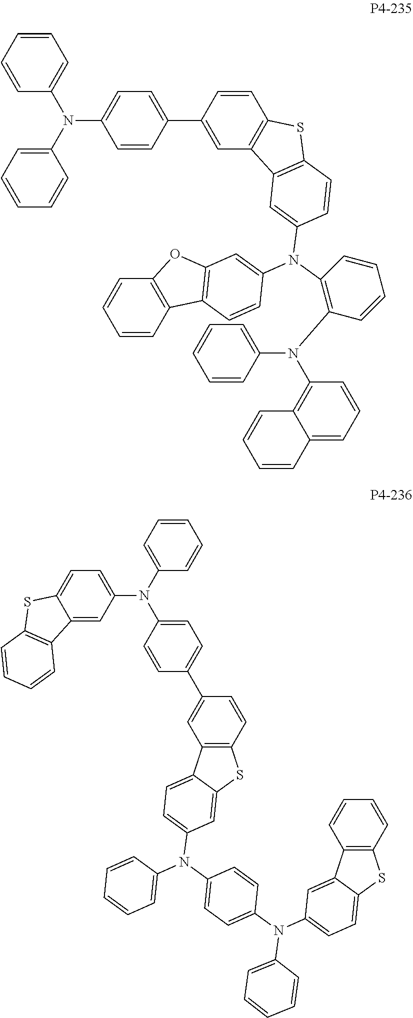 [SMILES: c1ccc(N(c2ccccc2)c2ccc(-c3ccc4sc5ccc(N(c6ccc7c(c6)oc6ccccc67)c6ccccc6N(c6ccccc6)c6cccc7ccccc67)cc5c4c3)cc2)cc1 ; c1ccc(N(c2ccc(N(c3ccccc3)c3ccc4sc5ccccc5c4c3)cc2)c2ccc3c(c2)sc2ccc(-c4ccc(N(c5ccccc5)c5ccc6sc7ccccc7c6c5)cc4)cc23)cc1]

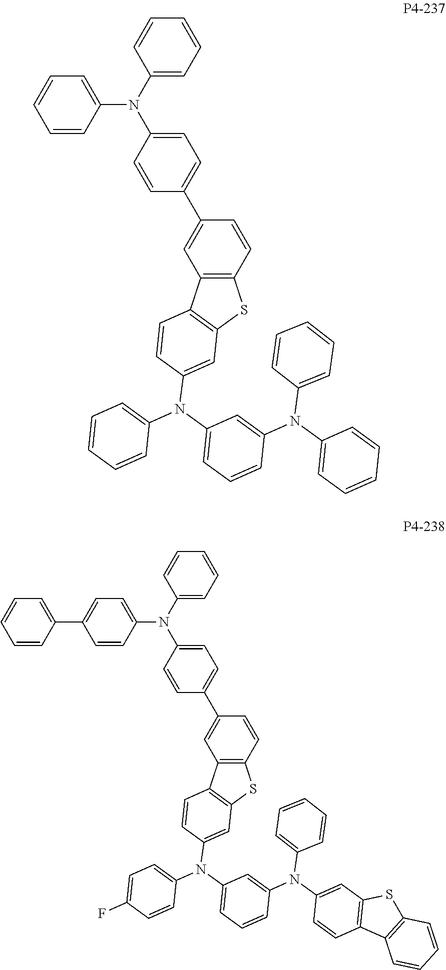 [SMILES: c1ccc(N(c2ccccc2)c2ccc(-c3ccc4sc5cc(N(c6ccccc6)c6cccc(N(c7ccccc7)c7ccccc7)c6)ccc5c4c3)cc2)cc1 ; Fc1ccc(N(c2cccc(N(c3ccccc3)c3ccc4c(c3)sc3ccccc34)c2)c2ccc3c(c2)sc2ccc(-c4ccc(N(c5ccccc5)c5ccc(-c6ccccc6)cc5)cc4)cc23)cc1]

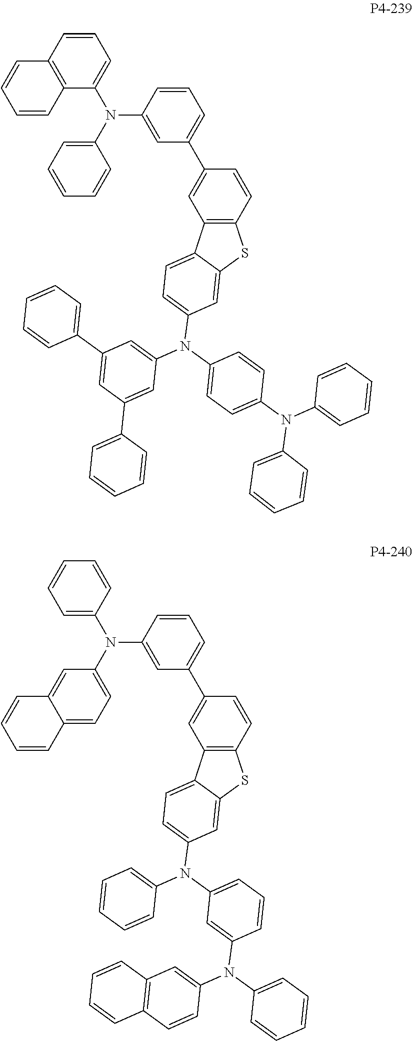 [SMILES: c1ccc(-c2cc(-c3ccccc3)cc(N(c3ccc(N(c4ccccc4)c4ccccc4)cc3)c3ccc4c(c3)sc3ccc(-c5cccc(N(c6ccccc6)c6cccc7ccccc67)c5)cc34)c2)cc1 ; c1ccc(N(c2cccc(-c3ccc4sc5cc(N(c6ccccc6)c6cccc(N(c7ccccc7)c7ccc8ccccc8c7)c6)ccc5c4c3)c2)c2ccc3ccccc3c2)cc1]

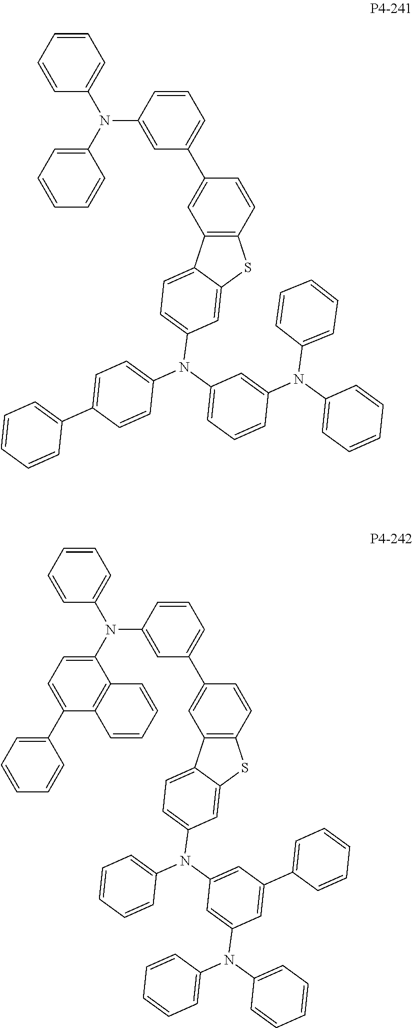 [SMILES: c1ccc(-c2ccc(N(c3cccc(N(c4ccccc4)c4ccccc4)c3)c3ccc4c(c3)sc3ccc(-c5cccc(N(c6ccccc6)c6ccccc6)c5)cc34)cc2)cc1 ; c1ccc(-c2cc(N(c3ccccc3)c3ccccc3)cc(N(c3ccccc3)c3ccc4c(c3)sc3ccc(-c5cccc(N(c6ccccc6)c6ccc(-c7ccccc7)c7ccccc67)c5)cc34)c2)cc1]

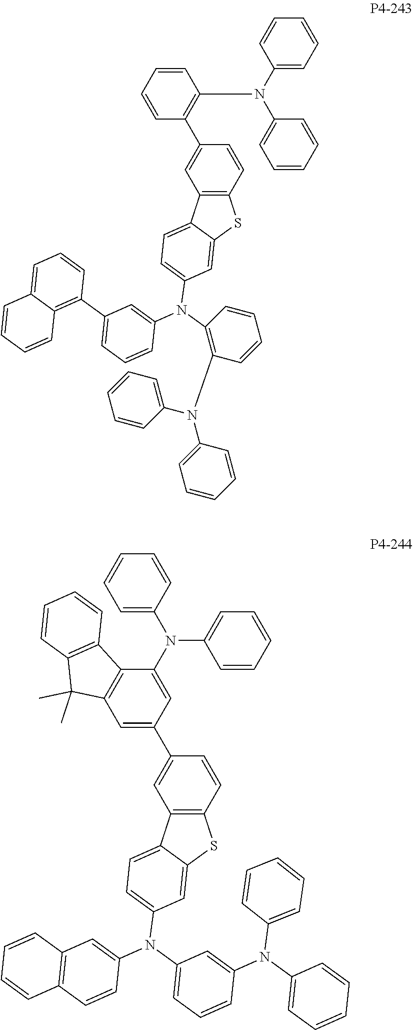 [SMILES: c1ccc(N(c2ccccc2)c2ccccc2-c2ccc3sc4cc(N(c5cccc(-c6cccc7ccccc67)c5)c5ccccc5N(c5ccccc5)c5ccccc5)ccc4c3c2)cc1 ; CC1(C)c2ccccc2-c2c(N(c3ccccc3)c3ccccc3)cc(-c3ccc4sc5cc(N(c6cccc(N(c7ccccc7)c7ccccc7)c6)c6ccc7ccccc7c6)ccc5c4c3)cc21]

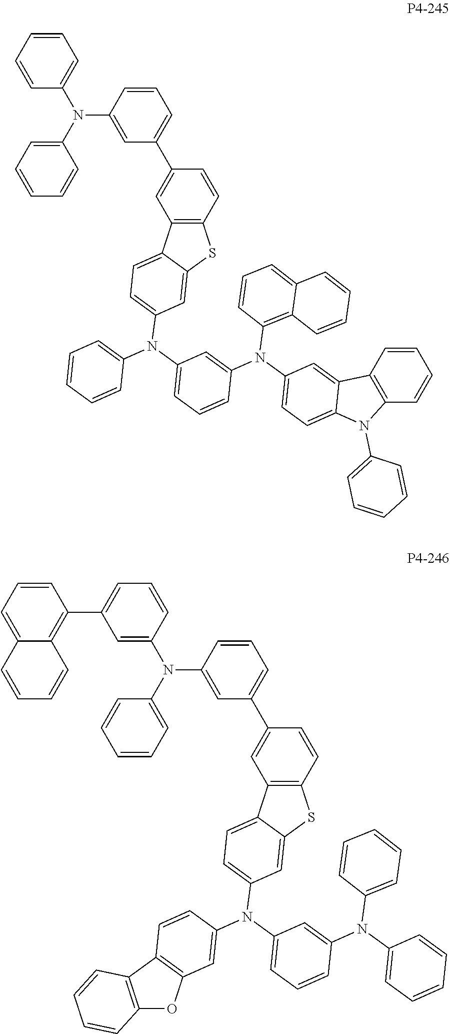 [SMILES: c1ccc(N(c2ccccc2)c2cccc(-c3ccc4sc5cc(N(c6ccccc6)c6cccc(N(c7ccc8c(c7)c7ccccc7n8-c7ccccc7)c7cccc8ccccc78)c6)ccc5c4c3)c2)cc1 ; c1ccc(N(c2cccc(-c3ccc4sc5cc(N(c6cccc(N(c7ccccc7)c7ccccc7)c6)c6ccc7c(c6)oc6ccccc67)ccc5c4c3)c2)c2cccc(-c3cccc4ccccc34)c2)cc1]

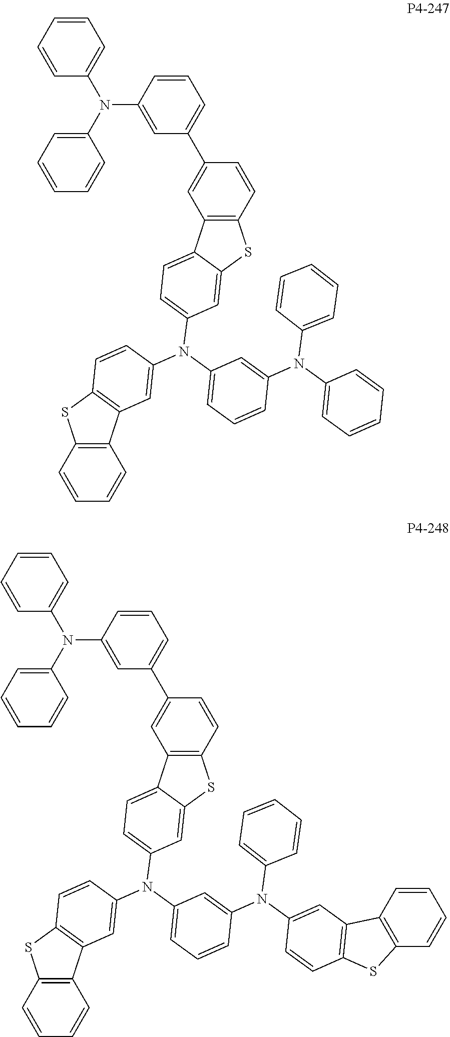 [SMILES: c1ccc(N(c2ccccc2)c2cccc(-c3ccc4sc5cc(N(c6cccc(N(c7ccccc7)c7ccccc7)c6)c6ccc7sc8ccccc8c7c6)ccc5c4c3)c2)cc1 ; c1ccc(N(c2ccccc2)c2cccc(-c3ccc4sc5cc(N(c6cccc(N(c7ccccc7)c7ccc8sc9ccccc9c8c7)c6)c6ccc7sc8ccccc8c7c6)ccc5c4c3)c2)cc1]

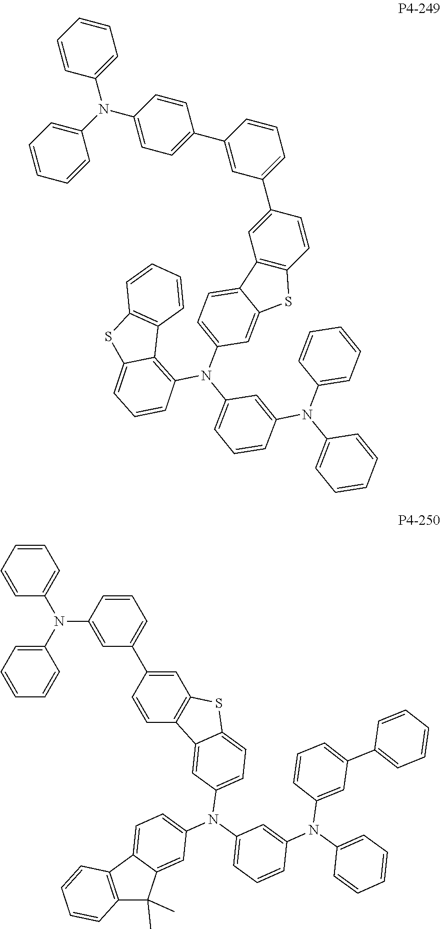 [SMILES: c1ccc(N(c2ccccc2)c2ccc(-c3cccc(-c4ccc5sc6cc(N(c7cccc(N(c8ccccc8)c8ccccc8)c7)c7cccc8sc9ccccc9c78)ccc6c5c4)c3)cc2)cc1 ; CC1(C)c2ccccc2-c2ccc(N(c3cccc(N(c4ccccc4)c4cccc(-c5ccccc5)c4)c3)c3ccc4sc5cc(-c6cccc(N(c7ccccc7)c7ccccc7)c6)ccc5c4c3)cc21]

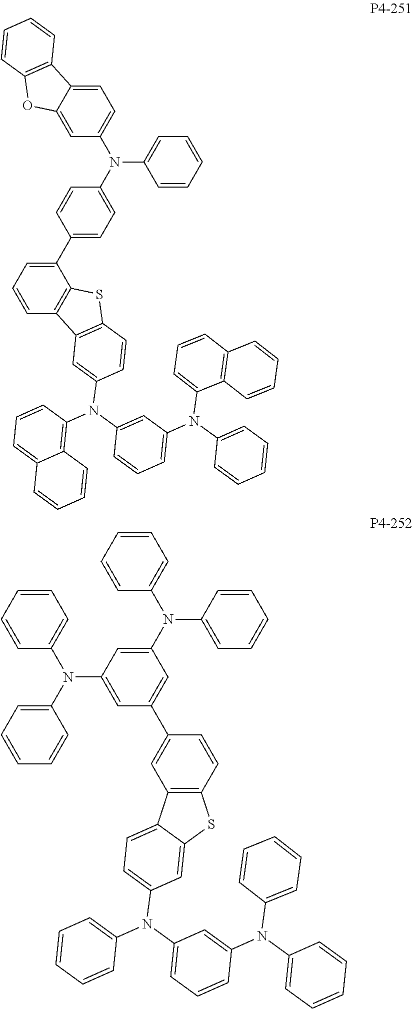 [SMILES: c1ccc(N(c2ccc(-c3cccc4c3sc3ccc(N(c5cccc(N(c6ccccc6)c6cccc7ccccc67)c5)c5cccc6ccccc56)cc34)cc2)c2ccc3c(c2)oc2ccccc23)cc1 ; c1ccc(N(c2ccccc2)c2cccc(N(c3ccccc3)c3ccc4c(c3)sc3ccc(-c5cc(N(c6ccccc6)c6ccccc6)cc(N(c6ccccc6)c6ccccc6)c5)cc34)c2)cc1]

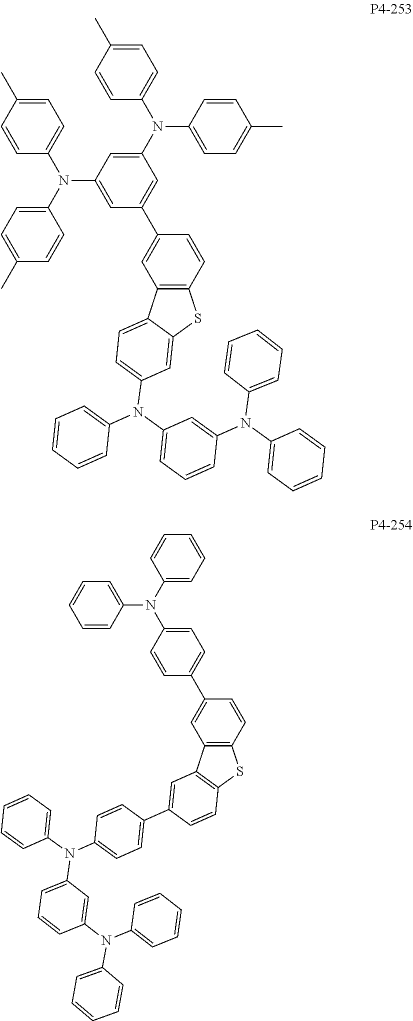 [SMILES: Cc1ccc(N(c2ccc(C)cc2)c2cc(-c3ccc4sc5cc(N(c6ccccc6)c6cccc(N(c7ccccc7)c7ccccc7)c6)ccc5c4c3)cc(N(c3ccc(C)cc3)c3ccc(C)cc3)c2)cc1 ; c1ccc(N(c2ccccc2)c2ccc(-c3ccc4sc5ccc(-c6ccc(N(c7ccccc7)c7cccc(N(c8ccccc8)c8ccccc8)c7)cc6)cc5c4c3)cc2)cc1]

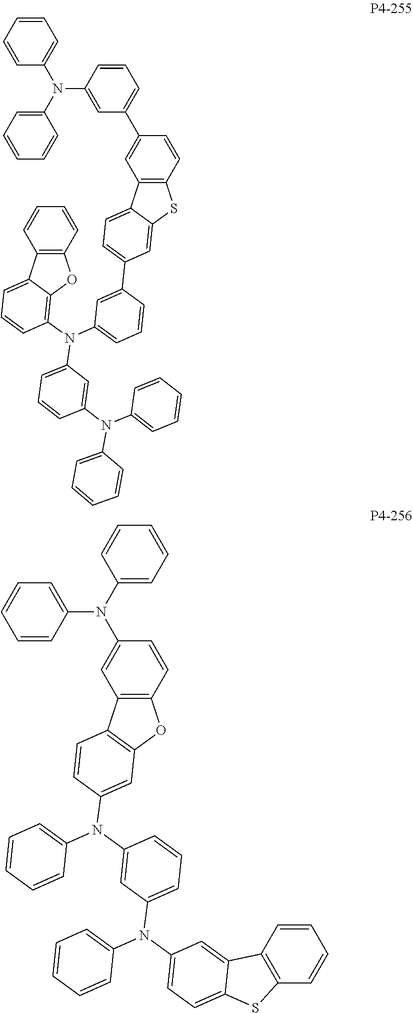

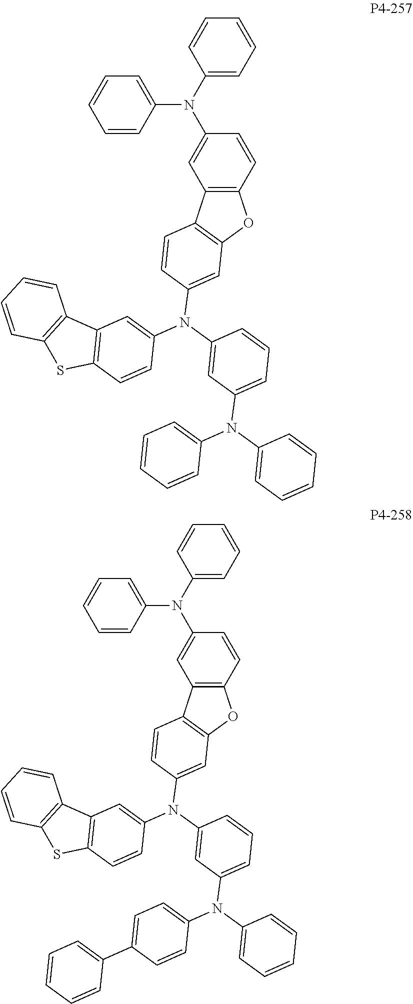 [SMILES: c1ccc(N(c2ccccc2)c2cccc(N(c3ccc4c(c3)oc3ccc(N(c5ccccc5)c5ccccc5)cc34)c3ccc4sc5ccccc5c4c3)c2)cc1 ; c1ccc(-c2ccc(N(c3ccccc3)c3cccc(N(c4ccc5c(c4)oc4ccc(N(c6ccccc6)c6ccccc6)cc45)c4ccc5sc6ccccc6c5c4)c3)cc2)cc1]

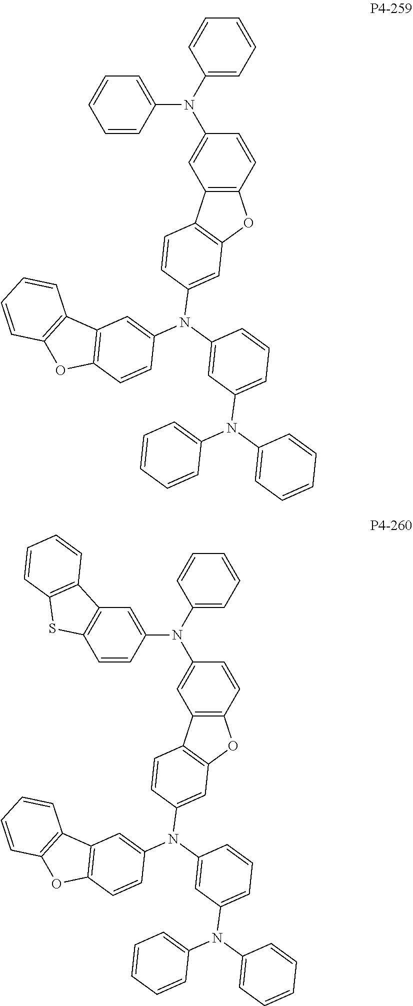 [SMILES: c1ccc(N(c2ccccc2)c2cccc(N(c3ccc4c(c3)oc3ccc(N(c5ccccc5)c5ccccc5)cc34)c3ccc4oc5ccccc5c4c3)c2)cc1 ; c1ccc(N(c2ccccc2)c2cccc(N(c3ccc4c(c3)oc3ccc(N(c5ccccc5)c5ccc6sc7ccccc7c6c5)cc34)c3ccc4oc5ccccc5c4c3)c2)cc1]

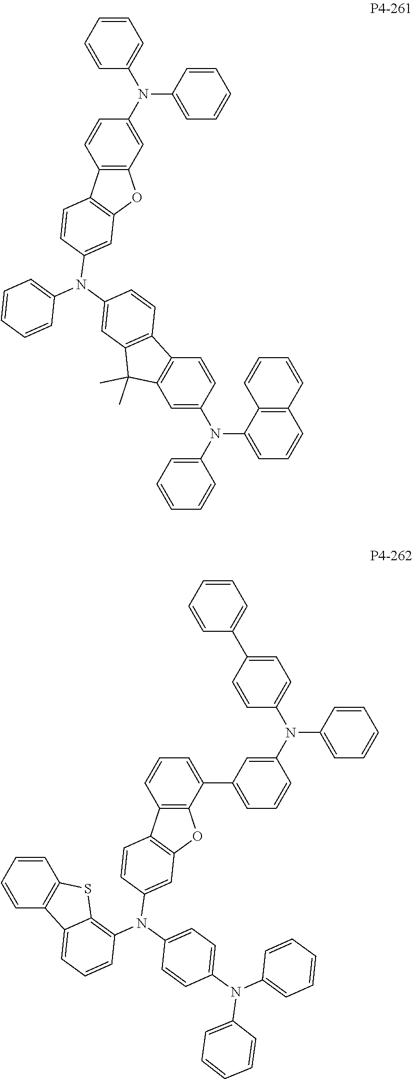 [SMILES: CC1(C)c2cc(N(c3ccccc3)c3ccc4c(c3)oc3cc(N(c5ccccc5)c5ccccc5)ccc34)ccc2-c2ccc(N(c3ccccc3)c3cccc4ccccc34)cc21 ; c1ccc(-c2ccc(N(c3ccccc3)c3cccc(-c4cccc5c4oc4cc(N(c6ccc(N(c7ccccc7)c7ccccc7)cc6)c6cccc7c6sc6ccccc67)ccc45)c3)cc2)cc1]

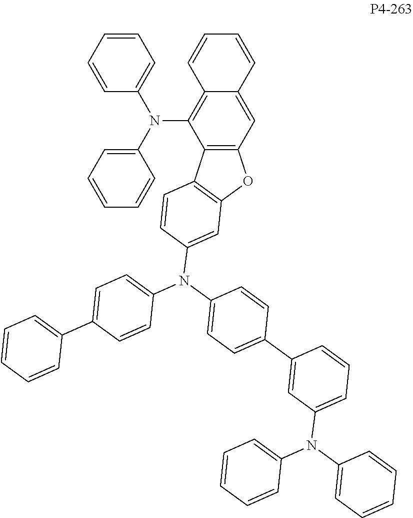 [SMILES: c1ccc(-c2ccc(N(c3ccc(-c4cccc(N(c5ccccc5)c5ccccc5)c4)cc3)c3ccc4c(c3)oc3cc5ccccc5c(N(c5ccccc5)c5ccccc5)c34)cc2)cc1]

Hereinafter, examples for synthesizing the compounds represented by Formulas 1 and 2 will be described in detail with reference to examples, but the present invention is not limited to the following examples.

### SYNTHESIS EXAMPLE

### [Synthesis Example of 1] Compound Represented by Formula 1

The compound represented by Formula 1 according to the present invention (Final product 1) was prepared by the synthesis method disclosed in Korean Patent No. 10-1786749 (registration-published on Oct. 11, 2017), Korean Patent Application No. 2014-0152779 (filed on Nov. 5, 2014) and Korea Patent Application 2014-0161275 (filed on Nov. 19, 2014) which are filed by the applicant of the present invention.

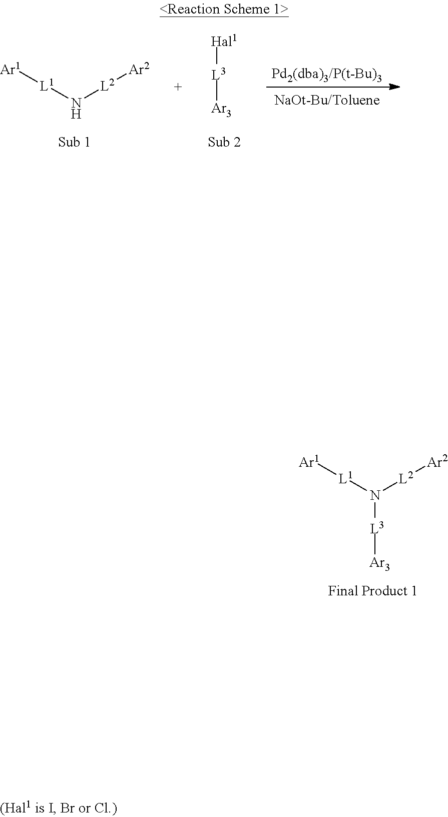

### Synthesis Example of Sub 1

Sub 1 of Reaction Scheme 1 may be synthesized by the reaction route of the following Reaction Scheme 2, but are not limited thereto.

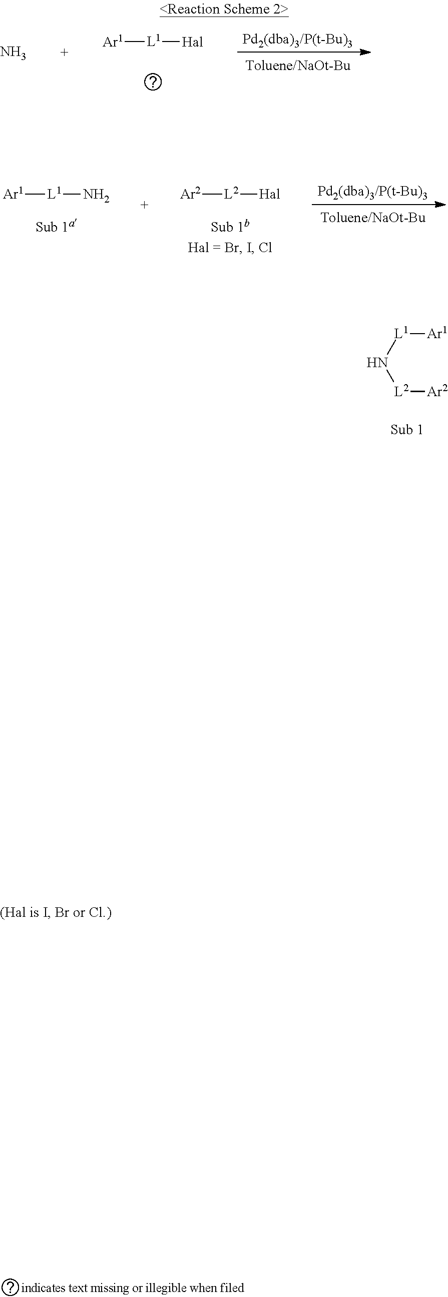

### 1. Synthesis Example of Sub 1A-58

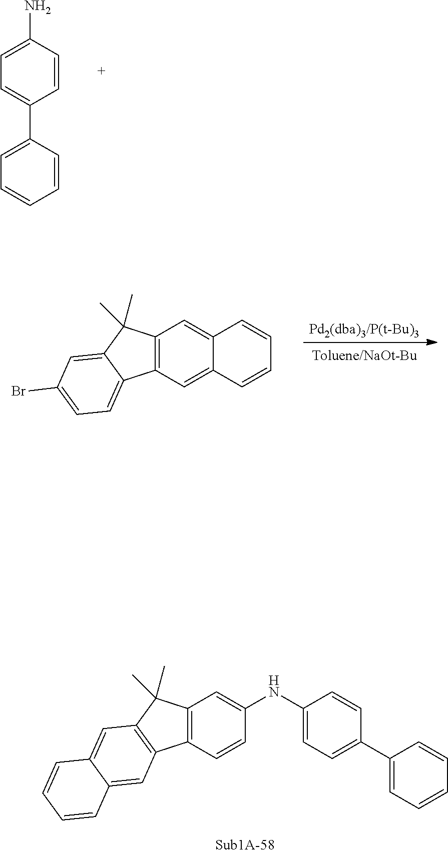 [SMILES: Nc1ccc(-c2ccccc2)cc1 ; CC1(C)c2cc(Br)ccc2-c2cc3ccccc3cc21 ; "Pd2(dba)3/P(t-Bu)3" ; "Toluene/NaOt-Bu" ; CC1(C)c2cc(Nc3ccc(-c4ccccc4)cc3)ccc2-c2cc3ccccc3cc21]

[1,1′-biphenyl]-4-amine (50 g, 295.5 mmol), 2-bromo-11,11-dimethyl-11H-benzo[b]fluorene (95.5 g, 295.5 mmol), Pd₂(dba)₃ (8.12 g, 8.9 mmol), P(t-Bu)₃ (3.59 g, 17.7 mmol), NaOt-Bu (56.8 g, 590.9 mmol) and toluene (1,477 mL) are placed in a round-bottom flask, and the reaction is carried out at 100° C. When the reaction was completed, the reaction product was extracted using CH₂Cl₂ and water. Then, an organic layer was dried over MgSO₄ and concentrated. Then, the concentrate was separated by a silica gel column and recrystallized to obtain 87.5 g (yield: 72%) of the product.

### 2. Synthesis Example of Sub 1A-59

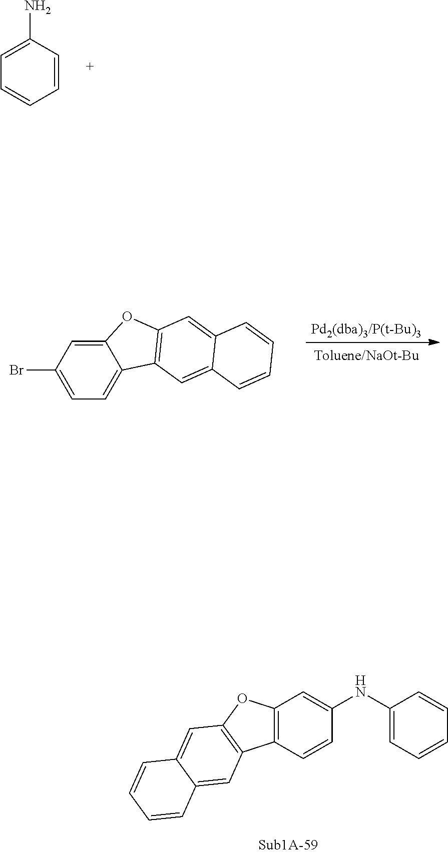 [SMILES: Nc1ccccc1 ; Brc1ccc2c(c1)oc1cc3ccccc3cc12 ; "Pd2(dba)3/P(t-Bu)3" ; "Toluene/NaOt-Bu" ; c1ccc(Nc2ccc3c(c2)oc2cc4ccccc4cc23)cc1]

Aniline (50 g, 536.9 mmol), 3-bromonaphtho[2,3-b]benzofuran (158.9 g, 536.9 mmol), Pd₂(dba)₃ (14.75 g, 16.1 mmol), P(t-Bu)₃ (6.52 g, 32.2 mmol), NaOt-Bu (103.2 g, 1,073.8 mmol) and toluene (2,684 mL) are placed in a round-bottom flask, and then the reaction was carried out in the same manner as in the synthesis method of Sub 1A-58 to obtain 129.5 g (yield: 78%) of the product.

### 3. Synthesis Example of Sub1C-18

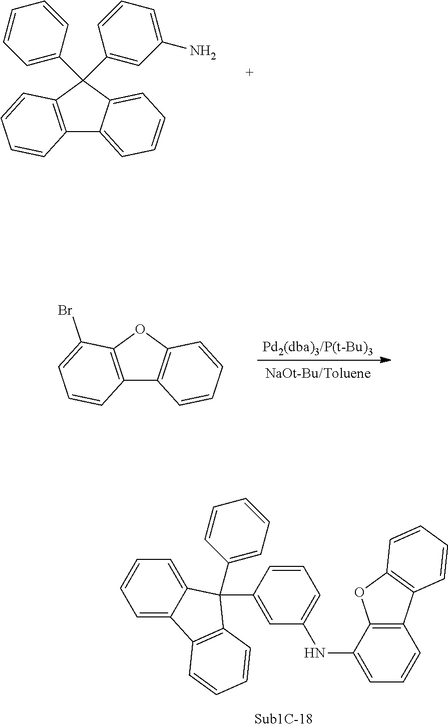 [SMILES: Nc1cccc(C2(c3ccccc3)c3ccccc3-c3ccccc32)c1 ; Brc1cccc2c1oc1ccccc12 ; "NaOt-Bu/Toluene" ; "Pd2(dba)3/P(t-Bu)3" ; c1ccc(C2(c3cccc(Nc4cccc5c4oc4ccccc45)c3)c3ccccc3-c3ccccc32)cc1]

3-(9-phenyl-9H-fluoren-9-yl)aniline (43 g, 128.96 mmol), 4-bromodibenzo[b,d]furan (33.5 g, 135.4 mmol), Pd₂(dba)₃ (3.5 g, 3.8 mmol), P(t-Bu)₃ (1.6 g, 7.7 mmol), NaOt-Bu (37.2 g, 386.9 mmol) and toluene (1,322 mL) are placed in a round-bottom flask, and then the reaction was carried out in the same manner as in the synthesis method of Sub 1A-58 to obtain 55.5 g (yield: 86.2%) of the product.

Compounds that belong to Sub 1 are as follows, but are not limited thereto, and FD-MS values of the compounds are shown in Table 1 below.

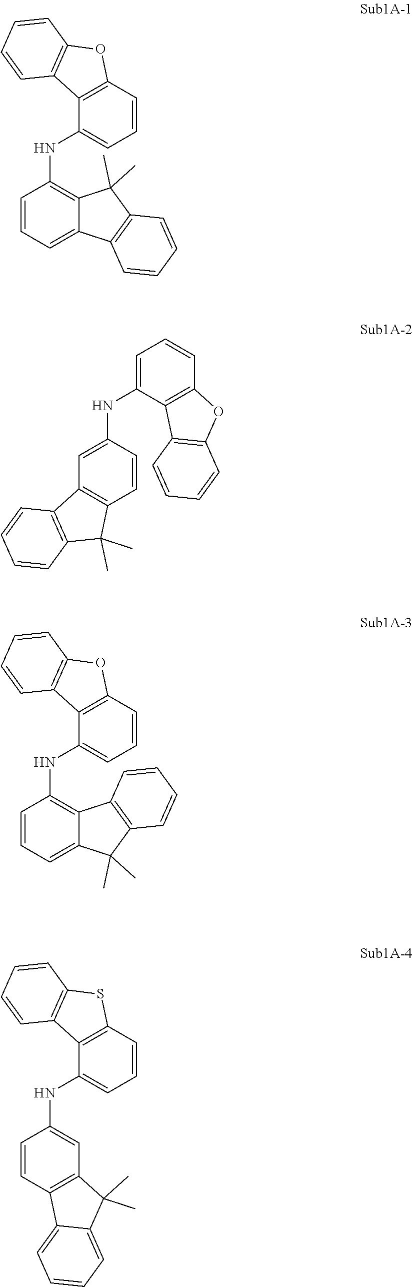 [SMILES: CC1(C)c2ccccc2-c2cccc(Nc3cccc4oc5ccccc5c34)c21 ; CC1(C)c2ccccc2-c2cc(Nc3cccc4oc5ccccc5c34)ccc21 ; CC1(C)c2ccccc2-c2c(Nc3cccc4oc5ccccc5c34)cccc21 ; CC1(C)c2ccccc2-c2ccc(Nc3cccc4sc5ccccc5c34)cc21]

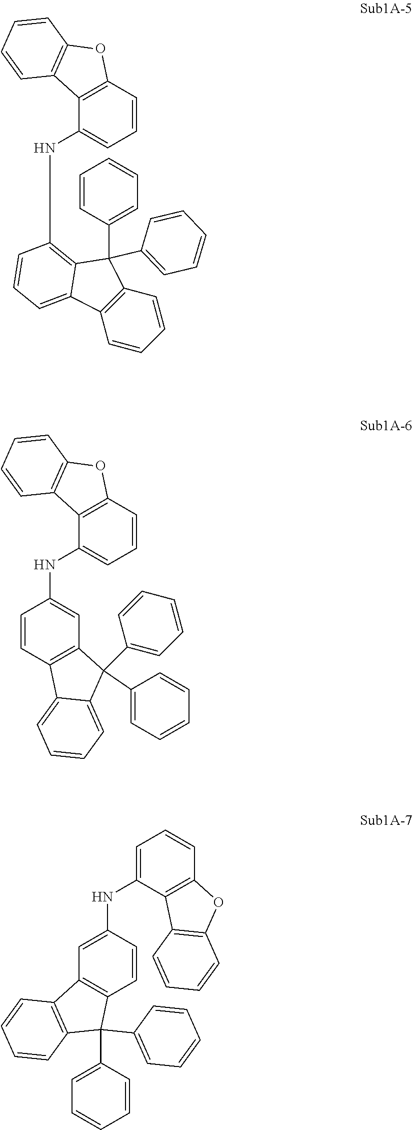 [SMILES: c1ccc(C2(c3ccccc3)c3ccccc3-c3cccc(Nc4cccc5oc6ccccc6c45)c32)cc1 ; c1ccc(C2(c3ccccc3)c3ccccc3-c3ccc(Nc4cccc5oc6ccccc6c45)cc32)cc1 ; c1ccc(C2(c3ccccc3)c3ccccc3-c3cc(Nc4cccc5oc6ccccc6c45)ccc32)cc1]

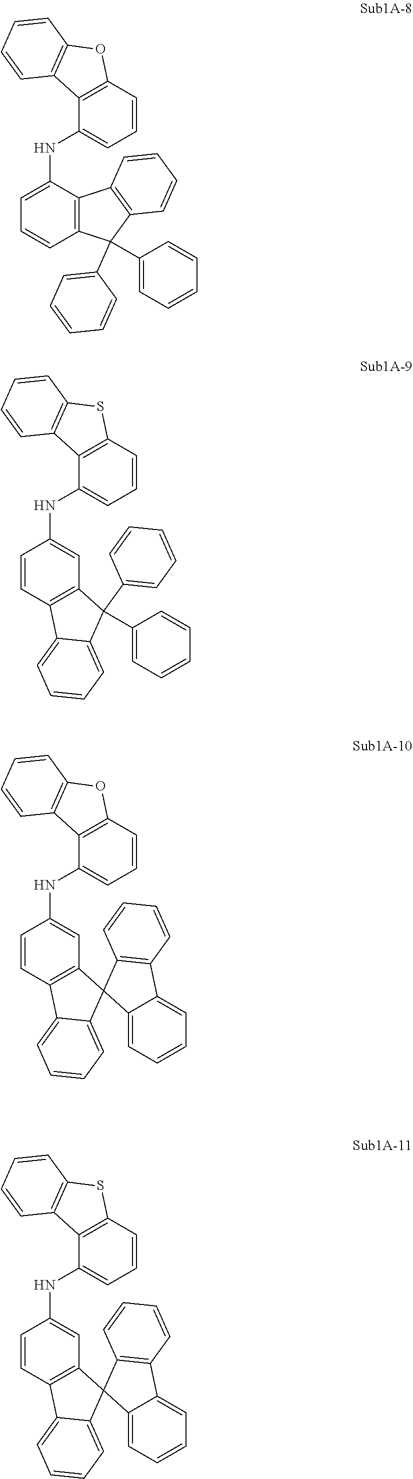 [SMILES: c1ccc(C2(c3ccccc3)c3ccccc3-c3c(Nc4cccc5oc6ccccc6c45)cccc32)cc1 ; c1ccc(C2(c3ccccc3)c3ccccc3-c3ccc(Nc4cccc5sc6ccccc6c45)cc32)cc1 ; c1ccc2c(c1)-c1ccccc1C21c2ccccc2-c2ccc(Nc3cccc4oc5ccccc5c34)cc21 ; c1ccc2c(c1)-c1ccccc1C21c2ccccc2-c2ccc(Nc3cccc4sc5ccccc5c34)cc21]

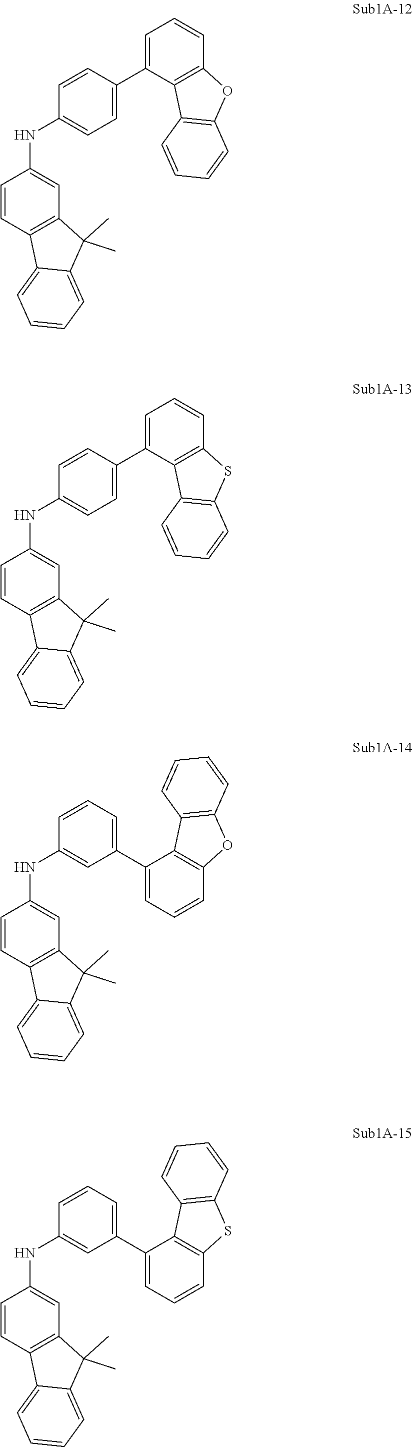 [SMILES: CC1(C)c2ccccc2-c2ccc(Nc3ccc(-c4cccc5oc6ccccc6c45)cc3)cc21 ; CC1(C)c2ccccc2-c2ccc(Nc3ccc(-c4cccc5sc6ccccc6c45)cc3)cc21 ; CC1(C)c2ccccc2-c2ccc(Nc3cccc(-c4cccc5oc6ccccc6c45)c3)cc21 ; CC1(C)c2ccccc2-c2ccc(Nc3cccc(-c4cccc5sc6ccccc6c45)c3)cc21]

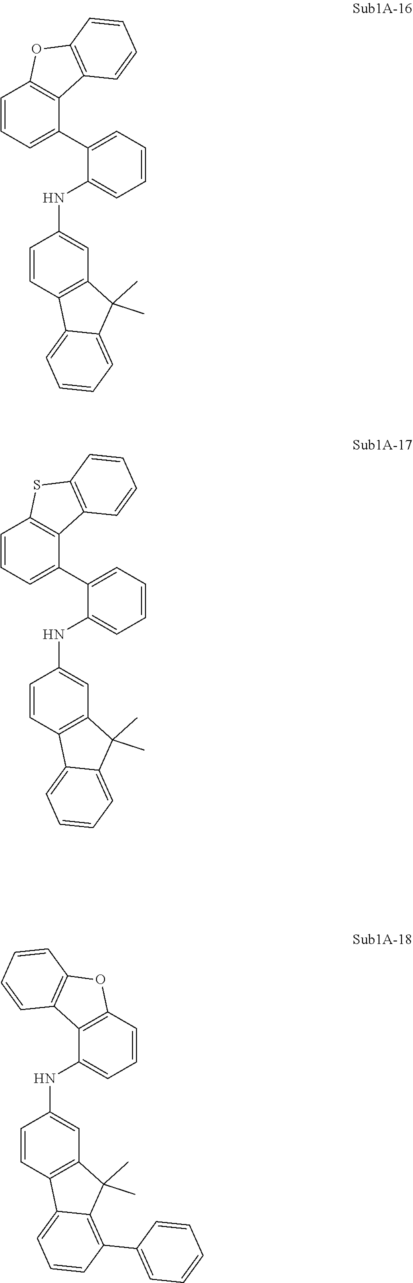 [SMILES: CC1(C)c2ccccc2-c2ccc(Nc3ccccc3-c3cccc4oc5ccccc5c34)cc21 ; CC1(C)c2ccccc2-c2ccc(Nc3ccccc3-c3cccc4sc5ccccc5c34)cc21 ; CC1(C)c2cc(Nc3cccc4oc5ccccc5c34)ccc2-c2cccc(-c3ccccc3)c21]

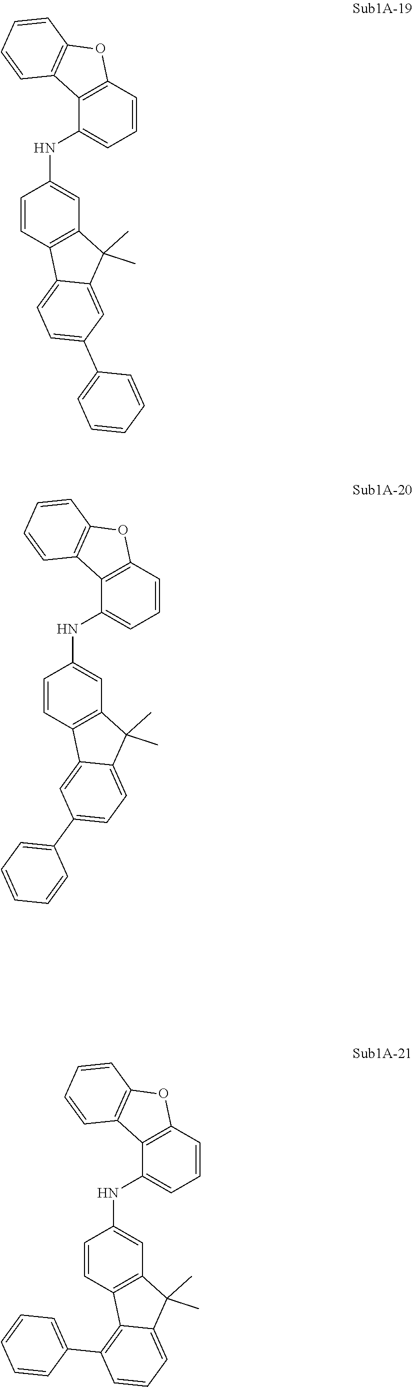 [SMILES: CC1(C)c2cc(Nc3cccc4oc5ccccc5c34)ccc2-c2ccc(-c3ccccc3)cc21 ; CC1(C)c2ccc(-c3ccccc3)cc2-c2ccc(Nc3cccc4oc5ccccc5c34)cc21 ; CC1(C)c2cc(Nc3cccc4oc5ccccc5c34)ccc2-c2c(-c3ccccc3)cccc21]

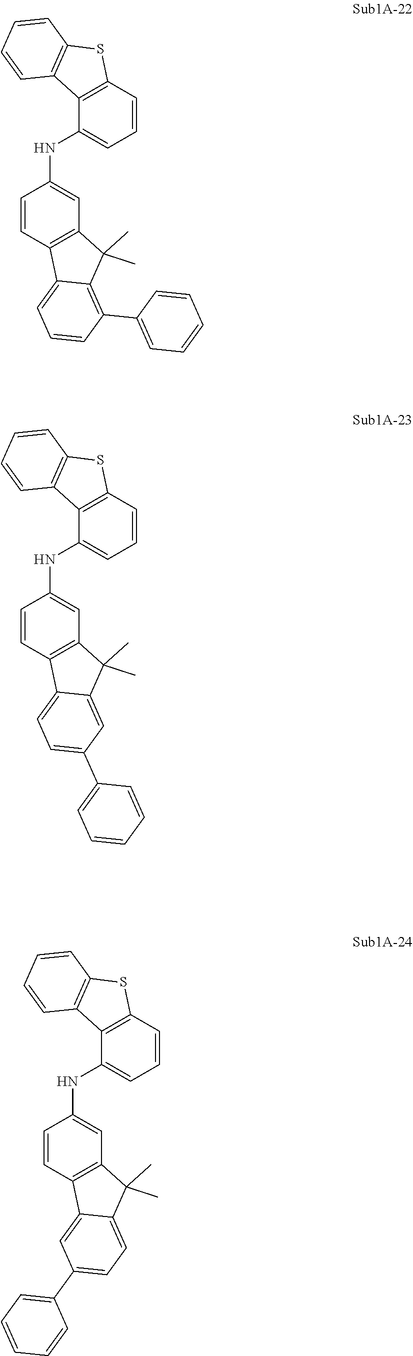 [SMILES: CC1(C)c2cc(Nc3cccc4sc5ccccc5c34)ccc2-c2cccc(-c3ccccc3)c21 ; CC1(C)c2cc(Nc3cccc4sc5ccccc5c34)ccc2-c2ccc(-c3ccccc3)cc21 ; CC1(C)c2ccc(-c3ccccc3)cc2-c2ccc(Nc3cccc4sc5ccccc5c34)cc21]

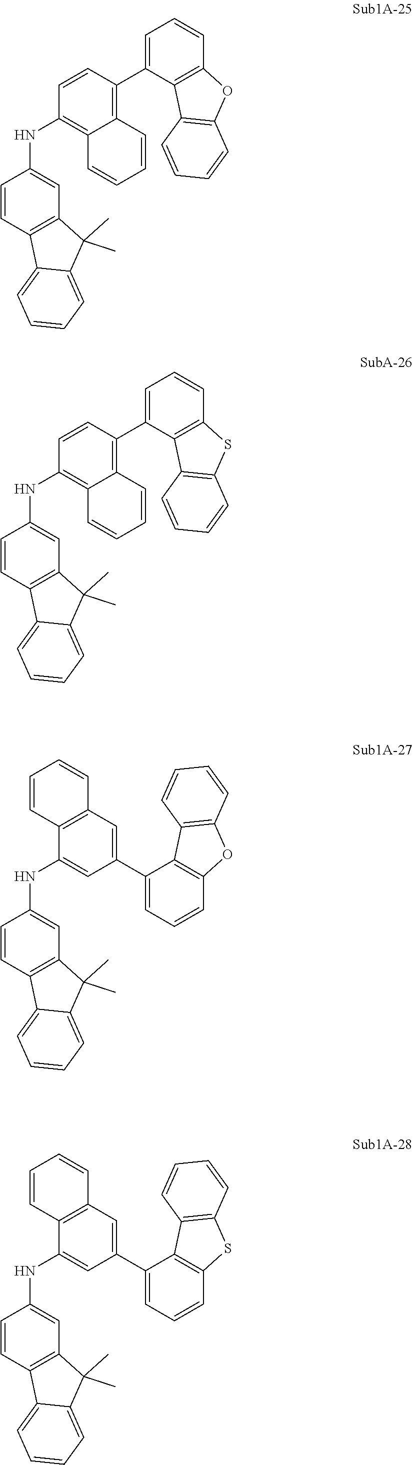 [SMILES: CC1(C)c2ccccc2-c2ccc(Nc3ccc(-c4cccc5oc6ccccc6c45)c4ccccc34)cc21 ; CC1(C)c2ccccc2-c2ccc(Nc3ccc(-c4cccc5sc6ccccc6c45)c4ccccc34)cc21 ; CC1(C)c2ccccc2-c2ccc(Nc3cc(-c4cccc5oc6ccccc6c45)cc4ccccc34)cc21 ; CC1(C)c2ccccc2-c2ccc(Nc3cc(-c4cccc5sc6ccccc6c45)cc4ccccc34)cc21]

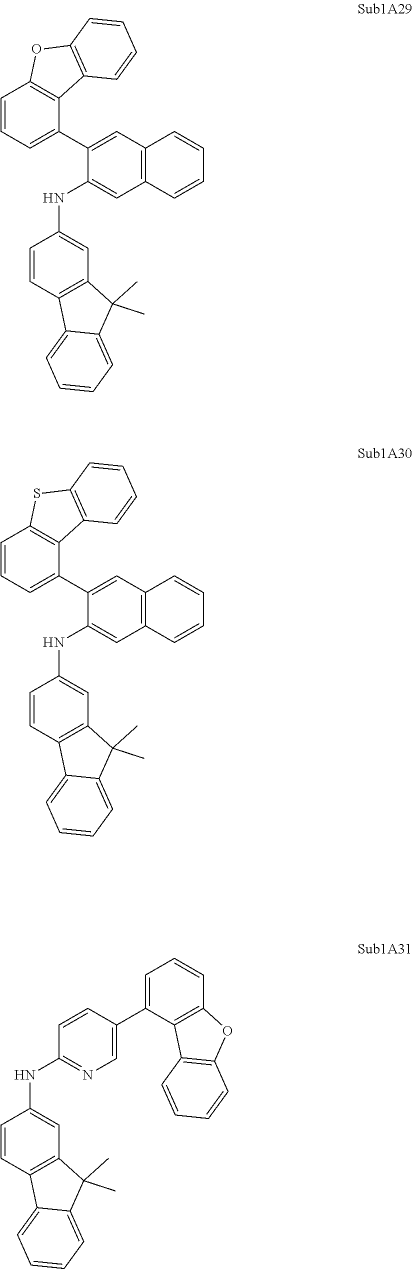 [SMILES: CC1(C)c2ccccc2-c2ccc(Nc3cc4ccccc4cc3-c3cccc4oc5ccccc5c34)cc21 ; CC1(C)c2ccccc2-c2ccc(Nc3cc4ccccc4cc3-c3cccc4sc5ccccc5c34)cc21 ; CC1(C)c2ccccc2-c2ccc(Nc3ccc(-c4cccc5oc6ccccc6c45)cn3)cc21]

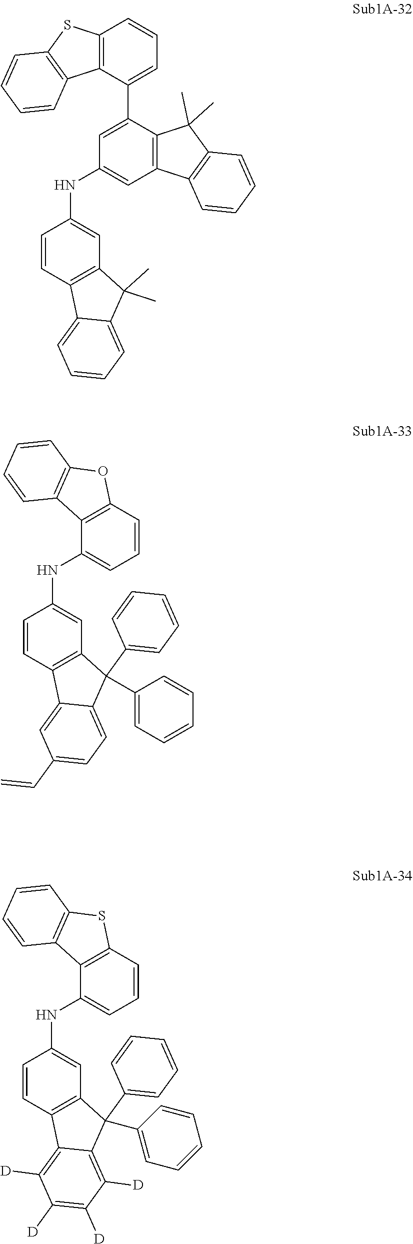 [SMILES: CC1(C)c2ccccc2-c2ccc(Nc3cc4c(c(-c5cccc6sc7ccccc7c56)c3)C(C)(C)c3ccccc3-4)cc21 ; C=Cc1ccc2c(c1)-c1ccc(Nc3cccc4oc5ccccc5c34)cc1C2(c1ccccc1)c1ccccc1 ; [2H]c1c([2H])c([2H])c2c(c1[2H])-c1ccc(Nc3cccc4sc5ccccc5c34)cc1C2(c1ccccc1)c1ccccc1]

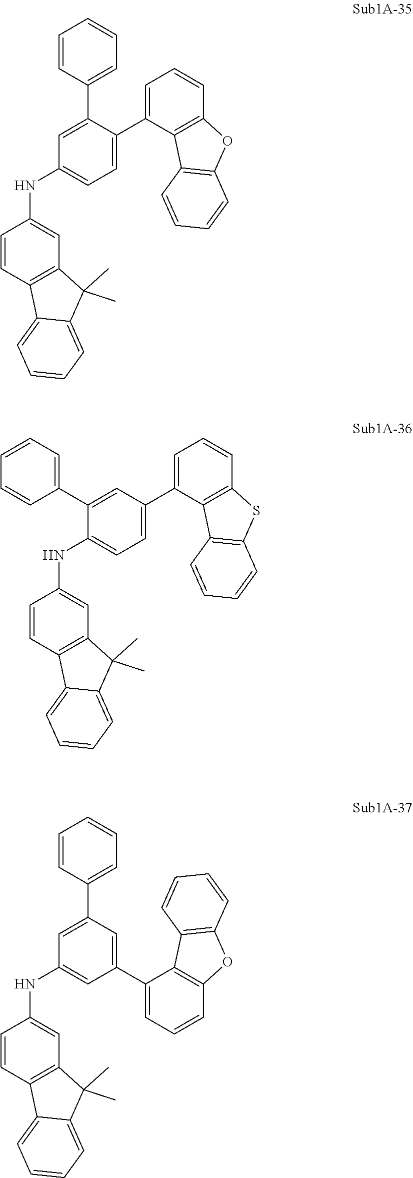 [SMILES: CC1(C)c2ccccc2-c2ccc(Nc3ccc(-c4cccc5oc6ccccc6c45)c(-c4ccccc4)c3)cc21 ; CC1(C)c2ccccc2-c2ccc(Nc3ccc(-c4cccc5sc6ccccc6c45)cc3-c3ccccc3)cc21 ; CC1(C)c2ccccc2-c2ccc(Nc3cc(-c4ccccc4)cc(-c4cccc5oc6ccccc6c45)c3)cc21]

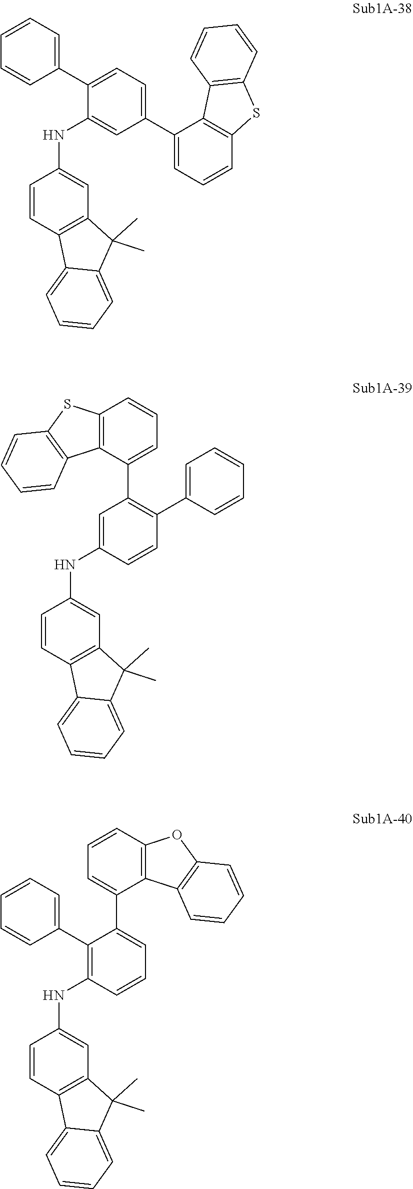 [SMILES: CC1(C)c2ccccc2-c2ccc(Nc3cc(-c4cccc5sc6ccccc6c45)ccc3-c3ccccc3)cc21 ; CC1(C)c2ccccc2-c2ccc(Nc3ccc(-c4ccccc4)c(-c4cccc5sc6ccccc6c45)c3)cc21 ; CC1(C)c2ccccc2-c2ccc(Nc3cccc(-c4cccc5oc6ccccc6c45)c3-c3ccccc3)cc21]

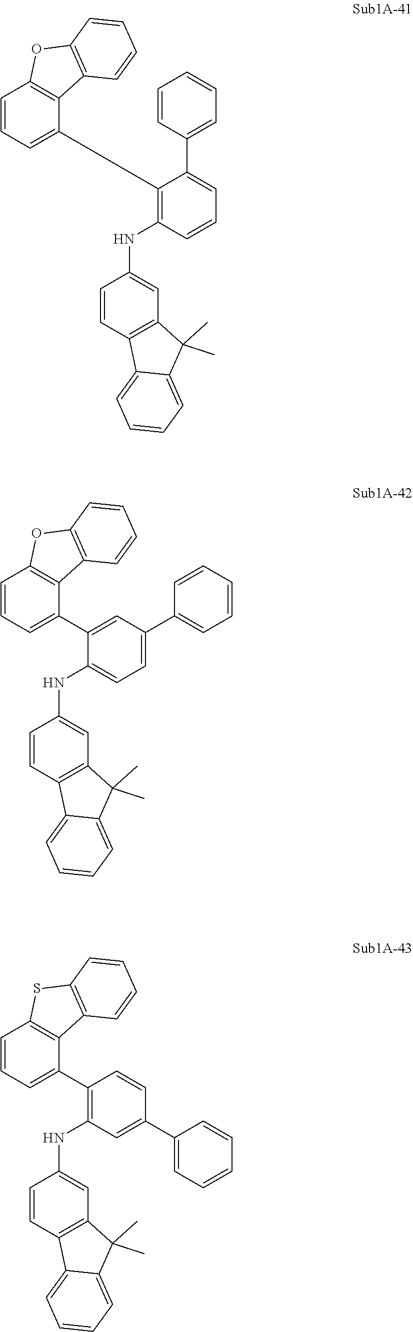 [SMILES: CC1(C)c2ccccc2-c2ccc(Nc3cccc(-c4ccccc4)c3-c3cccc4oc5ccccc5c34)cc21 ; CC1(C)c2ccccc2-c2ccc(Nc3ccc(-c4ccccc4)cc3-c3cccc4oc5ccccc5c34)cc21 ; CC1(C)c2ccccc2-c2ccc(Nc3cc(-c4ccccc4)ccc3-c3cccc4sc5ccccc5c34)cc21]

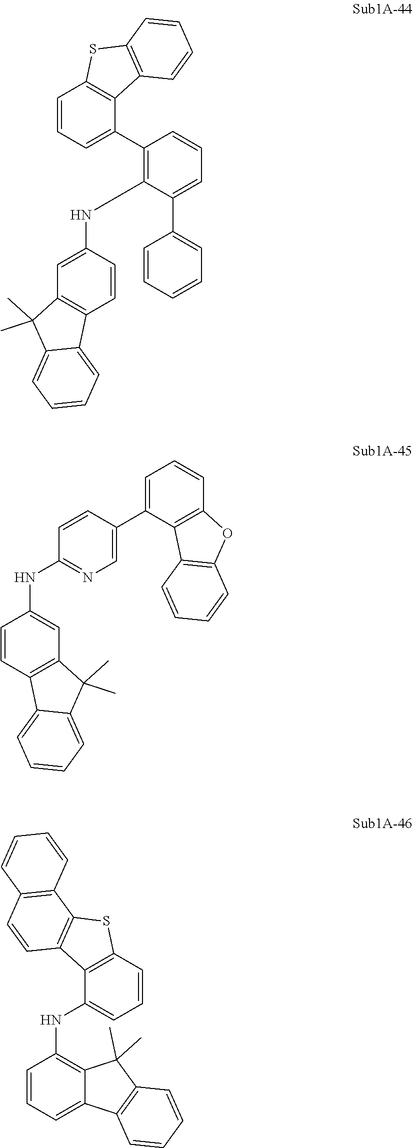 [SMILES: CC1(C)c2ccccc2-c2ccc(Nc3c(-c4ccccc4)cccc3-c3cccc4sc5ccccc5c34)cc21 ; CC1(C)c2ccccc2-c2ccc(Nc3ccc(-c4cccc5oc6ccccc6c45)cn3)cc21 ; CC1(C)c2ccccc2-c2cccc(Nc3cccc4sc5c6ccccc6ccc5c34)c21]

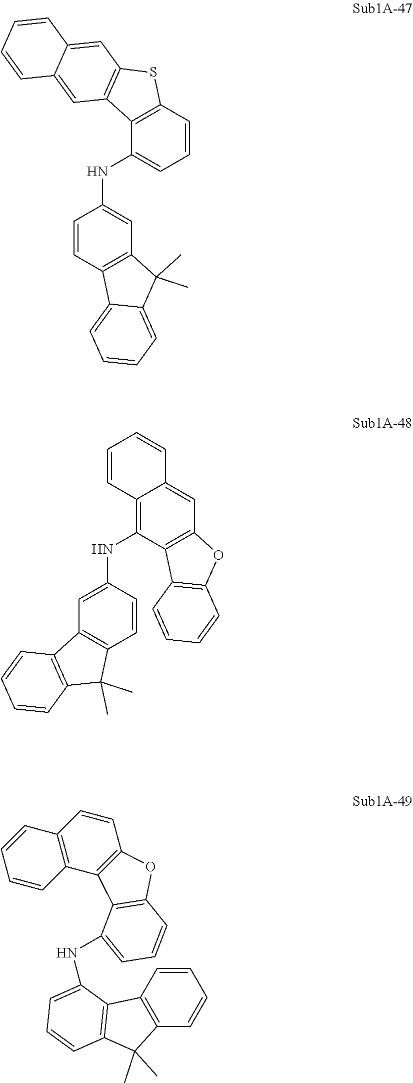 [SMILES: CC1(C)c2ccccc2-c2ccc(Nc3cccc4sc5cc6ccccc6cc5c34)cc21 ; CC1(C)c2ccccc2-c2cc(Nc3c4ccccc4cc4oc5ccccc5c34)ccc21 ; CC1(C)c2ccccc2-c2c(Nc3cccc4oc5ccc6ccccc6c5c34)cccc21]

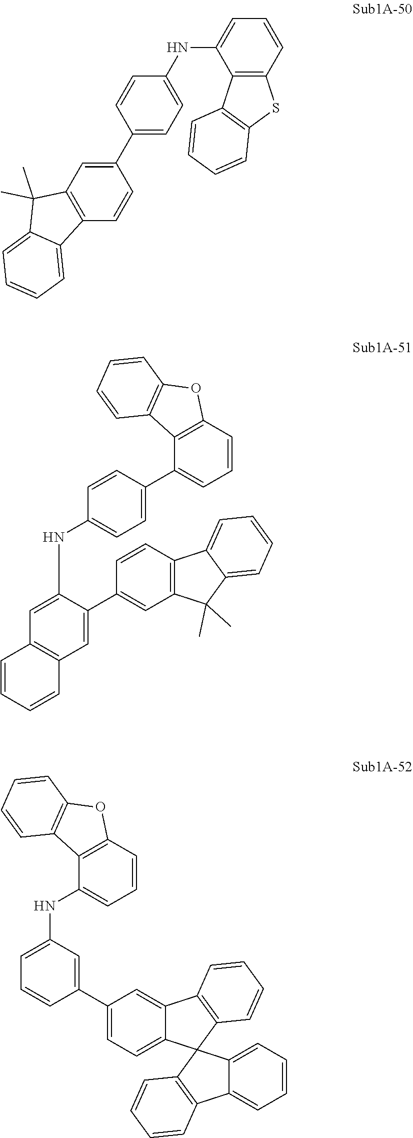 [SMILES: CC1(C)c2ccccc2-c2ccc(-c3ccc(Nc4cccc5sc6ccccc6c45)cc3)cc21 ; CC1(C)c2ccccc2-c2ccc(-c3cc4ccccc4cc3Nc3ccc(-c4cccc5oc6ccccc6c45)cc3)cc21 ; c1cc(Nc2cccc3oc4ccccc4c23)cc(-c2ccc3c(c2)-c2ccccc2C32c3ccccc3-c3ccccc32)c1]

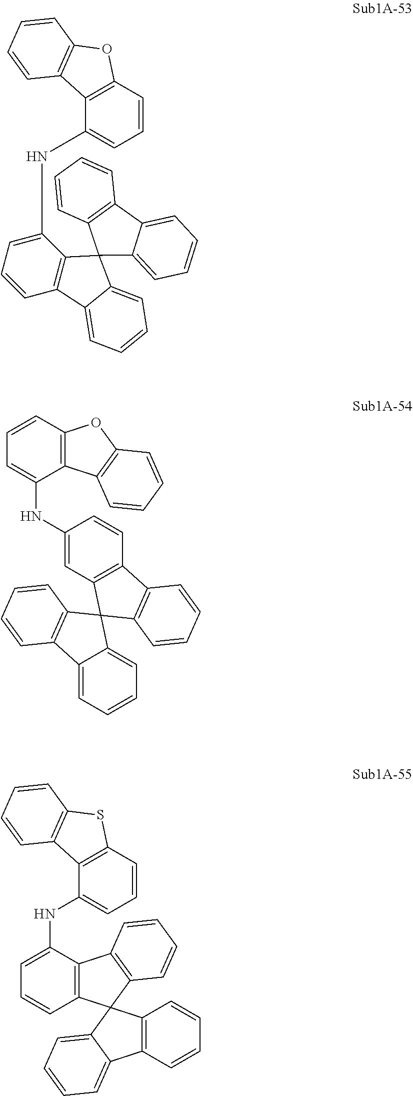 [SMILES: c1ccc2c(c1)-c1ccccc1C21c2ccccc2-c2cccc(Nc3cccc4oc5ccccc5c34)c21 ; c1ccc2c(c1)-c1ccccc1C21c2ccccc2-c2ccc(Nc3cccc4oc5ccccc5c34)cc21 ; c1ccc2c(c1)-c1ccccc1C21c2ccccc2-c2c(Nc3cccc4sc5ccccc5c34)cccc21]

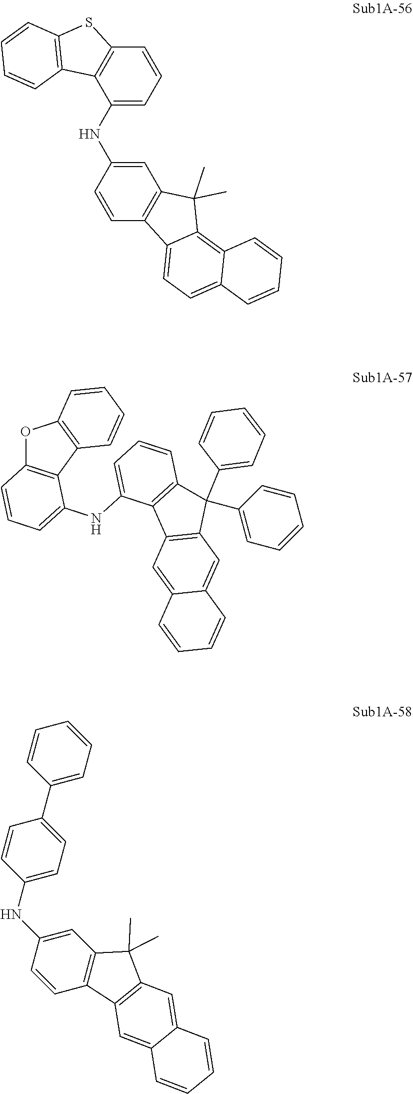 [SMILES: CC1(C)c2cc(Nc3cccc4sc5ccccc5c34)ccc2-c2ccc3ccccc3c21 ; c1ccc(C2(c3ccccc3)c3cc4ccccc4cc3-c3c(Nc4cccc5oc6ccccc6c45)cccc32)cc1 ; CC1(C)c2cc(Nc3ccc(-c4ccccc4)cc3)ccc2-c2cc3ccccc3cc21]

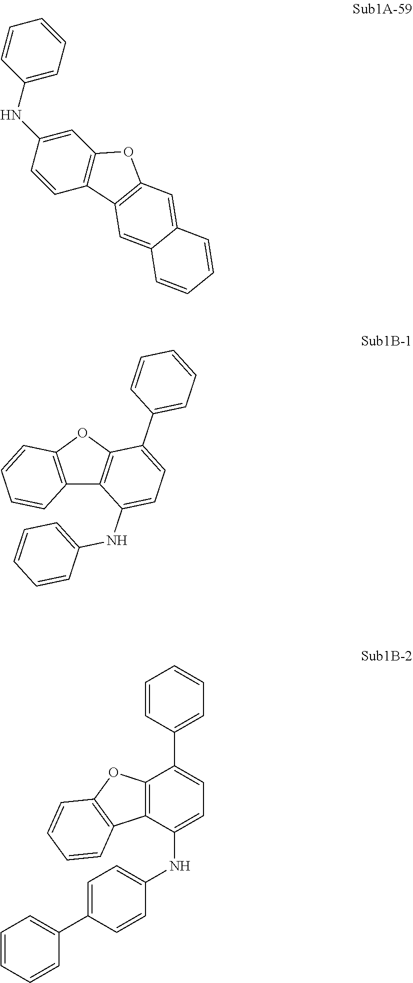 [SMILES: c1ccc(Nc2ccc3c(c2)oc2cc4ccccc4cc23)cc1 ; c1ccc(Nc2ccc(-c3ccccc3)c3oc4ccccc4c23)cc1 ; c1ccc(-c2ccc(Nc3ccc(-c4ccccc4)c4oc5ccccc5c34)cc2)cc1]

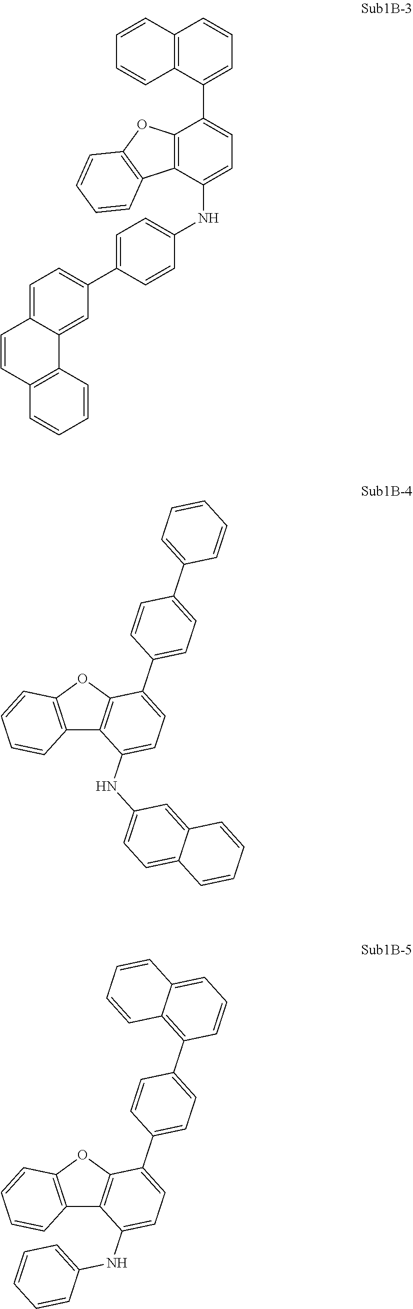 [SMILES: c1ccc2c(-c3ccc(Nc4ccc(-c5ccc6ccc7ccccc7c6c5)cc4)c4c3oc3ccccc34)cccc2c1 ; c1ccc(-c2ccc(-c3ccc(Nc4ccc5ccccc5c4)c4c3oc3ccccc34)cc2)cc1 ; c1ccc(Nc2ccc(-c3ccc(-c4cccc5ccccc45)cc3)c3oc4ccccc4c23)cc1]

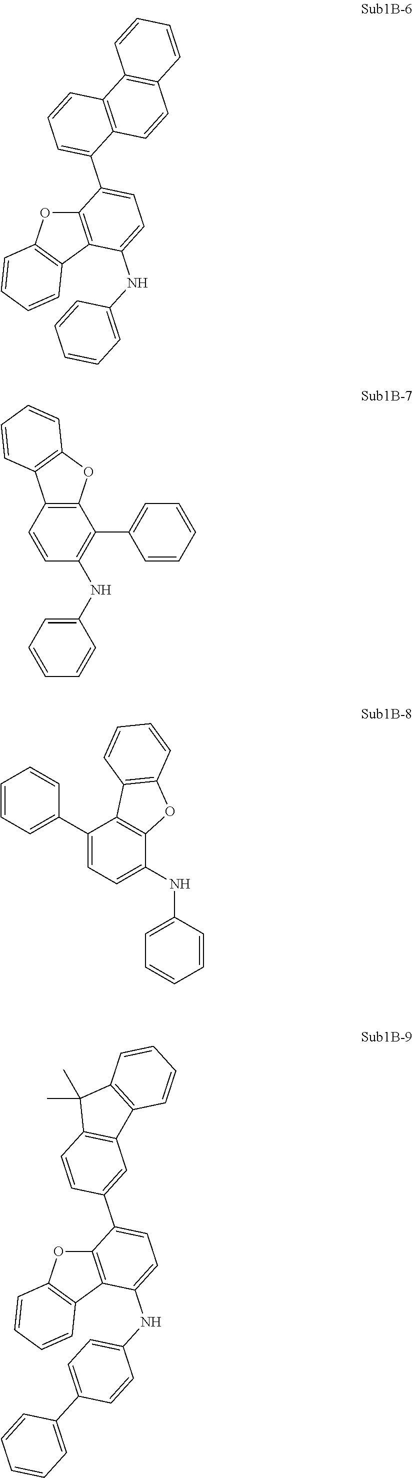 [SMILES: c1ccc(Nc2ccc(-c3cccc4c3ccc3ccccc34)c3oc4ccccc4c23)cc1 ; c1ccc(Nc2ccc3c(oc4ccccc43)c2-c2ccccc2)cc1 ; c1ccc(Nc2ccc(-c3ccccc3)c3c2oc2ccccc23)cc1 ; CC1(C)c2ccccc2-c2cc(-c3ccc(Nc4ccc(-c5ccccc5)cc4)c4c3oc3ccccc34)ccc21]

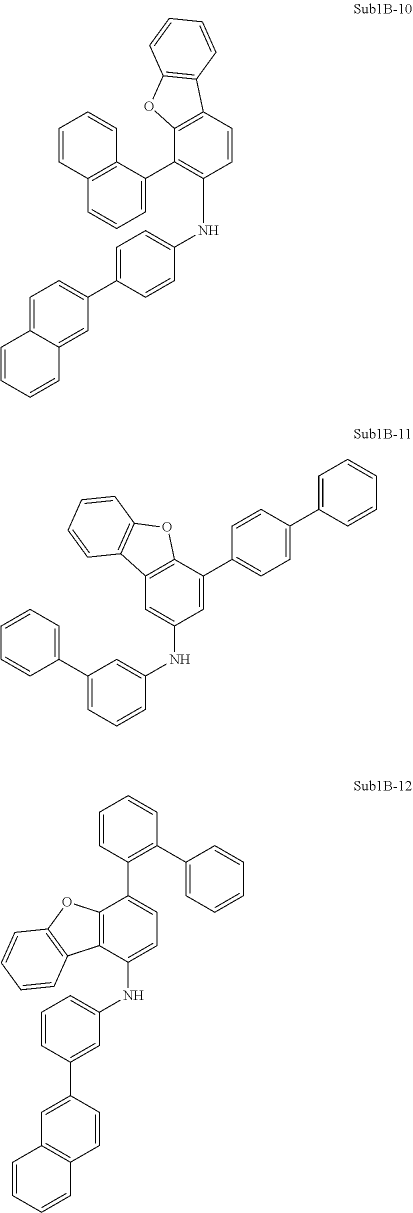 [SMILES: c1ccc2cc(-c3ccc(Nc4ccc5c(oc6ccccc65)c4-c4cccc5ccccc45)cc3)ccc2c1 ; c1ccc(-c2ccc(-c3cc(Nc4cccc(-c5ccccc5)c4)cc4c3oc3ccccc34)cc2)cc1 ; c1ccc(-c2ccccc2-c2ccc(Nc3cccc(-c4ccc5ccccc5c4)c3)c3c2oc2ccccc23)cc1]

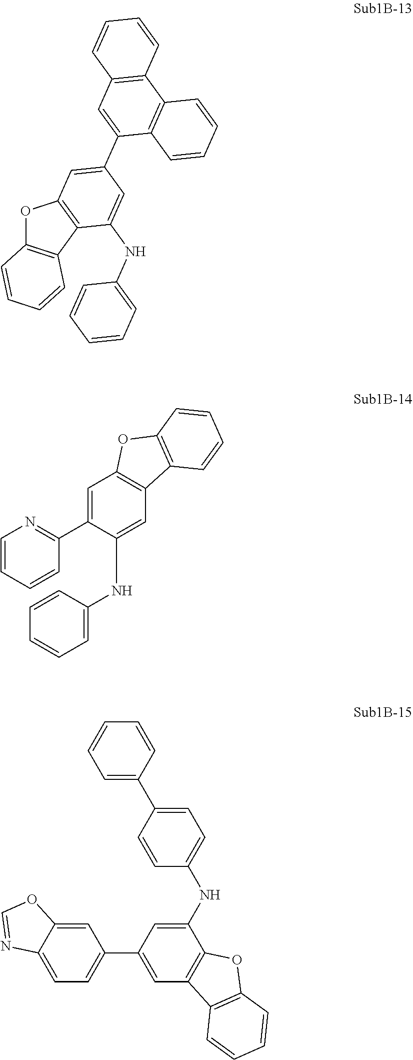 [SMILES: c1ccc(Nc2cc(-c3cc4ccccc4c4ccccc34)cc3oc4ccccc4c23)cc1 ; c1ccc(Nc2cc3c(cc2-c2ccccn2)oc2ccccc23)cc1 ; c1ccc(-c2ccc(Nc3cc(-c4ccc5ncoc5c4)cc4c3oc3ccccc34)cc2)cc1]

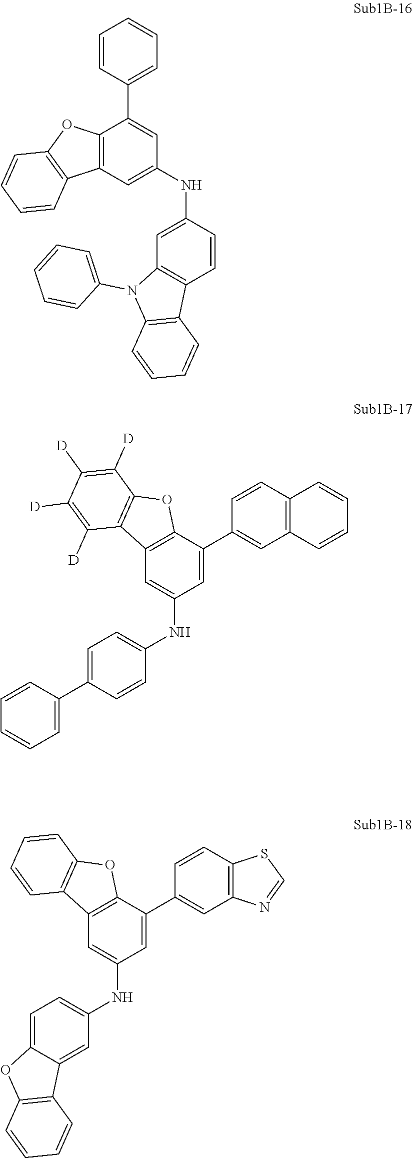 [SMILES: c1ccc(-c2cc(Nc3ccc4c5ccccc5n(-c5ccccc5)c4c3)cc3c2oc2ccccc23)cc1 ; [2H]c1c([2H])c([2H])c2c(oc3c(-c4ccc5ccccc5c4)cc(Nc4ccc(-c5ccccc5)cc4)cc32)c1[2H] ; c1ccc2c(c1)oc1ccc(Nc3cc(-c4ccc5scnc5c4)c4oc5ccccc5c4c3)cc12]

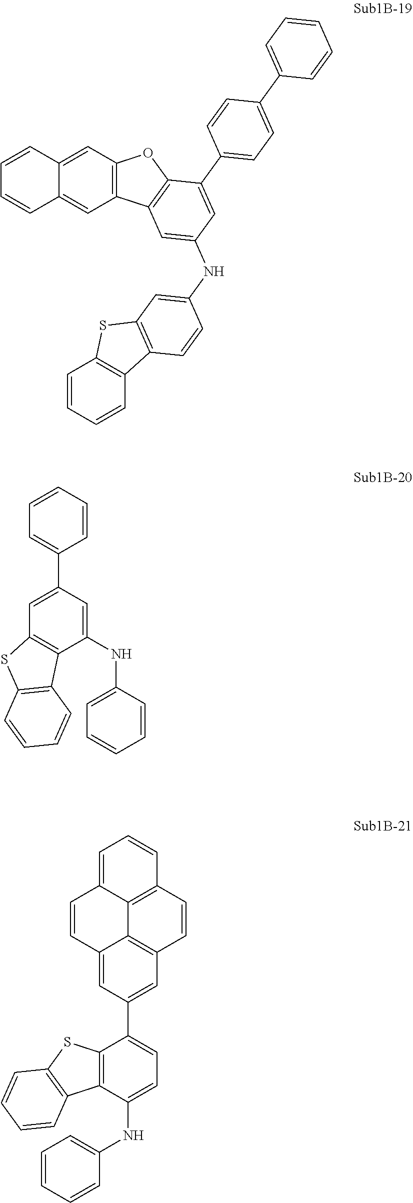 [SMILES: c1ccc(-c2ccc(-c3cc(Nc4ccc5c(c4)sc4ccccc45)cc4c3oc3cc5ccccc5cc34)cc2)cc1 ; c1ccc(Nc2cc(-c3ccccc3)cc3sc4ccccc4c23)cc1 ; c1ccc(Nc2ccc(-c3cc4ccc5cccc6ccc(c3)c4c56)c3sc4ccccc4c23)cc1]

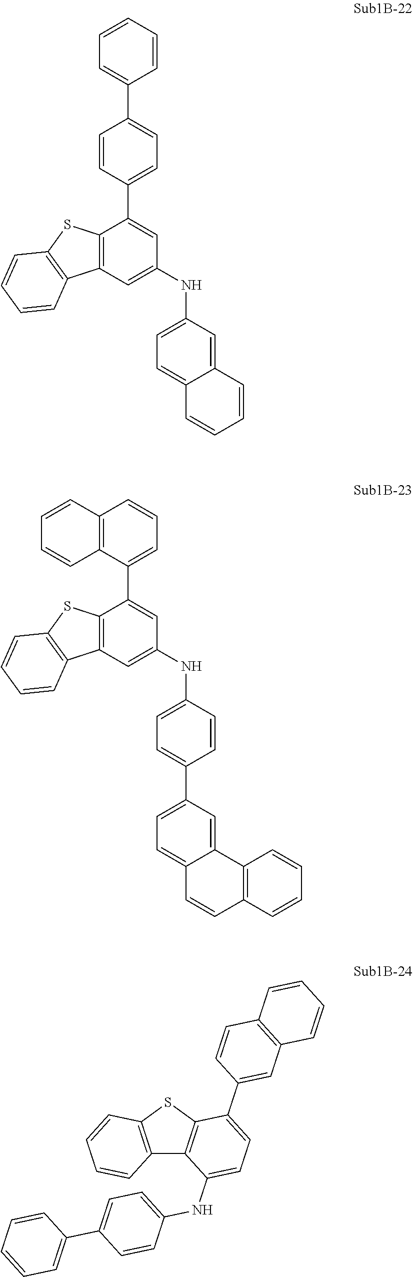 [SMILES: c1ccc(-c2ccc(-c3cc(Nc4ccc5ccccc5c4)cc4c3sc3ccccc34)cc2)cc1 ; c1ccc2c(-c3cc(Nc4ccc(-c5ccc6ccc7ccccc7c6c5)cc4)cc4c3sc3ccccc34)cccc2c1 ; c1ccc(-c2ccc(Nc3ccc(-c4ccc5ccccc5c4)c4sc5ccccc5c34)cc2)cc1]

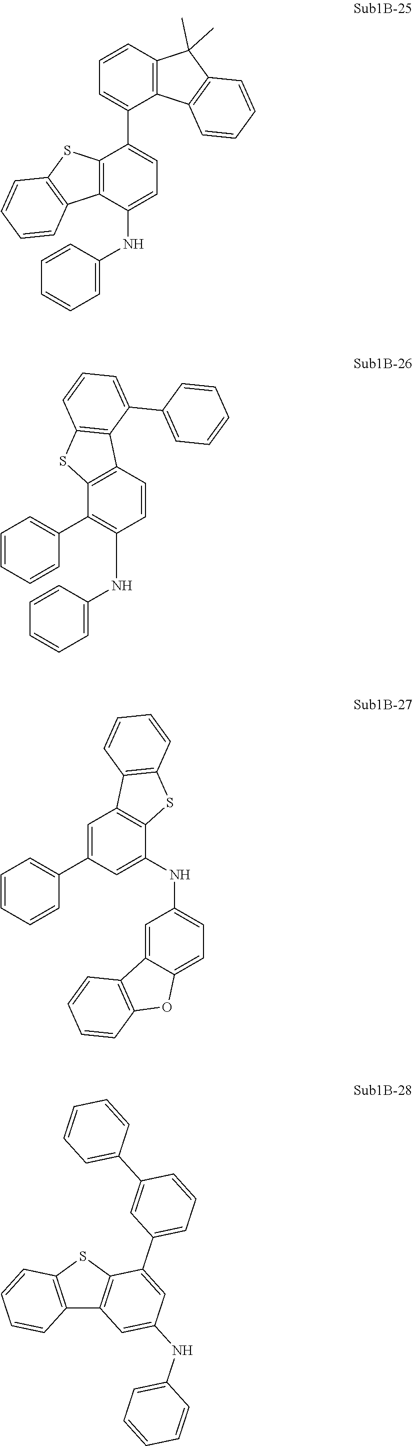 [SMILES: CC1(C)c2ccccc2-c2c(-c3ccc(Nc4ccccc4)c4c3sc3ccccc34)cccc21 ; c1ccc(Nc2ccc3c(sc4cccc(-c5ccccc5)c43)c2-c2ccccc2)cc1 ; c1ccc(-c2cc(Nc3ccc4oc5ccccc5c4c3)c3sc4ccccc4c3c2)cc1 ; c1ccc(Nc2cc(-c3cccc(-c4ccccc4)c3)c3sc4ccccc4c3c2)cc1]

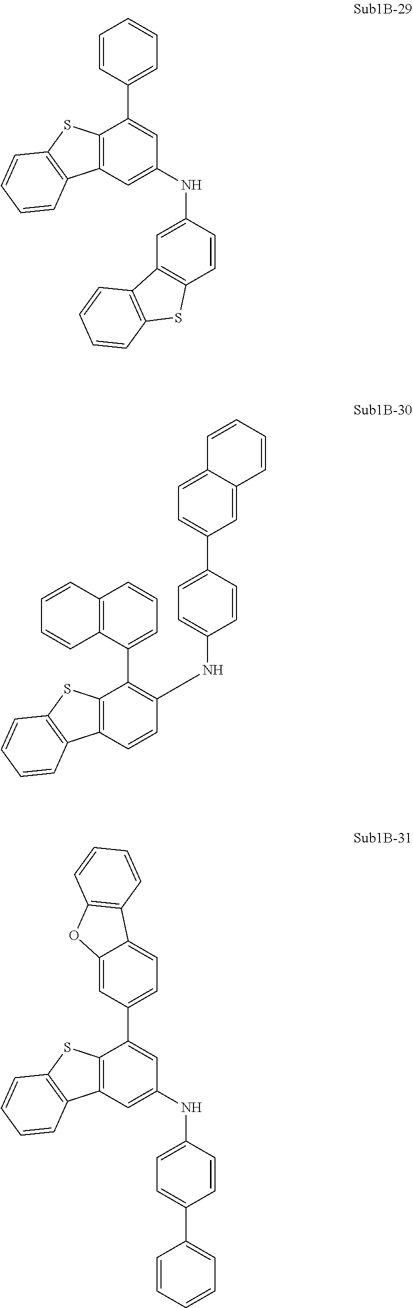 [SMILES: c1ccc(-c2cc(Nc3ccc4sc5ccccc5c4c3)cc3c2sc2ccccc23)cc1 ; c1ccc2cc(-c3ccc(Nc4ccc5c(sc6ccccc65)c4-c4cccc5ccccc45)cc3)ccc2c1 ; c1ccc(-c2ccc(Nc3cc(-c4ccc5c(c4)oc4ccccc45)c4sc5ccccc5c4c3)cc2)cc1]

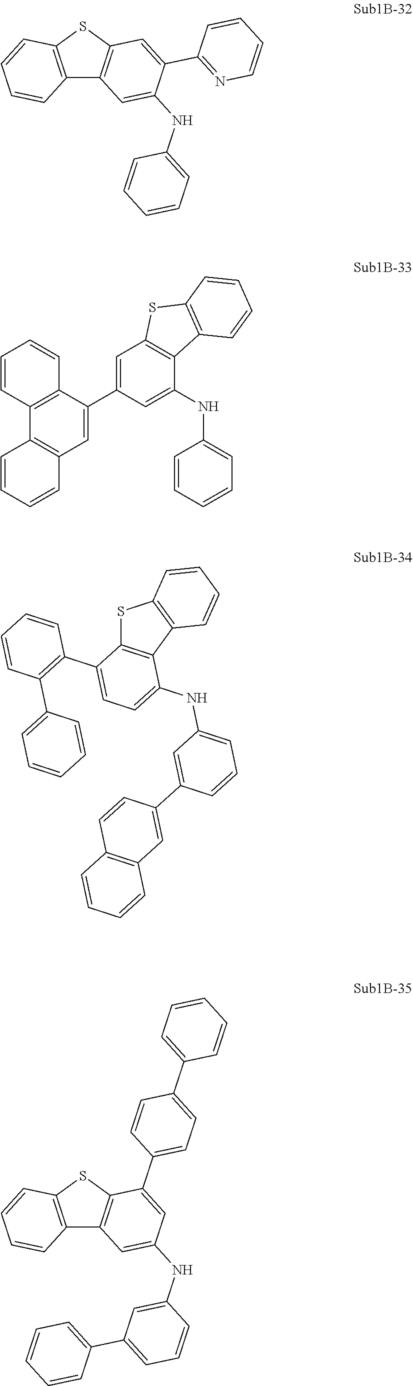 [SMILES: c1ccc(Nc2cc3c(cc2-c2ccccn2)sc2ccccc23)cc1 ; c1ccc(Nc2cc(-c3cc4ccccc4c4ccccc34)cc3sc4ccccc4c23)cc1 ; c1ccc(-c2ccccc2-c2ccc(Nc3cccc(-c4ccc5ccccc5c4)c3)c3c2sc2ccccc23)cc1 ; c1ccc(-c2ccc(-c3cc(Nc4cccc(-c5ccccc5)c4)cc4c3sc3ccccc34)cc2)cc1]

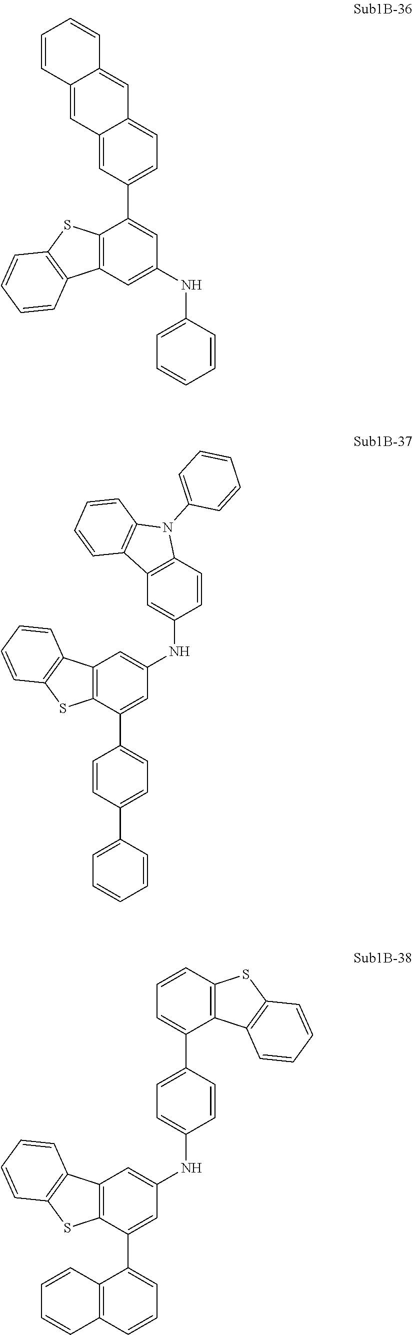 [SMILES: c1ccc(Nc2cc(-c3ccc4cc5ccccc5cc4c3)c3sc4ccccc4c3c2)cc1 ; c1ccc(-c2ccc(-c3cc(Nc4ccc5c(c4)c4ccccc4n5-c4ccccc4)cc4c3sc3ccccc34)cc2)cc1 ; c1ccc2c(-c3cc(Nc4ccc(-c5cccc6sc7ccccc7c56)cc4)cc4c3sc3ccccc34)cccc2c1]

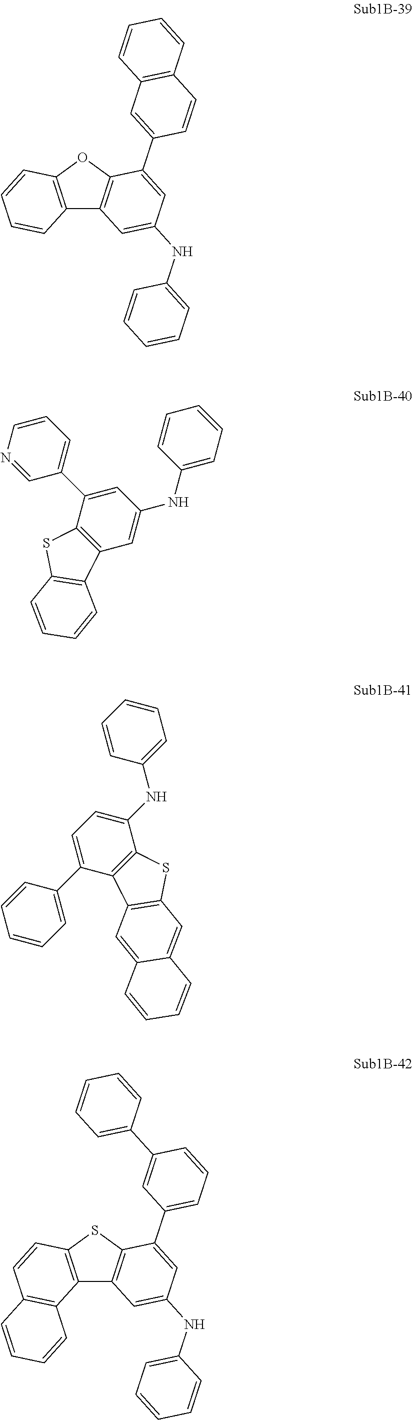 [SMILES: c1ccc(Nc2cc(-c3ccc4ccccc4c3)c3oc4ccccc4c3c2)cc1 ; c1ccc(Nc2cc(-c3cccnc3)c3sc4ccccc4c3c2)cc1 ; c1ccc(Nc2ccc(-c3ccccc3)c3c2sc2cc4ccccc4cc23)cc1 ; c1ccc(Nc2cc(-c3cccc(-c4ccccc4)c3)c3sc4ccc5ccccc5c4c3c2)cc1]

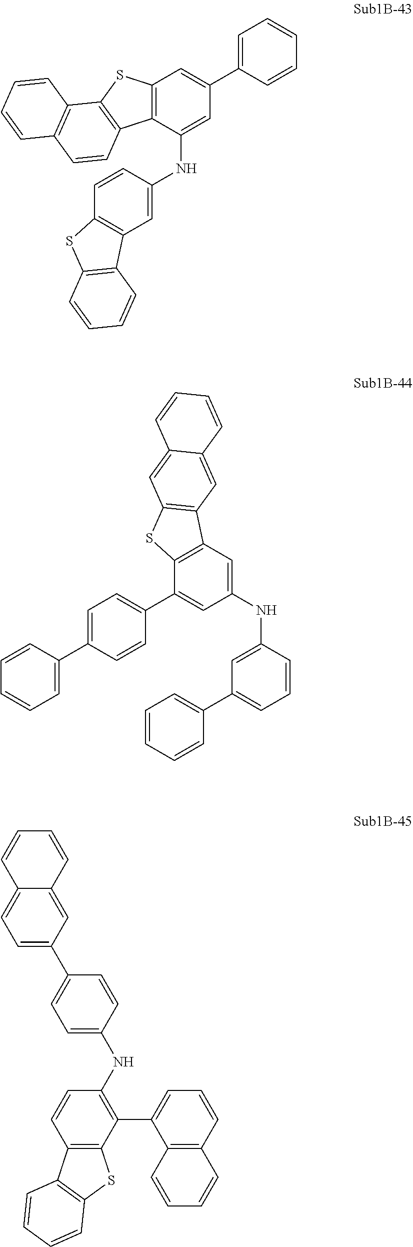 [SMILES: c1ccc(-c2cc(Nc3ccc4sc5ccccc5c4c3)c3c(c2)sc2c4ccccc4ccc23)cc1 ; c1ccc(-c2ccc(-c3cc(Nc4cccc(-c5ccccc5)c4)cc4c3sc3cc5ccccc5cc34)cc2)cc1 ; c1ccc2cc(-c3ccc(Nc4ccc5c(sc6ccccc65)c4-c4cccc5ccccc45)cc3)ccc2c1]

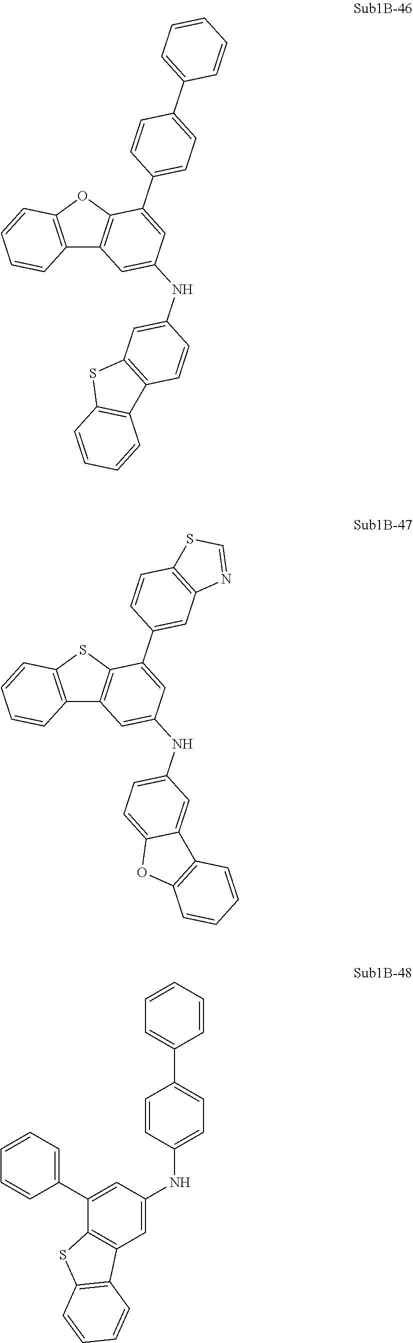 [SMILES: c1ccc(-c2ccc(-c3cc(Nc4ccc5c(c4)sc4ccccc45)cc4c3oc3ccccc34)cc2)cc1 ; c1ccc2c(c1)oc1ccc(Nc3cc(-c4ccc5scnc5c4)c4sc5ccccc5c4c3)cc12 ; c1ccc(-c2ccc(Nc3cc(-c4ccccc4)c4sc5ccccc5c4c3)cc2)cc1]

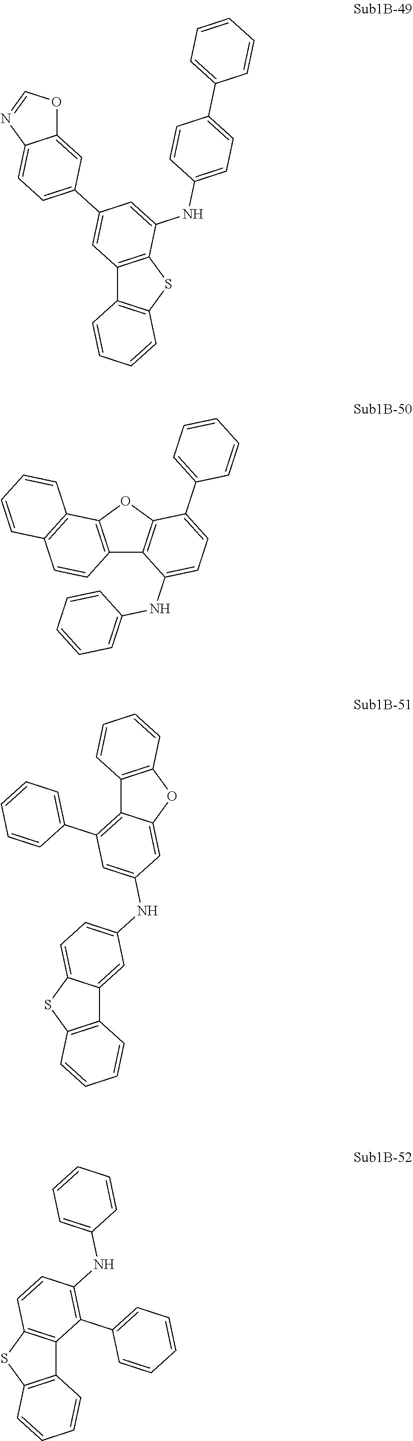 [SMILES: c1ccc(-c2ccc(Nc3cc(-c4ccc5ncoc5c4)cc4c3sc3ccccc34)cc2)cc1 ; c1ccc(Nc2ccc(-c3ccccc3)c3oc4c5ccccc5ccc4c23)cc1 ; c1ccc(-c2cc(Nc3ccc4sc5ccccc5c4c3)cc3oc4ccccc4c23)cc1 ; c1ccc(Nc2ccc3sc4ccccc4c3c2-c2ccccc2)cc1]

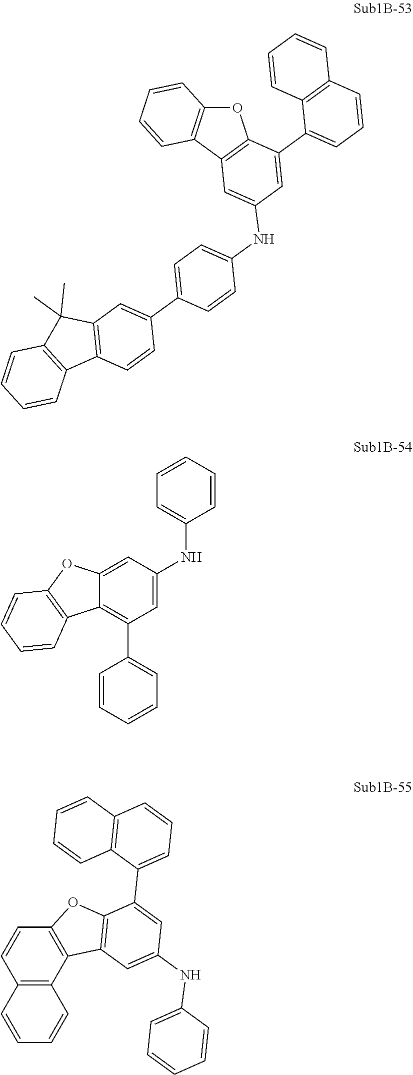 [SMILES: CC1(C)c2ccccc2-c2ccc(-c3ccc(Nc4cc(-c5cccc6ccccc56)c5oc6ccccc6c5c4)cc3)cc21 ; c1ccc(Nc2cc(-c3ccccc3)c3c(c2)oc2ccccc23)cc1 ; c1ccc(Nc2cc(-c3cccc4ccccc34)c3oc4ccc5ccccc5c4c3c2)cc1]

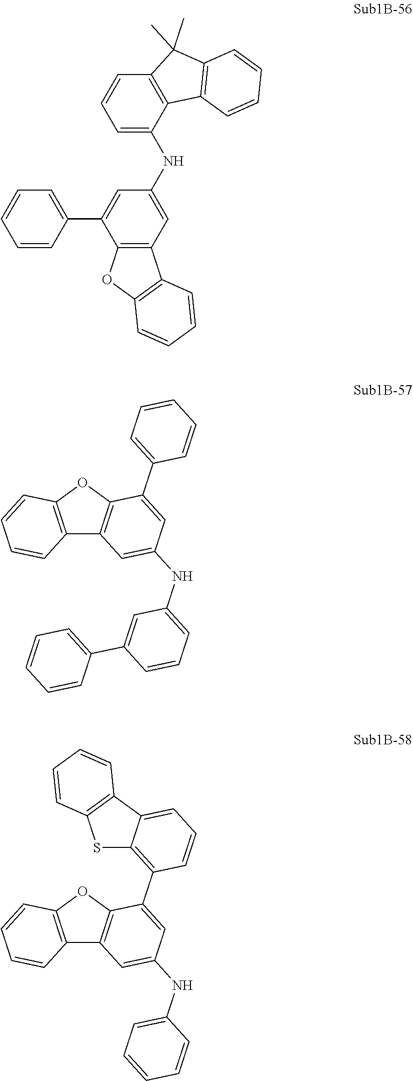 [SMILES: CC1(C)c2ccccc2-c2c(Nc3cc(-c4ccccc4)c4oc5ccccc5c4c3)cccc21 ; c1ccc(-c2cccc(Nc3cc(-c4ccccc4)c4oc5ccccc5c4c3)c2)cc1 ; c1ccc(Nc2cc(-c3cccc4c3sc3ccccc34)c3oc4ccccc4c3c2)cc1]

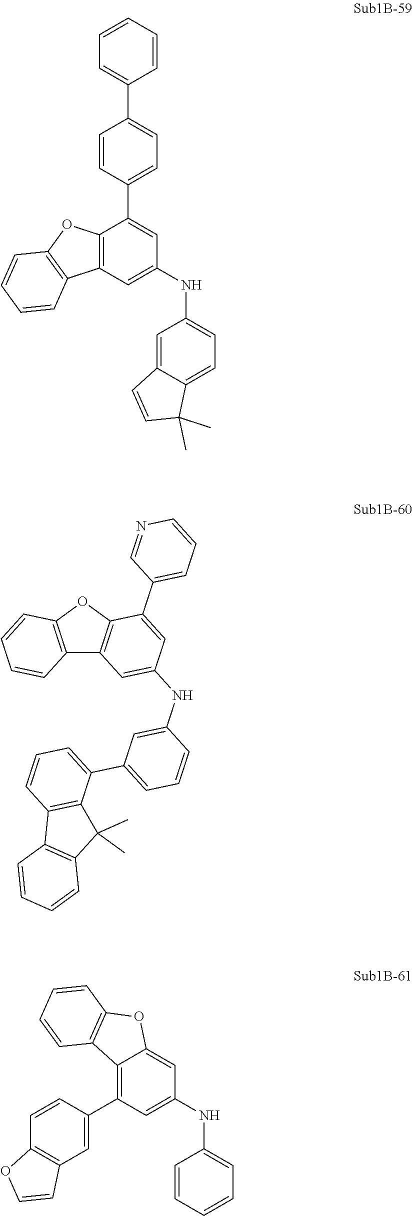 [SMILES: CC1(C)C=Cc2cc(Nc3cc(-c4ccc(-c5ccccc5)cc4)c4oc5ccccc5c4c3)ccc21 ; CC1(C)c2ccccc2-c2cccc(-c3cccc(Nc4cc(-c5cccnc5)c5oc6ccccc6c5c4)c3)c21 ; c1ccc(Nc2cc(-c3ccc4occc4c3)c3c(c2)oc2ccccc23)cc1]

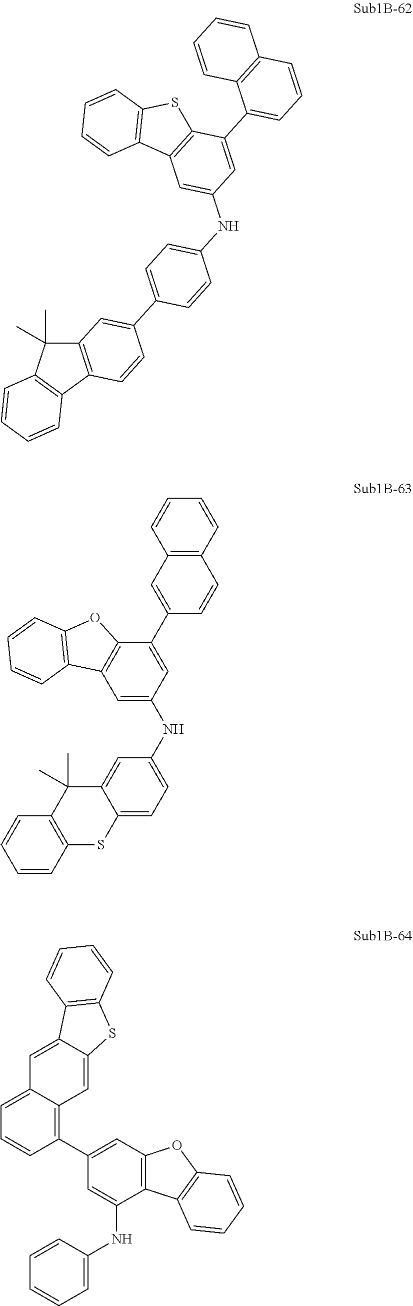 [SMILES: CC1(C)c2ccccc2-c2ccc(-c3ccc(Nc4cc(-c5cccc6ccccc56)c5sc6ccccc6c5c4)cc3)cc21 ; CC1(C)c2ccccc2Sc2ccc(Nc3cc(-c4ccc5ccccc5c4)c4oc5ccccc5c4c3)cc21 ; c1ccc(Nc2cc(-c3cccc4cc5c(cc34)sc3ccccc35)cc3oc4ccccc4c23)cc1]

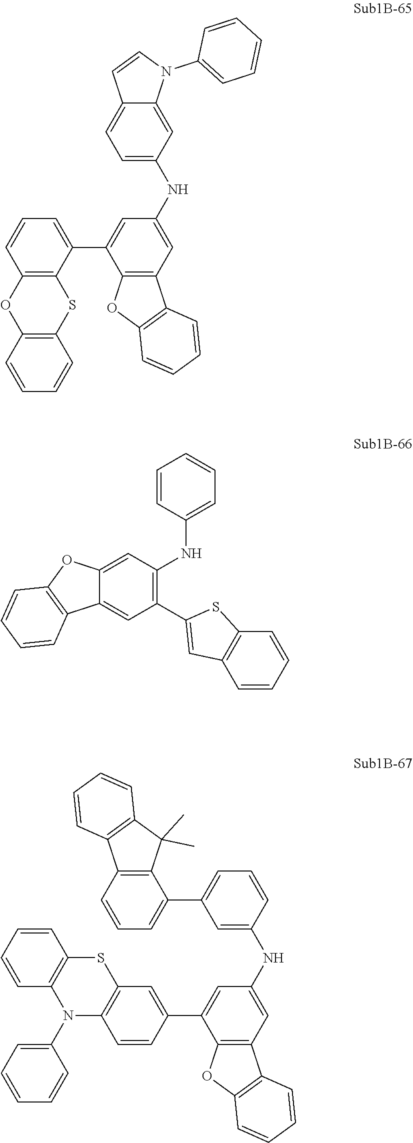 [SMILES: c1ccc(-n2ccc3ccc(Nc4cc(-c5cccc6c5Sc5ccccc5O6)c5oc6ccccc6c5c4)cc32)cc1 ; c1ccc(Nc2cc3oc4ccccc4c3cc2-c2cc3ccccc3s2)cc1 ; CC1(C)c2ccccc2-c2cccc(-c3cccc(Nc4cc(-c5ccc6c(c5)Sc5ccccc5N6c5ccccc5)c5oc6ccccc6c5c4)c3)c21]

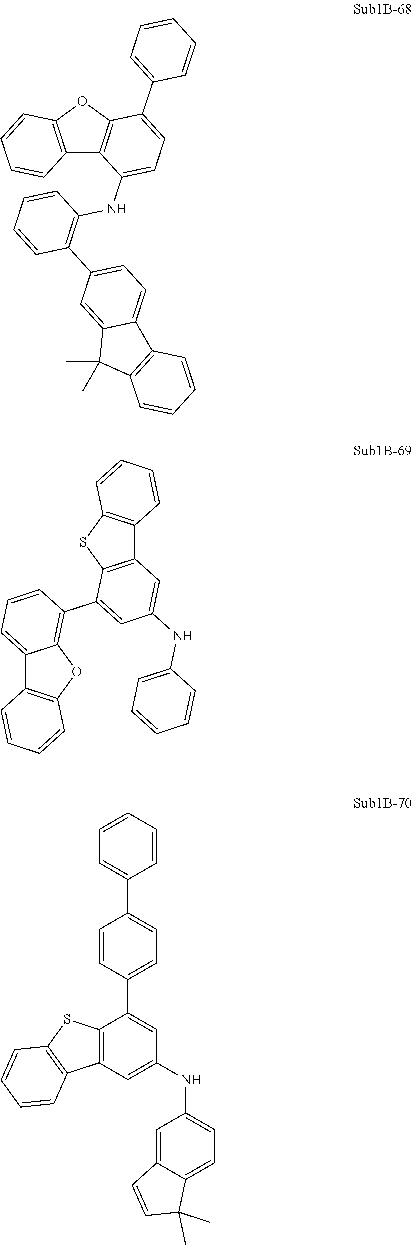 [SMILES: CC1(C)c2ccccc2-c2ccc(-c3ccccc3Nc3ccc(-c4ccccc4)c4oc5ccccc5c34)cc21 ; c1ccc(Nc2cc(-c3cccc4c3oc3ccccc34)c3sc4ccccc4c3c2)cc1 ; CC1(C)C=Cc2cc(Nc3cc(-c4ccc(-c5ccccc5)cc4)c4sc5ccccc5c4c3)ccc21]

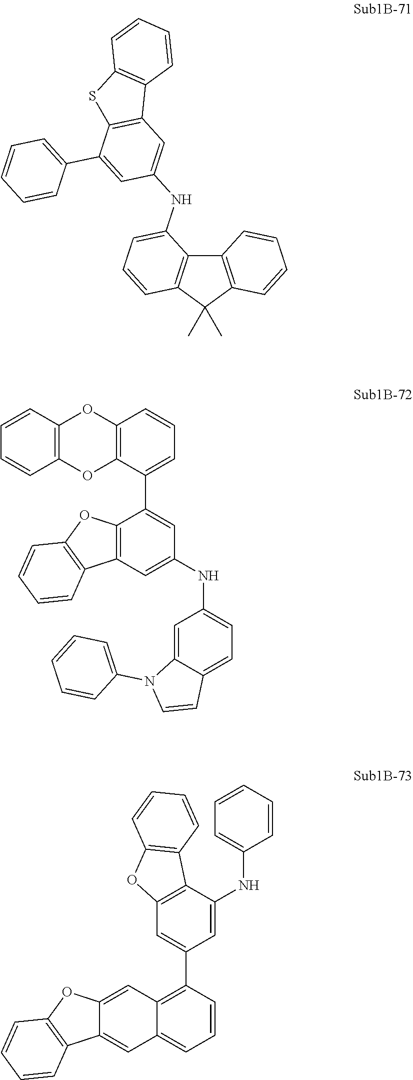 [SMILES: CC1(C)c2ccccc2-c2c(Nc3cc(-c4ccccc4)c4sc5ccccc5c4c3)cccc21 ; c1ccc(-n2ccc3ccc(Nc4cc(-c5cccc6c5Oc5ccccc5O6)c5oc6ccccc6c5c4)cc32)cc1 ; c1ccc(Nc2cc(-c3cccc4cc5c(cc34)oc3ccccc35)cc3oc4ccccc4c23)cc1]

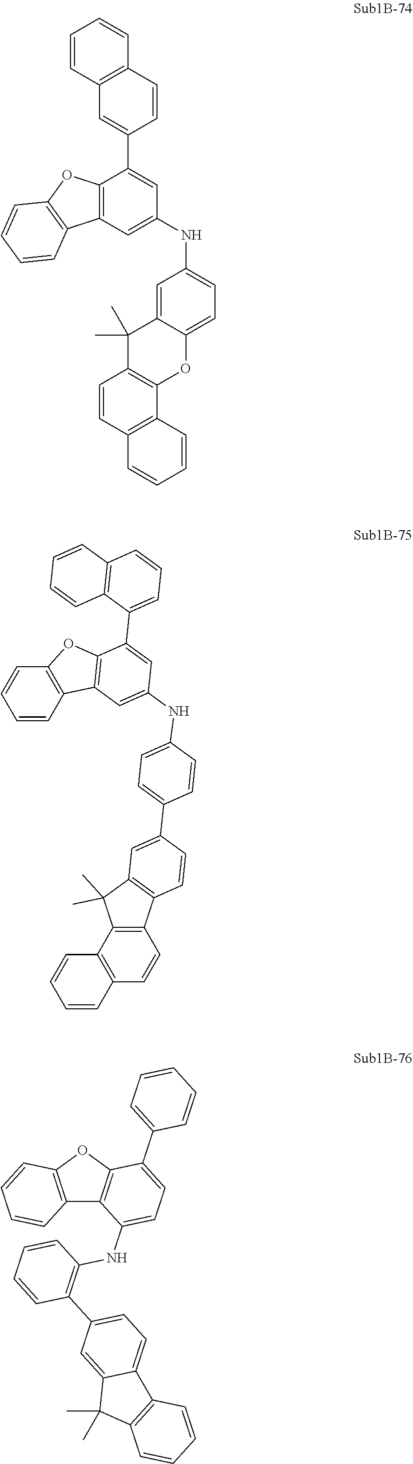 [SMILES: CC1(C)c2cc(Nc3cc(-c4ccc5ccccc5c4)c4oc5ccccc5c4c3)ccc2Oc2c1ccc1ccccc21 ; CC1(C)c2cc(-c3ccc(Nc4cc(-c5cccc6ccccc56)c5oc6ccccc6c5c4)cc3)ccc2-c2ccc3ccccc3c21 ; CC1(C)c2ccccc2-c2ccc(-c3ccccc3Nc3ccc(-c4ccccc4)c4oc5ccccc5c34)cc21]

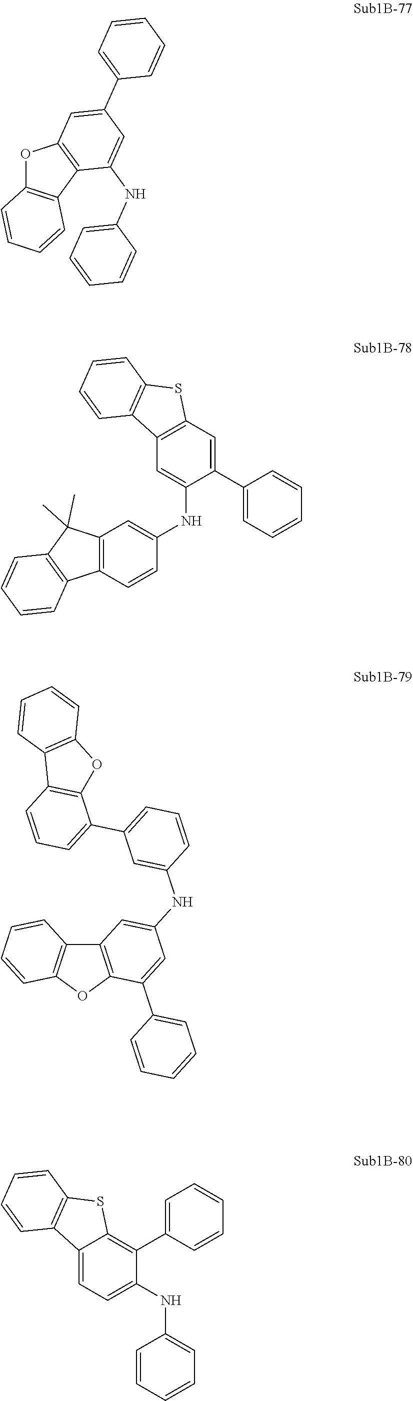 [SMILES: c1ccc(Nc2cc(-c3ccccc3)cc3oc4ccccc4c23)cc1 ; CC1(C)c2ccccc2-c2ccc(Nc3cc4c(cc3-c3ccccc3)sc3ccccc34)cc21 ; c1ccc(-c2cc(Nc3cccc(-c4cccc5c4oc4ccccc45)c3)cc3c2oc2ccccc23)cc1 ; c1ccc(Nc2ccc3c(sc4ccccc43)c2-c2ccccc2)cc1]

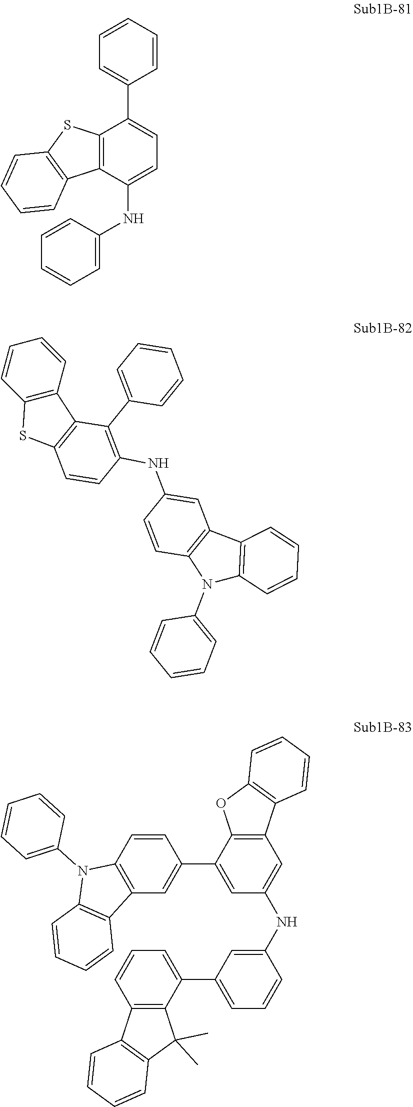 [SMILES: c1ccc(Nc2ccc(-c3ccccc3)c3sc4ccccc4c23)cc1 ; c1ccc(-c2c(Nc3ccc4c(c3)c3ccccc3n4-c3ccccc3)ccc3sc4ccccc4c23)cc1 ; CC1(C)c2ccccc2-c2cccc(-c3cccc(Nc4cc(-c5ccc6c(c5)c5ccccc5n6-c5ccccc5)c5oc6ccccc6c5c4)c3)c21]

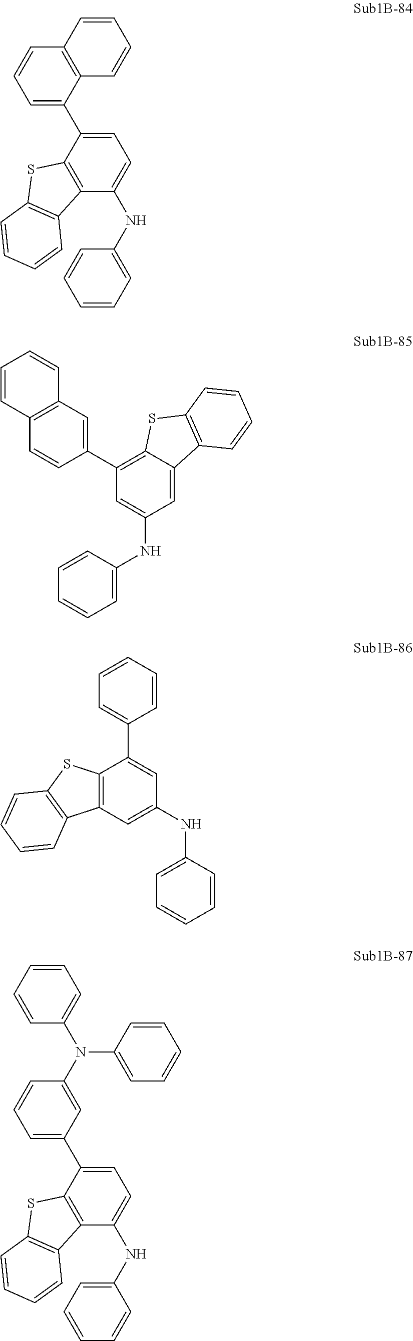 [SMILES: c1ccc(Nc2ccc(-c3cccc4ccccc34)c3sc4ccccc4c23)cc1 ; c1ccc(Nc2cc(-c3ccc4ccccc4c3)c3sc4ccccc4c3c2)cc1 ; c1ccc(Nc2cc(-c3ccccc3)c3sc4ccccc4c3c2)cc1 ; c1ccc(Nc2ccc(-c3cccc(N(c4ccccc4)c4ccccc4)c3)c3sc4ccccc4c23)cc1]

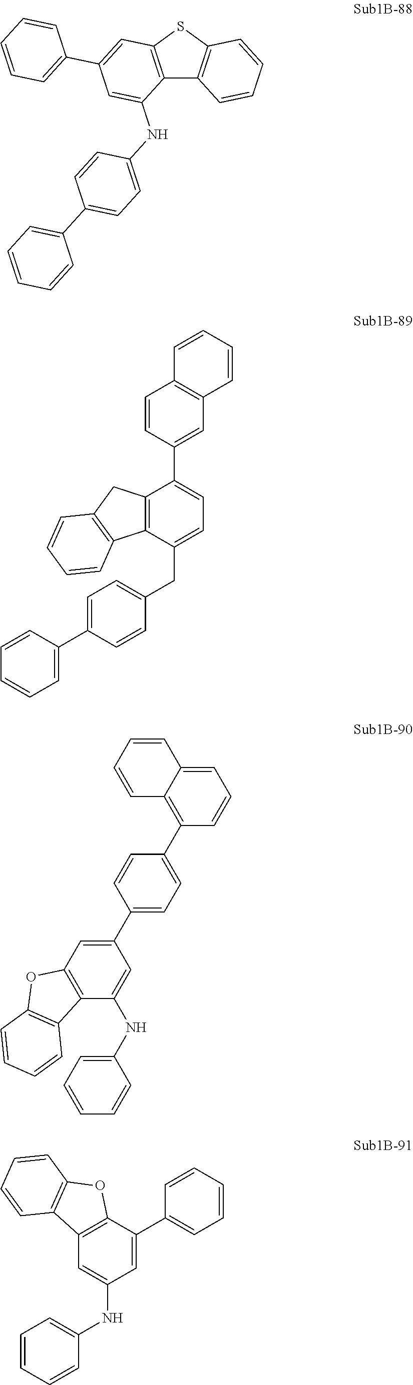

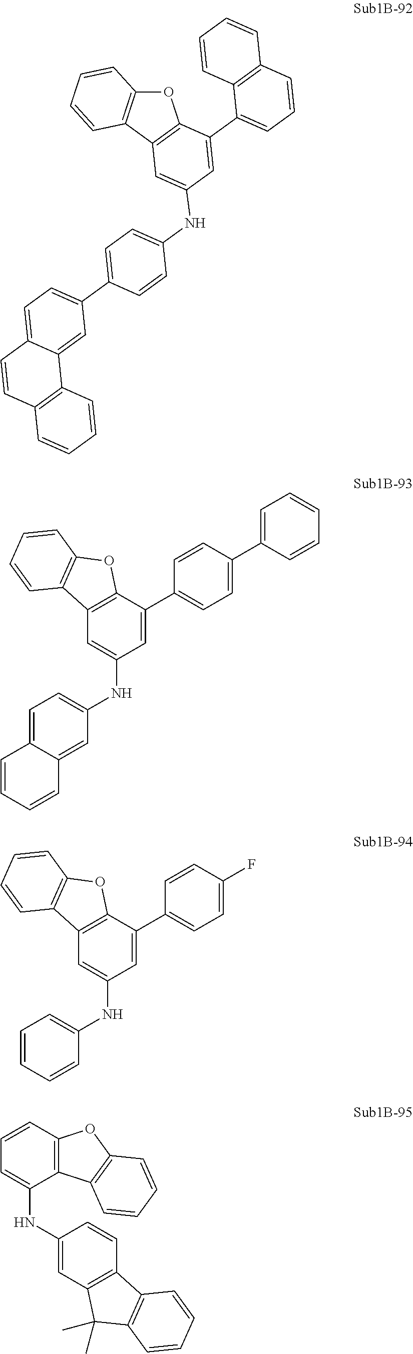

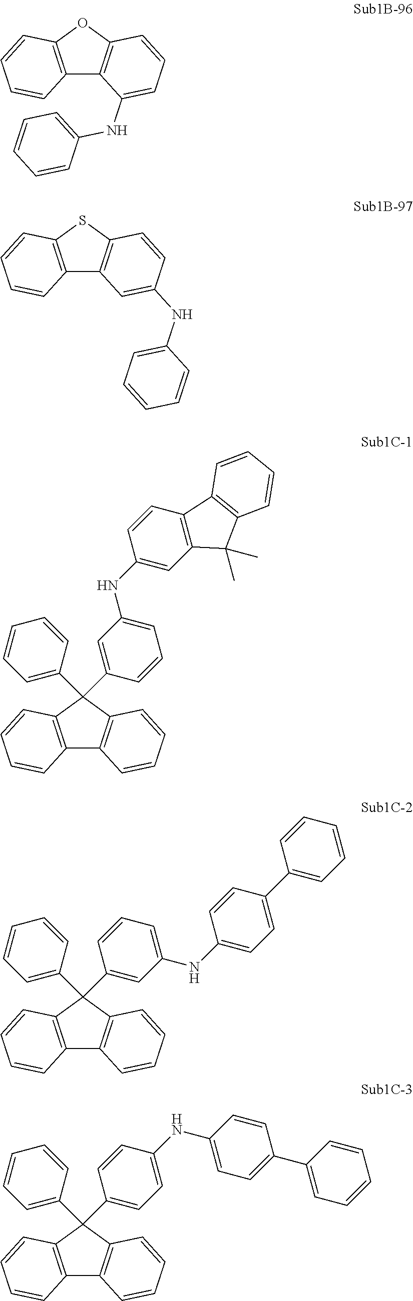 [SMILES: c1ccc(Nc2cccc3oc4ccccc4c23)cc1 ; c1ccc(Nc2ccc3sc4ccccc4c3c2)cc1 ; CC1(C)c2ccccc2-c2ccc(Nc3cccc(C4(c5ccccc5)c5ccccc5-c5ccccc54)c3)cc21 ; c1ccc(-c2ccc(Nc3cccc(C4(c5ccccc5)c5ccccc5-c5ccccc54)c3)cc2)cc1 ; c1ccc(-c2ccc(Nc3ccc(C4(c5ccccc5)c5ccccc5-c5ccccc54)cc3)cc2)cc1]

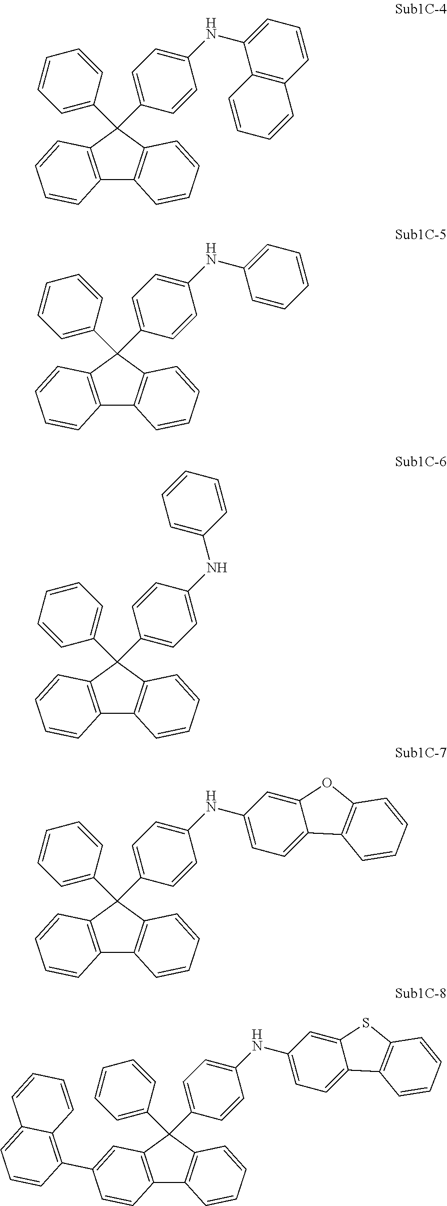 [SMILES: c1ccc(C2(c3ccc(Nc4cccc5ccccc45)cc3)c3ccccc3-c3ccccc32)cc1 ; c1ccc(Nc2ccc(C3(c4ccccc4)c4ccccc4-c4ccccc43)cc2)cc1 ; c1ccc(Nc2ccc(C3(c4ccccc4)c4ccccc4-c4ccccc43)cc2)cc1 ; c1ccc(C2(c3ccc(Nc4ccc5c(c4)oc4ccccc45)cc3)c3ccccc3-c3ccccc32)cc1 ; c1ccc(C2(c3ccc(Nc4ccc5c(c4)sc4ccccc45)cc3)c3ccccc3-c3ccc(-c4cccc5ccccc45)cc32)cc1]

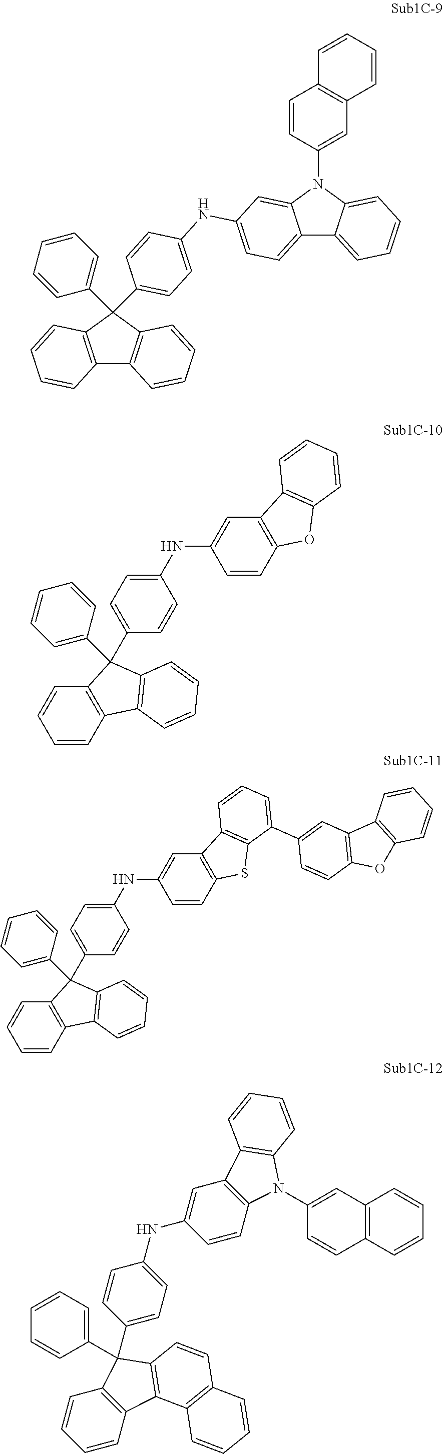 [SMILES: c1ccc(C2(c3ccc(Nc4ccc5c6ccccc6n(-c6ccc7ccccc7c6)c5c4)cc3)c3ccccc3-c3ccccc32)cc1 ; c1ccc(C2(c3ccc(Nc4ccc5oc6ccccc6c5c4)cc3)c3ccccc3-c3ccccc32)cc1 ; c1ccc(C2(c3ccc(Nc4ccc5sc6c(-c7ccc8oc9ccccc9c8c7)cccc6c5c4)cc3)c3ccccc3-c3ccccc32)cc1 ; c1ccc(C2(c3ccc(Nc4ccc5c(c4)c4ccccc4n5-c4ccc5ccccc5c4)cc3)c3ccccc3-c3c2ccc2ccccc32)cc1]

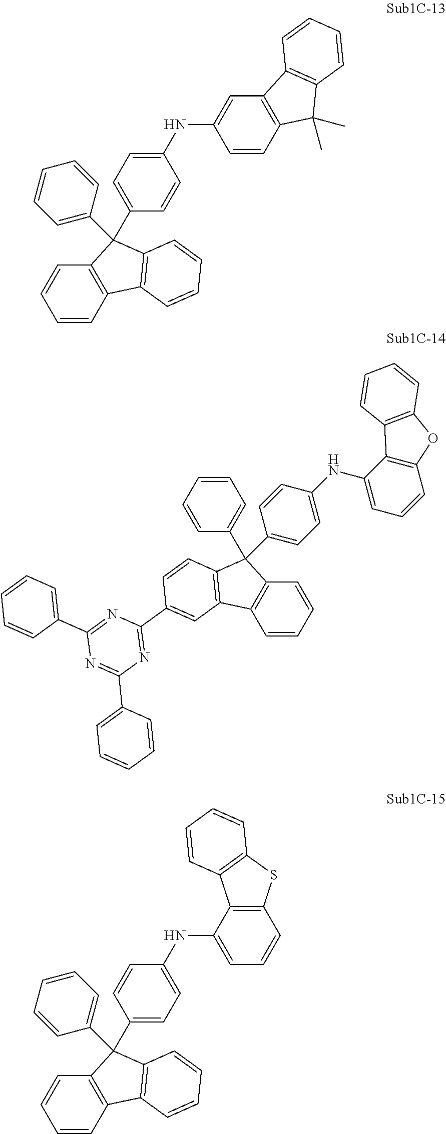 [SMILES: CC1(C)c2ccccc2-c2cc(Nc3ccc(C4(c5ccccc5)c5ccccc5-c5ccccc54)cc3)ccc21 ; c1ccc(-c2nc(-c3ccccc3)nc(-c3ccc4c(c3)-c3ccccc3C4(c3ccccc3)c3ccc(Nc4cccc5oc6ccccc6c45)cc3)n2)cc1 ; c1ccc(C2(c3ccc(Nc4cccc5sc6ccccc6c45)cc3)c3ccccc3-c3ccccc32)cc1]

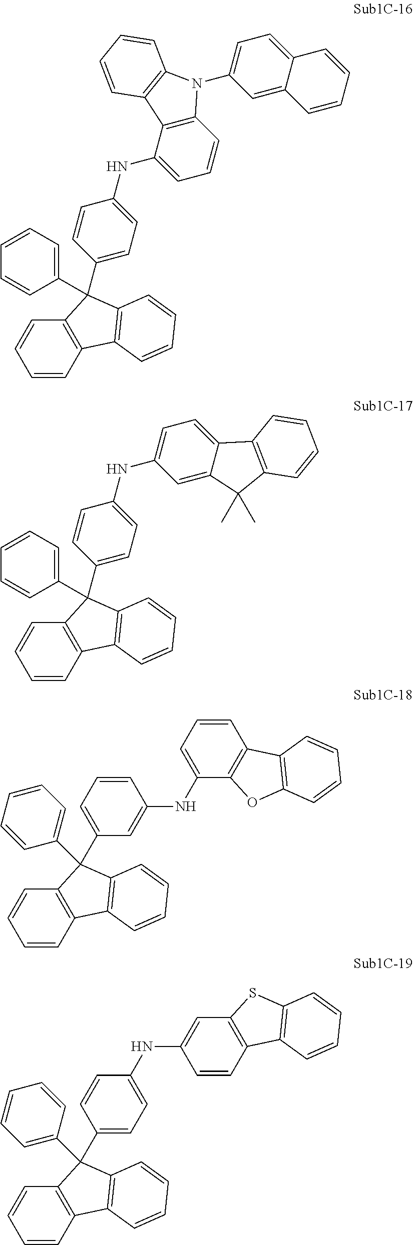 [SMILES: c1ccc(C2(c3ccc(Nc4cccc5c4c4ccccc4n5-c4ccc5ccccc5c4)cc3)c3ccccc3-c3ccccc32)cc1 ; CC1(C)c2ccccc2-c2ccc(Nc3ccc(C4(c5ccccc5)c5ccccc5-c5ccccc54)cc3)cc21 ; c1ccc(C2(c3cccc(Nc4cccc5c4oc4ccccc45)c3)c3ccccc3-c3ccccc32)cc1 ; c1ccc(C2(c3ccc(Nc4ccc5c(c4)sc4ccccc45)cc3)c3ccccc3-c3ccccc32)cc1]

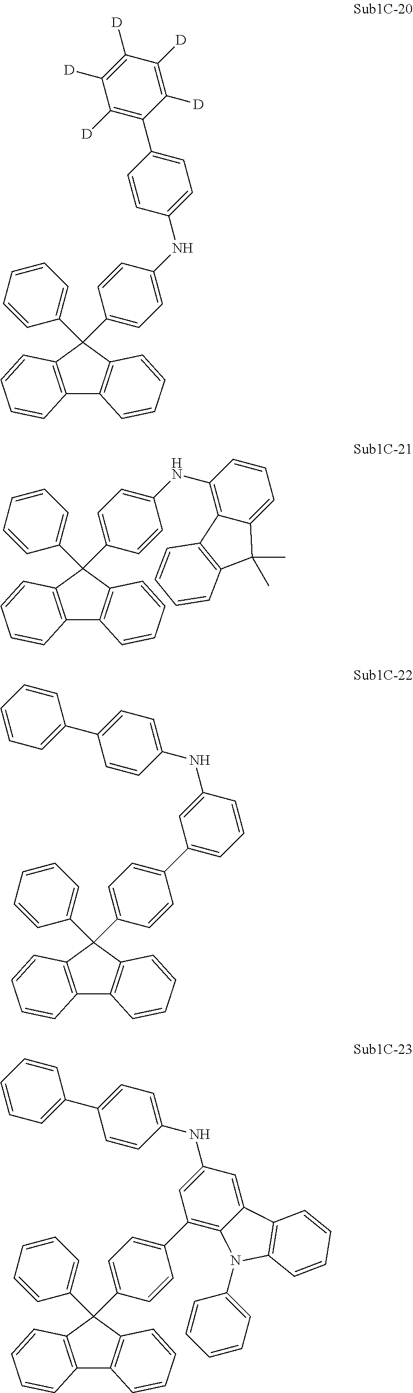

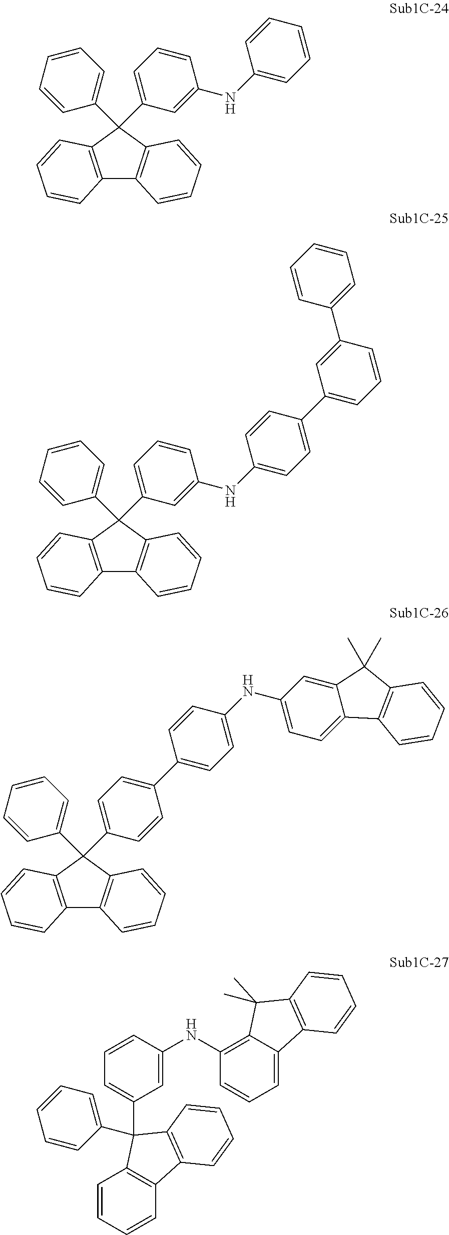 [SMILES: c1ccc(Nc2cccc(C3(c4ccccc4)c4ccccc4-c4ccccc43)c2)cc1 ; c1ccc(-c2cccc(-c3ccc(Nc4cccc(C5(c6ccccc6)c6ccccc6-c6ccccc65)c4)cc3)c2)cc1 ; CC1(C)c2ccccc2-c2ccc(Nc3ccc(-c4ccc(C5(c6ccccc6)c6ccccc6-c6ccccc65)cc4)cc3)cc21 ; CC1(C)c2ccccc2-c2cccc(Nc3cccc(C4(c5ccccc5)c5ccccc5-c5ccccc54)c3)c21]

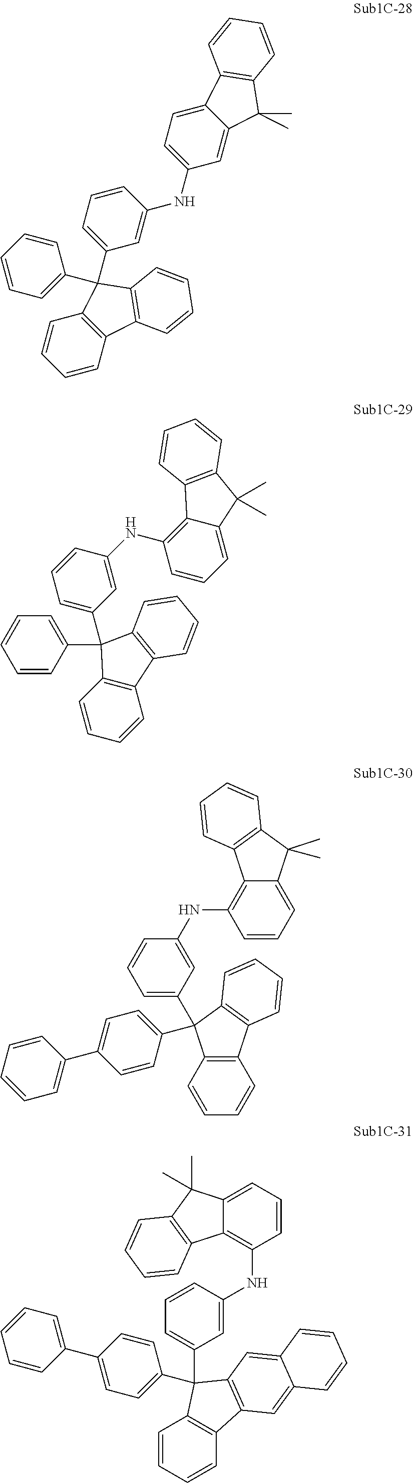

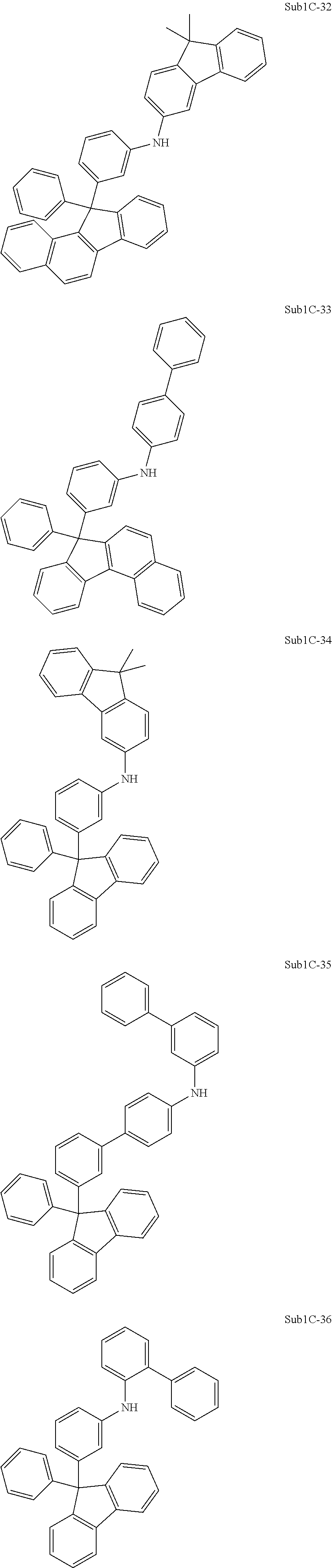

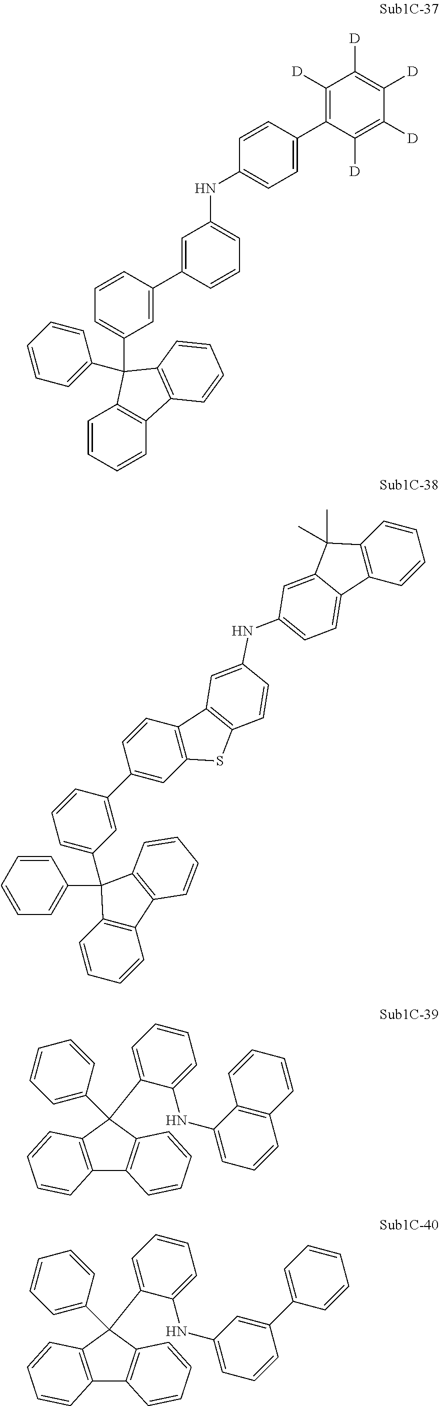

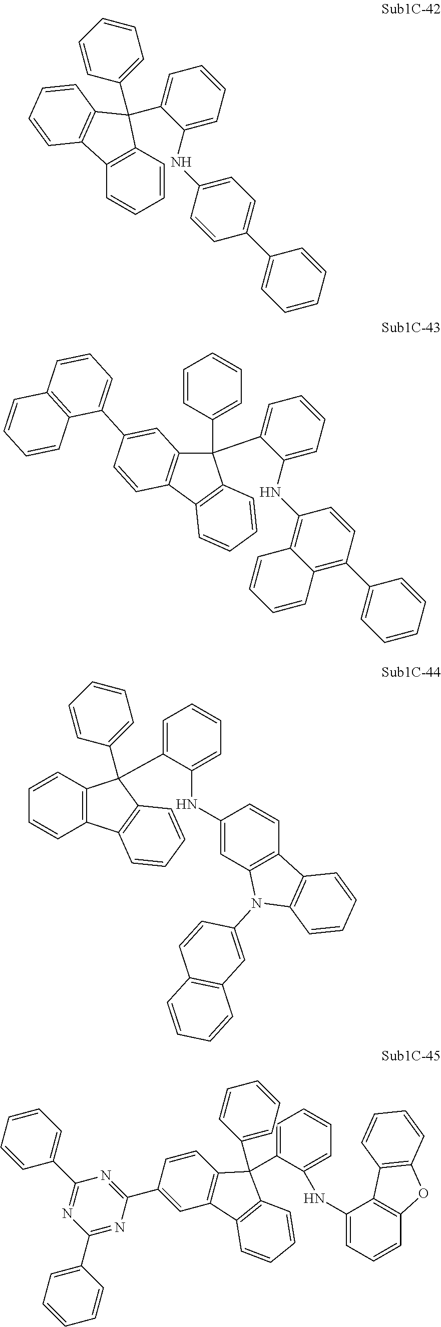 [SMILES: c1ccc(-c2ccc(Nc3ccccc3C3(c4ccccc4)c4ccccc4-c4ccccc43)cc2)cc1 ; c1ccc(-c2ccc(Nc3ccccc3C3(c4ccccc4)c4ccccc4-c4ccc(-c5cccc6ccccc56)cc43)c3ccccc23)cc1 ; c1ccc(C2(c3ccccc3Nc3ccc4c5ccccc5n(-c5ccc6ccccc6c5)c4c3)c3ccccc3-c3ccccc32)cc1 ; c1ccc(-c2nc(-c3ccccc3)nc(-c3ccc4c(c3)-c3ccccc3C4(c3ccccc3)c3ccccc3Nc3cccc4oc5ccccc5c34)n2)cc1]

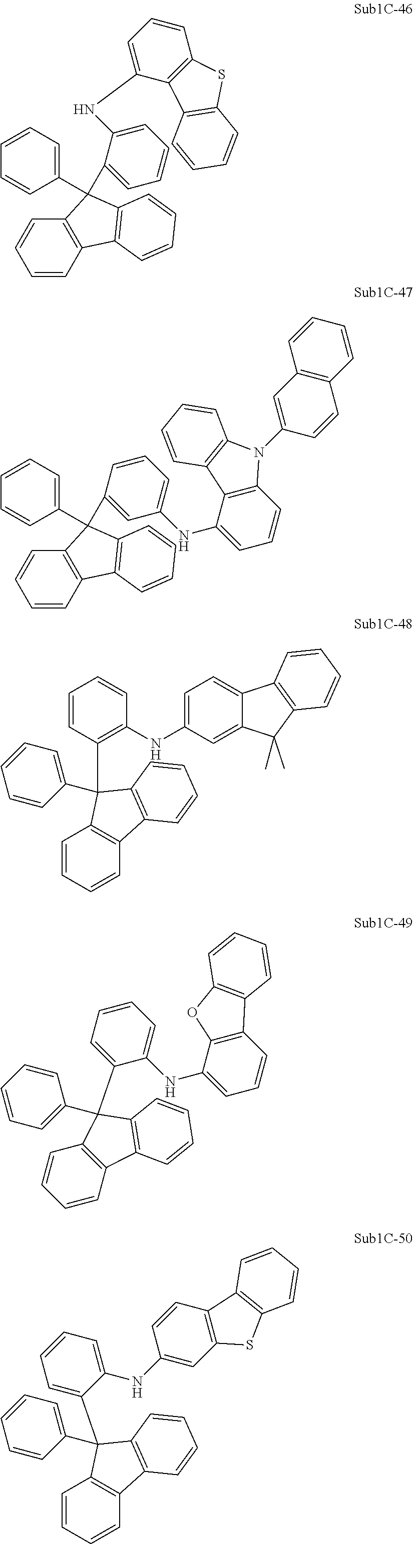 [SMILES: c1ccc(C2(c3ccccc3Nc3cccc4sc5ccccc5c34)c3ccccc3-c3ccccc32)cc1 ; c1ccc(C2(c3cccc(Nc4cccc5c4c4ccccc4n5-c4ccc5ccccc5c4)c3)c3ccccc3-c3ccccc32)cc1 ; CC1(C)c2ccccc2-c2ccc(Nc3ccccc3C3(c4ccccc4)c4ccccc4-c4ccccc43)cc21 ; c1ccc(C2(c3ccccc3Nc3cccc4c3oc3ccccc34)c3ccccc3-c3ccccc32)cc1 ; c1ccc(C2(c3ccccc3Nc3ccc4c(c3)sc3ccccc34)c3ccccc3-c3ccccc32)cc1]

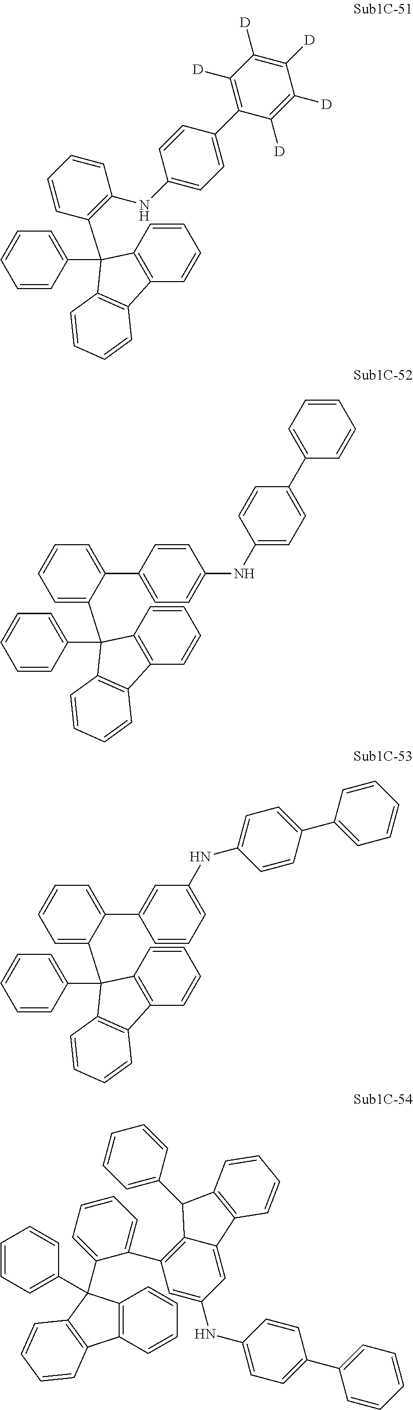 [SMILES: [2H]c1c([2H])c([2H])c(-c2ccc(Nc3ccccc3C3(c4ccccc4)c4ccccc4-c4ccccc43)cc2)c([2H])c1[2H] ; c1ccc(-c2ccc(Nc3ccc(-c4ccccc4C4(c5ccccc5)c5ccccc5-c5ccccc54)cc3)cc2)cc1 ; c1ccc(-c2ccc(Nc3cccc(-c4ccccc4C4(c5ccccc5)c5ccccc5-c5ccccc54)c3)cc2)cc1 ; c1ccc(-c2ccc(Nc3cc4c(c(-c5ccccc5C5(c6ccccc6)c6ccccc6-c6ccccc65)c3)C(c3ccccc3)c3ccccc3-4)cc2)cc1]

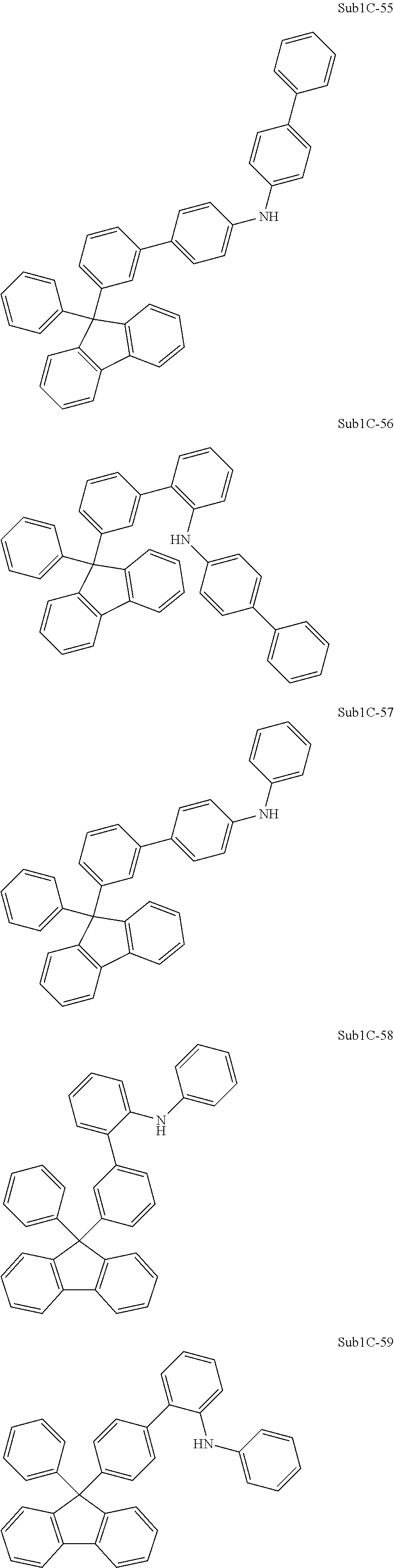

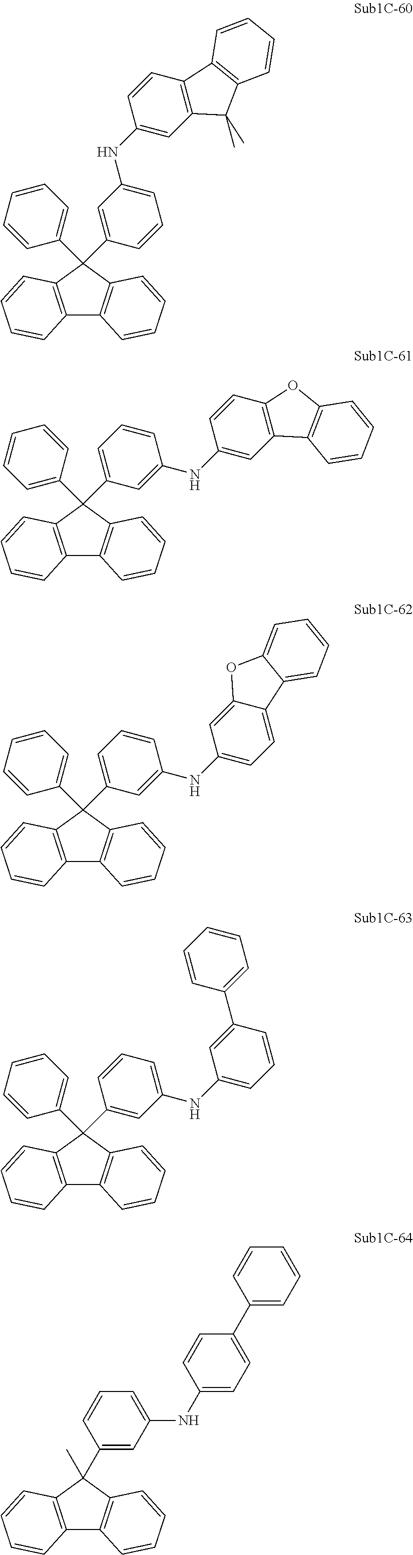 [SMILES: CC1(C)c2ccccc2-c2ccc(Nc3cccc(C4(c5ccccc5)c5ccccc5-c5ccccc54)c3)cc21 ; c1ccc(C2(c3cccc(Nc4ccc5oc6ccccc6c5c4)c3)c3ccccc3-c3ccccc32)cc1 ; c1ccc(C2(c3cccc(Nc4ccc5c(c4)oc4ccccc45)c3)c3ccccc3-c3ccccc32)cc1 ; c1ccc(-c2cccc(Nc3cccc(C4(c5ccccc5)c5ccccc5-c5ccccc54)c3)c2)cc1 ; CC1(c2cccc(Nc3ccc(-c4ccccc4)cc3)c2)c2ccccc2-c2ccccc21]

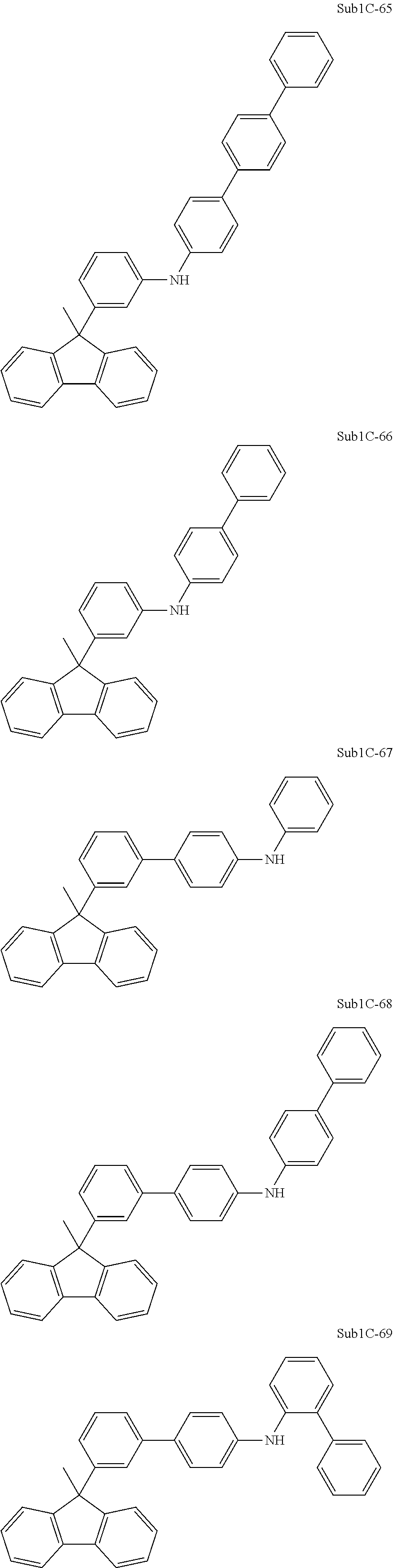 [SMILES: CC1(c2cccc(Nc3ccc(-c4ccc(-c5ccccc5)cc4)cc3)c2)c2ccccc2-c2ccccc21 ; CC1(c2cccc(Nc3ccc(-c4ccccc4)cc3)c2)c2ccccc2-c2ccccc21 ; CC1(c2cccc(-c3ccc(Nc4ccccc4)cc3)c2)c2ccccc2-c2ccccc21 ; CC1(c2cccc(-c3ccc(Nc4ccc(-c5ccccc5)cc4)cc3)c2)c2ccccc2-c2ccccc21 ; CC1(c2cccc(-c3ccc(Nc4ccccc4-c4ccccc4)cc3)c2)c2ccccc2-c2ccccc21]

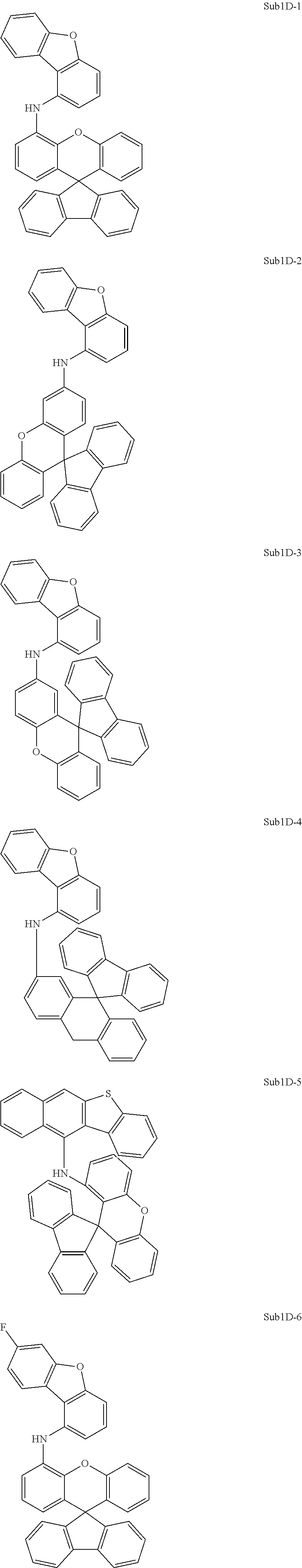

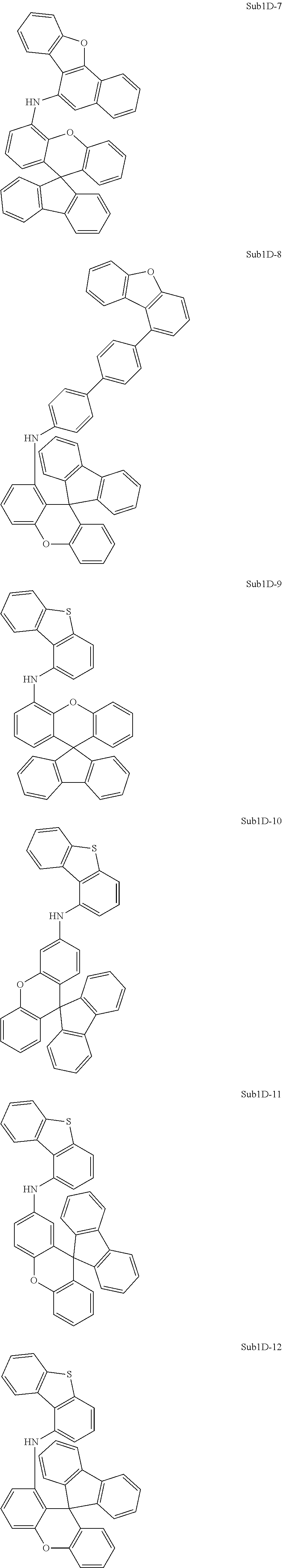

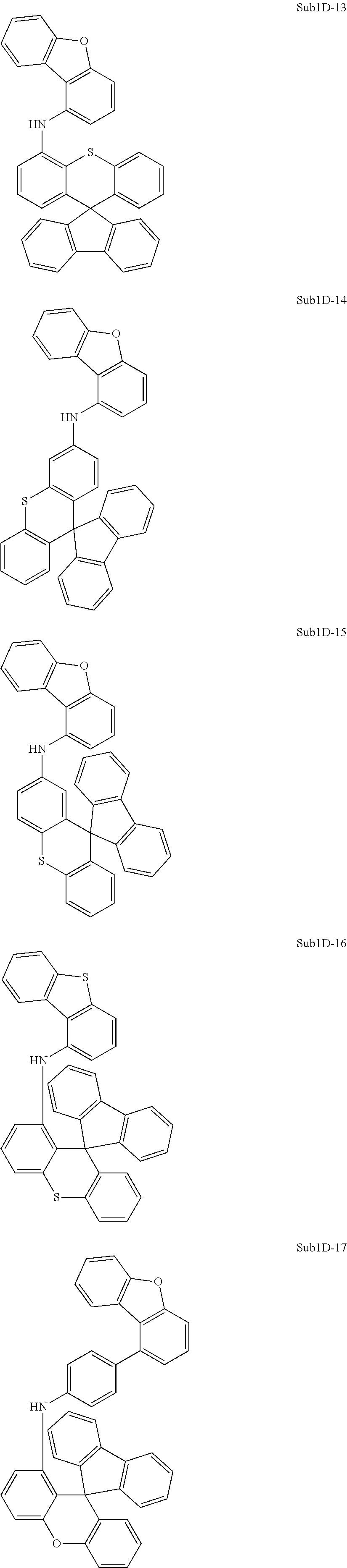

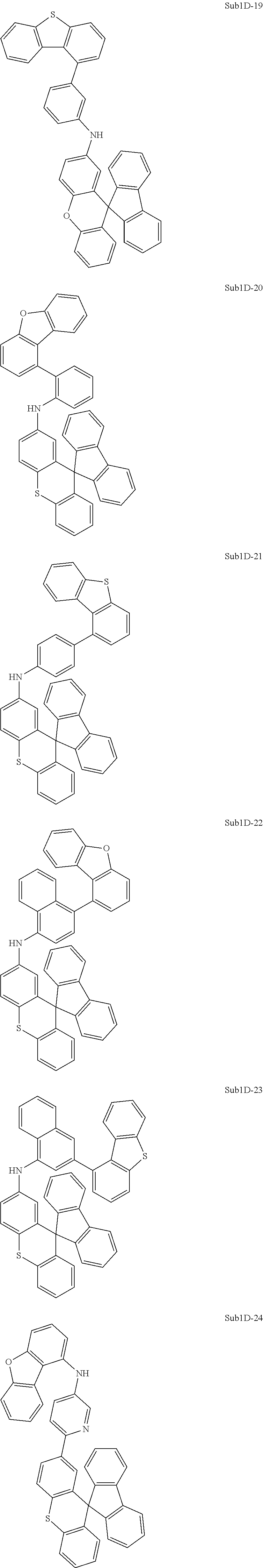

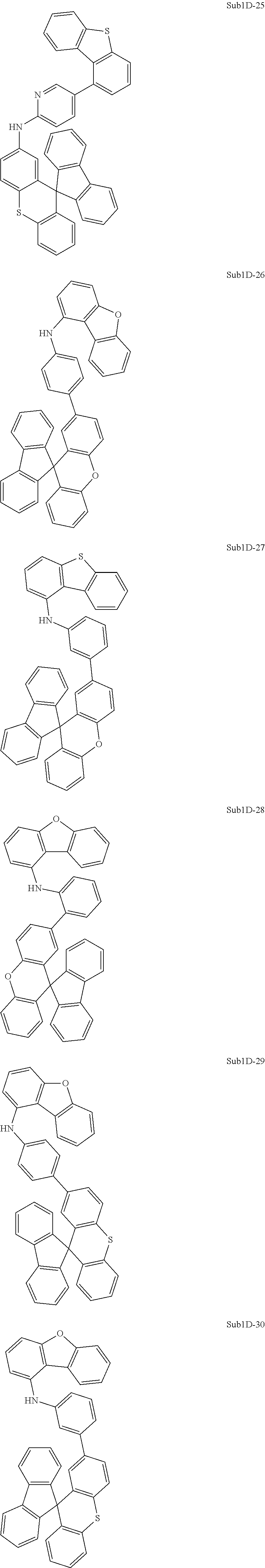

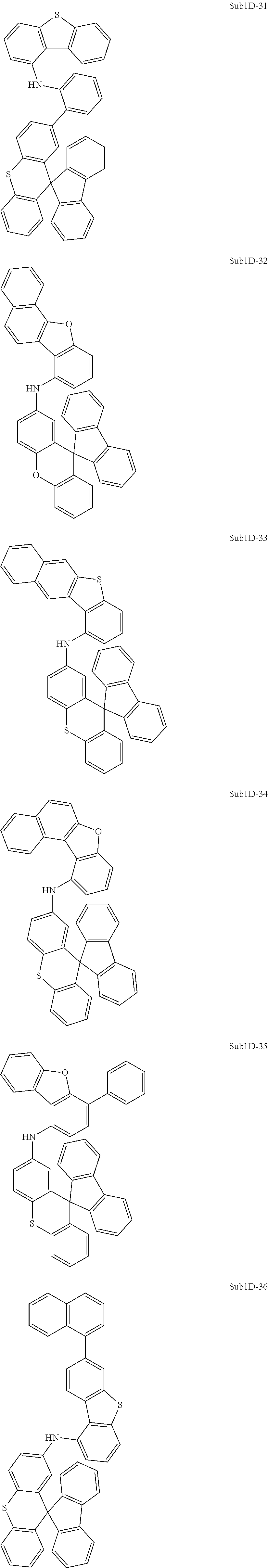 [SMILES: c1ccc(-c2ccc3c(c2)C2(c4ccccc4S3)c3ccccc3-c3ccccc32)c(Nc2cccc3sc4ccccc4c23)c1 ; c1ccc2c(c1)Oc1ccc(Nc3cccc4oc5c6ccccc6ccc5c34)cc1C21c2ccccc2-c2ccccc21 ; c1ccc2c(c1)Sc1ccc(Nc3cccc4sc5cc6ccccc6cc5c34)cc1C21c2ccccc2-c2ccccc21 ; c1ccc2c(c1)Sc1ccc(Nc3cccc4oc5ccc6ccccc6c5c34)cc1C21c2ccccc2-c2ccccc21 ; c1ccc(-c2ccc(Nc3ccc4c(c3)C3(c5ccccc5S4)c4ccccc4-c4ccccc43)c3c2oc2ccccc23)cc1 ; c1ccc2c(c1)Sc1ccc(Nc3cccc4sc5cc(-c6cccc7ccccc67)ccc5c34)cc1C21c2ccccc2-c2ccccc21]

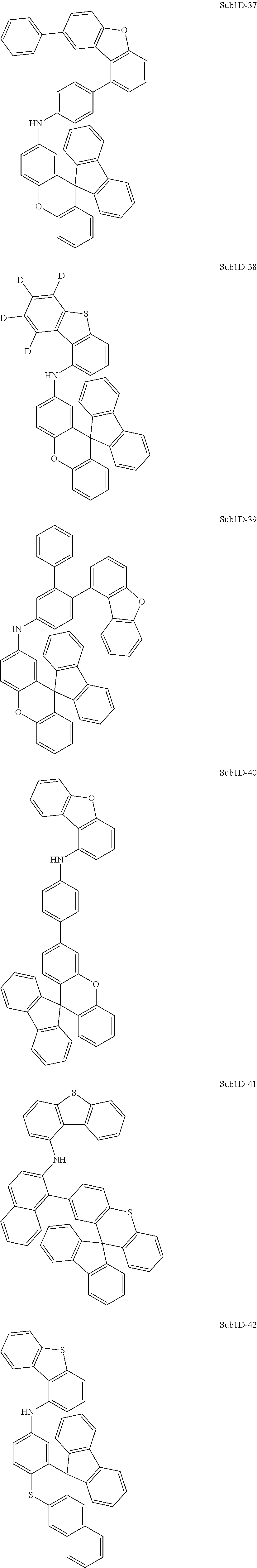

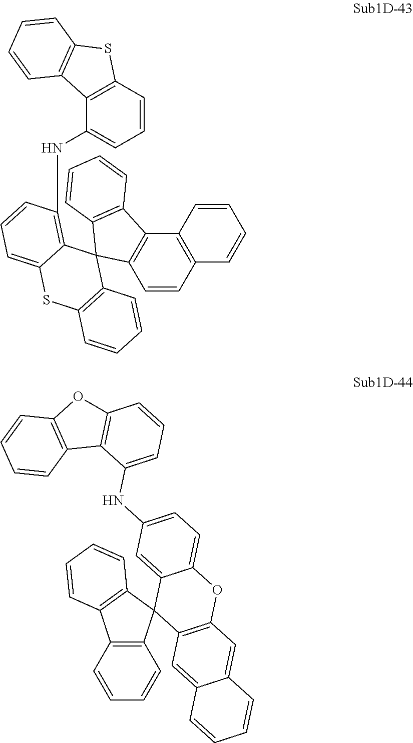 [SMILES: c1ccc2c(c1)Sc1cccc(Nc3cccc4sc5ccccc5c34)c1C21c2ccccc2-c2c1ccc1ccccc21 ; c1ccc2c(c1)-c1ccccc1C21c2cc(Nc3cccc4oc5ccccc5c34)ccc2Oc2cc3ccccc3cc21]

TABLE 1

| Com- | | Com- | |
|---|---|---|---|
| pound | FD-MS | pound | FD-MS |
| Sub1A-1 | m/z = 375.16(C₂₇H₂₁NO = 375.47) | Sub1A-2 | m/z = 375.16(C₂₇H₂₁NO = 375.47) |
| Sub1A-3 | m/z = 375.16(C₂₇H₂₁NO = 375.47) | Sub1A-4 | m/z = 391.14(C₂₇H₂₁NS = 391.53) |
| Sub1A-5 | m/z = 499.19(C₃₇H₂₅NO = 499.61) | Sub1A-6 | m/z = 499.19(C₃₇H₂₅NO = 499.61) |
| Sub1A-7 | m/z = 499.19(C₃₇H₂₅NO = 499.61) | Sub1A-8 | m/z = 499.19(C₃₇H₂₅NO = 499.61) |
| Sub1A-9 | m/z = 515.17(C₃₇H₂₅NS = 515.67) | Sub1A-10 | m/z = 497.18(C₃₇H₂₃NO = 497.60) |
| Sub1A-11 | m/z = 513.16(C₃₇H₂₃NS = 513.66) | Sub1A-12 | m/z = 451.19(C₃₃H₂₅NO = 451.57) |
| Sub1A-13 | m/z = 467.17(C₃₃H₂₅NS = 467.63) | Sub1A-14 | m/z = 451.19(C₃₃H₂₅NO = 451,57) |
| Sub1A-15 | m/z = 467.17(C₃₃H₂₅NS = 467.63) | Sub1A-16 | m/z = 451.19(C₃₃H₂₅NO = 451.57) |
| Sub1A-17 | m/z = 467.17(C₃₃H₂₅NS = 467.63) | Sub1A-18 | m/z = 451.19(C₃₃H₂₅NO = 451,57) |
| Sub1A-19 | m/z = 451.19(C₃₃H₂₅NO = 451.57) | Sub1A-20 | m/z = 451.19(C₃₃H₂₅NO = 451.57) |
| Sub1A-21 | m/z = 451.19(C₃₃H₂₅NO = 451.57) | Sub1A-22 | m/z = 467.17(C₃₃H₂₅NS = 467.63) |
| Sub1A-23 | m/z = 467.17(C₃₃H₂₅NS = 467.63) | Sub1A-24 | m/z = 467.17(C₃₃H₂₅NS = 467.63) |
| Sub1A-25 | m/z = 501.21(C₃₇H₂₇NO = 501.63) | Sub1A-26 | m/z = 517.19(C₃₇H₂₇NS = 517.69) |
| Sub1A-27 | m/z = 501.21(C₃₇H₂₇NO = 501.63) | Sub1A-28 | m/z = 517.19(C₃₇H₂₇NS = 517.69) |
| Sub1A-29 | m/z = 501.21(C₃₇H₂₇NO = 501.63) | Sub1A-30 | m/z = 517.19(C₃₇H₂₇NS = 517.69) |
| Sub1A-31 | m/z = 452.19(C₃₂H₂₄N₂O = 452.56) | Sub1A-32 | m/z = 583.23(C₄₂H₃₃NS = 583.79) |
| Sub1A-33 | m/z = 525.21(C₃₉H₂₇NO = 525.65) | Sub1A-34 | m/z = 519.20(C₃₇H₂₁D₄NS = 519.70) |
| Sub1A-35 | m/z = 527.22(C₃₉H₂₉NO = 527.67) | Sub1A-36 | m/z = 543.20(C₃₉H₂₉NS = 543.73) |
| Sub1A-37 | m/z = 527.22(C₃₉H₂₉NO = 527.67) | Sub1A-38 | m/z = 543.20(C₃₉H₂₉NS = 543.73) |
| Sub1A-39 | m/z = 543.20(C₃₉H₂₉NS = 543.73) | Sub1A-40 | m/z = 527.22(C₃₉H₂₉NO = 527.67) |
| Sub1A-41 | m/z = 527.22(C₃₉H₂₉NO = 527.67) | Sub1A-42 | m/z = 527.22(C₃₉H₂₉NO = 527.67) |
| Sub1A-43 | m/z = 543.20(C₃₉H₂₉NS = 543.73) | Sub1A-44 | m/z = 543.20(C₃₉H₂₉NS = 543.73) |
| Sub1A-45 | m/z = 452.19(C₃₂H₂₄N₂O = 452.56) | Sub1A-46 | m/z = 441.16(C₃₁H₂₃NS = 441.59) |
| Sub1A-47 | m/z = 441.16(C₃₁H₂₃NS = 441.59) | Sub1A-48 | m/z = 425.18(C₃₁H₂₃NO = 425.53) |
| Sub1A-49 | m/z = 425.18(C₃₁H₂₃NO = 425.53) | Sub1A-50 | m/z = 467.17(C₃₃H₂₅NS = 467.63) |
| Sub1A-51 | m/z = 577.24(C₄₃H₃₁NO = 577.73) | Sub1A-52 | m/z = 573.21(C₄₃H₂₇NO = 573.70) |
| Sub1A-53 | m/z = 497.18(C₃₇H₂₃NO = 497.60) | Sub1A-54 | m/z = 497.18(C₃₇H₂₃NO = 497.60) |
| Sub1A-55 | m/z = 513.16(C₃₇H₂₃NS = 513.66) | Sub1A-56 | m/z = 441.16(C₃₁H₂₃NS = 441.59) |
| Sub1A-57 | m/z = 549.21(C₄₁H₂₇NO = 549.67) | Sub1A-58 | m/z = 511.20(C₃₁H₂₅N = 411.55) |
| Sub1A-59 | m/z = 309.12(C₂₂H₁₅NO = 309.37) | | |
| Sub1B-1 | m/z = 335.13(C₂₄H₁₇NO = 335.41) | Sub1B-2 | m/z = 427.19(C₃₁H₂₅NO = 427.55) |
| Sub1B-3 | m/z = 561.21(C₄₂H₂₇NO = 561.68) | Sub1B-4 | m/z = 461.18(C₃₄H₂₃NO = 461,56) |
| Sub1B-5 | m/z = 461.18(C₃₄H₂₃NO = 461.56) | Sub1B-6 | m/z = 435.16(C₂₄H₁₇NO = 435.53) |
| Sub1B-7 | m/z = 335.13(C₂₄H₁₇NO = 335.41) | Sub1B-8 | m/z = 335.13(C₃₂H₂₁NO = 335.41) |
| Sub1B-9 | m/z = 527.22(C₃₉H₂₉NO = 527.67) | Sub1B-10 | m/z = 511.19(C₃₈H₂₅NO = 511.62) |
| Sub1B-11 | m/z = 487.19(C₃₆H₂₅NO = 487.60) | Sub1B-12 | m/z = 537.21(C₄₆H₂₇NO = 537.66) |
| Sub1B-13 | m/z = 435.16(C₃₂H₂₁NO = 435.53) | Sub1B-14 | m/z = 336.13(C₂₃H₁₆N₂O = 336.39) |
| Sub1B-15 | m/z = 452.15(C₃₁H₂₀N₂O₂ = 452.51) | Sub1B-16 | m/z = 500.19(C₃₆H₂₄N₂O = 500.60) |
| Sub1B-17 | m/z = 465.20(C₃₄H₁₉D₄NO = 465.59) | Sub1B-18 | m/z = 482.11(C₃₁H₁₈N₂O₂S = 482.56) |
| Sub1B-19 | m/z = 567.17(C₄₀H₂₅NOS = 567.71) | Sub1B-20 | m/z = 351.11(C₂₄H₁₇NS = 351.47) |
| Sub1B-21 | m/z = 475.14(C₃₄H₂₁NS = 475.61) | Sub1B-22 | m/z = 477.16(C₃₄H₂₃NS = 477.63) |
| Sub1B-23 | m/z = 577.19(C₄₂H₂₇NS = 577.75) | Sub1B-24 | m/z = 477.16(C₃₄H₂₃NS = 477.63) |
| Sub1B-25 | m/z = 467.17(C₃₃H₂₅NS = 467.63) | Sub1B-26 | m/z = 427.14(C₃₀H₂₁NS = 427.57) |
| Sub1B-27 | m/z = 441.12(C₃₀H₁₉NOS = 441.55) | Sub1B-28 | m/z = 427.14(C₃₀H₂₁NS = 427.57) |
| Sub1B-29 | m/z = 457.10(C₃₀H₁₉NS₂ = 457.61) | Sub1B-30 | m/z = 527.17(C₃₈H₂₅NS = 527.69) |
| Sub1B-31 | m/z = 517.15(C₃₅H₂₃NOS = 517.65) | Sub1B-32 | m/z = 352.10(C₂₃H₁₆N₂S = 352.46) |
| Sub1B-33 | m/z = 451.14(C₃₂H₂₁NS = 451.59) | Sub1B-34 | m/z = 553.19(C₄₀H₂₇NS = 553.72) |
| Sub1B-35 | m/z = 503.17(C₃₆H₂₅NS = 503.66) | Sub1B-36 | m/z = 451.14(C₃₂H₂₁NS = 451.59) |
| Sub1B-37 | m/z = 592.20(C₄₂H₂₈N₂S = 592.76) | Sub1B-38 | m/z = 583.14(C₄₀H₂₅NS₂ = 583.77) |
| Sub1B-39 | m/z = 385.15(C₂₈H₁₉NO = 385.47) | Sub1B-40 | m/z = 352.10(C₂₃H₁₆N₂S = 352.46) |
| Sub1B-41 | m/z = 401.12(C₂₈H₁₉NS = 401.53) | Sub1B-42 | m/z = 477.16(C₃₄H₂₃NS = 477.63) |
| Sub1B-43 | m/z = 507.11(C₃₄H₂₁NS₂ = 507.67) | Sub1B-44 | m/z = 553.19(C₄₀H₂₇NS = 553.72) |
| Sub1B-45 | m/z = 527.17(C₃₈H₂₅NS = 527.69) | Sub1B-46 | m/z = 517.15(C₃₆H₂₃NOS = 517.65) |
| Sub1B-47 | m/z = 498.09(C₃₁H₁₈N₂OS₂ = 498.62) | Sub1B-48 | m/z = 427.14(C₃₀H₂₁NS = 427.57) |
| Sub1B-49 | m/z = 468.13(C₃₁H₂₀N₂OS = 468.57) | Sub1B-50 | m/z = 385.15(C₂₈H₁₉NO = 385.47) |
| Sub1B-51 | m/z = 441.12(C₃₀H₁₉NOS = 441.55) | Sub1B-52 | m/z = 367.14(C₂₅H₂₁NS = 367.51) |
| Sub1B-53 | m/z = 577.24(C₄₃H₃₁NO = 577.73) | Sub1B-54 | m/z = 351.16(C₂₅H₂₁NO = 351.45) |
| Sub1B-55 | m/z = 435.16(C₃₂H₂₁NO = 435.53) | Sub1B-56 | m/z = 451.19(C₃₃H₂₅NO = 451.57) |
| Sub1B-57 | m/z = 427.19(C₃₁H₂₅NO = 427.55) | Sub1B-58 | m/z = 441.12(C₃₀H₁₉NOS = 441.55) |
| Sub1B-59 | m/z = 477.21(C₃₅H₂₇NO = 477.61) | Sub1B-60 | m/z = 528.22(C₃₈H₂₈N₂O = 528.66) |
| Sub1B-61 | m/z = 375.13(C₂₆H₁₇NO₂ = 375.43) | Sub1B-62 | m/z = 609.25(C₄₄H₃₅NS = 609.83) |
| Sub1B-63 | m/z = 533.18(C₃₇H₂₇NOS = 533.69) | Sub1B-64 | m/z = 507.17(C₃₅H₂₅NOS = 507.65) |
| Sub1B-65 | m/z = 572.16(C₃₈H₂₄N₂O₂S = 572.68) | Sub1B-66 | m/z = 391.10(C₂₆H₁₇NOS = 391,49) |
| Sub1B-67 | m/z = 724.25(C₅₁H₃₆N₂OS = 724.92) | Sub1B-68 | m/z = 527.22(C₃₉H₂₉NO = 527.67) |
| Sub1B-69 | m/z = 441.12(C₃₀H₁₀NOS = 441.55) | Sub1B-70 | m/z = 493.19(C₃₅H₂₇NS = 493.67) |
| Sub1B-71 | m/z = 467.17(C₃₃H₂₅NS = 467,63) | Sub1B-72 | m/z = 556.18(C₃₈H₂₄N₂O₃ = 556,62) |
| Sub1B-73 | m/z = 475.16(C₃₄H₂₁NO₂ = 475.55) | Sub1B-74 | m/z = 567.22(C₄₁H₂₉NO₂ = 567.69) |
| Sub1B-75 | m/z = 627.26(C₄₇H₃₃NO = 627.79) | Sub1B-76 | m/z = 527.22(C₃₉H₂₉NO = 527.67) |
| Sub1B-77 | m/z = 335.13(C₂₄H₁₇NO = 335.41) | Sub1B-78 | m/z = 467.17(C₃₃H₂₅NS = 467.63) |
| Sub1B-79 | m/z = 501.17(C₄₇H₂₃NO₂ = 501.59) | Sub1B-80 | m/z = 351.11(C₂₄H₁₇NS = 351.47) |
| Sub1B-81 | m/z = 351.11(C₂₄H₁₇NS = 351.47) | Sub1B-82 | m/z = 516.17(C₃₆H₂₄N₂S = 516.66) |
| Sub1B-83 | m/z = 708.31(C₅₂H₄₀N₂O = 708.91) | Sub1B-84 | m/z = 401.12(C₂₈H₁₉NS = 401.53) |
| Sub1B-85 | m/z = 401.12(C₂₈H₁₉NS = 401.53) | Sub1B-86 | m/z = 351.11(C₂₄H₁₇NS = 351,47) |
| Sub1B-87 | m/z = 518.18(C₃₆H₂₆N₂S = 518.68) | Sub1B-88 | m/z = 427.14(C₃₀H₂₁NS = 427.57) |
| Sub1B-89 | m/z = 461.18(C₃₄H₂₃NO = 461.56) | Sub1B-90 | m/z = 461.18(C₃₄H₂₃NO = 461.56) |
| Sub1B-91 | m/z = 335.13(C₂₄H₁₇NO = 335.41) | Sub1B-92 | m/z = 561.21(C₄₂H₂₇NO = 561.68) |
| Sub1B-93 | m/z = 461.18(C₃₄H₂₃NO = 461.56) | Sub1B-94 | m/z = 353.12(C₂₄H_{16F}NO = 353.40) |
| Sub1B-95 | m/z = 391.19(C₂₈H₂₃NO = 391.51) | Sub1B-96 | m/z = 259.10(C₁₈H₁₃NO = 259.31) |
| Sub1B-97 | m/z = 275.08(C₁₈H₁₃NS = 275.37) | | |
| Sub1C-1 | m/z = 525.25(C₄₀H₃₁N = 525.7) | Sub1C-2 | m/z = 485.21(C₃₇H₂₇N = 485.63) |
| Sub1C-3 | m/z = 485.21(C₃₇H₂₇N = 485.63) | Sub1C-4 | m/z = 459.2(C₃₅H₂₅N = 459.59) |
| Sub1C-5 | m/z = 409.18(C₃₁H₂₃N = 409.53) | Sub1C-6 | m/z = 409.18(C₃₁H₂₃N = 409.53) |
| Sub1C-7 | m/z = 499.19(C₃₇H₂₅NO = 499.61) | Sub1C-8 | m/z = 641.22(C₄₇H₃₁NS = 641.83) |
| Sub1C-9 | m/z = 624.26(C₄₇H₃₂N₂ = 624.79) | Sub1C-10 | m/z = 499.19(C₃₇H₂₅NO = 499.61) |
| Sub1C-11 | m/z = 681.21(C₄₉H₃₁NOS = 681.85) | Sub1C-12 | m/z = 674.27(C₅₁₁H₃N₂ = 674.85) |
| Sub1C-13 | m/z = 525.25(C₄₀H₃₁N = 525.7) | Sub1C-14 | m/z = 730.27(C₅₂H₃₄N₄O = 730.87) |
| Sub1C-15 | m/z = 515.17(C₃₇H₂₅NS = 515.67) | Sub1C-16 | m/z = 624.26(C₄₇H₃₂N₂ = 624.79) |
| Sub1C-17 | m/z = 525.25(C₄₀H₃₁N = 525.7) | Sub1C-18 | m/z = 499.19(C₃₇H₂₅NO = 499.61) |
| Sub1C-19 | m/z = 515.17(C₃₇H₂₅NS = 515.67) | Sub1C-20 | m/z = 490.25(C₃₇H₂₂D₅N = 490.66) |
| Sub1C-21 | m/z = 525.25(C₄₀H₃₁N = 525.7) | Sub1C-22 | m/z = 561.25(C₄₃H₃₁N = 561.73) |
| Sub1C-23 | m/z = 726.3(C₅₅H₃₈N₂ = 726.92) | Sub1C-24 | m/z = 409.18(C₃₁H₂₃N = 409.53) |
| Sub1C-25 | m/z = 561.25(C₄₃H₃₁N = 561.73) | Sub1C-26 | m/z = 601.28(C₄₆H₃₅N = 601.79) |
| Sub1C-27 | m/z = 525.25(C₄₀H₃₁N = 525,7) | Sub1C-28 | m/z = 525.25(C₄₀H₃₁N = 525,7) |
| Sub1C-29 | m/z = 525.25(C₄₀H₃₁N = 525.7) | Sub1C-30 | m/z = 601.28(C₄₆H₃₅N = 601.79) |
| Sub1C-31 | m/z = 651.29(C₅₀H₃₇N = 651.85) | Sub1C-32 | m/z = 575.26(C₄₄H₃₃N = 575.76) |
| Sub1C-33 | m/z = 535.23(C₄₁H₂₉N = 535.69) | Sub1C-34 | m/z = 525.25(C₄₀H₃₁N = 525.7) |
| Sub1C-35 | m/z = 561.25(C₄₃H₃₁N = 561.73) | Sub1C-36 | m/z = 485.21(C₃₇H₂₇N = 485.63) |
| Sub1C-37 | m/z = 566.28(C₄₃H₂₆D₅N = 566.76) | Sub1C-38 | m/z = 707.26(C₅₂H₃₇NS = 707.94) |
| Sub1C-39 | m/z = 459.2(C₃₅H₂₅N = 459.59) | Sub1C-40 | m/z = 409.18(C₃₁H₂₃N = 409.53) |
| Sub1C-41 | m/z = 485.21(C₃₇H₂₇N = 485.63) | Sub1C-42 | m/z = 485.21(C₃₇H₂₇N = 485.63) |
| Sub1C-43 | m/z = 661.28(C₅₁H₃₅N = 661.85) | Sub1C-44 | m/z = 624.26(C₄₇H₃₂N₂ = 624.79) |
| Sub1C-45 | m/z = 730.27(C₅₂H₃N₄O = 730.87) | Sub1C-46 | m/z = 515.17(C₃₇H₂₅NS = 515,67) |
| Sub1C-47 | m/z = 624.26(C₄₇H₃₂N₂ = 624.79) | Sub1C-48 | m/z = 525.25(C₄₀H₃₁N = 525.7) |
| Sub1C-49 | m/z = 499.19(C₃₇H₂₅NO = 499.61) | Sub1C-50 | m/z = 515.17(C₃₇H₂₅NS = 515.67) |
| Sub1C-51 | m/z = 490.25(C₃₇H₂₂D₅N = 490.66) | Sub1C-52 | m/z = 561.25(C₄₃H₃₁N = 561.73) |
| Sub1C-53 | m/z = 561.25(C₄₃H₃₁N = 561.73) | Sub1C-54 | m/z = 726.3(C₅₅H₃₈N₂ = 726.92) |
| Sub1C-55 | m/z = 561.25(C₄₃H₃₁N = 561.73) | Sub1C-56 | m/z = 561.25(C₄₃H₃₁N = 561.73) |
| Sub1C-57 | m/z = 485.21(C₃₇H₂₇N = 485.63) | Sub1C-58 | m/z = 485.21(C₃₇H₂₇N = 485.63) |
| Sub1C-59 | m/z = 485.21(C₃₇H₂₇N = 485.63) | Sub1C-60 | m/z = 525.25(C₄₀H₃₁N = 525.7) |
| Sub1C-61 | m/z = 499.19(C₃₇H₂₅NO = 499.61) | Sub1C-62 | m/z = 499.19(C₃₇H₂₅NO = 499.61) |
| Sub1C-63 | m/z = 485.21(C₃₇H₂₇N = 485.63) | Sub1C-64 | m/z = 423.2(C₃₂H₂₅N = 423.56) |
| Sub1C-65 | m/z = 499.23(C₃₈H₂₉N = 499.66) | Sub1C-66 | m/z = 499.23(C₃₈H₂₉N = 499.66) |
| Sub1C-67 | m/z = 423.2(C₃₂H₂₅N = 423.56) | Sub1C-68 | m/z = 423.2(C₃₂H₂₅N = 423.56) |
| Sub1C-69 | m/z = 499.23(C₃₈H₂₉N = 499.66) | | |
| Sub1D-1 | m/z = 513.17(C₃₇H₂₃NO₂ = 513.60) | Sub1D-2 | m/z = 513.17(C₃₇H₂₃NO₂ = 513.60) |
| Sub1D-3 | m/z = 513.17(C₃₇H₂₃NO₂ = 513.60) | Sub1D-4 | m/z = 513.17(C₃₇H₂₃NO₂ = 513.60) |
| Sub1D-5 | m/z = 579.17(C₄₁H₂₅NOS = 579.72) | Sub1D-6 | m/z = 531.16(C₃₇H₂₂FNO₂ = 531.59) |
| Sub1D-7 | m/z = 563.19(C₄₁H₂₅NO₂ = 563.66) | Sub1D-8 | m/z = 665.24(C₄₉H₃₁NO₂ = 665.79) |
| Sub1D-9 | m/z = 529.15(C₃₇H₂₃NOS = 529.66) | Sub1D-10 | m/z = 529.15(C₃₇H₂₃NOS = 529.66) |
| Sub1D-11 | m/z = 529.15(C₃₇H₂₃NOS = 529.66) | Sub1D-12 | m/z = 529.15(C₃₇H₂₃NOS = 529.66) |
| Sub1D-13 | m/z = 529.15(C₃₇H₂₃NOS = 529.66) | Sub1D-14 | m/z = 529.15(C₃₇H₂₃NOS = 529.66) |
| Sub1D-15 | m/z = 529.15(C₃₇H₂₃NOS = 529.66) | Sub1D-16 | m/z = 529.15(C₃₇H₂₃NOS = 529.66) |
| Sub1D-17 | m/z = 545.13(C₃₇H₂₃NS₂ = 545.72) | Sub1D-18 | m/z = 589.20(C₄₃H₂₇NO₂ = 589.69) |
| Sub1D-19 | m/z = 605.18(C₄₃H₂₇NOS = 605.76) | Sub1D-20 | m/z = 605.18(C₄₃H₂₇NOS = 605.76) |
| Sub1D-21 | m/z = 621.16(C₄₃H₂₇NS₂ = 621.82) | Sub1D-22 | m/z = 655.20(C₄₇H₂₉NOS = 655.82) |
| Sub1D-23 | m/z = 671.17(C₄₇H₂₉NS₂ = 671,88) | Sub1D-24 | m/z = 606.18(C₄₂H₂₆N₂OS = 606.74) |
| Sub1D-25 | m/z = 622.15(C₄₂H₂₆N₂S₂ = 622.80) | Sub1D-26 | m/z = 589.20(C₄₃H₂₇NO₂ = 589.69) |
| Sub1D-27 | m/z = 605.18(C₄₃H₂₇NOS = 605.76) | Sub1D-28 | m/z = 589.20(C₄₃H₂₇NO₂ = 589.69) |
| Sub1D-29 | m/z = 605.18(C₄₃H₂₇NOS = 605.76) | Sub1D-30 | m/z = 605.18(C₄₃H₂₇NOS = 605.76) |
| Sub1D-31 | m/z = 621.16(C₄₃H₂₇NS₂ = 621.82) | Sub1D-32 | m/z = 563.19(C₄₁H₂₅NO₂ = 563.66) |
| Sub1D-33 | m/z = 595.14(C₄₁H₂₅NS₂ = 595.78) | Sub1D-34 | m/z = 579.17(C₄₁H₂₅NOS = 579.72) |
| Sub1D-35 | m/z = 605.18(C₄₃H₂₇NOS = 605.76) | Sub1D-36 | m/z = 671.17(C₄₇H₂₉NS₂ = 671.88) |
| Sub1D-37 | m/z = 665.24(C₄₉H₃₁NO₂ = 665.79) | Sub1D-38 | m/z = 549.15(C₃₇H₁₉D₄NS₂ = 549.74) |
| Sub1D-39 | m/z = 665.24(C₄₉H₃₁NO₂ = 665.79) | Sub1D-40 | m/z = 589.20(C₄₃H₂₇NO₂ = 589.69) |
| Sub1D-41 | m/z = 671.17(C₄₇H₂₉NS₂ = 671.88) | Sub1D-42 | m/z = 595.14(C₄₁H₂₅NS₂ = 595.78) |
| Sub1D-42 | m/z = 595.14(C₄₁H₂₅NS₂ = 595.78) | Sub1D-44 | m/z = 563.19(C₄₁H₂₅NO₂ = 563.66) |

### Synthesis Example of Sub 2

Sub 2 of Reaction Scheme 1 may be synthesized by the following Reaction Scheme 3, but are not limited thereto.

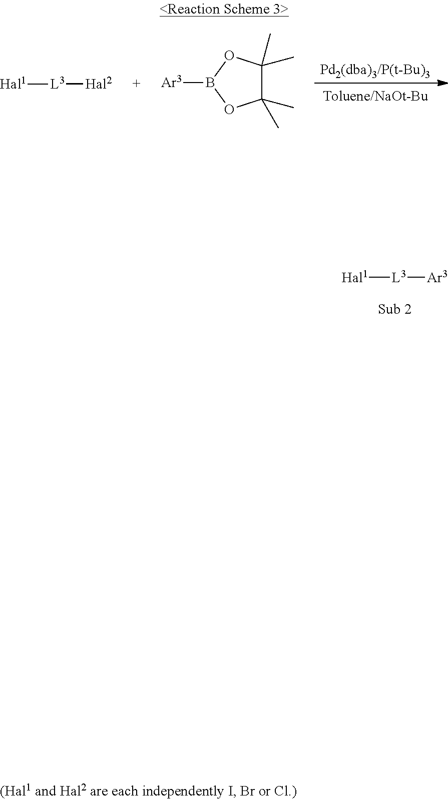

### 1. Synthesis Example of Sub2B-1

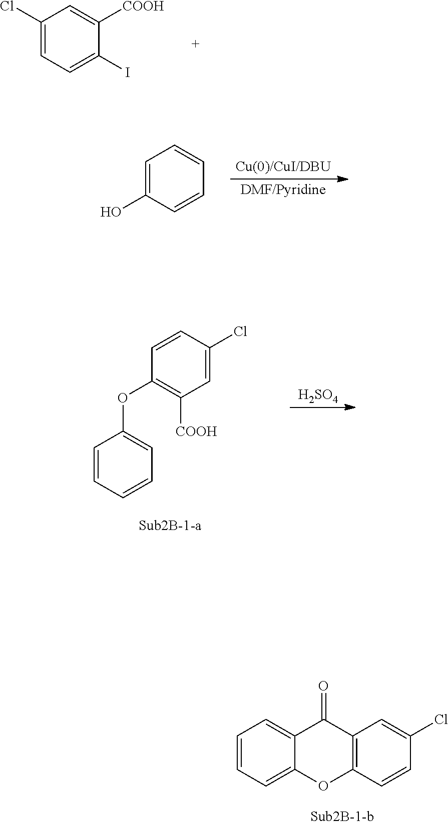

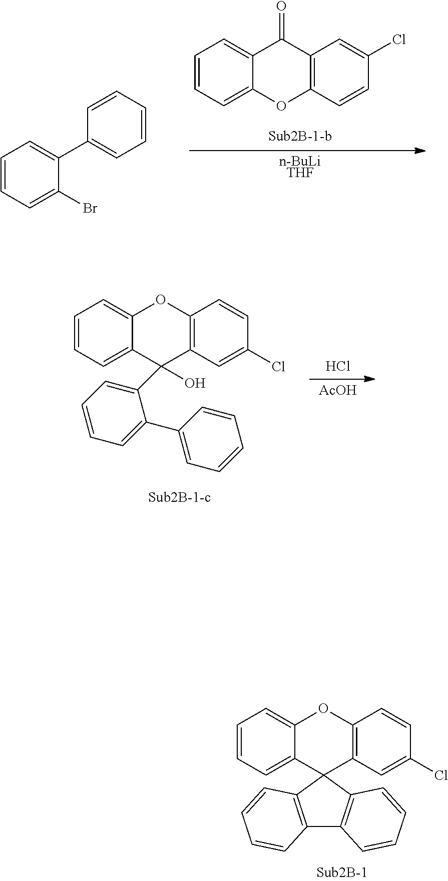

### (1) Synthesis Example of Sub2B-1-a

After 5-chloro-2-iodobenzoic acid (50.0 g, 177 mmol), phenol (33.3 g, 354 mmol), 1,8-diazabicyclo[5.4.0]undec-7-ene (DBU) (80.9 g, 531 mmol), pyridine (2.9 mL), Copper powder (1.5 g, 23 mmol) and CuI (1.5 g, 7.97 mmol) were placed in a round-bottom flask, and DMF (1.2 L) was added thereto, the mixture was refluxed for 3 hours. When the reaction was complete, the reaction product was cooled to room temperature and then 3M HCl was added the reaction product until precipitation was complete. Then, the precipitate was washed with water and dried to obtain 38.3 g (yield 87%) of the product.

### (2) Synthesis Example of Sub2B-1-b

After Sub2B-1-a (38.3 g, 154 mmol) were placed in a round-bottom flask and H₂SO₄ (1.1 mL, 21.5 mmol) was added thereto, the mixture was refluxed until all the starting materials were dissolved. When all the starting materials were dissolved, the mixture was cooled to room temperature and then ice water was added to precipitate. Then, the precipitate is washed with water, dried and dissolved with CH₂Cl₂. Thereafter, the solution was separated by silica gel column and recrystallized to obtain 23.09 g (yield 65%) of the product.

### (3) Synthesis Example of Sub2B-1-c

2-bromo-1,1′-biphenyl (23.3 g, 99.7 mmol) was dissolved in THF (270 mL) in a round-bottom flask under a nitrogen atmosphere and the mixture was cooled to −78° C. Thereafter, n-BuLi (40 mL) was slowly titrated to the mixture, followed by stirring for 30 minutes. Then, after dissolving Sub2B-1-b (23 g, 99.7 mmol) in THF (140 mL) and the solution was slowly titrated to the round bottom flask being the reaction in progress. Then, the reaction mixture was stirred at −78° C. for 1 hour, and then slowly raised to room temperature. When the reaction was completed, the reaction product was extracted with ethyl acetate and water. Then, an organic layer was dried over MgSO₄ and concentrated. Then, the concentrate was separated by a silica gel column and recrystallized to obtain 32.6 g (yield 85%) of the product.

### (4) Synthesis Example of Sub2B-1

Sub2B-1-c (32 g, 84.7 mmol), acetic acid (208 mL) and concentrated hydrochloric acid (34.6 mL) were placed in a round-bottom flask and the mixture was stirred at 60-80° C. under nitrogen atmosphere for 3 hours. When the reaction was completed, the reaction product was extracted with CH₂Cl₂ and water. Then, an organic layer was dried over MgSO₄ and concentrated. Then, the concentrate was separated by a silica gel column and recrystallized to obtain 27.7 g (yield 91%) of the product.

### 2. Synthesis Example of Sub2B-11

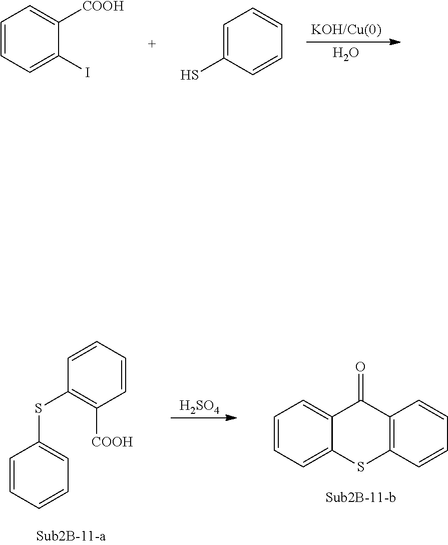

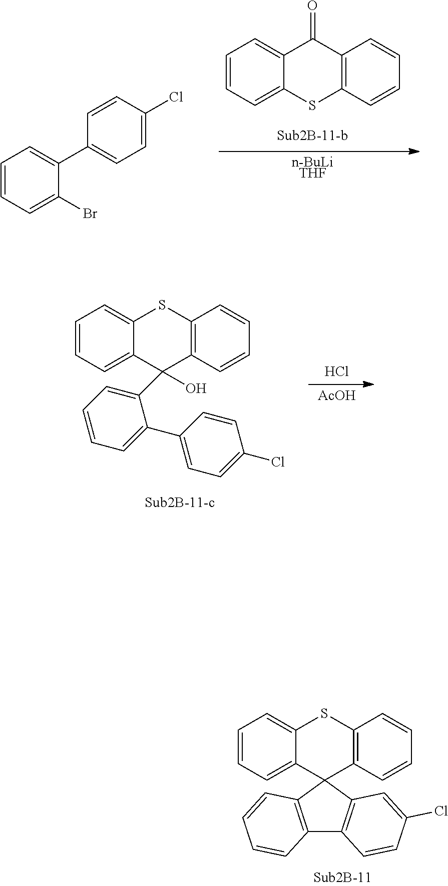

### (1) Synthesis Example of Sub2B-11-a

After 2-iodobenzoic acid (50.0 g, 202 mmol), thiophenol (22.2 g, 202 mmol), potassium hydroxide (56.6 g, 1008 mmol) and Copper powder (1.3 g, 20.2 mmol) were placed in a round-bottom flask and water (1.3 L) was added thereto, the mixture was refluxed for 12 hours. When the reaction was complete, the reaction product was cooled to room temperature and then 3M HCl was added the reaction product until precipitation was complete. Then, the precipitate was washed with water and dried to obtain 41.3 g (yield 89%) of the product.

### (2) Synthesis Example of Sub2B-11-b

After Sub2B-11-a (41.3 g, 179 mmol) were placed in a round-bottom flask and H₂SO₄ (1.3 mL) was added thereto, the mixture was refluxed until all the starting materials were dissolved. When all the starting materials were dissolved, the mixture was cooled to room temperature and then ice water was added to precipitate. Then, the precipitate is washed with water, dried and dissolved with CH₂Cl₂. Thereafter, the solution was separated by silica gel column and recrystallized to obtain 25.9 g (yield 68%) of the product.

### (3) Synthesis Example of Sub2B-11-c

2-bromo-4′-chloro-1,1′-biphenyl (32.6 g, 122 mmol) was dissolved in THF in a round-bottom flask under a nitrogen atmosphere and the mixture was cooled to −78° C. Thereafter, n-BuLi (49 mL) was slowly titrated to the mixture, followed by stirring for 30 minutes. Then, after dissolving Sub2B-11-b (25.9 g, 122 mmol) in THF and the solution was slowly titrated to the round bottom flask being the reaction in progress. Then, the reaction mixture was stirred at −78° C. for 1 hour, and then slowly raised to room temperature. When the reaction was completed, the reaction product was extracted with ethyl acetate and water. Then, an organic layer was dried over MgSO₄ and concentrated. Then, the concentrate was separated by a silica gel column and recrystallized to obtain 40.1 g (yield 82%) of the product.

### (4) Synthesis Example of Sub2B-11

Sub2B-11-c (40.1 g, 100 mmol), acetic acid (250 mL) and concentrated hydrochloric acid (40 mL) were placed in a round-bottom flask and the mixture was stirred at 60-80° C. under nitrogen atmosphere for 3 hours. When the reaction was completed, the reaction product was extracted with CH₂Cl₂ and water. Then, an organic layer was dried over MgSO₄ and concentrated. Then, the concentrate was separated by a silica gel column and recrystallized to obtain 31.8 g (yield 83%) of the product.

Compounds belong to Sub 2 are as follows, but are not limited thereto, and FD-MS values of the compounds are shown in Table 2 below.

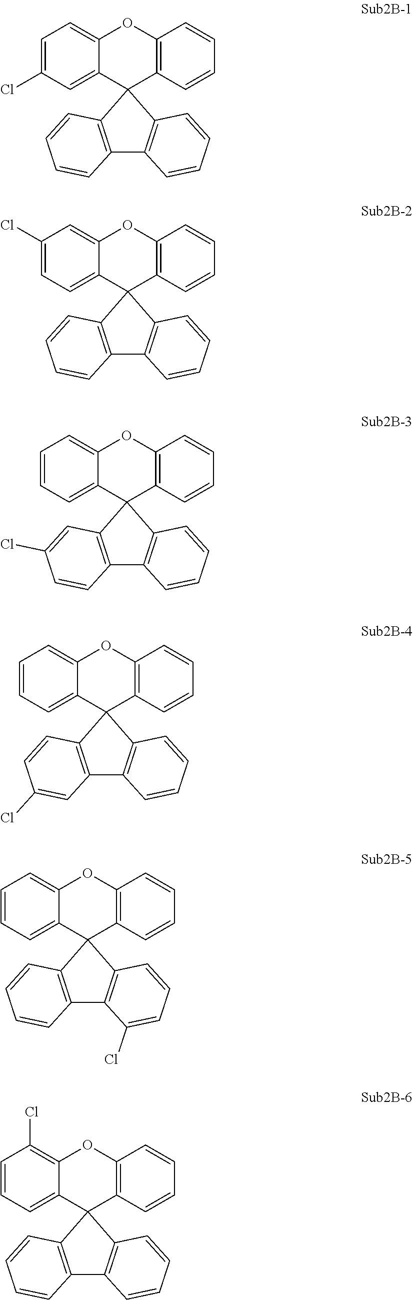 [SMILES: Clc1ccc2c(c1)C1(c3ccccc3O2)c2ccccc2-c2ccccc21 ; Clc1ccc2c(c1)Oc1ccccc1C21c2ccccc2-c2ccccc21 ; Clc1ccc2c(c1)C1(c3ccccc3Oc3ccccc31)c1ccccc1-2 ; Clc1ccc2c(c1)-c1ccccc1C21c2ccccc2Oc2ccccc21 ; Clc1cccc2c1-c1ccccc1C21c2ccccc2Oc2ccccc21 ; Clc1cccc2c1Oc1ccccc1C21c2ccccc2-c2ccccc21]

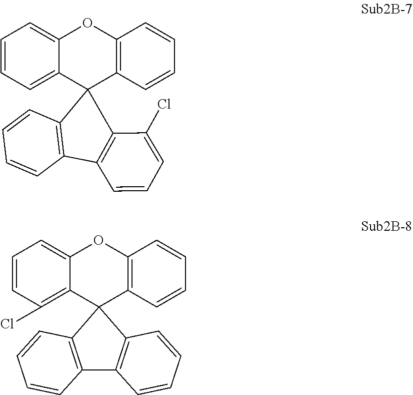 [SMILES: Clc1cccc2c1C1(c3ccccc3Oc3ccccc31)c1ccccc1-2 ; Clc1cccc2c1C1(c3ccccc3O2)c2ccccc2-c2ccccc21]

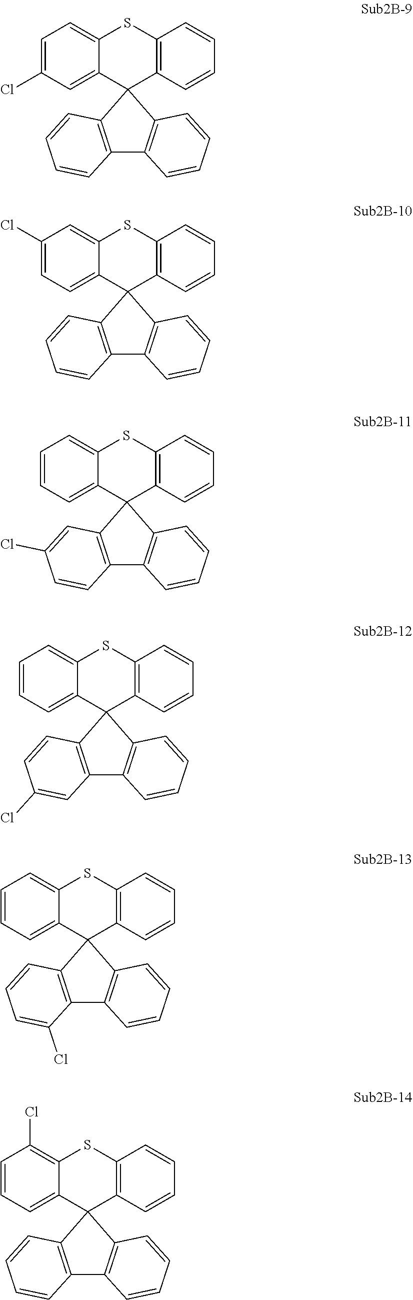 [SMILES: Clc1ccc2c(c1)C1(c3ccccc3S2)c2ccccc2-c2ccccc21 ; Clc1ccc2c(c1)Sc1ccccc1C21c2ccccc2-c2ccccc21 ; Clc1ccc2c(c1)C1(c3ccccc3Sc3ccccc31)c1ccccc1-2 ; Clc1ccc2c(c1)-c1ccccc1C21c2ccccc2Sc2ccccc21 ; Clc1cccc2c1-c1ccccc1C21c2ccccc2Sc2ccccc21 ; Clc1cccc2c1Sc1ccccc1C21c2ccccc2-c2ccccc21]

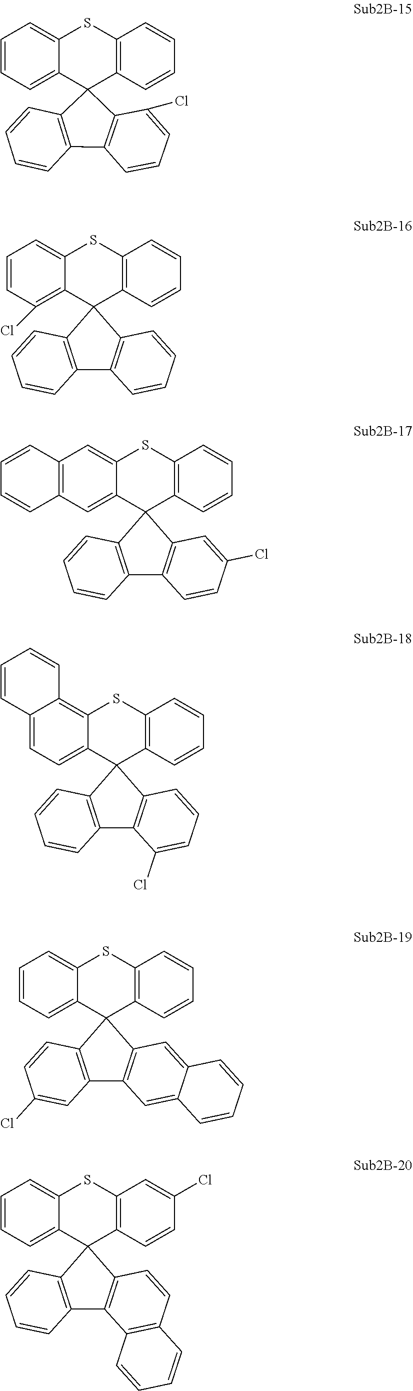 [SMILES: Clc1cccc2c1C1(c3ccccc3Sc3ccccc31)c1ccccc1-2 ; Clc1cccc2c1C1(c3ccccc3S2)c2ccccc2-c2ccccc21 ; Clc1ccc2c(c1)C1(c3ccccc3Sc3cc4ccccc4cc31)c1ccccc1-2 ; Clc1cccc2c1-c1ccccc1C21c2ccccc2Sc2c1ccc1ccccc21 ; Clc1ccc2c(c1)-c1cc3ccccc3cc1C21c2ccccc2Sc2ccccc21 ; Clc1ccc2c(c1)Sc1ccccc1C21c2ccccc2-c2c1ccc1ccccc21]

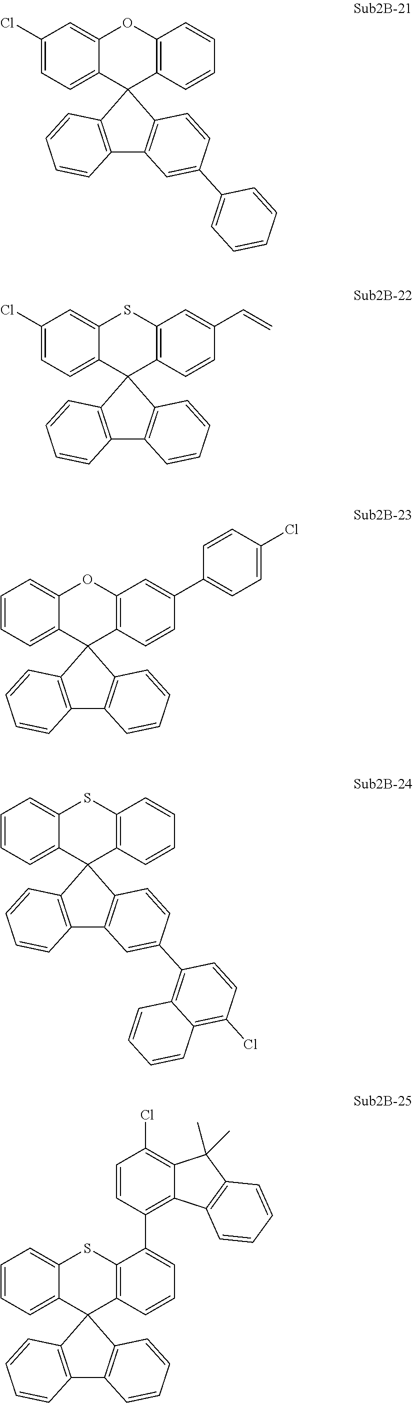 [SMILES: Clc1ccc2c(c1)Oc1ccccc1C21c2ccccc2-c2cc(-c3ccccc3)ccc21 ; C=Cc1ccc2c(c1)Sc1cc(Cl)ccc1C21c2ccccc2-c2ccccc21 ; Clc1ccc(-c2ccc3c(c2)Oc2ccccc2C32c3ccccc3-c3ccccc32)cc1 ; Clc1ccc(-c2ccc3c(c2)-c2ccccc2C32c3ccccc3Sc3ccccc32)c2ccccc12 ; CC1(C)c2ccccc2-c2c(-c3cccc4c3Sc3ccccc3C43c4ccccc4-c4ccccc43)ccc(Cl)c21]

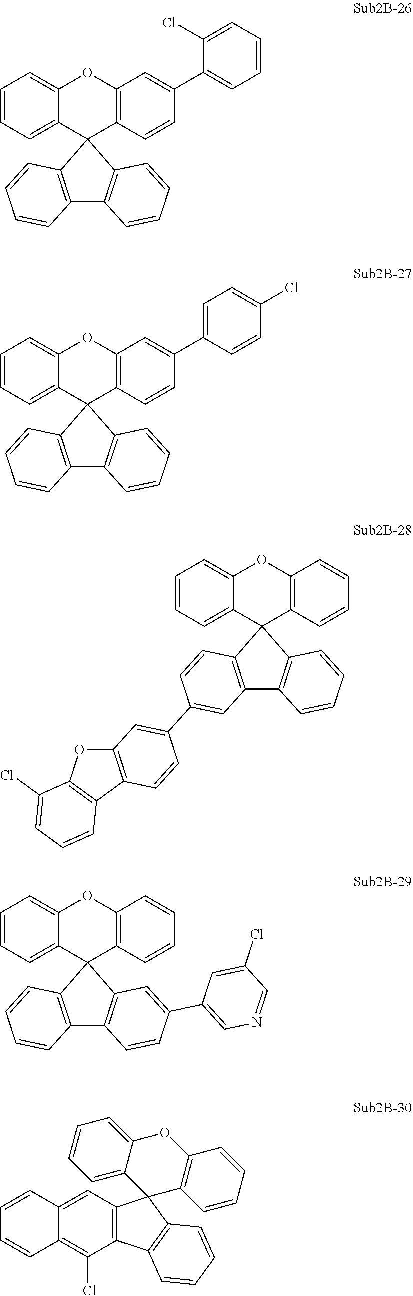 [SMILES: Clc1ccccc1-c1ccc2c(c1)Oc1ccccc1C21c2ccccc2-c2ccccc21 ; Clc1ccc(-c2ccc3c(c2)Oc2ccccc2C32c3ccccc3-c3ccccc32)cc1 ; Clc1cccc2c1oc1cc(-c3ccc4c(c3)-c3ccccc3C43c4ccccc4Oc4ccccc43)ccc12 ; Clc1cncc(-c2ccc3c(c2)C2(c4ccccc4Oc4ccccc42)c2ccccc2-3)c1 ; Clc1c2c(cc3ccccc13)C1(c3ccccc3Oc3ccccc31)c1ccccc1-2]

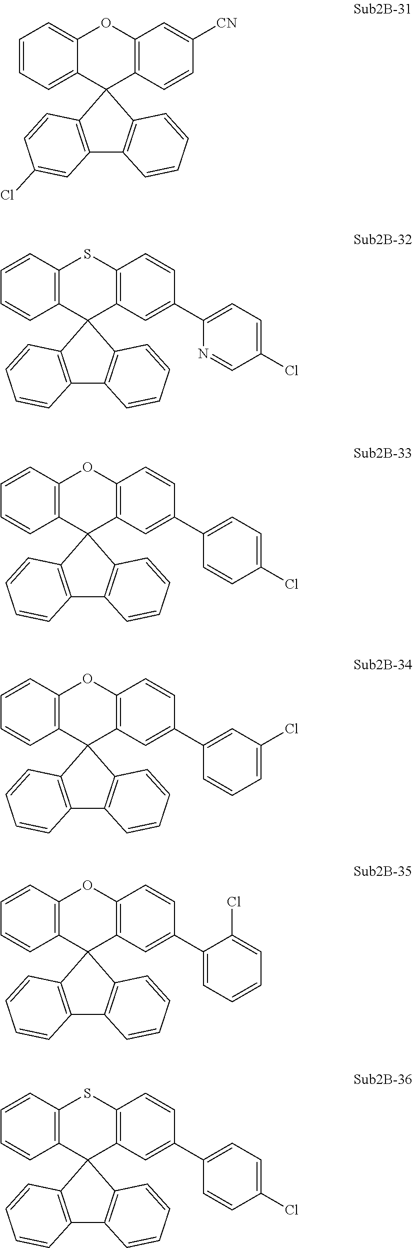 [SMILES: N#Cc1ccc2c(c1)Oc1ccccc1C21c2ccccc2-c2cc(Cl)ccc21 ; Clc1ccc(-c2ccc3c(c2)C2(c4ccccc4S3)c3ccccc3-c3ccccc32)nc1 ; Clc1ccc(-c2ccc3c(c2)C2(c4ccccc4O3)c3ccccc3-c3ccccc32)cc1 ; Clc1cccc(-c2ccc3c(c2)C2(c4ccccc4O3)c3ccccc3-c3ccccc32)c1 ; Clc1ccccc1-c1ccc2c(c1)C1(c3ccccc3O2)c2ccccc2-c2ccccc21 ; Clc1ccc(-c2ccc3c(c2)C2(c4ccccc4S3)c3ccccc3-c3ccccc32)cc1]

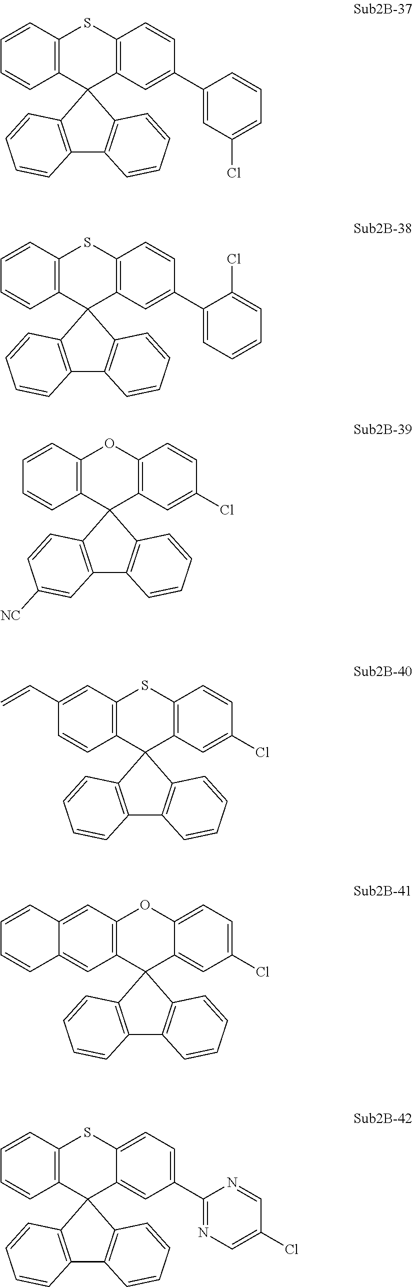 [SMILES: Clc1cccc(-c2ccc3c(c2)C2(c4ccccc4S3)c3ccccc3-c3ccccc32)c1 ; Clc1ccccc1-c1ccc2c(c1)C1(c3ccccc3S2)c2ccccc2-c2ccccc21 ; N#Cc1ccc2c(c1)-c1ccccc1C21c2ccccc2Oc2ccc(Cl)cc21 ; C=Cc1ccc2c(c1)Sc1ccc(Cl)cc1C21c2ccccc2-c2ccccc21 ; Clc1ccc2c(c1)C1(c3cc4ccccc4cc3O2)c2ccccc2-c2ccccc21 ; Clc1cnc(-c2ccc3c(c2)C2(c4ccccc4S3)c3ccccc3-c3ccccc32)nc1]

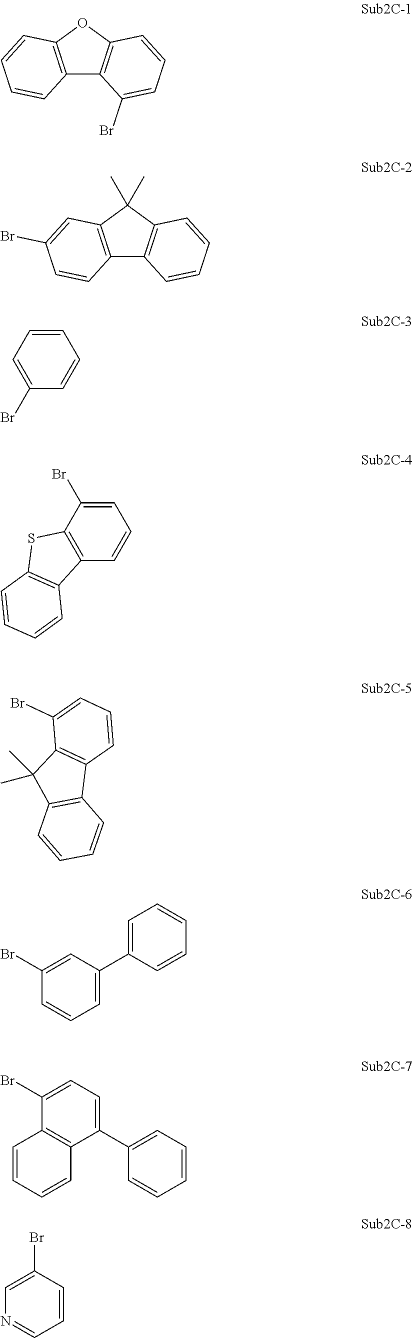

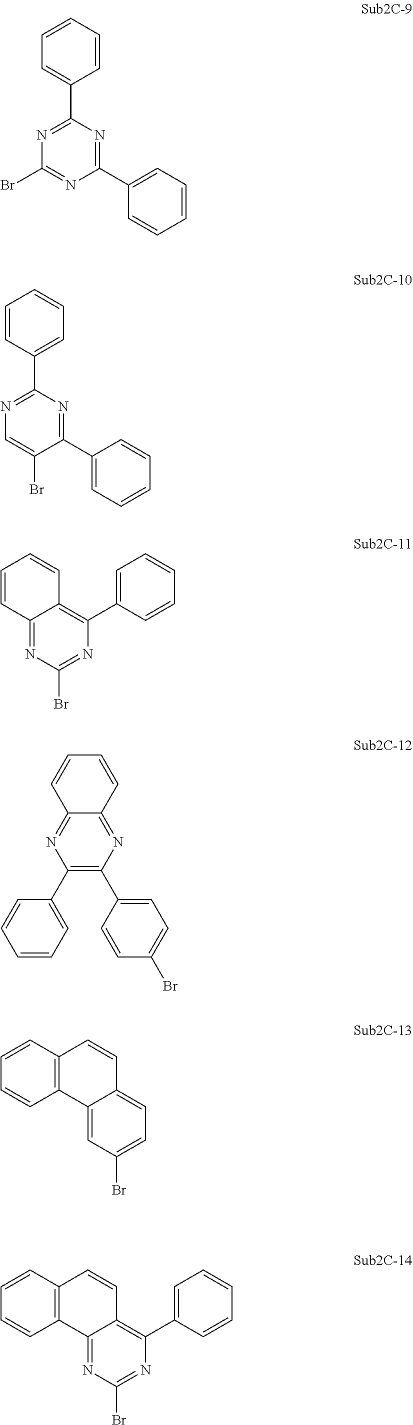 [SMILES: Brc1nc(-c2ccccc2)nc(-c2ccccc2)n1 ; Brc1cnc(-c2ccccc2)nc1-c1ccccc1 ; Brc1nc(-c2ccccc2)c2ccccc2n1 ; Brc1ccc(-c2nc3ccccc3nc2-c2ccccc2)cc1 ; Brc1ccc2ccc3ccccc3c2c1 ; Brc1nc(-c2ccccc2)c2ccc3ccccc3c2n1]

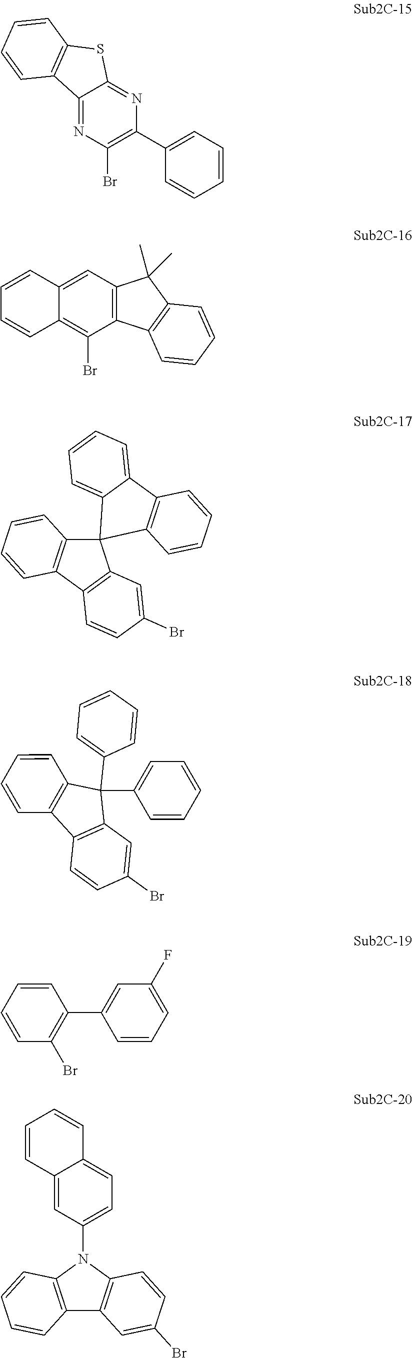

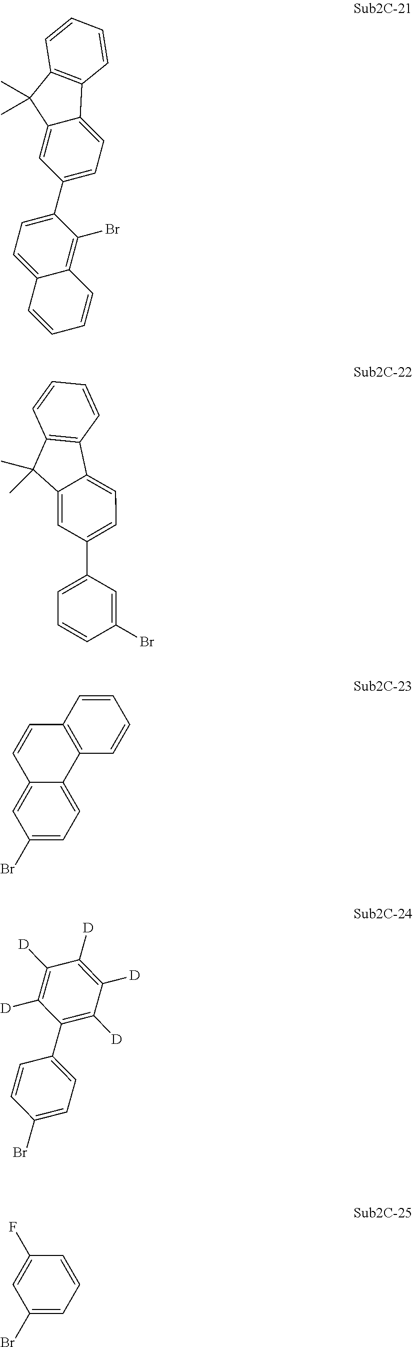 [SMILES: CC1(C)c2ccccc2-c2ccc(-c3ccc4ccccc4c3Br)cc21 ; CC1(C)c2ccccc2-c2ccc(-c3cccc(Br)c3)cc21 ; Brc1ccc2c(ccc3ccccc32)c1 ; [2H]c1c([2H])c([2H])c(-c2ccc(Br)cc2)c([2H])c1[2H] ; Fc1cccc(Br)c1]

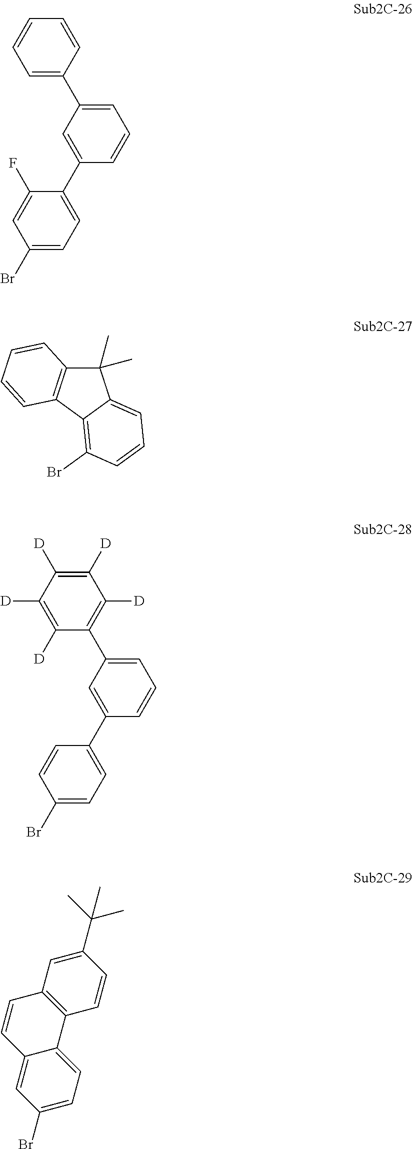 [SMILES: Fc1cc(Br)ccc1-c1cccc(-c2ccccc2)c1 ; CC1(C)c2ccccc2-c2c(Br)cccc21 ; [2H]c1c([2H])c([2H])c(-c2cccc(-c3ccc(Br)cc3)c2)c([2H])c1[2H] ; CC(C)(C)c1ccc2c(ccc3cc(Br)ccc32)c1]

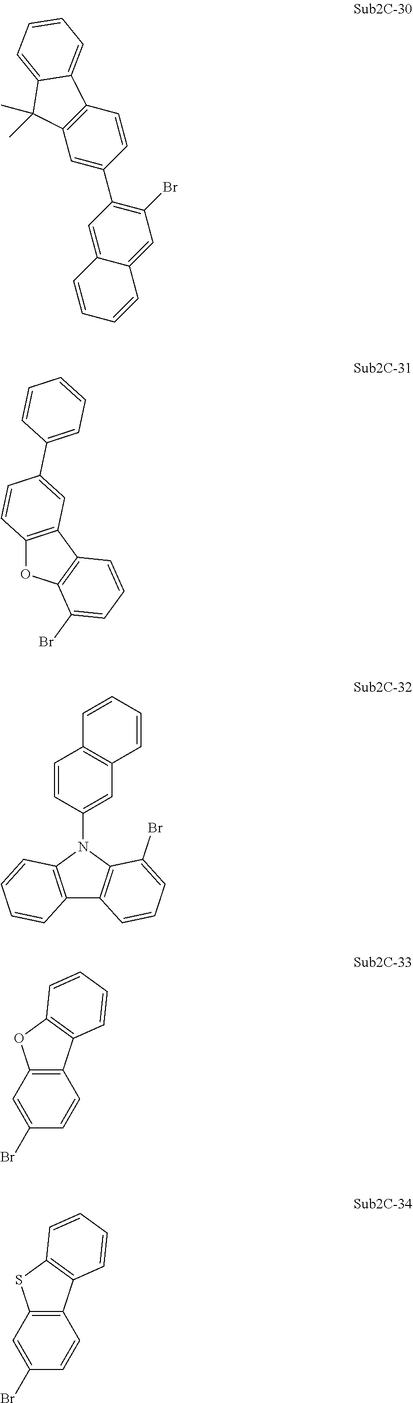 [SMILES: CC1(C)c2ccccc2-c2ccc(-c3cc4ccccc4cc3Br)cc21 ; Brc1cccc2c1oc1ccc(-c3ccccc3)cc12 ; Brc1cccc2c3ccccc3n(-c3ccc4ccccc4c3)c12 ; Brc1ccc2c(c1)oc1ccccc12 ; Brc1ccc2c(c1)sc1ccccc12]

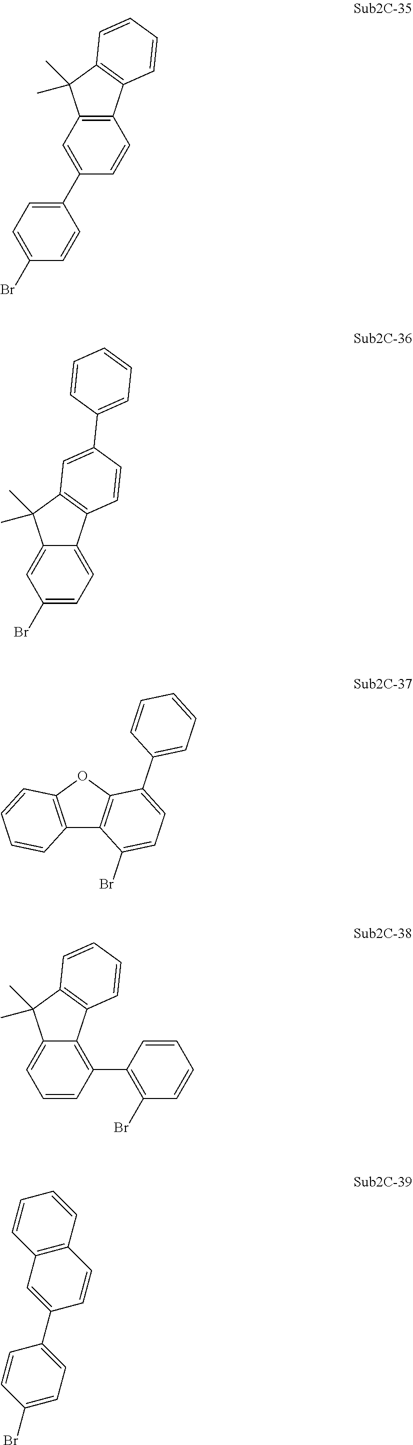 [SMILES: CC1(C)c2ccccc2-c2ccc(-c3ccc(Br)cc3)cc21 ; CC1(C)c2cc(Br)ccc2-c2ccc(-c3ccccc3)cc21 ; Brc1ccc(-c2ccccc2)c2oc3ccccc3c12 ; CC1(C)c2ccccc2-c2c(-c3ccccc3Br)cccc21 ; Brc1ccc(-c2ccc3ccccc3c2)cc1]

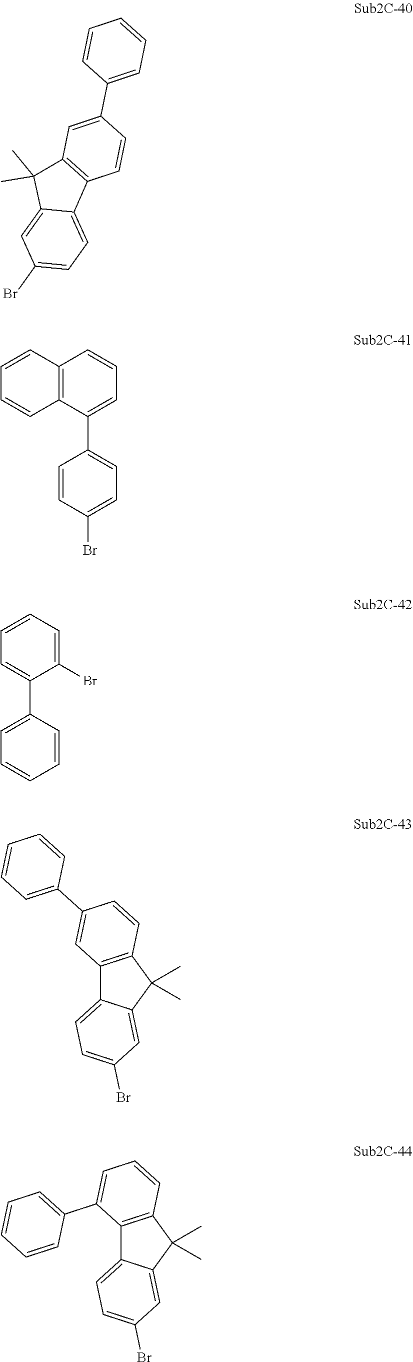 [SMILES: CC1(C)c2cc(Br)ccc2-c2ccc(-c3ccccc3)cc21 ; Brc1ccc(-c2cccc3ccccc23)cc1 ; Brc1ccccc1-c1ccccc1 ; CC1(C)c2ccc(-c3ccccc3)cc2-c2ccc(Br)cc21 ; CC1(C)c2cc(Br)ccc2-c2c(-c3ccccc3)cccc21]

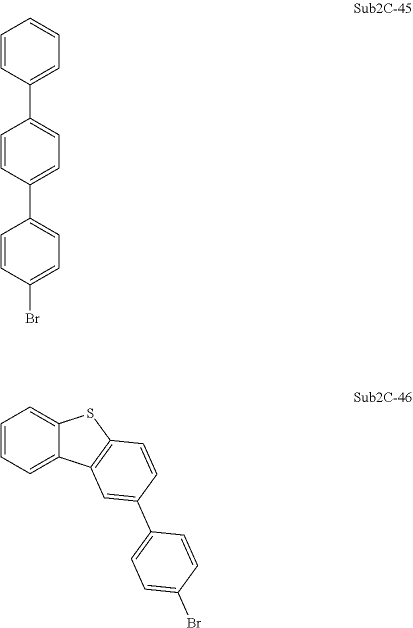 [SMILES: Brc1ccc(-c2ccc(-c3ccccc3)cc2)cc1 ; Brc1ccc(-c2ccc3sc4ccccc4c3c2)cc1]

TABLE 2

| Com- | | Com- | |
|---|---|---|---|
| pound | FD-MS | pound | FD-MS |
| Sub2B-1 | m/z = 366.08(C₂₅H₁₅ClO = 366.84) | Sub2B-2 | m/z = 366.08(C₂₅H₁₅ClO = 366.84) |
| Sub2B-3 | m/z = 366.08(C₂₅H₁₅ClO = 366.84) | Sub2B-4 | m/z = 366.08(C₂₅H₁₅ClO = 366.84) |
| Sub2B-5 | m/z = 366.08(C₂₅H₁₅ClO = 366.84) | Sub2B-6 | m/z = 366.08(C₂₅H₁₅ClO = 366.84) |
| Sub2B-7 | m/z = 366.08(C₂₅H₁₅ClO = 366.84) | Sub2B-8 | m/z = 366.08(C₂₅H₁₅ClO = 366.84) |
| Sub2B-9 | m/z = 382.06(C₂₅H₁₅ClS = 382.91) | Sub2B-10 | m/z = 382.06(C₂₅H₁₅ClS = 382.91) |
| Sub2B-11 | m/z = 382.06(C₂₅H₁₅ClS = 382.91) | Sub2B-12 | m/z = 382.06(C₂₅H₁₅ClS = 382.91) |
| Sub2B-13 | m/z = 382.06(C₂₅H₁₅ClS = 382.91) | Sub2B-14 | m/z = 382.06(C₂₅H₁₅ClS = 382.91) |
| Sub2B-15 | m/z = 382.06(C₂₅H₁₅ClS = 382.91) | Sub2B-16 | m/z = 382.06(C₂₅H₁₅ClS = 382.91) |
| Sub2B-17 | m/z = 432.07(C₂₉H₁₇ClS = 432.97) | Sub2B-18 | m/z = 432.07(C₂₉H₁₇ClS = 432.97) |
| Sub2B-19 | m/z = 432.07(C₂₉H₁₇ClS = 432.97) | Sub2B-20 | m/z = 432.07(C₂₉H₁₇ClS = 432.97) |
| Sub2B-21 | m/z = 442.11(C₃₁H₁₉ClO = 442.94) | Sub2B-22 | m/z = 408.07(C₂₇H₁₇ClS = 408.94) |
| Sub2B-23 | m/z = 442.11(C₃₁H₁₉ClO = 442.94) | Sub2B-24 | m/z = 508.11(C₃₅H₂₁ClS = 509.06) |
| Sub2B-25 | m/z = 574.15(C₄₀H₂₇ClS = 575.17) | Sub2B-26 | m/z = 442.11(C₃₁H₁₉ClO = 442.94) |
| Sub2B-27 | m/z = 442.11(C₃₁H₁₉ClO = 442.94) | Sub2B-28 | m/z = 532.12(C₃₇H₂₁ClO₂ = 533.02) |
| Sub2B-29 | m/z = 443.11(C₃H₁₈ClNO = 443.93) | Sub2B-30 | m/z = 416.10(C₂₉H₁₇ClO = 416.90) |
| Sub2B-31 | m/z = 391.08(C₂₆H₁₄₁ClNO = 391.85) | Sub2B-32 | m/z = 459.08(C₃₀H₁₈ClNS = 459.99) |
| Sub2B-33 | m/z = 442.11(C₃₁H₁₉ClO = 442.94) | Sub2B-34 | m/z = 442.11(C₃₁H₁₉ClO = 442.94) |
| Sub2B-35 | m/z = 442.11(C₃₁H₁₉ClO = 442.94) | Sub2B-36 | m/z = 458.09(C₃₁H₁₉ClS = 459.00) |
| Sub2B-37 | m/z = 458.09(C₃₁H₁₉ClO = 459.00) | Sub2B-38 | m/z = 458.09(C₃₁H₁₉ClS = 459.00) |
| Sub2B-39 | m/z = 391.08(C₂₆H₁₄ClNO = 391.85) | Sub2B-40 | m/z = 408.07(C₂₇H₁₇ClS = 408.94) |
| Sub2B-41 | m/z = 416.10(C₂₉H₁₇ClO = 416.90) | Sub2B-42 | m/z = 460.08(C₂₉H₁₇ClN₂S = 460.98) |
| Sub2C-1 | m/z = 245.97(C₁₂H₇BrO = 247.09) | Sub2C-2 | m/z = 272.02(C₁₅H₁₃Br = 273.17) |
| Sub2C-3 | m/z = 155.96(C₆H₅Br = 157.01) | Sub2C-4 | m/z = 261.95(C₁₂H₇BrS = 263.15) |
| Sub2C-5 | m/z = 272.02(C₁₅H₁₃Br = 273.17) | Sub2C-6 | m/z = 282(C₁₆H₁₁Br = 283.17) |
| Sub2C-7 | m/z = 231.99(C₁₂H₉Br = 233.11) | Sub2C-8 | m/z = 156.95(C₅H₄BrN = 158) |
| Sub2C-9 | m/z = 311.01(C₁₅H₁₀BrN₃ = 312.17) | Sub2C-10 | m/z = 310.01(C₁₆H₁₁BrN₂ = 311.18) |
| Sub2C-11 | m/z = 283.99(C₁₄H₉BrN_{z} = 285.14) | Sub2C-12 | m/z = 255.99(C₁₄H₉Br = 257.13) |
| Sub2C-13 | m/z = 360.03(C₂₀H₁₃BrN₂ = 361.24) | Sub2C-14 | m/z = 334.01(C₁₈H₁₁BrN_{z} = 335.2) |
| Sub2C-15 | m/z = 339.97(C₁₆H₉BrN₂S = 341.23) | Sub2C-16 | m/z = 322.04(C₁₉H₁₅Br = 323.23) |
| Sub2C-17 | m/z = 394.04(C₂₅H₁₅Br = 395.3) | Sub2C-18 | m/z = 396.05(C₂₅H₁₇Br = 397.32) |
| Sub2C-19 | m/z = 249.98(C₁₂H₈BrF = 251.1) | Sub2C-20 | m/z = 371.03(C₂₂H₁₄BrN = 372.27) |
| Sub2C-21 | m/z = 398.07(C₂₅H₁₉Br = 399.33) | Sub2C-22 | m/z = 348.05(C₂₁H₁₇Br = 349.27) |
| Sub2C-23 | m/z = 255.99(C₁₄H₁₉Br = 257.13) | Sub2G-24 | m/z = 237.02(C₁₂H₄D₅Br = 238.14) |
| Sub2C-25 | m/z = 173.95(C₆H₄BrF = 175) | Sub2C-26 | m/z = 308.02(C₁₈H₁₃Br = 309.21) |
| Sub2C-27 | m/z = 272.02(C₁₅H₁₃Br = 273.17) | Sub2C-28 | m/z = 313.05(C₁₈H₈D₅Br = 314.24) |
| Sub2C-29 | m/z = 312.05(C₁₈H₁₇Br = 313.24) | Sub2C-30 | m/z = 398.07(C₂₅H₁₉Br = 399.33) |
| Sub2C-31 | m/z = 322(C₁₈H₁₁BrO = 323.19) | Sub2C-32 | m/z = 371.03(C₂₂H₁₄BrN = 372.27) |
| Sub2C-33 | m/z = 245.97(C₁₂H₁₉BrO = 247.09) | Sub2C-34 | m/z = 261.95(C₁₂H₇BrS = 263.15) |
| Sub2C-35 | m/z = 348.05(C₂₁H₁₇Br = 349.27) | Sub2C-36 | m/z = 348.05(C₂₁H₁₇Br = 349.27) |
| Sub2C-37 | m/z = 322(C₁₈H₁₁BrO = 323.19) | Sub2C-38 | m/z = 348.05(C₂₁H₁₇Br = 349.27) |
| Sub2C-39 | m/z = 282(C₁₆H₁₁Br = 283.17) | Sub2C-40 | m/z = 348.05(C₂₁H₁₇Br = 349.27) |
| Sub2C-41 | m/z = 282(C₁₆H₁₁Br = 283.17) | Sub2C-42 | m/z = 231.99(C₁₂H₉Br = 233.11) |
| Sub2C-43 | m/z = 348.05(C₂₁H₁₇Br = 349.27) | Sub2C-44 | m/z = 348.05(C₂₁H₁₇Br = 349.27) |
| Sub2C-45 | m/z = 308.02(C₁₈H₁₃Br = 309.21) | Sub2C-46 | m/z = 337.98 (C₁₈H₁₁BrS = 339.25) |

### Synthesis Example of Final Products

### 1. Synthesis Example of 1-76

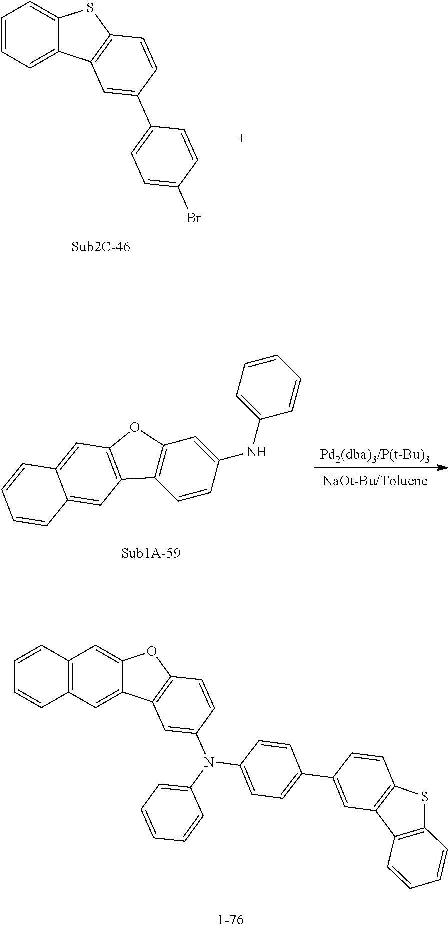 [SMILES: Brc1ccc(-c2ccc3sc4ccccc4c3c2)cc1 ; c1ccc(Nc2ccc3c(c2)oc2cc4ccccc4cc23)cc1 ; "NaOt-Bu/Toluene" ; "Pd2(dba)3/P(t-Bu)3" ; c1ccc(N(c2ccc(-c3ccc4sc5ccccc5c4c3)cc2)c2ccc3oc4cc5ccccc5cc4c3c2)cc1]

After Sub 2C-46 (142.0 g, 418.6 mmol) was dissolved in toluene (2,093 mL) and Sub 1A-59 (129.5 g, 418.6 mmol), Pd₂(dba)₃ (11.5 g, 12.6 mmol), P(t-Bu)₃ (5.1 g, 25.1 mmol) and NaOt-Bu (80.5 g, 837.2 mmol) were added to the solution, the reaction was carried out at 100° C. When the reaction was completed, the reaction product was extracted with CH₂Cl₂ and water. Then, an organic layer was dried over MgSO₄ and concentrated. Then, the concentrate was separated by a silica gel column and recrystallized to obtain 173.5 g (yield: 73%) of the product.

### 2. Synthesis Example of 1-110

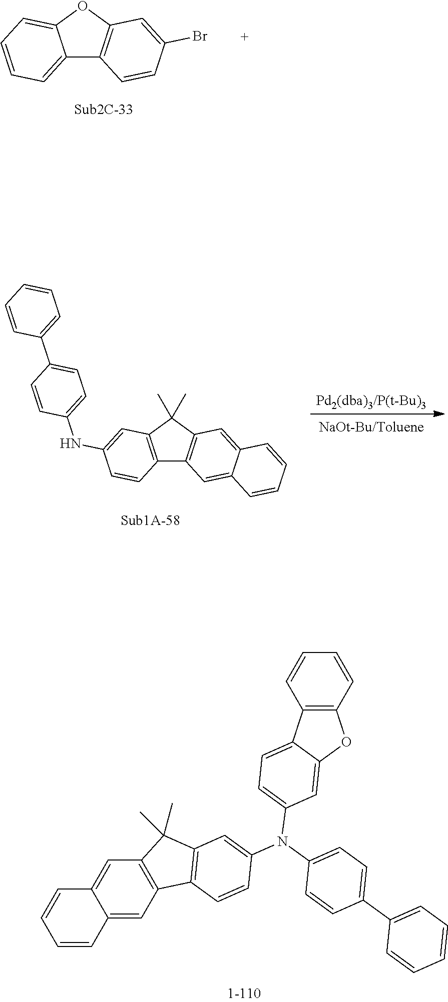 [SMILES: Brc1ccc2c(c1)oc1ccccc12 ; CC1(C)c2cc(Nc3ccc(-c4ccccc4)cc3)ccc2-c2cc3ccccc3cc21 ; "NaOt-Bu/Toluene" ; "Pd2(dba)3/P(t-Bu)3" ; CC1(C)c2cc(N(c3ccc(-c4ccccc4)cc3)c3ccc4c(c3)oc3ccccc34)ccc2-c2cc3ccccc3cc21]

After dissolving Sub 2C-33 (52.5 g, 212.6 mmol) in toluene (1,063 mL), Sub 1A-58 (87.5 g, 212.6 mmol), Pd₂(dba)₃ (5.8 g, 6.4 mmol), P(t-Bu)₃ (2.6 g, 12.8 mmol) and NaOt-Bu (40.9 g, 425.2 mmol) were added to the solution, and then the reaction was carried out in the same manner as in the synthesis method of 1-76 to obtain 92.1 g (yield: 75%) of the product.

### 3. Synthesis Example of P-1

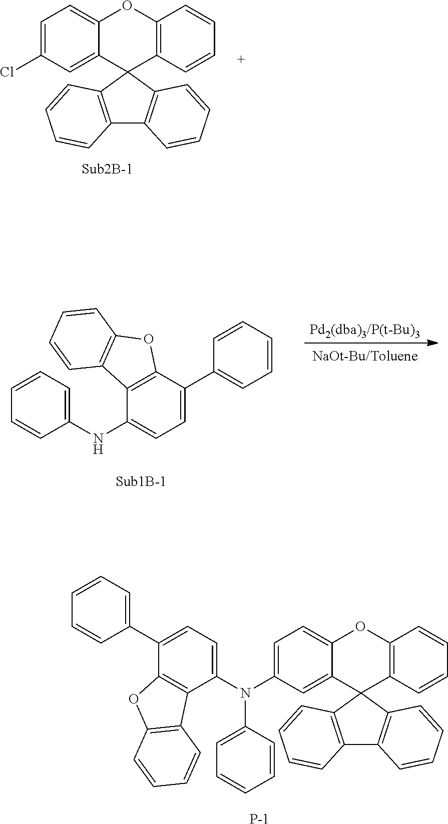

After Sub2B-1 (20 g, 54.5 mmol) was dissolved in toluene (400 mL) and Sub1B-1 (18.3 g, 54.5 mmol), Pd₂(dba)₃ (1.5 g, 1.64 mmol), P(t-Bu)₃ (50 wt % Sol.) (1.3 mL, 3.3 mmol) and NaOt-Bu (15.7 g, 163.6 mmol) were added to the solution, the reaction was carried out at 80° C. When the reaction was completed, the reaction product was extracted with CH₂Cl₂ and water. Then, an organic layer was dried over MgSO₄ and concentrated. Then, the concentrate was separated by a silica gel column and recrystallized to obtain 29.8 g (yield: 82%) of the product.

### 4. Synthesis Example of P-73

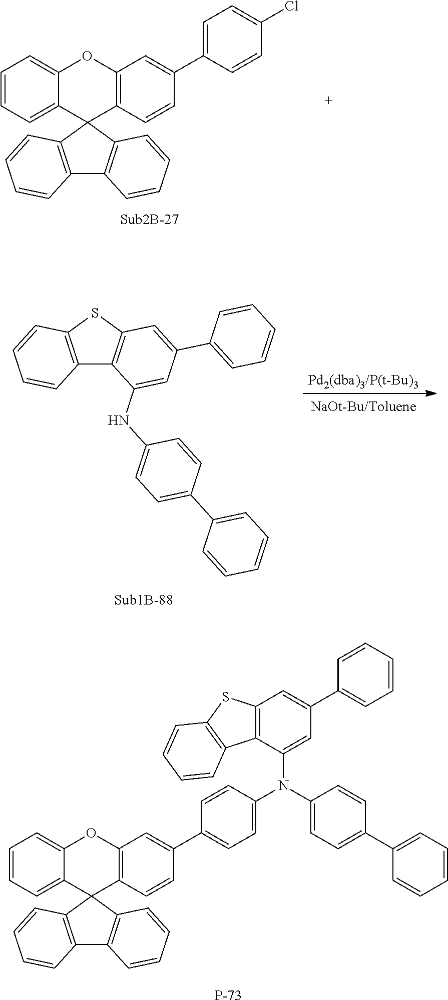

After dissolving Sub 2B-27 (17 g, 38.4 mmol) in toluene (340 mL), Sub 1B-88 (16.4 g, 38.4 mmol), Pd₂(dba)₃ (1.05 g, 1.15 mmol), NaOt-Bu (11.06 g, 115.14 mmol) and P(t-Bu)₃ (50 wt % Sol.) (0.93 mL, 2.3 mmol) were added to the solution, and then the reaction was carried out in the same manner as in the synthesis method of P-1 to obtain 20.4 g (yield: 80%) of the product.

### 5. Synthesis Example of P1-2

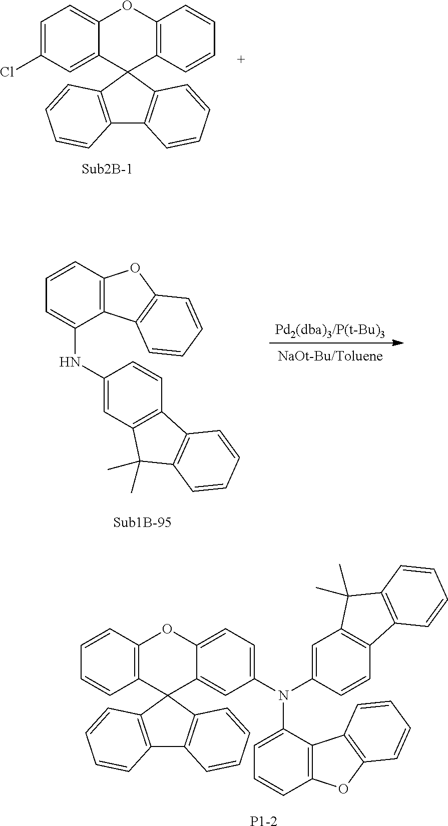

After dissolving Sub 2B-1 (15 g, 40.9 mmol) in toluene (300 mL), Sub 1B-95 (16.0 g, 40.9 mmol), Pd₂(dba)₃ (1.12 g, 1.2 mmol), NaOt-Bu (11.8 g, 122.7 mmol) and P(t-Bu)3 (50 wt % Sol.) (1.00 mL, 2.5 mmol) were added to the solution, and then the reaction was carried out in the same manner as in the synthesis method of P-1 to obtain 24.2 g (yield: 84%) of the product.

### 6. Synthesis Example of P1-13

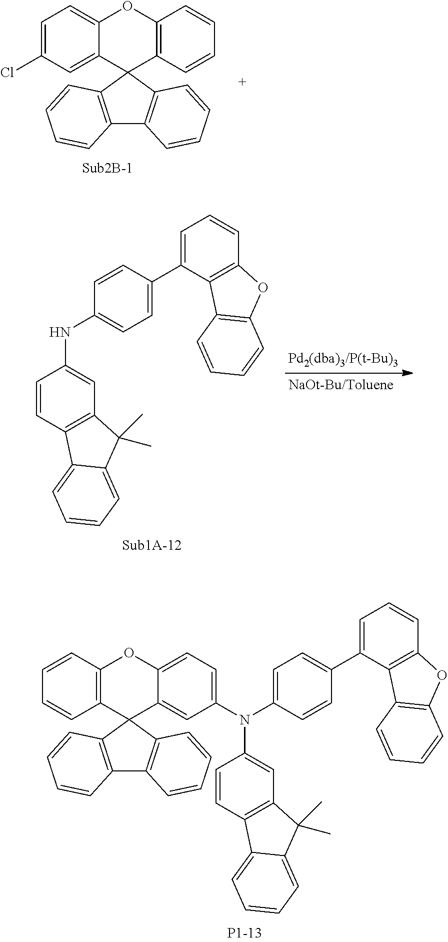 [SMILES: Clc1ccc2c(c1)C1(c3ccccc3O2)c2ccccc2-c2ccccc21 ; CC1(C)c2ccccc2-c2ccc(Nc3ccc(-c4cccc5oc6ccccc6c45)cc3)cc21 ; CC1(C)c2ccccc2-c2ccc(N(c3ccc(-c4cccc5oc6ccccc6c45)cc3)c3ccc4c(c3)C3(c5ccccc5O4)c4ccccc4-c4ccccc43)cc21]

After dissolving Sub 2B-1 (10.2 g, 27.8 mmol) in toluene (210 mL), Sub 1A-12 (12.6 g, 27.8 mmol), Pd₂(dba)₃ (0.8 g, 0.76 mmol), NaOt-Bu (8.0 g, 83.4 mmol) and P(t-Bu)₃ (50 wt % Sol.) (0.7 mL, 1.7 mmol) were added to the solution, and then the reaction was carried out in the same manner as in the synthesis method of P-1 to obtain 17.6 g (yield: 81%) of the product.

### 7. Synthesis Example of P1-86

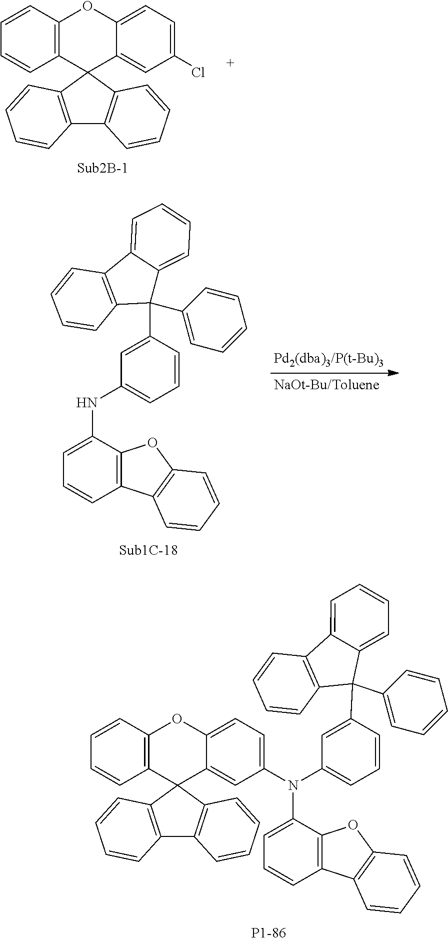 [SMILES: Clc1ccc2c(c1)C1(c3ccccc3O2)c2ccccc2-c2ccccc21 ; c1ccc(C2(c3cccc(Nc4cccc5c4oc4ccccc45)c3)c3ccccc3-c3ccccc32)cc1 ; c1ccc(C2(c3cccc(N(c4ccc5c(c4)C4(c6ccccc6O5)c5ccccc5-c5ccccc54)c4cccc5c4oc4ccccc45)c3)c3ccccc3-c3ccccc32)cc1]

After dissolving Sub 2B-1 (33 g, 89.9 mmol) in toluene (922 mL), Sub 1C-18 (47.2 g, 94.5 mmol), Pd₂(dba)₃ (2.5 g, 2.7 mmol), NaOt-Bu (25.9 g, 269.8 mmol) and P(t-Bu)₃ (50 wt % Sol.) (1.1 mL, 5.4 mmol) were added to the solution, and then the reaction was carried out in the same manner as in the synthesis method of P-1 to obtain 63.5 g (yield: 85.1%) of the product.

### 8. Synthesis Example of P2-3

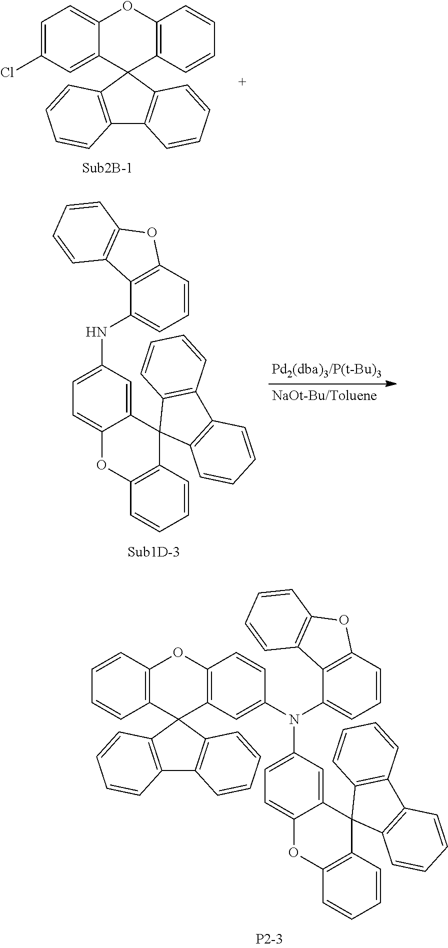 [SMILES: Clc1ccc2c(c1)C1(c3ccccc3O2)c2ccccc2-c2ccccc21 ; c1ccc2c(c1)Oc1ccc(Nc3cccc4oc5ccccc5c34)cc1C21c2ccccc2-c2ccccc21 ; c1ccc2c(c1)Oc1ccc(N(c3ccc4c(c3)C3(c5ccccc5O4)c4ccccc4-c4ccccc43)c3cccc4oc5ccccc5c34)cc1C21c2ccccc2-c2ccccc21]

After dissolving Sub 2B-1 (9.5 g, 25.9 mmol) in toluene (200 mL), Sub 1D-3 (13.3 g, 25.9 mmol), Pd₂(dba)₃ (0.7 g, 0.8 mmol), NaOt-Bu (7.5 g, 77.7 mmol) and P(t-Bu)3 (50 wt % Sol.) (0.6 mL, 0.8 mmol) were added to the solution, and then the reaction was carried out in the same manner as in the synthesis method of P-1 to obtain 18.1 g (yield: 83%) of the product.

### 9. Synthesis Example of P3-80

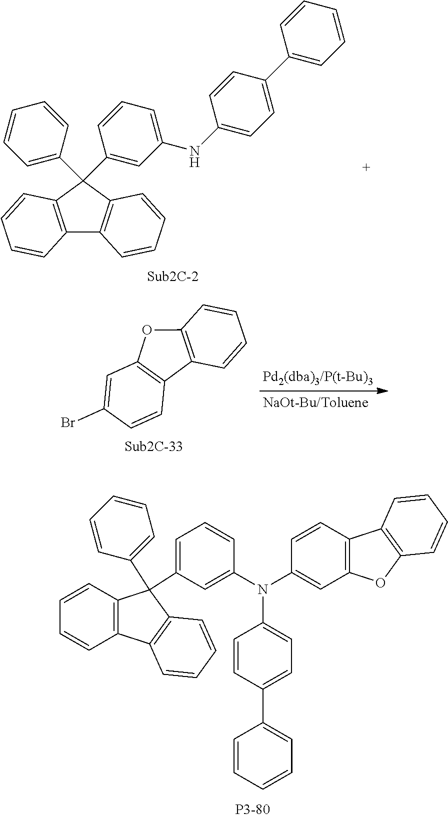 [SMILES: c1ccc(-c2ccc(Nc3cccc(C4(c5ccccc5)c5ccccc5-c5ccccc54)c3)cc2)cc1 ; Brc1ccc2c(c1)oc1ccccc12 ; c1ccc(-c2ccc(N(c3cccc(C4(c5ccccc5)c5ccccc5-c5ccccc54)c3)c3ccc4c(c3)oc3ccccc34)cc2)cc1]

After dissolving Sub1C-2 (10 g, 20.59 mmol) in toluene (211 mL), Sub2C-33 (5.34 g, 21.62 mmol), Pd₂(dba)₃ (0.57 g, 0.62 mmol), P(t-Bu)₃ (0.33 g, 1.65 mmol) and NaOt-Bu (5.94 g, 61.78 mmol) were added to the solution, and then the reaction was carried out in the same manner as in the synthesis method of P-1 to obtain 10.87 g (yield: 81%) of the product.

### 10. Synthesis Example of P3-88

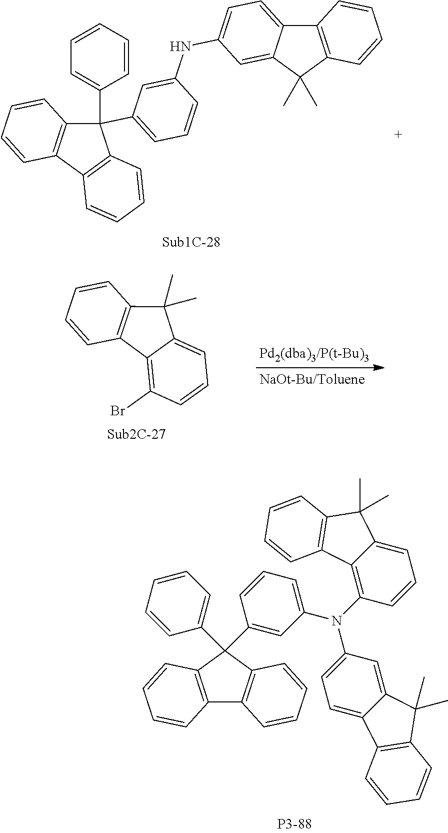 [SMILES: CC1(C)c2ccccc2-c2ccc(Nc3cccc(C4(c5ccccc5)c5ccccc5-c5ccccc54)c3)cc21 ; CC1(C)c2ccccc2-c2c(Br)cccc21 ; CC1(C)c2ccccc2-c2ccc(N(c3cccc(C4(c5ccccc5)c5ccccc5-c5ccccc54)c3)c3cccc4c3-c3ccccc3C4(C)C)cc21]

After dissolving Sub1C-28 (8.9 g, 16.93 mmol) in toluene (174 mL), Sub2C-27 (4.86 g, 17.78 mmol), Pd₂(dba)₃ (0.47 g, 0.51 mmol), P(t-Bu)3 (0.27 g, 1.35 mmol) and NaOt-Bu (4.88 g, 50.79 mmol) were added to the solution, and then the reaction was carried out in the same manner as in the synthesis method of P-1 to obtain 9.72 g (yield: 80%) of the product.

The FD-MS values of the compounds represented by Formula 1 of the present invention synthesized by the above synthesis method are shown in Table 3 below.

TABLE 3

| Com- | | Com- | |
|---|---|---|---|
| pound | FD-MS | pound | FD-MS |
| 1-1 | m/z = 473.21(C₃₆H₂₇N = 473.62) | 1-2 | m/z = 573.25(C₄₄H₃₁N = 753.74) |
| 1-3 | m/z = 447.20(C₃₄H₂₅N = 447.58) | 1-4 | m/z = 471.20(C₃₆H₂₅N = 471.60) |
| 1-5 | m/z = 625.28(C₄₈H₃₅N = 625.82) | 1-6 | m/z = 473.21(C₃₆H₂₇N = 473.62) |
| 1-7 | m/z = 623.26(C₄₈H₃₃N = 623.80) | 1-8 | m/z = 701.31(C₅₄H₃₉N = 701.91) |
| 1-9 | m/z = 503.17(C₃₆H₂₅NS = 503.66) | 1-10 | m/z = 451.14(C₃₂H₂₁NS = 451.59) |
| 1-11 | m/z = 563.08(C₃₆H₂₁NS₃ = 563.75) | 1-12 | m/z = 633.21(C₄₅H₃₁NOS = 633.81) |
| 1-13 | m/z = 677.31(C₅₂H₃₉N = 677.89) | 1-14 | m/z = 727.29(C₅₅H₃₇NO = 727.91) |
| 1-15 | m/z = 637.24(C₄₈H₃₁NO = 637.78) | 1-16 | m/z = 715.29(C₅₄H₃₇NO = 715.29) |
| 1-17 | m/z = 613.28(C₄₇H₃₅N = 613.80) | 1-18 | m/z = 713.31(C₅₅H₃₇₉N = 713.92) |
| 1-19 | m/z = 562.24(C₄₂H₃₀N₂ = 562.72) | 1-20 | m/z = 612.26(C₄₆H₃₂N₂ = 612.78) |
| 1-21 | m/z = 638.27(C₄₈H₃₄N₂ = 638.81) | 1-22 | m/z = 678.30(C₅₁H_{3B}N₂ = 678.88) |
| 1-23 | m/z = 802.33(C₆₁H₄₂N₂ = 803.02) | 1-24 | m/z = 800.32(C₆₁H₄₀N₂ = 801.01) |
| 1-25 | m/z = 602.27(C₄₅H₃₄N₂ = 602.78) | 1-26 | m/z = 678.30(C₅₁H₃₈N₂ = 678.88) |
| 1-27 | m/z = 754.33(C₅₇H₄₂N₂ = 754.98) | 1-28 | m/z = 744.26(C₅₄H₃₆N₂S = 744.96) |
| 1-29 | m/z = 688.29(C₅₂H₃N₂ = 688.87) | 1-30 | m/z = 652.29(C₄₉H₃N₂ = 652.84) |
| 1-31 | m/z = 754.33(C₅₇H₄₂N₂ = 754.98) | 1-32 | m/z = 878.37(C₆₇H₄₆N₂ = 879.12) |
| 1-33 | m/z = 876.35(C₆₇H₄₄N₂ = 877.10) | 1-34 | m/z = 639.27(C₄₇H₃₃N₃ = 639.80) |
| 1-35 | m/z = 768.26(C₅₆H₃₆N₂S = 768.98) | 1-36 | m/z = 833.29(C₆₆H₃₉N₃S = 834.05) |
| 1-37 | m/z = 742.26(C₅₄H₃₄N₂O₂ = 742.88) | 1-38 | m/z = 778.33(C₅₉H₄₂N₂ = 779.00) |
| 1-39 | m/z = 688.29(C₅₂H₃₆N₂ = 688.87) | 1-40 | m/z = 702.27(C₅₂H₃₄N₂O = 702.86) |
| 1-41 | m/z = 692.23(C₅₀H₃₂N₂S = 692.88) | 1-42 | m/z = 782.24(C₅₆H₃₄N₂OS = 782.96) |
| 1-43 | m/z = 738.30(C₅₆H₃₈N₂ = 738.93) | 1-44 | m/z = 768.26(C₅₆H₃₆N₂S = 768.98) |
| 1-45 | m/z = 716.32(C₅₄H₄₀N₂ = 716.93) | 1-46 | m/z = 857.29(C₆₂H₃₉N₃S = 858.08) |
| 1-47 | m/z = 738.30(C₅₆H₃₈N₂ = 738.93) | 1-48 | m/z = 753.28(C₅₅H₃₅N₃O = 753.91) |
| 1-49 | m/z = 677.28(C₅₀H₃₅N₃ = 677.85) | 1-50 | m/z = 879.32(C₆₅H₄₁N₃O = 880.06) |
| 1-51 | m/z = 602.27(C₄₅H₃₄N₂ = 602.78) | 1-52 | m/z = 612.26(C₄₆H₃₂N₂ = 612.78) |
| 1-53 | m/z = 662.27(C₅₀H₃₄N₂ = 662.84) | 1-54 | m/z = 642.21(C₄₆H₃₀N₂S = 642.82) |
| 1-55 | m/z = 668.23(C₄₈H₃₂N₂S = 668.86) | 1-56 | m/z = 668.23(C₄₈H₃₂N₂S = 668.86) |
| 1-57 | m/z = 642.21(C₄₆H₃₀N₂S = 642.82) | 1-58 | m/z = 744.26(C₅₄H₃₆N₂S = 744.96) |
| 1-59 | m/z = 652.25(C₄₈H₃₂N₂O = 652.80) | 1-60 | m/z = 682.21(C₄₈H₃N₂OS = 682.84) |
| 1-61 | m/z = 638.27(C₄₈H₃₄N₂ = 638.81) | 1-62 | m/z = 652.25(C₄₈N₃₂N₂O = 652.80) |
| 1-63 | m/z = 754.33(C₅₇H₄₂N₂ = 754.98) | 1-64 | m/z = 804.17(C₅₄H₃₂N₂S₃ = 805.04) |
| 1-65 | m/z = 606.18(C₄₂H₂₆N₂OS = 606.74) | 1-66 | m/z = 486.21(C₃₆H₂₆N₂ = 486.62) |
| 1-67 | m/z = 541.26(C₄₀H₂₃DsN₂ = 541.71) | 1-68 | m/z = 612.26(C₄₆H₃₂N₂ = 612.78) |
| 1-69 | m/z = 602.27(C₄₅H₃₄N₂ = 602.78) | 1-70 | m/z = 830.28(C₆₁H₃₈N₂S = 831.05) |
| 1-71 | m/z = 727.30(C₅₄H₃₇N₃ = 727.91) | 1-72 | m/z = 562.24(C₄₂H₃₀N₂ = 562.72) |
| 1-73 | m/z = 668.23(C₄₈H₃₂N₂S = 668.86) | 1-74 | m/z = 732.22(C₃₂H₃₂N₂OS = 732.9) |
| 1-75 | m/z = 652.25(C₄₈H₃₂N₂O = 652.8) | 1-76 | m/z = 567.17(C₄₀H₂₅NOS = 567.71) |
| 1-77 | m/z = 567.17(C₄₀H₂₅NOS = 567.71) | 1-78 | m/z = 731.23(C₅₃H₃₃NOS = 731.91) |
| 1-79 | m/z = 731.23(C₅₃H₃₃NOS = 731.91) | 1-80 | m/z = 553.19(C₄₀H₂₇NS = 553.72) |
| 1-81 | m/z = 553.19(C₄₀H₂₇NS = 553.72) | 1-82 | m/z = 553.19(C₄₀H₂₇NS = 553.72) |
| 1-83 | m/z = 653.22(C₄₈H₃₁NS = 653.84) | 1-84 | m/z = 639.11(C₄₂H₂₅NS₃ = 639.85) |
| 1-85 | m/z = 715.15(C₄₈H₂₉NS₃ = 715.95) | 1-86 | m/z = 791.18(C₅₄H₃₃NS₃ = 792.05) |
| 1-87 | m/z = 607.16(C₄₂H₂₅NO₂S = 607.73) | 1-88 | m/z = 725.31(C₅₆H₃₉N = 725.94) |
| 1-89 | m/z = 735.29(C₅₇H₃₇N = 735.93) | 1-90 | m/z = 751.32(C₅₈H₄₁N = 751.97) |
| 1-91 | m/z = 725.31(C₅₈H₃₉N = 725.94) | 1-92 | m/z = 675.29(C₅₂H₃₇N = 675.88) |
| 1-93 | m/z = 513.25(C₃₉H₃₁N = 513.68) | 1-94 | m/z = 613.28(C₄₇H₃₅N = 613.80) |
| 1-95 | m/z = 665.31(C₅₁H₃₉N = 665.88) | 1-96 | m/z = 705.34(C₅₄H₄₃N = 705.95) |
| 1-97 | m/z = 593.31(C₄₅H₃₉N = 593.81) | 1-98 | m/z = 639.20(C₄₇H₂₉NS = 639.82) |
| 1-99 | m/z = 699.26(C₅₃H₃₃NOS = 699.85) | 1-100 | m/z = 801.30(C₆₁H₃₉NO = 801.99) |
| 1-101 | m/z = 775.29(C₅₉H₃₇NO = 775.95) | 1-102 | m/z = 865.30(C₆₅H₃₉NO₂ = 866.03) |
| 1-103 | m/z = 583.23(C₄₅H₂₉N = 583.73) | 1-104 | m/z = 685.28(C₅₃H₃₅N = 685.87) |
| 1-105 | m/z = 577.24(C₄₃H₃₁NO = 577.73) | 1-106 | m/z = 699.29(C₅₄H₃₇N₃ = 699.90) |
| 1-107 | m/z = 725.31(C₅₆H₃₉N = 725.94) | 1-108 | m/z = 577.24(C₄₃H₃₁NO = 577.73) |
| 1-109 | m/z = 593.22(C₄₃H₃₁NS = 593.79) | 1-110 | m/z = 577.24(C₄₃H₃₁NO = 577.73) |
| 1-111 | m/z = 627.26(C₄₇H₃₃NO = 627.79) | 1-112 | m/z = 679.32(C₅₂H₄₁N = 679.91) |
| 1-113 | m/z = 685.28(C₅₃H₃₅N = 685.87) | 1-114 | m/z = 775.32(C₆₀H₄₁N = 776.00) |
| 1-115 | m/z = 772.29(C₅₉H₃₆N₂ = 772.95) | 1-116 | m/z = 685.28(C₅₃H₃₅N = 685.87) |
| 1-117 | m/z = 941.31(C₇₁H₇₁N₄₃S = 942.19) | 1-118 | m/z = 751.29(C₅₇H₃₇NO = 751.93) |
| 1-119 | m/z = 643.23(C₄₇H₃₃NS = 643.85) | 1-120 | m/z = 676.29(C₅₁H₃₆N₂ = 676.86) |
| 1-121 | m/z = 727,29(C₅₅H₃₇NO = 727.91) | 1-122 | m/z = 843.30(C₆₃H₄₁NS = 844.09) |
| 1-123 | m/z = 751.29(C₅₇H₃₇NO = 751.93) | 1-124 | m/z = 727.32(C₅₆H₄₁N = 727.95) |
| 1-125 | m/z = 800.32(C₆₁H₄₀N₂ = 801.01) | 1-126 | m/z = 823.33(C₆₁H₄₅NS = 824.10) |
| 1-127 | m/z = 757.24(C₅₅H₃₅NOS = 757.95) | 1-128 | m/z = 637.28(C₄₉H₃₅N = 637.83) |
| 1-129 | m/z = 727.29(C₅₅H₃₇NO = 727.91) | 1-130 | m/z = 750.30(C₅₇H₃₈N₂ = 750.95) |
| 1-131 | m/z = 691.29(C₅₂H₃₇NO = 691.87) | 1-132 | m/z = 815.32(C₆₂H₄₁ NO = 816.02) |
| 1-133 | m/z = 705.27(C₅₂H₃₅NO₂ = 705.86) | 1-134 | m/z = 668.23(C₄₈H₃₂N₂S = 668.86) |
| 1-135 | m/z = 612.26(C₄₆H₃₂N₂ = 612.78) | | |
| P-1 | m/z = 665.24(C₄₉H₃₁NO₂ = 665.79) | P-2 | m/z = 791.28(C₅₉H₃₇NO₂ = 791.95) |
| P-3 | m/z = 891.31(C₆₇H₄₁NO₂ = 892.07) | P-4 | m/z = 741.27(C₅₅H₃₅NO₂ = 741.89) |
| P-5 | m/z = 791.28(C₅₉H₃₇NO₂ = 791.95) | P-6 | m/z = 665.24(C₄₉H₃₁NO₂ = 665.79) |
| P-7 | m/z = 665.24(C₄₉H₃₁NO₂ = 665.79) | P-8 | m/z = 665.24(C₄₉H₃₁NO₂ = 665.79) |
| P-9 | m/z = 665.24(C₄₉H₃₁NO₂ = 665.79) | P-10 | m/z = 857.33(C₆₄H₄₃NO₂ = 858.05) |
| P-11 | m/z = 841.30(C₆₃H₃NO₂ = 842.01) | P-12 | m/z = 817.30(C₆₁H₃₉NO₂ = 817.99) |
| P-13 | m/z = 867.31(C₆₅H₄₁NO₂ = 868.05) | P-14 | m/z = 833.30(C₆₀H₃₉NO₂ = 833.99) |
| P-15 | m/z = 666.23(C₄₈H₃₀N₂O₂ = 666.78) | P-16 | m/z = 782.26(C₅₆H₃₄N₂O₃ = 782.90) |
| P-17 | m/z = 830.29(C₆₁H₃₈N₂O₂ = 830.99) | P-18 | m/z = 795.31(C₅₉H₃₃D₄NO₂ = 795.97) |
| P-19 | m/z = 812.21(C₅₆H₃₂N₂O₃S = 812.94) | P-20 | m/z = 897.27(C₆₅H₃₉NO₂S = 898.09) |
| P-21 | m/z = 681.21(C₄₉H₃₁NOS = 681.85) | P-22 | m/z = 807.26(C₅₉H₃₇NOS = 808.01) |
| P-23 | m/z = 907.29(C₆₇H₄₁NOS = 908.13) | P-24 | m/z = 807.26(C₅₉H₃₇NOS = 808.01) |
| P-25 | m/z = 805.24(C₅₉H₃₅NOS = 806.00) | P-26 | m/z = 797.28(C₅₈H₃₉NOS = 798.02) |
| P-27 | m/z = 757.24(C₅₅H₃₅NOS = 757.95) | P-28 | m/z = 771.22(C₅₅H₃₃NO₂S = 771.93) |
| P-29 | m/z = 757.24(C₅₅H₃₅NOS = 757.95) | P-30 | m/z = 787.20(C₅₅H₃₃NOS₂ = 788.00) |
| P-31 | m/z = 857.28(C₆₃H₃₉NOS = 858.07) | P-32 | m/z = 833.28(C₆₁H₃₉NOS = 834.05) |
| P-33 | m/z = 883.29(C₆₅H₄₁NOS = 884.11) | P-34 | m/z = 781.24(C₅₇H₃₅NOS = 781.97) |
| P-35 | m/z = 682.21(C₄₈H₃N₂OS = 682.84) | P-36 | m/z = 681.21(C₄₉H₃₁NOS = 681.85) |
| P-37 | m/z = 807.26(C₅₉H₃₇NOS = 808.01) | P-38 | m/z = 907.29(C₆₇H₄₁NOS = 908.13) |
| P-39 | m/z = 807.26(C₅₉H₃₇NOS = 808.01) | P-40 | m/z = 807.26(C₅₉H₃₇NOS = 808.01) |
| P-41 | m/z = 681.21(C₄₉H₃₁NOS = 681.85) | P-42 | m/z = 681.21(C₄₉H₃₁NOS = 681.85) |
| P-43 | m/z = 681.21(C₄₉H₃₁NOS = 681.85) | P-44 | m/z = 681.21(C₄₉H₃₁NOS = 681.85) |
| P-45 | m/z = 873.31(C₆₄H₄₃NOS = 874.11) | P-46 | m/z = 857.28(C₆₃H₃₉NOS = 858.07) |
| P-47 | m/z = 833.28(C₆₁H₃₉NOS = 834.05) | P-48 | m/z = 883.29(C₆₅H₄₁NOS = 884.11) |
| P-49 | m/z = 781.24(C₅₇H₃₅NOS = 781.97) | P-50 | m/z = 682.21(C₄₈H₃₀N₂OS = 682.84) |
| P-51 | m/z = 798.23(C₅₈H₃N₂O₂S = 798.96) | P-52 | m/z = 846.27(C₆₁H₃₈N₂OS = 847.05) |
| P-53 | m/z = 811.28(C₅₉H₃₃D₄NOS = | P-54 | m/z = 828.19(C₅₆H₃₂N₂O₂S₂ = |
| | 812.04) | | 829.00) |
| P-55 | m/z = 863.23(C₆₁H₃₇NOS₂ = 864.09) | P-56 | m/z = 823.24(C₅₉H₃₇NS₂ = 824.07) |
| P-57 | m/z = 863.23(C₆₁H₃₇NOS₂ = 864.09) | P-58 | m/z = 929.22(C₆₅H₃₉NS₃ = 930.21) |
| P-59 | m/z = 938.28(C₆₇H₄₂N₂S₂ = 939.21) | P-60 | m/z = 797.22(C₅₇H₃₅NS₂ = 798.03) |
| P-61 | m/z = 813.25(C₅₈H₃₉NS₂ = 814.08) | P-62 | m/z = 773.22(C₅₅H₃₅NS₂ = 774.01) |
| P-63 | m/z = 747.21(C₅₃H₃₃NS₂ = 747.97) | P-64 | m/z = 823.24(C₅₉H₃₇NS₂ = 824.07) |
| P-65 | m/z = 853.19(C₅₉H₃₅NS₃ = 854.12) | P-66 | m/z = 923.27(C₆₇H₄₁NS₂ = 924.19) |
| P-67 | m/z = 949.28(C₆₉H₄₃NS₂ = 950.23) | P-68 | m/z = 781.24(C₅₇H₃₅NOS = 781.97) |
| P-69 | m/z = 847.24(C₆₁H₃₇NS₂ = 848.09) | P-70 | m/z = 698.19(C₄₈H₃₀N₂S₂ = 698.90) |
| P-71 | m/z = 874.27(C₆₂H₃₈N₂O₂S = 875.06) | P-72 | m/z = 872.29(C₆₃H₄₀N₂OS = 873.09) |
| P-73 | m/z = 833.28(C₆₁H₃₉NOS = 834.05) | P-74 | m/z = 970.21(C₆₆H₃₈N₂OS₃ = 971.22) |
| P-75 | m/z = 1055.33(C₇₆H₄₉NOS₂ = | P-76 | m/z = 741.27(C₅₅H₃₅NO₂ = |
| | 1056.35) | | 741.89) |
| P-77 | m/z = 883.29(C₆₅H₄₁NOS = 884.11) | P-78 | m/z = 931.31(C₆₉H₄₁NO₃ = 932.09) |
| P-79 | m/z = 868.31(C₆H₄₀N₂O₂ = 869.04) | P-80 | m/z = 841.30(C₆₃H₃₉NO₂ = 842.01) |
| P-81 | m/z = 741.27(C₅₅H₃₅NO₂ = 741.89) | P-82 | m/z = 781.30(C₅₈H₃₉NO₂ = 781.96) |
| P-83 | m/z = 705.27(C₅₂H₃₅NO₂ = 705.86) | P-84 | m/z = 795.28(C₅₈H₃₇NO₃ = 795.94) |
| P1-1 | m/z = 705.27(C₅₂H₃₅NO₂ = 705.86) | P1-2 | m/z = 781.30(C₅₈H₃₉NO₂ = 781.96) |
| P1-3 | m/z = 705.27(C₅₂H₃₅NO₂ = 705.86) | P1-4 | m/z = 705.27(C₅₂H₃₅NO₂ = 705.86) |
| P1-5 | m/z = 721.24(C₅₂H₃₃NOS = 721.92) | P1-6 | m/z = 829.30(C₆₂H₃₉NO₂ = 830.00) |
| P1-7 | m/z = 829.30(C₆₂H₃₉NO₂ = 830.00) | P1-8 | m/z = 829.30(C₆₂H₃₉NO₂ = 830.00) |
| P1-9 | m/z = 829.30(C₆₂H₃₉NO₂ = 830.00) | P1-10 | m/z = 845.28(C₆₂H₃₉NOS = 846.06) |
| P1-11 | m/z = 827.28(C₆₂H₃₇NO₂ = 827.98) | P1-12 | m/z = 843.26(C₆₂H₃₇NOS = 844.04) |
| P1-13 | m/z = 781.30(C₅₈H₃₉NO₂ = 781.96) | P1-14 | m/z = 797.28(C₅₈H₃₉NOS = 798.02) |
| P1-15 | m/z = 781.30(C₅₈H₃₉NO₂ = 781.96) | P1-16 | m/z = 797.28(C₅₈H₃₉NOS = 798.02) |
| P1-17 | m/z = 781.30(C₃₈H₃₉NO₂ = 781.96) | P1-18 | m/z = 797.28(C₅₈H₃₉NOS = 798.02) |
| P1-19 | m/z = 781.30(C₅₈H₃₉NO₂ = 781.96) | P1-20 | m/z = 781.30(C₅₈H₃₉NO₂ = 781.96) |
| P1-21 | m/z = 781.30(C₅₈H₃₉NO₂ = 781.96) | P1-22 | m/z = 781.30(C₅₈H₃₉NO₂ = 781.96) |
| P1-23 | m/z = 797.28(C₅₈H₃₉NOS = 798.02) | P1-24 | m/z = 797.28(C₅₈H₃₉NOS = 798.02) |
| P1-25 | m/z = 797.28(C₅₈H₃₉NOS = 798.02) | P1-26 | m/z = 831.31(C₆₂H₄₁NO₂ = 832.02) |
| P1-27 | m/z = 847.29(C₆₂H₄₁NOS = 848.08) | P1-28 | m/z = 831.31(C₆₂H4₁NO₂ = 832.02) |
| P1-29 | m/z = 847.29(C₆₂H₄₁NOS = 848.08) | P1-30 | m/z = 831.31(C₆₂H₄₁NO₂ = 832.02) |
| P1-31 | m/z = 847.29(C₆₂H₄₁NOS = 848.08) | P1-32 | m/z = 782.29(C₅₇H₃₈N₂O₂ = 782.94) |
| P1-33 | m/z = 913.34(C₆₇H₄₇NOS = 914.18) | P1-34 | m/z = 855.31(C₆₄H₄₁NO₂ = 856.04) |
| P1-35 | m/z = 849.30(C₆₂H₃₅D₄NOS = | P1-36 | m/z = 857.33(C₆₄H₄₃NO₂ = |
| | 850.08) | | 858.05) |
| P1-37 | m/z = 873.31(C₆₄H₄₃NOS = 874.11) | P1-38 | m/z = 857.33(C₆₄H₄₃NO_{z} = 858.05) |
| P1-39 | m/z = 873.31(C₆₄H₄₃NOS = 874.11) | P1-40 | m/z = 873.31(C₆₄H₄₃NOS = 874.11) |
| P1-41 | m/z = 857.33(C₆₄H₄₃NO₂ = 858.05) | P1-42 | m/z = 857.33(C₆₄H₄₃NO₂ = 858.05) |
| P1-43 | m/z = 857.33(C₆₄H₄₃NO₂ = 858.05) | P1-44 | m/z = 873.31(C₆₄H₄₃NOS = 874.11) |
| P1-45 | m/z = 873.31(C₆₄H₄₃NOS = 874.11) | P1-46 | m/z = 797.28(C₅₈H₃₉NOS = 798.02) |
| P1-47 | m/z = 721.24(C₅₂H₃₅NOS = 721.92) | P1-48 | m/z = 721.24(C₅₂H₃₅NOS = 721.92) |
| P1-49 | m/z = 721.24(C₅₂H₃₅NOS = 721.92) | P1-50 | m/z = 737.22(C₅₂H₃₅NS₂ = 737.98) |
| P1-51 | m/z = 845.28(C₆₂H₃₉NOS = 846.06) | P1-52 | m/z = 861.25(C₆₂H₃₉NS = = 862.12) |
| P1-53 | m/z = 861.25(C₆₂H₃₉NS₂ = 862.12) | P1-54 | m/z = 861.25(C₆₂H₃₉NS₂ = 862.12) |
| P1-55 | m/z = 861.25(C₆₂H₃₉NS₂ = 862.12) | P1-56 | m/z = 921.28(C₆₂H₃₉N₃OS = 922.12) |
| P1-57 | m/z = 859.24(C₆₂H₃₇NS₂ = 860.11) | P1-58 | m/z = 797.28(C₅₈H₃₉NOS = 798.02) |
| P1-59 | m/z = 813.25(C₅₈H₃₉NS₂ = 814.08) | P1-60 | m/z = 797.28(C₅₈H₃₉NOS = 798.02) |
| P1-61 | m/z = 813.25(C₅₈H₃₉NS₂ = 814.08) | P1-62 | m/z = 797.28(C₅₈H₃₉NOS = 798.02) |
| P1-63 | m/z = 813.25(C₅₈H₃₉NS₂ = 814.08) | P1-64 | m/z = 797.28(C₅₈H₃₉NOS = 798.02) |
| P1-65 | m/z = 813.25(C₅₈H₃₉NS₂ = 814.08) | P1-66 | m/z = 847.29(C₆₂H₄₁NOS = 848.08) |
| P1-67 | m/z = 863.27(C₆₂H₄₁NS₂ = 864.14) | P1-68 | m/z = 847.29(C₆₂H₄₁NOS = 848.08) |
| P1-69 | m/z = 863.27(C₆₂H₄₁NS₂ = 864.14) | P1-70 | m/z = 847.29(C₆₂H₄₁NOS = 848.08) |
| P1-71 | m/z = 863.27(C₈₂H₄₁NS₂ = 864.14) | P1-72 | m/z = 798.27(C₅₇H₃₈N₂OS = 799.00) |
| P1-73 | m/z = 797.28(C₅₈H₃₉NOS = 798.02) | P1-74 | m/z = 787.24(C₅₆H₃₇NS₂ = 788.04) |
| P1-75 | m/z = 787.24(C₅₆H₃₇NS₂ = 788.04) | P1-76 | m/z = 771.26(C₅₆H₃₇NOS = 771.98) |
| P1-77 | m/z = 771.26(C₅₆H₃₇NOS = 771.98) | P1-78 | m/z = 813.25(C₅₈H₃₉NS₂ = 814.08) |
| P1-79 | m/z = 907.35(C₆₈H₄₅NO₂ = 908.11) | P1-80 | m/z = 903.31(C₆₈H₄₁NO = 904.08) |
| P1-81 | m/z = 827.28(C₆₂H₃₇NO₂ = 827.98) | P1-82 | m/z = 843.26(C₆₂H₃₇NOS = 844.04) |
| P1-83 | m/z = 843.26(C₆₂H₃₇NOS = 844.04) | P1-84 | m/z = 787.24(C₅₆H₃₇NS₂ = 788.04) |
| P1-85 | m/z = 879.31(C₆₆H₄₁NO₂ = 880.06) | P1-86 | m/z = 829.30(C₆₂H₃₉NO₂ = 830.00) |
| P1-87 | m/z = 649.23(C₄₈H₃₁N₃ = 649.80) | | |
| P2-1 | m/z = 843.28(C₆₂H₃₇NO₃ = 843,98) | P2-2 | m/z = 843.28(C₆₂H₃₇NO₃ = 843.98) |
| P2-3 | m/z = 843.28(C₆₂H₃₇NO₃ = 843.98) | P2-4 | m/z = 843.28(C₆₂H₃₇NO₃ = 843.98) |
| P2-5 | m/z = 909.27(C₆₆H₃₉NO₂S = 910.10) | P2-6 | m/z = 861.27(C₆₂H₃₆FNO₃ = 861.97) |
| P2-7 | m/z = 893.29(C₆₆H₃₉NO₃ = 894.04) | P2-8 | m/z = 995.34(C₇₄H₄₅NO₃ = 996.18) |
| P2-9 | m/z = 859.25(C₆₂H₃₇NO₂S = 860.04) | P2-10 | m/z = 859.25(C₆₂H₃₇NO₂S = 860.04) |
| P2-11 | m/z = 859.25(C₆₂H₃₇NO₂S = 860.04) | P2-12 | m/z = 859.25(C₆₂H₃₇NO₂S = 860.04) |
| P2-13 | m/z = 859.25(C₆₂H₃₇NO₂S = 860.04) | P2-14 | m/z = 859.25(C₆₂H₃₇NO₂S = 860.04) |
| P2-15 | m/z = 859.25(C₆₂H₃₇NO₂S = 860.04) | P2-16 | m/z = 859.25(C₆₂H₃₇NO₂S = 860.04) |
| P2-17 | m/z = 875.23(C₆₂H₃₇NOS₂ = 876.10) | P2-18 | m/z = 875.23(C₆₂H₃₇NOS₂ = 876.1) |
| P2-19 | m/z = 891.21(C₆₂H₃₇NS₃ = 892.17) | P2-20 | m/z = 919.31(C₆₈H₄₁NO = 920.08) |
| P2-21 | m/z = 935.29(C₆₈H₄₁NO₂S = 936.14) | P2-22 | m/z = 951.26(C₆₈H₄₁NOS₂ = 952.20) |
| P2-23 | m/z = 967.24(C₆₈H₄₁NS₃ = 968.26) | P2-24 | m/z = 985.30(C₇₂H₄₃NO₂S = 986.20) |
| P2-25 | m/z = 1001.28(C₇₂H₄₃NOS₂ = | P2-26 | m/z = 952.26(C₆₇H₄₀N₂OS₂ = |
| | 1002.26) | | 953.19) |
| P2-27 | m/z = 952.26(C₆₇H₄₀N₂OS₂ = 953.19) | P2-28 | m/z = 919.31(C₆₈H₄₁NO₃ = 920.08) |
| P2-29 | m/z = 935.29(C₆₈H₄₁NO₂S = 936.14) | P2-30 | m/z = 919.31(C₆₈H₄₁NO₃ = 920.08) |
| P2-31 | m/z = 935.29(C₆₈H₄₁NO₂S = 936.14) | P2-32 | m/z = 935.29(C₆₈H₄₁NO₂S = 936.14) |
| P2-33 | m/z = 967.24(C₆₈H₄₁NS₃ = 968.26) | P2-34 | m/z = 900.23(C₆₃H₃₆N₂OS₂ = 901.11) |
| P2-35 | m/z = 901.25(C₆₄H₃₉NOS = 902.14) | P2-36 | m/z = 893.29(C₆₆H₃₉NO₃ = 894.04) |
| P2-37 | m/z = 941.22(C₆₆H₃₉NS₃ = 942.23) | P2-38 | m/z = 909.27(C₆₆H₃₉NO₂S = 910.10) |
| P2-39 | m/z = 919.31(C₆H₄₁NO₃ = 920,08) | P2-40 | m/z = 941.22(C₆₆H₃₉NS₃ = 942.23) |
| P2-41 | m/z = 909.27(C₆₆H₃₉NO₂S = 910.1) | P2-42 | m/z = 893.29(C₆₆H₃₉NO₃ = 894.04) |
| P2-43 | m/z = 941.22(C₆₆H₃₉NS₃ = 942.23) | P2-44 | m/z = 909.27(C₆₆H₃₉NO₂S = 910.10) |
| P2-45 | m/z = 893.29(C₆₆H₃₉NO₃ = 894.04) | P2-46 | m/z = 951.26(C₆₈H₄₁NOS₂ = 952.2) |
| P2-47 | m/z = 1017.26(C₇₂H₄₃NS₃ = 1018.32) | P2-48 | m/z = 995.34(C₇₄H₄₅NO₃ = 996.18) |
| P2-49 | m/z = 895.23(C₆₂H₃₃D₄NS₃ = 896.19) | P2-50 | m/z = 995.34(C₇₄H₄₅NO₃ = 996.18) |
| P2-51 | m/z = 995.34(C₇₄H₄₅NO₃ = 996.18) | P2-52 | m/z = 1093.29(C₇₈H₄₁NS₃ = 1094.42) |
| P2-53 | m/z = 975.26(C₇₀H₄₁NOS₂ = 976.22) | P2-54 | m/z = 991.24(C₇₀H₄₁NS₃ = 992.29) |
| P2-55 | m/z = 943.31(C₇₀H₄₁NO₃ = 944.10) | | |
| P3-1 | m/z = 691.29(C₅₂H₃₇NO = 691.87) | P3-2 | m/z = 651.26(C₄₉H₃₃NO = 651.81) |
| P3-3 | m/z = 767.32(C₅₈H₄₁NO = 767.97) | P3-4 | m/z = 651.26(C₄₉H₃₃NO = 651.81) |
| P3-5 | m/z = 641.22(C₄₇H₃₁NS = 641.83) | P3-6 | m/z = 700.29(C₅₃H₃₆N₂ = 700.89) |
| P3-7 | m/z = 601.28(C₄₆H₃₅N = 601.79) | P3-8 | m/z = 651.26(C₄₉H₃₃NO = 651.81) |
| P3-9 | m/z = 843.3(C₆₃H₄₁NS = 844.09) | P3-10 | m/z = 701.28(C₅₂H₃₅N₃ = 701.87) |
| P3-11 | m/z = 677.31(C₅₂H₃₉N = 677.89) | P3-12 | m/z = 729.28(C₅₃H₃₅N₃O = 729.88) |
| P3-13 | m/z = 912.29(C₆₄H₄₀N₄OS = 913.11) | P3-14 | m/z = 878.34(C₆₅H₄₂N₄ = 879.08) |
| P3-15 | m/z = 805.35(C₆₀H₄₃N₃ = 806.03) | P3-16 | m/z = 906.34(C₆₆H₄₂N₃O = 907.09) |
| P3-17 | m/z = 769.26(C₅₅H₃₅N₃S = 769.97) | P3-18 | m/z = 884.3(C₆₃H₄₀N₄S = 885.1) |
| P3-19 | m/z = 767.36(C₅₉H₄₅N = 768.02) | P3-20 | m/z = 815.32(C₆₂H₄₁NO = 816.02) |
| P3-21 | m/z = 829.28(C₆₂H₃₉NS = 830.06) | P3-22 | m/z = 781.35(C₅₉H₃₅D₅N₂ = 782.01) |
| P3-23 | m/z = 695.3(C₅₂H₃₈FN = 695.88) | P3-24 | m/z = 753.34(C₅₈H₄₃N = 753.99) |
| P3-25 | m/z = 803.36(C₆₂H₄₅N = 804.05) | P3-26 | m/z = 829.37(C₆₄H₄₇N = 830.09) |
| P3-27 | m/z = 918.4(C₇₀H₅₀N₂ = 919.18) | P3-28 | m/z = 601.28(C₄₆H₃₅N = 601.79) |
| P3-29 | m/z = 677.31(C₃₂H₃₉N = 677.89) | P3-30 | m/z = 753.34(C₅₈H₄₃N = 753.99) |
| P3-31 | m/z = 701.31(C₅₄H₃₉N = 701.91) | P3-32 | m/z = 677.31(C₅₂H₃₉N = 677.89) |
| P3-33 | m/z = 677.31(C₅₂H₃₉N = 677.89) | P3-34 | m/z = 682.34(C₅₂H₃₄D₅N = 682.92) |
| P3-35 | m/z = 701.31(C₅₄H₃₉N = 701.91) | P3-36 | m/z = 619.27(C₄₆H₃₄FN = 619.78) |
| P3-37 | m/z = 753.34(C₅₈H₄₃N = 753.99) | P3-38 | m/z = 879.39(C₆₈H₄₉N = 880.15) |
| P3-39 | m/z = 701.31(C₅₄H₃₉N = 701.91) | P3-40 | m/z = 651.29(C₅₀H₃₇N = 651.85) |
| P3-41 | m/z = 727.32(C₅₆H₄₁N = 727.95) | P3-42 | m/z = 758.37(C₅₈H₃₈D₅N = 759.02) |
| P3-43 | m/z = 757.37(C₅₈H₄₇N = 758.02) | P3-44 | m/z = 753.34(C₅₈H₄₃N = 753.99) |
| P3-45 | m/z = 803.36(C₆₂H₄₅N = 804.05) | P3-46 | m/z = 834.4(C₆₄H₄₂D₅N = 835.12) |
| P3-47 | m/z = 883.33(C₆₆H₄₅NS = 884.15) | P3-48 | m/z = 651.26(C₄₉H₃₃NO = 651.81) |
| P3-49 | m/z = 641.22(C₄₇H₃₁NS = 641.83) | P3-50 | m/z = 700.29(C₅₃H₃₆N₂ = 700.89) |
| P3-51 | m/z = 677.31(C₅₂H₃₉N = 677.89) | P3-52 | m/z = 651.26(C₄₉H₃₃NO = 651.81) |
| P3-53 | m/z = 843.3(C₆₃H₄₁NS = 844.09) | P3-54 | m/z = 701.28(C₅₂H₃₅N₃ = 701.87) |
| P3-55 | m/z = 677.31(C₅₂H₃₉N = 677.89) | P3-56 | m/z = 906.34(C₆₆H₄₂NO = 907.09) |
| P3-57 | m/z = 769.26(C₅₅H₃₅N₃S = 769.97) | P3-58 | m/z = 884.3(C₆₃H₄₀N₄S = 885.1) |
| P3-59 | m/z = 767.36(C₅₉H₄₅N = 768.02) | P3-60 | m/z = 815.32(C₆₂H₄₁NO = 816.02) |
| P3-61 | m/z = 829.28(C₆₂H₃₉NS = 830.06) | P3-62 | m/z = 781.35(C₅₉H₃₅D₅N₂ = 782.01) |
| P3-63 | m/z = 695.3(C₅₂H₃₈FN = 695.88) | P3-64 | m/z = 753.34(C₅₈H₄₃N = 753.99) |
| P3-65 | m/z = 803.36(C₆₂H₄₅N = 804.05) | P3-66 | m/z = 829.37(C₆₄H₄₇N = 830.09) |
| P3-67 | m/z = 918.4(C₇₀H₅₀N₂ = 919.18) | P3-68 | m/z = 753.34(C₅₈H₄₃N = 753.99) |
| P3-69 | m/z = 753.34(C₅₈H₄₃N = 753.99) | P3-70 | m/z = 601.28(C₄₆H₃₅N = 601.79) |
| P3-71 | m/z = 677.31(C₅₂H₃₉N = 677.89) | P3-72 | m/z = 677.31(C₅₂H₃₉N = 677.89) |
| P3-73 | m/z = 677.31(C₅₂H₃₉N = 677.89) | P3-74 | m/z = 677.31(C₅₂H₃₉N = 677.89) |
| P3-75 | m/z = 677.31(C₅₂H₄₃N = 677.89) | P3-76 | m/z = 717.34(C₅₅H₄₃N = 717.96) |
| P3-77 | m/z = 753.34(C₅₈H₄₃N = 753.99) | P3-78 | m/z = 691.29(C₅₂H₃₇NO = 691.87) |
| P3-79 | m/z = 767.32(C₅₈H₄₁NO = 767.97) | P3-80 | m/z = 651.26(C₄₉H₃₃NO = 651.81) |
| P3-81 | m/z = 665.24(C₄₉H₃₁NO₂ = 665.79) | P3-82 | m/z = 691.29(C₅₂H₃₇NO = 691.87) |
| P3-83 | m/z = 717.34(C₅₅H₄₃N = 717.96) | P3-84 | m/z = 677.31(C₅₂H₃₉N = 677.89) |
| P3-85 | m/z = 691.29(C₅₂H₃₇NO = 691.87) | P3-86 | m/z = 753.34(C₅₈H₄₃N = 753,99) |
| P3-87 | m/z = 727.32(C₅₆H₄₁N = 727.95) | P3-88 | m/z = 717.34(C₅₅H₄₃N = 717.96) |
| P3-89 | m/z = 677.31(C₅₂H₃₉N = 677.89) | P3-90 | m/z = 753.34(C₅₈H₄₃N = 753.99) |
| P3-91 | m/z = 727.32(C₅₆H₄₁N = 727.95) | P3-92 | m/z = 793.37(C₆₁H₄₇N = 794.05) |
| P3-93 | m/z = 753.34(C₅₈H₄₃N = 753.99) | P3-94 | m/z = 753.34(C₅₈H₄₃N = 753.99) |
| P3-95 | m/z = 615.29(C₄₇H₃₇N = 615.82) | P3-96 | m/z = 615.29(C₄₇H₃₇N = 615.82) |
| P3-97 | m/z = 691.32(C₅₃H₄₁N = 691.92) | P3-98 | m/z = 691.32(C₅₃H₄₁N = 691.92) |
| P3-99 | m/z = 691.32(C₅₃H₄₁N = 691.92) | P3-100 | m/z = 691.32(C₅₃H₄₁N = 691.92) |
| P3-101 | m/z = 691.32(C₅₃H₄₁N = 691.92) | P3-102 | m/z = 691.32(C₅₃H₄₁N = 691.92) |
| P3-103 | m/z = 801.34(C₆₂H₄₃N = 802.03) | P3-104 | m/z = 815.32(C₆₂H₄₁NO = 816.02) |
| P3-105 | m/z = 815.32(C₆₂H₄₁NO = 816.02) | P3-106 | m/z = 841.37(C₆₅H₄₇N = 842.10) |
| P3-107 | m/z = 851.36(C₆₆H₄₅N = 852.09) | P3-108 | m/z = 801.34(C₆₂H₄₃N = 802.03) |

### [Synthesis Example of 2] Compounds Represented by Formula

The compound represented by Formula 2 according to the present invention (final products 2) may be prepared by reacting Sub 3 and Sub 4 as shown in Reaction Scheme 2 below, but is not limited thereto. Sub 3 may be the same as Sub 1 of Reaction Scheme 1. In addition, the compound represented by Formula 2 according to the present invention (Final product 2) was prepared by the synthesis method disclosed in Korean Patent No. 10-1614739 (registration-published on Apr. 18, 2016) and Korean Patent Application No. 10-2016-0110817 (filed on Aug. 30, 2016) which are filed by the applicant of the present invention, but is not limited thereto.

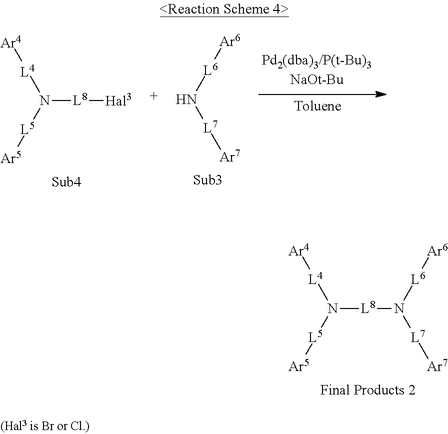

### Synthesis Example of Sub 3

Sub 3 of Reaction Scheme 3 may be synthesized by the reaction route of the following Reaction Scheme 5, but are not limited thereto.

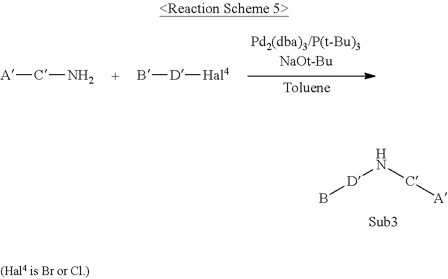

In Reaction Scheme 5, A′ and B′ are correspond to Ar⁶ and Ar⁷, respectively, and C′ and D′ are correspond to L⁶ and L⁷, respectively.

### 1. Synthesis Example of Sub 3-1

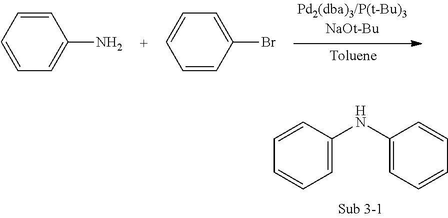 [SMILES: Nc1ccccc1 ; Brc1ccccc1 ; c1ccc(Nc2ccccc2)cc1]

After aniline (12.0 g, 128.24 mmol) was dissolved in toluene (400 mL) and bromobenzene (20.1 g, 128.24 mmol), Pd₂(dba)₃ (5.9 g, 6.44 mmol), 50% P(t-Bu)₃ (5.21 mL, 12.89 mmol) and NaOt-Bu (37.16 g, 386.64 mmol) were added to the solution, the mixture was stirred at 100° C. When the reaction was completed, the reaction product was extracted with CH₂Cl₂ and water. Then, an organic layer was dried over MgSO₄ and concentrated. Then, the concentrate was separated by a silica gel column and recrystallized to obtain 17.01 g (yield: 78%) of the product.

### 2. Synthesis Example of Sub 3-22

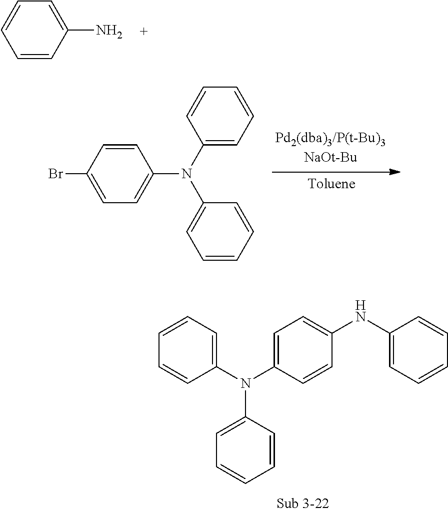 [SMILES: Nc1ccccc1 ; Brc1ccc(N(c2ccccc2)c2ccccc2)cc1 ; c1ccc(Nc2ccc(N(c3ccccc3)c3ccccc3)cc2)cc1]

After dissolving aniline (7.09 g, 76.18 mmol) in toluene (500 mL) in a round bottom flask, 4-bromo-N,N-diphenylaniline (24.7 g 76.18 mmol), Pd₂(dba)₃ (3.49 g, 3.81 mmol), 50% P(t-Bu)₃ (3.08 mL, 7.62 mmol) and NaOt-Bu (21.96 g, 228.55 mmol) were added to the solution, and then the reaction was carried out in the same manner as in the synthesis method of Sub 3-1 to obtain 19.22 g (yield: 75%) of the product.

### 3. Synthesis Example of Sub 3-46

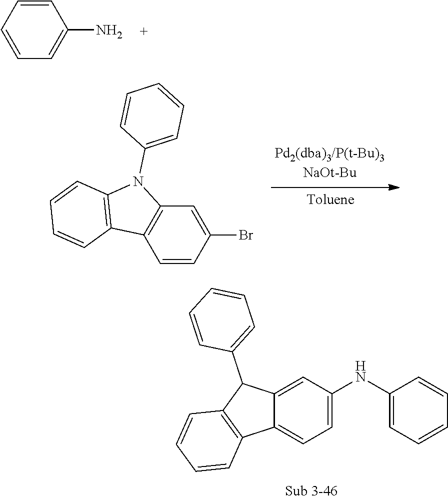

After dissolving aniline (5.72 g, 61.45 mmol) in toluene (400 mL) in a round bottom flask, 2-bromo-9-phenyl-9H-carbazole (19.80 g, 61.45 mmol), Pd₂(dba)₃ (2.81 g, 3.07 mmol), 50% P(t-Bu)₃ (2.49 mL, 6.15 mmol) and NaOt-Bu (17.72 g, 184.35 mmol) were added to the solution, and then the reaction was carried out in the same manner as in the synthesis method of Sub 3-1 to obtain 14.39 g (yield: 70%) of the product.

### 4. Synthesis Example of Sub 3-57

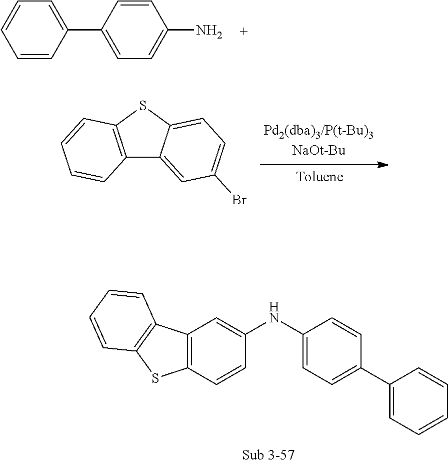 [SMILES: Nc1ccc(-c2ccccc2)cc1 ; Brc1ccc2sc3ccccc3c2c1 ; c1ccc(-c2ccc(Nc3ccc4sc5ccccc5c4c3)cc2)cc1]

After dissolving [1,1′-biphenyl]-4-amine (13.86 g, 81.89 mmol) in toluene (430 mL) in a round bottom flask, 2-bromodibenzo[b,d]thiophene (21.55 g, 81.89 mmol), Pd₂(dba)₃ (3.75 g, 4.09 mmol), 50% P(t-Bu)₃ (3.31 mL, 8.19 mmol) and NaOt-Bu (23.61 g, 245.68 mmol) were added to the solution, and then the reaction was carried out in the same manner as in the synthesis method of Sub 3-1 to obtain 20.44 g (yield: 71%) of the product.

### 5. Synthesis Example of Sub 3-69

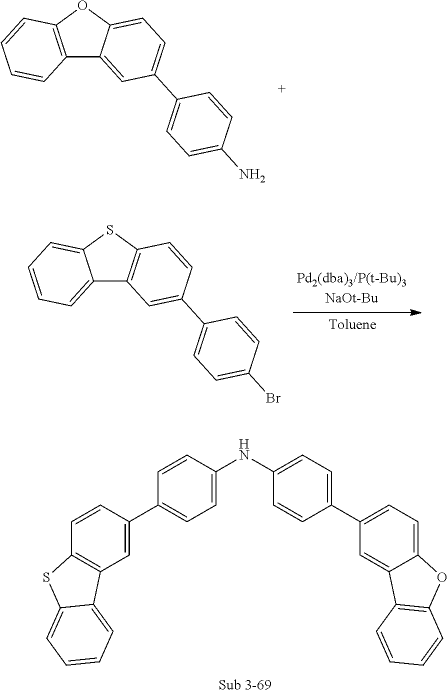 [SMILES: Nc1ccc(-c2ccc3oc4ccccc4c3c2)cc1 ; Brc1ccc(-c2ccc3sc4ccccc4c3c2)cc1 ; c1ccc2c(c1)oc1ccc(-c3ccc(Nc4ccc(-c5ccc6sc7ccccc7c6c5)cc4)cc3)cc12]

After dissolving 4-(dibenzo[b,d]furan-2-yl)aniline (12.60 g, 48.58 mmol) in toluene (330 mL) in a round bottom flask, 2-(4-bromophenyl)dibenzo[b,d]thiophene (16.48 g, 48.58 mmol), Pd₂(dba)₃ (2.22 g, 2.43 mmol), 50% P(t-Bu)₃ (1.97 mL, 4.86 mmol) and NaOt-Bu (14.0 g, 145.73 mmol) were added to the solution, and then the reaction was carried out in the same manner as in the synthesis method of Sub 3-1 to obtain 11.78 g (yield: 69%) of the product.

Compounds belonging to Sub 3 are as follows, but are not limited thereto, and FD-MS values of the compounds are shown in Table 4 below.

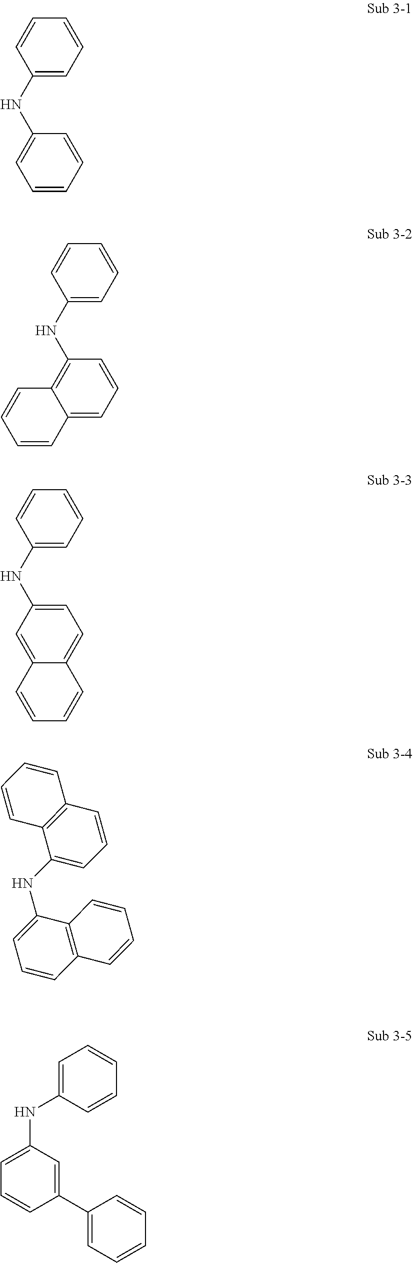

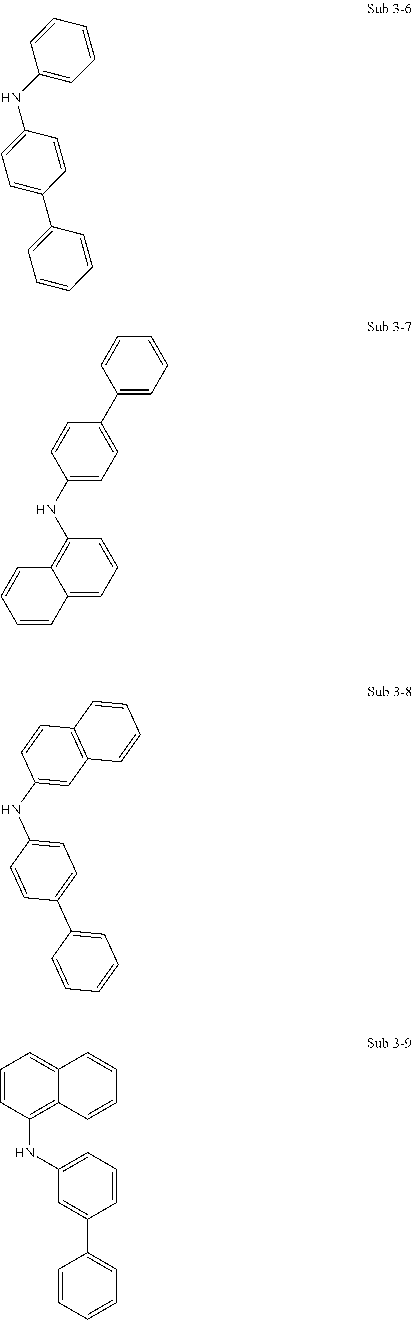 [SMILES: c1ccc(Nc2ccc(-c3ccccc3)cc2)cc1 ; c1ccc(-c2ccc(Nc3cccc4ccccc34)cc2)cc1 ; c1ccc(-c2ccc(Nc3ccc4ccccc4c3)cc2)cc1 ; c1ccc(-c2cccc(Nc3cccc4ccccc34)c2)cc1]

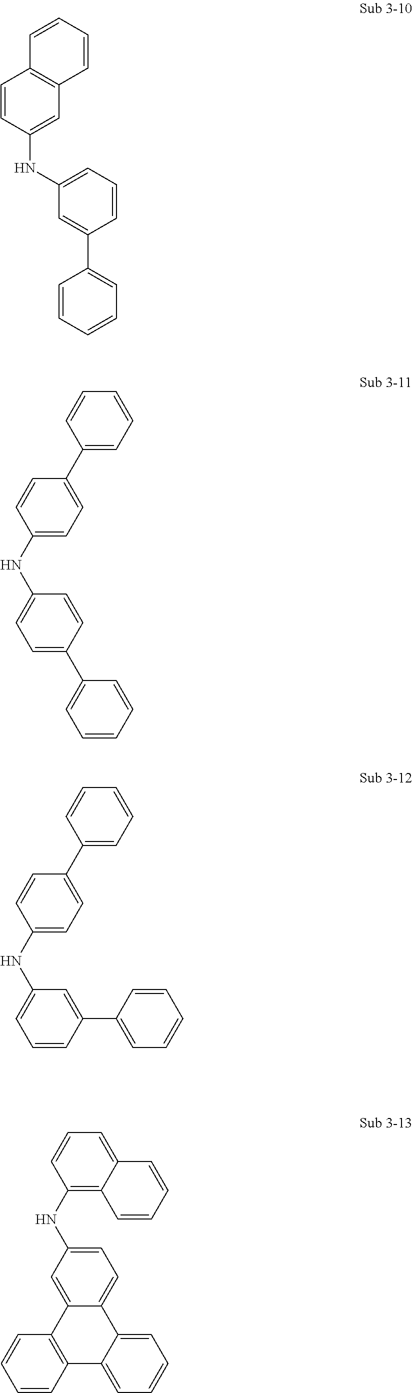 [SMILES: c1ccc(-c2cccc(Nc3ccc4ccccc4c3)c2)cc1 ; c1ccc(-c2ccc(Nc3ccc(-c4ccccc4)cc3)cc2)cc1 ; c1ccc(-c2ccc(Nc3cccc(-c4ccccc4)c3)cc2)cc1 ; c1ccc2c(Nc3ccc4c5ccccc5c5ccccc5c4c3)cccc2c1]

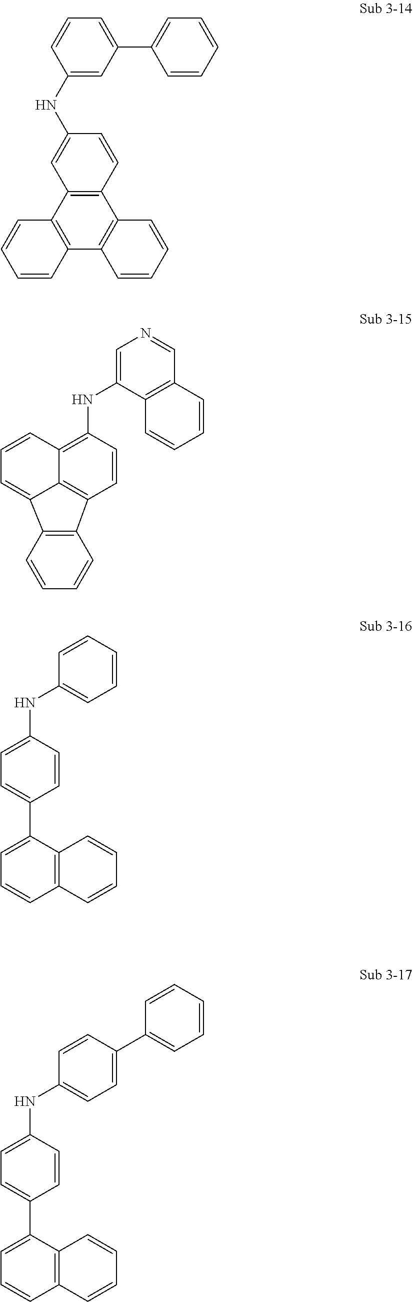 [SMILES: c1ccc(-c2cccc(Nc3ccc4c5ccccc5c5ccccc5c4c3)c2)cc1 ; c1ccc2c(c1)-c1cccc3c(Nc4cncc5ccccc45)ccc-2c13 ; c1ccc(Nc2ccc(-c3cccc4ccccc34)cc2)cc1 ; c1ccc(-c2ccc(Nc3ccc(-c4cccc5ccccc45)cc3)cc2)cc1]

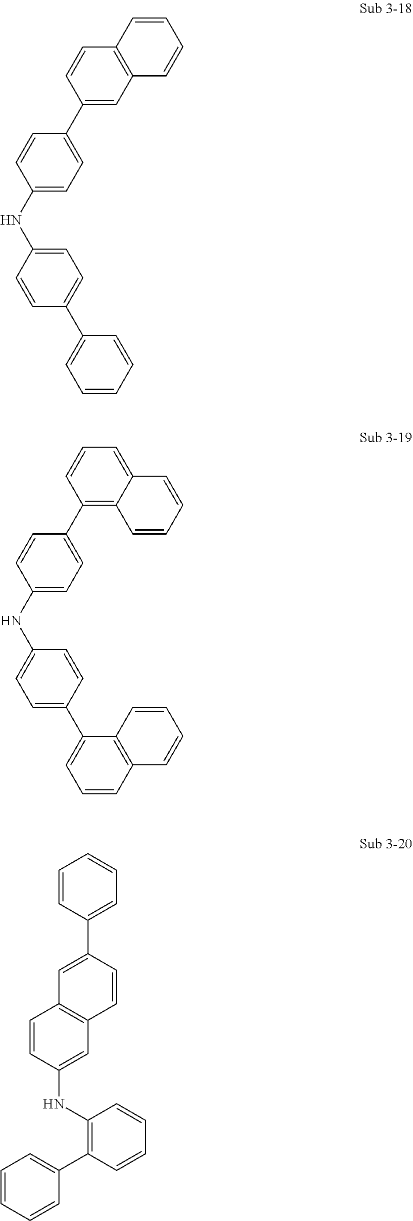 [SMILES: c1ccc(-c2ccc(Nc3ccc(-c4ccc5ccccc5c4)cc3)cc2)cc1 ; c1ccc2c(-c3ccc(Nc4ccc(-c5cccc6ccccc56)cc4)cc3)cccc2c1 ; c1ccc(-c2ccc3cc(Nc4ccccc4-c4ccccc4)ccc3c2)cc1]

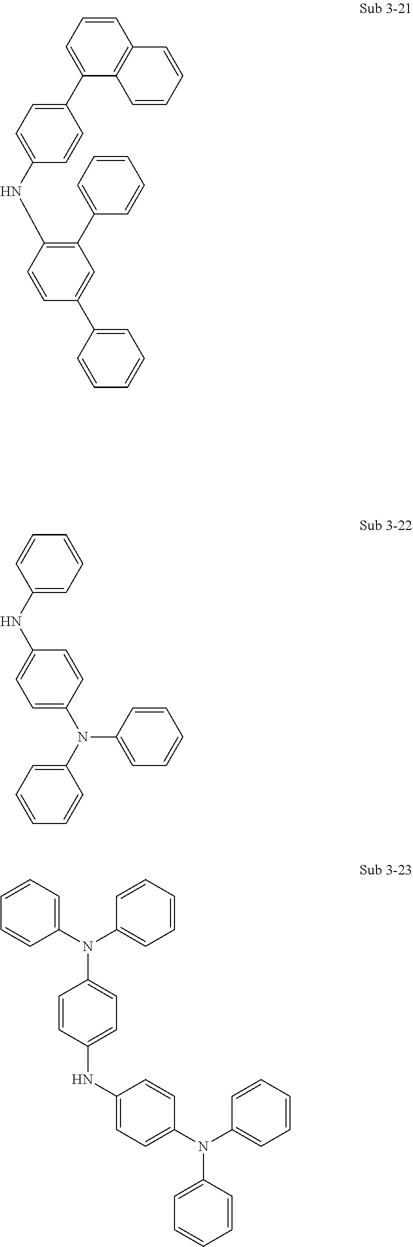 [SMILES: c1ccc(-c2ccc(Nc3ccc(-c4cccc5ccccc45)cc3)c(-c3ccccc3)c2)cc1 ; c1ccc(Nc2ccc(N(c3ccccc3)c3ccccc3)cc2)cc1 ; c1ccc(N(c2ccccc2)c2ccc(Nc3ccc(N(c4ccccc4)c4ccccc4)cc3)cc2)cc1]

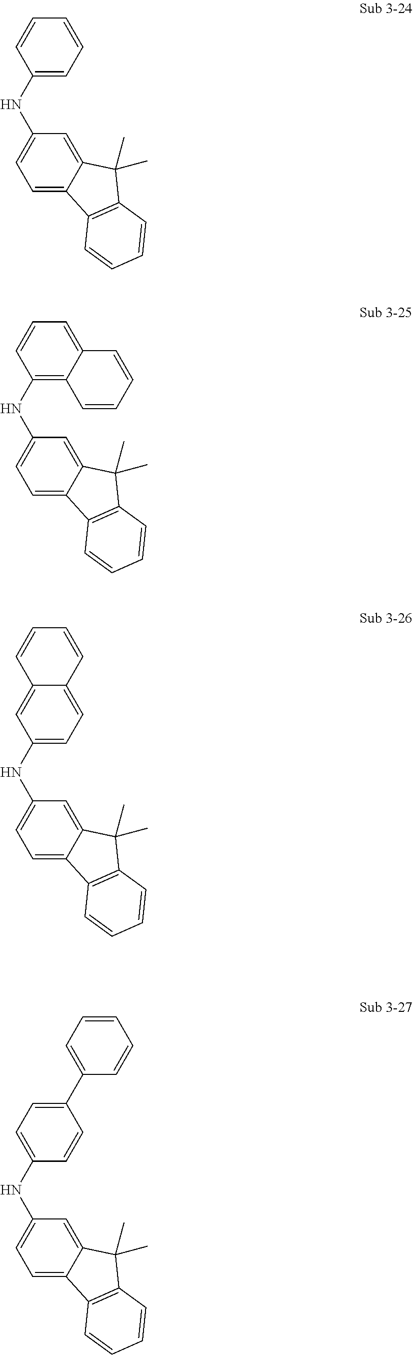 [SMILES: CC1(C)c2ccccc2-c2ccc(Nc3ccccc3)cc21 ; CC1(C)c2ccccc2-c2ccc(Nc3cccc4ccccc34)cc21 ; CC1(C)c2ccccc2-c2ccc(Nc3ccc4ccccc4c3)cc21 ; CC1(C)c2ccccc2-c2ccc(Nc3ccc(-c4ccccc4)cc3)cc21]

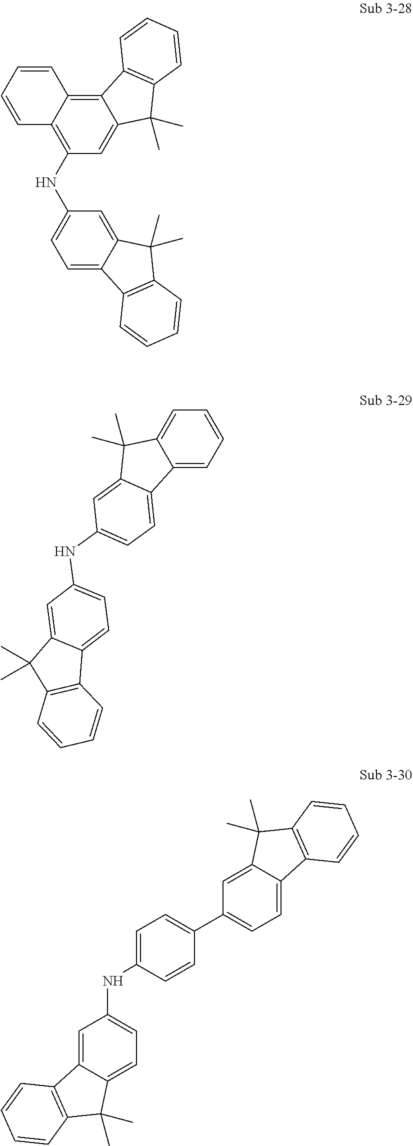 [SMILES: CC1(C)c2ccccc2-c2ccc(Nc3cc4c(c5ccccc35)-c3ccccc3C4(C)C)cc21 ; CC1(C)c2ccccc2-c2ccc(Nc3ccc4c(c3)C(C)(C)c3ccccc3-4)cc21 ; CC1(C)c2ccccc2-c2cc(Nc3ccc(-c4ccc5c(c4)C(C)(C)c4ccccc4-5)cc3)ccc21]

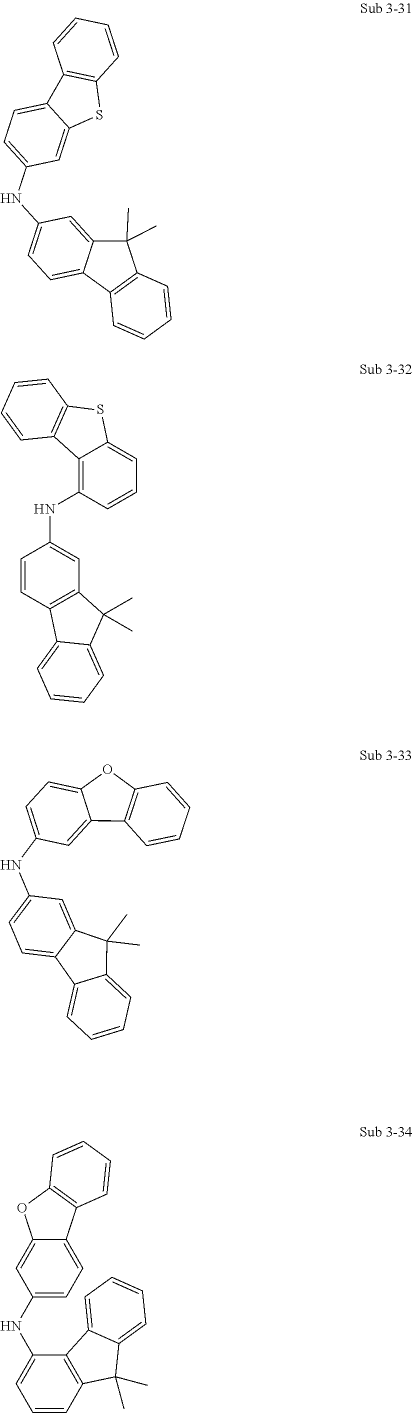 [SMILES: CC1(C)c2ccccc2-c2ccc(Nc3ccc4c(c3)sc3ccccc34)cc21 ; CC1(C)c2ccccc2-c2ccc(Nc3cccc4sc5ccccc5c34)cc21 ; CC1(C)c2ccccc2-c2ccc(Nc3ccc4oc5ccccc5c4c3)cc21 ; CC1(C)c2ccccc2-c2c(Nc3ccc4c(c3)oc3ccccc34)cccc21]

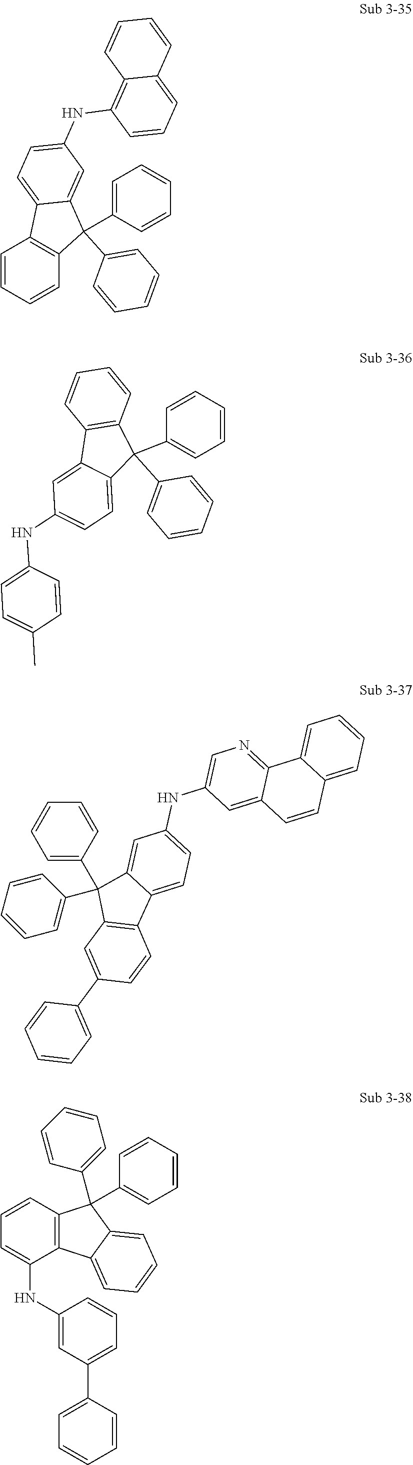

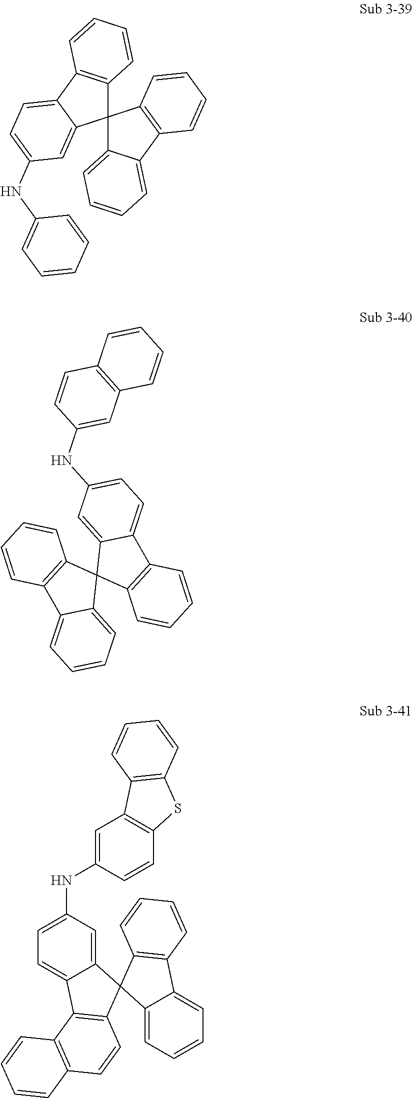 [SMILES: c1ccc(Nc2ccc3c(c2)C2(c4ccccc4-c4ccccc42)c2ccccc2-3)cc1 ; c1ccc2c(c1)-c1ccccc1C21c2ccccc2-c2ccc(Nc3ccc4ccccc4c3)cc21 ; c1ccc2c(c1)-c1ccccc1C21c2cc(Nc3ccc4sc5ccccc5c4c3)ccc2-c2c1ccc1ccccc21]

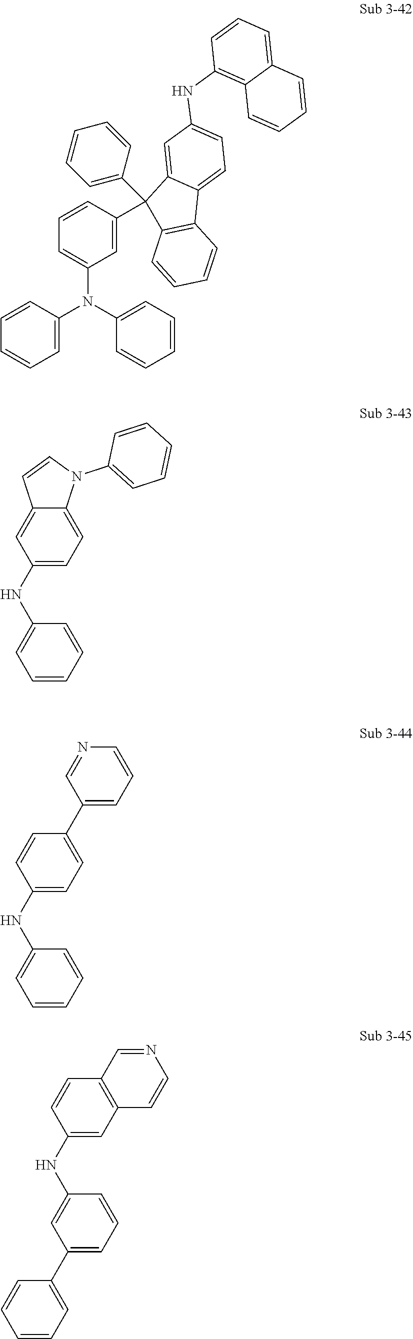 [SMILES: c1ccc(N(c2ccccc2)c2cccc(C3(c4ccccc4)c4ccccc4-c4ccc(Nc5cccc6ccccc56)cc43)c2)cc1 ; c1ccc(Nc2ccc3c(ccn3-c3ccccc3)c2)cc1 ; c1ccc(Nc2ccc(-c3cccnc3)cc2)cc1 ; c1ccc(-c2cccc(Nc3ccc4cnccc4c3)c2)cc1]

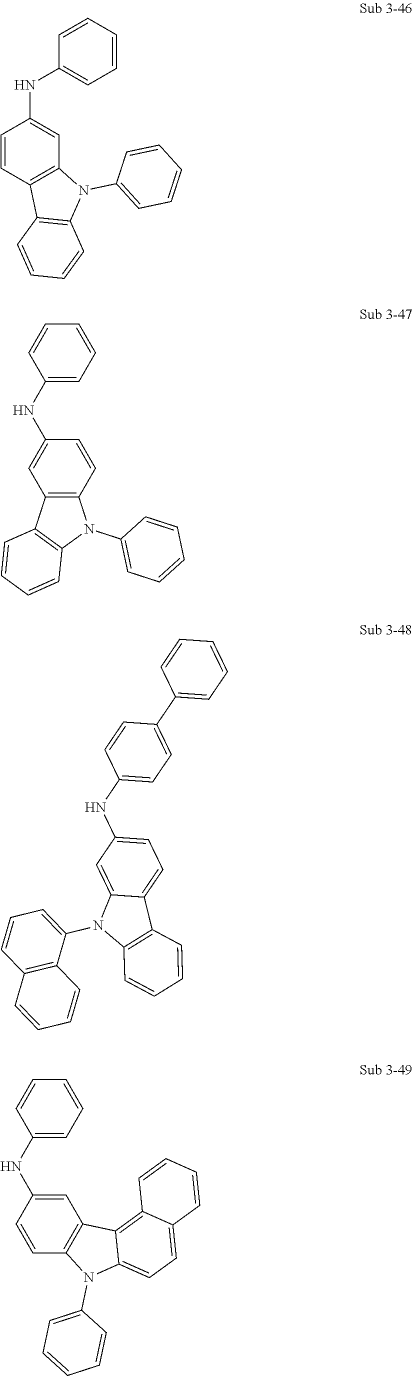 [SMILES: c1ccc(Nc2ccc3c4ccccc4n(-c4ccccc4)c3c2)cc1 ; c1ccc(Nc2ccc3c(c2)c2ccccc2n3-c2ccccc2)cc1 ; c1ccc(-c2ccc(Nc3ccc4c5ccccc5n(-c5cccc6ccccc56)c4c3)cc2)cc1 ; c1ccc(Nc2ccc3c(c2)c2c4ccccc4ccc2n3-c2ccccc2)cc1]

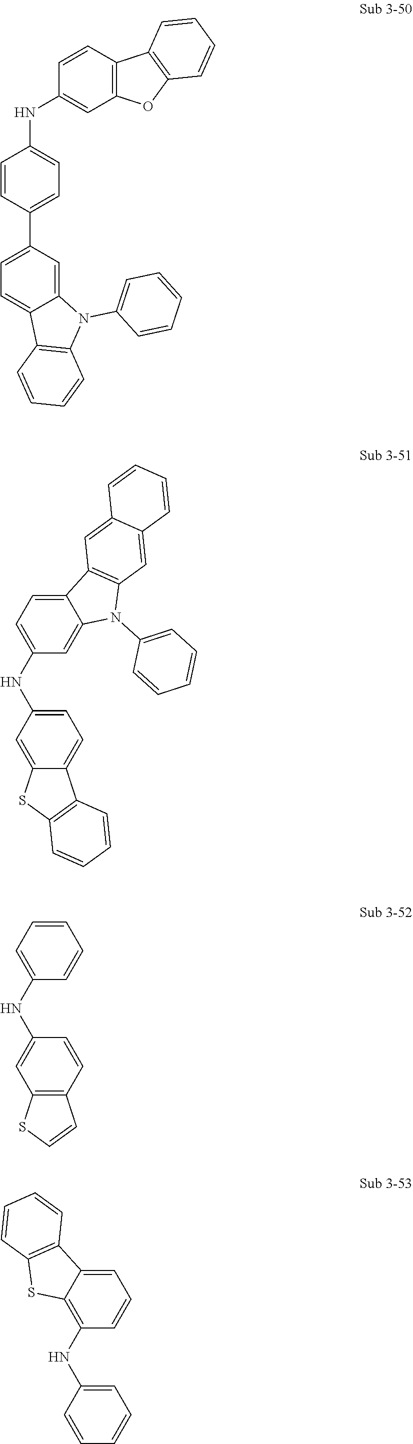 [SMILES: c1ccc(-n2c3ccccc3c3ccc(-c4ccc(Nc5ccc6c(c5)oc5ccccc56)cc4)cc32)cc1 ; c1ccc(-n2c3cc(Nc4ccc5c(c4)sc4ccccc45)ccc3c3cc4ccccc4cc32)cc1 ; c1ccc(Nc2ccc3ccsc3c2)cc1 ; c1ccc(Nc2cccc3c2sc2ccccc23)cc1]

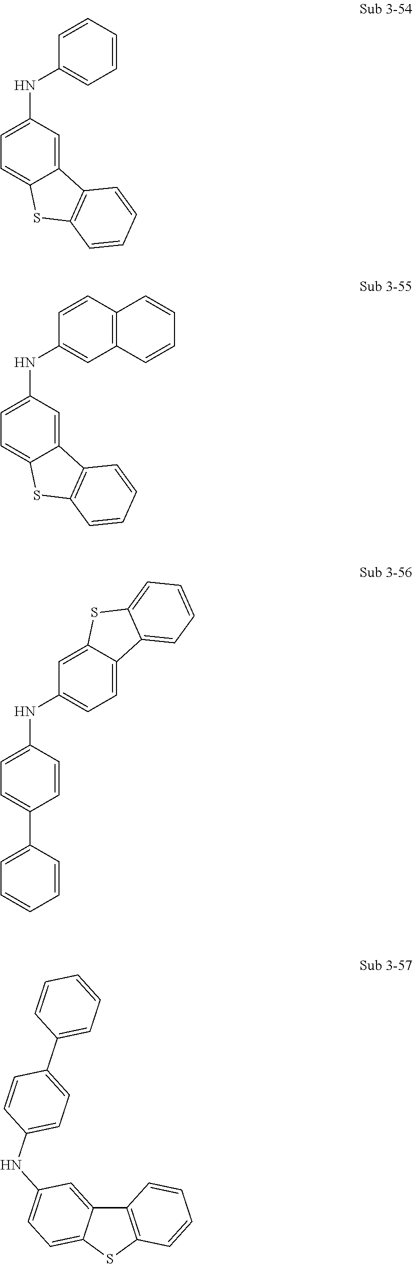 [SMILES: c1ccc(Nc2ccc3sc4ccccc4c3c2)cc1 ; c1ccc2cc(Nc3ccc4sc5ccccc5c4c3)ccc2c1 ; c1ccc(-c2ccc(Nc3ccc4c(c3)sc3ccccc34)cc2)cc1 ; c1ccc(-c2ccc(Nc3ccc4sc5ccccc5c4c3)cc2)cc1]

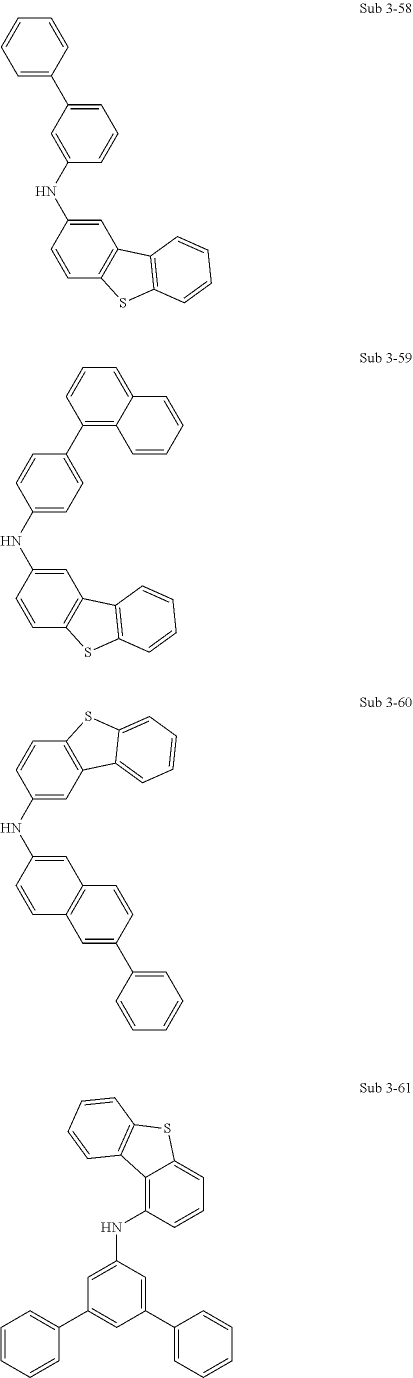 [SMILES: c1ccc(-c2cccc(Nc3ccc4sc5ccccc5c4c3)c2)cc1 ; c1ccc2c(-c3ccc(Nc4ccc5sc6ccccc6c5c4)cc3)cccc2c1 ; c1ccc(-c2ccc3cc(Nc4ccc5sc6ccccc6c5c4)ccc3c2)cc1 ; c1ccc(-c2cc(Nc3cccc4sc5ccccc5c34)cc(-c3ccccc3)c2)cc1]

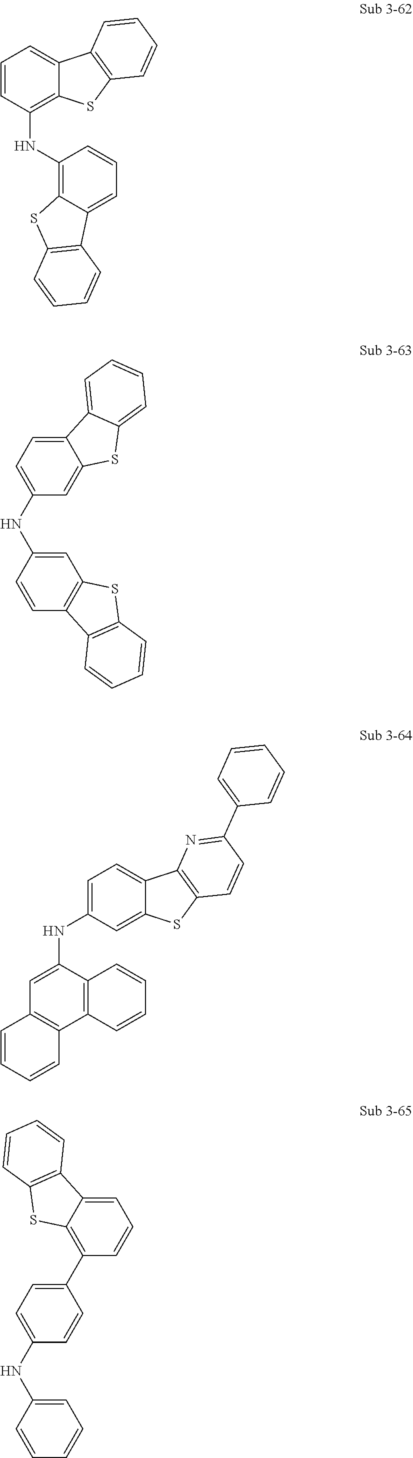

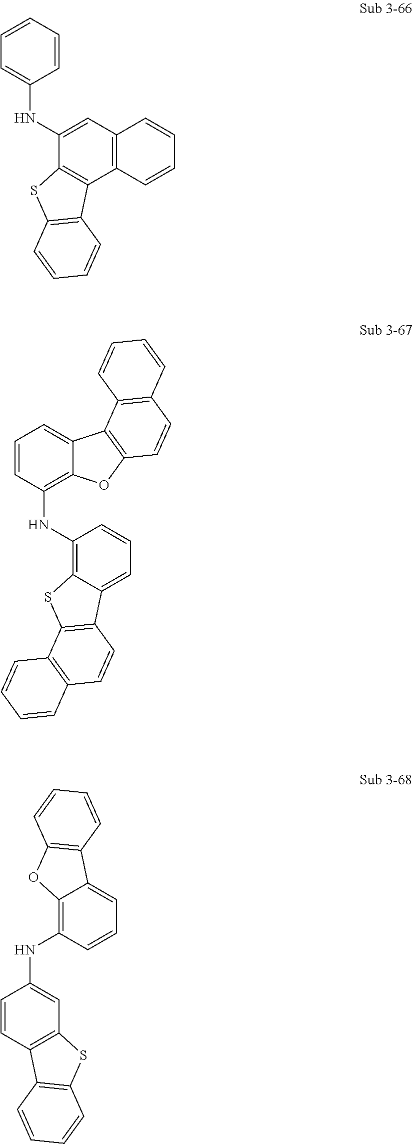 [SMILES: c1ccc(Nc2cc3ccccc3c3c2sc2ccccc23)cc1 ; c1ccc2c(c1)ccc1c3cccc(Nc4cccc5c4oc4ccc6ccccc6c45)c3sc21 ; c1ccc2c(c1)oc1c(Nc3ccc4c(c3)sc3ccccc34)cccc12]

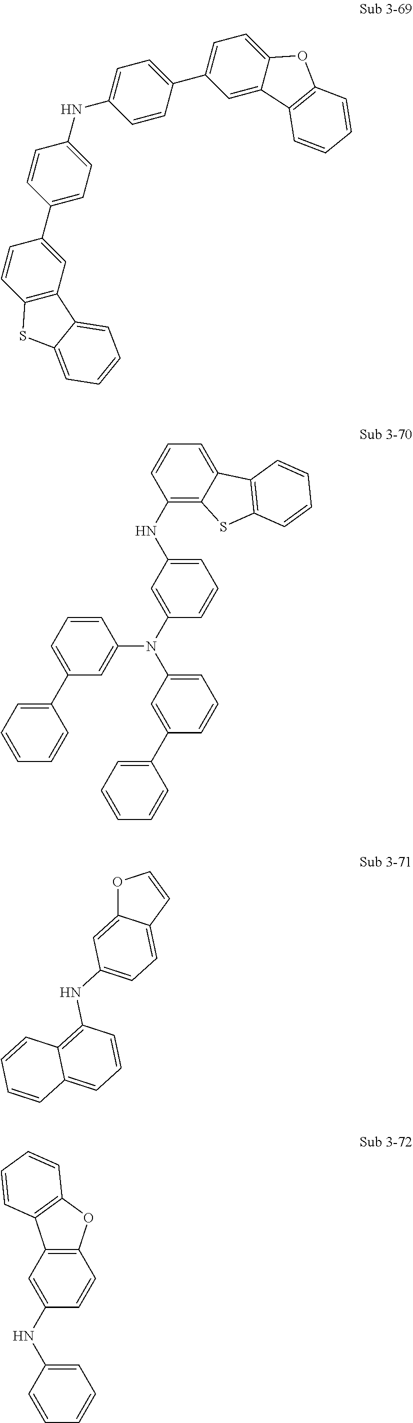 [SMILES: c1ccc2c(c1)oc1ccc(-c3ccc(Nc4ccc(-c5ccc6sc7ccccc7c6c5)cc4)cc3)cc12 ; c1ccc(-c2cccc(N(c3cccc(Nc4cccc5c4sc4ccccc45)c3)c3cccc(-c4ccccc4)c3)c2)cc1 ; c1ccc2c(Nc3ccc4ccoc4c3)cccc2c1 ; c1ccc(Nc2ccc3oc4ccccc4c3c2)cc1]

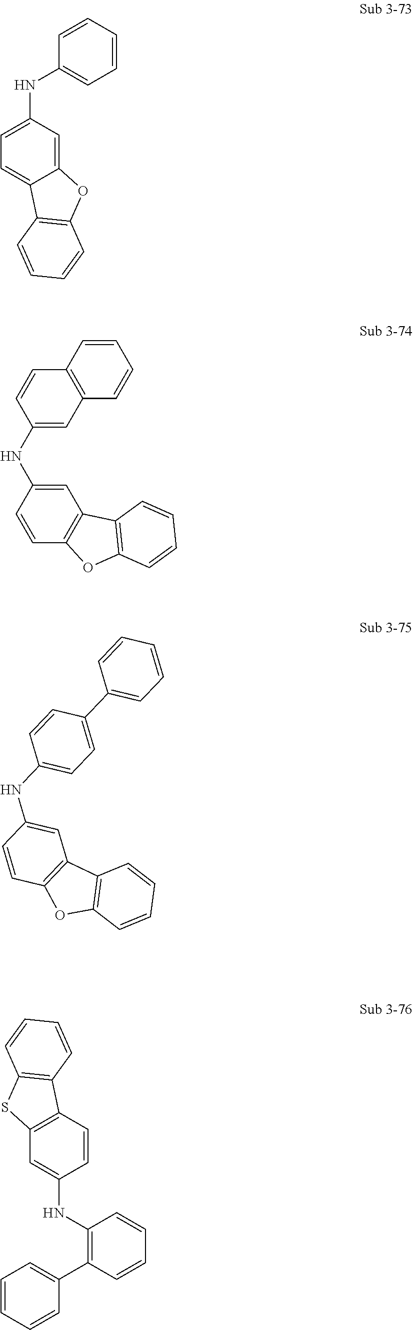 [SMILES: c1ccc(Nc2ccc3c(c2)oc2ccccc23)cc1 ; c1ccc2cc(Nc3ccc4oc5ccccc5c4c3)ccc2c1 ; c1ccc(-c2ccc(Nc3ccc4oc5ccccc5c4c3)cc2)cc1 ; c1ccc(-c2ccccc2Nc2ccc3c(c2)sc2ccccc23)cc1]

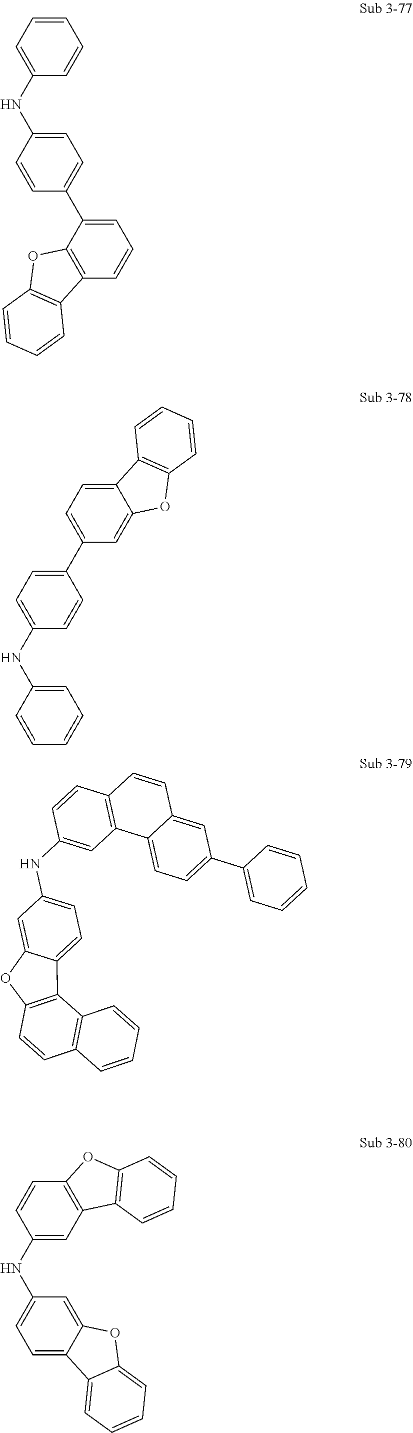

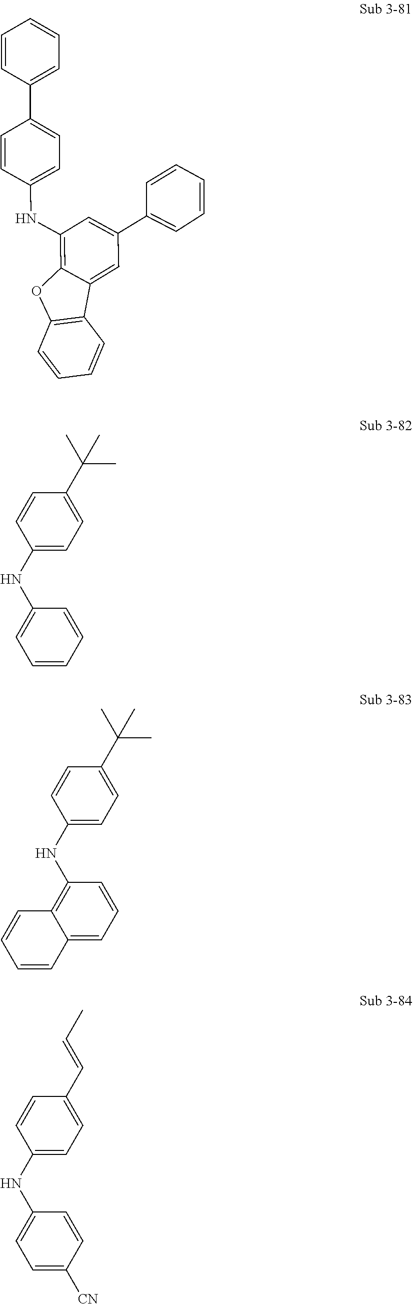 [SMILES: c1ccc(-c2ccc(Nc3cc(-c4ccccc4)cc4c3oc3ccccc34)cc2)cc1 ; CC(C)(C)c1ccc(Nc2ccccc2)cc1 ; CC(C)(C)c1ccc(Nc2cccc3ccccc23)cc1 ; C/C=C/c1ccc(Nc2ccc(C#N)cc2)cc1]

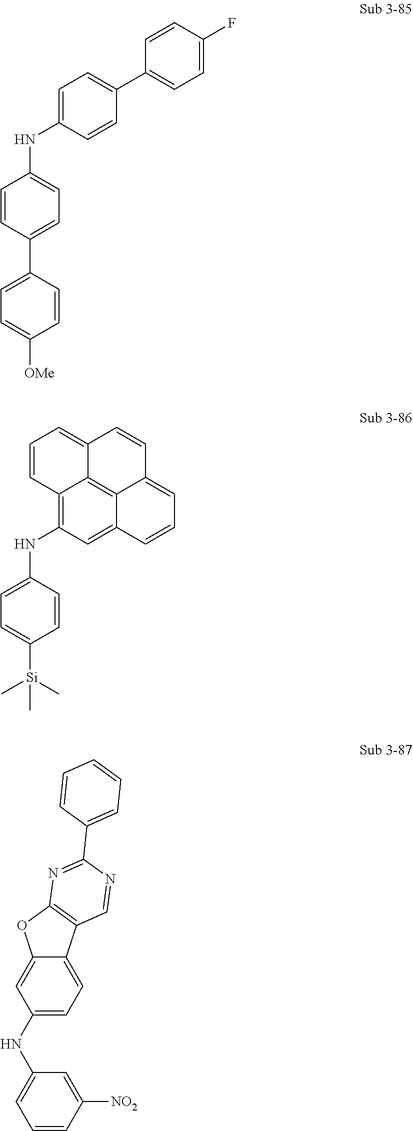 [SMILES: COc1ccc(-c2ccc(Nc3ccc(-c4ccc(F)cc4)cc3)cc2)cc1 ; C[Si](C)(C)c1ccc(Nc2cc3cccc4ccc5cccc2c5c43)cc1 ; O=[N+]([O-])c1cccc(Nc2ccc3c(c2)oc2nc(-c4ccccc4)ncc23)c1]

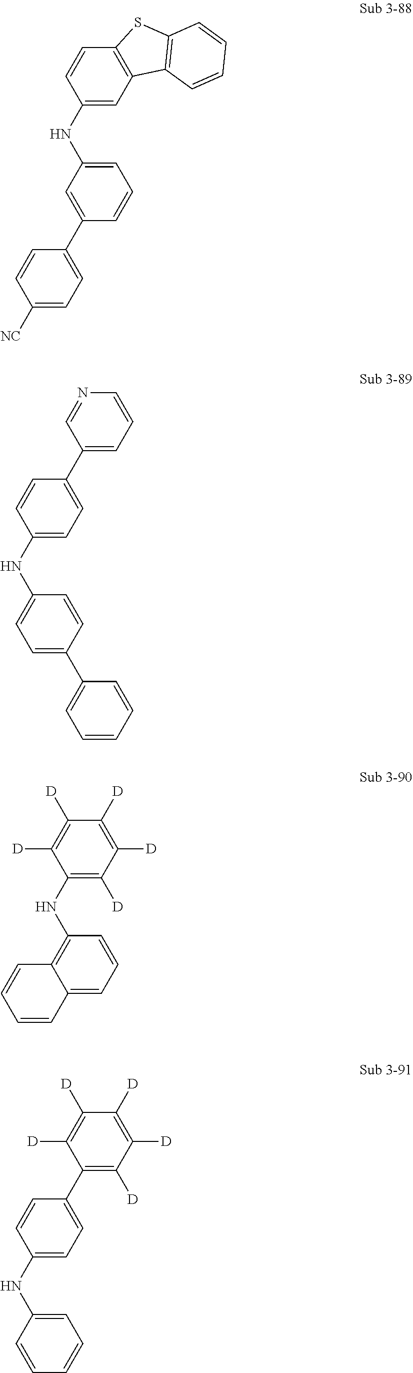 [SMILES: N#Cc1ccc(-c2cccc(Nc3ccc4sc5ccccc5c4c3)c2)cc1 ; c1ccc(-c2ccc(Nc3ccc(-c4cccnc4)cc3)cc2)cc1 ; [2H]c1c([2H])c([2H])c(Nc2cccc3ccccc23)c([2H])c1[2H] ; [2H]c1c([2H])c([2H])c(-c2ccc(Nc3ccccc3)cc2)c([2H])c1[2H]]

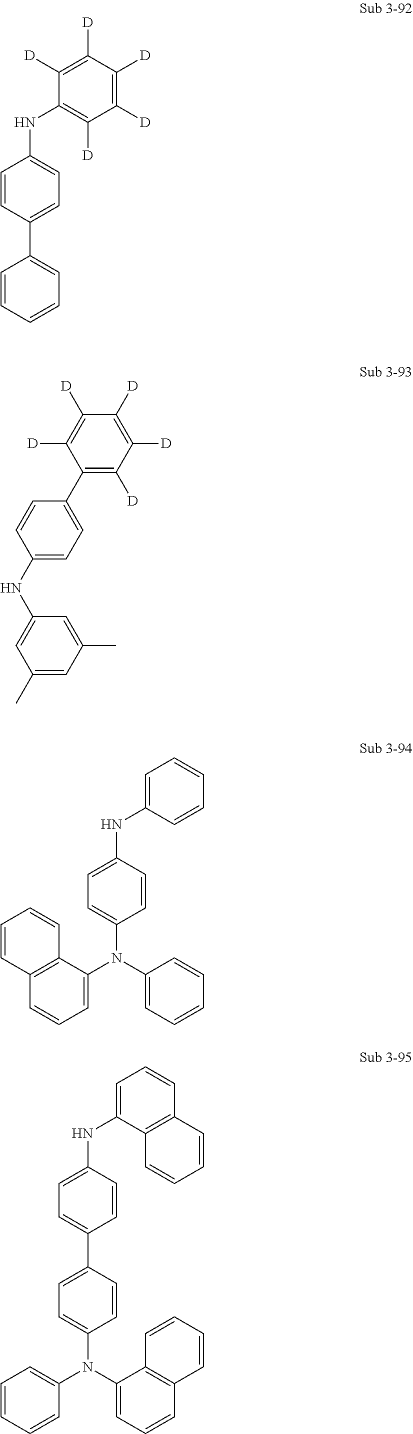 [SMILES: [2H]c1c([2H])c([2H])c(Nc2ccc(-c3ccccc3)cc2)c([2H])c1[2H] ; [2H]c1c([2H])c([2H])c(-c2ccc(Nc3cc(C)cc(C)c3)cc2)c([2H])c1[2H] ; c1ccc(Nc2ccc(N(c3ccccc3)c3cccc4ccccc34)cc2)cc1 ; c1ccc(N(c2ccc(-c3ccc(Nc4cccc5ccccc45)cc3)cc2)c2cccc3ccccc23)cc1]

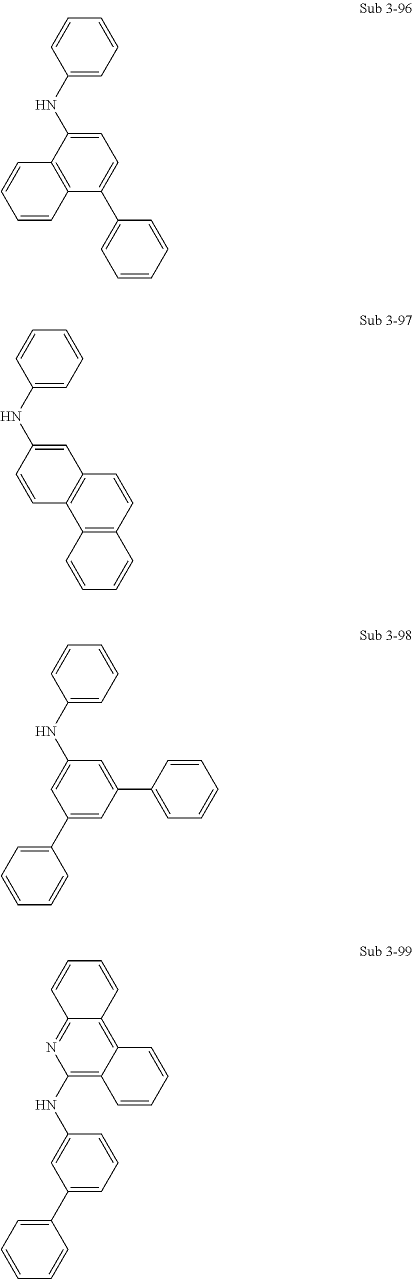 [SMILES: c1ccc(Nc2ccc(-c3ccccc3)c3ccccc23)cc1 ; c1ccc(Nc2ccc3c(ccc4ccccc43)c2)cc1 ; c1ccc(Nc2cc(-c3ccccc3)cc(-c3ccccc3)c2)cc1 ; c1ccc(-c2cccc(Nc3nc4ccccc4c4ccccc34)c2)cc1]

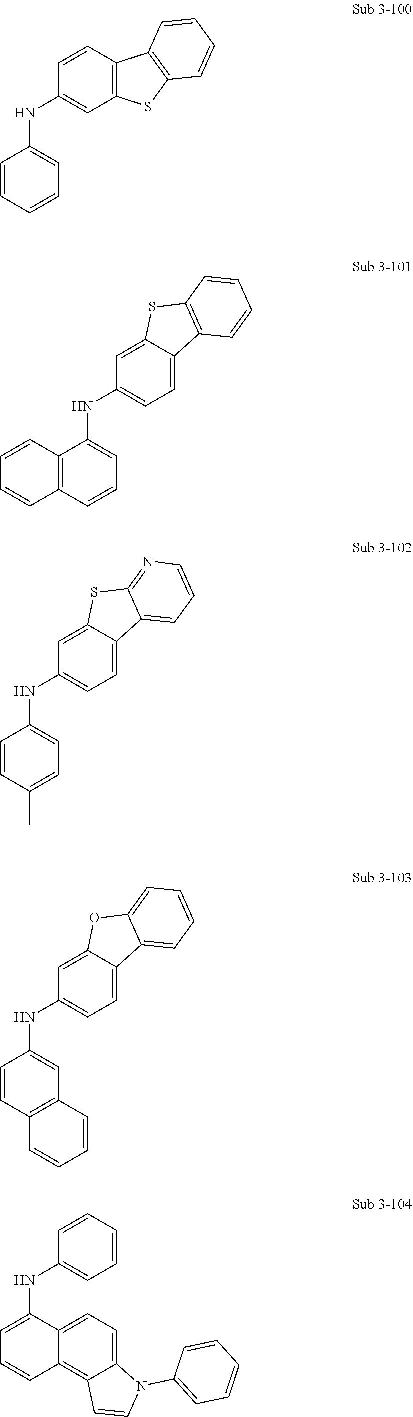 [SMILES: c1ccc(Nc2ccc3c(c2)sc2ccccc23)cc1 ; c1ccc2c(Nc3ccc4c(c3)sc3ccccc34)cccc2c1 ; Cc1ccc(Nc2ccc3c(c2)sc2ncccc23)cc1 ; c1ccc2cc(Nc3ccc4c(c3)oc3ccccc34)ccc2c1 ; c1ccc(Nc2cccc3c2ccc2c3ccn2-c2ccccc2)cc1]

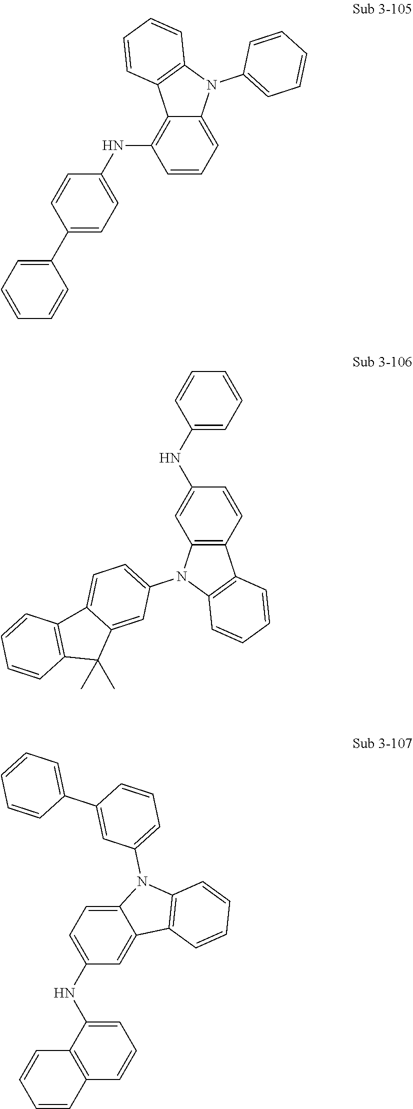 [SMILES: c1ccc(-c2ccc(Nc3cccc4c3c3ccccc3n4-c3ccccc3)cc2)cc1 ; CC1(C)c2ccccc2-c2ccc(-n3c4ccccc4c4ccc(Nc5ccccc5)cc43)cc21 ; c1ccc(-c2cccc(-n3c4ccccc4c4cc(Nc5cccc6ccccc56)ccc43)c2)cc1]

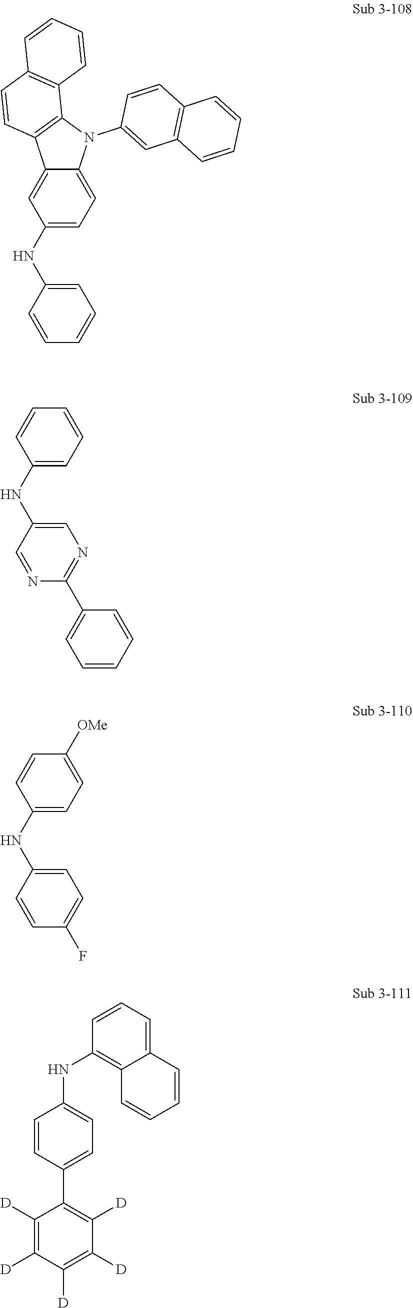 [SMILES: c1ccc(Nc2ccc3c(c2)c2ccc4ccccc4c2n3-c2ccc3ccccc3c2)cc1 ; c1ccc(Nc2cnc(-c3ccccc3)nc2)cc1 ; COc1ccc(Nc2ccc(F)cc2)cc1 ; [2H]c1c([2H])c([2H])c(-c2ccc(Nc3cccc4ccccc34)cc2)c([2H])c1[2H]]

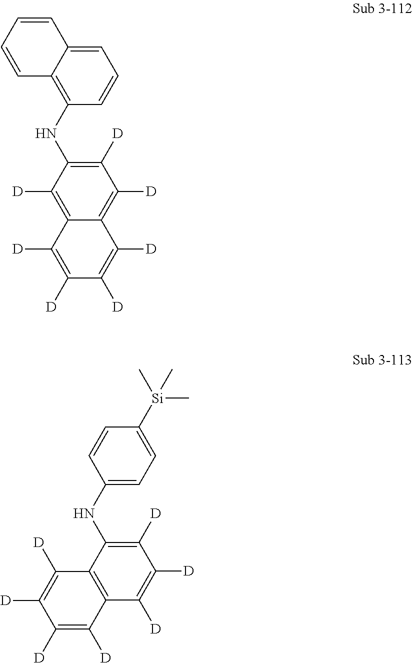 [SMILES: [2H]c1c([2H])c([2H])c2c([2H])c(Nc3cccc4ccccc34)c([2H])c([2H])c2c1[2H] ; [2H]c1c([2H])c([2H])c2c(Nc3ccc([Si](C)(C)C)cc3)c([2H])c([2H])c([2H])c2c1[2H]]

TABLE 4

| Com- | | Com- | |
|---|---|---|---|
| pound | FD-MS | pound | FD-MS |
| Sub 3-1 | m/z = 169.09(C₁₂H₁₁N = 169.22) | Sub 3-2 | m/z = 219.10(C₁₆H₁₃N = 219.28) |
| Sub 3-3 | m/z = 245.12(C₁₈H₁₅N = 245.32) | Sub 3-4 | m/z = 269.12(C₂₀H₁₅N = 269.34) |
| Sub 3-5 | m/z = 245.12(C₁₈H₁₅N = 245.32) | Sub 3-6 | m/z = 245.12(C₁₈H₁₅N = 245.32) |
| Sub 3-7 | m/z = 295.14(C₂₂H₁₇N = 295.38) | Sub 3-8 | m/z = 295.14(C₂₂H₁₇N = 295.38) |
| Sub 3-9 | m/z = 295.14(C₂₂H₁₇N = 295.38) | Sub 3-10 | m/z = 295.14(C₂₂H₁₇N = 295.38) |
| Sub 3-11 | m/z = 321.15(C₂₄H₁₉N = 321.41) | Sub 3-12 | m/z = 321.15(C₂₄H₁₉N = 321.41) |
| Sub 3-13 | m/z = 369.15(C₂₈H₁₉N = 369.47) | Sub 3-14 | m/z = 395.17(C₃₀H₂₁N = 395.51) |
| Sub 3-15 | m/z = 295.14(C₂₂H₁₇N = 295.38) | Sub 3-16 | m/z = 652.25(C₄₈H₃₂N₂O = 652.80) |
| Sub 3-17 | m/z = 371.17(C₂₈H₂₁N = 371.48) | Sub 3-18 | m/z = 371.17(C₂₈H₂₁N = 371.48) |
| Sub 3-19 | m/z = 421.18(C₃₂H₂₃N = 421.54) | Sub 3-20 | m/z = 371.17(C₂₈H₂₁N = 371.48) |
| Sub 3-21 | m/z = 447.20(C₃₄H₂₅N = 447.58) | Sub 3-22 | m/z = 336.16(C₂₄H₂₀N₂ = 336.43) |
| Sub 3-23 | m/z = 503.24(C₃₆H₂₉N₃ = 503.64) | Sub 3-24 | m/z = 285.15(C₂₁H₁₉N = 285.38) |
| Sub 3-25 | m/z = 335.17(C₂₅H₂₁N = 335.44) | Sub 3-26 | m/z = 335.17(C₂₅H₂₁N = 335.44) |
| Sub 3-27 | m/z = 361.18(C₂₇H₂₃N = 361.48) | Sub 3-28 | m/z = 451.23(C₃₄H₂₉N = 451.61) |
| Sub 3-29 | m/z = 401.21(C₃₀H₂₇N = 401.55) | Sub 3-30 | m/z = 477.25(C₃₆H₃₁N = 477.65) |
| Sub 3-31 | m/z = 391.14(C₂₇H₂₁NS = 391.53) | Sub 3-32 | m/z = 391.14(C₂₇H₂₁NS = 391,53) |
| Sub 3-33 | m/z = 375.16(C₂₇H₂₁NO = 375.46) | Sub 3-34 | m/z = 375.16(C₂₇H₂₁NO = 375.46) |
| Sub 3-35 | m/z = 459.20(C₃₅H₂₅N = 459.58) | Sub 3-36 | m/z = 423.20(C₃₂H₂₅N = 423.56) |
| Sub 3-37 | m/z = 586.24(C₄₄H₃₀N₂ = 586.74) | Sub 3-38 | m/z = 485.21(C₃₇H₂₇N = 485.63) |
| Sub 3-39 | m/z = 407.17(C₃₁H₂₁N = 407.52) | Sub 3-40 | m/z = 457.18(C₃₅H₂₃N = 457.58) |
| Sub 3-41 | m/z = 563.17(C₄₁H₂₅NS = 563.72) | Sub 3-42 | m/z = 626.27(C₄₇H₃₄N₂ = 626.80) |
| Sub 3-43 | m/z = 284.13(C₂₀H₁₆N₂ = 284.36) | Sub 3-44 | m/z = 246.12(C₁₇H₁₄N₂ = 246.31) |
| Sub 3-45 | m/z = 296.13(C₂₁H₁₆N₂ = 296.37) | Sub 3-46 | m/z = 334.15(C₂₄H₁₃N₂ = 334.42) |
| Sub 3-47 | m/z = 334.15(C₂₄H₁₈N₂ = 334.42) | Sub 3-48 | m/z = 460.19(C₃₄H₂₄N₂ = 460.58) |
| Sub 3-49 | m/z = 384.16(C₂₈H₂₀N₂ = 384.48) | Sub 3-50 | m/z = 500.19(C₃₆H₂₄N₂O = 500.60) |
| Sub 3-51 | m/z = 490.15(C₃₄H₂₂N₂S = 490,62) | Sub 3-52 | m/z = 225.06(C₁₄H₁₁NS = 225.31) |
| Sub 3-53 | m/z = 275.08(C₁₃H₁₃NS = 275.37) | Sub 3-54 | m/z = 275.08(C₁₈H₁₃NS = 275.37) |
| Sub 3-55 | m/z = 325.09(C₂₂H₁₅NS = 325.43) | Sub 3-56 | m/z = 351.11(C₂₄H₁₇NS = 351.47) |
| Sub 3-57 | m/z = 351.11(C₂₄H₁₇NS = 351.47) | Sub 3-58 | m/z = 351.11(C₂₄H₁₇NS = 351.47) |
| Sub 3-59 | m/z = 401.12(C₂₈H₁₉NS = 401.53) | Sub 3-60 | m/z = 401.12(C₂₈H₁₉NS = 401,53) |
| Sub 3-61 | m/z = 427.14(C₃₀H₂₁NS = 427.57) | Sub 3-62 | m/z = 381.06(C₂₄H₁₅NS₂ = 381.51) |
| Sub 3-63 | m/z = 381.06(C₂₄H₁₅NS₂ = 381.51) | Sub 3-64 | m/z = 452.13(C₃₁H₂₀N₂S = 452.58) |
| Sub 3-65 | m/z = 351.11(C₂₄H₁₇NS = 351.47) | Sub 3-66 | m/z = 325.09(C₂₂H₁₅NS = 325.43) |
| Sub 3-67 | m/z = 465.12(C₃₂H₁₉NOS = | Sub 3-68 | m/z = 365.09(C₂₄H₁₅NOS = |
| | 465.57) | | 365.45) |
| Sub 3-69 | m/z = 517.15(C₃₇H₂₃NOS = | Sub 3-70 | m/z = 594.21(C₄₂H₃₀N₂S = |
| | 517.65) | | 594.78) |
| Sub 3-71 | m/z = 259.10(C₁₈H₁₃NO = 259.31) | Sub 3-72 | m/z = 259.10(C₁₈H₁₃NO = 259.31) |
| Sub 3-73 | m/z = 259.10(C₁₈H₁₃NO = 259.31) | Sub 3-74 | m/z = 309.12(C₂₂H₁₅NO = 309.36) |
| Sub 3-75 | m/z = 335.13(C₂₄H₁₇NO = 335.40) | Sub 3-76 | m/z = 335.13(C₂₄H₁₇NO = 335.40) |
| Sub 3-77 | m/z = 335.13(C₂₄H₁₇NO = 335.40) | Sub 3-78 | m/z = 335.13(C₂₄H₁₇NO = 335.40) |
| Sub 3-79 | m/z = 485.18(C₃₆H₂₃NO = 485.59) | Sub 3-80 | m/z = 349.11(C₂₄H₁₅NO₂ = 349.39) |
| Sub 3-81 | m/z = 411.16(C₃₀H₂₁NO = 411.49) | Sub 3-82 | m/z = 225.15(C₁₆H₁₉N = 225.34) |
| Sub 3-83 | m/z = 275.17(C₂₀H₂₁N = 275.40) | Sub 3-84 | m/z = 234.12(C₁₆H₁₄N₂ = 234.30) |
| Sub 3-85 | m/z = 369.15(C₂₅H₂₀FNO = | Sub 3-86 | m/z = 365.16(C₂₅H₂₃NSi = |
| | 369.44) | | 365.55) |
| Sub 3-87 | m/z = 382.38(C₂₂H₁₄NO₃ = 382.38) | Sub 3-88 | m/z = 376.10(C₂₅H₁₆N₂S = 376.48) |
| Sub 3-89 | m/z = 322.15(C₂₃H₁₈N₂ = 322.41) | Sub 3-90 | m/z = 224.14(C₁₆H₈D₅N = 224.32) |
| Sub 3-91 | m/z = 250.15(C₁₈H₁₀D₅N = 250.36) | Sub 3-92 | m/z = 250.15(C₁₈H₁₀D₅N = 250.36) |
| Sub 3-93 | m/z = 278.18(C₂₀H₁₄D₅N = 278.41) | Sub 3-94 | m/z = 386.18(C₂₈H₂₂N₂ = 386.50) |
| Sub 3-95 | m/z = 512.23(C₃₈H₂₈N₂ = 512.66) | Sub 3-96 | m/z = 295.14(C₂₂H₁₇N = 295.39) |
| Sub 3-97 | m/z = 269.12(C₂₀H₁₅N = 269.35) | Sub 3-98 | m/z = 321.15(C₂₄H₁₉N = 321.42) |
| Sub 3-99 | m/z = 346.15(C₂₅H₁₈N = 346.43) | Sub 3-100 | m/z = 275.08(C₁₈H₁₃NS = 275.37) |
| Sub 3-101 | m/z = 325.09(C₂₂H₁₅NS = 325.43) | Sub 3-102 | m/z = 290.09(C₁₈H₁N₂S = 290.38) |
| Sub 3-103 | m/z = 309.12(C₂₂H₁₅NO = 309.37) | Sub 3-104 | m/z = 334.15(C₂₄H₁₈N₂ = 334.42) |
| Sub 3-105 | m/z = 410.18(C₃₀H₂₂N₂ = 410.52) | Sub 3-106 | m/z = 450.21(C₃₃H₂₆N₂ = 450.59) |
| Sub 3-107 | m/z = 460.19(C₃₄H₂₄N₂ = 460.58) | Sub 3-108 | m/z = 434.18(C₃₂H₂₂N₂ = 434.54) |
| Sub 3-109 | m/z = 247.11(C₁₆H₁₃N₃ = | Sub 3-110 | m/z = 217.09(C₁₃H₁₂FNO = |
| | 247.30) | | 217.24) |
| Sub 3-111 | m/z = 300.17(C₂₂H₁₂D₅N = 300,42) | Sub 3-112 | m/z = 276.16(C₂₀H₈D₇N = 276.39) |
| Sub 3-113 | m/z = 298.19(C₁₉H₁₄DNSi = | | |
| | 298.51) | | |

### Synthesis Example of Sub 4

Sub 4 of Reaction Scheme 4 may be synthesized by the reaction route of the following Reaction Scheme 6, but are not limited thereto. The following Sub 4′ may be the same as Sub 1 or Sub 3 of Reaction Scheme 1.

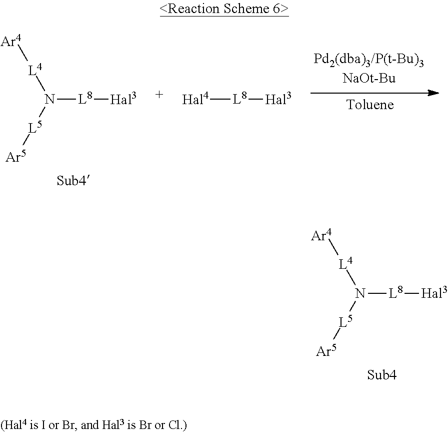

### 1. Synthesis Example of Sub 4-1

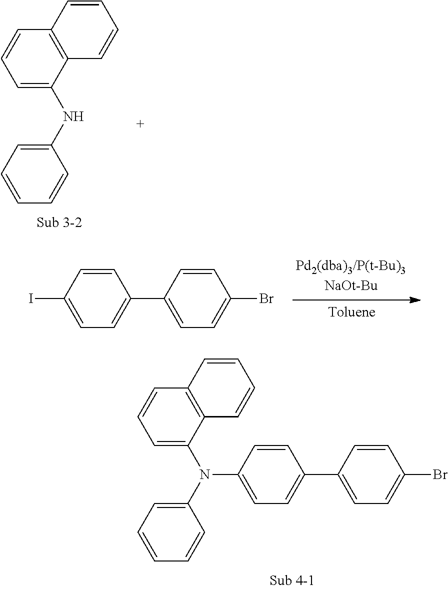

After Sub 3-2 (20.16 g, 91.92 mmol) was dissolved in toluene (965 mL) and 4-bromo-4′-iodo-1,1′-biphenyl (33 g, 91.92 mmol), Pd₂(dba)₃ (1.26 g, 1.38 mmol), P(t-Bu)₃ (0.56 g, 2.76 mmol) and NaOt-Bu (13.25 g, 137.88 mmol) were added to the solution, the mixture was stirred at 70° C. When the reaction was completed, the reaction product was extracted with CH₂Cl₂ and water. Then, an organic layer was dried over MgSO₄ and concentrated. Then, the concentrate was separated by a silica gel column and recrystallized to obtain 28.15 g (yield: 68%) of the product.

### 2. Synthesis Example of Sub 4-14

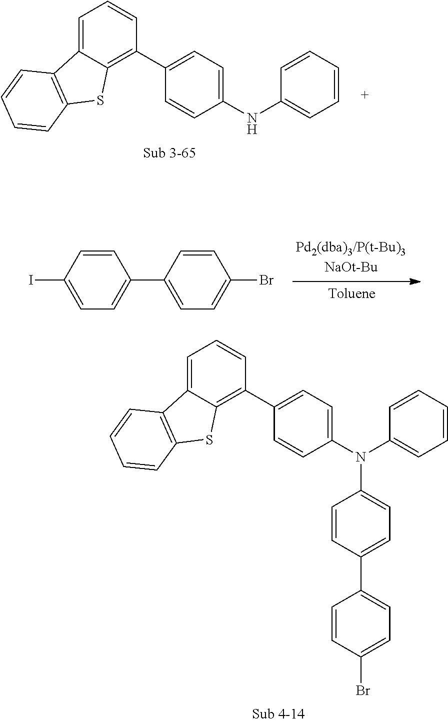

After dissolving Sub 3-65 (24.48 g, 69.64 mmol) in toluene (731 ml), 2-bromo-6-iodonaphthalene (25 g, 69.64 mmol), Pd₂(dba)₃ (0.96 g, 1.04 mmol), P(t-Bu)₃ (0.42 g, 2.09 mmol) and NaOt-Bu (10.04 g, 104.46 mmol) were added to the solution, and then the reaction was carried out in the same manner as in the synthesis method of Sub 4-1 to obtain 27.18 g (yield: 67%) of the product.

### 3. Synthesis Example of Sub 4-30

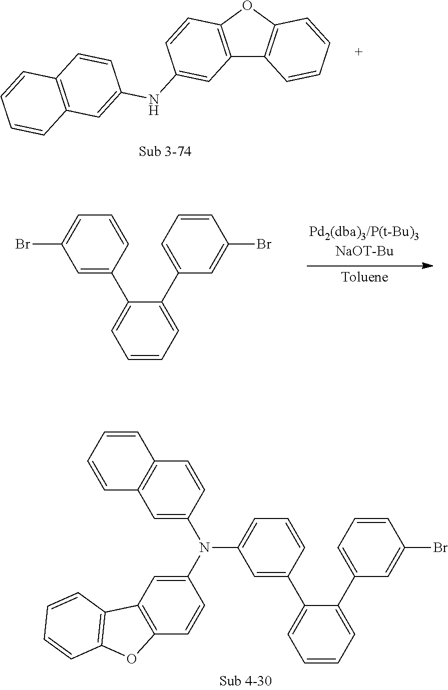 [SMILES: c1ccc2cc(Nc3ccc4oc5ccccc5c4c3)ccc2c1 ; Brc1cccc(-c2ccccc2-c2cccc(Br)c2)c1 ; Brc1cccc(-c2ccccc2-c2cccc(N(c3ccc4ccccc4c3)c3ccc4oc5ccccc5c4c3)c2)c1]

After dissolving Sub 3-74 (20.73 g, 66.99 mmol) in toluene (703 ml), 3,3″-dibromo-1,1′:2′,1″-terphenyl (26 g, 66.99 mmol), Pd₂(dba)₃ (0.92 g, 1 mmol), P(t-Bu)₃ (0.41 g, 2.01 mmol) and NaOt-Bu (9.66 g, 100.49 mmol) were added to the solution, and then the reaction was carried out in the same manner as in the synthesis method of Sub 4-1 to obtain 24.78 g (yield: 60%) of the product.

### 4. Synthesis Example of Sub 4-36

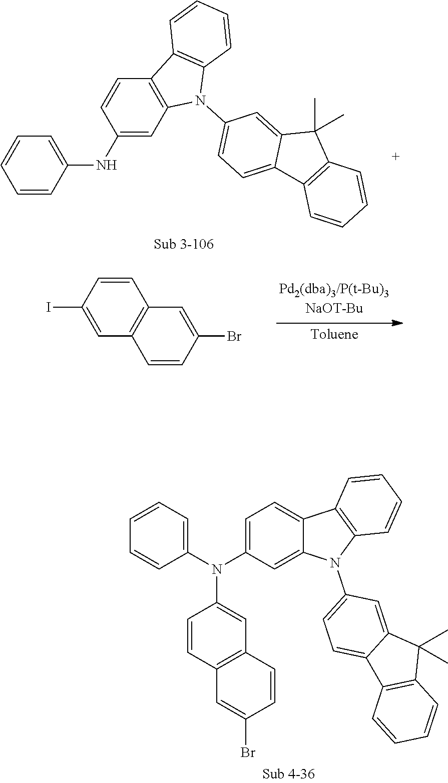 [SMILES: CC1(C)c2ccccc2-c2ccc(-n3c4ccccc4c4ccc(Nc5ccccc5)cc43)cc21 ; Brc1ccc2cc(I)ccc2c1 ; CC1(C)c2ccccc2-c2ccc(-n3c4ccccc4c4ccc(N(c5ccccc5)c5ccc6cc(Br)ccc6c5)cc43)cc21]

After dissolving Sub 3-106 (31.12 g, 69.08 mmol) in toluene (725 ml), 2-bromo-6-iodonaphthalene (23 g, 69.08 mmol), Pd₂(dba)₃ (0.95 g, 1.04 mmol), P(t-Bu)₃ (0.42 g, 2.07 mmol) and NaOt-Bu (9.96 g, 103.61 mmol) were added to the solution, and then the reaction was carried out in the same manner as in the synthesis method of Sub 4-1 to obtain 28.98 g (yield: 64%) of the product.

### 5. Synthesis Example of Sub 4-44

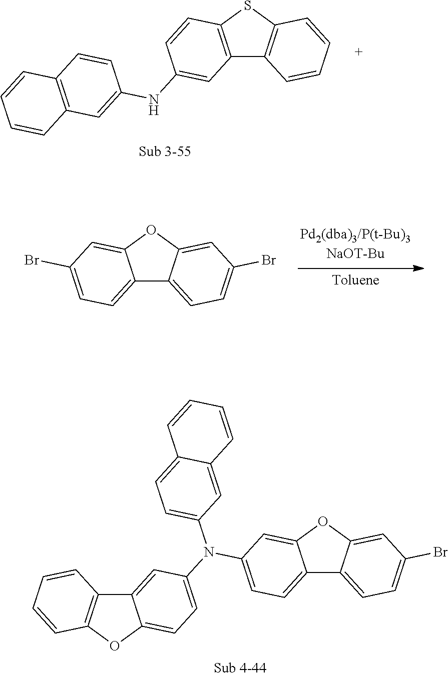 [SMILES: c1ccc2cc(Nc3ccc4sc5ccccc5c4c3)ccc2c1 ; Brc1ccc2c(c1)oc1cc(Br)ccc12 ; Brc1ccc2c(c1)oc1cc(N(c3ccc4ccccc4c3)c3ccc4oc5ccccc5c4c3)ccc12]

After dissolving Sub 3-55 (25.96 g, 79.76 mmol) in toluene (837 ml), 3,7-dibromodibenzo[b,d]furan (26 g, 79.76 mmol), Pd₂(dba)₃ (1.10 g, 1.20 mmol), P(t-Bu)₃ (0.48 g, 2.39 mmol) and NaOt-Bu (11.5 g, 119.64 mmol) were added to the solution, and then the reaction was carried out in the same manner as in the synthesis method of Sub 4-1 to obtain 30.94 g (yield: 68%) of the product.

### 6. Synthesis Example of Sub 4-56

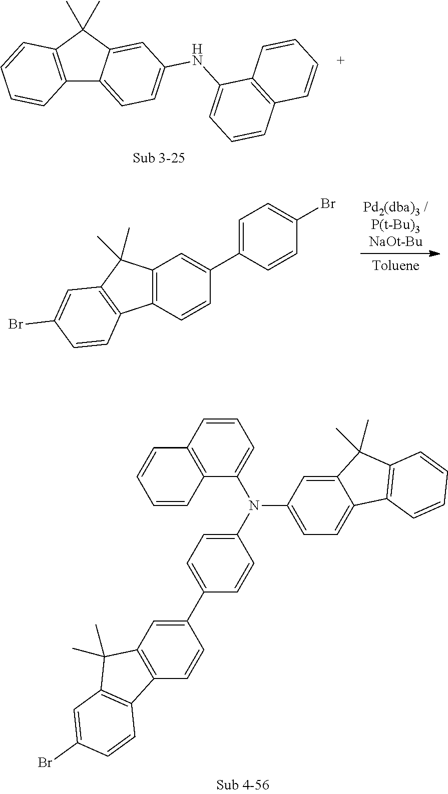 [SMILES: CC1(C)c2ccccc2-c2ccc(Nc3cccc4ccccc34)cc21 ; CC1(C)c2cc(Br)ccc2-c2ccc(-c3ccc(Br)cc3)cc21 ; CC1(C)c2cc(Br)ccc2-c2ccc(-c3ccc(N(c4ccc5c(c4)C(C)(C)c4ccccc4-5)c4cccc5ccccc45)cc3)cc21]

After dissolving Sub 3-25 (20.37 g, 60.72 mmol) in toluene (638 ml), 2-bromo-7-(4-bromophenyl)-9,9-dimethyl-9H-fluorene (26 g, 60.72 mmol), Pd₂(dba)₃ (0.83 g, 0.91 mmol), P(t-Bu)₃ (0.37 g, 1.82 mmol) and NaOt-Bu (8.75 g, 91.09 mmol) were added to the solution, and then the reaction was carried out in the same manner as in the synthesis method of Sub 4-1 to obtain 25.70 g (yield: 62%) of the product.

### 7. Synthesis Example of Sub 4-82

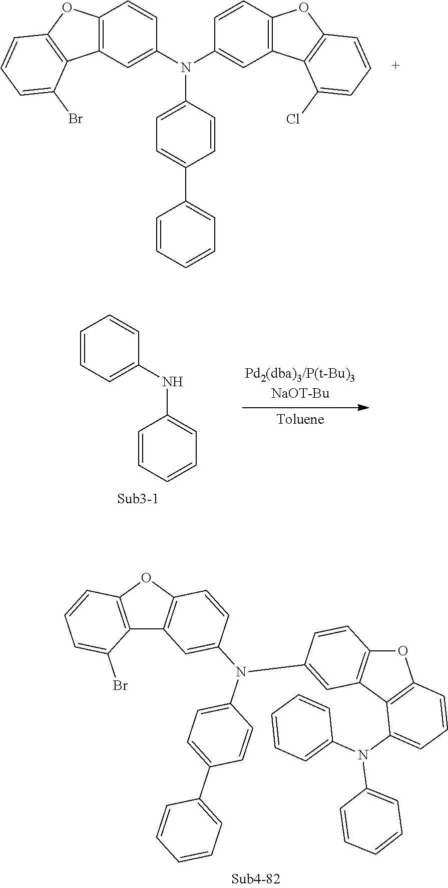 [SMILES: Clc1cccc2oc3ccc(N(c4ccc(-c5ccccc5)cc4)c4ccc5oc6cccc(Br)c6c5c4)cc3c12 ; c1ccc(Nc2ccccc2)cc1 ; Brc1cccc2oc3ccc(N(c4ccc(-c5ccccc5)cc4)c4ccc5oc6cccc(N(c7ccccc7)c7ccccc7)c6c5c4)cc3c12]

After dissolving N-([1,1′-biphenyl]-4-yl)-9-bromo-N-(9-chlorodibenzo[b,d]furan-2-yl)dibenzo[b,d]furan-2-amine (33 g, 53.7 mmol) in toluene (550 ml), Sub3-1 (9.5 g, 56.4 mmol), Pd₂(dba)₃ (1.5 g, 1.6 mmol), P(t-Bu)₃ (0.7 g, 3.2 mmol) and NaOt-Bu (15.5 g, 161 mmol) were added to the solution, and then the reaction was carried out in the same manner as in the synthesis method of Sub 4-1 to obtain 33 g (yield: 82.4%) of the product.

Compounds belonging to Sub 4 are as follows, but are not limited thereto, and FD-MS values of the compounds are shown in Table 5 below.

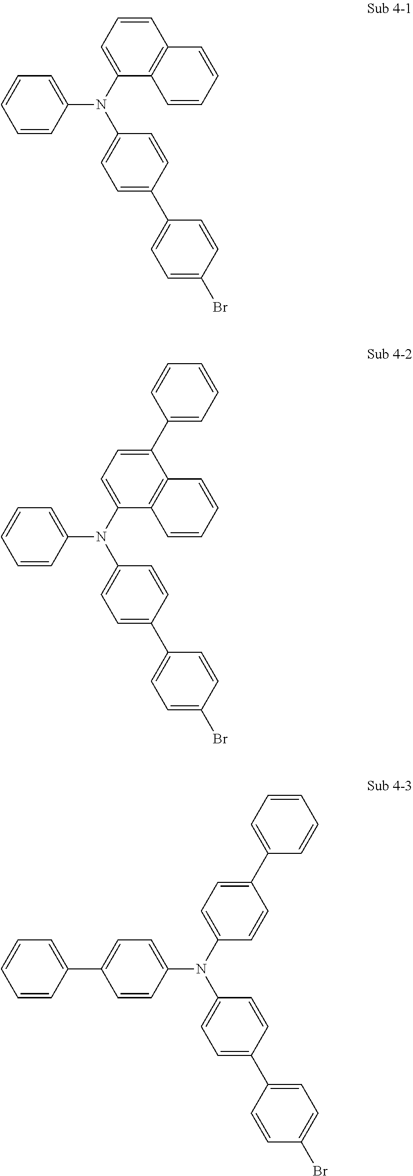 [SMILES: Brc1ccc(-c2ccc(N(c3ccccc3)c3cccc4ccccc34)cc2)cc1 ; Brc1ccc(-c2ccc(N(c3ccccc3)c3ccc(-c4ccccc4)c4ccccc34)cc2)cc1 ; Brc1ccc(-c2ccc(N(c3ccc(-c4ccccc4)cc3)c3ccc(-c4ccccc4)cc3)cc2)cc1]

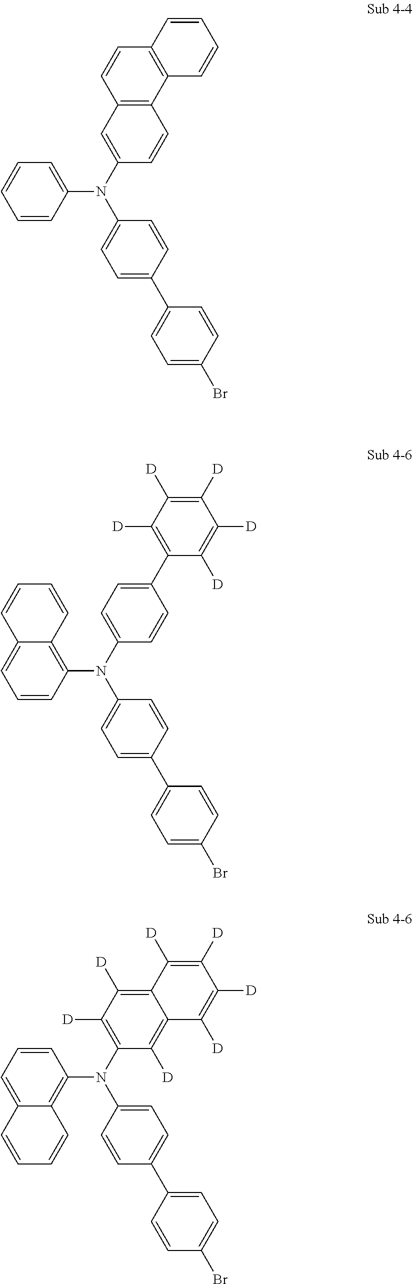 [SMILES: Brc1ccc(-c2ccc(N(c3ccccc3)c3ccc4c(ccc5ccccc54)c3)cc2)cc1 ; [2H]c1c([2H])c([2H])c(-c2ccc(N(c3ccc(-c4ccc(Br)cc4)cc3)c3cccc4ccccc34)cc2)c([2H])c1[2H] ; [2H]c1c([2H])c([2H])c2c([2H])c(N(c3ccc(-c4ccc(Br)cc4)cc3)c3cccc4ccccc34)c([2H])c([2H])c2c1[2H]]

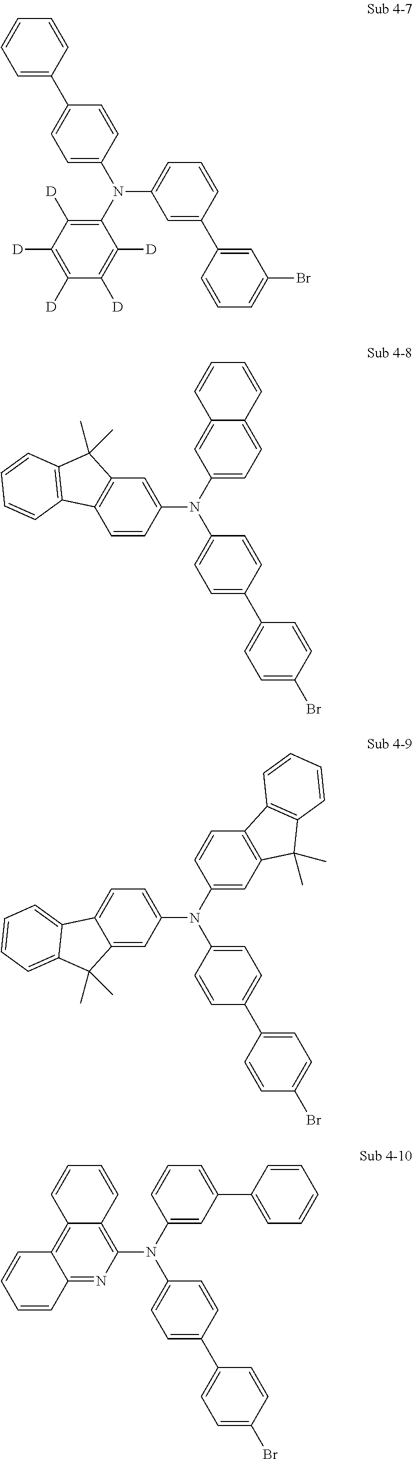 [SMILES: [2H]c1c([2H])c([2H])c(N(c2ccc(-c3ccccc3)cc2)c2cccc(-c3cccc(Br)c3)c2)c([2H])c1[2H] ; CC1(C)c2ccccc2-c2ccc(N(c3ccc(-c4ccc(Br)cc4)cc3)c3ccc4ccccc4c3)cc21 ; CC1(C)c2ccccc2-c2ccc(N(c3ccc(-c4ccc(Br)cc4)cc3)c3ccc4c(c3)C(C)(C)c3ccccc3-4)cc21 ; Brc1ccc(-c2ccc(N(c3cccc(-c4ccccc4)c3)c3nc4ccccc4c4ccccc34)cc2)cc1]

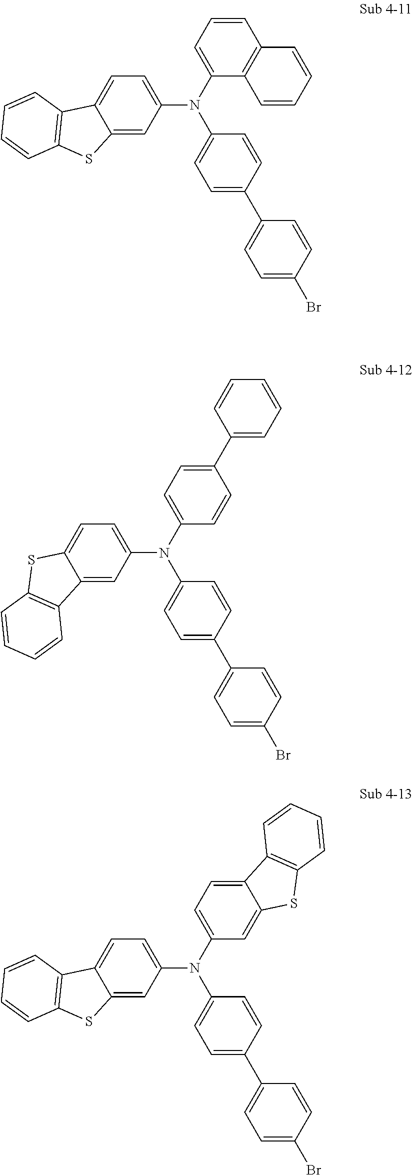 [SMILES: Brc1ccc(-c2ccc(N(c3ccc4c(c3)sc3ccccc34)c3cccc4ccccc34)cc2)cc1 ; Brc1ccc(-c2ccc(N(c3ccc(-c4ccccc4)cc3)c3ccc4sc5ccccc5c4c3)cc2)cc1 ; Brc1ccc(-c2ccc(N(c3ccc4c(c3)sc3ccccc34)c3ccc4c(c3)sc3ccccc34)cc2)cc1]

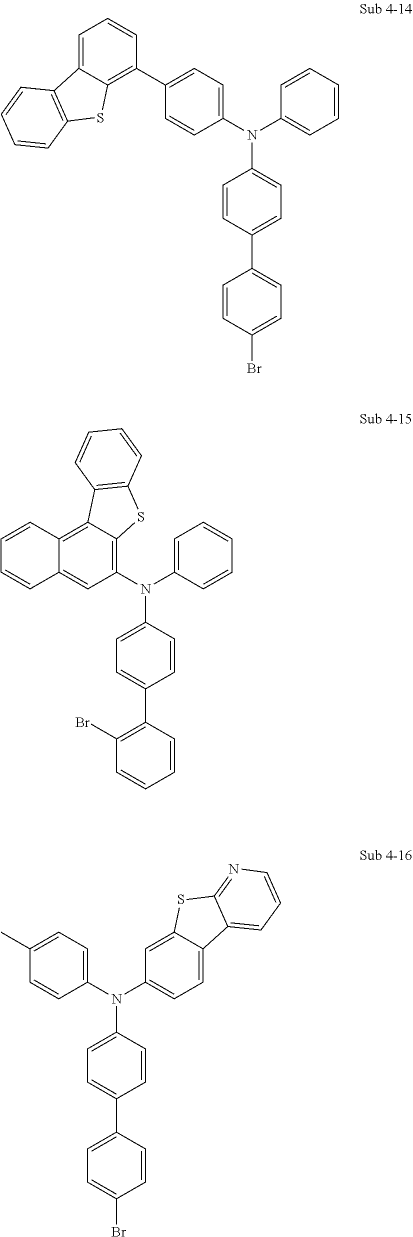 [SMILES: Brc1ccc(-c2ccc(N(c3ccccc3)c3ccc(-c4cccc5c4sc4ccccc45)cc3)cc2)cc1 ; Brc1ccccc1-c1ccc(N(c2ccccc2)c2cc3ccccc3c3c2sc2ccccc23)cc1 ; Cc1ccc(N(c2ccc(-c3ccc(Br)cc3)cc2)c2ccc3c(c2)sc2ncccc23)cc1]

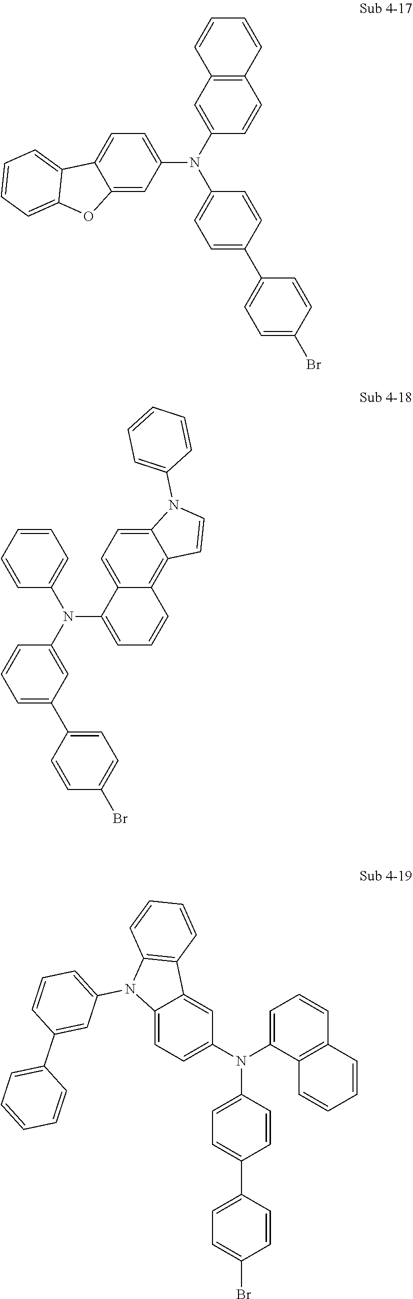 [SMILES: Brc1ccc(-c2ccc(N(c3ccc4ccccc4c3)c3ccc4c(c3)oc3ccccc34)cc2)cc1 ; Brc1ccc(-c2cccc(N(c3ccccc3)c3cccc4c3ccc3c4ccn3-c3ccccc3)c2)cc1 ; Brc1ccc(-c2ccc(N(c3ccc4c(c3)c3ccccc3n4-c3cccc(-c4ccccc4)c3)c3cccc4ccccc34)cc2)cc1]

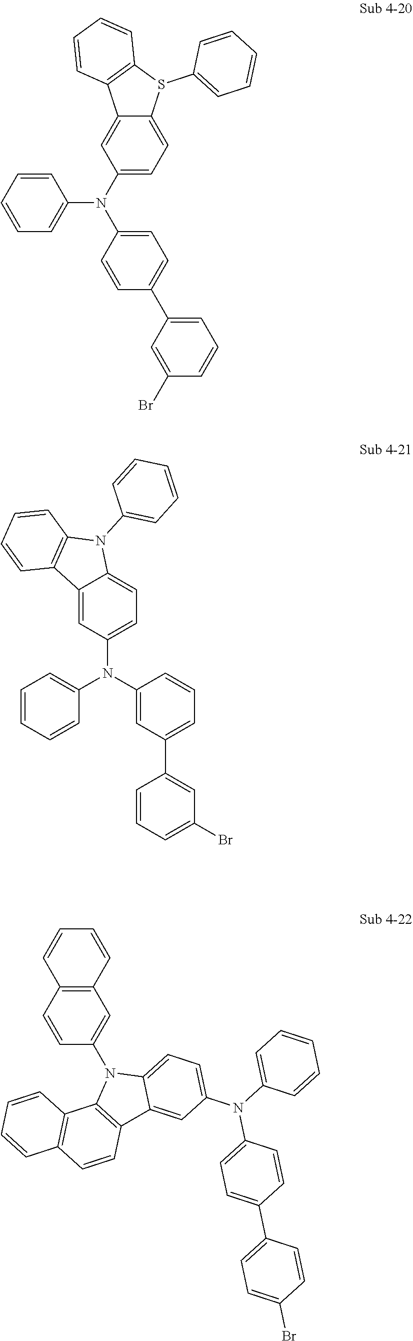

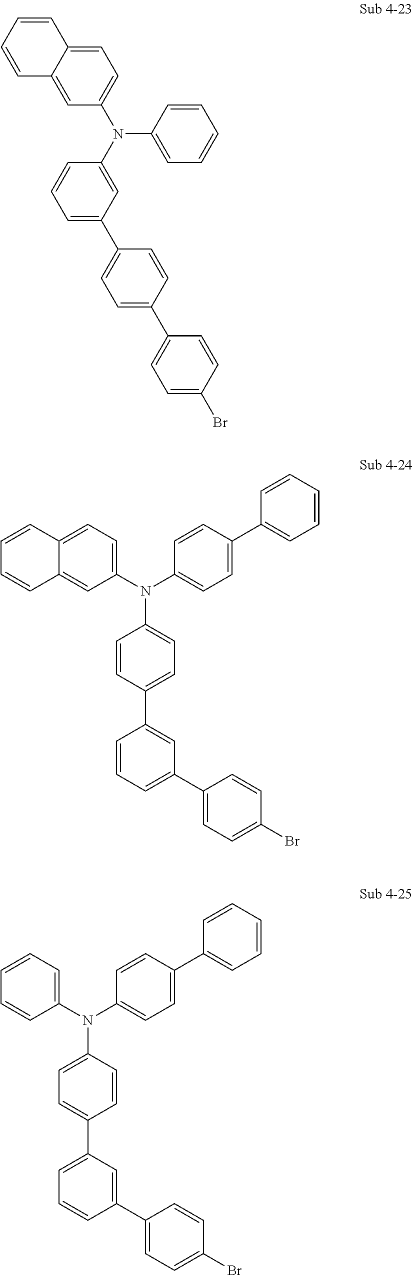 [SMILES: Brc1ccc(-c2ccc(-c3cccc(N(c4ccccc4)c4ccc5ccccc5c4)c3)cc2)cc1 ; Brc1ccc(-c2cccc(-c3ccc(N(c4ccc(-c5ccccc5)cc4)c4ccc5ccccc5c4)cc3)c2)cc1 ; Brc1ccc(-c2cccc(-c3ccc(N(c4ccccc4)c4ccc(-c5ccccc5)cc4)cc3)c2)cc1]

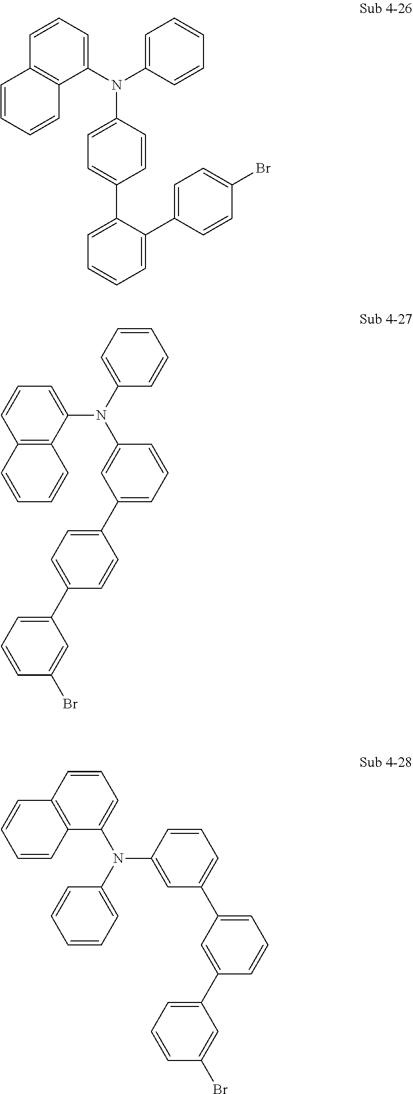

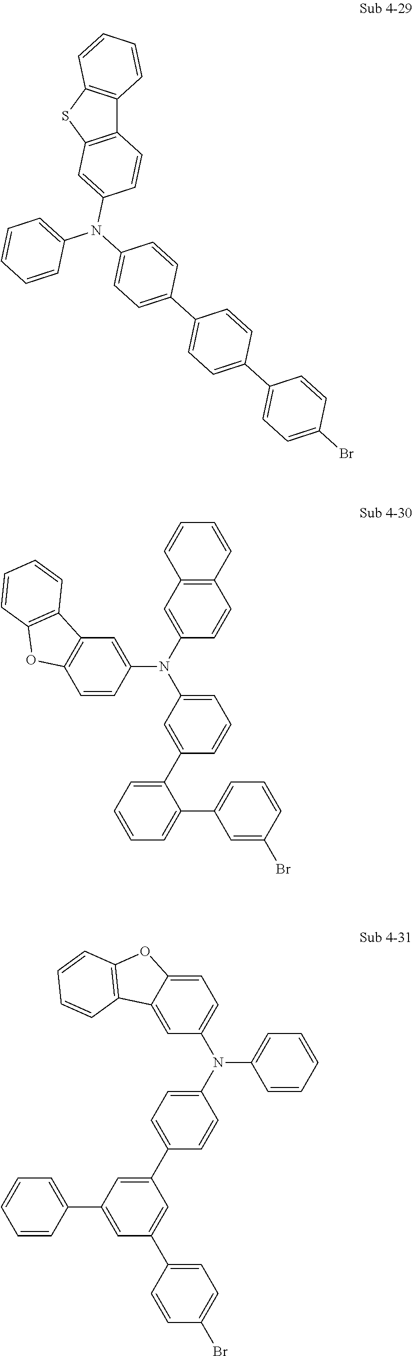 [SMILES: Brc1ccc(-c2ccc(-c3ccc(N(c4ccccc4)c4ccc5c(c4)sc4ccccc45)cc3)cc2)cc1 ; Brc1cccc(-c2ccccc2-c2cccc(N(c3ccc4ccccc4c3)c3ccc4oc5ccccc5c4c3)c2)c1 ; Brc1ccc(-c2cc(-c3ccccc3)cc(-c3ccc(N(c4ccccc4)c4ccc5oc6ccccc6c5c4)cc3)c2)cc1]

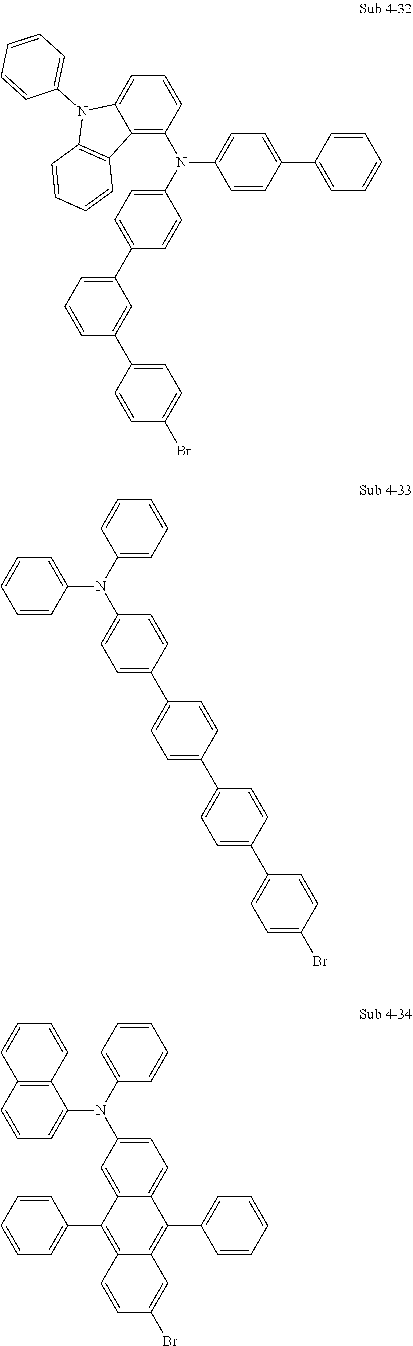 [SMILES: Brc1ccc(-c2cccc(-c3ccc(N(c4ccc(-c5ccccc5)cc4)c4cccc5c4c4ccccc4n5-c4ccccc4)cc3)c2)cc1 ; Brc1ccc(-c2ccc(-c3ccc(-c4ccc(N(c5ccccc5)c5ccccc5)cc4)cc3)cc2)cc1 ; Brc1ccc2c(-c3ccccc3)c3cc(N(c4ccccc4)c4cccc5ccccc45)ccc3c(-c3ccccc3)c2c1]

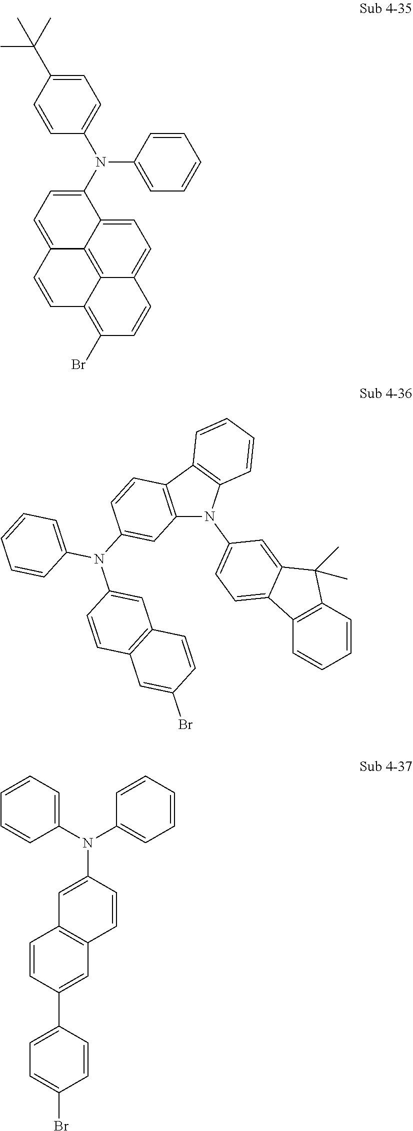 [SMILES: CC(C)(C)c1ccc(N(c2ccccc2)c2ccc3ccc4c(Br)ccc5ccc2c3c54)cc1 ; CC1(C)c2ccccc2-c2ccc(-n3c4ccccc4c4ccc(N(c5ccccc5)c5ccc6cc(Br)ccc6c5)cc43)cc21 ; Brc1ccc(-c2ccc3cc(N(c4ccccc4)c4ccccc4)ccc3c2)cc1]

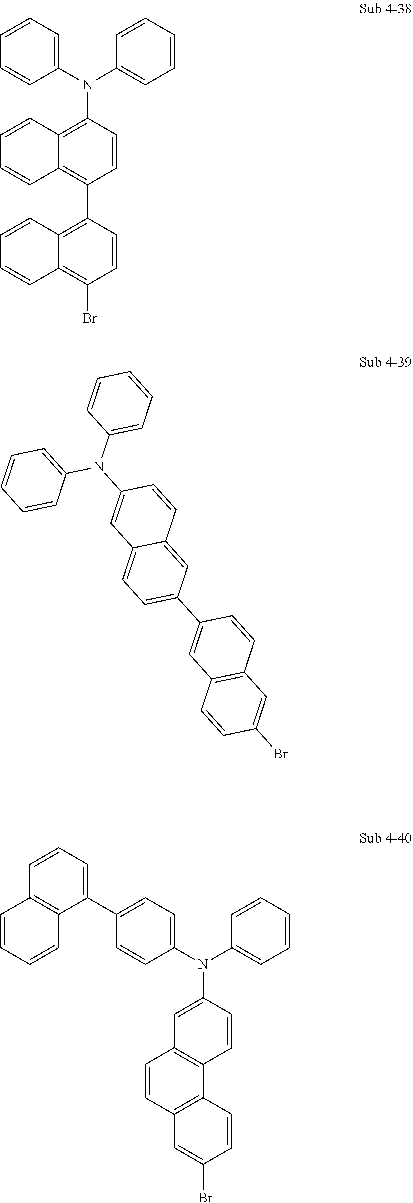 [SMILES: Brc1ccc(-c2ccc(N(c3ccccc3)c3ccccc3)c3ccccc23)c2ccccc12 ; Brc1ccc2cc(-c3ccc4cc(N(c5ccccc5)c5ccccc5)ccc4c3)ccc2c1 ; Brc1ccc2c(ccc3cc(N(c4ccccc4)c4ccc(-c5cccc6ccccc56)cc4)ccc32)c1]

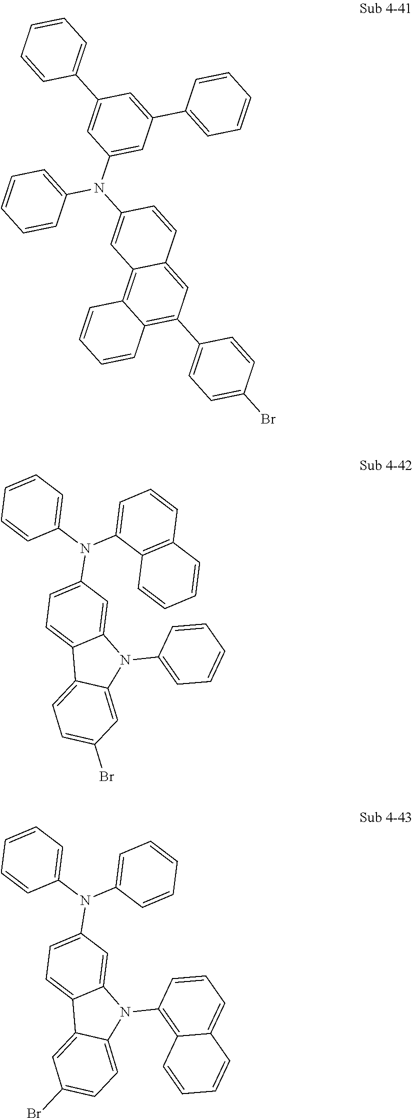 [SMILES: Brc1ccc(-c2cc3ccc(N(c4ccccc4)c4cc(-c5ccccc5)cc(-c5ccccc5)c4)cc3c3ccccc23)cc1 ; Brc1ccc2c3ccc(N(c4ccccc4)c4cccc5ccccc45)cc3n(-c3ccccc3)c2c1 ; Brc1ccc2c(c1)c1ccc(N(c3ccccc3)c3ccccc3)cc1n2-c1cccc2ccccc12]

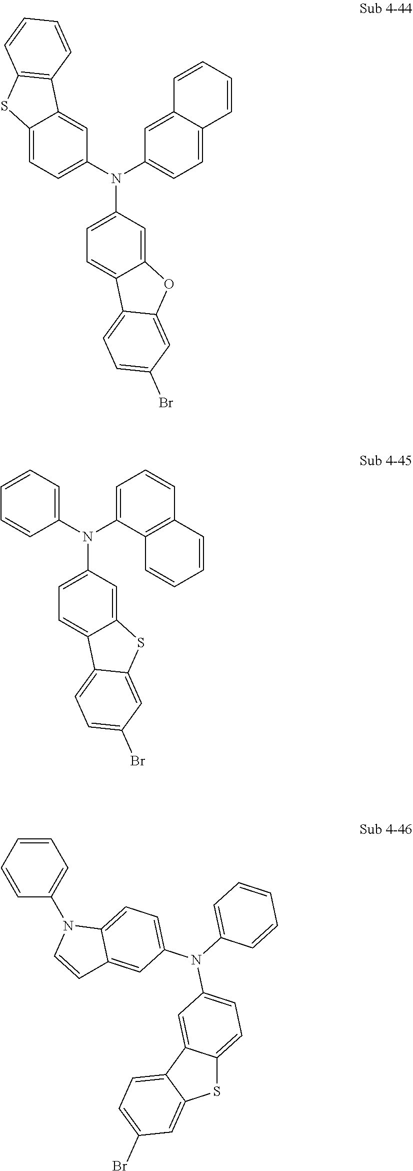 [SMILES: Brc1ccc2c(c1)oc1cc(N(c3ccc4ccccc4c3)c3ccc4sc5ccccc5c4c3)ccc12 ; Brc1ccc2c(c1)sc1cc(N(c3ccccc3)c3cccc4ccccc34)ccc12 ; Brc1ccc2c(c1)sc1ccc(N(c3ccccc3)c3ccc4c(ccn4-c4ccccc4)c3)cc12]

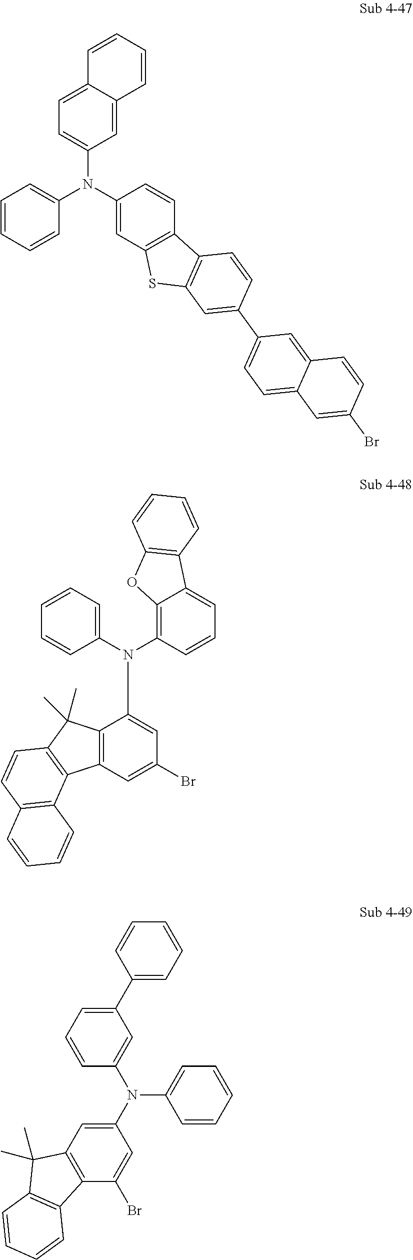 [SMILES: Brc1ccc2cc(-c3ccc4c(c3)sc3cc(N(c5ccccc5)c5ccc6ccccc6c5)ccc34)ccc2c1 ; CC1(C)c2ccc3ccccc3c2-c2cc(Br)cc(N(c3ccccc3)c3cccc4c3oc3ccccc34)c21 ; CC1(C)c2ccccc2-c2c(Br)cc(N(c3ccccc3)c3cccc(-c4ccccc4)c3)cc21]

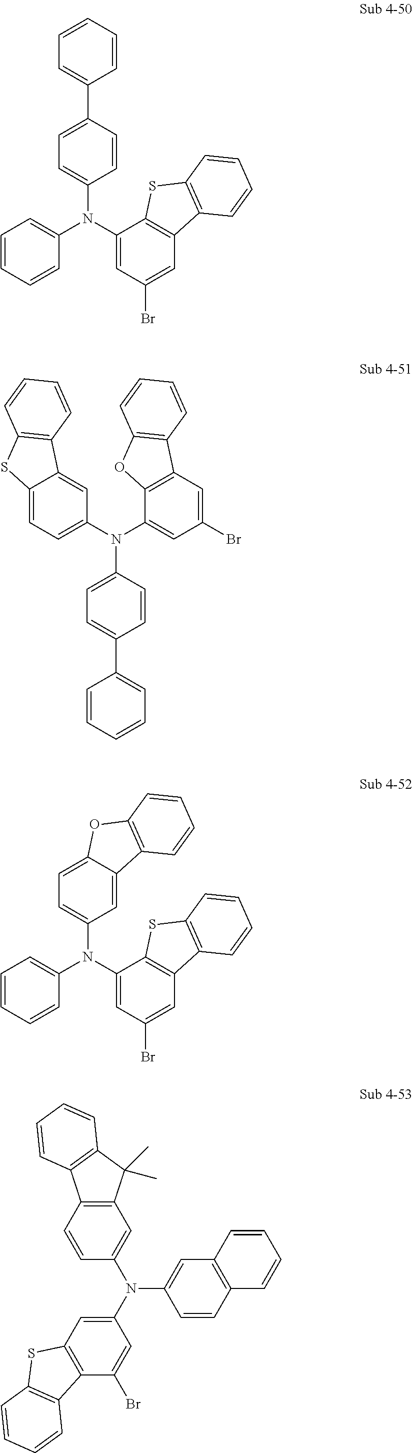 [SMILES: Brc1cc(N(c2ccccc2)c2ccc(-c3ccccc3)cc2)c2sc3ccccc3c2c1 ; Brc1cc(N(c2ccc(-c3ccccc3)cc2)c2ccc3sc4ccccc4c3c2)c2oc3ccccc3c2c1 ; Brc1cc(N(c2ccccc2)c2ccc3oc4ccccc4c3c2)c2sc3ccccc3c2c1 ; CC1(C)c2ccccc2-c2ccc(N(c3ccc4ccccc4c3)c3cc(Br)c4c(c3)sc3ccccc34)cc21]

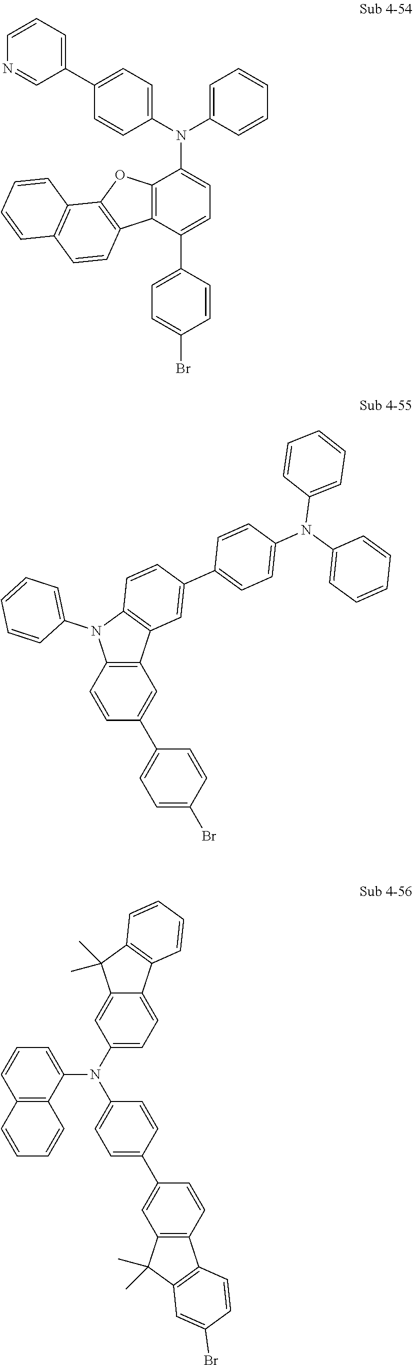 [SMILES: Brc1ccc(-c2ccc(N(c3ccccc3)c3ccc(-c4cccnc4)cc3)c3oc4c5ccccc5ccc4c23)cc1 ; Brc1ccc(-c2ccc3c(c2)c2cc(-c4ccc(N(c5ccccc5)c5ccccc5)cc4)ccc2n3-c2ccccc2)cc1 ; CC1(C)c2cc(Br)ccc2-c2ccc(-c3ccc(N(c4ccc5c(c4)C(C)(C)c4ccccc4-5)c4cccc5ccccc45)cc3)cc21]

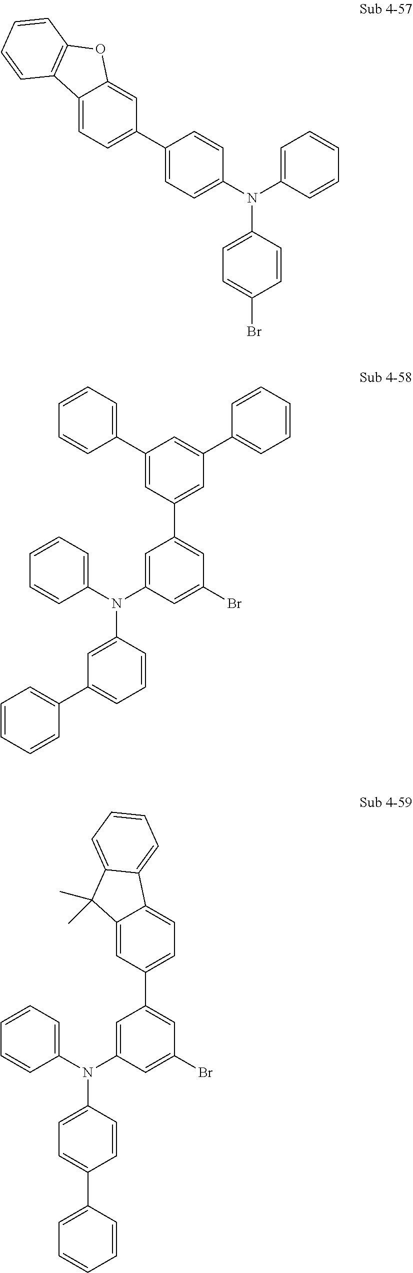 [SMILES: Brc1ccc(N(c2ccccc2)c2ccc(-c3ccc4c(c3)oc3ccccc34)cc2)cc1 ; Brc1cc(-c2cc(-c3ccccc3)cc(-c3ccccc3)c2)cc(N(c2ccccc2)c2cccc(-c3ccccc3)c2)c1 ; CC1(C)c2ccccc2-c2ccc(-c3cc(Br)cc(N(c4ccccc4)c4ccc(-c5ccccc5)cc4)c3)cc21]

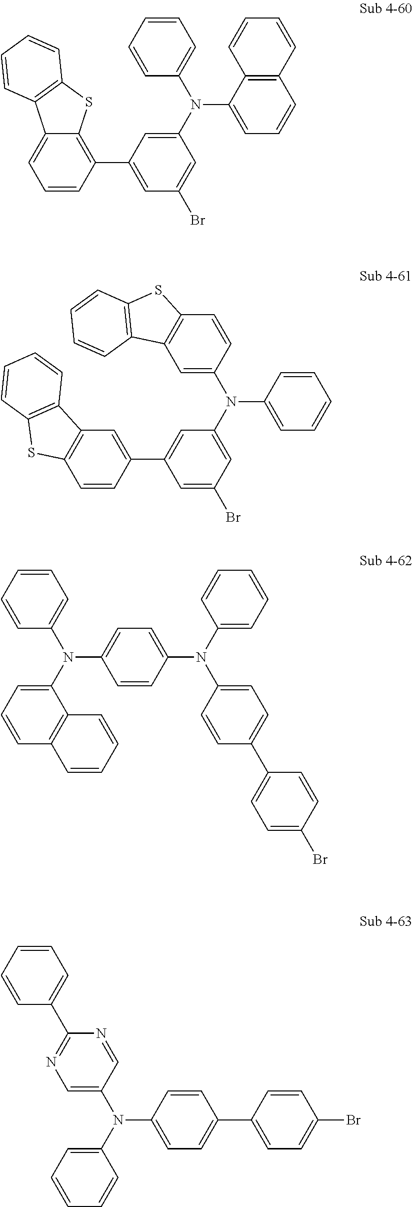 [SMILES: Brc1cc(-c2cccc3c2sc2ccccc23)cc(N(c2ccccc2)c2cccc3ccccc23)c1 ; Brc1cc(-c2ccc3sc4ccccc4c3c2)cc(N(c2ccccc2)c2ccc3sc4ccccc4c3c2)c1 ; Brc1ccc(-c2ccc(N(c3ccccc3)c3ccc(N(c4ccccc4)c4cccc5ccccc45)cc3)cc2)cc1 ; Brc1ccc(-c2ccc(N(c3ccccc3)c3cnc(-c4ccccc4)nc3)cc2)cc1]

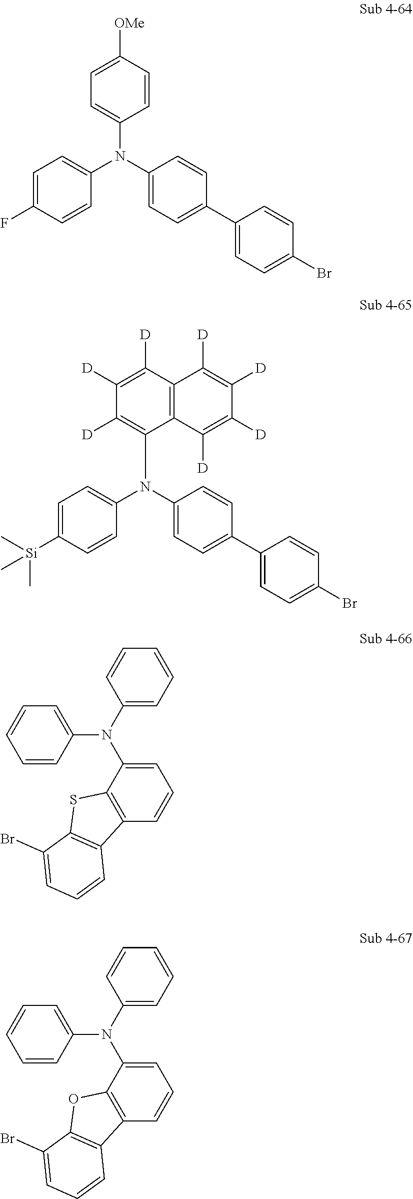 [SMILES: COc1ccc(N(c2ccc(F)cc2)c2ccc(-c3ccc(Br)cc3)cc2)cc1 ; [2H]c1c([2H])c([2H])c2c(N(c3ccc(-c4ccc(Br)cc4)cc3)c3ccc([Si](C)(C)C)cc3)c([2H])c([2H])c([2H])c2c1[2H] ; Brc1cccc2c1sc1c(N(c3ccccc3)c3ccccc3)cccc12 ; Brc1cccc2c1oc1c(N(c3ccccc3)c3ccccc3)cccc12]

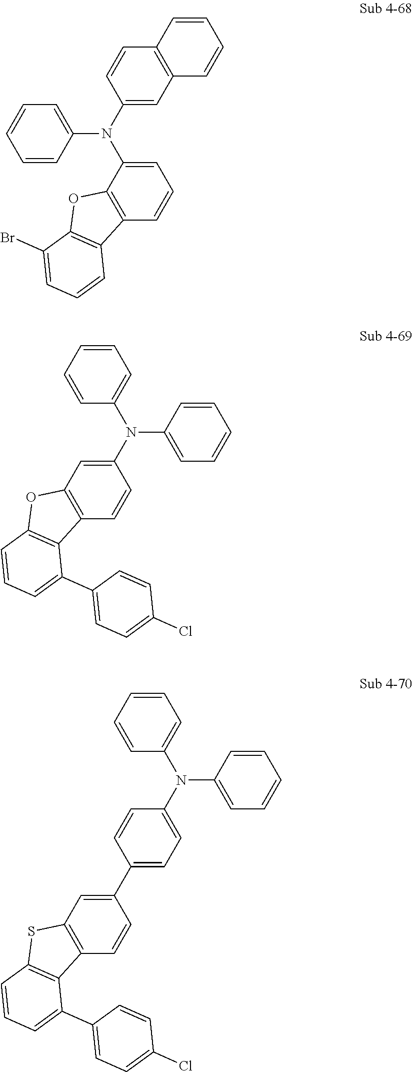 [SMILES: Brc1cccc2c1oc1c(N(c3ccccc3)c3ccc4ccccc4c3)cccc12 ; Clc1ccc(-c2cccc3oc4cc(N(c5ccccc5)c5ccccc5)ccc4c23)cc1 ; Clc1ccc(-c2cccc3sc4cc(-c5ccc(N(c6ccccc6)c6ccccc6)cc5)ccc4c23)cc1]

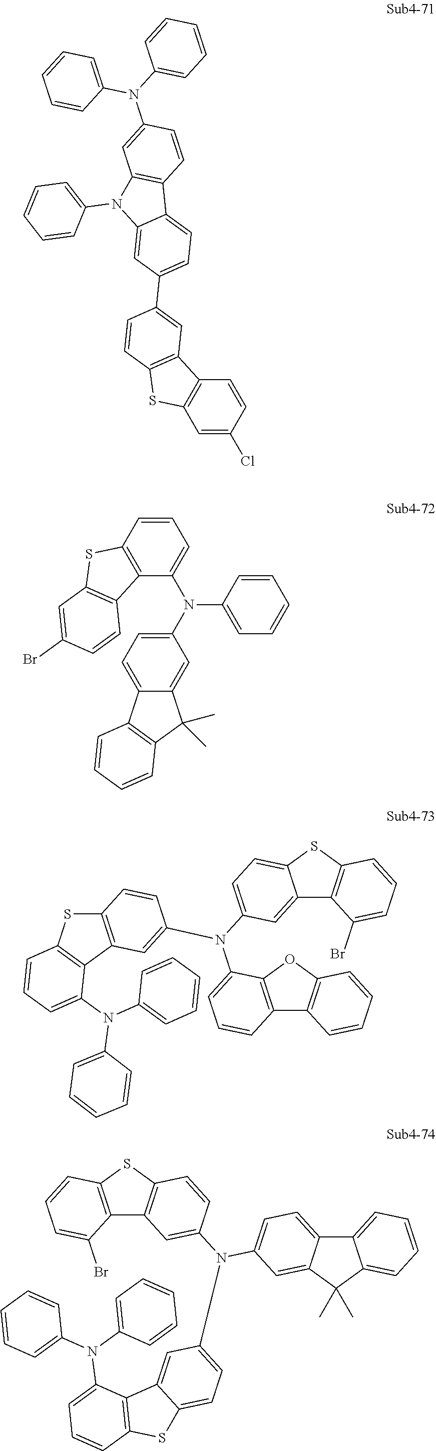 [SMILES: Clc1ccc2c(c1)sc1ccc(-c3ccc4c5ccc(N(c6ccccc6)c6ccccc6)cc5n(-c5ccccc5)c4c3)cc12 ; CC1(C)c2ccccc2-c2ccc(N(c3ccccc3)c3cccc4sc5cc(Br)ccc5c34)cc21 ; Brc1cccc2sc3ccc(N(c4ccc5sc6cccc(N(c7ccccc7)c7ccccc7)c6c5c4)c4cccc5c4oc4ccccc45)cc3c12 ; CC1(C)c2ccccc2-c2ccc(N(c3ccc4sc5cccc(Br)c5c4c3)c3ccc4sc5cccc(N(c6ccccc6)c6ccccc6)c5c4c3)cc21]

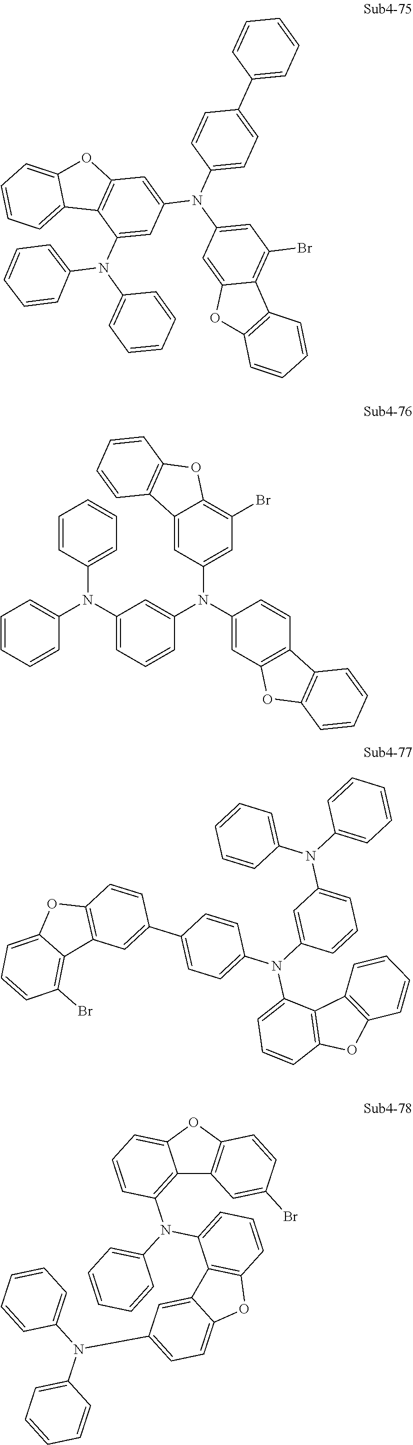 [SMILES: Brc1cc(N(c2ccc(-c3ccccc3)cc2)c2cc(N(c3ccccc3)c3ccccc3)c3c(c2)oc2ccccc23)cc2oc3ccccc3c12 ; Brc1cc(N(c2cccc(N(c3ccccc3)c3ccccc3)c2)c2ccc3c(c2)oc2ccccc23)cc2c1oc1ccccc12 ; Brc1cccc2oc3ccc(-c4ccc(N(c5cccc(N(c6ccccc6)c6ccccc6)c5)c5cccc6oc7ccccc7c56)cc4)cc3c12 ; Brc1ccc2oc3cccc(N(c4ccccc4)c4cccc5oc6ccc(N(c7ccccc7)c7ccccc7)cc6c45)c3c2c1]

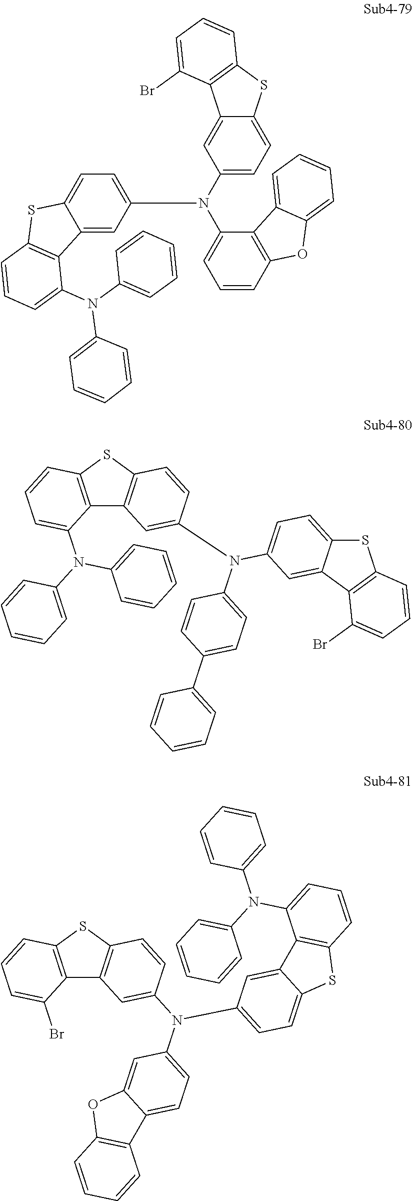 [SMILES: Brc1cccc2sc3ccc(N(c4ccc5sc6cccc(N(c7ccccc7)c7ccccc7)c6c5c4)c4cccc5oc6ccccc6c45)cc3c12 ; Brc1cccc2sc3ccc(N(c4ccc(-c5ccccc5)cc4)c4ccc5sc6cccc(N(c7ccccc7)c7ccccc7)c6c5c4)cc3c12 ; Brc1cccc2sc3ccc(N(c4ccc5c(c4)oc4ccccc45)c4ccc5sc6cccc(N(c7ccccc7)c7ccccc7)c6c5c4)cc3c12]

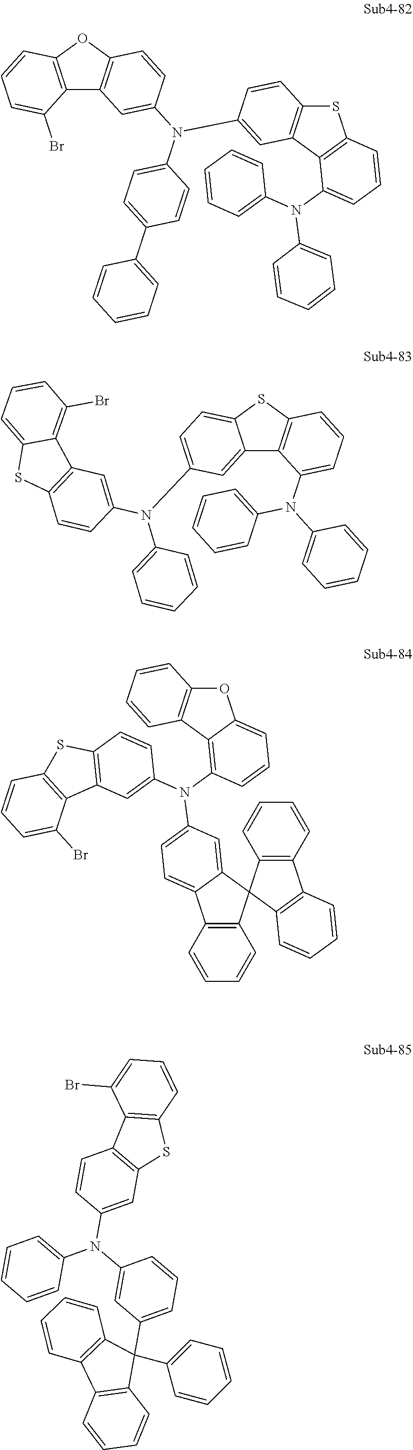 [SMILES: Brc1cccc2oc3ccc(N(c4ccc(-c5ccccc5)cc4)c4ccc5sc6cccc(N(c7ccccc7)c7ccccc7)c6c5c4)cc3c12 ; Brc1cccc2sc3ccc(N(c4ccccc4)c4ccc5sc6cccc(N(c7ccccc7)c7ccccc7)c6c5c4)cc3c12 ; Brc1cccc2sc3ccc(N(c4ccc5c(c4)C4(c6ccccc6-c6ccccc64)c4ccccc4-5)c4cccc5oc6ccccc6c45)cc3c12 ; Brc1cccc2sc3cc(N(c4ccccc4)c4cccc(C5(c6ccccc6)c6ccccc6-c6ccccc65)c4)ccc3c12]

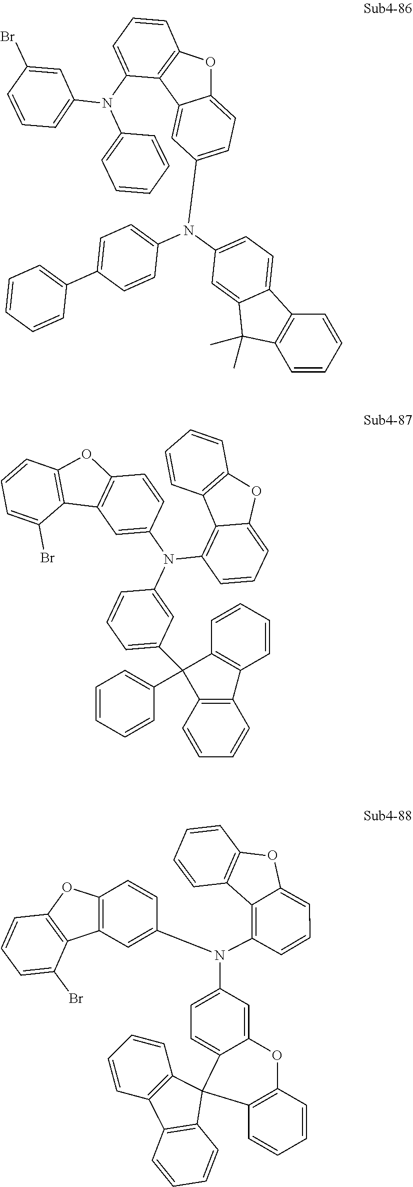 [SMILES: CC1(C)c2ccccc2-c2ccc(N(c3ccc(-c4ccccc4)cc3)c3ccc4oc5cccc(N(c6ccccc6)c6cccc(Br)c6)c5c4c3)cc21 ; Brc1cccc2oc3ccc(N(c4cccc(C5(c6ccccc6)c6ccccc6-c6ccccc65)c4)c4cccc5oc6ccccc6c45)cc3c12 ; Brc1cccc2oc3ccc(N(c4ccc5c(c4)Oc4ccccc4C54c5ccccc5-c5ccccc54)c4cccc5oc6ccccc6c45)cc3c12]

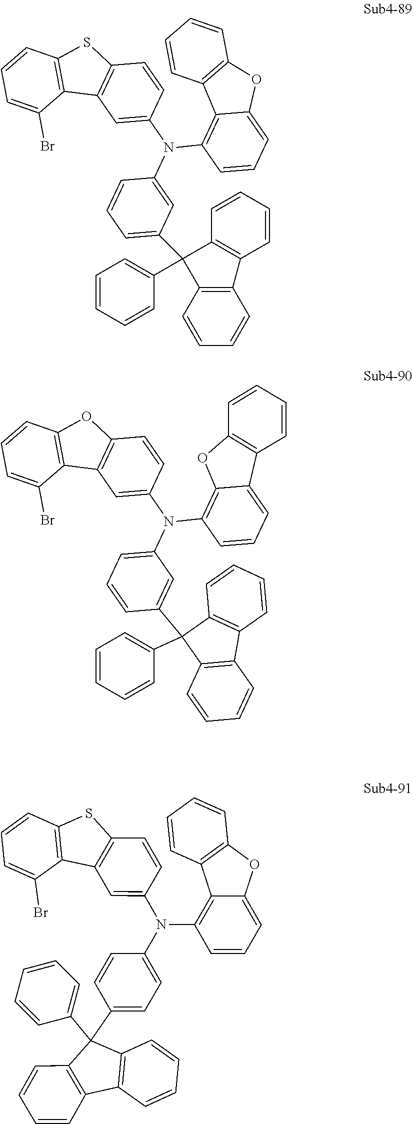 [SMILES: Brc1cccc2sc3ccc(N(c4cccc(C5(c6ccccc6)c6ccccc6-c6ccccc65)c4)c4cccc5oc6ccccc6c45)cc3c12 ; Brc1cccc2oc3ccc(N(c4cccc(C5(c6ccccc6)c6ccccc6-c6ccccc65)c4)c4cccc5c4oc4ccccc45)cc3c12 ; Brc1cccc2sc3ccc(N(c4ccc(C5(c6ccccc6)c6ccccc6-c6ccccc65)cc4)c4cccc5oc6ccccc6c45)cc3c12]

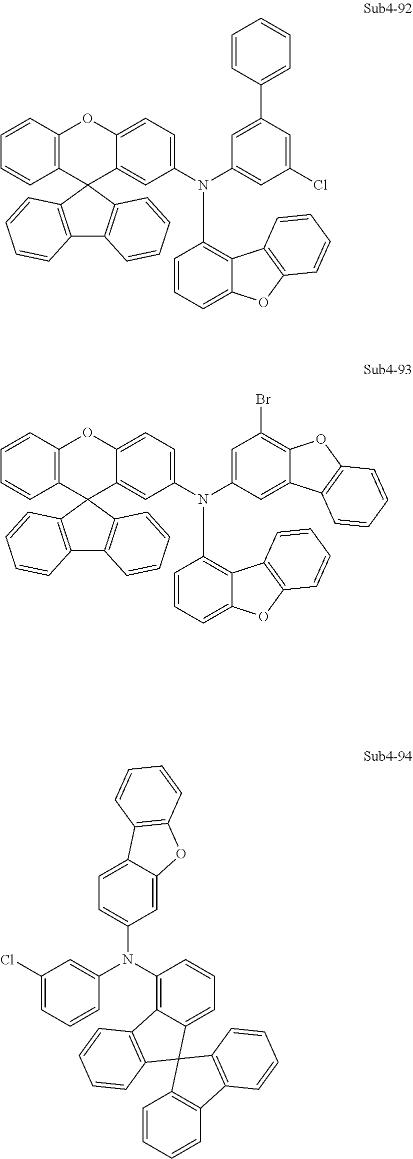 [SMILES: Clc1cc(-c2ccccc2)cc(N(c2ccc3c(c2)C2(c4ccccc4O3)c3ccccc3-c3ccccc32)c2cccc3oc4ccccc4c23)c1 ; Brc1cc(N(c2ccc3c(c2)C2(c4ccccc4O3)c3ccccc3-c3ccccc32)c2cccc3oc4ccccc4c23)cc2c1oc1ccccc12 ; Clc1cccc(N(c2ccc3c(c2)oc2ccccc23)c2cccc3c2-c2ccccc2C32c3ccccc3-c3ccccc32)c1]

TABLE 5

| Com- | | Com- | |
|---|---|---|---|
| pound | FD-MS | pound | FD-MS |
| Sub 4-1 | m/z = 449.08(C₂₈H₂₀BrN = 450.37) | Sub 4-2 | m/z = 525.11(C₃₄H₂₄BrN = 526.48) |
| Sub 4-3 | m/z = 551.12(C₃₆H₂₆BrN = 552.50) | Sub 4-4 | m/z = 499.09(C₃₂H₂₂BrN = 500.43) |
| Sub 4-5 | m/z = 530.14(C₃₄H₁₉D₅BrN = 531.51) | Sub 4-6 | m/z = 506.14(C₃₂H₁₅D₇BrN = 507.48) |
| Sub 4-7 | m/z = 480.12(C₃₀H₁₇D₅BrN = 481.45) | Sub 4-8 | m/z = 565.14(C₃₇H₂₈BrN = 566.54) |
| Sub 4-9 | m/z = 631.19(C₄₂H₃₄BrN = 632.65) | Sub 4-10 | m/z = 576.12(C₃₇H₂₅BrN₂ = 577.53) |
| Sub 4-11 | m/z = 555.07(C₃₄H₂₂BrNS = 556.51) | Sub 4-12 | m/z = 581.08(C₃₆H₂₄BrNS = 582.55) |
| Sub 4-13 | m/z = 611.04(C₃₆H₂₂BrNS₂ = 612.60) | Sub 4-14 | m/z = 581.08(C₃₆H₂₄BrNS = 582.55) |
| Sub 4-15 | m/z = 704.28(C₅₂H₃₆N₂O = 704.87) | Sub 4-16 | m/z = 520.06(C₃₀H₂₁BrN₂S = 521.48) |
| Sub 4-17 | m/z = 539.09(C₃₄H₂₂BrNO = 540.45) | Sub 4-18 | m/z = 564.12(C₃₆H₂₅BrN₂ = 565.50) |
| Sub 4-19 | m/z = 690.17(C₄₆H₃₁BrN₂ = 691.67) | Sub 4-20 | m/z = 657.11(C₄₂H₂₈BrNS = 658.65) |
| Sub 4-21 | m/z = 564.12(C₃₆H₂₅BrN₂ = 565.50) | Sub 4-22 | m/z = 664.15(C₄₄H₂₉BrN₂ = 665.63) |
| Sub 4-23 | m/z = 525.11(C₃₄H₂₄BrN = 526.47) | Sub 4-24 | m/z = 601.14(C₄₀H₂₈BrN = 602.58) |
| Sub 4-25 | m/z = 551.12(C₃₆H₂₆BrN = 552.52) | Sub 4-26 | m/z = 525.11(C₃₄H₂₄BrN = 526.47) |
| Sub 4-27 | m/z = 525.11(C₃₄H₂₄BrN = 526.47) | Sub 4-28 | m/z = 525.11(C₃₄H₂₄BrN = 526.47) |
| Sub 4-29 | m/z = 581.08(C₃₆H₂₄BrNS = 582.55) | Sub 4-30 | m/z = 615.12(C₄₀H₂₆BrNO = 616.54) |
| Sub 4-31 | m/z = 641.14(C₃₀H₂₈BrNO = 642.58) | Sub 4-32 | m/z = 716.18(C₄₈H₃₃BrN₂ = 717.71) |
| Sub 4-33 | m/z = 475.09(C₃₀H₂₂BrN = 476.41) | Sub 4-34 | m/z = 625.14(C₄₂H₂₈BrN = 626.58) |
| Sub 4-35 | m/z = 503.12(C₃₂H₂₆BrN = 504.46) | Sub 4-36 | m/z = 538.10(C₃₄H₂₃BrN₂ = 539.46) |
| Sub 4-37 | m/z = 449.08(C₂₈H₂₀BrN = 450.38) | Sub 4-38 | m/z = 499.09(C₃₂H₂₂BrN = 500.43) |
| Sub 4-39 | m/z = 499.09(C₃₂₂H₂₂BrN = 500.43) | Sub 4-40 | m/z = 549.11(C₃₆H₂₄BrN = 550.50) |
| Sub 4-41 | m/z = 651.16(C₄₄H₃₀BrN = 652.64) | Sub 4-42 | m/z = 538.10(C₃₄H₂₃BrN₂ = 539.46) |
| Sub 4-43 | m/z = 538.10(C₃₄H₂₃BrN₂ = | Sub 4-44 | m/z = 569.04(C₃₄H₂₀BrNOS = |
| | 539.46) | | 570.50) |
| Sub 4-45 | m/z = 479.03(C₂₈H₁₈BrNS = 480.42) | Sub 4-46 | m/z = 544.06(C₃₂H₂₁BrN₂S = 545.49) |
| Sub 4-47 | m/z = 605.08(C₃₈H₂₄BrNS = 606.57) | Sub 4-48 | m/z = 579.12(C₃₇H₂₆BrNO = 580.53) |
| Sub 4-49 | m/z = 515.12(C₃₃H₂₆BrN = 516.48) | Sub 4-50 | m/z = 505.05(C₃₀H₂₀BrNS = 506.46) |
| Sub 4-51 | m/z = 559.06(C₃₆H₂₂BrNOS = | Sub 4-52 | m/z = 519.03(C₃₀H₁₈BrNOS = |
| | 596.54) | | 520.44) |
| Sub 4-53 | m/z = 595.10(C₃₇H₂₆BrNS = 596.59) | Sub 4-54 | m/z = 612.12(C₃₉H₂₅BrN₂O = 617.55) |
| Sub 4-55 | m/z = 640.15(C₄₂H₂₉BrN₂ = 641.61) | Sub 4-56 | m/z = 681.20(C₄₆H₃₆BrN = 682.71) |
| Sub 4-57 | m/z = 489.07(C₃₀H₂₀BrNO = 490.40) | Sub 4-58 | m/z = 627.16(C₄₂H₃₀BrN = 628.61) |
| Sub 4-59 | m/z = 591.16(C₃₉H₃₀BrN = 592.58) | Sub 4-60 | m/z = 555.07(C₃₄H₂₂BrNS = 556.52) |
| Sub 4-61 | m/z = 611.04(C₃₆H₂₂BrNS₂ = 612.60) | Sub 4-62 | m/z = 616.15(C₄₀H₂₉BrN₂ = 617.59) |
| Sub 4-63 | m/z = 477.08(C₂₈H₂₆BrN₃ = | Sub 4-64 | m/z = 447.06(C₂₄H₁₉BrFNO = |
| | 478.39) | | 448.34) |
| Sub 4-65 | m/z = 528.16(C₃₁H₂₁D₅BrNSi = | Sub 4-66 | m/z = 429.02(C₂₄H₁₆BrNS = |
| | 529.60) | | 430.36) |
| Sub 4-67 | m/z = 413.04(C₂₄H₁₆BrNO = 414.30) | Sub 4-68 | m/z = 463.06(C₂₈H₁₈BrNO = 464.36) |
| Sub 4-69 | m/z = 445.12(C₃₀H₂₀ClNO = 445.95) | Sub 4-70 | m/z = 537.13(C₃₆H₂₄ClNS = 538.11) |
| Sub 4-71 | m/z = 626.16(C₄₂H₂₇ClN₂S = 627.20) | Sub 4-72 | m/z = 545.08(C₃₃H₂₄BrNS = 546.53) |
| Sub4-73 | m/z = 792.09(C₄₈H₂₉BrN₂OS₂ = | Sub4-74 | m/z = 818.14(C₅₁H₃₅BrN₂S₂ = |
| | 793.8) | | 819.88) |
| Sub4-75 | m/z = 746.16(C₄₈H₃₁BrN₂O₂ = | Sub4-76 | m/z = 670.13(C₄₂H₂₇BrN₂O₂ = |
| | 747.69) | | 671.59) |
| Sub4-77 | m/z = 746.16(C₄₈H₃₁BrN₂O₂ = | Sub4-78 | m/z = 670.13(C₄₂H₂₇BrN₂O_{z} = |
| | 747.69) | | 671.59) |
| Sub4-79 | m/z = 792.09(C₄₈H₂₉BrN₂OS₂ = | Sub4-80 | m/z = 778.11(C₄₈H₃₁BrN₂S₂ = |
| | 793.8) | | 779.81) |
| Sub4-81 | m/z = 792.09(C₄₈H₂₉BrN₂OS₂ = | Sub4-82 | m/z = 746.16(C₄₈H₃₁BrN₂O₂ = |
| | 793.8) | | 747.69) |
| Sub4-83 | m/z = 702.08(C₄₂H₂₇BrN₂S₂ = | Sub4-84 | m/z = 757.11(C₄₉H₂₈BrNOS = |
| | 703.72) | | 758.73) |
| Sub4-85 | m/z = 669.11(C₄₃H₂₈BrNS = 670.67) | Sub4-86 | m/z = 772.21(C₅₁H₃₇BrN₂O = 773.77) |
| Sub4-87 | m/z = 743.15(C₄₉H₃₀BrNO₂ = 744.69) | Sub4-88 | m/z = 757.13(C₄₉H₂₈BrNO₃ = 758.67) |
| Sub4-89 | m/z = 759.12(C₄₉H₃₀BrNOS = | Sub4-90 | m/z = 743.15(C₄₉H₃₀BrNO₂ = |
| | 760.75) | | 744.69) |
| Sub4-91 | m/z = 759.12(C₄₉H₃₀BrNOS = | Sub4-92 | m/z = 699.2(C₄₉H₃₀ClNO₂ = |
| | 760.75) | | 700.23) |
| Sub4-93 | m/z = 757.13(C₄₉H₂₈BrNO₃ = 758.67) | Sub4-94 | m/z = 607.17(C₄₃H₂₆ClNO = 608.14) |

### Synthesis Example of Final Products

### 1. Synthesis Example of 2-1

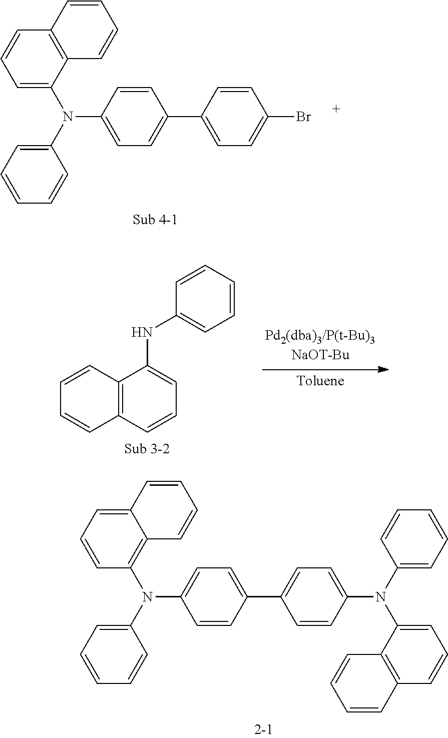 [SMILES: Brc1ccc(-c2ccc(N(c3ccccc3)c3cccc4ccccc34)cc2)cc1 ; c1ccc(Nc2cccc3ccccc23)cc1 ; c1ccc(N(c2ccc(-c3ccc(N(c4ccccc4)c4cccc5ccccc45)cc3)cc2)c2cccc3ccccc23)cc1]

After Sub 4-1 (10 g, 22.20 mmol) was dissolved in toluene (233 mL), and Sub 3-2 (5.36 g, 24.42 mmol), Pd₂(dba)₃ (0.61 g, 0.67 mmol), P(t-Bu)₃ (0.45 g, 2.22 mmol) and NaOt-Bu (6.40 g, 66.61 mmol) were added to the solution, the mixture was stirred at 100° C. When the reaction was completed, the reaction product was extracted with CH₂Cl₂ and water. Then, an organic layer was dried over MgSO₄ and concentrated. Then, the concentrate was separated by a silica gel column and recrystallized to obtain 10.46 g (yield: 80%) of the product.

### 2. Synthesis Example of 2-10

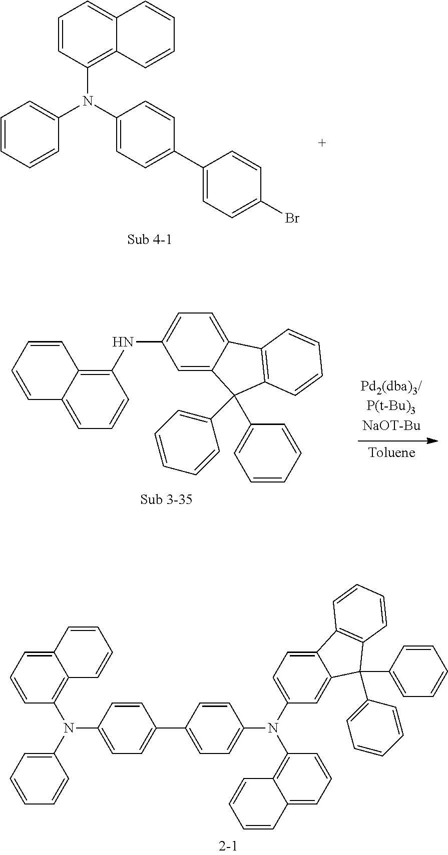 [SMILES: Brc1ccc(-c2ccc(N(c3ccccc3)c3cccc4ccccc34)cc2)cc1 ; c1ccc(C2(c3ccccc3)c3ccccc3-c3ccc(Nc4cccc5ccccc45)cc32)cc1 ; c1ccc(N(c2ccc(-c3ccc(N(c4ccc5c(c4)C(c4ccccc4)(c4ccccc4)c4ccccc4-5)c4cccc5ccccc45)cc3)cc2)c2cccc3ccccc23)cc1]

After dissolving Sub 4-1 (8 g, 17.76 mmol) in toluene (187 ml), Sub 3-35 (8.98 g, 19.54 mmol), Pd₂(dba)₃ (0.49 g, 0.53 mmol), P(t-Bu)₃ (0.36 g, 1.78 mmol) and NaOt-Bu (5.12 g, 53.29 mmol) were added to the solution, and then the reaction was carried out in the same manner as in the synthesis method of 2-1 to obtain 10.6 g (yield: 72%) of the product.

### 3. Synthesis Example of 2-23

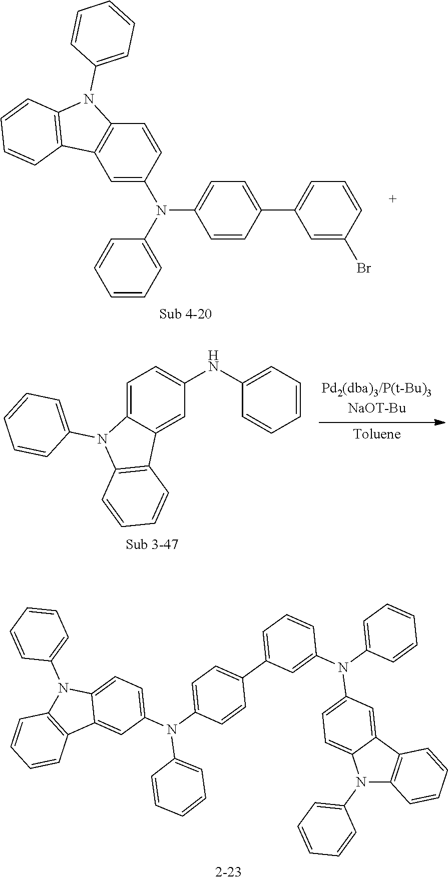 [SMILES: Brc1cccc(-c2ccc(N(c3ccccc3)c3ccc4c(c3)c3ccccc3n4-c3ccccc3)cc2)c1 ; c1ccc(Nc2ccc3c(c2)c2ccccc2n3-c2ccccc2)cc1 ; c1ccc(N(c2ccc(-c3cccc(N(c4ccccc4)c4ccc5c(c4)c4ccccc4n5-c4ccccc4)c3)cc2)c2ccc3c(c2)c2ccccc2n3-c2ccccc2)cc1]

After dissolving Sub 4-20 (9 g, 15.91 mmol) in toluene (167 ml), Sub 3-47 (5.85 g, 17.51 mmol), Pd₂(dba)₃ (0.44 g, 0.48 mmol), P(t-Bu)₃ (0.32 g, 1.59 mmol) and NaOt-Bu (4.59 g, 47.74 mmol) were added to the solution, and then the reaction was carried out in the same manner as in the synthesis method of 2-1 to obtain 10.04 g (yield: 77%) of the product.

### 4. Synthesis Example of 2-50

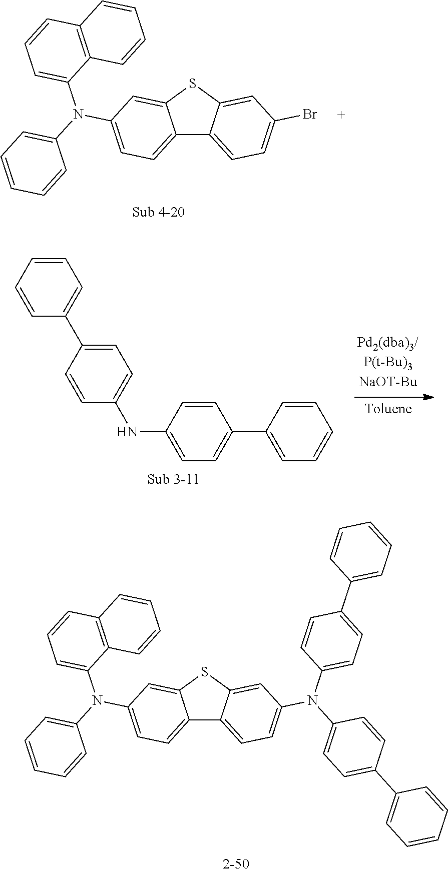 [SMILES: Brc1ccc2c(c1)sc1cc(N(c3ccccc3)c3cccc4ccccc34)ccc12 ; c1ccc(-c2ccc(Nc3ccc(-c4ccccc4)cc3)cc2)cc1 ; c1ccc(-c2ccc(N(c3ccc(-c4ccccc4)cc3)c3ccc4c(c3)sc3cc(N(c5ccccc5)c5cccc6ccccc56)ccc34)cc2)cc1]

After dissolving Sub 4-45 (9.5 g, 19.77 mmol) in toluene (208 ml), Sub 3-11 (6.99 g, 21.75 mmol), Pd₂(dba)₃ (0.54 g, 0.59 mmol), P(t-Bu)₃ (0.40 g, 1.98 mmol) and NaOt-Bu (5.70 g, 59.32 mmol) were added to the solution, and then the reaction was carried out in the same manner as in the synthesis method of 2-1 to obtain 10.41 g (yield: 73%) of the product.

### 5. Synthesis Example of 2-114

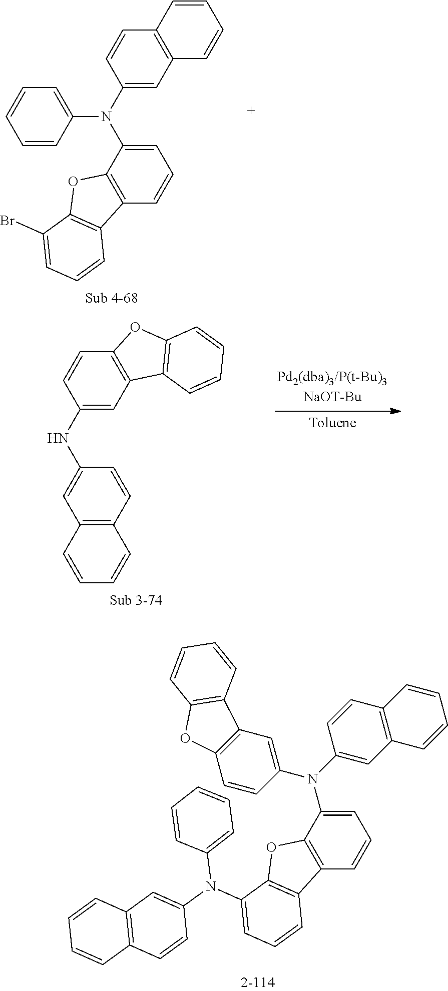 [SMILES: Brc1cccc2c1oc1c(N(c3ccccc3)c3ccc4ccccc4c3)cccc12 ; c1ccc2cc(Nc3ccc4oc5ccccc5c4c3)ccc2c1 ; c1ccc(N(c2ccc3ccccc3c2)c2cccc3c2oc2c(N(c4ccc5ccccc5c4)c4ccc5oc6ccccc6c5c4)cccc23)cc1]

After dissolving Sub 4-68 (6.13 g, 13.20 mmol) in toluene (130 ml), Sub 3-74 (4.08 g, 13.20 mmol), Pd₂(dba)₃ (0.36 g, 0.40 mmol), P(t-Bu)₃ (0.27 g, 1.32 mmol) and NaOt-Bu (3.81 g, 39.60 mmol) were added to the solution, and then the reaction was carried out in the same manner as in the synthesis method of 2-1 to obtain 7.32 g (yield: 80%) of the product.

### 6. Synthesis Example of 2-128

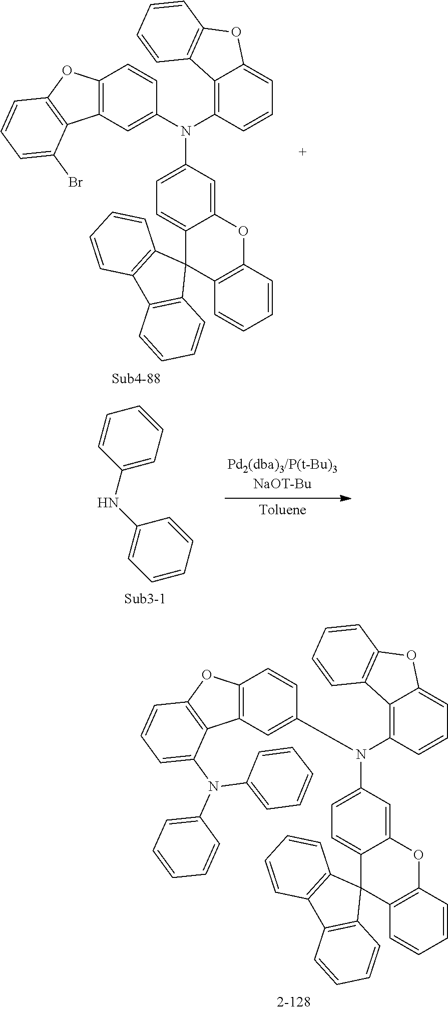 [SMILES: Brc1cccc2oc3ccc(N(c4ccc5c(c4)Oc4ccccc4C54c5ccccc5-c5ccccc54)c4cccc5oc6ccccc6c45)cc3c12 ; c1ccc(Nc2ccccc2)cc1 ; c1ccc(N(c2ccccc2)c2cccc3oc4ccc(N(c5ccc6c(c5)Oc5ccccc5C65c6ccccc6-c6ccccc65)c5cccc6oc7ccccc7c56)cc4c23)cc1]

After dissolving Sub 4-88 (22 g, 29 mmol) in toluene (297 ml), Sub 3-1 (5.2 g, 30.5 mmol), Pd₂(dba)₃ (0.8 g, 0.9 mmol), P(t-Bu)₃ (0.4 g, 1.7 mmol) and NaOt-Bu (8.4 g, 87 mmol) were added to the solution, and then the reaction was carried out in the same manner as in the synthesis method of 2-1 to obtain 19.2 g (yield: 78.3%) of the product.

### 7. Synthesis Example of P4-23

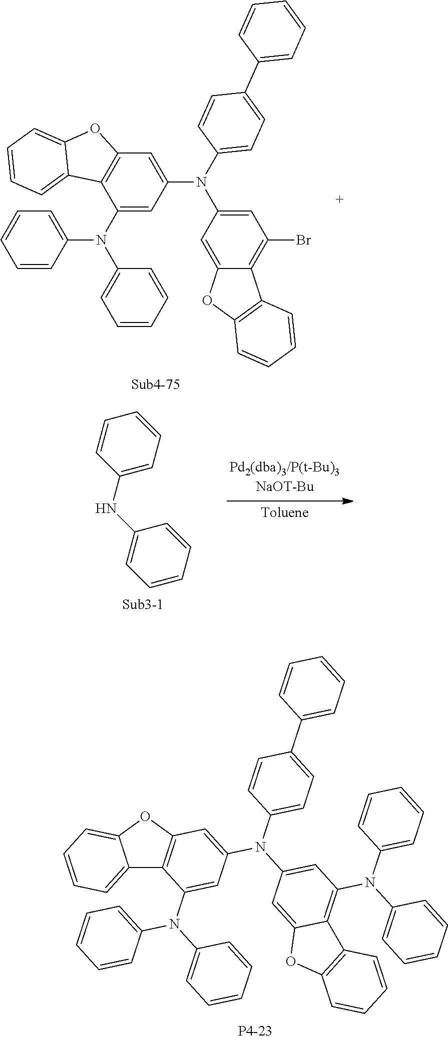 [SMILES: Brc1cc(N(c2ccc(-c3ccccc3)cc2)c2cc(N(c3ccccc3)c3ccccc3)c3c(c2)oc2ccccc23)cc2oc3ccccc3c12 ; c1ccc(Nc2ccccc2)cc1 ; c1ccc(-c2ccc(N(c3cc(N(c4ccccc4)c4ccccc4)c4c(c3)oc3ccccc34)c3cc(N(c4ccccc4)c4ccccc4)c4c(c3)oc3ccccc34)cc2)cc1]

After dissolving Sub 4-75 (26 g, 34.8 mmol) in toluene (256 ml), Sub 3-1 (6.2 g, 36.5 mmol), Pd₂(dba)₃ (0.96 g, 1.0 mmol), P(t-Bu)₃ (0.4 g, 2.1 mmol) and NaOt-Bu (10 g, 104.3 mmol) were added to the solution, and then the reaction was carried out in the same manner as in the synthesis method of 2-1 to obtain 24.2 g (yield: 83.1%) of the product.

### 8. Synthesis Example of P4-25

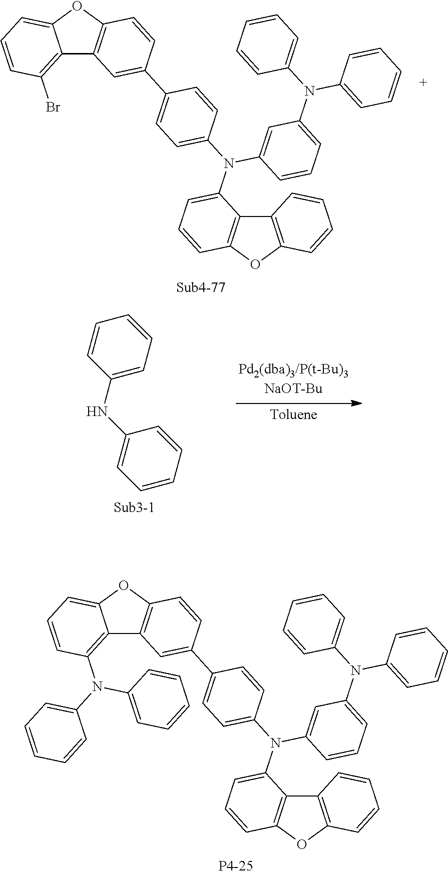 [SMILES: Brc1cccc2oc3ccc(-c4ccc(N(c5cccc(N(c6ccccc6)c6ccccc6)c5)c5cccc6oc7ccccc7c56)cc4)cc3c12 ; c1ccc(Nc2ccccc2)cc1 ; c1ccc(N(c2ccccc2)c2cccc(N(c3ccc(-c4ccc5oc6cccc(N(c7ccccc7)c7ccccc7)c6c5c4)cc3)c3cccc4oc5ccccc5c34)c2)cc1]

After dissolving Sub 4-77 (19 g, 25.4 mmol) in toluene (260 ml), Sub 3-1 (4.5 g, 26.7 mmol), Pd₂(dba)₃ (0.7 g, 0.8 mmol), P(t-Bu)₃ (0.3 g, 1.5 mmol) and NaOt-Bu (7.3 g, 76.2 mmol) were added to the solution, and then the reaction was carried out in the same manner as in the synthesis method of 2-1 to obtain 16 g (yield: 75.4%) of the product.

### 9. Synthesis Example of P4-146

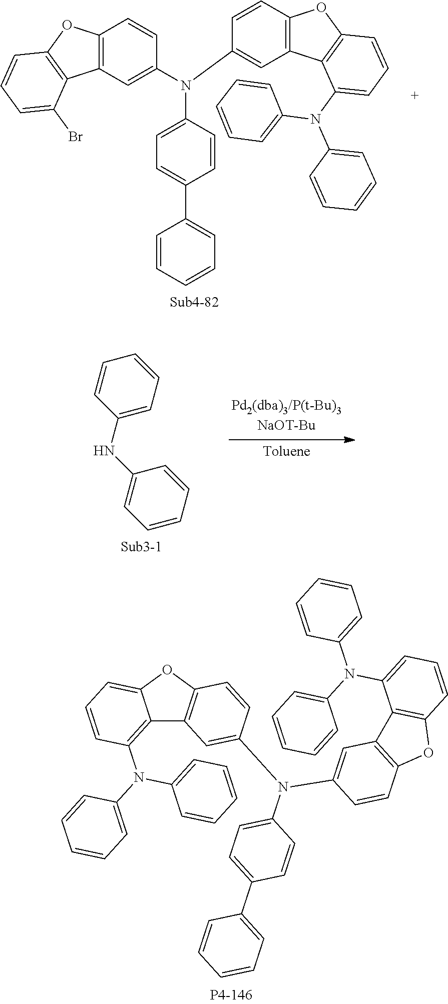 [SMILES: Brc1cccc2oc3ccc(N(c4ccc(-c5ccccc5)cc4)c4ccc5oc6cccc(N(c7ccccc7)c7ccccc7)c6c5c4)cc3c12 ; c1ccc(Nc2ccccc2)cc1 ; c1ccc(-c2ccc(N(c3ccc4oc5cccc(N(c6ccccc6)c6ccccc6)c5c4c3)c3ccc4oc5cccc(N(c6ccccc6)c6ccccc6)c5c4c3)cc2)cc1]

After dissolving Sub 4-82 (23 g, 30.8 mmol) in toluene (315 ml), Sub 3-1 (5.5 g, 32.3 mmol), Pd₂(dba)₃ (0.9 g, 0.9 mmol), P(t-Bu)₃ (0.4 g, 1.9 mmol) and NaOt-Bu (8.9 g, 92.3 mmol) were added to the solution, and then the reaction was carried out in the same manner as in the synthesis method of 2-1 to obtain 20.6 g (yield: 80%) of the product.

### 10. Synthesis Example of P4-150

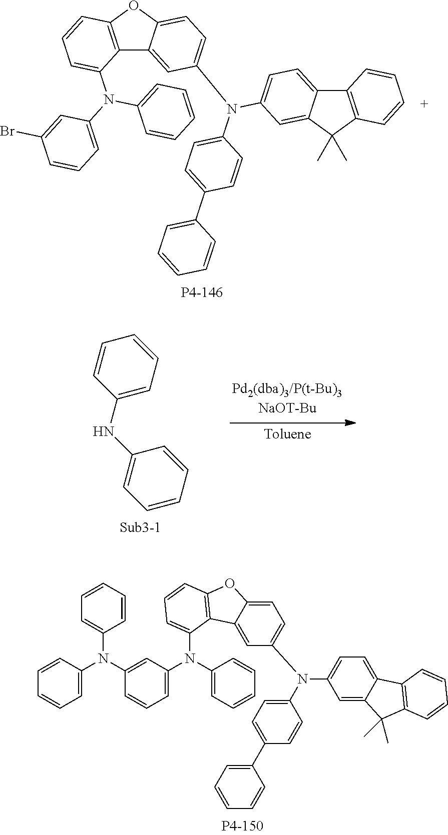 [SMILES: CC1(C)c2ccccc2-c2ccc(N(c3ccc(-c4ccccc4)cc3)c3ccc4oc5cccc(N(c6ccccc6)c6cccc(Br)c6)c5c4c3)cc21 ; c1ccc(Nc2ccccc2)cc1 ; CC1(C)c2ccccc2-c2ccc(N(c3ccc(-c4ccccc4)cc3)c3ccc4oc5cccc(N(c6ccccc6)c6cccc(N(c7ccccc7)c7ccccc7)c6)c5c4c3)cc21]

After dissolving Sub 4-86 (24 g, 31 mmol) in toluene (318 ml), Sub 3-1 (5.5 g, 32.6 mmol), Pd₂(dba)₃ (0.9 g, 0.9 mmol), P(t-Bu)₃ (0.4 g, 1.9 mmol) and NaOt-Bu (8.9 g, 93.1 mmol) were added to the solution, and then the reaction was carried out in the same manner as in the synthesis method of 2-1 to obtain 20.7 g (yield: 77.3%) of the product.

The FD-MS values of the compounds represented by Formula 2 of the present invention synthesized by the above synthesis method are shown in Table 6 below.

TABLE 6

| Com- | | Com- | |
|---|---|---|---|
| pound | FD-MS | pound | FD-MS |
| 2-1 | m/z = 588.26(C₄₄H₃₂N₂ = 588.74) | 2-2 | m/z = 816.35(C₆₂H₄₄N₂ = 817.05) |
| 2-3 | m/z = 792.35(C₆₀H₄₄N₂ = 793.03) | 2-4 | m/z = 763.30(C₅₇H₃₇N₃ = 763.94) |
| 2-5 | m/z = 700.37(C₅₂H₂₈D₁₀N₂ = 700.95) | 2-6 | m/z = 730.33(C₅₅H₄₂N₂ = 730.96) |
| 2-7 | m/z = 877.44(C₆₆H₄₃D₇N₂ = 878.18) | 2-8 | m/z = 876.35(C₆₄H₄₈N₂S = 877.16) |
| 2-9 | m/z = 952.48(C₇₂H₆₀N₂ = 953.29) | 2-10 | m/z = 828.35(C₆₃H₄₄N₂ = 829.06) |
| 2-11 | m/z = 863.33(C₆₂H₄₅N₃S = 864.12) | 2-12 | m/z = 981.41(C₇₄H₅₁N₃ = 982.24) |
| 2-13 | m/z = 816.31(C₆₁H₄₀N₂O = 817.00) | 2-14 | m/z = 770.28(C₅₆H₃₈N₂S = 770.99) |
| 2-15 | m/z = 794.29(C₅₈H₃₈N₂O₂ = 794.95) | 2-16 | m/z = 776.23(C₅H₃₆N₂S₂ = 777.02) |
| 2-17 | m/z = 912.18(C₆₀H₃₆N₂S₄ = 913.20) | 2-18 | m/z = 852.26(C₆₀H₄₀N₂S₂ = 853.10) |
| 2-19 | m/z = 905.38(C₆₈H₄₇N₃ = 906.15) | 2-20 | m/z = 935.33(C₆₈H₄₅N₂S₂ = 936.19) |
| 2-21 | m/z = 709.26(C₅₀H₃₅NS = 709.91) | 2-22 | m/z = 800.23(C₅₆H₃₆N₂S₂ = 801.04) |
| 2-23 | m/z = 818.34(C₆₀H₄₂N₄ = 819.02) | 2-24 | m/z = 818.34(C₆₀H₄₂N₄ = 819.02) |
| 2-25 | m/z = 650.35(C₄₈H₂₆D₁₀N₂ = 650.89) | 2-26 | m/z = 664.29(C₅₀H₃₆N₂ = 664.85) |
| 2-27 | m/z = 760.25(C₅₄H₃₆N₂OS = 760.96) | 2-28 | m/z = 835.30(C₆₀H₄₁N₃S = 836.07) |
| 2-29 | m/z = 740.32(C₅₆H₄₀N₂ = 740.95) | 2-30 | m/z = 878.37(C₆₇H₄₆N₂ = 879.12) |
| 2-31 | m/z = 911.33(C₆₆H₄₅N₃S = 912,17) | 2-32 | m/z = 664.29(C₅₀H₃₆N₂ = 664.85) |
| 2-33 | m/z = 844.31(C₆₂H₄₀N₂O₂ = 844.99) | 2-34 | m/z = 664.29(C₅₀H₃₆N₂ = 664.85) |
| 2-35 | m/z = 664.29(C₅₀H₃₆N₂ = 664.85) | 2-36 | m/z = 820.31(C₆₀H₄₀N₂O₂ = 820.99) |
| 2-37 | m/z = 640.29(C₄₈H₃₆N₂ = 640.83) | 2-38 | m/z = 881.38(C₆₆H₄₇N₃ = 882.10) |
| 2-39 | m/z = 764.32(C₆₈H₄₀N₂ = 764.97) | 2-40 | m/z = 648.35(C₄₈H₄₄N₂ = 648.89) |
| 2-41 | m/z = 908.39(C₆₇H₃₆N₄ = 909.15) | 2-42 | m/z = 538.24(C₄₀H₃₀N₂ = 538.69) |
| 2-43 | m/z = 588.26(C₄₄H₃₂N₂ = 588.75) | 2-44 | m/z = 759.27(C₅₄H₃₇N₃S = 759.97) |
| 2-45 | m/z = 764.32(C₅₈H₄₀N₂ = 764.97) | 2-46 | m/z = 846.31(C₆₂H₄₂N₂S = 847.09) |
| 2-47 | m/z = 677.28(C₅₀H₃₅N₃ = 677.85 | 2-48 | m/z = 627.27(C₄₆H₃₃N₃ = 627.79) |
| 2-49 | m/z = 814.21(C₅₆H₃N₂OS₂ = 815.02) | 2-50 | m/z = 720.26(C₆₂H₃₆N₂S = 720.93) |
| 2-51 | m/z = 748.27(C₅₂H₃₆N₄S = 748.95) | 2-52 | m/z = 744.26(C₅₄H₃₆N₂S = 744.96) |
| 2-53 | m/z = 774.27(C₅₅H₃₈N₂OS = 774.98) | 2-54 | m/z = 731.33(C₅₄H₄₁N₃ = 731.94) |
| 2-55 | m/z = 670.24(C₄₈H₃₄N₂S = 670.87) | 2-56 | m/z = 866.24(C₆₀H₃₈N₂OS₂ = 867.10) |
| 2-57 | m/z = 698.20(C₄₈H₃₀N₂O₂S = 698.84) | 2-58 | m/z = 850.34(C₆₂H₄₆N₂S = 851.12) |
| 2-59 | m/z = 782.30(C₅₆H₃₈N₄ = 782.95) | 2-60 | m/z = 729.31(C₅₄H₃₉N₃ = 729.93) |
| 2-61 | m/z = 936.44(C₇₁H₅₆N₂ = 937.24) | 2-62 | m/z = 744.28(C₅₄H₃₆N₂O₂ = 744.89) |
| 2-63 | m/z = 792.35(C₆₀H₄₄N₂ = 793.03) | 2-64 | m/z = 756.35(C₅₇H₄₄N₄ = 756.99) |
| 2-65 | m/z = 694.24(C₅₀H₃N₂S = 694.90) | 2-66 | m/z = 852.26(C₆₀H₄₀N₂S₂ = 853.11) |
| 2-67 | m/z = 922.40(C₆₈H₅₀N₄ = 923.18) | 2-68 | m/z = 631.27(C₄₄H₃₃N₅ = 631.78) |
| 2-69 | m/z = 626.24(C₄₃H₃₁FN₂O₂ = | 2-70 | m/z = 723.40(C₅₁H₄₁D₇N₂Si = |
| | 626.73) | | 724.09) |
| 2-71 | m/z = 608.19(C₄₂H₂₈N₂OS = 608.76) | 2-72 | m/z = 608.19(C₄₂H₂₈N₂OS = 608.76) |
| 2-73 | m/z = 791.24(C₅₄H₃₇N₃S₂ = 792.03) | 2-74 | m/z = 684.22(C₄₈H₃₂N₂OS = 684.86) |
| 2-75 | m/z = 658.21(C₄₆H₃N₂OS = 658.82) | 2-76 | m/z = 624.17(C₄₂H₂₈N₂S₂ = 624.82) |
| 2-77 | m/z = 700.20(C₄₈H₃₂N₂S₂ = 700.92) | 2-78 | m/z = 791.24(C₅₄H₃₇N₃S₂ = 792.03) |
| 2-79 | m/z = 638.19(C₄₃H₃₀N₂S₂ = 638.85) | 2-80 | m/z = 730.16(C₄₈H₃₀N₂S = = 730.96) |
| 2-81 | m/z = 624.17(C₄₂H₂₈N₂S₂ = 624.82) | 2-82 | m/z = 700.2(C₄₈H₃₂N₂S₂ = 700.92) |
| 2-83 | m/z = 848.30(C₆₀H₄₀N₄S = 849.07) | 2-84 | m/z = 674.19(C₄₆H₃₀N₂S₂ = 674.88) |
| 2-85 | m/z = 624.17(C₄₂H₂₈N₂S₂ = 624.82) | 2-86 | m/z = 674.19(C₄₆H₃₀N₂S₂ = 674.88) |
| 2-87 | m/z = 624.17(C₄₂H₂₈N₂S₂ = 624.82) | 2-88 | m/z = 700.2(C₄₈H₃₂N₂S₂ = 700.92) |
| 2-89 | m/z = 674.19(C₄₆H₃₀N₂S₂ = 674.88) | 2-90 | m/z = 674.19(C₄₆H₃₀N₂S₂ = 674.88) |
| 2-91 | m/z = 674.19(C₄₆H₃₀N₂S₂ = 674.88) | 2-92 | m/z = 674.19(C₄₆H₃₀N₂S₂ = 674.88) |
| 2-93 | m/z = 674.19(C₄₆H₃₈N₂S₂ = 674.88) | 2-94 | m/z = 674.19(C₄₆H₃₀N₂S₂ = 674.88) |
| 2-95 | m/z = 674.19(C₄₆H₃₀N₂S₂ = 674.88) | 2-96 | m/z = 674.19(C₄₆H₃₀N₂S₂ = 674.88) |
| 2-97 | m/z = 700.2(C₄₈H₃₂N₂S₂ = 700.92) | 2-98 | m/z = 710.28(C₅₁H₃₈N₂S = 710.94) |
| 2-99 | m/z = 634.24(C₄₅H₃₄N₂S = 634.84) | 2-100 | m/z = 834.31(C₆₁H₄₂N₂S = 835.08) |
| 2-101 | m/z = 658.21(C₄₆H₃₂N₂OS = 658.82) | 2-102 | m/z = 684.22(C₄₈H₃₂N₂OS = 684.86) |
| 2-103 | m/z = 684.22(C₄₈H₃₂N₂OS = 684.86) | 2-104 | m/z = 658.21(C₄₈H₃₀N₂OS = 658.82) |
| 2-105 | m/z = 658.21(C₆₄H₃₀N₂OS = 658.82) | 2-106 | m/z = 832.31(C₆₁H₄₀N₂O₂ = 833.00) |
| 2-107 | m/z = 668.25(C₄₈H₃₂N₂O₂ = 668.80) | 2-108 | m/z = 720.26(C₅₂H₃₆N₂S = 720.93) |
| 2-109 | m/z = 759.27(C₅₄H₃₇N₃S = 759.97) | 2-110 | m/z = 872.32(C₆₄H₄₄N₂S = 873.13) |
| 2-111 | m/z = 618.21(C₄₄H₃₀N₂S = 618.80) | 2-112 | m/z = 700.20(C₄₈H₃₂N₂S₂ = 700.92) |
| 2-113 | m/z = 708.22(C₅₆H₃₂N₂OS = 708.88) | 2-114 | m/z = 692.25(C₅₀H₃₂N₂O₂ = 692.82) |
| 2-115 | m/z = 742.30(C₅₅H₃₈N₂O = 742.92) | 2-116 | m/z = 891.33(C₆₃H₄₅N₃OS = 892.13) |
| 2-117 | m/z = 862.27(C₆₁H₃₈N₂O₂S = 863.05) | 2-118 | m/z = 958.32(C₆₆H₄₆N₄S₂ = 959.24) |
| 2-119 | m/z = 872.34(C₆₄H₄₄N₂O₂ = 873.07) | 2-120 | m/z = 708.28(C₅₁H₃₆N₂O₂ = 708.86) |
| 2-121 | m/z = 734.33(C₅₄H₄₂N₂O = 734.94) | 2-122 | m/z = 724.25(C₅₁H₃₆N₂OS = 724.92) |
| 2-123 | m/z = 750.31(C₅₄H₄₂N₂S = 751.00) | 2-124 | m/z = 884.41(C₆₇H₅₂N₂ = 885.17) |
| 2-125 | m/z = 846.27(C₆₁H₃₈N₂OS = 847.05) | 2-126 | m/z = 758.28(C₅₅H₃₈N₂S = 758.98) |
| 2-127 | m/z = 832.31(C₆₁H₄₀N₂O₂ = 833) | 2-128 | m/z = 846.29(C₆₁H₃₈N₂O₃ = 846.99) |
| 2-129 | m/z = 848.29(C₆₁H₄₀N₂OS = 849.06) | 2-130 | m/z = 832.31(C₆₁H₄₀N₂O₂ = 833) |
| 2-131 | m/z = 848.29(C₆₁H₄₀N₂OS = 849.06) | 2-132 | m/z = 832.31(C₆₁H₄₀N₂O₂ = 833) |
| 2-133 | m/z = 846.29(C₆₁H₃₈N₂O₃ = 846.99) | 2-134 | m/z = 816.31(C₆₁H₄₀N₂O = 817) |
| 2-135 | m/z = 850.27(C₆₀H₃₈N₂O₂S = 851.04) | 2-136 | m/z = 700.2(C₄₈H₃₂N₂S₂ = 700.92) |
| 2-137 | m/z = 684.22(C₄₈H₃₂N₂OS = 684.86) | 2-138 | m/z = 760.25(C₅₄H₃₆N₂OS = 760.96) |
| P4-21 | m/z = 881.25(C₆₀H₃₉N₃OS₂ = 882.11) | P4-22 | m/z = 907.31(C₆₃H₄₅N₃S₂ = 908.19) |
| P4-23 | m/z = 835.32(C₆₆H₄₁N₃O₂ = 836.01) | P4-24 | m/z = 759.29(C₅₄H₃₇N₃O₂ = 759.91) |
| P4-25 | m/z = 835.32(C₆₀H₄₁N₃O₂ = 836.01) | P4-51 | m/z = 867.27(C₆₀H₄₁N₃S₂ = 868.13) |
| P4-52 | m/z = 881.25(C₆₀H₃₉N₃OS₂ = 882.11) | P4-146 | m/z = 835.32(C₆₀H₄₁N₃O₂ = 836.01) |
| P4-147 | m/z = 791.24(C₅₄H₃₇N₃S₂ = 792.03) | P4-150 | m/z = 861.37(C₆₃H₄₇N₃O = 862.09) |
| P4-214 | m/z = 759.29(C₅₄H₃₇N₃O₂ = 759.91) | P4-215 | m/z = 881.25(C₆₀H₃₉N₃OS₂ = 882.11) |

Hereinafter, a method for measuring the HOMO energy level using the compound of the present invention prepared according to the above synthesis example will be described in detail with reference to Examples, but the present invention is not limited to the following Examples.

### Example for Measuring HOMO Energy Level

The HOMO energy level can be measured using a CV-graph.

A measurement sample in which the electrolyte and the compound to be measured are dissolved is prepared. Illustratively, 0.1M TBAP in ACN (acetonitrile) electrolyte may be prepared, and 2.5 mg of the compound to be measured may be dissolved in 1 ml of chloroform as a solvent to prepare a measurement sample.

Thereafter, the cyclic voltammetry of the measurement sample is measured at room temperature, and the HOMO energy level can be obtained using the CV-graph (current-voltage graph). The vertical axis of the CV-graph represents the current and the horizontal axis represents the voltage (potential), and the HOMO energy level is calculated using the lower curve among the two curves. That is, a graph in the case of reverse scanning of the voltage is used, and the HOMO energy level can be obtained from the potential value at the intersection of two straight lines. That is, the unit of the potential value can be changed to the energy unit eV.

The above two straight lines refer to the tangent line (horizontal line) drawn to the graph in the section before the meaningful reaction starts (the section with little change in current) and the tangent line drawn to the curve (the section in which the current rapidly decreases as the voltage is applied) between the points where a meaningful reaction starts and the maximum oxidation current flows.

On the other hand, in order to obtain the HOMO energy level of the compound to be measured, it is necessary to correct the HOMO energy level of the reference sample. That is, the HOMO energy level of the compound to be measured is calculated by adding the correction value, which is the difference in CV value between the reference sample and the measurement sample, to HOMO energy level intrinsic to the reference sample as s shown in the following conversion formula.

HOMO energy level of the compound to be measured=HOMO energy level unique to the reference sample+correction value Conversion formula:

In the conversion equation, the correction value is obtained by the following equation.

Correction value=(HOMO energy level in CV-graph of reference sample)−(HOMO level in CV-graph of measurement sample)

For example, when Alq₃ is used as a reference sample, the HOMO energy level of the compound to be measured can be obtained by the following conversion equation. The intrinsic HOMO energy level of Alq₃ is −5.8 eV.

HOMO energy level of the compound to be measured=−5.8 (eV)+correction value

[Correction value=(HOMO energy level in CV-graph of Alq₃)−(HOMO energy level in CV-graph of sample to be measured)]

The HOMO energy levels for the compounds of the present invention measured according to the energy level measurement method as described above are shown in Table 7 below.

TABLE 7

| Com- | HOMO | Com- | HOMO |
|---|---|---|---|
| pound | Energy level | pound | Energy level |
| 1-5 | −5.63 eV | 1-9 | −5.56 eV |
| 1-13 | −5.57 eV | 1-16 | −5.61 eV |
| 1-62 | −5.75 eV | 1-72 | −5.72 eV |
| 1-100 | −5.71 eV | 1-105 | −5.53 eV |
| 1-131 | −5.61 eV | 1-134 | −5.55 eV |
| 1-135 | −5.48 eV | 2-16 | −5.58 eV |
| 2-28 | −5.51 eV | 2-44 | −5.64 eV |
| 2-73 | −5.54 eV | 2-76 | −5.60 eV |
| 2-78 | −5.55 eV | 2-83 | −5.53 eV |
| 2-106 | −5.65 eV | 2-116 | −5.58 eV |
| 2-117 | −5.60 eV | 2-118 | −5.57 eV |
| 2-120 | −5.65 eV | 2-123 | −5.59 eV |

Hereinafter, examples will be given for the manufacture and evaluation of an organic electric element employing the compound of the present invention, but the present invention is not limited to the following examples.

### <Manufacturing and Evaluation of a Blue Organic Electric Element>

### [Test Example 1] Green Organic Electric Element (Emission-Auxiliary Layer)

A hole injection layer having a thickness of 60 nm was formed by vacuum-deposition of 4,4′,4″-tris[2-naphthyl(phenyl)amino]triphenylamine (hereinafter, abbreviated as 2-TNATA) on an ITO layer (anode) that was formed on the glass substrate. Thereafter, N,N′-bis(1-naphthalenyl)-N,N′-bis-phenyl-(1,1′-biphenyl)-4,4′-diamine (hereinafter, abbreviated as NPB) was vacuum-deposited to a thickness of 60 nm to form a hole transport layer on the hole injection layer.

Next, light emitting-auxiliary layers comprising a first light emitting-auxiliary layer and a second light emitting-auxiliary layer were formed on the hole transport layer, wherein the first emission-auxiliary layer is formed by vacuum-depositing the compound 1-3 of the present invention to a thickness of 30 nm and the second emission-auxiliary layer is formed by vacuum-depositing the compound 1-16 of the present invention to a thickness of 5 nm. Here, it is preferable to first deposit a material having a high HOMO energy level among the first emission-auxiliary layer and the second emission-auxiliary layer.

Thereafter, a light-emitting layer having a thickness of 30 nm was formed on the light emitting-auxiliary layer. Here, 4,4′-N,N′-dicarbazole-biphenyl(hereinafter, “CBP”) was used as a host, and tris(2-phenylpyridine)-iridium (hereinafter, “Ir(ppy)₃”) was used as a dopant, and the dopant was doped so that the weight ratio thereof was 95:5.

Next, (1,1′-biphenyl-4-olato)bis(2-methyl-8-quinolinolato)aluminum (hereinafter, abbreviated as BAlq) was vacuum-deposited to a thickness of 10 nm on the light-emitting layer to form a hole blocking layer and bis(10-hydroxybenzo[h]quinolinato)beryllium (hereinafter, abbreviated as BeBq₂) was vacuum-deposited to a thickness of 50 nm on the hole blocking layer to form an electron transport layer.

Thereafter, LiF was deposited to a thickness of 0.2 nm to form an electron injection layer, and then Al was deposited to a thickness of 150 nm to form a cathode, thereby manufacturing an organic electroluminescent element.

### [Test Example 2] to [Test Example 24]

An organic electroluminescent element was manufactured in the same manner as in Test Example 1, except that the compounds shown in Table 8 were used as material of the first and second light emitting-auxiliary layer.

### Comparative Example 11

An organic electroluminescent element was manufactured in the same manner as in Test Example 1, except that the following Comparative Compounds 1 and 2 were mixed in a weight ratio of 98:2 and the mixture was vacuum deposited to a thickness of 10 nm to form a first emission-auxiliary layer, and then Comparative Compound 1 was vacuum deposited on the first emission-auxiliary layer to a thickness of 40 nm to form a second emission-auxiliary layer.

### Comparative Example 21

An organic electroluminescent element was manufactured in the same manner as in Test Example 1, except that Compound 1-13 and the following comparative compound 2 were mixed in a weight ratio of 98:2 and the mixture was vacuum-deposited to a thickness of 5 nm to form a first emission-auxiliary layer, and then Comparative Compound 1-16 was vacuum deposited on the first emission-auxiliary layer to a thickness of 30 nm to form a second emission-auxiliary layer.

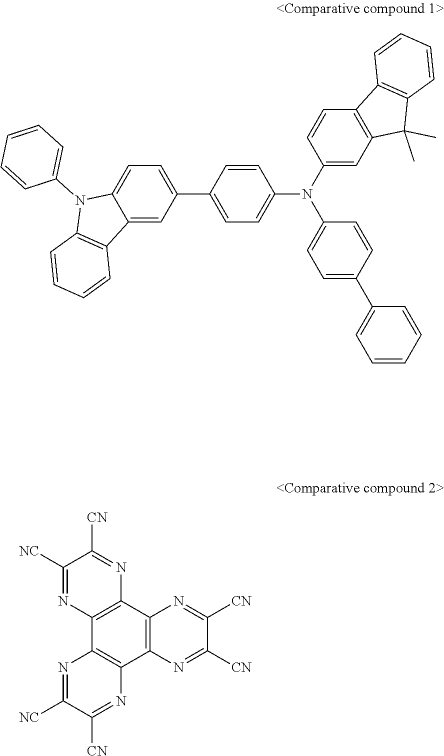 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; N#Cc1nc2c3nc(C#N)c(C#N)nc3c3nc(C#N)c(C#N)nc3c2nc1C#N]

### [Comparative Example 3] to [Comparative Example 8]

An organic electroluminescent element was manufactured in the same manner as in Test Example 1, except that one type of compound was vacuum-deposited to a thickness of 35 nm without additional doping to form one emission-auxiliary layer, as shown in Table 8 below.

A forward bias DC voltage was applied to the organic electric elements manufactured in Test Examples 1 to 24 and Comparative Examples 1 to 8 and electroluminescence (EL) characteristics were measured with a PR-650 manufactured by photo research and lifetime (T95) was measured with a lifetime measuring device manufactured by Mc Science at 5000 cd/m² standard luminance. The measurement results are shown in Table 8 below.

TABLE 8

| | | | | Current | | | | | |
|---|---|---|---|---|---|---|---|---|---|
| | | | Voltage | Density | Brightness | Efficiency | Lifetime | CIE | |
| | EAL 1 | EAL 2 | (V) | (mA/cm²) | (cd/m²) | (cd/A) | T(95) | x | y |
| comp. Ex(1) | Comp. | Comp. | 6.5 | 17.8 | 5000 | 28.1 | 100.7 | 0.34 | 0.64 |
| | compd | compd | | | | | | | |
| | 1 + | 1 | | | | | | | |
| | Comp. | | | | | | | | |
| | compd 2 | | | | | | | | |
| comp. Ex(2) | 1-13 + | 1-16 | 6.3 | 16.0 | 5000 | 31.2 | 115.2 | 0.35 | 0.62 |
| | Comp. | | | | | | | | |
| | compd 2 | | | | | | | | |
| comp. Ex(3) | 1-9 | — | 6.2 | 15.0 | 5000 | 33.3 | 112.4 | 0.33 | 0.62 |
| comp. Ex(4) | 1-13 | — | 6.1 | 14.7 | 5000 | 34.1 | 114.9 | 0.30 | 0.63 |
| comp. Ex(5) | 1-134 | — | 6.1 | 15.4 | 5000 | 32.5 | 113.1 | 0.35 | 0.61 |
| comp. Ex(6) | 2-106 | — | 6.2 | 15.7 | 5000 | 31.8 | 116.3 | 0.32 | 0.61 |
| comp. Ex(7) | 2-116 | — | 6.0 | 16.7 | 5000 | 31.9 | 115.5 | 0.33 | 0.64 |
| comp. Ex(8) | 2-120 | — | 6.0 | 15.3 | 5000 | 32.7 | 113.8 | 0.35 | 0.62 |
| Test Ex. (1) | 1-13 | 1-16 | 5.3 | 9.1 | 5000 | 55.1 | 128.7 | 0.30 | 0.63 |
| Test Ex. (2) | | 1-100 | 5.1 | 10.0 | 5000 | 50.1 | 126.7 | 0.34 | 0.61 |
| Test Ex. (3) | | 2-44 | 5.1 | 9.1 | 5000 | 55.2 | 129.3 | 0.32 | 0.65 |
| Test Ex. (4) | | 2-116 | 5.3 | 9.2 | 5000 | 54.4 | 126.9 | 0.32 | 0.63 |
| Test Ex. (5) | 1-134 | 1-5 | 5.4 | 11.9 | 5000 | 42.0 | 122.8 | 0.33 | 0.65 |
| Test Ex. (6) | | 1-131 | 5.3 | 12.1 | 5000 | 41.5 | 121.1 | 0.32 | 0.61 |
| Test Ex. (7) | | 2-16 | 5.4 | 12.2 | 5000 | 41.1 | 122.4 | 0.32 | 0.63 |
| Test Ex. (8) | | 2-117 | 5.3 | 12.3 | 5000 | 40.5 | 121.8 | 0.32 | 0.62 |
| Test Ex. (9) | 2-28 | 1-9 | 5.1 | 10.4 | 5000 | 48.0 | 128.5 | 0.31 | 0.65 |
| Test Ex. (10) | | 1-13 | 5.2 | 10.6 | 5000 | 47.2 | 129.5 | 0.31 | 0.64 |
| Test Ex. (11) | | 2-73 | 5.1 | 11.0 | 5000 | 45.5 | 129.4 | 0.32 | 0.60 |
| Test Ex. (12) | | 2-120 | 5.1 | 10.6 | 5000 | 47.3 | 125.0 | 0.34 | 0.63 |
| Test Ex. (13) | 2-116 | 1-16 | 4.8 | 9.0 | 5000 | 55.7 | 131.3 | 0.32 | 0.60 |
| Test Ex. (14) | | 1-62 | 4.8 | 9.1 | 5000 | 55.1 | 132.8 | 0.30 | 0.62 |
| Test Ex. (15) | | 2-76 | 4.9 | 9.7 | 5000 | 51.8 | 133.0 | 0.31 | 0.65 |
| Test Ex. (16) | | 2-106 | 4.8 | 8.9 | 5000 | 56.2 | 131.7 | 0.32 | 0.61 |
| Test Ex. (17) | 2-117 | 1-13 | 4.6 | 8.2 | 5000 | 61.2 | 135.0 | 0.34 | 0.64 |
| Test Ex. (18) | | P1-86 | 4.6 | 8.1 | 5000 | 61.5 | 134.3 | 0.35 | 0.61 |
| Test Ex. (19) | | 2-127 | 4.7 | 8.4 | 5000 | 59.4 | 133.8 | 0.30 | 0.65 |
| Test Ex. (20) | 2-117 | 2-128 | 4.7 | 8.5 | 5000 | 58.6 | 133.2 | 0.35 | 0.64 |
| Test Ex. (21) | P4-146 | 1-13 | 4.5 | 8.0 | 5000 | 62.5 | 136.7 | 0.31 | 0.63 |
| Test Ex. (22) | | P1-86 | 4.5 | 7.8 | 5000 | 63.8 | 136.0 | 0.30 | 0.64 |
| Test Ex. (23) | | 2-127 | 4.6 | 8.1 | 5000 | 61.9 | 135.6 | 0.31 | 0.62 |
| Test Ex. (24) | | 2-128 | 4.6 | 8.2 | 5000 | 61.3 | 135.2 | 0.32 | 0.62 |

As can be seen from the results in table 8 above, when a green organic electroluminescent element is manufactured by using the material for an organic electroluminescent element of the present invention as a material for a plurality of emission-auxiliary layers, the driving voltage, efficiency and lifespan were improved, compared to the comparative examples.

Comparative Examples 1 and 2 are similar to the present invention in that two emission-auxiliary layers are formed, but are different from the present invention in that the first emission-auxiliary is formed by doping comparative compound 1 or compound 1-13 of the present invention with comparative compound 2 being a p-type doping material.

Comparative Examples 1 and 2 also have a difference in the material and thickness of the emission-auxiliary layer. It can be seen that the driving voltage, efficiency and lifespan of the element were further improved in Comparative Example 2, in which the total thickness of the emission-auxiliary layer and each of the emission-auxiliary layers were thinner than those of Comparative Example 1.

In addition, the driving voltage and efficiency of the element were improved in Comparative Examples 3 to 8, compared to Comparative Examples 1 and 2, wherein the elements of Comparative Examples 1 and 2 were manufactured by mixing Comparative Compound 2 being a p-type doping material and in Comparative Examples 3 to 8, a single-layered emission-auxiliary layer is formed as one type of compound without using a p-type doping material.

In addition, it can be seen that the driving voltage, efficiency, and lifespan in the elements of Test Examples 1 to 24 of the present invention significantly are significantly improved, compared to Comparative Examples 3 to 8, wherein, in Test Examples 1 to 24 of the present invention, a plurality of emission-auxiliary layers, that is, two emission-auxiliary layers are formed, and the HOMO energy levels of two emission-auxiliary layers are each lower than that of a hole transport layer and the HOMO energy level of the first emission-auxiliary layer is higher than that of the second emission-auxiliary layer.

This is because the charge balance within the light-emitting layer is increased by forming a plurality of emission-auxiliary layers with compound having high hole mobility and excellent hole injection properties, wherein the compound is used as the first emission-auxiliary layer material, and compound having excellent electron blocking properties, wherein the compound is used as the second emission-auxiliary layer material, thereby improving the injection/flow characteristics of holes and electrons without using a p-type doping material.

### [Test Example 25] to [Test Example 48] Red Organic Electric Element (Emission-Auxiliary Layer)

An organic electroluminescent element was manufactured in the same manner as in Test Example 1, except that the compounds were used as a first emission-auxiliary layer material and a second emission-auxiliary layer material, as shown in Table 9, and bis-(1-phenylisoquinolyl)iridium(III)acetylacetonate (hereinafter, (piq)₂Ir(acac) was approximately flagship) was used as a dopant.

### Comparative Example 91

An organic electroluminescent element was manufactured in the same manner as in Comparative Example 1, except that bis-(1-phenylisoquinolyl)iridium(III)acetylacetonate (hereinafter, abbreviated as (piq)₂Ir(acac)) was used as a dopant.

### Comparative Example 101

An organic electroluminescent element was manufactured in the same manner as in Comparative Example 2, except that a mixture of Compound 1-9 of the present invention and Comparative Compound 2 in a weight ratio of 98:2 is used as a first emission-auxiliary layer material, Compound 1-5 of the present invention is used as a second emission-auxiliary layer material, and bis-(1-phenylisoquinolyl)iridium(III)acetylacetonate (hereinafter, abbreviated as (piq)₂Ir(acac)) is used as a dopant.

### [Comparative Example 11] to [Comparative Example 16]

An organic electroluminescent element was manufactured in the same manner as in Comparative Example 3, except that the compound shown in Table 9 was used as the emission-auxiliary layer material, and bis-(1-phenylisoquinolyl)iridium(III)acetylacetonate (hereinafter, abbreviated as (piq)₂Ir(acac)) was used as the dopant.

A forward bias DC voltage was applied to the organic electric elements manufactured in Test Examples 25 to 48 and Comparative Examples 9 to 16 and electroluminescence (EL) characteristics were measured with a PR-650 manufactured by photo research and lifetime (T95) was measured with a lifetime measuring device manufactured by Mc Science at 2500 cd/m² standard luminance. The measurement results are shown in Table 9 below.

TABLE 9

| | | | | Current | | | | | |
|---|---|---|---|---|---|---|---|---|---|
| | | | Voltage | Density | Brightness | Efficiency | Lifetime | CIE | |
| | EAL 1 | EAL 2 | (V) | (mA/cm²) | (cd/m²) | (cd/A) | T(95) | x | y |
| comp. Ex(9) | Comp. | Comp. | 5.8 | 21.2 | 2500 | 11.8 | 102.8 | 0.6 | 0.3 |
| | compd 1 + | compd 1 | | | | | | | |
| | Comp. | | | | | | | | |
| | compd 2 | | | | | | | | |
| comp. Ex(10) | 1-9 + | 1-5 | 5.6 | 17.6 | 2500 | 14.2 | 103.9 | 0.6 | 0.4 |
| | Comp. | | | | | | | | |
| | compd 2 | | | | | | | | |
| comp. Ex(11) | 1-5 | — | 5.5 | 17.7 | 2500 | 14.1 | 103.5 | 0.6 | 0.3 |
| comp. Ex(12) | 1-62 | — | 5.4 | 16.4 | 2500 | 15.2 | 103.7 | 0.6 | 0.3 |
| comp. Ex(13) | 1-100 | — | 5.3 | 16.9 | 2500 | 14.8 | 104.3 | 0.6 | 0.3 |
| comp. Ex(14) | 2-16 | — | 5.4 | 15.3 | 2500 | 16.3 | 104.2 | 0.6 | 0.4 |
| comp. Ex(15) | 2-44 | — | 5.3 | 15.7 | 2500 | 15.9 | 105.6 | 0.6 | 0.3 |
| comp. Ex(16) | 2-76 | — | 5.3 | 15.2 | 2500 | 16.5 | 105.8 | 0.6 | 0.3 |
| Test Ex. (25) | 1-9 | 1-5 | 4.8 | 9.6 | 2500 | 26.1 | 121.9 | 0.66 | 0.33 |
| Test Ex. (26) | | 1-16 | 4.9 | 10.4 | 2500 | 24.1 | 123.7 | 0.66 | 0.32 |
| Test Ex. (27) | | 2-76 | 4.8 | 10.1 | 2500 | 24.8 | 121.4 | 0.66 | 0.33 |
| Test Ex. (28) | | 2-118 | 4.9 | 9.5 | 2500 | 26.2 | 120.8 | 0.66 | 0.33 |
| Test Ex. (29) | 1-135 | 1-9 | 5.2 | 10.5 | 2500 | 23.7 | 119.3 | 0.66 | 0.32 |
| Test Ex. (30) | | 1-105 | 5.1 | 10.8 | 2500 | 23.1 | 119.4 | 0.66 | 0.32 |
| Test Ex. (31) | | 2-16 | 5.0 | 10.5 | 2500 | 23.9 | 118.6 | 0.66 | 0.33 |
| Test Ex. (32) | | 2-28 | 5.1 | 10.7 | 2500 | 23.3 | 119.6 | 0.66 | 0.33 |
| Test Ex. (33) | 2-44 | 1-62 | 5.0 | 10.6 | 2500 | 23.6 | 120.8 | 0.66 | 0.33 |
| Test Ex. (34) | | 1-100 | 5.0 | 9.1 | 2500 | 27.4 | 123.1 | 0.66 | 0.33 |
| Test Ex. (35) | | 2-106 | 4.9 | 10.3 | 2500 | 24.3 | 121.0 | 0.66 | 0.32 |
| Test Ex. (36) | | 2-120 | 4.9 | 9.9 | 2500 | 25.3 | 123.9 | 0.66 | 0.33 |
| Test Ex. (37) | 2-73 | 1-13 | 4.5 | 8.8 | 2500 | 28.4 | 127.7 | 0.66 | 0.32 |
| Test Ex. (38) | | 1-134 | 4.6 | 8.7 | 2500 | 28.6 | 126.6 | 0.66 | 0.33 |
| Test Ex. (39) | | 2-76 | 4.6 | 8.6 | 2500 | 29.1 | 127.4 | 0.66 | 0.32 |
| Test Ex. (40) | | 2-123 | 4.7 | 8.9 | 2500 | 28.2 | 127.8 | 0.66 | 0.33 |
| Test Ex. (41) | 2-135 | 1-16 | 4.6 | 7.9 | 2500 | 31.8 | 129.7 | 0.66 | 0.33 |
| Test Ex. (42) | | 1-100 | 4.6 | 7.7 | 2500 | 32.4 | 130.7 | 0.66 | 0.32 |
| Test Ex. (43) | | 2-16 | 4.6 | 7.8 | 2500 | 32.1 | 130.3 | 0.66 | 0.33 |
| Test Ex. (44) | 2-135 | 2-137 | 4.5 | 7.6 | 2500 | 32.9 | 131.0 | 0.66 | 0.32 |
| Test Ex. (45) | 2-138 | 1-16 | 4.5 | 8.3 | 2500 | 30.3 | 128.2 | 0.66 | 0.33 |
| Test Ex. (46) | | 1-100 | 4.5 | 8.0 | 2500 | 31.1 | 129.0 | 0.66 | 0.33 |
| Test Ex. (47) | | 2-16 | 4.5 | 8.1 | 2500 | 30.8 | 128.7 | 0.66 | 0.33 |
| Test Ex. (48) | | 2-137 | 4.4 | 7.9 | 2500 | 31.5 | 129.4 | 0.66 | 0.33 |

As can be seen in Table 9, Comparative Examples 1 and 2 are similar to the present invention in that two emission-auxiliary layers are formed, but are different from the present invention in that the first emission-auxiliary is formed by doping comparative compound 1 or compound 1-9 of the present invention with comparative compound 2 being a p-type doping material, and Comparative Examples 11 to 16 are different from the present invention in that a single emission-auxiliary layer is formed with one type of compound.

Looking at Comparative Examples 9 to 16, the element characteristics of Comparative Examples 11 to 16 being formed as a single layer were better than those of Comparative Examples 11 to 16 being formed with two emission-auxiliary layers. In particular, Comparative Examples 10 and 11 are common in that they include an emission-auxiliary layer formed of Compound 1-5, but the element characteristics are slightly improved in Comparative Example 11 having a single emission-auxiliary layer.

However, in the case of Examples 25 to 48 of the present invention, even when a plurality of emission-auxiliary layers are formed, the characteristics of the element were remarkably improved. From these results, it can be confirmed that the characteristics of the element can be improved when a plurality of emission-auxiliary layers are formed with different thicknesses by selectively using compounds having the HOMO energy level correlation according to the conditions defined in the present invention.

In the case of the present invention, it seems that the characteristics of the element are is improved because the compound having a different HOMO energy level between the HOMO energy level of a hole transport layer and the HOMO energy level of the light-emitting layer is used as a emission-auxiliary layer material, and the thicknesses of the emission-auxiliary layers was controlled when the first and the second emission-auxiliary layer are formed, thereby improving the injection of electrons and holes into the light-emitting layer and the charge balance.

Although the exemplary embodiments of the present invention have been described for illustrative purposes, those skilled in the art to which the present invention pertains will be capable of various modifications without departing from the essential characteristics of the present invention. Therefore, the embodiment disclosed herein is intended to illustrate the scope of the technical idea of the present invention, and the spirit and scope of the present invention are not limited by the embodiments. The scope of the present invention shall be construed on the basis of the accompanying claims, and it shall be construed that all of the technical ideas included within the scope equivalent to the claims belong to the present invention.

What is claimed is:

1. An organic electric element comprising:
a first electrode;
a second electrode; and
an organic material layer between the first electrode and the second electrode, the organic material layer comprising:
a light-emitting layer;
a hole transport layer between the first electrode and the light-emitting layer; and
a plurality of emission-auxiliary layers between the light-emitting layer and the hole transport layer,
wherein the plurality of emission-auxiliary layers comprise a first emission-auxiliary layer adjacent to the hole transport layer and a second emission-auxiliary layer adjacent to the light-emitting layer,
each of the first emission-auxiliary layer and the second emission-auxiliary layer is independently formed of one type of a compound without additional doping,
a highest occupied molecular orbital (HOMO) energy level of the plurality of emission-auxiliary layers is lower than a HOMO energy level of the hole transport layer and is higher than the HOMO energy level of the light-emitting layer,
a HOMO energy level of the first emission-auxiliary layer is higher than the HOMO energy level of the second emission-auxiliary layer,
wherein the first emission-auxiliary layer and the second emission-auxiliary layer are formed of different compounds,
wherein the first emission-auxiliary layer comprises a compound represented by the following Formula 1 or Formula 2, and the second emission-auxiliary layer comprises a compound represented by Formula A-4-1 or Formula A-4-2: 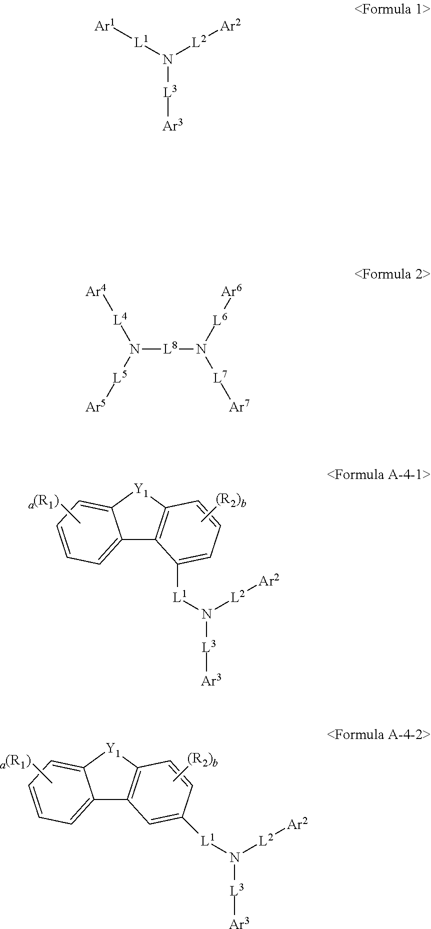
wherein:
Ar¹ to Ar⁷ are each independently selected from the group consisting of a C₆-C₆₀ aryl group, a fluorenyl group, a C₂-C₆₀ heterocyclic group comprising at least one heteroatom selected from the group consisting of O, N, S, Si and P, and a C₃-C₆₀ aliphatic ring, Ar⁴ and Ar⁵ may be linked to each other to form a ring, and Ar⁶ and Ar⁷ may be linked to each other to form a ring,
L¹ to L⁷ are each independently selected from the group consisting of a single bond, a C₆-C₆₀ arylene group, a fluorenylene group, a C₃-C₆₀ aliphatic ring, and a C₂-C₆₀ heterocyclic group comprising at least one heteroatom selected from the group consisting of O, N, S, Si and P,
L⁸ is selected from the group consisting of a C₆-C₆₀ arylene group, a fluorenylene group, a C₃-C₆₀ aliphatic ring, and a C₂-C₆₀ heterocyclic group comprising at least one heteroatom selected from the group consisting of O, N, S, Si and P,
with a proviso that at least one of Ar⁴ to Ar⁷ and L⁸ comprises the heterocyclic group or at least two of Ar⁴ to Ar⁷ comprise the fluorenyl group in Formula 2, and
Y₁ is O, S or C(R₅)(R₆),
R₁, R₂, R₅ and R₆ are each independently selected from the group consisting of deuterium, halogen, a silane group unsubstituted or substituted with a C₁-C₂₀ alkyl group or a C₆-C₂₀ aryl group, a siloxane group, a cyano group, a nitro group, a C₁-C₂₀ alkylthio group, a C₁-C₂₀ alkoxy group, a C₆-C₂₀ aryloxy group, a C₆-C₂₀ arylthio, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and adjacent groups may be linked to each other to form a ring, R₅ and R₆ may be linked to each other to form a ring,
a is an integer of 0 to 4, b is an integer of 0 to 3, and when each of a and b is an integer of 2 or more, a plurality of R₁ may be the same or different from each other, and a plurality of R₂ may be the same or different from each other,
wherein the aryl group, the arylene group, the fluorenyl group, the fluorenylene group, the heterocyclic group, the aliphatic ring group, the ring formed by linking Ar⁴ and Ar5 to each other, the ring formed by linking Ar⁶ and Ar⁷ to each other, the ring formed by adjacent R₁ groups or adjacent R₂ groups, the ring formed by R₅ and R₆ may be each optionally substituted with one or more substituents selected from the group consisting of deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}),
L¹ is selected from the group consisting of a single bond, a C₆-C₂₀ arylene group, a fluorenylene group, a C₃-C₂₀ aliphatic ring, and a C₂-C₂₀ heterocyclic group comprising at least one heteroatom selected from the group consisting of O, N, S, Si and P, and
Rₐ and R_{b} are each independently selected from the group consisting of a C₆-C₂₀ aryl group, a fluorenyl group, a C₃-C₂₀ aliphatic ring, and a C₂-C₂₀ heterocyclic group comprising at least one heteroatom selected from the group consisting of O, N, S, Si and P.

2. The organic electric element of claim 1, wherein the thickness of the first emission-auxiliary layer is 200 to 400 Å, the thickness of the second emission-auxiliary layer is 50 to 200 Å, and the total thickness of the plurality of emission-auxiliary layers is 300 to 400 Å.

3. The organic electric element of claim 1, wherein the HOMO energy level of the first emission-auxiliary layer is 0.01 to 0.5 eV higher than the HOMO energy level of the second auxiliary layer.

4. The organic electric element of claim 1, wherein the HOMO energy levels of the first and the second emission-auxiliary layer are respectively 5.50 to 5.69 eV based on absolute values.

5. The organic electric element of claim 1, wherein Formula 1 is represented by Formula A-1 or Formula A-2: 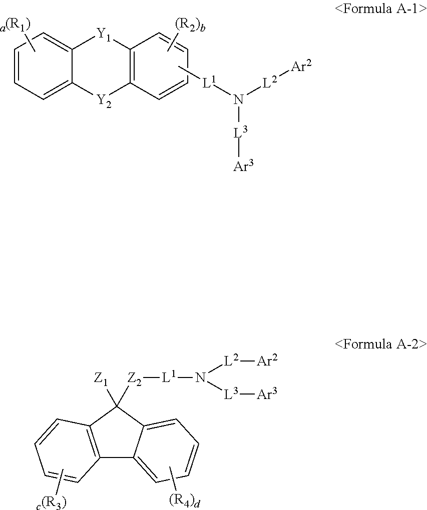
wherein:
L¹ to L³, Ar², Ar³ are the same as defined in claim 1,
Y₁ and Y₂ are a single bond, O, S or C(R₅)(R₆), and a case when both Y₁ and Y₂ are a single bond is excluded,
R₁, R₂, R₅, R₆, a and b are the same as defined in claim 1,
R₃, R₄ and Z₁ are each independently selected from the group consisting of deuterium, halogen, a silane group unsubstituted or substituted with a C₁-C₂₀ alkyl group or a C₆-C₂₀ aryl group, a siloxane group, a cyano group, a nitro group, a C₁-C₂₀ alkylthio group, a C₁-C₂₀ alkoxy group, a C₆-C₂₀ aryloxy group, a C₆-C₂₀ arylthio, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and adjacent groups may be linked to each other to form a ring, and Z₁ and Z₂ may be linked to each other to form a ring,
Z₂ is selected from the group consisting of a C₆-C₂₀ arylene group, a fluorenylene group, a C₂-C₂₀ heterocyclic group containing at least one heteroatom of O, N, S, Si, and P, and a C₃-C₂₀ aliphatic ring group,
c and d are each an integer of 0 to 4, and when each of c and d is an integer of 2 or more, a plurality of R₃ are the same or different from each other, and a plurality of R₄ are the same or different from each other,
the aryl group, the arylene group, the fluorenyl group, the fluorenylene group, the heterocyclic group, the aliphatic ring group, the alkyl group, the alkenyl group, the alkynyl group, the alkoxy group, the aryloxy group, the ring formed by linking adjacent groups to each other, and the ring formed by linking Z₁ and Z₂ to each other may be each optionally substituted with one or more substituents selected from the group consisting of deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and
L′, Rₐ and R_{b} are the same as defined in claim 1.

6. The organic electric element of claim 5, wherein Formula A-1 is represented by Formula A-3 or Formula A-4: 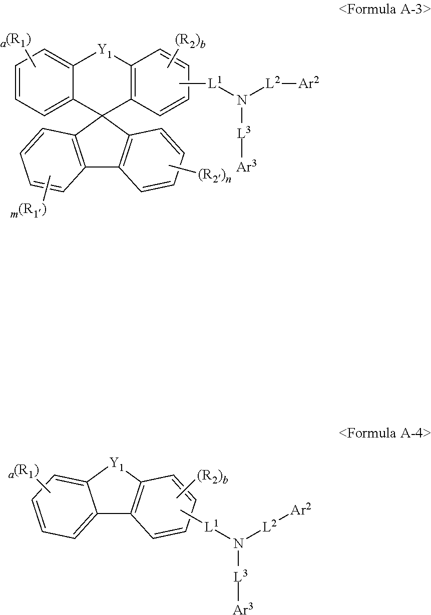
wherein:
R_{1′} and R_{2′} are each independently selected from the group consisting of deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}),
m is an integer of 0 to 4, n is an integer of 0 to 3, and when each of these is an integer of 2 or more, a plurality of R_{1′} are the same or different from each other, and a plurality of R_{2′} are the same or different from each other, and
Y₁, L¹ to L³, Ar², Ar³, R₁, R₂, a, b, L′, Rₐ and R_{b} are the same as defined in claim 5.

7. The organic electric element of claim 5, wherein Formula A-1 is represented by Formula A-5 or Formula A-6: 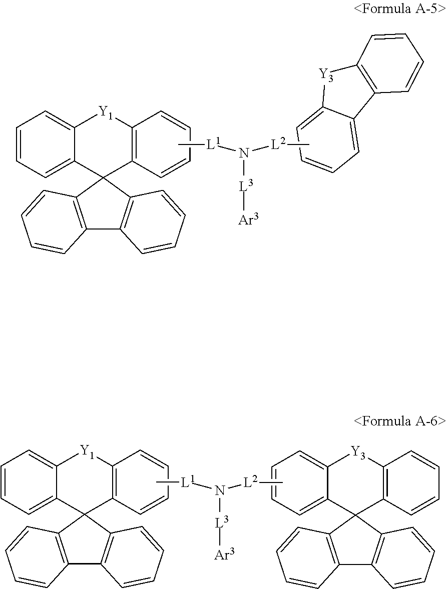
wherein Y₁, L¹ to L³, Ar³ are the same as defined in claim 5 and Y₃ is defined the same as Y₁.

8. The organic electric element of claim 1, wherein Formula 2 is represented by Formula B-1: 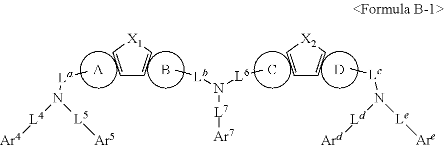
wherein, L⁴ to L⁷, Ar⁴, Ar⁵, Ar⁷ are the same as defined in claim 1,
A ring, B ring, C ring and D ring are each independently selected from the group consisting of a C₆-C₂₀ aromatic ring group, a fluorene group, a C₂-C₂₀ heterocyclic group containing at least one heteroatom of O, N, S, Si and P, and a C₃-C₂₀ aliphatic ring, and each of these may be substituted with one or more R,
X₁ and X₂ are each independently O, S, N(Ar) or C(R₇)(R₈),
L^{a} to L^{e} are each independently selected from the group consisting of a single bond, a C₆-C₂₀ arylene group, a fluorenylene group, a C₂-C₂₀ heterocyclic group comprising at least one heteroatom selected from the group consisting of O, N, S, Si and P, and a C₃-C₂₀ aliphatic ring,
Ar^{d}, Ar^{e} and Ar are each independently selected from the group consisting of a C₆-C₂₀ aryl group, a fluorenyl group, a C₂-C₂₀ heterocyclic group comprising at least one heteroatom selected from the group consisting of O, N, S, Si and P, a C₃-C₂₀ aliphatic ring,
R, R₇ and R₈ are each independently selected from the group consisting of hydrogen, deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, and a C₃-C₂₀ aliphatic ring group, and R₇ and R₈ may be linked to each other to form a ring,
the aryl group, arylene group, fluorenyl group, fluorenylene group, heterocyclic group, aliphatic ring group, alkyl group, alkenyl group, alkynyl group, alkoxy group, aryloxy group, the ring formed by linking R₇ and R₈ to each other may be each optionally substituted with one or more substituents selected from the group consisting of deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group, and -L′-N(Rₐ)(R_{b}), and
L′, Rₐ and R_{b} are the same as defined in claim 1.

9. The organic electric element of claim 8, wherein Formula B-1 is represented by Formula B-2: 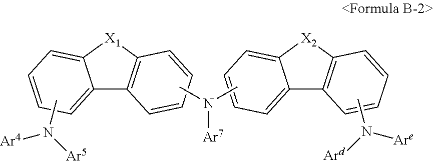
wherein Ar⁴, Ar⁵, Ar⁷, Ar^{d}, Ar^{e}, X₁ and X₂ are the same as defined in claim 8.

10. The organic electric element of claim 8, wherein Formula B-1 is represented by one of the following Formula B-3 to Formula B-6: 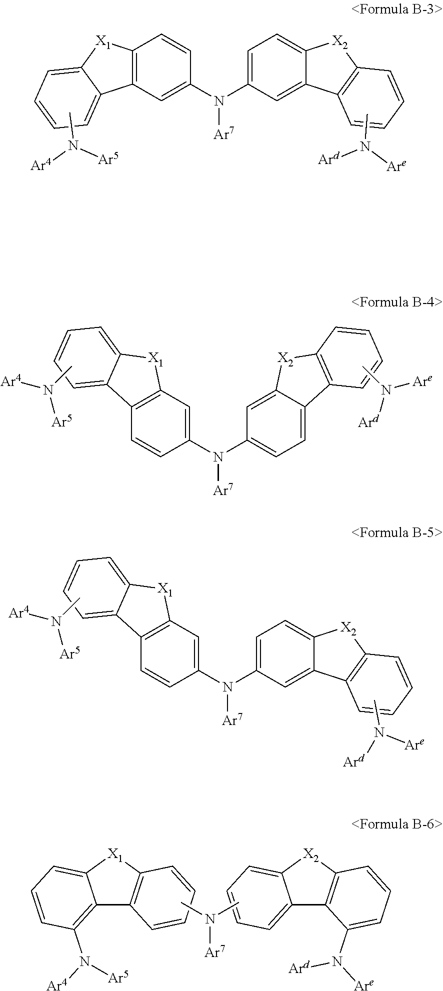
wherein Ar⁴, Ar⁵, Ar⁷, Ar^{d}, Ar^{e}, X₁ and X₂ are the same as defined in claim 8.

11. The organic electric element of claim 5, wherein the first emission-auxiliary layer comprises the compound represented by Formula A-1.

12. The organic electric element of claim 1, wherein at least one of Ar¹ to Ar⁷ and L⁸ is represented by Formula 3: 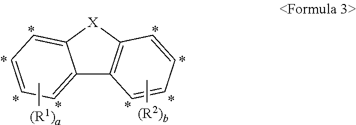
wherein:
* indicates the bonding position,
X is N, N-(L^{a}-Ar^{a}), O, S or C(R′)(R″),
R¹, R², R′ and R″ are each independently selected from the group consisting of hydrogen, deuterium, halogen, a cyano group, a nitro group, a C₁-C₂₀ alkoxy group, a C₆-C₂₀ aryloxy group, a C₁-C₂₀ alkyl group, a C₂-C₂₀ alkenyl group, a C₂-C₂₀ alkynyl group, a C₆-C₂₀ aryl group, a fluorenyl group, a C₂-C₂₀ heterocyclic group containing at least one heteroatom of O, N, S, Si, and P, a C₃-C₂₀ aliphatic ring group and -L′-N(Rₐ)(R_{b}), adjacent groups may be linked to each other to form a ring, and R′ and R″ may be linked to each other to form a ring,
a and b are each an integer of 0 to 4, and when each of these is an integer of 2 or more, a plurality of R₁ are the same or different from each other, and a plurality of R₂ are the same or different from each other,
L^{a} is selected from the group consisting of a single bond, a C₆-C₂₀ arylene group, a fluorenylene group, a C₂-C₂₀ heterocyclic group comprising at least one heteroatom selected from the group consisting of O, N, S, Si and P, and a C₃-C₂₀ aliphatic ring,
Ar^{a} is selected from the group consisting of a C₆-C₂₀ aryl group, a fluorenyl group, a C₂-C₂₀ heterocyclic group comprising at least one heteroatom selected from the group consisting of O, N, S, Si and P, a C₃-C₂₀ aliphatic ring, and
L′, Rₐ and R_{b} are the same as defined in claim 1.

13. The organic electric element of claim 1, further comprising a layer for improving luminous efficiency, wherein the layer for improving luminous efficiency is formed on one side of both sides of the first electrode or the second electrode that is not in contact with the organic material layer.

14. The organic electric element of claim 1, wherein the organic material layer comprises two or more stacks, and the two or more stacks each comprise a hole transport layer, a light-emitting layer and an electron transport layer formed sequentially on the first electrode.

15. The organic electric element of claim 14, wherein the organic material layer further comprises a charge generation layer formed between the two or more stacks.

16. An electronic device comprising a display device and a control unit for driving the display device, wherein the display device comprises the organic electric element of claim 1.
